(19) United States
(12) Patent Application Publication
(10) Pub. No.: US 2025/0374745 A1
(43) Pub. Date: Dec. 4, 2025

(54) MIXTURE AND COMPOSITION COMPRISING AN ARYLAMINE COMPOUND, ELECTROLUMINESCENT DEVICE AND ELECTRONIC DEVICE THEREOF

(71) Applicant: BEIJING SUMMER SPROUT TECHNOLOGY CO., LTD.

(72) Inventors: Le Wang, Beijing (CN); Qiang Wang, Beijing (CN); Ziyan Zhang, Beijing (CN); Gaoqi Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/220,547

(22) Filed: May 28, 2025

(30) Foreign Application Priority Data
May 31, 2024 (CN) 202410701629.2

(51) Int. Cl. H10K 50/11; C09K 11/06; H10K 85/30; H10K 85/40; H10K 85/60

(52) U.S. Cl. CPC H10K 50/11; C09K 11/06; H10K 85/342; H10K 85/40; H10K 85/622; H10K 85/626; H10K 85/633; H10K 85/636; H10K 85/654; H10K 85/656; H10K 85/6572; H10K 85/6574; H10K 85/6576; C09K 2211/1033; C09K 2211/185

(57) ABSTRACT

Provided are a mixture and composition comprising an arylamino compound, an organic electroluminescent device and an electronic device thereof. The mixture, composition, organic electroluminescent device and electronic device comprise three or more compounds, one of which contains an arylamino group. The mixture and the composition can each be used as a host material in the organic electroluminescent device so that the electroluminescent device can obtain good overall performance, such as relatively high efficiency and a relatively long lifetime. In particular, the mixture has high evaporation stability and can be used as a single evaporation source in a preparation process of an OLED device, which can simplify a production process and reduce a production cost.

### CROSS-REFERENCE TO RELATED APPLICATION(S)

This application claims priority to Chinese Patent Application No. CN 202410701629.2 filed on May 31, 2024, the disclosure of which is incorporated herein by reference in its entirety.

### TECHNICAL FIELD

The present disclosure relates to a mixture and composition comprising three or more compounds, an organic electroluminescent device, and an electronic device comprising the electroluminescent device and, in particular, to a mixture and composition comprising three or more compounds, one of which contains an arylamino group, an organic electroluminescent device and an electronic device thereof.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

CN115943749A has disclosed an electronic element whose overlay comprises a compound having a structure represented by the following general formula:

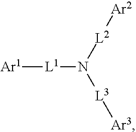

wherein the structure is further limited to a structure represented by the following general formula:

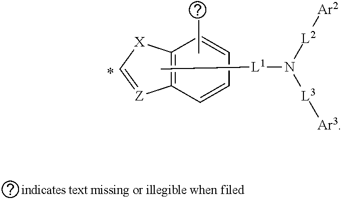

However, this application has neither disclosed nor taught a mixture formed by premixing such materials with two or more other compounds, let alone the use of the mixture as a host material in an organic electroluminescent device and the effects achievable.

CN115340516A has disclosed a compound having a structure represented by a general formula of

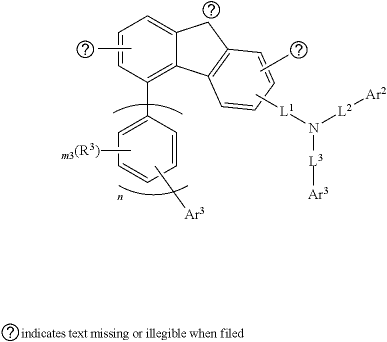

and an application thereof in an electroluminescent device. However, this application has neither disclosed nor taught a mixture formed by premixing the compound with two or more other compounds, let alone the use of the mixture as a host material in an organic electroluminescent device and the effects achievable.

WO2015163848A1 has disclosed an electroluminescent device whose emissive layer comprises a pre-mixture comprising a physical mixture of an organic metallic phosphorescent doping material and an organic host material having a particular structure. This application focuses on a pre-mixture of two materials, an emissive material and a host material, and an application of the mixture in the electroluminescent device. However, this application has neither disclosed nor taught a mixture formed by premixing three or more hole and electron transporting materials with different structures, let alone the use of the mixture as a host material in an organic electroluminescent device and the effects achievable.

To obtain devices with better overall performance, a variety of raw materials can be used to prepare an emissive layer. It is particularly important to select a combination of materials whose properties are better matched. Therefore, the technical problem to be urgently solved in the industry is to focus on the combination and matching of different materials and develop a novel mixture with better matched properties and high evaporation stability, wherein the mixture is applied to an organic electroluminescent device to obtain better device performance.

### SUMMARY

The present disclosure aims to provide a novel mixture comprising three or more compounds to solve at least part of the preceding problems. The novel mixture of the present disclosure comprises at least three hole transport-type compounds and electron transport-type compounds having different structures from each other, wherein at least one hole transport-type compound contains an arylamino group. In particular, the mixture of the present disclosure has high evaporation stability and can be used as a single evaporation source in a preparation process of an OLED device, which can simplify a production process and reduce a production cost. Moreover, when the mixture is used as a host material in an organic electroluminescent device, the electroluminescent device can obtain good overall performance.

According to an embodiment of the present disclosure, a mixture is disclosed. The mixture comprises at least a first compound, a second compound and a third compound;
wherein the first compound is a hole transport-type compound, the second compound is an electron transport-type compound, and the third compound is selected from a hole transport-type compound or an electron transport-type compound;
the hole transport-type compound contains an arylamino group;
the first compound, the second compound and the third compound have chemical structures different from each other;
the mixture comprises a pre-mixture formed by pre-mixing the first compound, the second compound and the third compound, a mass proportion of at least one compound of the first compound, the second compound or the third compound in the mixture is C₀, and when the mixture is evaporated at a rate of 0.01-5 Å/s and a vacuum degree of 10⁻⁶ Torr or lower, the pre-mixture is evaporated on a surface positioned at a certain distance from the mixture to be evaporated to form n films, each with a certain thickness, and a mass proportion of the at least one compound in the n-th film is Cₙ, wherein n is an integer greater than or equal to 1; and
an absolute value of a difference between C₀ and a mass proportion Cₘ of the at least one compound in any one of the evaporated n films satisfies that |Cₘ−C₀|≤2%, wherein m is an integer selected from 1 to n.

According to another embodiment of the present disclosure, a compound composition is further disclosed. The compound composition comprises a first compound represented by Formula 1, a second compound represented by Formula 2 and a third compound represented by Formula 1 or Formula 2, wherein the first compound, the second compound and the third compound have structures different from each other;

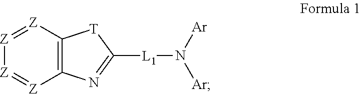

wherein
Ar is, at each occurrence identically or differently, selected from substituted or unsubstituted aryl having 6 to 30 carbon atoms, substituted or unsubstituted heteroaryl having 3 to 30 carbon atoms or a combination thereof;
L₁ is selected from a single bond, substituted or unsubstituted arylene having 6 to 30 carbon atoms, substituted or unsubstituted heteroarylene having 3 to 30 carbon atoms or a combination thereof;
Z is, at each occurrence identically or differently, selected from N or CR_{z}; and
T is selected from O, S or Se;

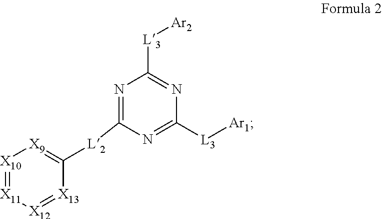

wherein
X₉ to X₁₃ are, at each occurrence identically or differently, selected from CRₓ or N;
L′₂, L₃ and L′₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are selected from substituted or unsubstituted aryl having 6 to 30 carbon atoms, substituted or unsubstituted heteroaryl having 3 to 30 carbon atoms or a combination thereof;
R_{z} and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring; and
adjacent substituents Rₓ can be optionally joined to form a ring.

According to another embodiment of the present disclosure, an electroluminescent device is further disclosed. The electroluminescent device comprises a first electrode, a second electrode and an organic layer disposed between the first electrode and the second electrode, wherein the organic layer comprises at least the mixture of the preceding embodiment.

According to another embodiment of the present disclosure, an electronic device is further disclosed. The electronic device comprises the electroluminescent device of the preceding embodiment.

The novel mixture of the present disclosure comprises at least three hole and electron transport-type compounds having different structures from each other, wherein at least one of the hole transport-type compounds contains the arylamino group. In particular, the novel mixture of the present disclosure has high evaporation stability and can be used as a single evaporation source in the preparation process of the OLED device, which can simplify the production process and reduce the production cost. Moreover, when the mixture is used as the host material in the organic electroluminescent device, the electroluminescent device can obtain good overall performance.

### BRIEF DESCRIPTION OF DRAWINGS

FIG. 1 is a schematic diagram of an organic light-emitting device that may comprise a mixture or a compound composition disclosed herein.

FIG. 2 is another schematic diagram of an organic light-emitting device that may comprise a mixture or a compound composition disclosed herein.

### DETAILED DESCRIPTION

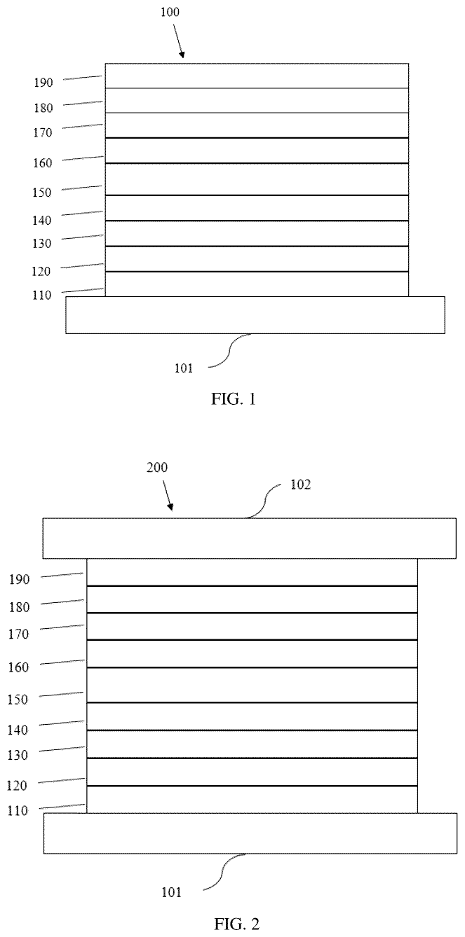

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small Δ_{ES-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, trimethylgermanylmethyl, dimethylaminomethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, I-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphtbylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

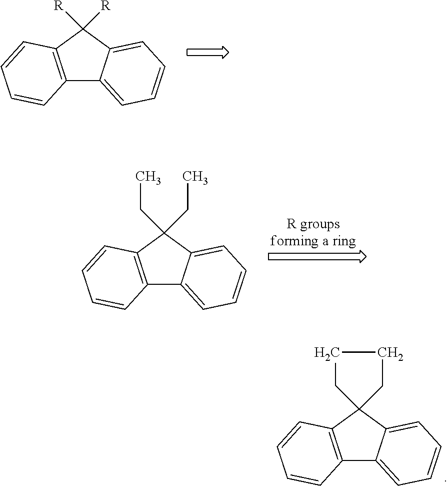

The expression that adjacent substituents can be optionally joined to form a ring is also intended to mean that two substituents bonded to carbon atoms which are directly bonded to each other are joined to each other via a chemical bond to form a ring, which can be exemplified by the following formula:

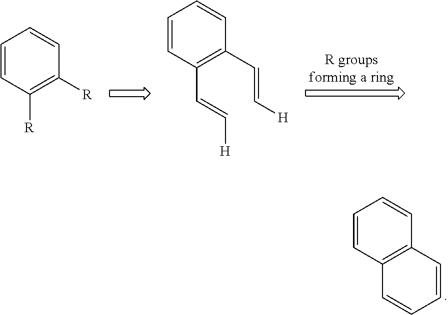

The expression that adjacent substituents can be optionally joined to form a ring is also intended to mean that two substituents bonded to further distant carbon atoms are joined to each other via a chemical bond to form a ring, which can be exemplified by the following formula:

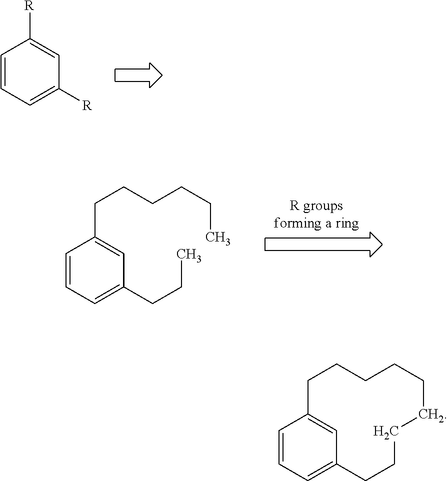

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

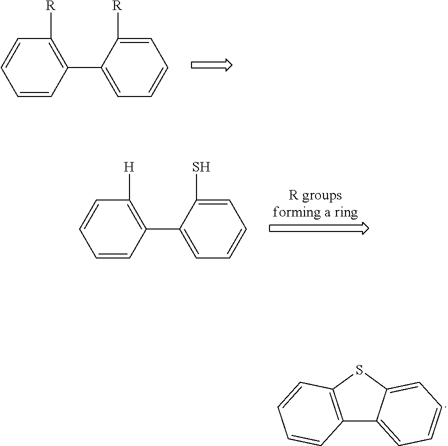

According to an embodiment of the present disclosure, a mixture is disclosed. The mixture comprises at least a first compound, a second compound and a third compound;
wherein the first compound is a hole transport-type compound, the second compound is an electron transport-type compound, and the third compound is selected from a hole transport-type compound or an electron transport-type compound;
the hole transport-type compound contains an arylamino group;
the first compound, the second compound and the third compound have chemical structures different from each other;
the mixture comprises a pre-mixture formed by pre-mixing the first compound, the second compound and the third compound, a mass proportion of at least one compound of the first compound, the second compound or the third compound in the mixture is C₀, and when the mixture is evaporated at a rate of 0.01-5 Å/s and a vacuum degree of 10⁻⁶ Torr or lower, the pre-mixture is evaporated on a surface positioned at a certain distance from the mixture to be evaporated to form n films, each with a certain thickness, and a mass proportion of the at least one compound in the n-th film is Cₙ, wherein n is an integer greater than or equal to 1; and
an absolute value of a difference between C₀ and a mass proportion Cₘ of the at least one compound in any one of the evaporated n films satisfies that |Cₘ−C₀|≤2%, wherein m is an integer selected from 1 to n.

In the present disclosure, the “hole transport-type compound” refers to a compound that has a hole transporting capability stronger than an electron transporting capability and that can be used as a hole transporting material in an electroluminescent device, including, but not limited to, a hole transporting compound or a bipolar compound.

The “electron transport-type compound” refers to a compound that has an electron transporting capability stronger than a hole transporting capability, which means that the electron transporting capability of the compound is stronger than the hole transporting capability of the compound. The “electron transport-type compound” includes, but is not limited to, an electron transporting compound or a bipolar compound.

For example, the hole transporting capability and the electron transporting capability may be determined by those skilled in the art according to carrier mobilities of a material. A material with an electron mobility greater than a hole mobility has the stronger electron transporting capability. On the contrary, the material has the stronger hole transporting capability.

In the present disclosure, the “arylamino group” is intended to mean an amino group substituted with an aromatic group which may be aryl or heteroaryl, etc. Obviously, fused carbazolyl such as carbazolyl, azacarbazolyl or indolocarbazolyl is not within the range of the “arylamino group” described herein.

According to an embodiment of the present disclosure, the mass proportion of the at least one compound of the first compound, the second compound or the third compound in the mixture is C₀, and when the mixture is evaporated at a rate of 0.01-5 Å/s and a vacuum degree of 10⁻⁶ Torr or lower, the mixture is evaporated on the surface positioned at the certain distance from the mixture to be evaporated to form n films, each with a certain thickness, and the mass proportion of the at least one compound in the n-th film is Cₙ, wherein n is an integer greater than or equal to 1; and the absolute value of the difference between C₀ and the mass proportion Cₘ of the at least one compound in any one of the evaporated n films satisfies that |Cₘ−C₀|≤1.5%, wherein m is an integer selected from 1 to n.

According to an embodiment of the present disclosure, the mass proportion of the at least one compound of the first compound, the second compound or the third compound in the mixture is C₀, and when the mixture is evaporated at a rate of 0.01-5 Å/s and a vacuum degree of 10⁻⁶ Torr or lower, the mixture is evaporated on the surface positioned at the certain distance from the mixture to be evaporated to form n films, each with a certain thickness, and the mass proportion of the at least one compound in the n-th film is Cₙ, wherein n is an integer greater than or equal to 1; and the absolute value of the difference between C₀ and the mass proportion Cₘ of the at least one compound in any one of the evaporated n films satisfies that |Cₘ−C₀|≤1.0%, wherein m is an integer selected from 1 to n.

According to an embodiment of the present disclosure, the mass proportion of the at least one compound of the first compound, the second compound or the third compound in the mixture is C₀, and when the mixture is evaporated at a rate of 0.01-5 Å/s and a vacuum degree of 10⁻⁶ Torr or lower, the mixture is evaporated on the surface positioned at the certain distance from the mixture to be evaporated to form n films, each with a certain thickness, and the mass proportion of the at least one compound in the n-th film is Cₙ, wherein n is an integer greater than or equal to 1; and the absolute value of the difference between C₀ and the mass proportion Cₘ of the at least one compound in any one of the evaporated n films satisfies that |Cₘ−C₀|≤0.7%, wherein m is an integer selected from 1 to n.

According to another embodiment of the present disclosure, when the third compound is selected from the hole transport-type compound, the third compound is heavier than the second compound and the first compound is lighter than the second compound in evaporation characteristics.

According to another embodiment of the present disclosure, when the third compound is selected from the electron transport-type compound, the second compound is heavier than the first compound and the third compound is lighter than the first compound in evaporation characteristics.

In the present disclosure, any two compounds are premixed to form a two-component mixture. When the two-component mixture is evaporated at a rate of 0.01-5 Å/s and a vacuum degree of about 10⁻⁶ Torr or lower, the two-component mixture is evaporated on a surface positioned at a certain distance from the mixture to be evaporated to form n films, each with a certain thickness. As the film number increases, if a mass proportion of one compound shows an overall increasing trend, the compound is “heavy” in evaporation characteristics. On the contrary, when the mass proportion of one compound overall tends to decrease gradually, the compound is considered as “light” in evaporation characteristics. As shown by the data in Table 8, as the film number increases, the proportions of Compound A-890 in the films show an overall increasing trend (from 48.708% in the first film to 69.547% in the sixth film). Therefore, Compound A-890 is “heavy” relative to Compound B-1.

According to an embodiment of the present disclosure, when the first compound, the second compound and the third compound are separately evaporated at a rate of 0.01-5 Å/s and a vacuum degree of 10⁻⁶ Torr or lower, an absolute value of a difference between evaporation temperatures of any two of the first compound, the second compound and the third compound is less than 30° C.

According to an embodiment of the present disclosure, when the first compound, the second compound and the third compound are separately evaporated at a rate of 0.01-5 Å/s and a vacuum degree of 10⁻⁶ Torr or lower, an absolute value of a difference between the evaporation temperatures of any two of the first compound, the second compound and the third compound is less than 20° C.

According to an embodiment of the present disclosure, when the first compound, the second compound and the third compound are separately evaporated at a rate of 0.01-5 Å/s and a vacuum degree of 10⁻⁶ Torr or lower, an absolute value of a difference between the evaporation temperatures of any two of the first compound, the second compound and the third compound is less than 10° C.

According to an embodiment of the present disclosure, evaporation temperatures of the first compound, the second compound and the third compound are between 120° C. and 390° C.

According to an embodiment of the present disclosure, the evaporation temperatures of the first compound, the second compound and the third compound are between 140° C. and 370° C.

According to an embodiment of the present disclosure, the evaporation temperatures of the first compound, the second compound and the third compound are between 160° C. and 360° C.

According to an embodiment of the present disclosure, the evaporation temperatures of the first compound, the second compound and the third compound are between 200° C. and 350° C.

According to an embodiment of the present disclosure, the hole transport-type compound has a HOMO energy level of −3.5 eV to −6.0 eV.

According to an embodiment of the present disclosure, the hole transport-type compound has a HOMO energy level of −4.0 eV to −5.6 eV.

According to an embodiment of the present disclosure, the electron transport-type compound has a LUMO energy level of −1.9 eV to −3.5 eV.

According to an embodiment of the present disclosure, the electron transport-type compound has a LUMO energy level of −2.0 eV to −3.0 eV.

According to an embodiment of the present disclosure, in the mixture, at least one of the first compound, the second compound or the third compound has a triplet energy level T₁<2.65 eV.

According to an embodiment of the present disclosure, in the mixture, at least one of the first compound, the second compound or the third compound has a triplet energy level T₁<2.60 eV.

According to an embodiment of the present disclosure, the hole transport-type compound and/or the electron transport-type compound contain at least one chemical group selected from the group consisting of oxazole, thiazole, benzoxazole, benzothiazole, naphthoxazole, naphthothiazole, benzothiophene, benzofuran, dibenzothiophene, dibenzofuran, aza-dibenzothiophene, azadibenzofuran, dibenzoselenophene, benzene, pyridine, pyrimidine, carbazole, azacarbazole, indolocarbazole, triphenylene, azatriphenylene, fluorene, silafluorene, naphthalene, quinoline, isoquinoline, quinazoline, quinoxaline, phenanthrene, azaphenanthrene and combinations thereof.

In this embodiment, substituted, aza- or fused-ring derivatives of groups such as “oxazole, thiazole, benzoxazole, benzothiazole, naphthoxazole, naphthothiazole, benzothiophene, benzofuran, dibenzothiophene, dibenzofuran, aza-dibenzothiophene, azadibenzofuran, dibenzoselenophene, benzene, pyridine, pyrimidine, carbazole, azacarbazole, indolocarbazole, triphenylene, azatriphenylene, fluorene, silafluorene, naphthalene, quinoline, isoquinoline, quinazoline, quinoxaline, phenanthrene, azaphenanthrene” are also “chemical groups” in this embodiment, including, but not limited to, “substituted oxazole”, “substituted naphthoxazole”, “aza-naphthoxazole” or “phenanthroxazole (a fused-ring derivative of oxazole)”.

According to an embodiment of the present disclosure, the hole transport-type compound contains an oxazole group.

According to an embodiment of the present disclosure, the hole transport-type compound contains a benzoxazole group.

According to an embodiment of the present disclosure, the hole transport-type compound contains a naphthoxazole group.

According to an embodiment of the present disclosure, the electron transport-type compound contains a triazine group.

According to an embodiment of the present disclosure, in the mixture, the first compound has a structure represented by Formula 1:

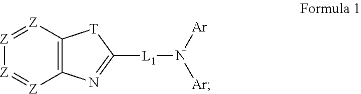

wherein
Ar is, at each occurrence identically or differently, selected from substituted or unsubstituted aryl having 6 to 30 carbon atoms, substituted or unsubstituted heteroaryl having 3 to 30 carbon atoms or a combination thereof;
L₁ is selected from a single bond, substituted or unsubstituted arylene having 6 to 30 carbon atoms, substituted or unsubstituted heteroarylene having 3 to 30 carbon atoms or a combination thereof;
Z is, at each occurrence identically or differently, selected from N or CR_{z};
T is selected from O, S or Se;
R_{z} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{z} can be optionally joined to form a ring.

In this embodiment, the expression that “adjacent substituents R_{z} can be optionally joined to form a ring” is intended to mean that two adjacent substituents R_{z} can be joined to form a ring. For example, in Formula 1, one or more of groups of adjacent substituents R_{z} on the groups Z can be optionally joined to form a ring. Obviously, it is also possible that none of these groups of substituents are joined to form a ring.

According to an embodiment of the present disclosure, the first compound has a structure represented by Formula 1′:

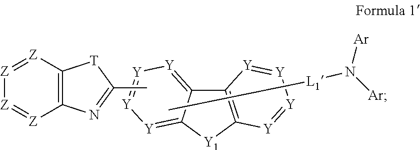

wherein Ar is, at each occurrence identically or differently, selected from substituted or unsubstituted aryl having 6 to 30 carbon atoms, substituted or unsubstituted heteroaryl having 3 to 30 carbon atoms or a combination thereof,
Y is, at each occurrence identically or differently, selected from N, C or CR_{y};
L₁′ is selected from a single bond, substituted or unsubstituted arylene having 6 to 30 carbon atoms, substituted or unsubstituted heteroarylene having 3 to 30 carbon atoms or a combination thereof;
T is selected from O, S or Se;
Z is, at each occurrence identically or differently, selected from N or CR_{z};
Y₁ is selected from O, S, Se, CR_{y1}R_{y1}, SiR_{y1}R_{y1} or NRₙ;
R_{z}, R_{y}, R_{y1} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring;
adjacent substituents R_{y} can be optionally joined to form a ring; and
adjacent substituents R_{y1} can be optionally joined to form a ring.

In this embodiment, in Formula 1′, at least two Y are selected from C and joined to

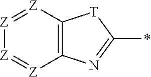

and L₁′, respectively.

In the present disclosure, the expressions that “adjacent substituents R_{z} can be optionally joined to form a ring”, that “adjacent substituents R_{y} can be optionally joined to form a ring” and that “adjacent substituents R_{y1} can be optionally joined to form a ring” are intended to mean that one or more of groups of two adjacent substituents R_{z}, two adjacent substituents R_{y}, and two adjacent substituents R_{y1} can be optionally joined to form a ring. Obviously, it is also possible that none of these groups of substituents are joined to form a ring.

According to an embodiment of the present disclosure, the first compound has a structure represented by one of Formula 1-1 to Formula 1-6:

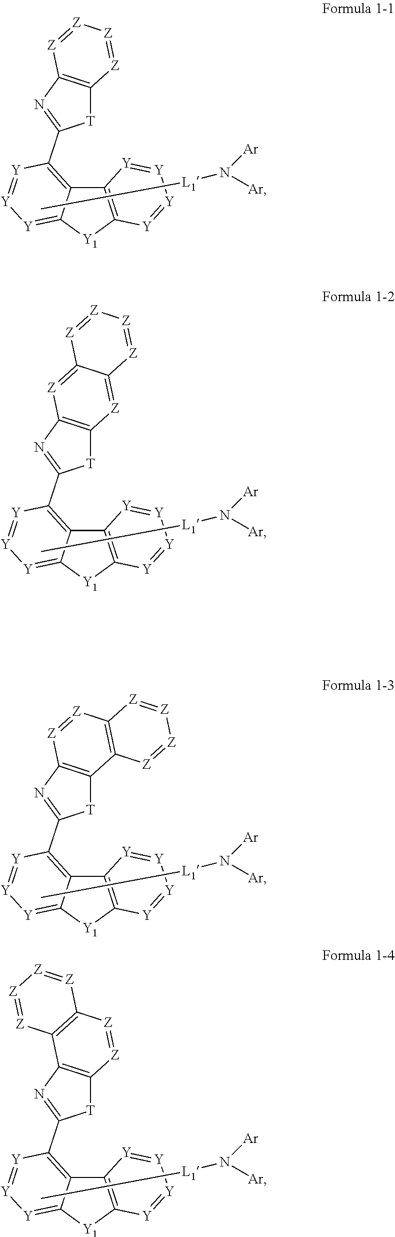

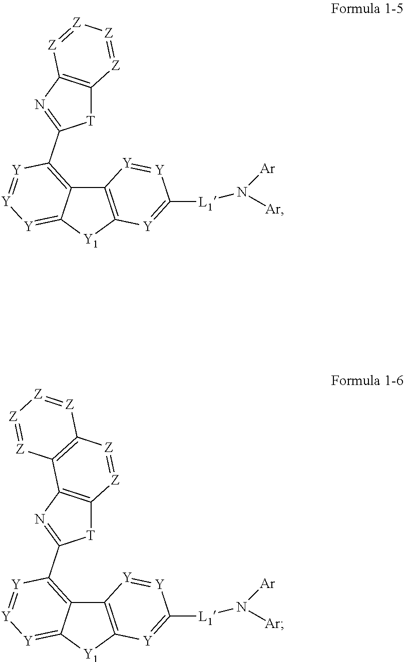

wherein Ar is, at each occurrence identically or differently, selected from substituted or unsubstituted aryl having 6 to 30 carbon atoms, substituted or unsubstituted heteroaryl having 3 to 30 carbon atoms or a combination thereof,
Y is, at each occurrence identically or differently, selected from N, C or CR_{y}, and at least one Y is selected from C and joined to L₁′;
L₁′ is selected from a single bond, substituted or unsubstituted arylene having 6 to 30 carbon atoms, substituted or unsubstituted heteroarylene having 3 to 30 carbon atoms or a combination thereof;
T is selected from O, S or Se;
Z is, at each occurrence identically or differently, selected from N or CR_{z};
Y₁ is selected from O, S, Se, CR_{y1}R_{y1}, SiR_{y1}R_{y1} or NRₙ;
R_{z}, R_{y}, R_{y1} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring;
adjacent substituents R_{y} can be optionally joined to form a ring; and
adjacent substituents R_{y} can be optionally joined to form a ring.

According to an embodiment of the present disclosure, the first compound has a structure represented by one of Formula 1-2 to Formula 1-6.

According to an embodiment of the present disclosure, the first compound has a structure represented by Formula 1-2, Formula 1-4, Formula 1-5 or Formula 1-6.

According to an embodiment of the present disclosure, T is selected from O or S.

According to an embodiment of the present disclosure, T is selected from O.

According to an embodiment of the present disclosure, Y₁ is selected from O, S, CR_{y1}R_{y1} or NRₙ.

According to an embodiment of the present disclosure, Y₁ is selected from O or S.

According to an embodiment of the present disclosure, L₁′ is selected from a single bond, substituted or unsubstituted arylene having 6 to 24 carbon atoms, substituted or unsubstituted heteroarylene having 3 to 24 carbon atoms or a combination thereof.

According to an embodiment of the present disclosure, L₁′ is selected from a single bond, phenylene, naphthylene, biphenylene, phenanthrylene, pyridylene or a combination thereof.

According to an embodiment of the present disclosure, Z is selected from CR_{z}, and Y is selected from C or CR_{y}.

According to an embodiment of the present disclosure, Ar is, at each occurrence identically or differently, selected from substituted or unsubstituted aryl having 6 to 20 carbon atoms, substituted or unsubstituted heteroaryl having 3 to 20 carbon atoms or a combination thereof.

According to an embodiment of the present disclosure, R_{z}, Rₙ, R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyll having 2 to 20 carbon atoms, substituted or unsubstituted aryl having 6 to 30 carbon atoms, substituted or unsubstituted heteroaryl having 3 to 30 carbon atoms and combinations thereof; adjacent substituents R_{z} can be optionally joined to form a ring; and adjacent substituents R_{y1} can be optionally joined to form a ring.

According to an embodiment of the present disclosure, R_{z}, Rₙ, R_{y} and R_{y1} are, at each occurrence identically or differently, selected from the group consisting of: hydrogen, deuterium, fluorine, phenyl, pyridyl, pyrimidinyl, vinyl, naphthyl, biphenyl, phenanthryl, triphenylenyl, dibenzofuryl, dibenzothienyl, carbazolyl, chrysenyl, methyl, ethyl, t-butyl, adamantyl, cyclohexyl, cyclopentyl and combinations thereof.

According to an embodiment of the present disclosure, the first compound is selected from the group consisting of Compound A-1 to Compound A-1378. For specific structures of Compound A-1 to Compound A-1378, see claim 13.

According to an embodiment of the present disclosure, in the mixture, hydrogens in Compound A-1 to Compound A-1378 can be partially or fully substituted with deuterium.

According to an embodiment of the present disclosure, the second compound has a structure represented by Formula 2:

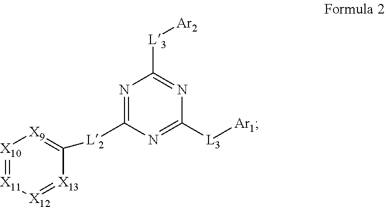

wherein
X₉ to X₁₃ are, at each occurrence identically or differently, selected from CRₓ or N;
L′₂, L₃ and L′₃ are selected from a single bond, substituted or unsubstituted arylene having 6 to 30 carbon atoms, substituted or unsubstituted heteroarylene having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ and Ar₂ are selected from substituted or unsubstituted aryl having 6 to 30 carbon atoms, substituted or unsubstituted heteroaryl having 3 to 30 carbon atoms or a combination thereof; and
adjacent substituents Rₓ can be optionally joined to form a ring.

In this embodiment, the expression that “adjacent substituents Rₓ can be optionally joined to form an aromatic ring” is intended to mean that two adjacent substituents Rₓ can be joined to form a ring. For example, one or more of groups of two adjacent substituents Rₓ in X₉ to X₁₃, including, but not limited to, two adjacent substituents Rₓ in X₉ and X₁₀, two adjacent substituents Rₓ in X₁₀ and X₁₁, two adjacent substituents Rₓ in X₁₁ and X₁₂, and two adjacent substituents Rₓ in X₁₂ and X₁₃, can be optionally joined to form a ring. Obviously, it is also possible that none of these groups of substituents are joined to form a ring.

According to an embodiment of the present disclosure, in Formula 2, at least one of Ar₁ or Ar₂ is selected from the group consisting of: substituted or unsubstituted dibenzofuryl, substituted or unsubstituted dibenzothienyl, substituted or unsubstituted carbazolyl, substituted or unsubstituted silafluorenyl, substituted or unsubstituted fluorenyl, substituted or unsubstituted naphthyl, substituted or unsubstituted chrysenyl and combinations thereof.

According to an embodiment of the present disclosure, the second compound has a structure represented by Formula 2′:

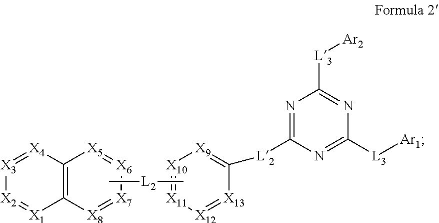

wherein
X₁ to X₄ are, at each occurrence identically or differently, selected from CRₓ or N;
X₅ to X₁₃ are, at each occurrence identically or differently, selected from C, CRₓ or N, at least one of X₅ to X₈ is selected from C and joined to L₂, and at least one of X₉ to X₁₃ is selected from C and joined to L₂;
L₂, L′₂, L₃ and L′₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ can be optionally joined to form a ring.

In this embodiment, the expression that “adjacent substituents Rₓ can be optionally joined to form a ring” is intended to mean that two adjacent substituents Rₓ can be joined to form a ring. For example, one or more of groups of any two adjacent substituents Rₓ in X₁ to X₁₃, including, but not limited to, two adjacent substituents Rₓ in X₁ and X₂, two adjacent substituents R_{y} in X₂ and X₃, two adjacent substituents Rₓ in X₇ and X₈, two adjacent substituents Rₓ in X₁₀ and X₁₁, and two adjacent substituents Rₓ in X₉ and X₁₀, can be optionally joined to form a ring. Obviously, it is also possible that none of these groups of substituents are joined to form a ring.

According to an embodiment of the present disclosure, L₂, L′₂, L₃ and L′₃ are, at each occurrence identically or differently, selected from a single bond, substituted or unsubstituted arylene having 6 to 20 carbon atoms, substituted or unsubstituted heteroarylene having 3 to 20 carbon atoms or a combination thereof.

According to an embodiment of the present disclosure, L₂, L′₂, L₃ and L′₃ are, at each occurrence identically or differently, selected from a single bond or substituted or unsubstituted arylene having 6 to 20 carbon atoms.

According to an embodiment of the present disclosure, L₂, L′₂, L₃ and L′₃ are, at each occurrence identically or differently, selected from a single bond or substituted or unsubstituted arylene having 6 to 12 carbon atoms.

According to an embodiment of the present disclosure, at least one of L₂ or L′₂ is selected from a single bond.

According to an embodiment of the present disclosure, at least one of L₃ or L′₃ is selected from a single bond.

According to an embodiment of the present disclosure, L₂ and L′₂ are each selected from a single bond, and L₃ and L′₃ are, at each occurrence identically or differently, selected from a single bond or substituted or unsubstituted arylene having 6 to 12 carbon atoms.

According to an embodiment of the present disclosure, L₂, L′₂, La and L′₃ are, at each occurrence identically or differently, selected from a single bond, substituted or unsubstituted phenylene, substituted or unsubstituted naphthylene, substituted or unsubstituted biphenylene, substituted or unsubstituted phenanthrylene, substituted or unsubstituted triphenylenylene, substituted or unsubstituted 9,9-dimethylfluorenylene, substituted or unsubstituted terphenylene, substituted or unsubstituted chrysenylene or a combination thereof.

According to an embodiment of the present disclosure, X₁ to X₄ are, at each occurrence identically or differently, selected from CRₓ; and X₅ to X₁₃ are, at each occurrence identically or differently, selected from C or CRₓ, X₆ or X₇ is selected from C and joined to L₂, and X₁₁ is selected from C and joined to L₂.

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, at least one Rₓ is selected from deuterium.

According to an embodiment of the present disclosure, Rₓ is, at each occurrence identically or differently, selected from the group consisting of: hydrogen, deuterium, halogen, phenyl, pyridyl, vinyl, adamantyl, methyl, ethyl, isopropyl, cyclopropanyl, naphthyl, biphenyl, phenanthryl, triphenylenyl, t-butyl, trifluoromethyl, 9,9-dimethylfluorenyl, terphenyl, dibenzothienyl, dibenzofuryl, benzothiazolyl, benzoxazolyl, phenanthroxazolyl, phenanthrothiazolyl, chrysenyl and combinations thereof.

According to an embodiment of the present disclosure, Ar₁ and Ar₂ have, at each occurrence identically or differently, a structure represented by any one or a combination of Formula Ar-1 to Formula Ar-6:

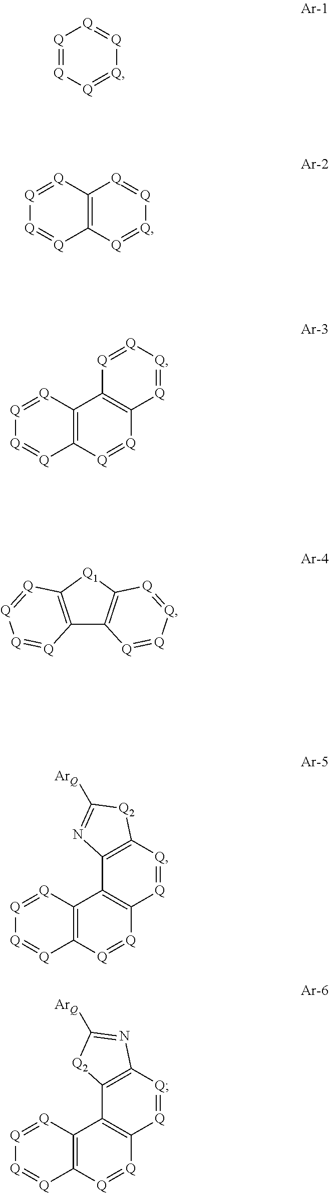

wherein
Ar_{Q} is, at each occurrence identically or differently, selected from substituted or unsubstituted aryl having 6 to 30 carbon atoms, substituted or unsubstituted heteroaryl having 3 to 30 carbon atoms or a combination thereof,
Q is, at each occurrence identically or differently, selected from C, CR_{Q} or N, and at least one Q is selected from C and joined to L₃ or L′₃;
Q₁ is selected from O, S, Se, NR_{Q} or CR_{Q}R_{Q};
Q₂ is selected from O, S or Se;
R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{Q} can be optionally joined to form a ring.

In this embodiment, the expression that “adjacent substituents R_{Q} can be optionally joined to form a ring” is intended to mean that two adjacent substituents R_{Q} can be joined to form a ring. For example, one or more of groups of substituents, including two adjacent substituents R_{Q} on the groups Q in Formula Ar-1 to Formula Ar-3 and Formula Ar-5 to Formula Ar-6 and two adjacent substituents R_{Q} on the groups Q and two adjacent substituents R_{Q} on the groups Q and Q₁ in Formula Ar-4, can be optionally joined to form a ring. Obviously, it is also possible that none of these groups of substituents are joined to form a ring.

According to an embodiment of the present disclosure, Ar₁ and Ar₂ have, at each occurrence identically or differently, a structure represented by any one of Formula Ar-1, Formula Ar-2 or Formula Ar-4.

According to an embodiment of the present disclosure, L₃ and L′₃ are, at each occurrence identically or differently, selected from a single bond or substituted or unsubstituted phenylene; and Ar₁ and Ar₂ have, at each occurrence identically or differently, a structure represented by Formula Ar-1 or Formula Ar-4.

According to an embodiment of the present disclosure, -L₃-Ar₁ and -L′₃-Ar₂ have, at each occurrence identically or differently, a structure represented by any one of Formula X-1, Formula X-2, Formula X-3 or Formula X-4:

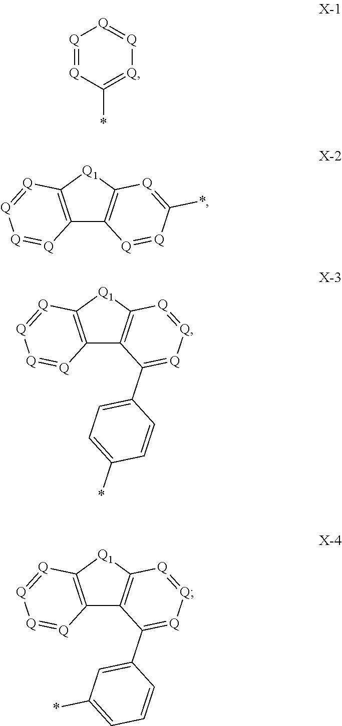

wherein
Q₁ is selected from O, S, Se, NR_{Q} or CR_{Q}R_{Q};
Q is, at each occurrence identically or differently, selected from CR_{Q} or N; and
R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

In this embodiment, * represents a position where Formula X-1, Formula X-2, Formula X-3 or Formula X-4 is joined to a triazine group in Formula 2.

According to an embodiment of the present disclosure, Q is, at each occurrence identically or differently, selected from CR_{Q}; Q₁ is selected from O, S or CR_{Q}R_{Q}; and Q₂ is selected from O or S.

According to an embodiment of the present disclosure, R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R_{Q} is, at each occurrence identically or differently, selected from the group consisting of: hydrogen, deuterium, halogen, phenyl, pyridyl, vinyl, adamantyl, methyl, ethyl, isopropyl, cyclopropanyl, naphthyl, biphenyl, phenanthryl, triphenylenyl, t-butyl, trifluoromethyl, 9,9-dimethylfluorenyl, terphenyl, dibenzothienyl, dibenzofuryl, benzothiazolyl, benzoxazolyl, phenanthroxazolyl, phenanthrothiazolyl, chrysenyl and combinations thereof.

According to an embodiment of the present disclosure, Ar_{Q} is selected from phenyl, naphthyl, biphenyl, pyridyl, phenanthryl, 9,9-dimethylfluorenyl, terphenyl, dibenzothienyl, dibenzofuryl, benzothiazolyl, benzoxazolyl, phenanthroxazolyl, phenanthrothiazolyl, chrysenyl or a combination thereof.

According to an embodiment of the present disclosure, the second compound is selected from the group consisting of Compound B-1 to Compound B-223. For specific structures of Compound B-1 to Compound B-223, see claim 20.

According to an embodiment of the present disclosure, hydrogens in the structures of Compound B-1 to Compound B-223 can be partially or fully substituted with deuterium.

According to an embodiment of the present disclosure, the third compound has a structure represented by one of Formula 1, Formula 1′, and Formula 1-1 to Formula 1-6.

According to an embodiment of the present disclosure, the third compound has a structure represented by Formula 2 or Formula 24.

According to an embodiment of the present disclosure, the third compound is an isomer or isotopologue of the first compound or the second compound.

In the present disclosure, the “isotopologue” includes, but is not limited to, the following two cases: when hydrogen in the structure of Compound X is substituted with deuterium to form a compound referred to as Compound X′, Compound X′ and Compound X are isotopologues of each other, and Compound X′ and Compound Z (an isomer of Compound X) are isotopologues of each other. For example, Compound B-2

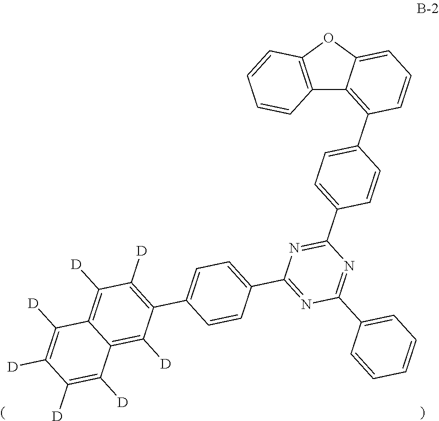 [SMILES: [2H]c1c([2H])c([2H])c2c([2H])c(-c3ccc(-c4nc(-c5ccccc5)nc(-c5ccc(-c6cccc7oc8ccccc8c67)cc5)n4)cc3)c([2H])c([2H])c2c1[2H]]

### and Compound B-1

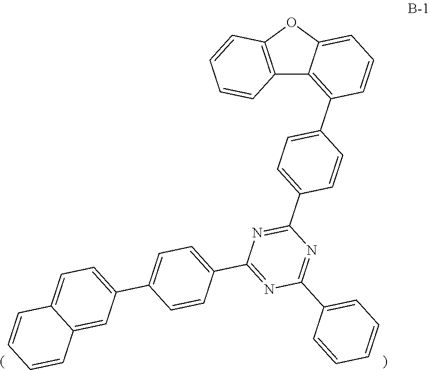 [SMILES: c1ccc(-c2nc(-c3ccc(-c4ccc5ccccc5c4)cc3)nc(-c3ccc(-c4cccc5oc6ccccc6c45)cc3)n2)cc1]

are isotopologues of each other, and Compound B-2

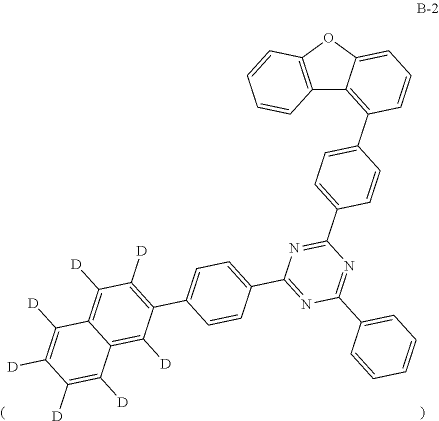 [SMILES: [2H]c1c([2H])c([2H])c2c([2H])c(-c3ccc(-c4nc(-c5ccccc5)nc(-c5ccc(-c6cccc7oc8ccccc8c67)cc5)n4)cc3)c([2H])c([2H])c2c1[2H]]

and Compound B-4

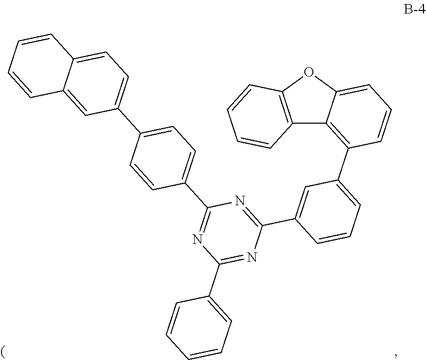 [SMILES: c1ccc(-c2nc(-c3ccc(-c4ccc5ccccc5c4)cc3)nc(-c3cccc(-c4cccc5oc6ccccc6c45)c3)n2)cc1]

an isomer of Compound B-1) are also isotopologues of each other.

According to an embodiment of the present disclosure, the third compound has a structure represented by Formula 1, and the third compound and the first compound are isomers or isotopologues of each other.

According to an embodiment of the present disclosure, the third compound has a structure represented by Formula 2, and the third compound and the second compound are isomers or isotopologues of each other.

According to an embodiment of the present disclosure, the deuteration rate of at least one of the first compound, the second compound or the third compound is 5% to 100%.

According to an embodiment of the present disclosure, the deuteration rate of at least one of the first compound, the second compound or the third compound is 30% to 100%.

According to an embodiment of the present disclosure, the deuteration rate of at least one of the first compound, the second compound or the third compound is 50% to 100%.

According to an embodiment of the present disclosure, the deuteration rate of at least one of the first compound, the second compound or the third compound is 60% to 100%.

In this embodiment, the “deuteration rate of a compound” refers to a percentage of the number of deuterium atoms to the total number of hydrogen and deuterium atoms in the structure of the first compound, the second compound or the third compound.

In the present disclosure, “a certain distance” and “a certain thickness” described in the film formation process of the evaporated mixture can be adaptively adjusted by those skilled in the art according to actual requirements to achieve the purpose of evaporation. The certain distance may be, for example and without limitation, 10-100 cm, 30-80 cm, or 35-60 cm. Similarly, the certain thickness may be, for example and without limitation, 100-10000 Å, 200-8000 Å, or 400-5000 Å.

According to an embodiment of the present disclosure, the mass ratio of the first compound, the second compound and the third compound in the mixture is 0.1-99.9:0.1-99.9:0.1-99.9.

According to an embodiment of the present disclosure, the mass ratio of the first compound, the second compound and the third compound in the mixture is 1-99:1-99:1-99.

According to an embodiment of the present disclosure, the mass ratio of the first compound, the second compound and the third compound in the mixture is 10-90:10-90:10-90.

According to an embodiment of the present disclosure, when the third compound is selected from the hole transport-type compound, the mass ratio of the first compound, the second compound and the third compound in the mixture is 50-80:1-40:1-30.

According to an embodiment of the present disclosure, when the third compound is selected from the electron transport-type compound, the mass ratio of the first compound, the second compound and the third compound in the mixture is 50-80:1-30:1-30.

According to an embodiment of the present disclosure, an electroluminescent device is further disclosed. The electroluminescent device comprises a first electrode, a second electrode and an organic layer disposed between the first electrode and the second electrode, wherein the organic layer comprises at least the mixture of any one of the preceding embodiments.

According to an embodiment of the present disclosure, in the electroluminescent device, the first electrode is an anode and the second electrode is a cathode.

According to another embodiment of the present disclosure, a compound composition is further disclosed. The compound composition comprises a first compound represented by Formula 1, a second compound represented by Formula 2 and a third compound represented by Formula 1 or Formula 2, wherein the first compound, the second compound and the third compound have structures different from each other;

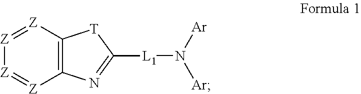

wherein
Ar is, at each occurrence identically or differently, selected from substituted or unsubstituted aryl having 6 to 30 carbon atoms, substituted or unsubstituted heteroaryl having 3 to 30 carbon atoms or a combination thereof;
L₁ is selected from a single bond, substituted or unsubstituted arylene having 6 to 30 carbon atoms, substituted or unsubstituted heteroarylene having 3 to 30 carbon atoms or a combination thereof;
Z is, at each occurrence identically or differently, selected from N or CR_{z}; and
T is selected from O, S or Se;

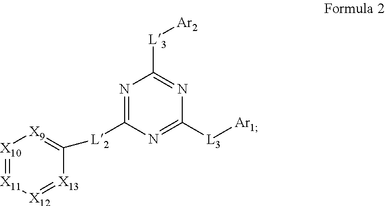

wherein
X₉ to X₁₃ are, at each occurrence identically or differently, selected from CRₓ or N;
L′₂, L₃ and L′₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are selected from substituted or unsubstituted aryl having 6 to 30 carbon atoms, substituted or unsubstituted heteroaryl having 3 to 30 carbon atoms or a combination thereof;
R_{z} and Rₓ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring; and
adjacent substituents Rₓ can be optionally joined to form a ring.

According to an embodiment of the present disclosure, an electroluminescent device is further disclosed. The electroluminescent device comprises a first electrode, a second electrode and an organic layer disposed between the first electrode and the second electrode, wherein the organic layer comprises at least the compound composition of the preceding embodiment.

According to an embodiment of the present disclosure, in the electroluminescent device, the organic layer is an emissive layer, and the mixture is a host material.

According to an embodiment of the present disclosure, in the electroluminescent device, the organic layer is an emissive layer, and the compound composition is a host material.

According to an embodiment of the present disclosure, in the electroluminescent device, the organic layer is the emissive layer, and the emissive layer further comprises at least one phosphorescent material.

According to an embodiment of the present disclosure, the electroluminescent device emits red light or white light.

According to an embodiment of the present disclosure, in the electroluminescent device, the organic layer is the emissive layer, the emissive layer further comprises at least one phosphorescent material, and a maximum emission wavelength of the phosphorescent material is greater than or equal to 580 nm.

According to an embodiment of the present disclosure, in the electroluminescent device, the organic layer is the emissive layer, the emissive layer further comprises at least one phosphorescent material, and the maximum emission wavelength of the phosphorescent material is 600 nm to 900 nm.

According to an embodiment of the present disclosure, the phosphorescent material is a metal complex having a general formula of M(Lₐ)ᵤ(L_{b})ᵥ(L_{c})_{q};
M is selected from a metal with a relative atomic mass greater than 40;
Lₐ, L_{b} and L_{c} are a first ligand, a second ligand and a third ligand coordinated to M, respectively; Lₐ, L_{b} and L_{c} can be optionally joined to form a multidentate ligand;
Lₐ, L_{b} and L_{c} may be identical or different; u is 1, 2 or 3, v is 0, 1 or 2, q is 0, 1 or 2, and u+v+q equals the oxidation state of M; when u is greater than or equal to 2, multiple Lₐ may be identical or different; when v is 2, two L_{b} may be identical or different; when q is 2, two L_{c} may be identical or different;
Lₐ has a structure represented by Formula 3:

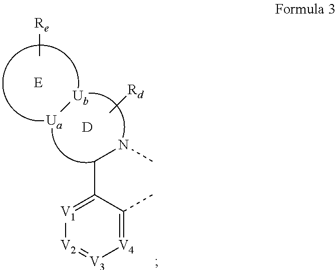

wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and R_{c} represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ and Rᵥ can be optionally joined to form a ring;
L_{b} and L_{c} are, at each occurrence identically or differently, selected from any one of the following structures:

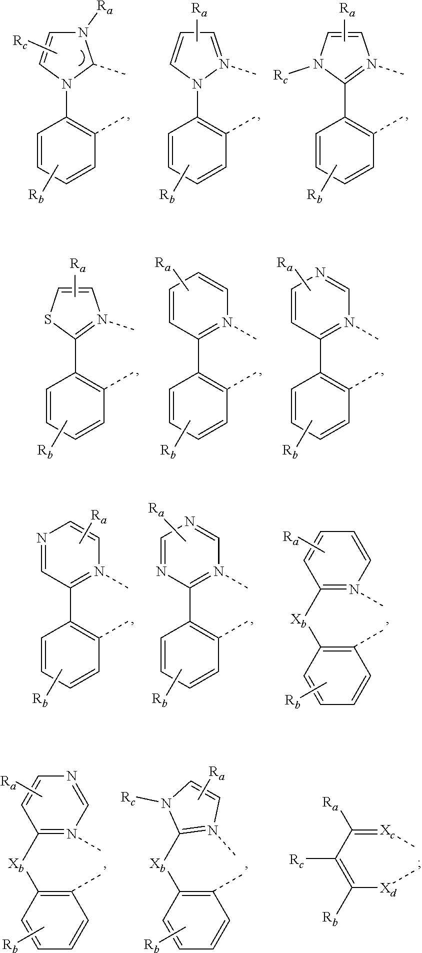

wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in the structures of the ligands L_{b} and L_{c}, adjacent substituents Rₐ, R_{b}, R_{c}, R_{N1}, R_{N2}, R_{C1} and R_{C2} can be optionally joined to form a ring.

In the present disclosure, the expression that “adjacent substituents R_{d}, Rₑ and Rᵥ can be optionally joined to form a ring” is intended to mean that in the presence of substituents Rd, Rₑ and Rᵥ, any one or more of groups of adjacent substituents, such as adjacent substituents Rd, adjacent substituents Rₑ, adjacent substituents Rᵥ, adjacent substituents R_{d} and R_{c}, adjacent substituents R_{d} and Rᵥ, and adjacent substituents Rₑ and Rᵥ, can be joined to form a ring. Obviously, in the presence of the substituents R_{d}, Rₑ and Rᵥ, it is also possible that none of these groups of substituents are joined to form a ring.

In the present disclosure, the expression that “adjacent substituents Rₐ, R_{b}, R_{c}, R_{N1}, R_{N2}, R_{C1} and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{b}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

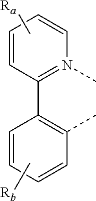

can be optionally joined to form a ring, which can form one or more of the following structures including, but not limited to,

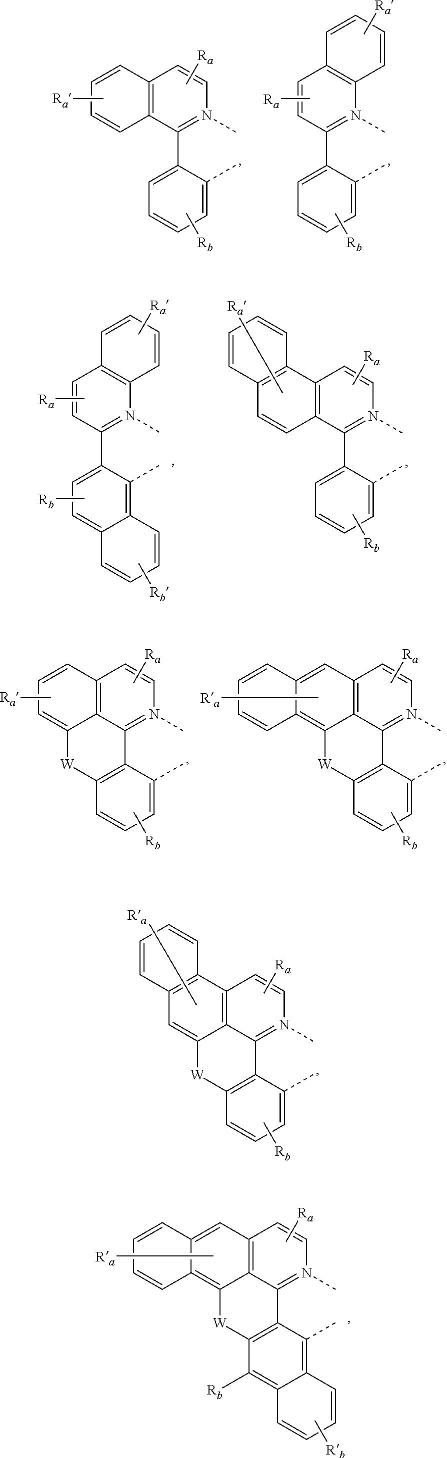

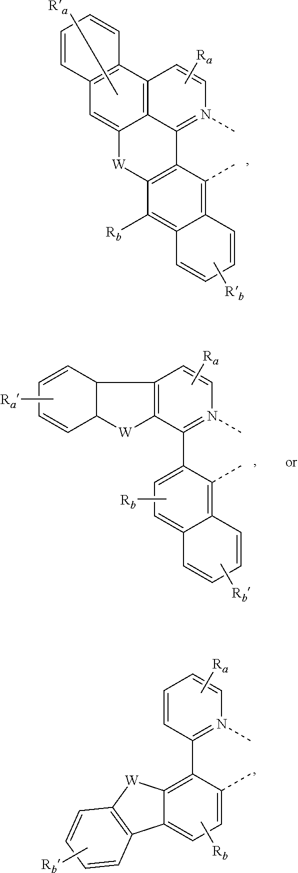

wherein W is selected from O, S, Se, NR′ or CR′R′, and R′, Rₐ′ and R_{b}′ are defined the same as Rₐ. Obviously, it is also possible that none of these substituents are joined to form a ring.

According to an embodiment of the present disclosure, in Formula 3, two adjacent substituents Rₑ are joined to form a ring.

According to an embodiment of the present disclosure, in Formula 3, two adjacent substituents Rₑ are joined to form a five-membered unsaturated carbocyclic ring, a five-membered heteroaromatic ring or a benzene ring.

According to an embodiment of the present disclosure, in Formula 3, the ring D is a six-membered heteroaromatic ring, and the ring E is a benzene ring or a six-membered heteroaromatic ring.

According to an embodiment of the present disclosure, in Formula 3, the ring D is a six-membered heteroaromatic ring, and the ring E is a five-membered heteroaromatic ring or a five-membered unsaturated carbocyclic ring.

According to an embodiment of the present disclosure, in Formula 3, the ring D is a six-membered heteroaromatic ring, the ring E is a benzene ring or a six-membered heteroaromatic ring, and two adjacent substituents Rₑ are joined to form a benzene ring or a six-membered heteroaromatic ring.

According to an embodiment of the present disclosure, in Formula 3, the ring D is a six-membered heteroaromatic ring, the ring E is a five-membered heteroaromatic ring or a five-membered unsaturated carbocyclic ring, and two adjacent substituents Rₑ are joined to form a benzene ring or a six-membered heteroaromatic ring.

According to an embodiment of the present disclosure, in Formula 3, at least one or two of groups of adjacent substituents R_{d}, Rₑ and Rᵥ are joined to form a ring. For example, two substituents R_{d} are joined to form a ring, two substituents Rₑ are joined to form a ring, two substituents Rᵥ are joined to form a ring, substituents R_{d} and Rₑ are joined to form a ring, substituents R_{d} and Rᵥ are joined to form a ring, substituents Rₑ and Rᵥ are joined to form a ring, two substituents Rₑ are joined to form a ring while two substituents R_{d} are joined to form a ring, two substituents Rᵥ are joined to form a ring while two substituents R_{d} are joined to form a ring, two substituents Rᵥ are joined to form a ring while two substituents Rₑ are joined to form a ring, two substituents Rᵥ are joined to form a ring while substituents Rₑ and Rᵥ are joined to form a ring, or two substituents Rᵥ are joined to form a ring while substituents R_{d} and Rᵥ are joined to form a ring; more groups of adjacent substituents R_{d}, Rₑ and Rᵥ are joined to form a ring similarly.

According to an embodiment of the present disclosure, in the electroluminescent device, the phosphorescent material is a metal complex having a general formula of M(Lₐ)ᵤ(L_{b})ᵥ;
M is selected from a metal with a relative atomic mass greater than 40;
Lₐ and L; are a first ligand and a second ligand coordinated to M, respectively; Lₐ and L_{b} can be optionally joined to form a multidentate ligand;
u is 1, 2 or 3, v is 0, 1 or 2, and u+v equals the oxidation state of M; when u is greater than or equal to 2, multiple Lₐ may be identical or different; when v is 2, two Lₐ may be identical or different;
Lₐ has a structure represented by Formula 3:

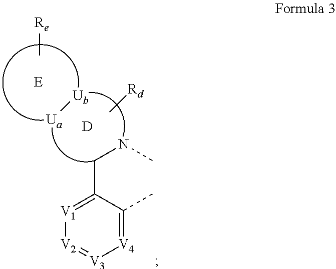

wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and Rₑ represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ and Rᵥ can be optionally joined to form a ring;
the ligand L_{b} has the following structure:

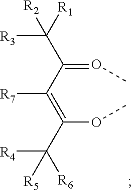

wherein R₁ to R₇ are each independently selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, in the electroluminescent device, the ligand L_{b} has the following structure:

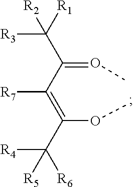

wherein at least one of R₁ to R₃ is selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one of R₄ to R₆ is selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, in the electroluminescent device, the ligand L_{b} has the following structure:

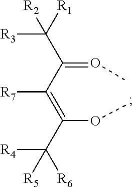

wherein at least two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof.

According to an embodiment of the present disclosure, in the electroluminescent device, the ligand L_{b} has the following structure:

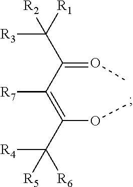

wherein at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

According to an embodiment of the present disclosure, in the electroluminescent device, the phosphorescent material is an Ir complex, a Pt complex or an Os complex.

According to an embodiment of the present disclosure, in the electroluminescent device, the phosphorescent material is an Ir complex having a structure represented by any one of Ir(Lₐ)(L_{b})(L_{c}), Ir(Lₐ)₂(L_{b}), Ir(Lₐ)(L_{b})₂, Ir(Lₐ)₂(L_{c}) or Ir(Lₐ)(L_{c})₂.

According to an embodiment of the present disclosure, Lₐ has a structure represented by Formula 3 and comprises at least one structural unit selected from the group consisting of an aromatic ring formed by fusing a six-membered ring to a six-membered ring, a heteroaromatic ring formed by fusing a six-membered ring to a six-membered ring, an aromatic ring formed by fusing a six-membered ring to a five-membered ring and a heteroaromatic ring formed by fusing a six-membered ring to a five-membered ring.

According to an embodiment of the present disclosure, in the electroluminescent device, Lₐ has a structure represented by Formula 3 and comprises at least one structural unit selected from the group consisting of naphthalene, phenanthrene, quinoline, isoquinoline and azaphenanthrene.

According to an embodiment of the present disclosure, in the organic electroluminescent device, the phosphorescent material is an Ir complex comprising the ligand Lₐ, wherein Lₐ is, at each occurrence identically or differently, selected from any one of the group consisting of the following structures:

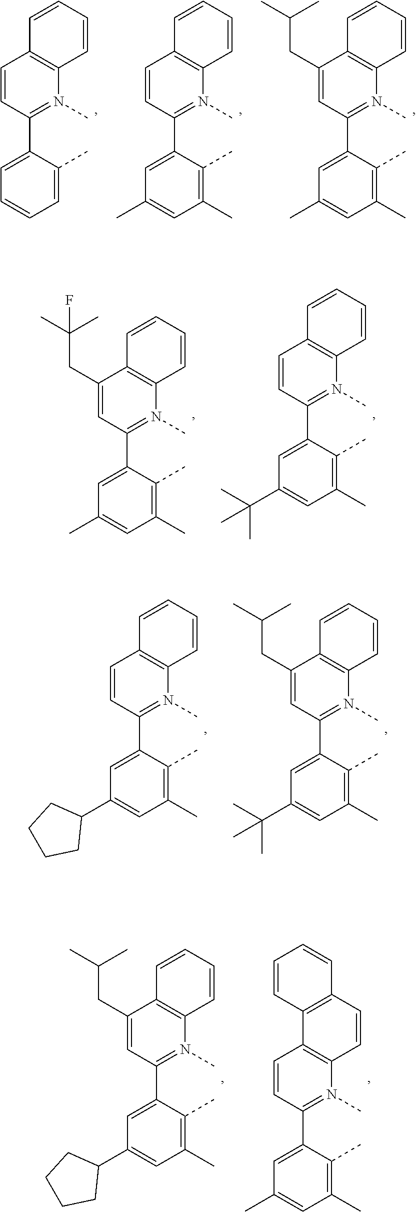

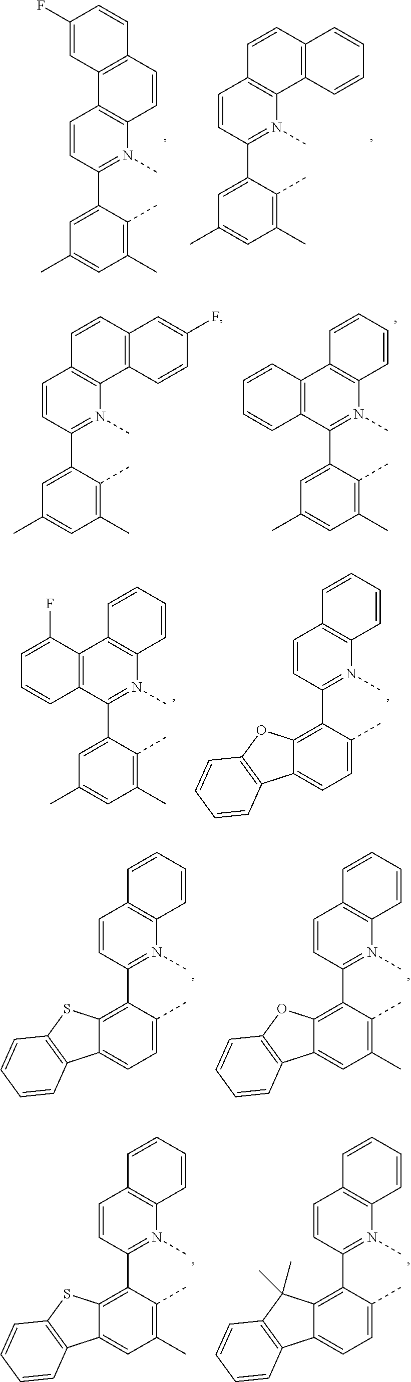

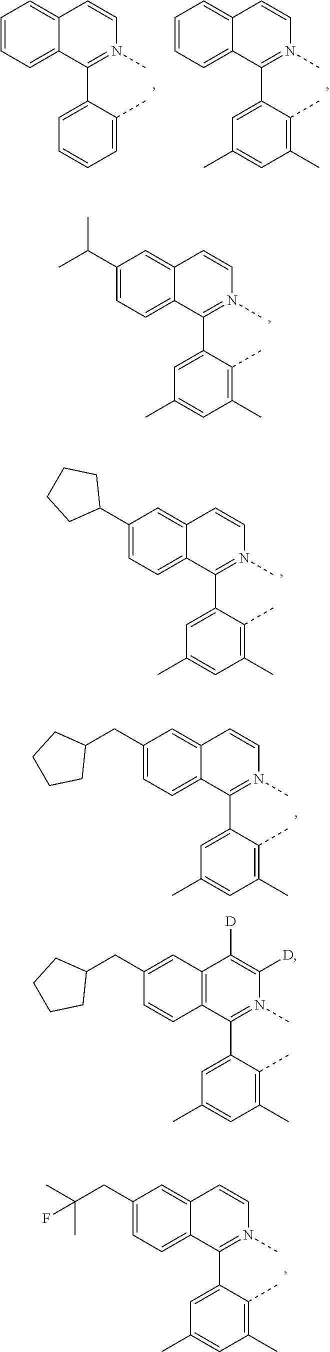

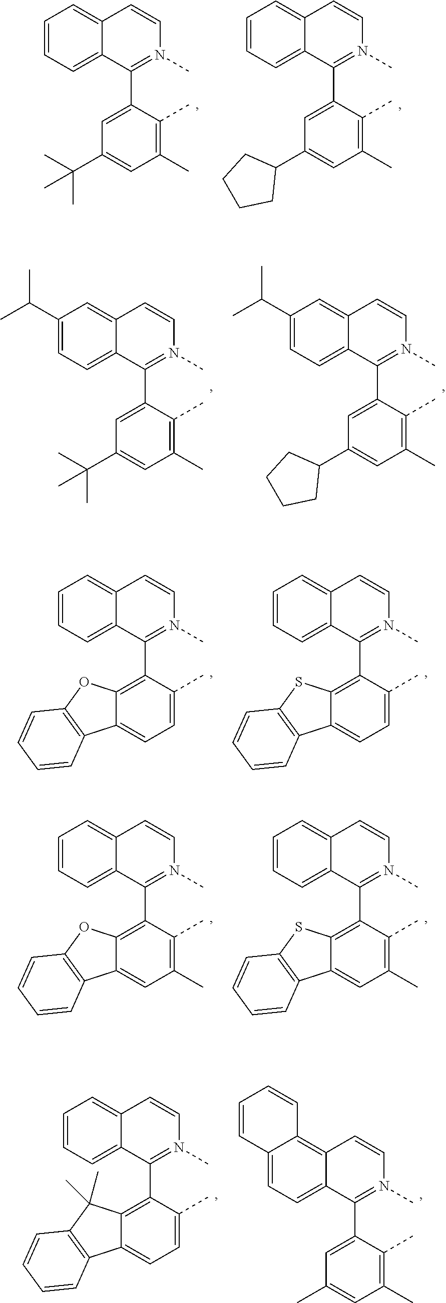

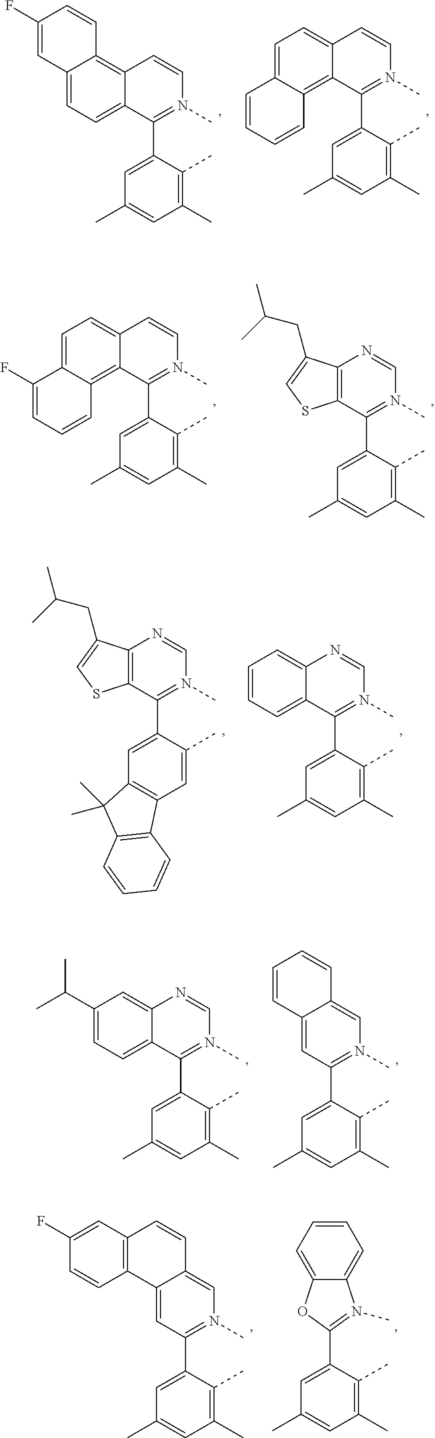

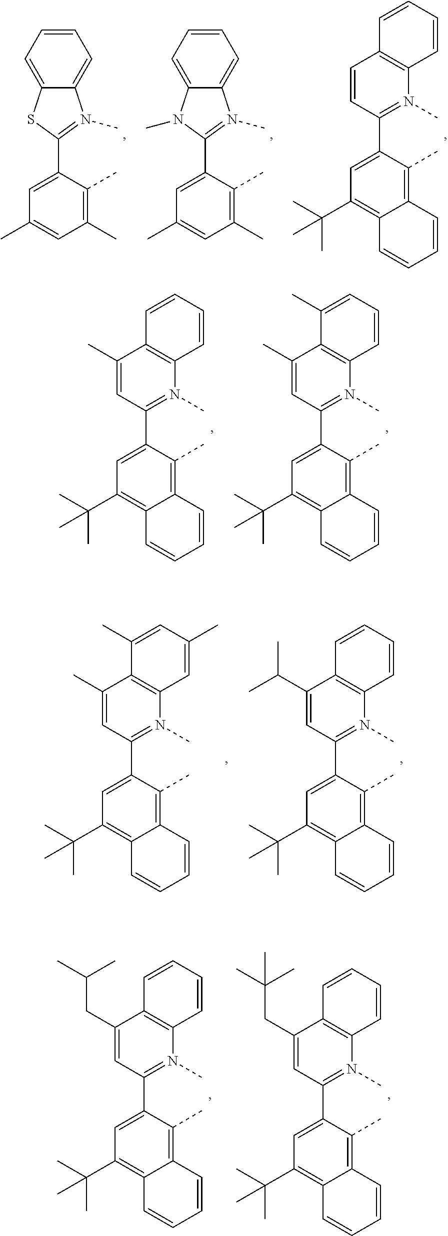

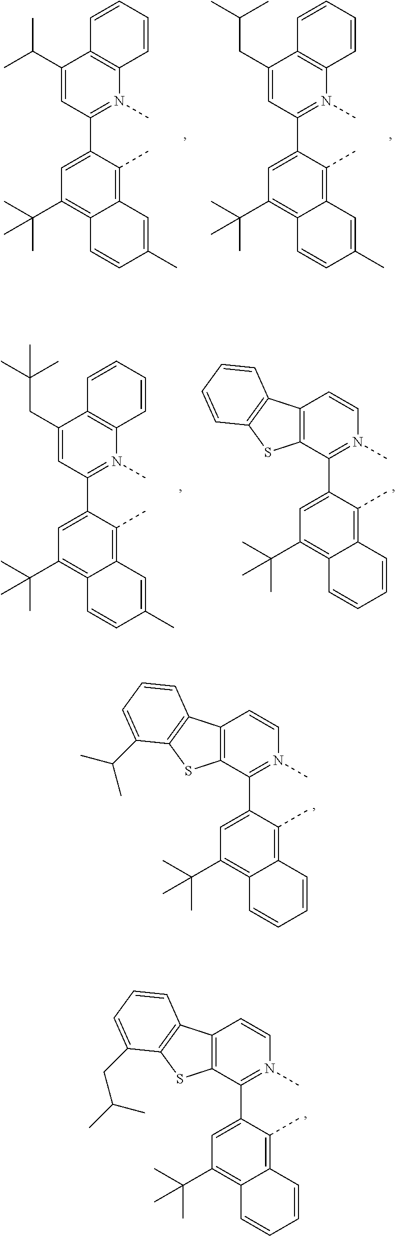

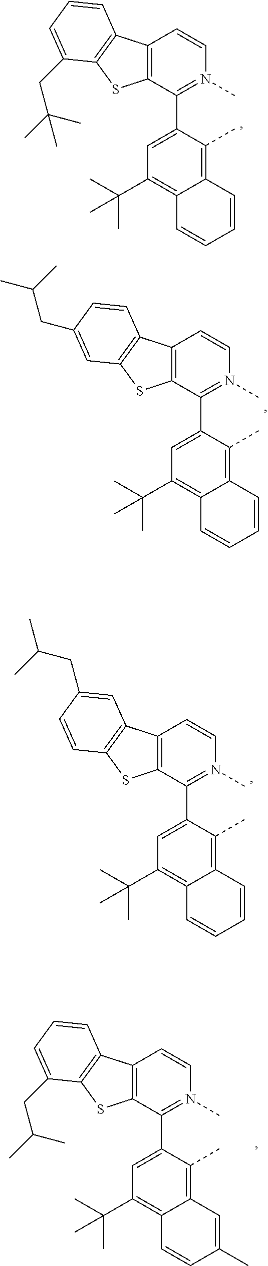

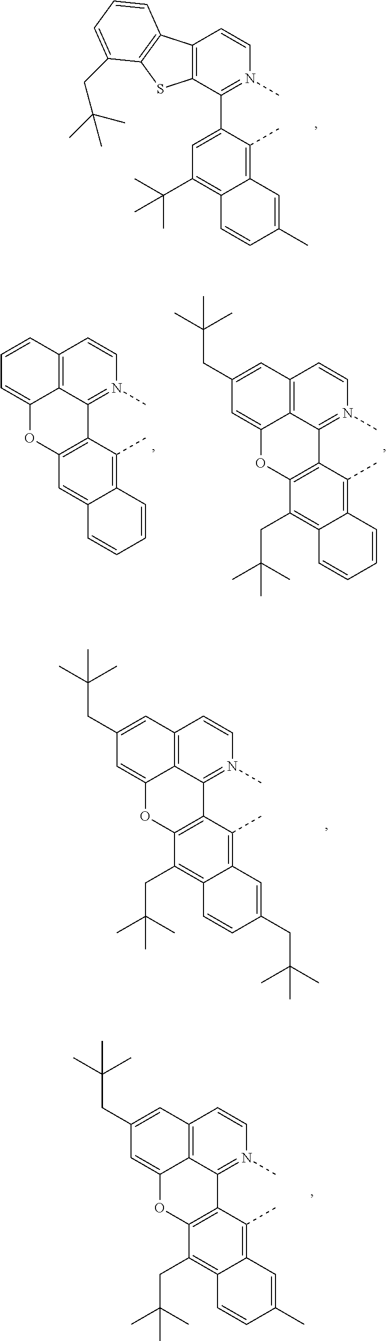

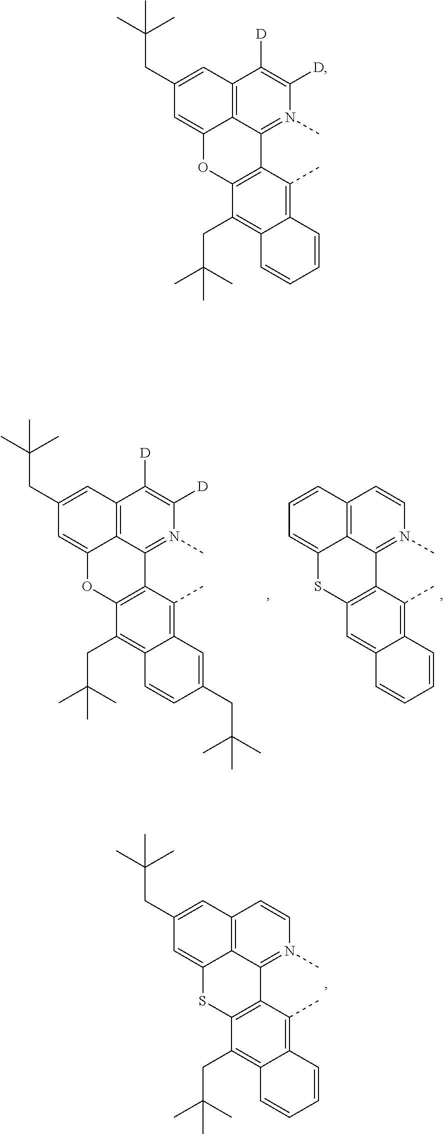

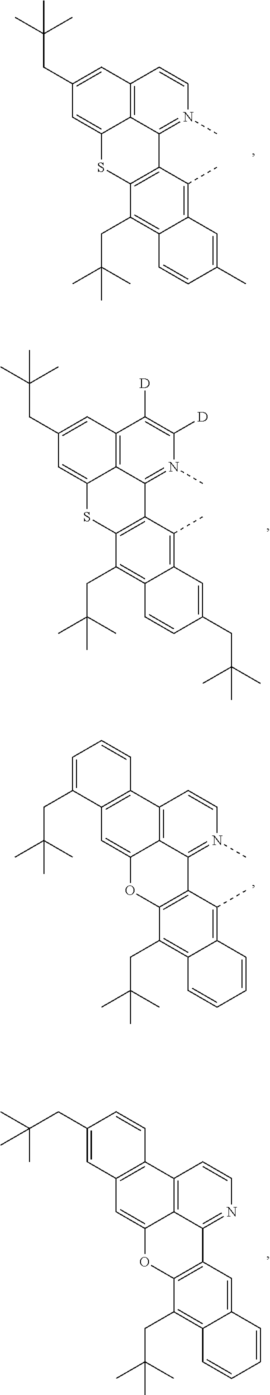

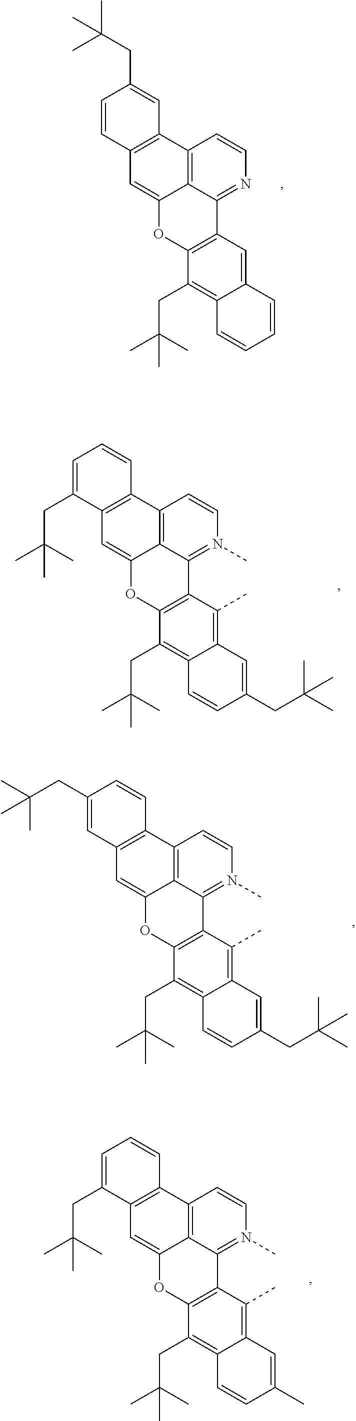

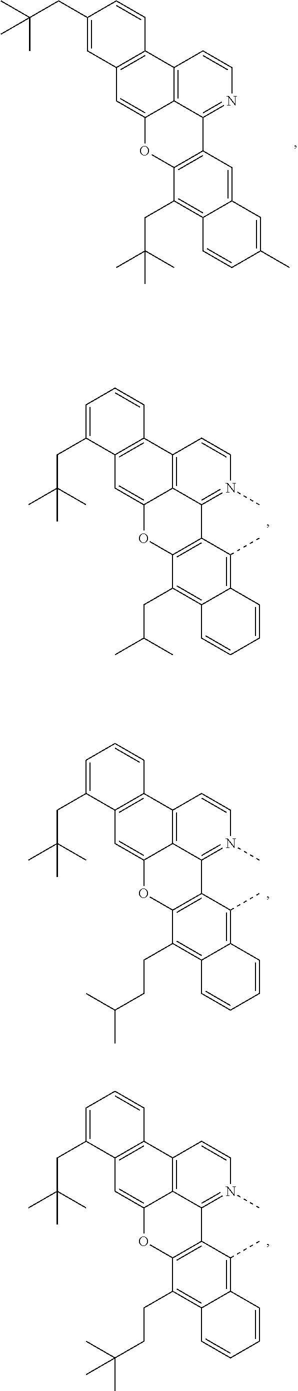

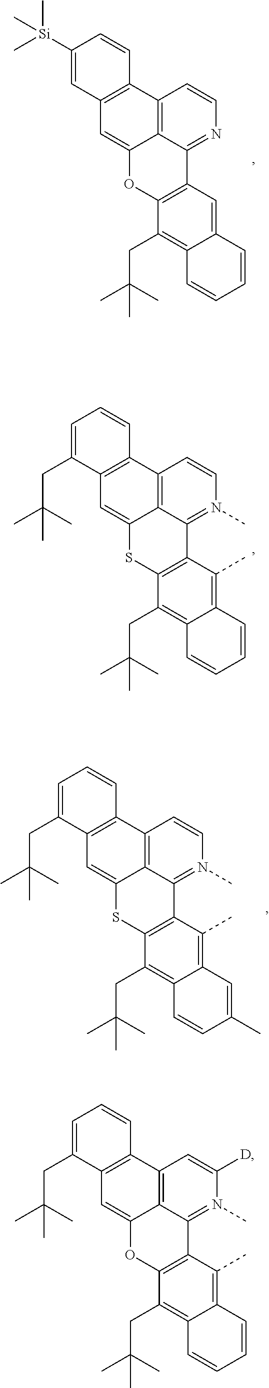

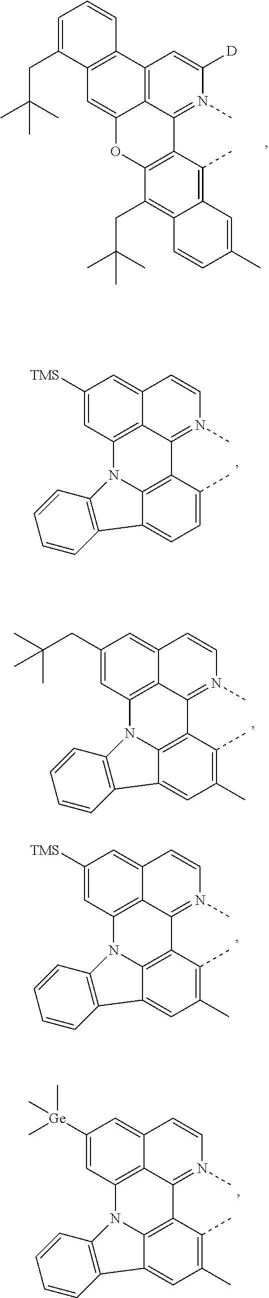

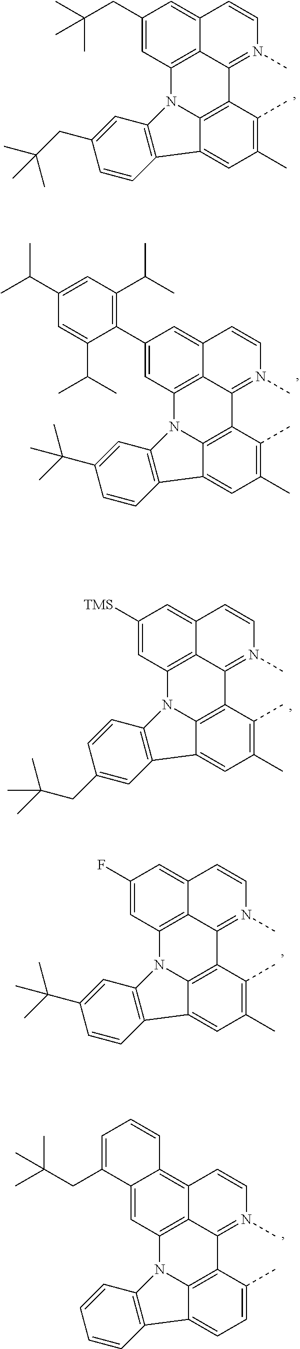

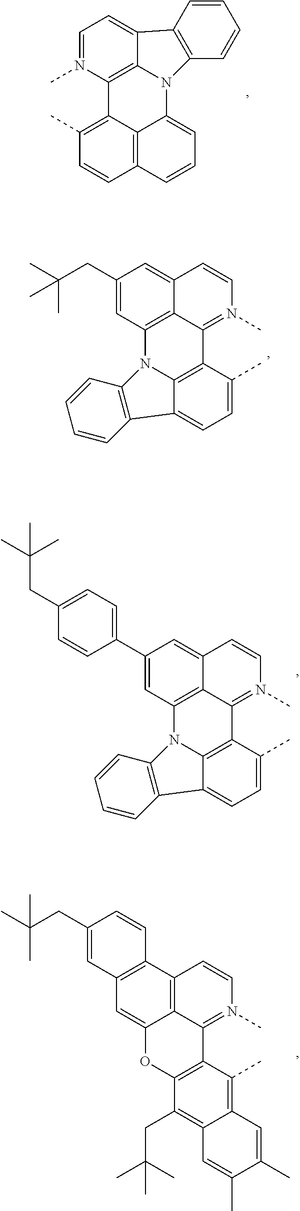

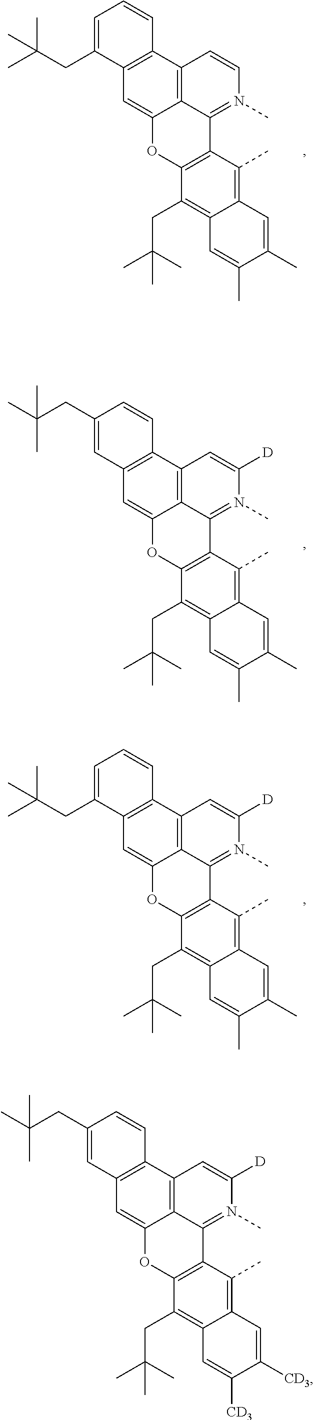

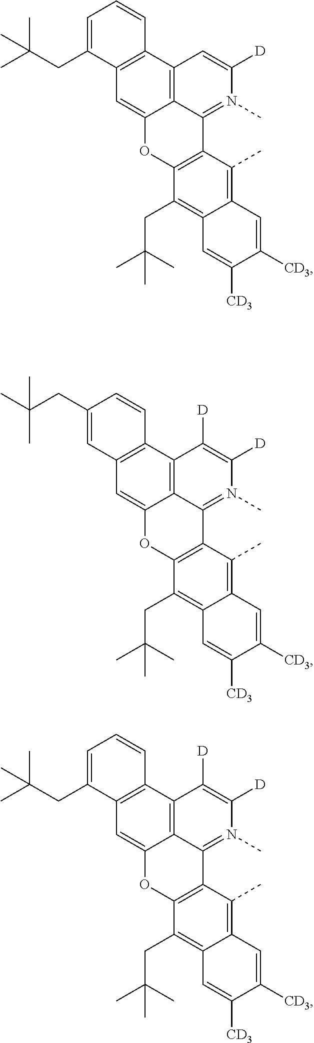

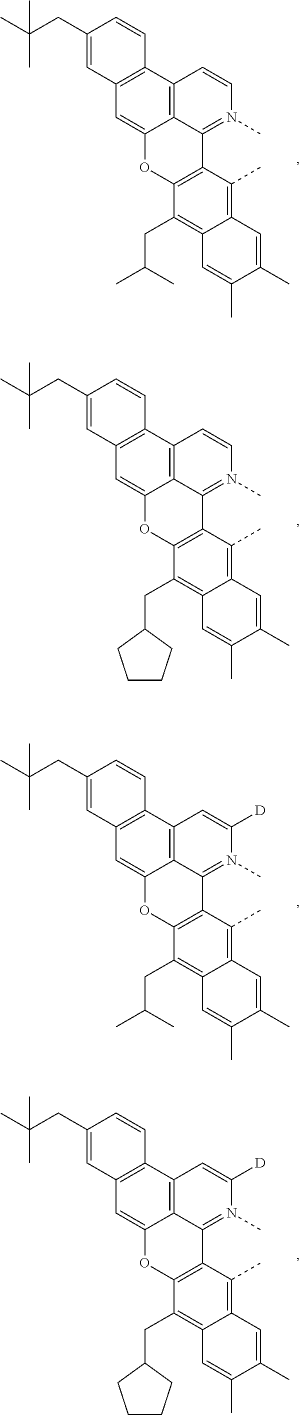

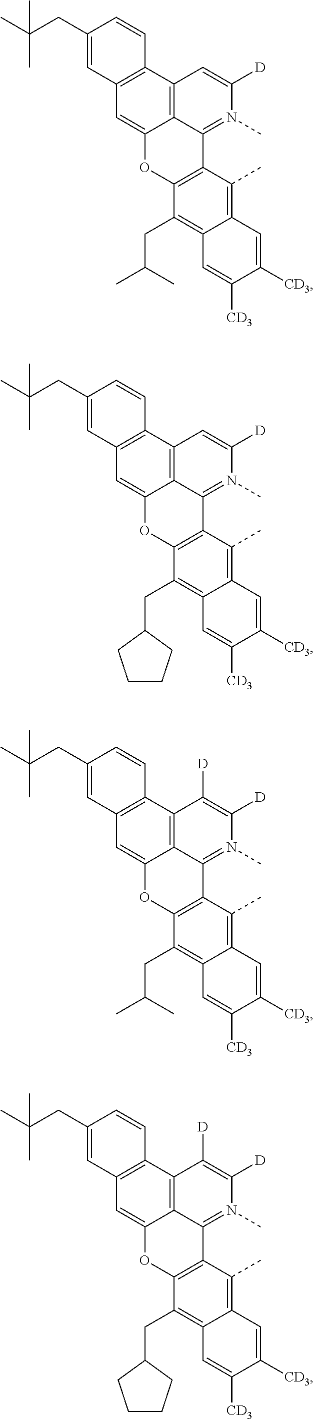

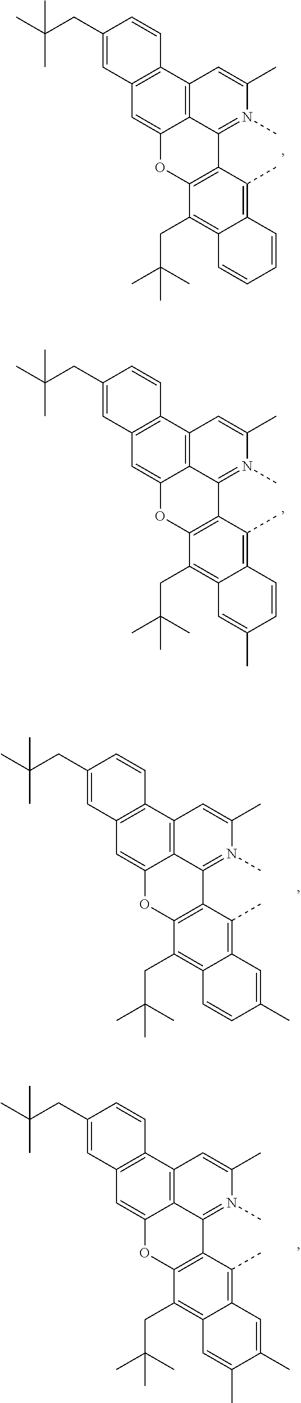

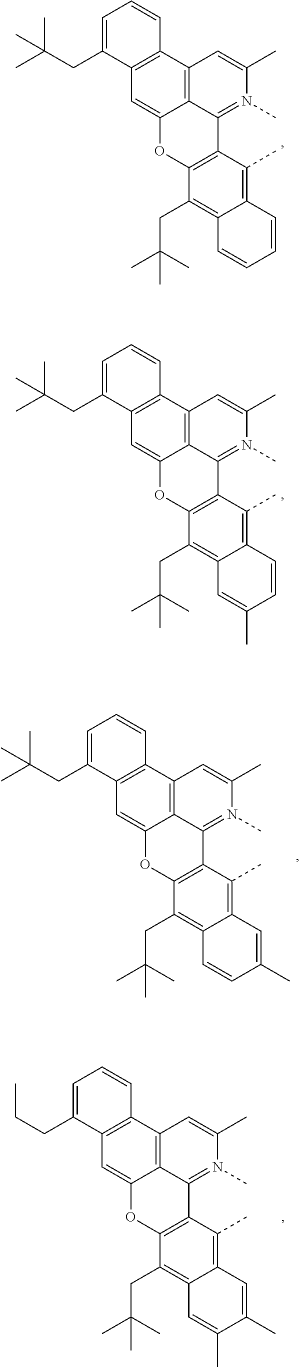

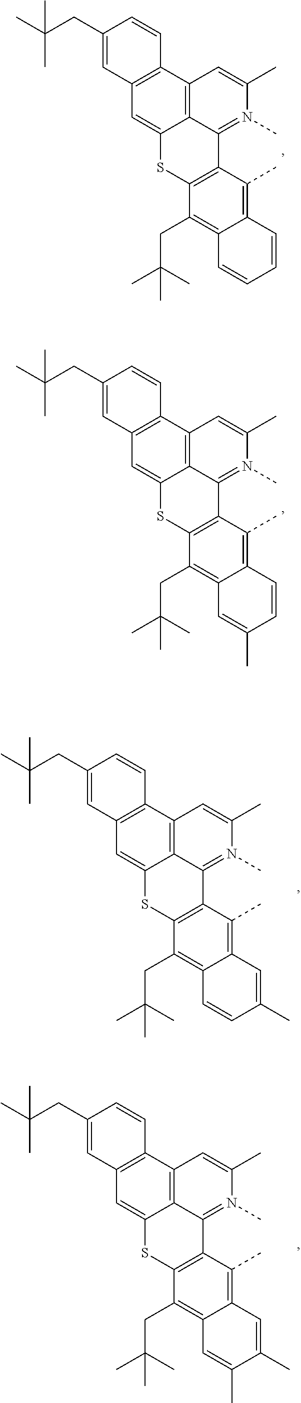

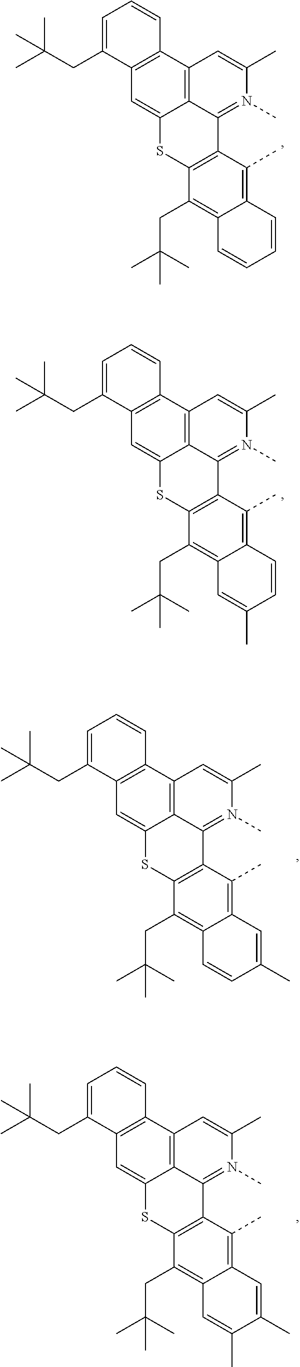

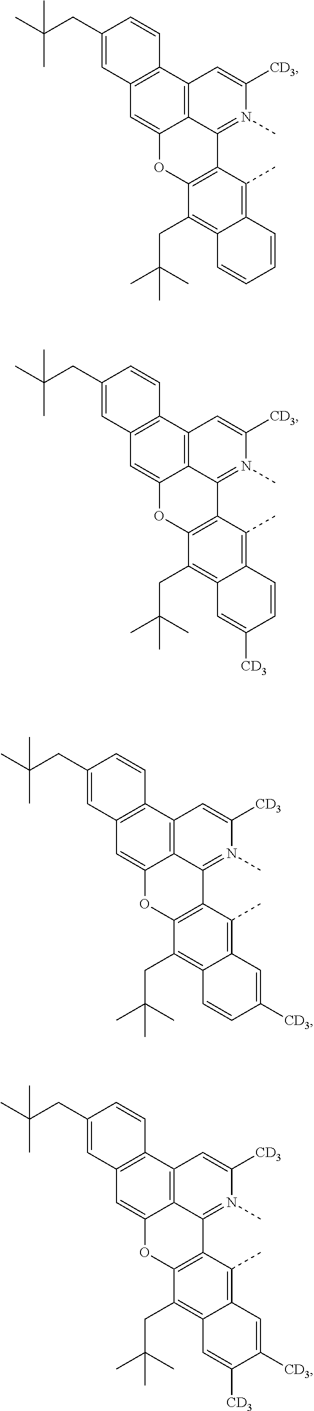

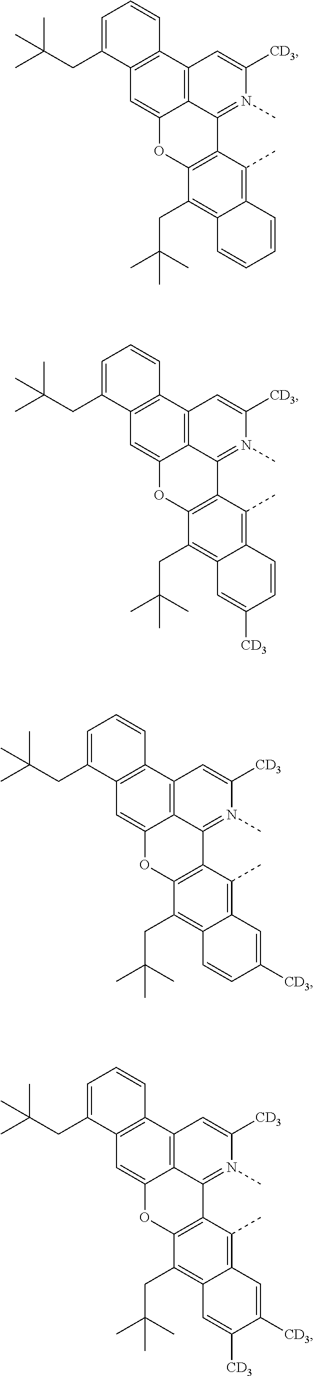

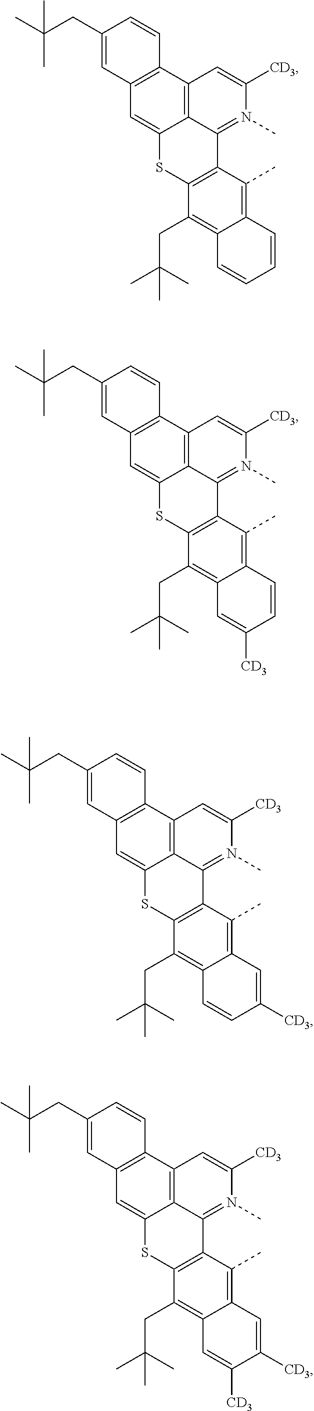

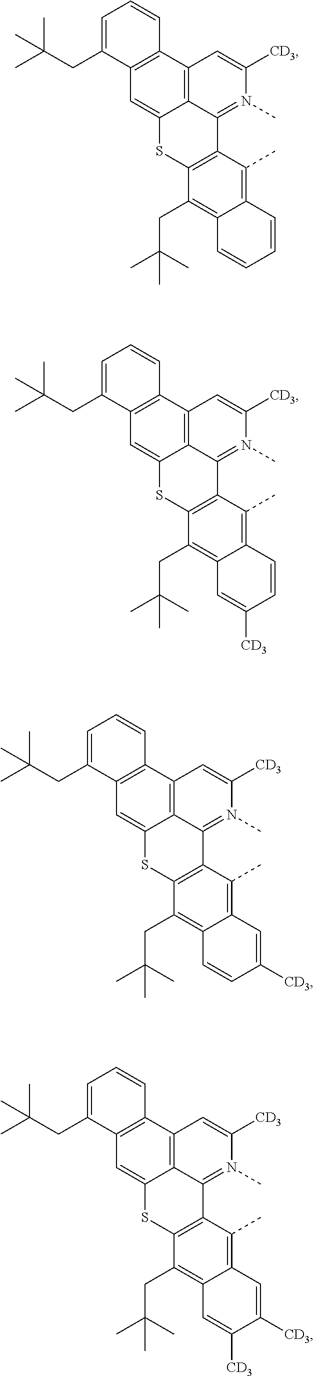

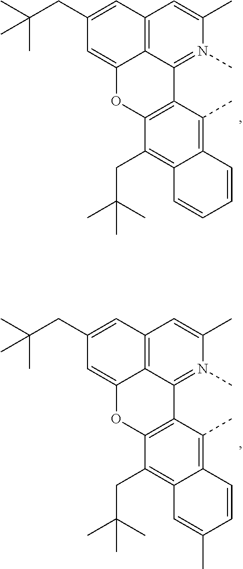

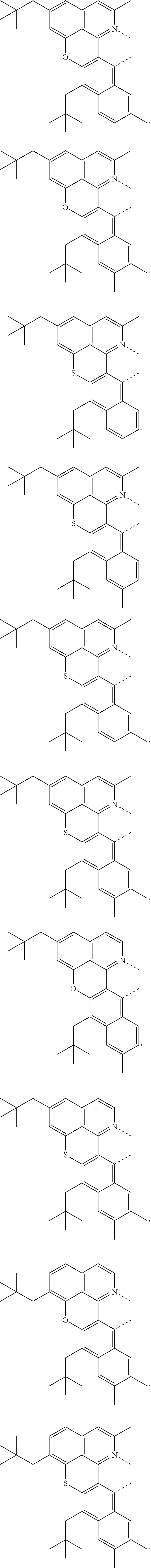

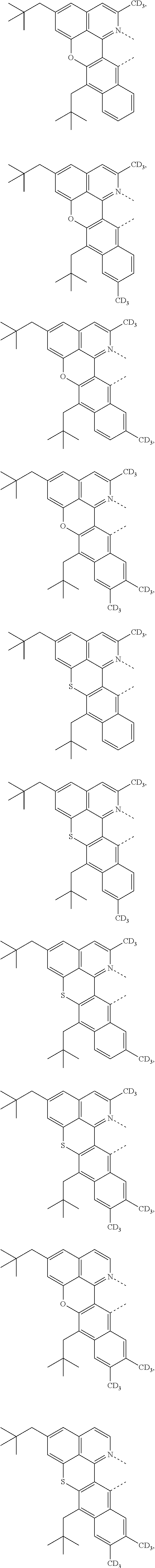

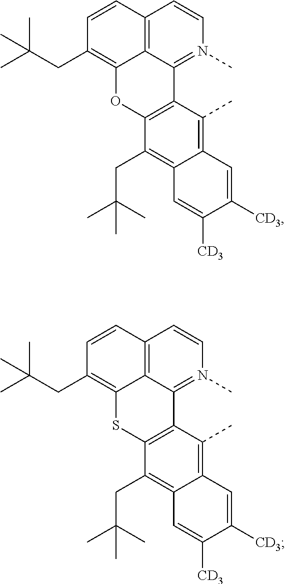

wherein in the above structures, TMS represents trimethylsilyl.

According to an embodiment of the present disclosure, in the organic electroluminescent device, the phosphorescent material is an Ir complex comprising the ligand L_{b}, wherein L; is, at each occurrence identically or differently, selected from any one of the group consisting of the following structures:

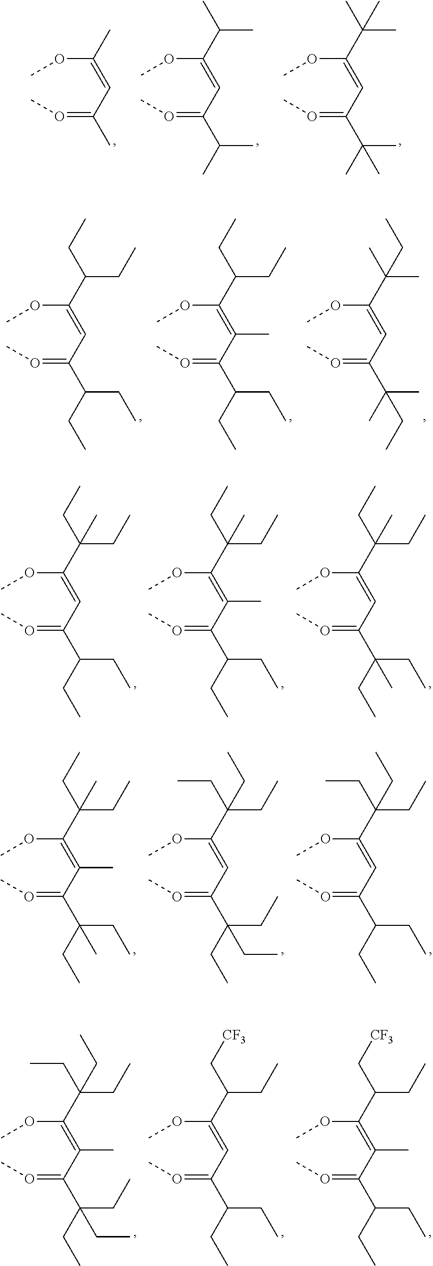

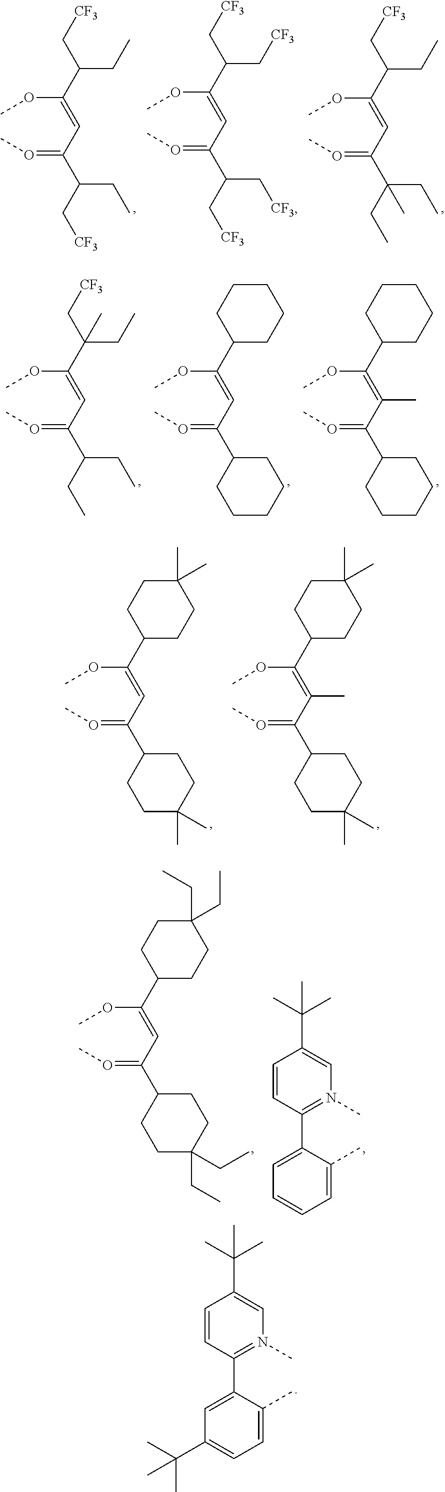

According to an embodiment of the present disclosure, in the organic electroluminescent device, the phosphorescent material is selected from the group consisting of the following structures:

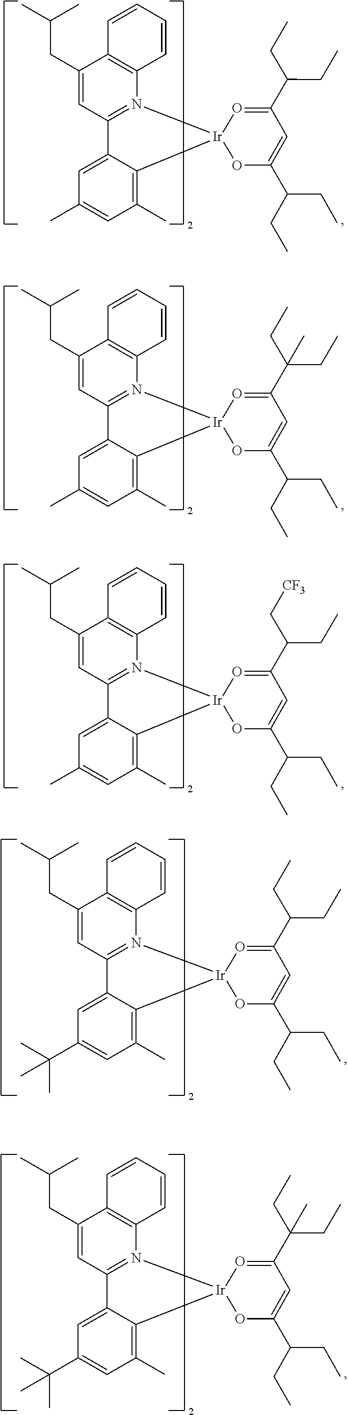

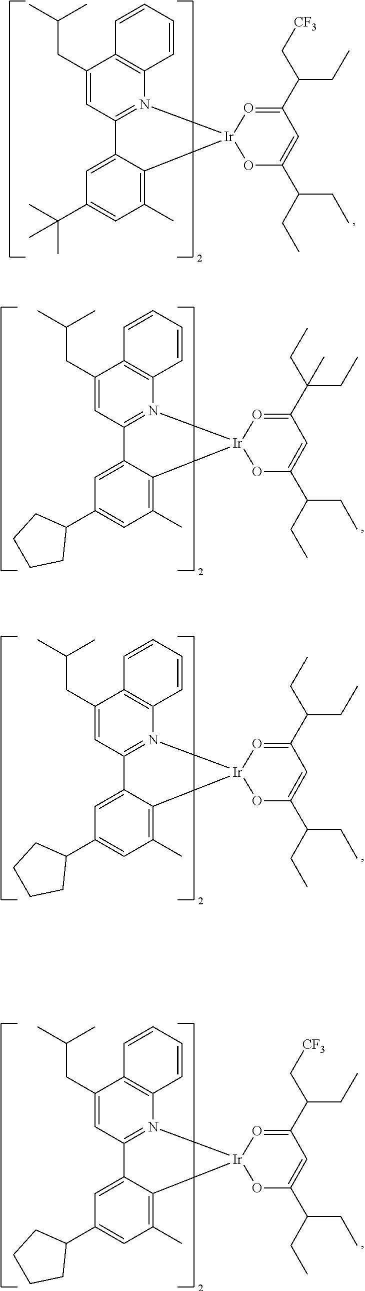

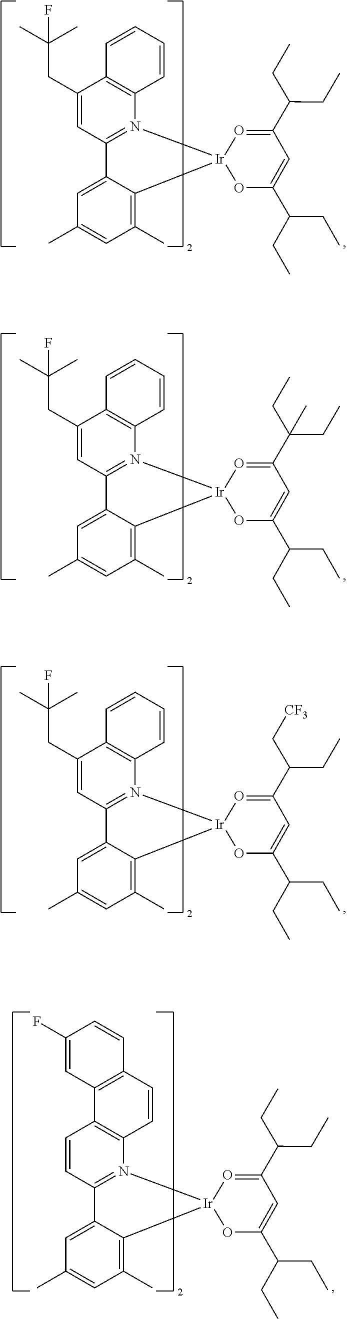

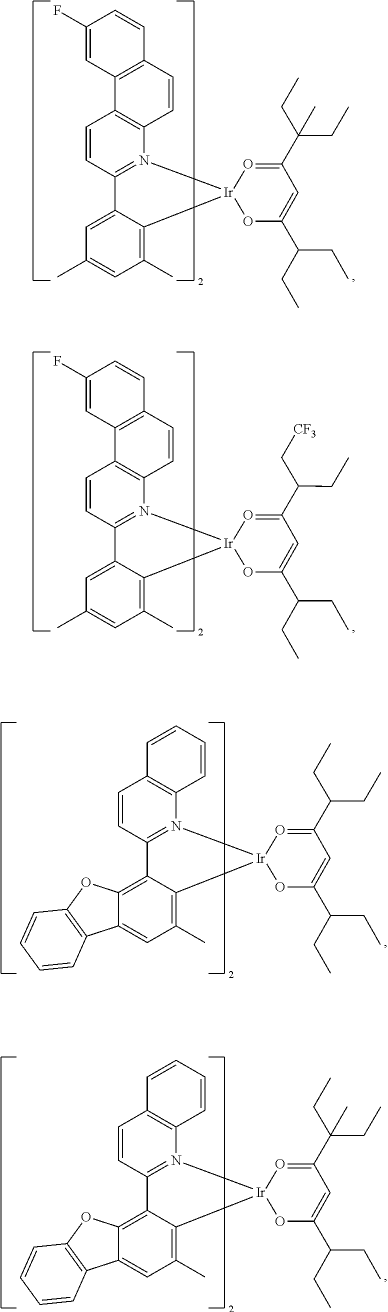

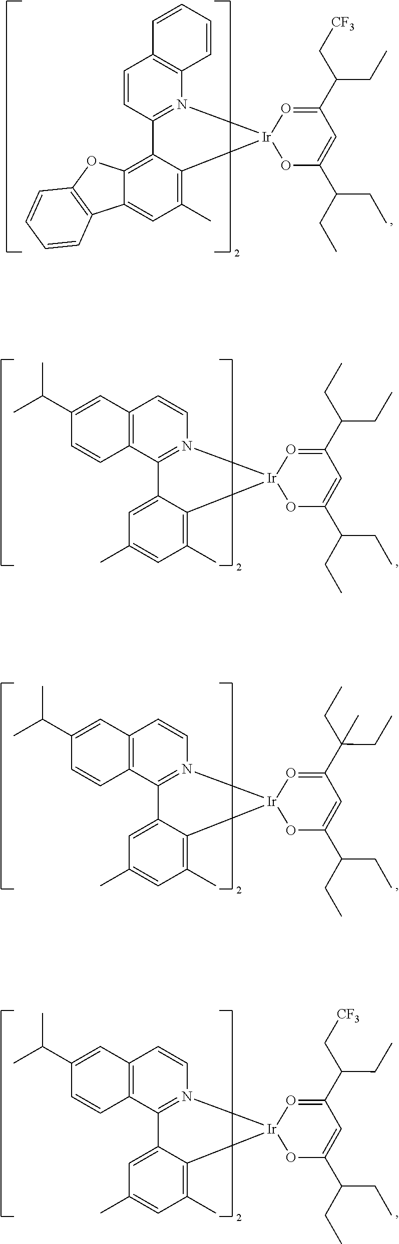

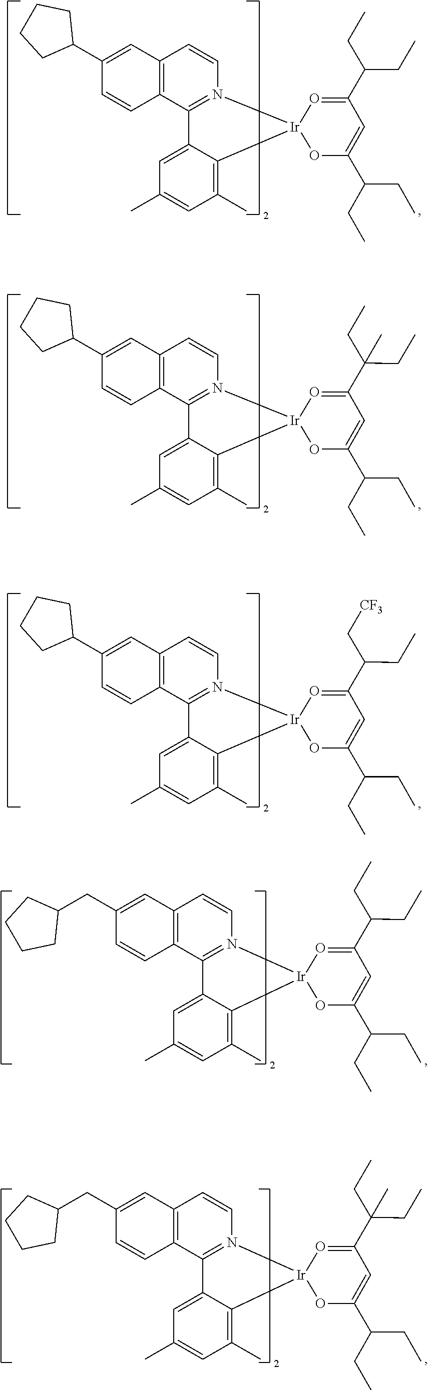

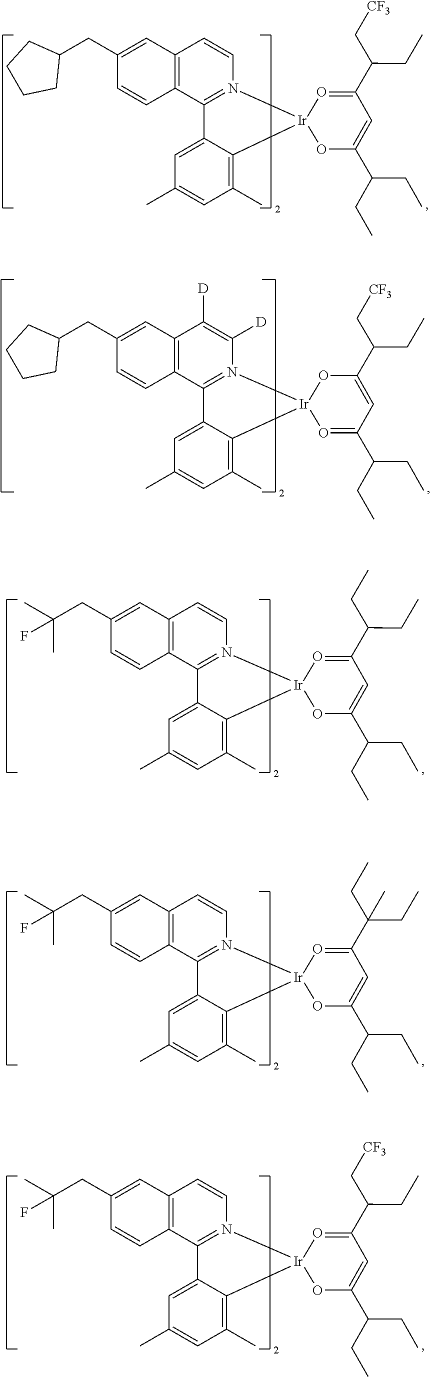

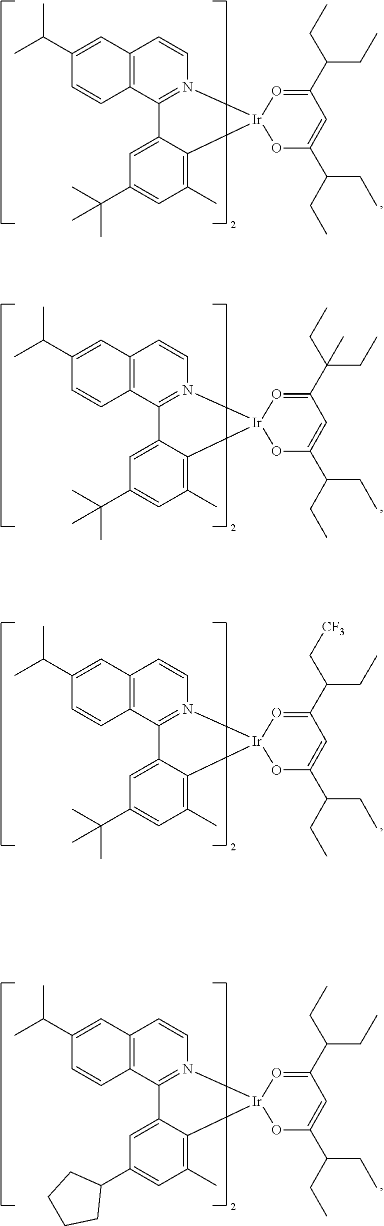

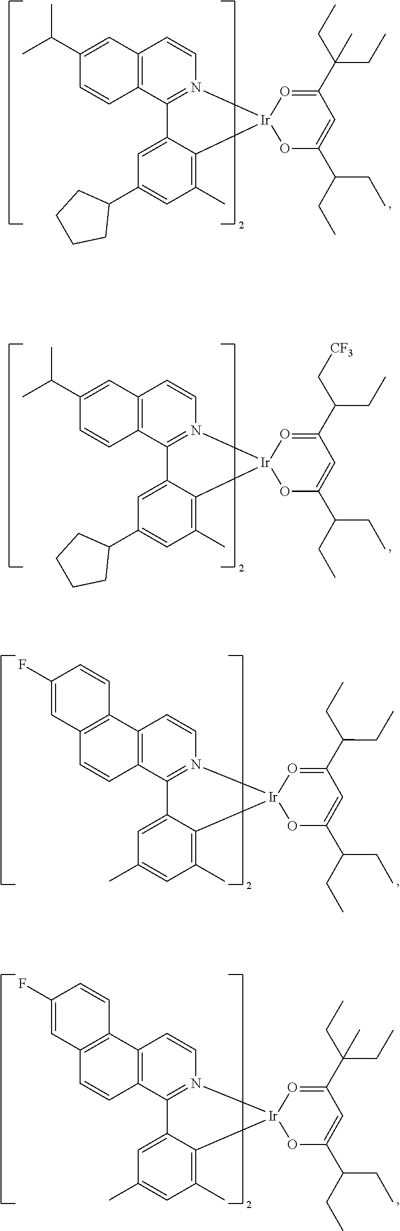

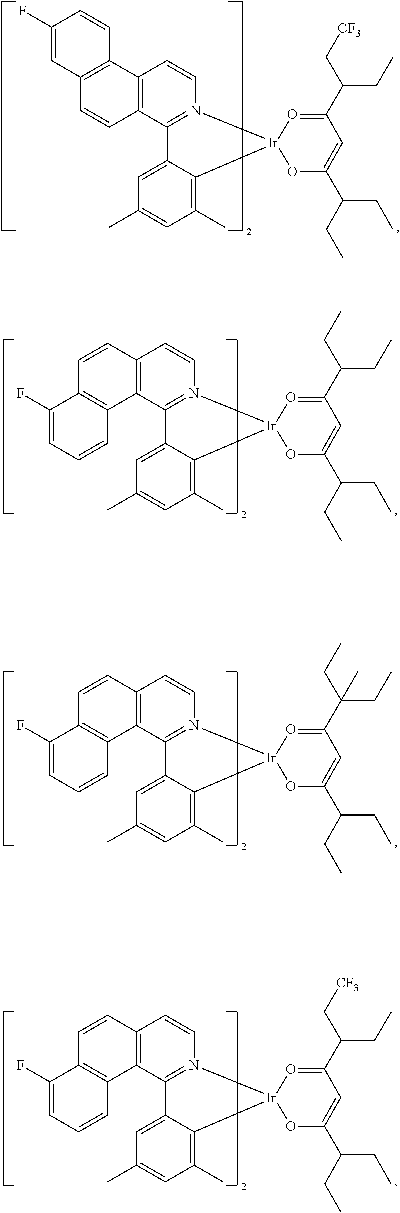

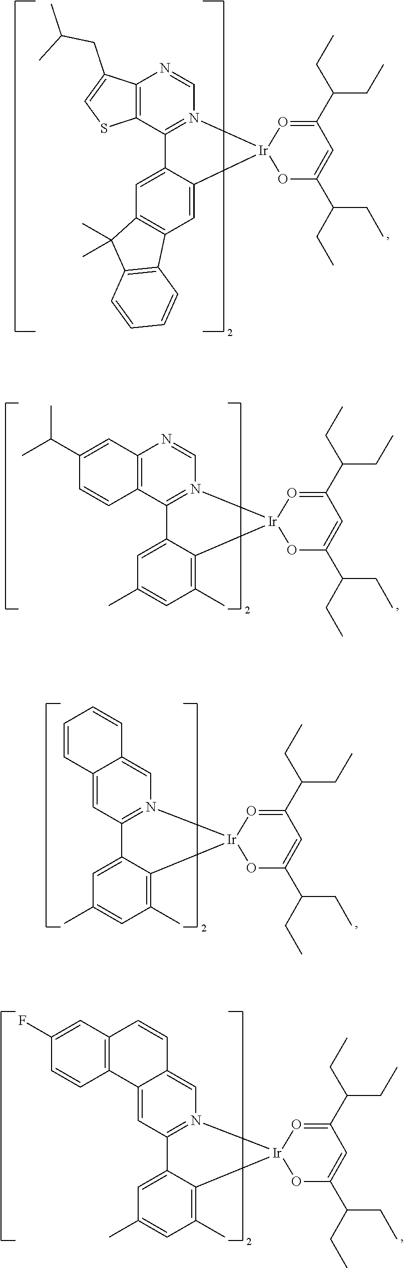

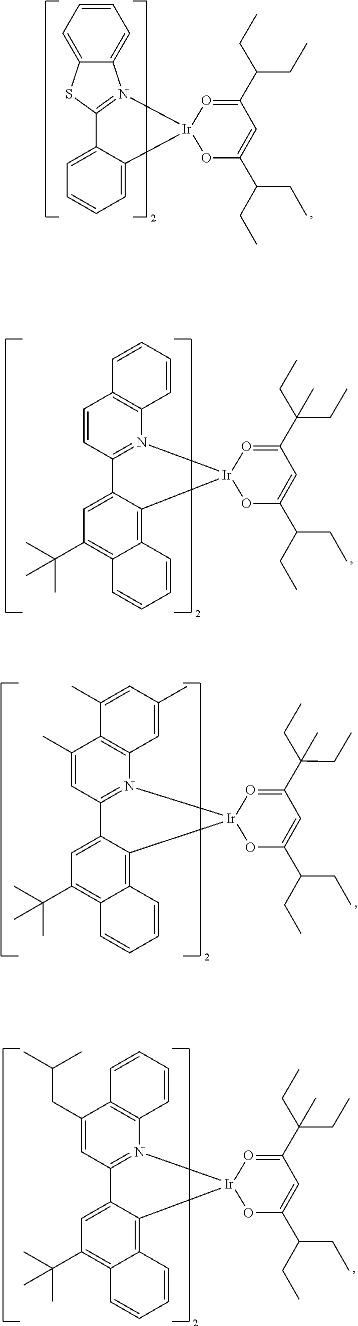

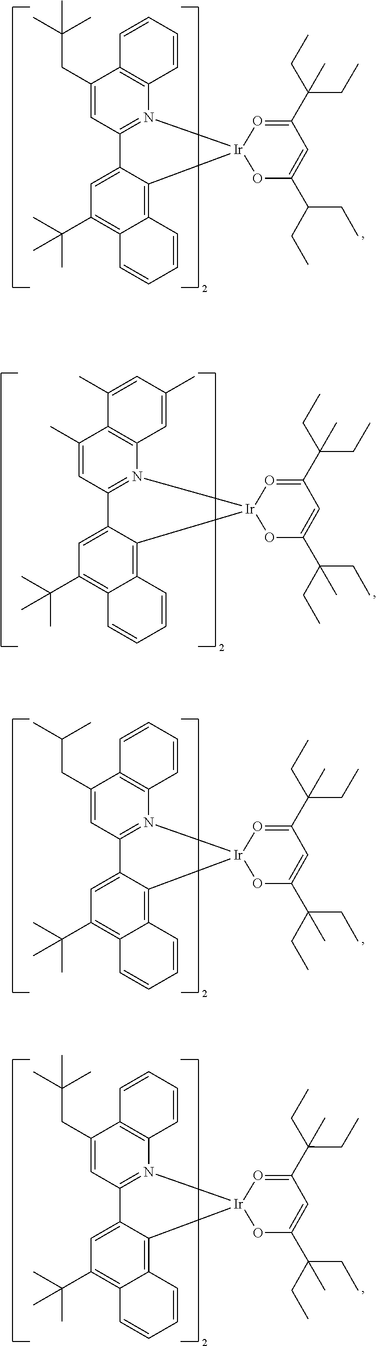

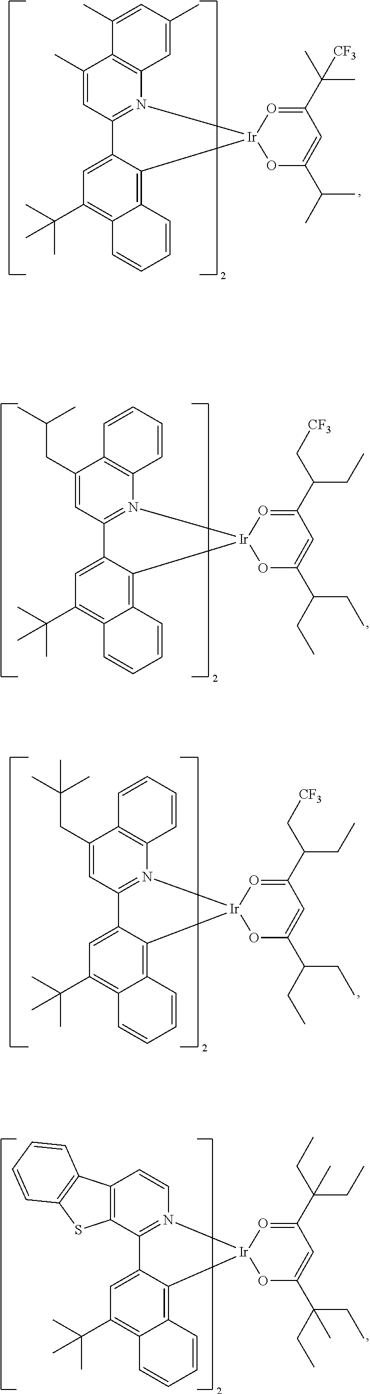

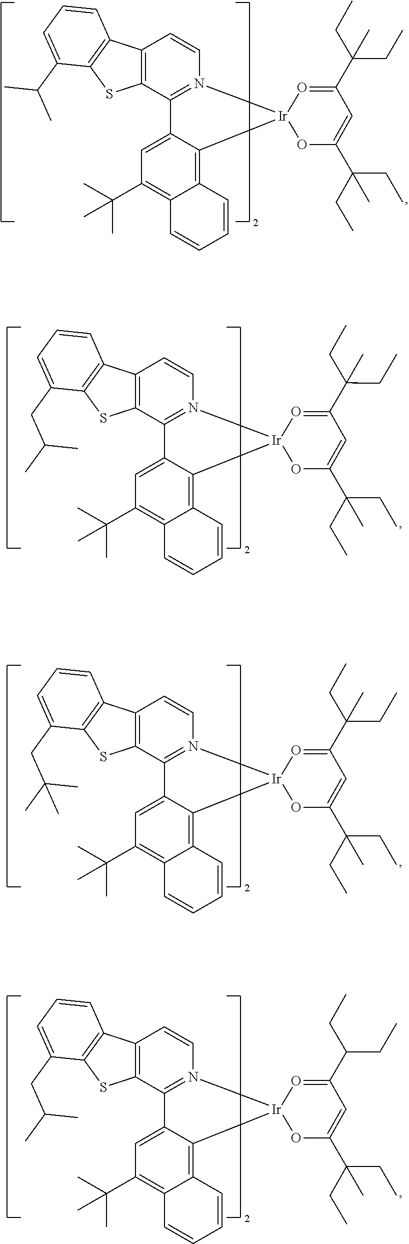

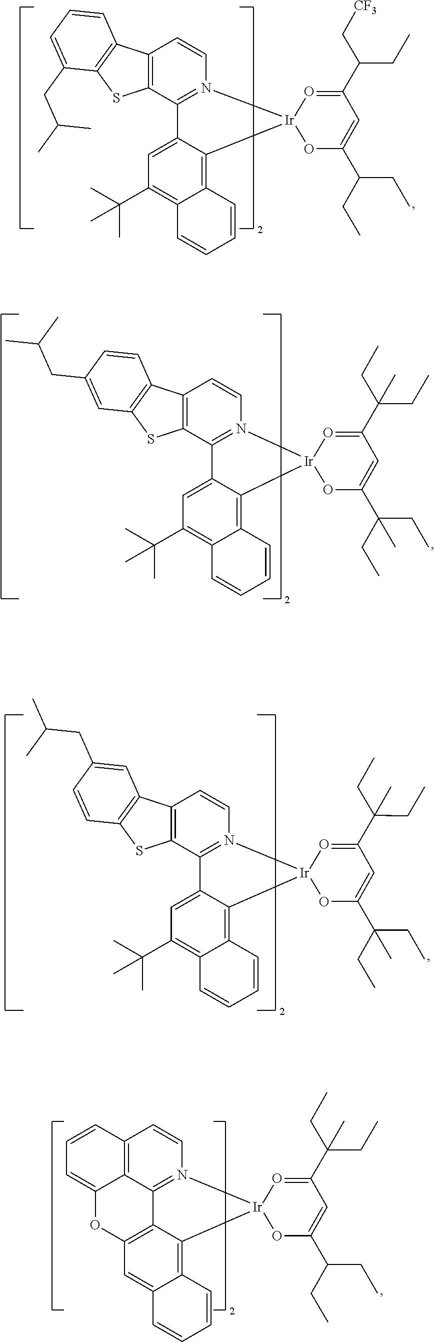

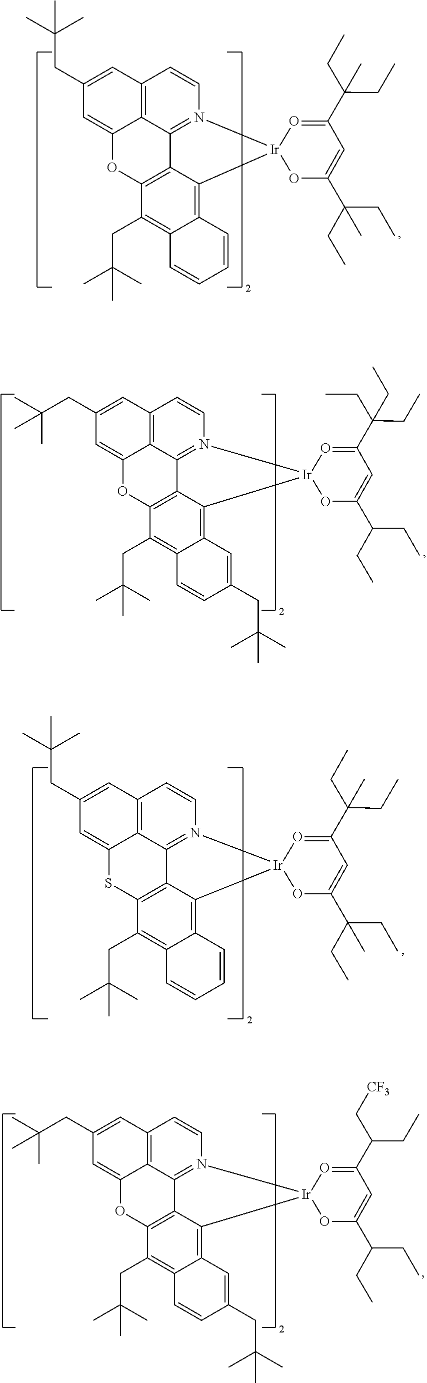

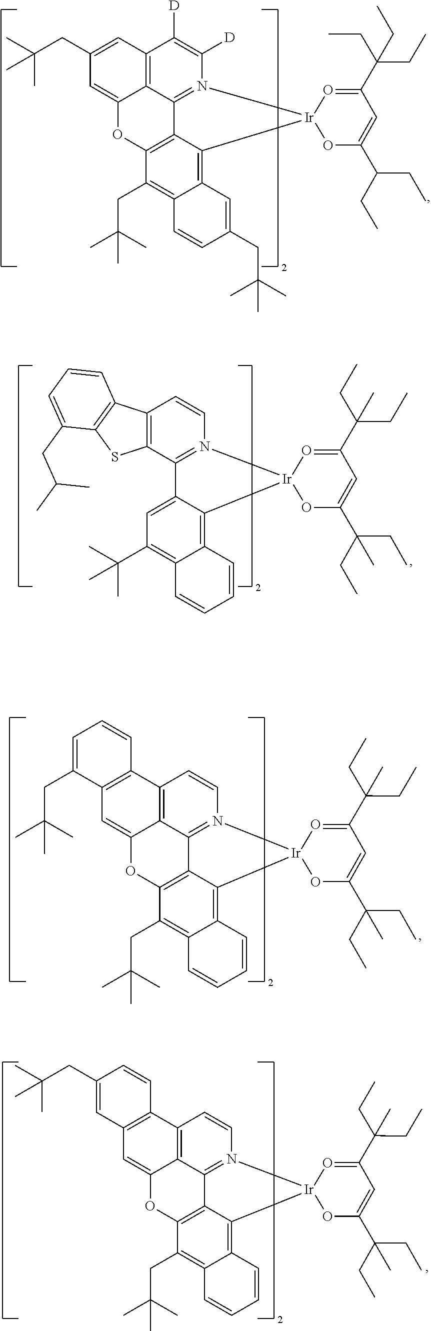

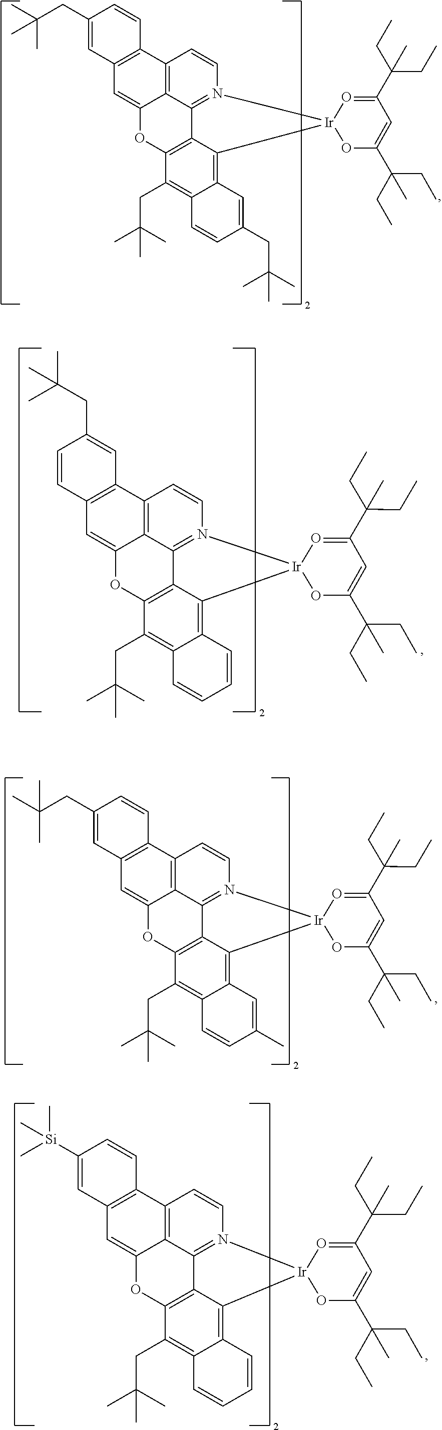

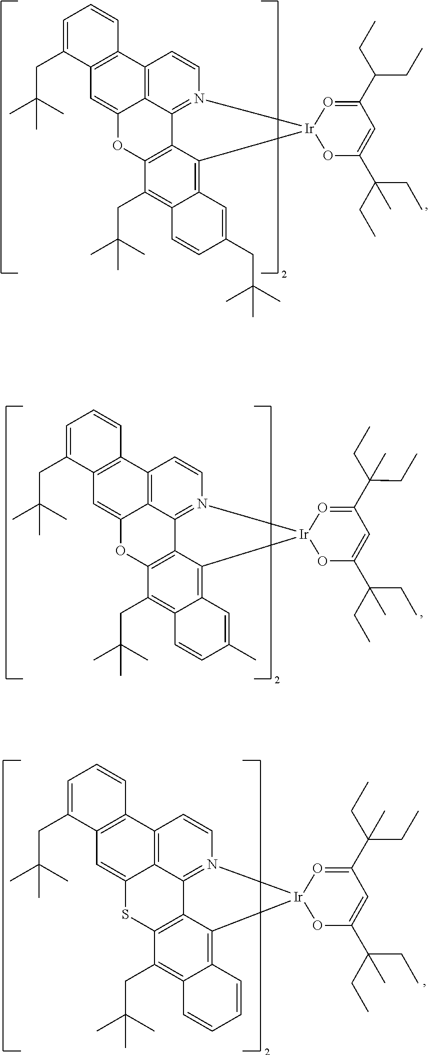

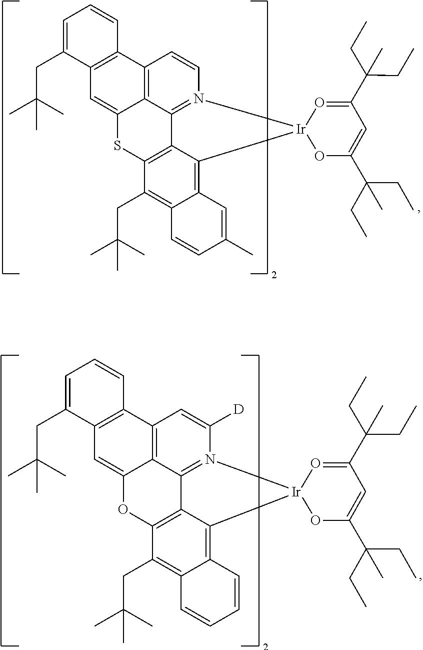

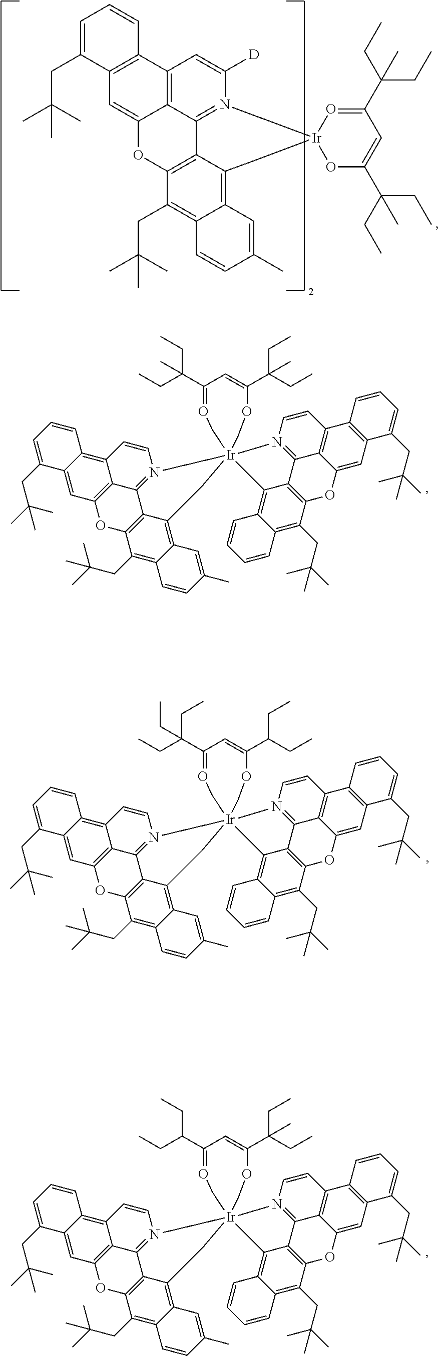

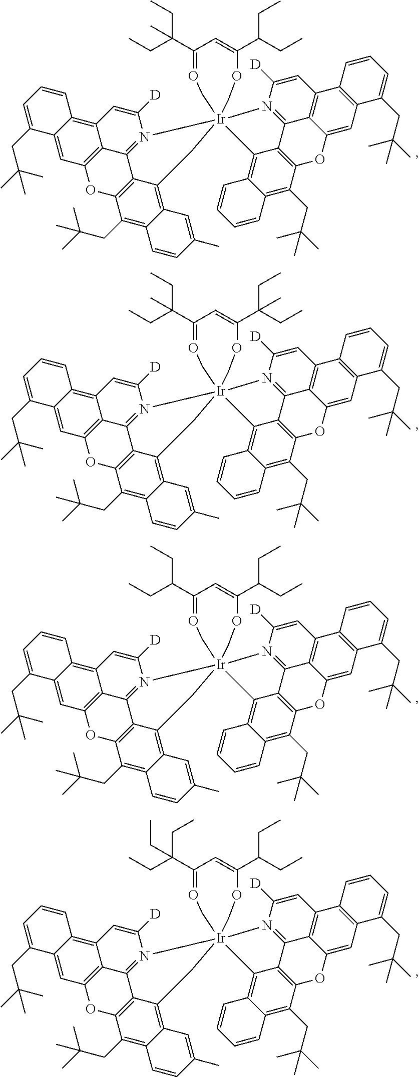

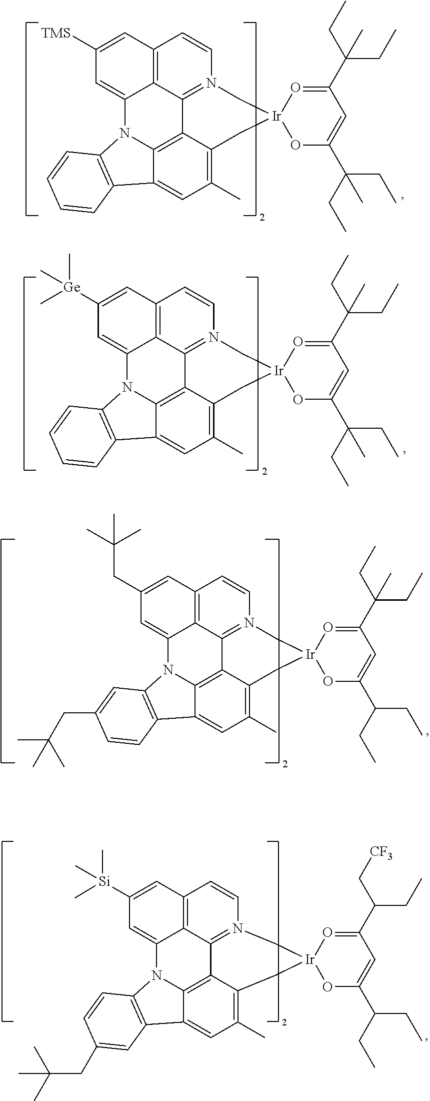

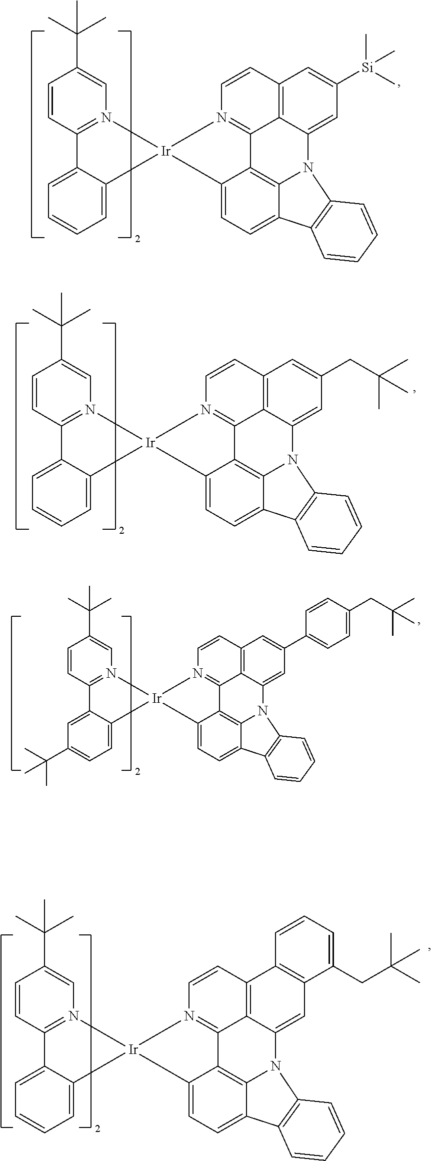

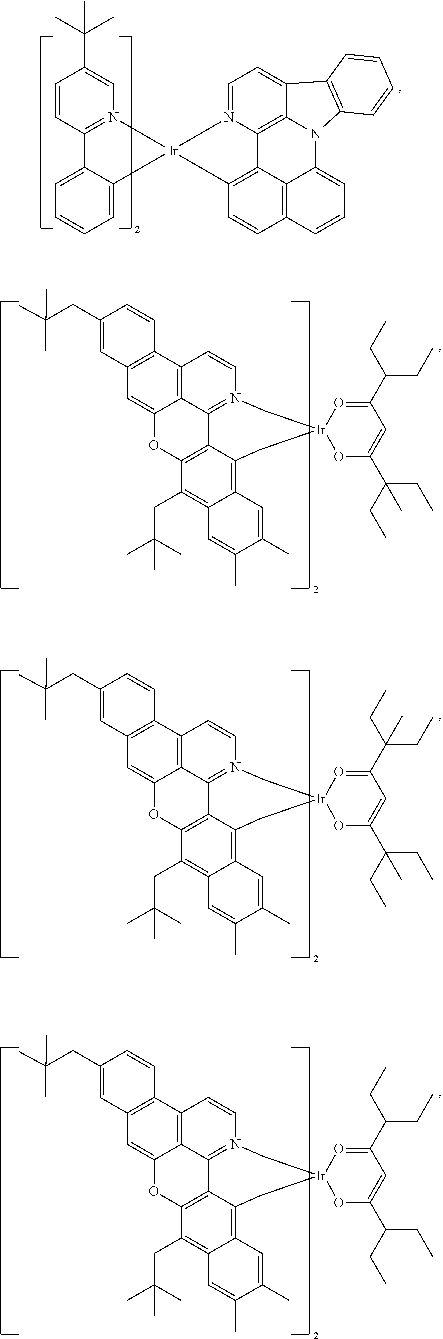

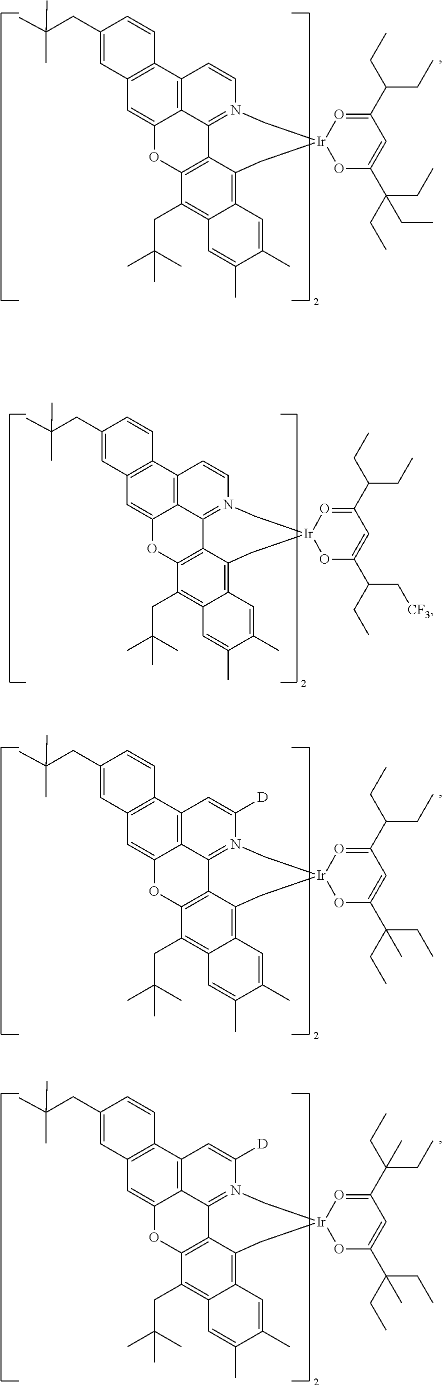

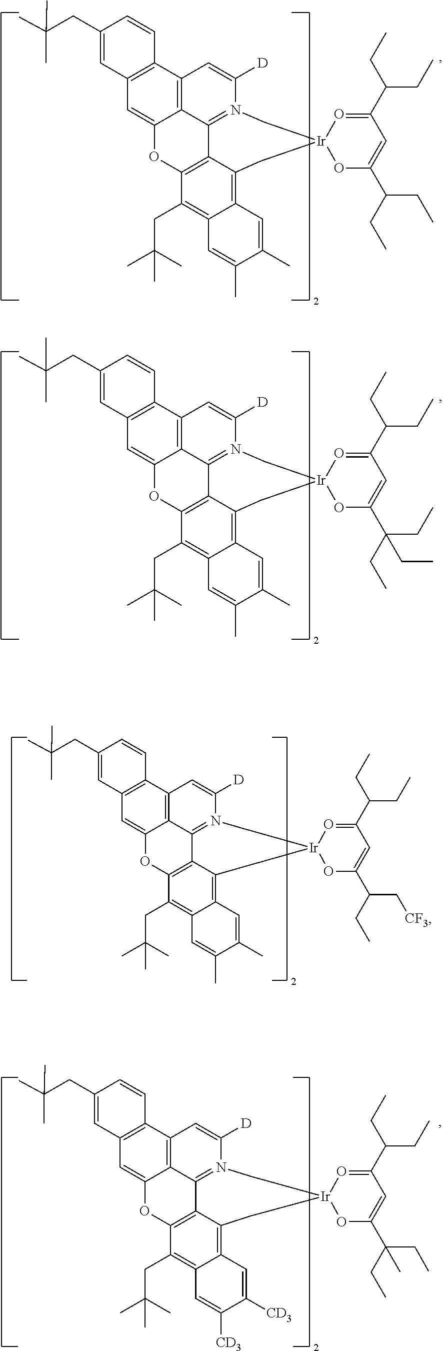

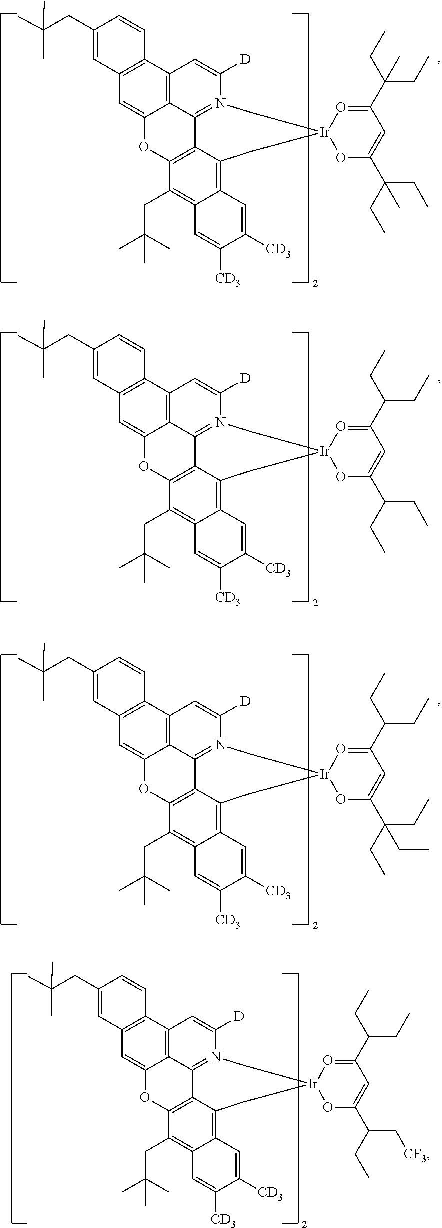

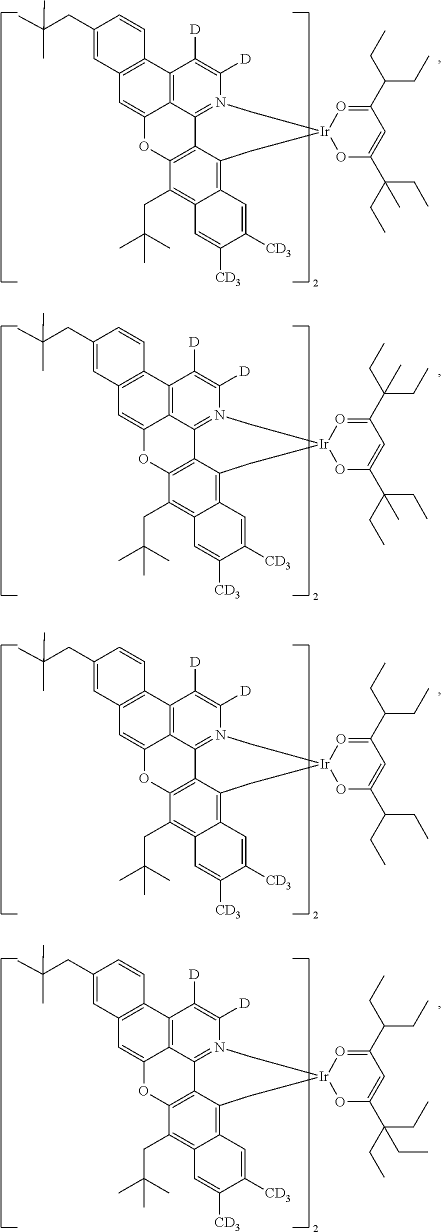

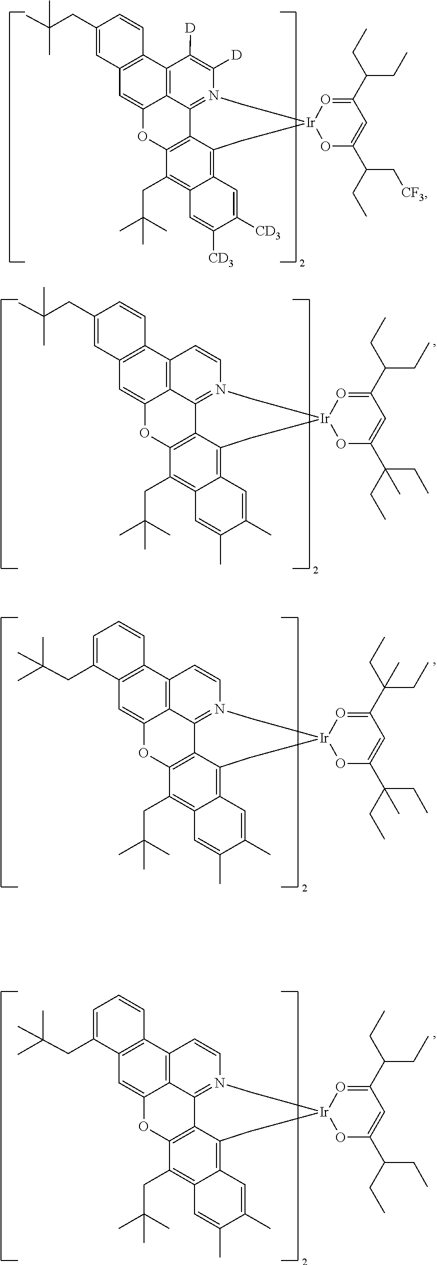

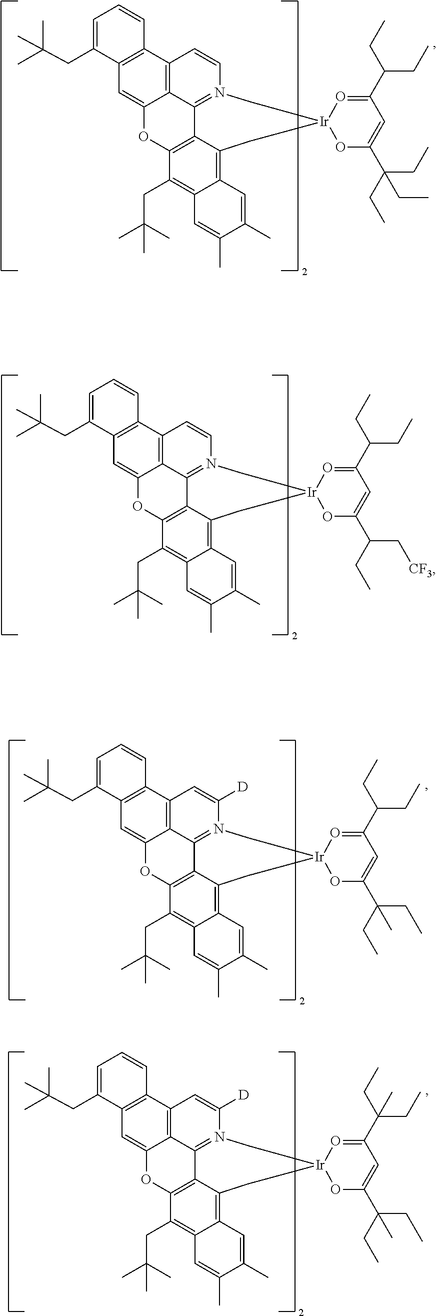

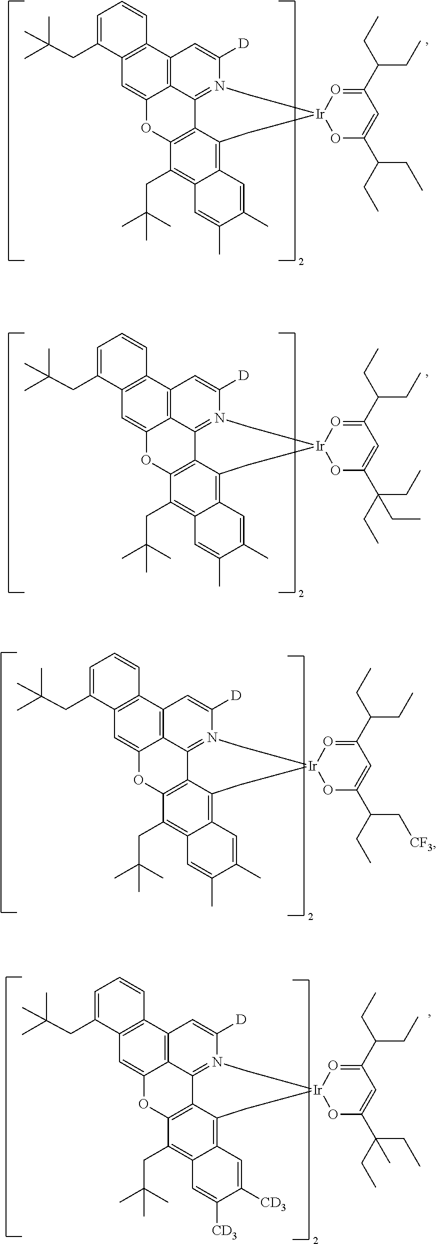

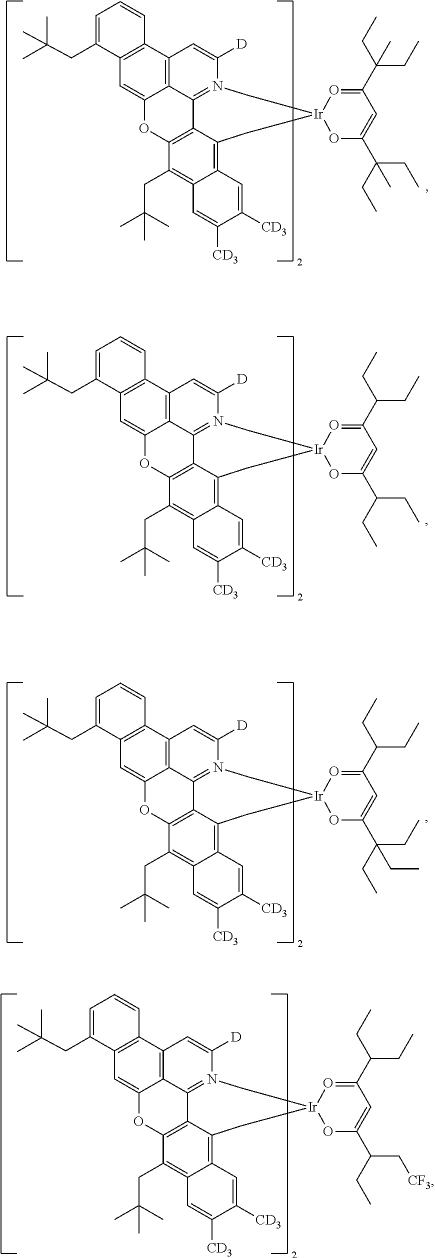

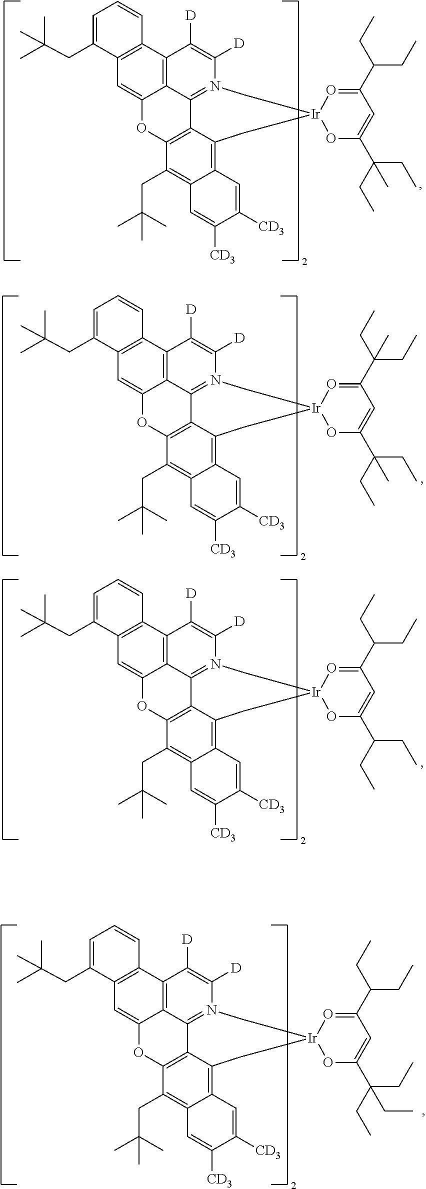

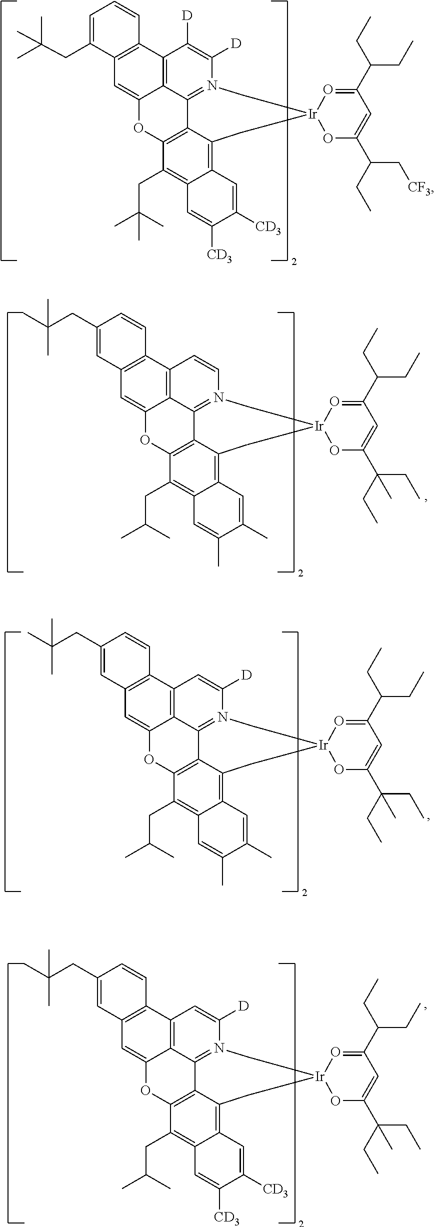

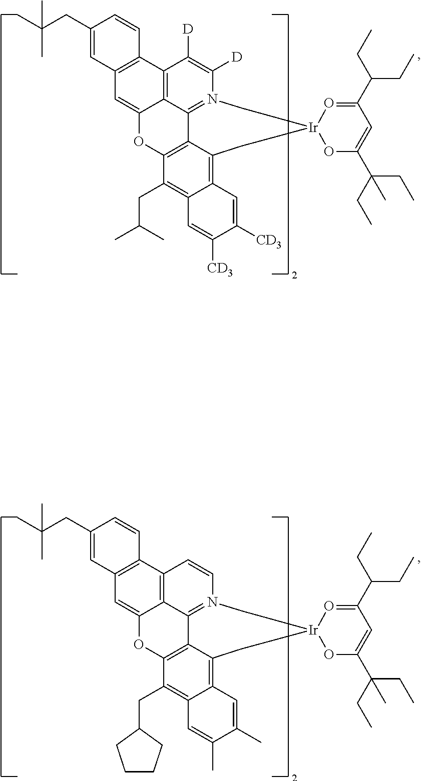

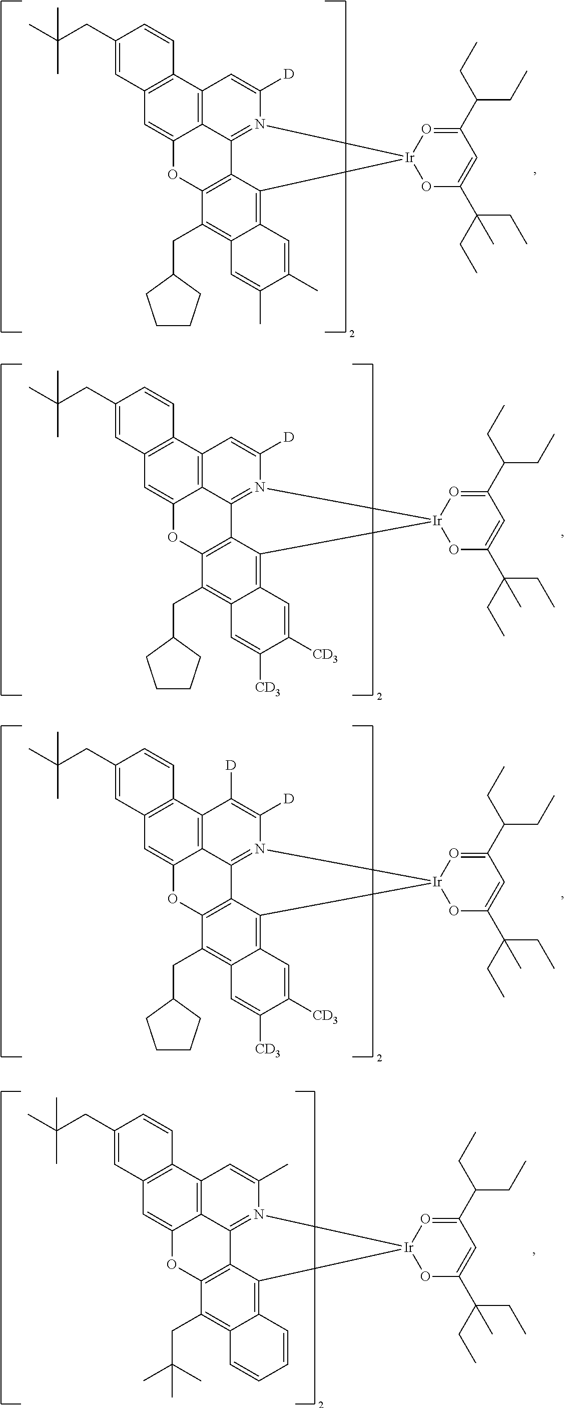

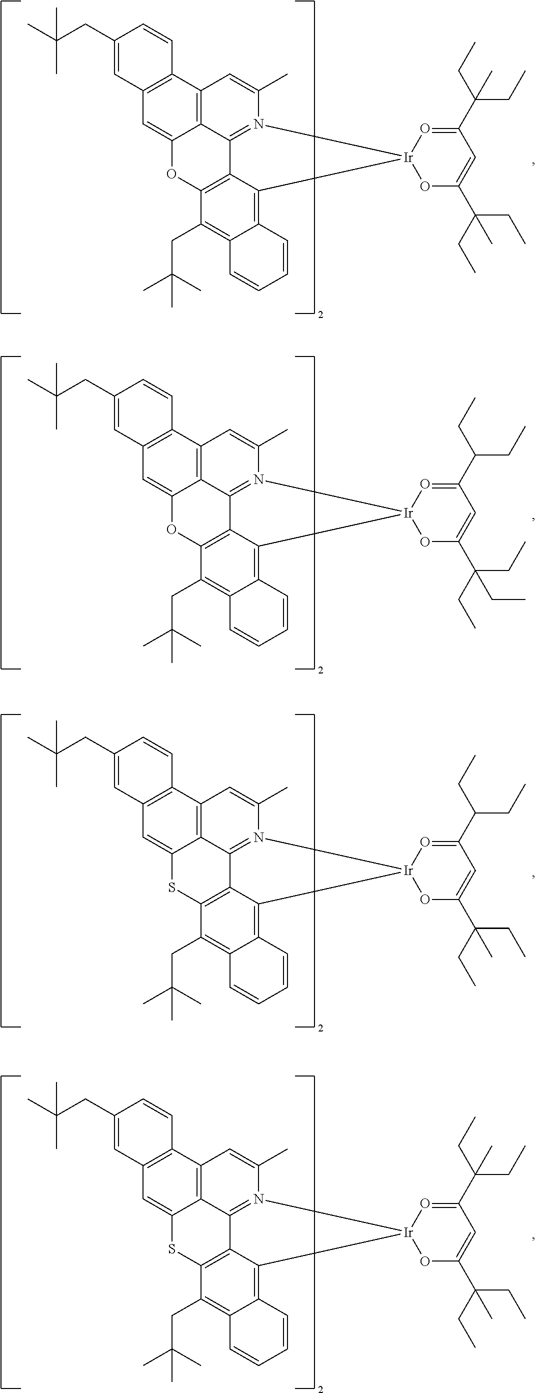

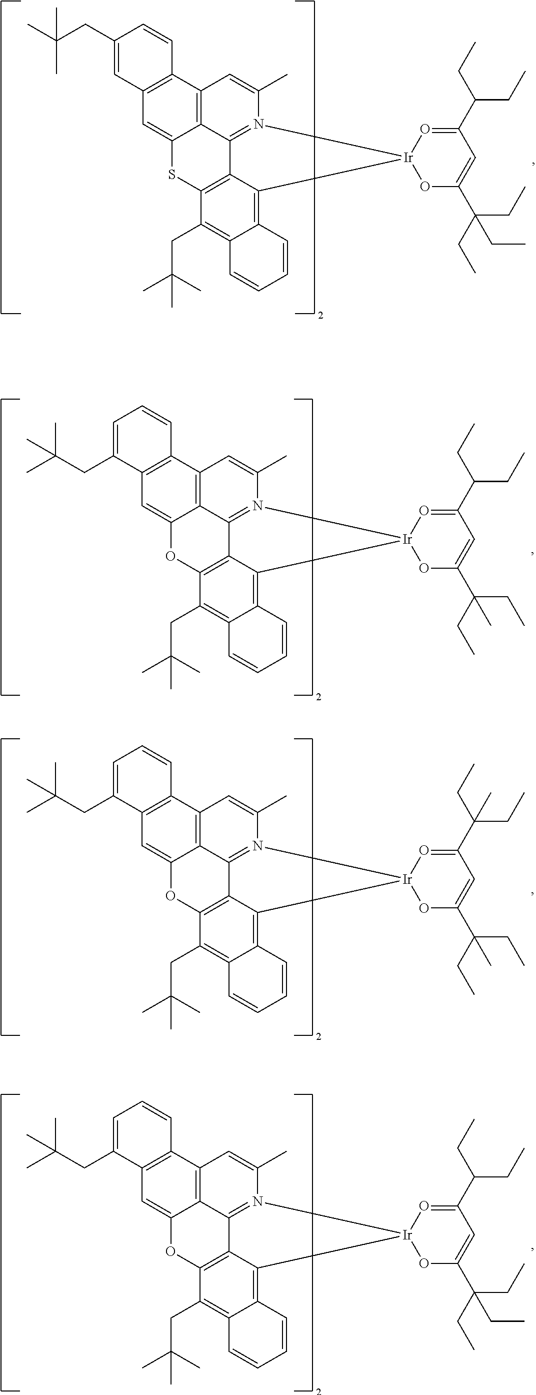

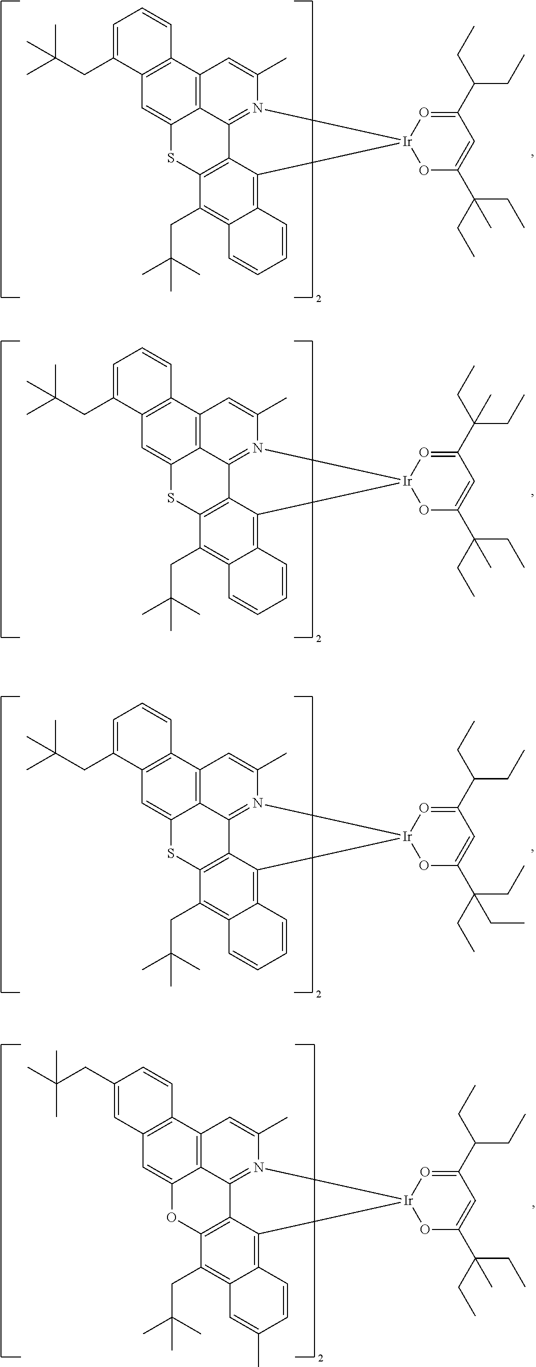

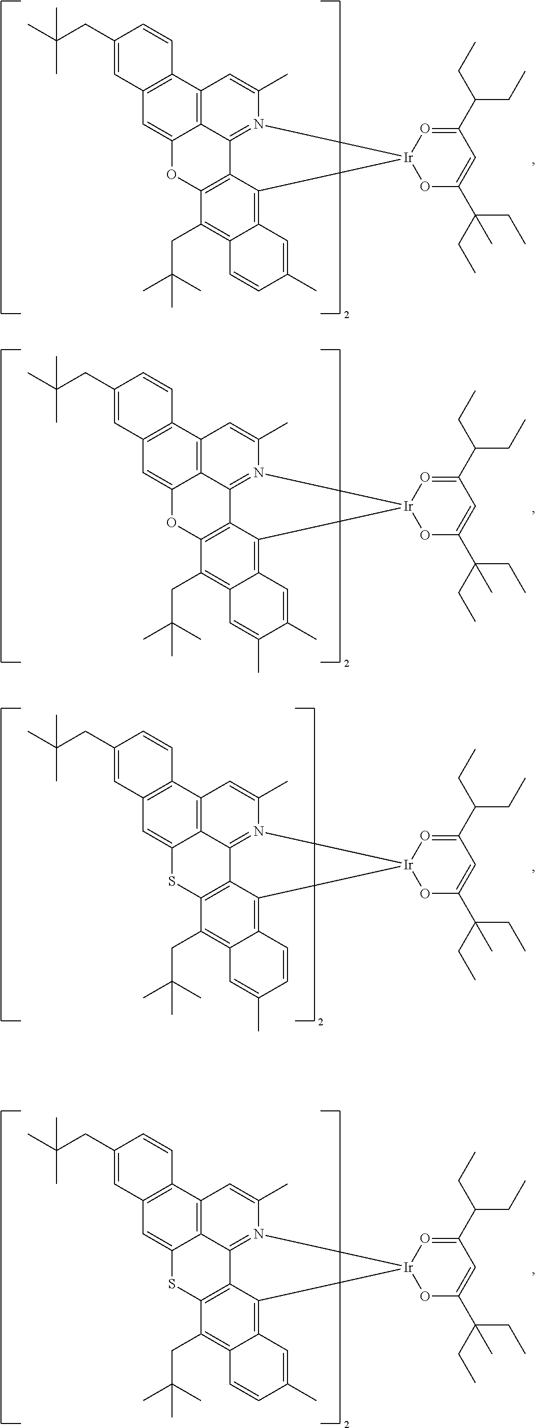

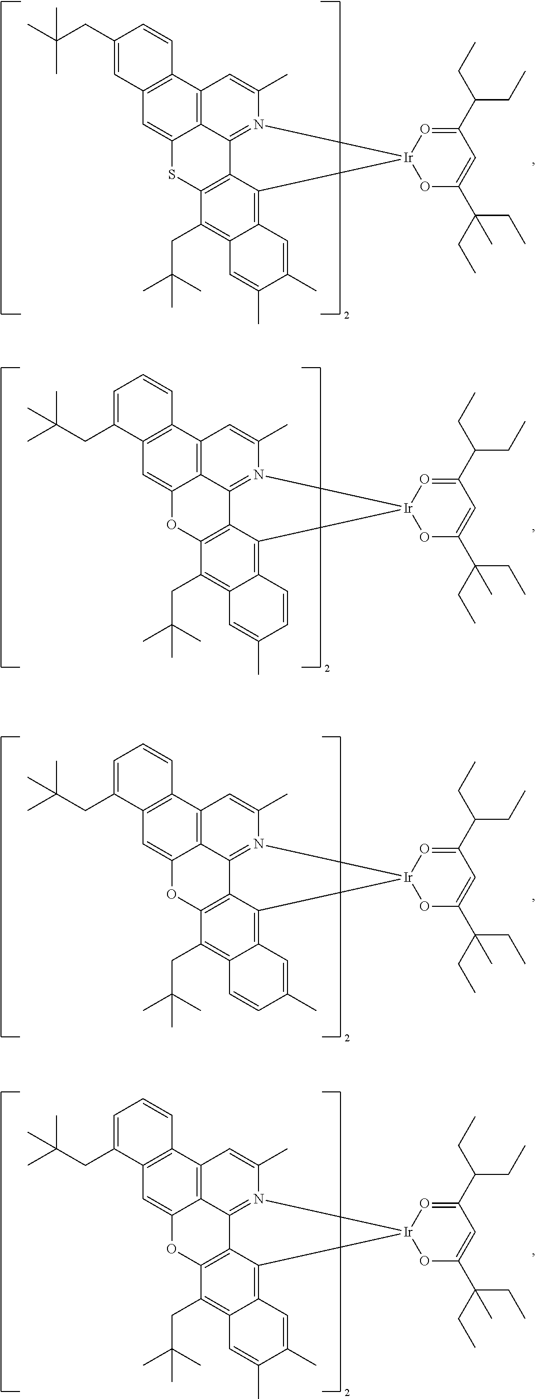

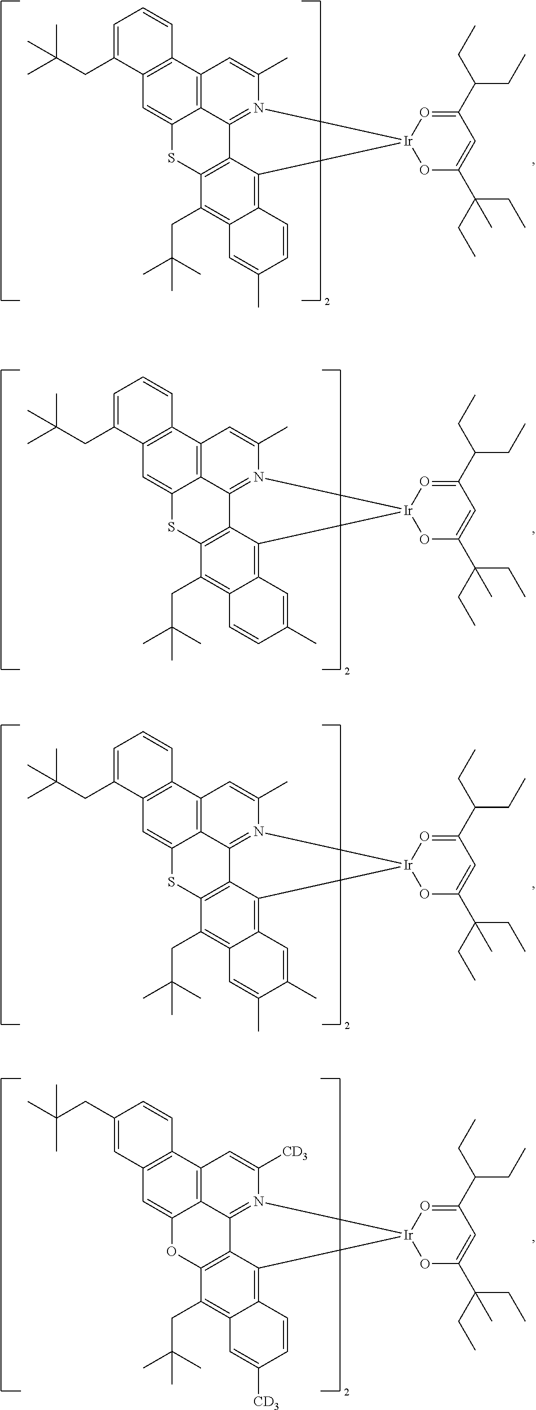

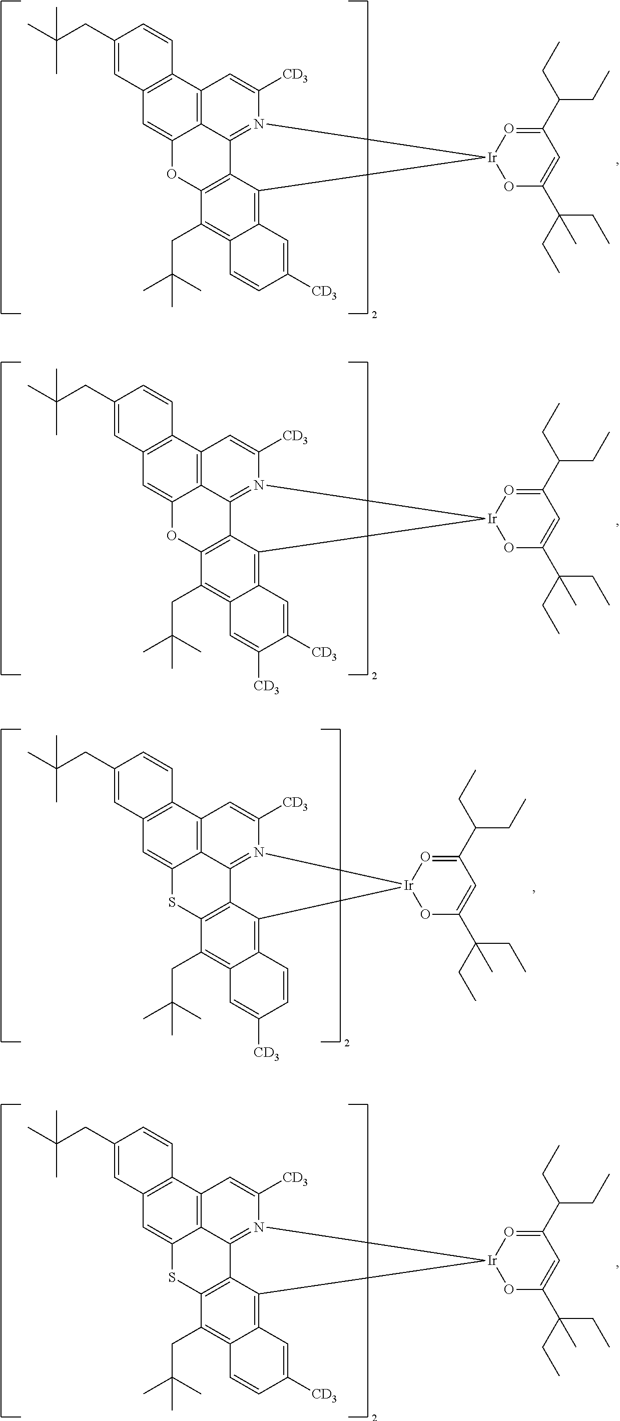

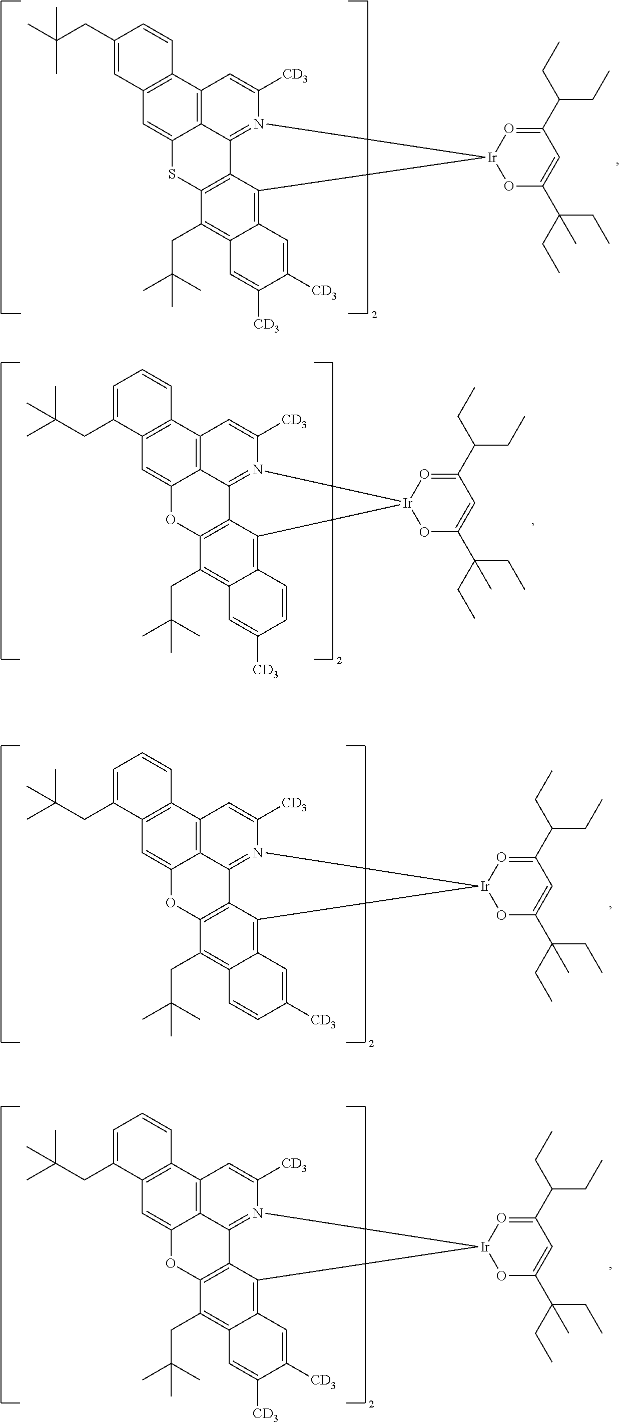

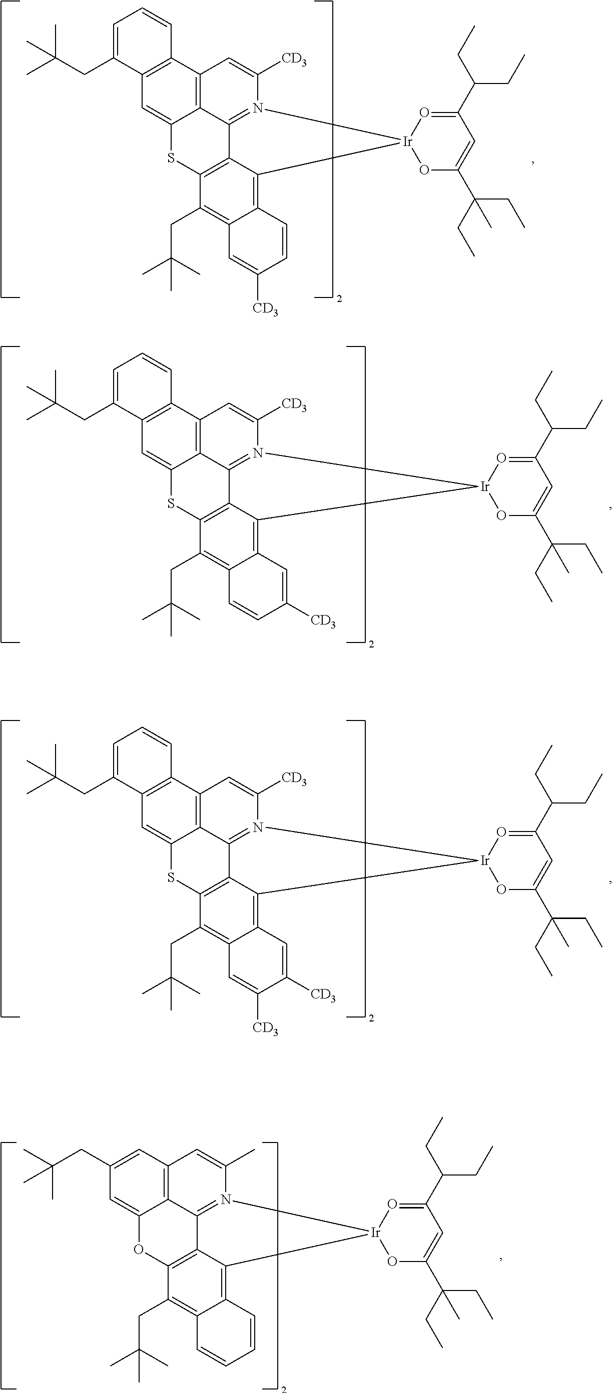

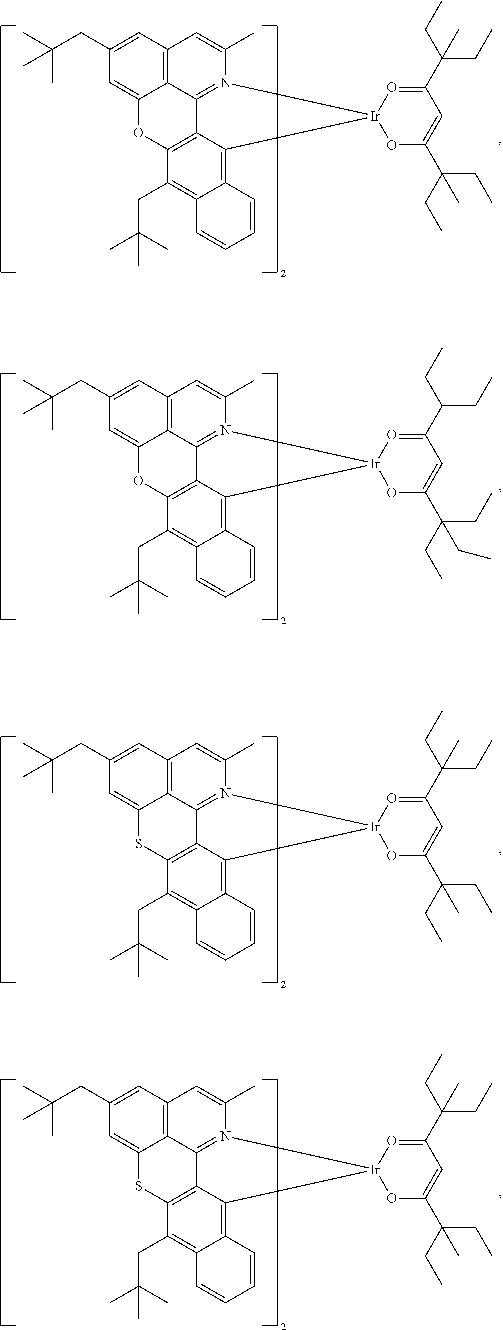

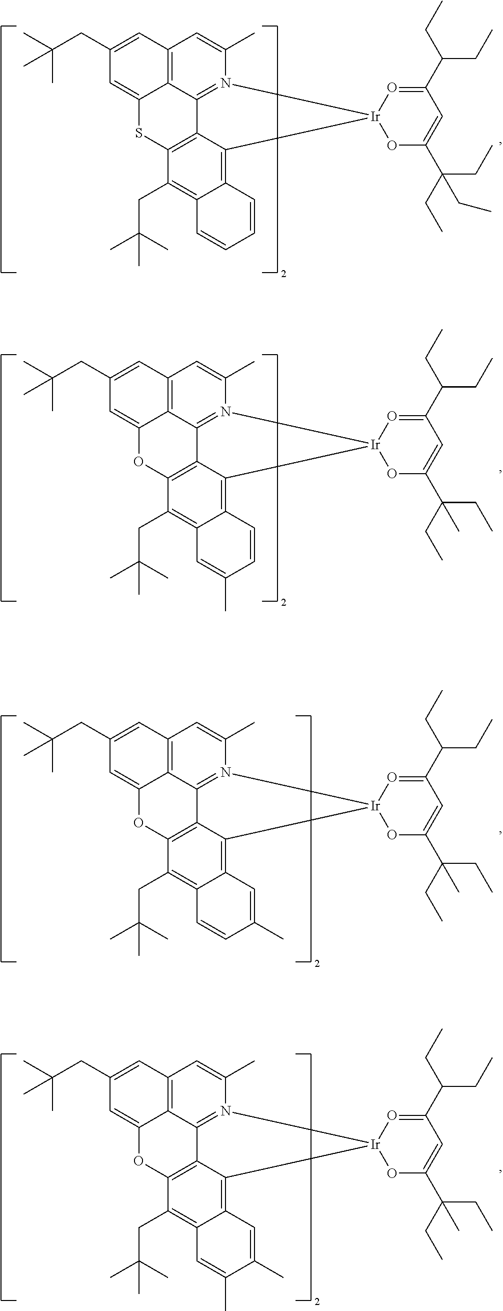

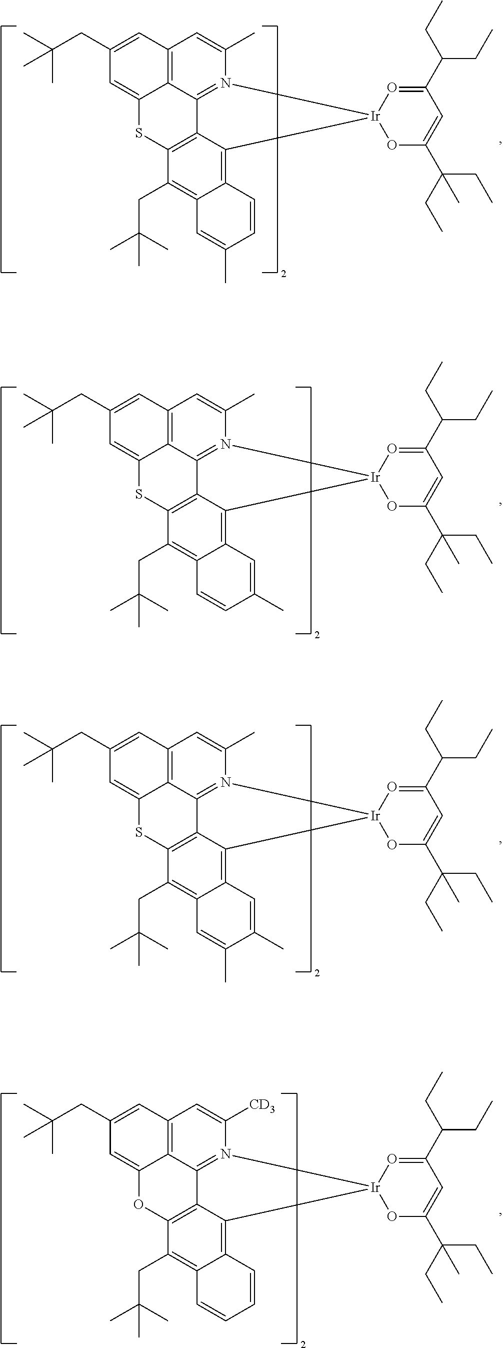

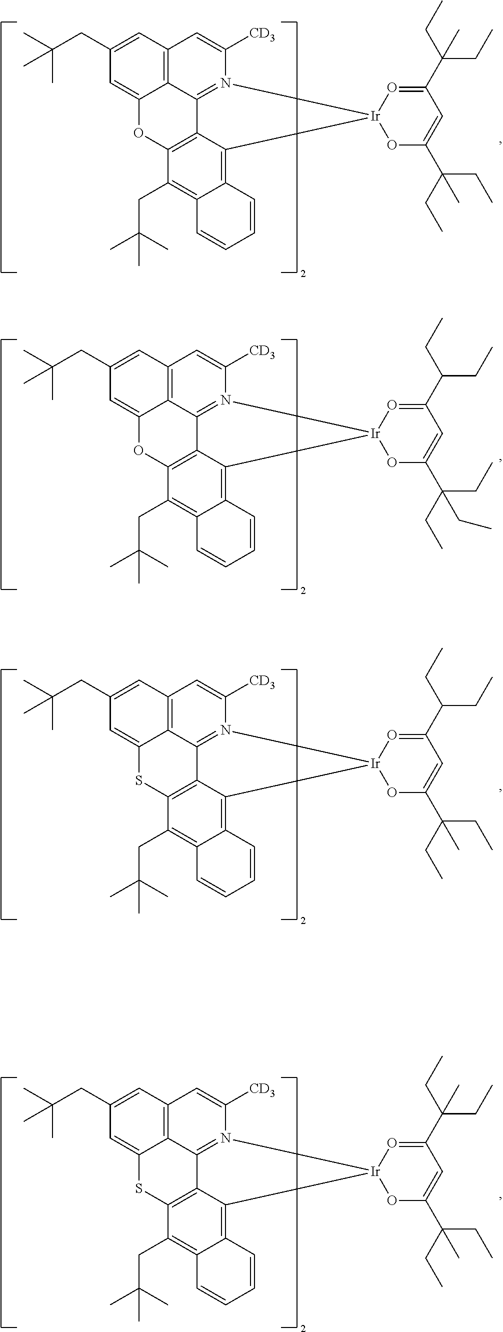

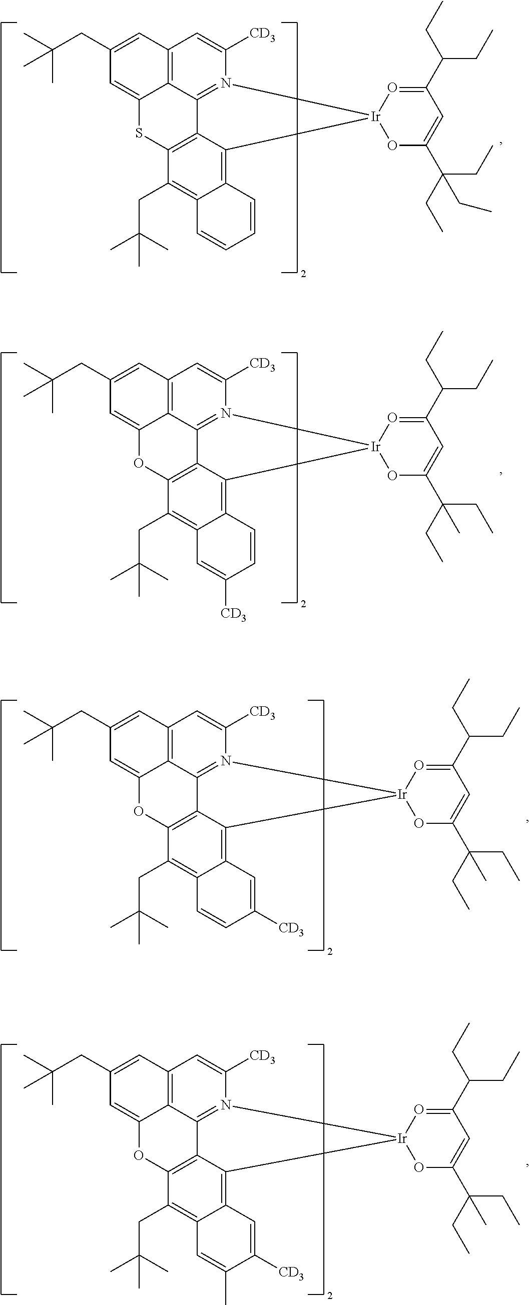

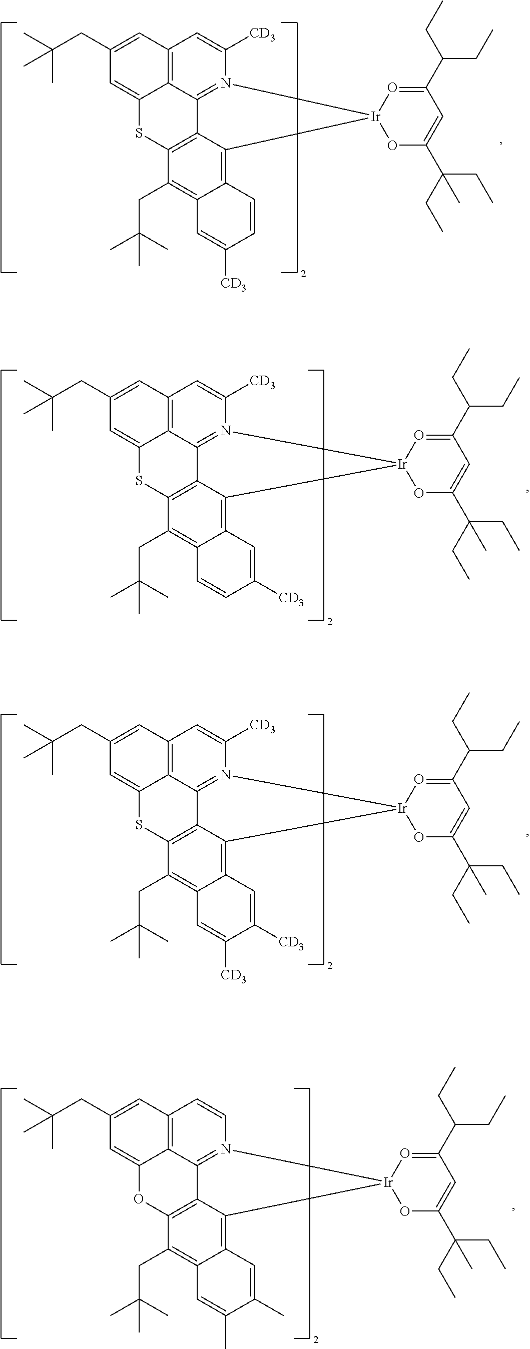

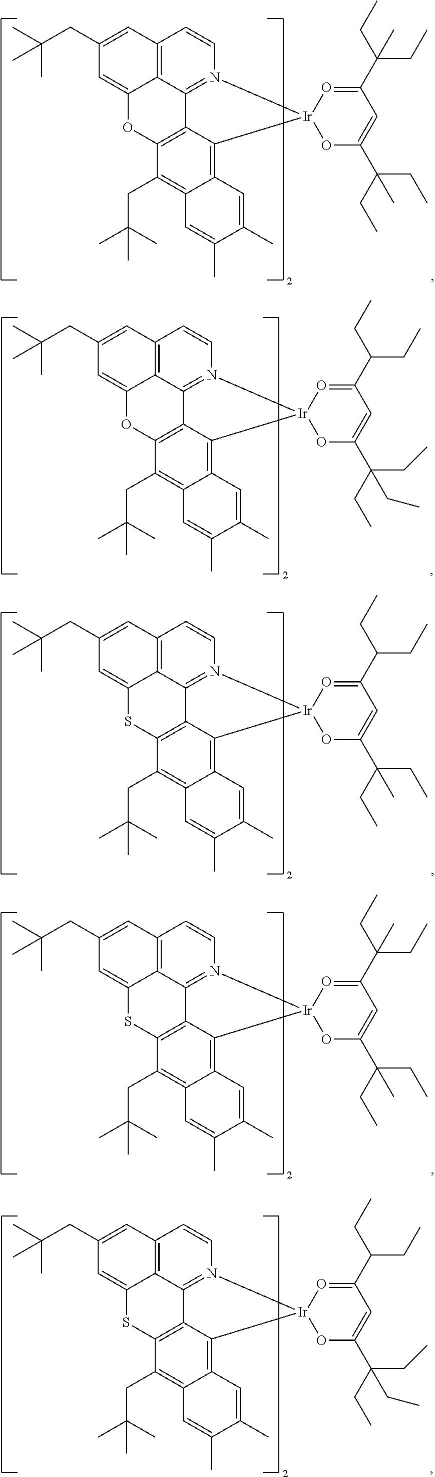

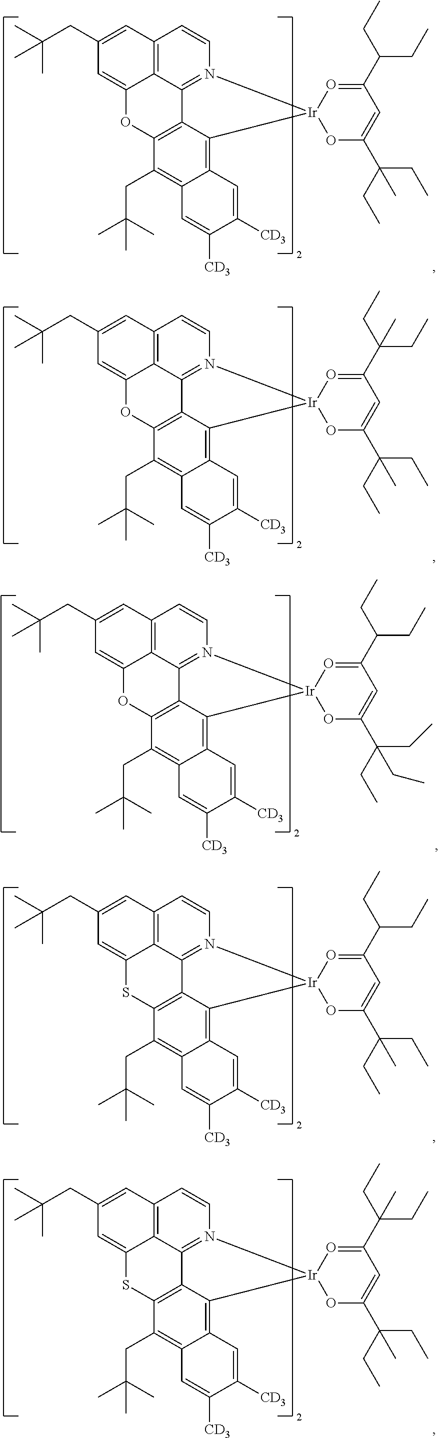

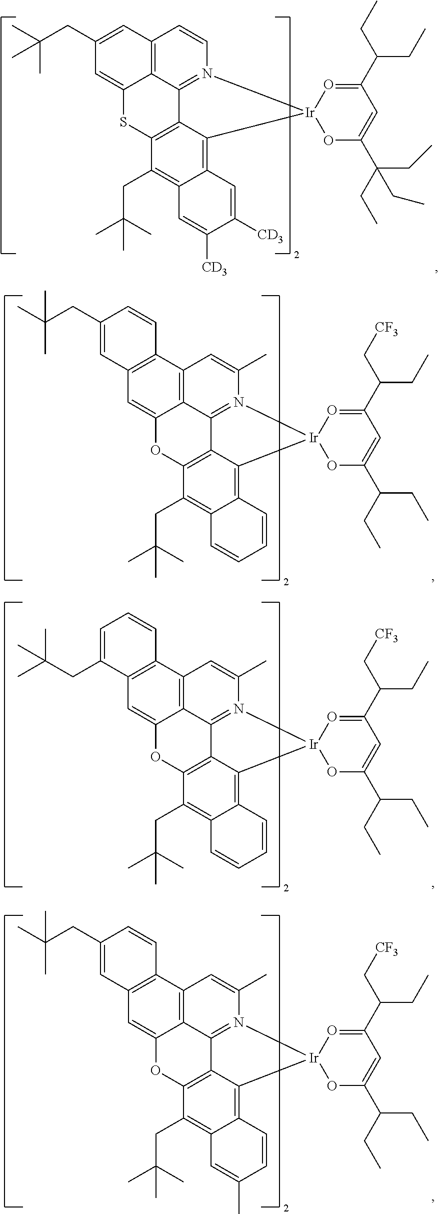

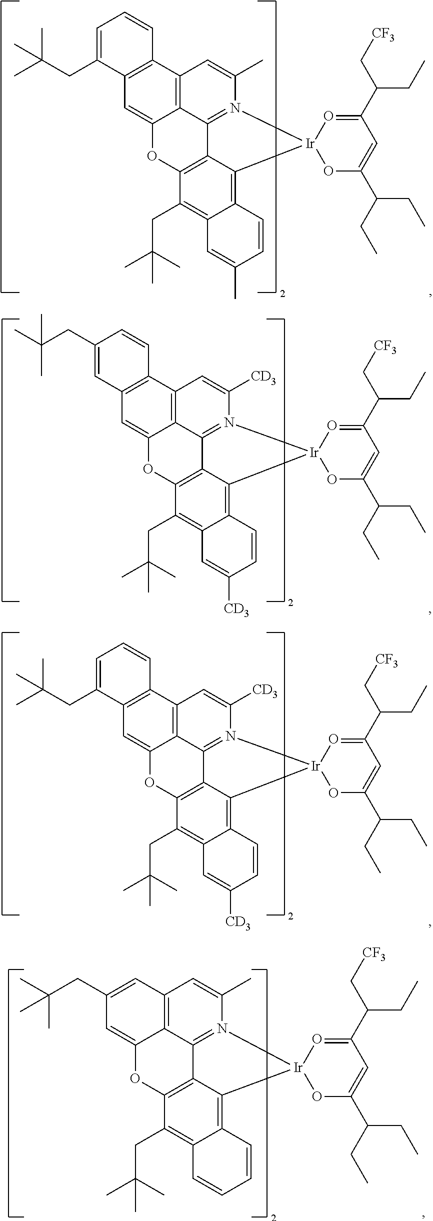

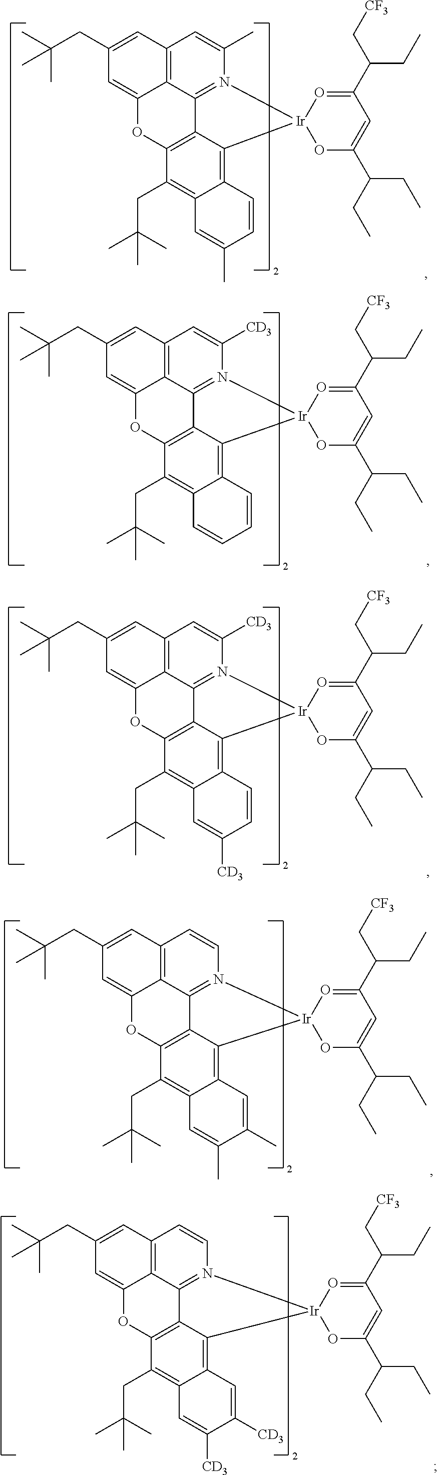

wherein in the above structures, TMS represents trimethylsilyl.

The above-listed specific structures of the phosphorescent material are exemplary and non-limiting. Of course, the phosphorescent material can not only be used in combination with the mixture of the present disclosure but also be used in combination with other host materials in the related art.

According to an embodiment of the present disclosure, in the preparation of the organic electroluminescent device of the present disclosure, when three or more host materials together with an emissive material are to be co-evaporated to form an emissive layer, this may be implemented in either of the following manners: (1) co-evaporating the three or more host materials and the emissive material from respective evaporation sources, to form the emissive layer; or (2) pre-mixing the three or more host materials to obtain a mixture, and co-evaporating the mixture from an evaporation source with the emissive material from another evaporation source, to form the emissive layer. The latter pre-mixing method can further save evaporation sources. For example, in the present disclosure, the first compound having a structure of Formula 1, the second compound having a structure of Formula 2, the third compound having a structure of Formula 1 or Formula 2 and the emissive material are co-evaporated from respective evaporation sources, to form the emissive layer; or the first compound, the second compound and the third compound are pre-mixed to obtain the mixture, and the mixture and the emissive material are co-evaporated from one evaporation source and the other evaporation source, to form the emissive layer.

According to an embodiment of the present disclosure, a method for preparing an electroluminescent device is further disclosed, wherein the electroluminescent device comprises the mixture of any one of the preceding embodiments. The method comprises the steps below.

In step 1, a substrate is provided, and a first electrode is formed on the substrate.

In step 2, the mixture of any one of the preceding embodiments is evaporated on the first electrode to form an organic layer.

In step 3, a second electrode is deposited on the organic layer.

The device prepared by the method of the present disclosure may also include other organic layers which may be disposed between the organic layer formed in step 2 and two electrode layers. The organic layer formed in step 2 is preferably an emissive layer which may further include another compound and preferably a phosphorescent compound.

According to another embodiment of the present disclosure, an electronic device is further disclosed. The electronic device comprises the electroluminescent device of any one of the preceding embodiments.

Combination with Other Materials

The materials described in the present disclosure for a particular layer in an organic light emitting device can be used in combination with various other materials present in the device. The combinations of these materials are described in more detail in U.S. Pat. Pub. No. US20160359122A1 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, the mixture and the compound composition disclosed herein may be used in combination with a wide variety of emissive dopants, hosts, transport layers, blocking layers, injection layers, electrodes and other layers that may be present. The combination of these materials is described in detail in paragraphs 0080-0101 of U.S. Pat. Pub. No. US20150349273A1, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

### Material Synthesis Example

Methods for preparing a first compound, a second compound and a third compound selected in the present disclosure are not limited herein. Typically, the following compounds are used as examples without limitation, and synthesis routes and preparation methods thereof are described below.

### Synthesis Example 1: Synthesis of Compound A-893

### Step 1: Synthesis of Intermediate 2

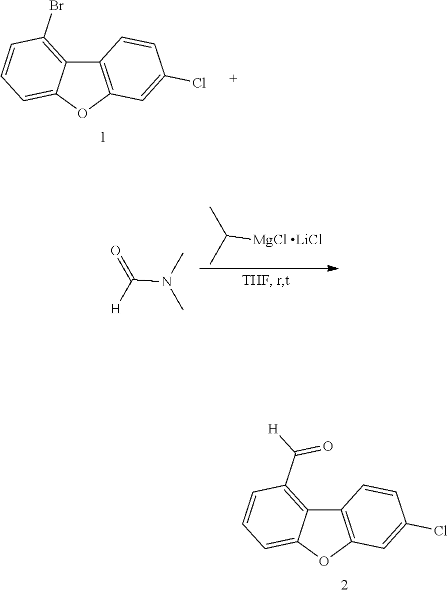

Under nitrogen protection, Intermediate 1 (100.00 g, 355.20 mmol) and THF (400 mL) were added to a three-necked flask, and a THE solution (409.85 mL, 532.80 mmol, 1.3 M) of isopropylmagnesium chloride-lithium chloride was slowly added dropwise at room temperature. After dropwise addition, the system was reacted for 5 h at room temperature. N,N-dimethylformamide (41.54 g, 568.32 mmol) was added dropwise and reacted for 3 h at room temperature. After the reaction was completed, the system was quenched with distilled water, the mixture was extracted with dichloromethane, and organic phases were washed with water and concentrated to remove a solvent. The crude product was purified through column chromatography (PE/DCM=3/1) to obtain Intermediate 2 as a white solid (70 g, with a yield of 85%).

### Step 2: Synthesis of Intermediate 4

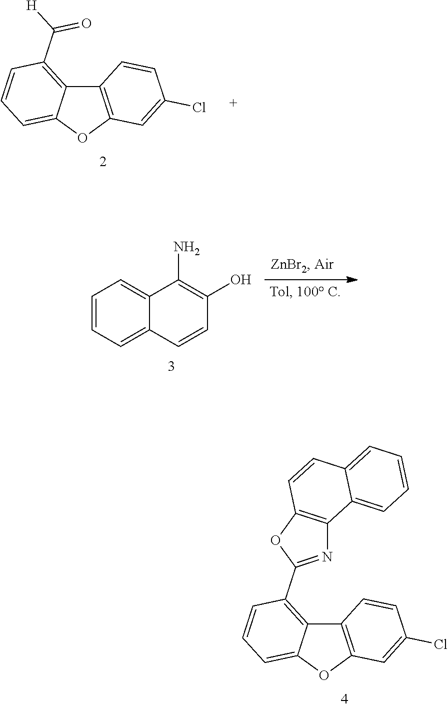 [SMILES: O=Cc1cccc2oc3cc(Cl)ccc3c12 ; Nc1c(O)ccc2ccccc12 ; Clc1ccc2c(c1)oc1cccc(-c3nc4c(ccc5ccccc54)o3)c12]

In an air atmosphere, Intermediate 2 (30 g, 130.07 mmol), Intermediate 3 (20.71 g, 130.07 mmol), zinc bromide (14.64 g, 65.03 mmol) and toluene (500 mL) were added to a three-necked flask and reacted for 120 h at 100° C. After the reaction was completed, the mixture was extracted with dichloromethane, and organic phases were washed with water and concentrated to remove a solvent. The crude product was purified through column chromatography (PE/DCM=1/1) to obtain Intermediate 4 as a white solid (30 g, with a yield of 62%).

### Step 3: Synthesis of Compound A-893

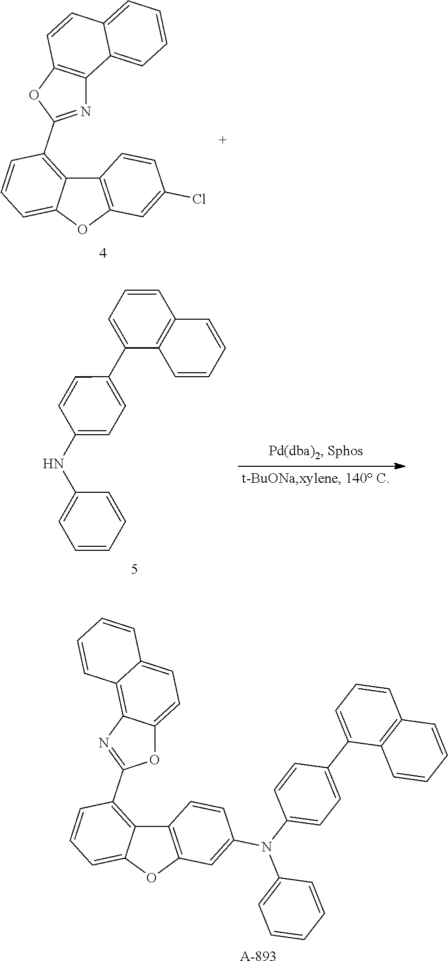

Under nitrogen protection, Intermediate 4 (9.0 g, 24.34 mmol), Intermediate 5 (7.91 g, 26.77 mmol), bis(dibenzylideneacetone) palladium (275.96 mg, 0.49 mmol), 2-dicyclohexylphosphino-2′,6′-dimethoxybiphenyl (Sphos, 399.65 mg, 0.97 mmol), sodium tert-butoxide (4.68 g, 48.67 mmol) and xylene (200 mL) were added to a three-necked flask and reacted for 2 h at 140° C. After the reaction was completed, the system was filtered to obtain a liquid, and the crude product was purified through column chromatography (PE/DCM=2/1) to obtain Compound A-893 as a yellow solid (10 g, with a yield of 65%). The product was confirmed as the target product with a molecular weight of 628.22.

### Synthesis Example 2: Synthesis of Compound A-890

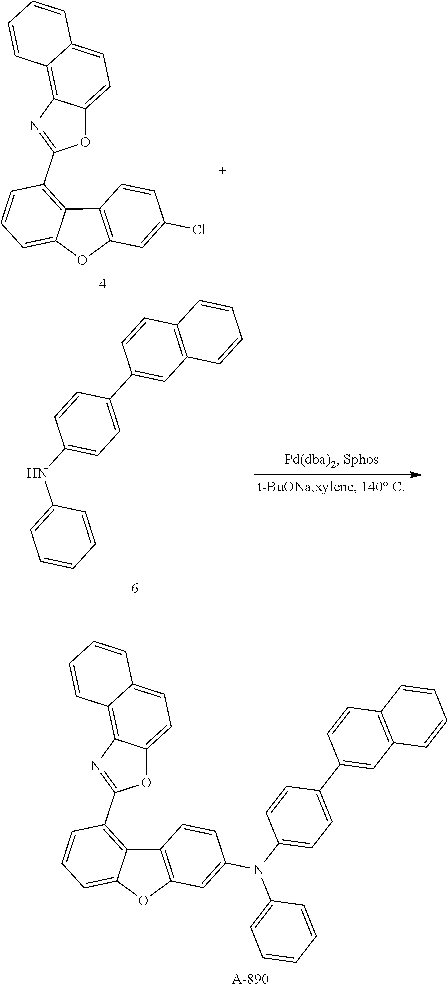

Under nitrogen protection, Intermediate 4 (2.0 g, 5.41 mmol), Intermediate 6 (1.76 g, 5.95 mmol), bis(dibenzylideneacetone) palladium (61.32 mg, 0.11 mmol), 2-dicyclohexylphosphino-2′,6-dimethoxybiphenyl (88.81 mg, 0.22 mmol), sodium tert-butoxide (1.04 g, 10.82 mmol) and xylene (50 mL) were added to a three-necked flask and reacted for 2 h at 140° C. After the reaction was completed, the system was filtered to obtain a liquid, and the crude product was purified through column chromatography (PE/DCM=2/1) to obtain Compound A-890 as a yellow solid (2.8 g, with a yield of 82%). The product was confirmed as the target product with a molecular weight of 628.22.

### Synthesis Example 3: Synthesis of Compound B-1

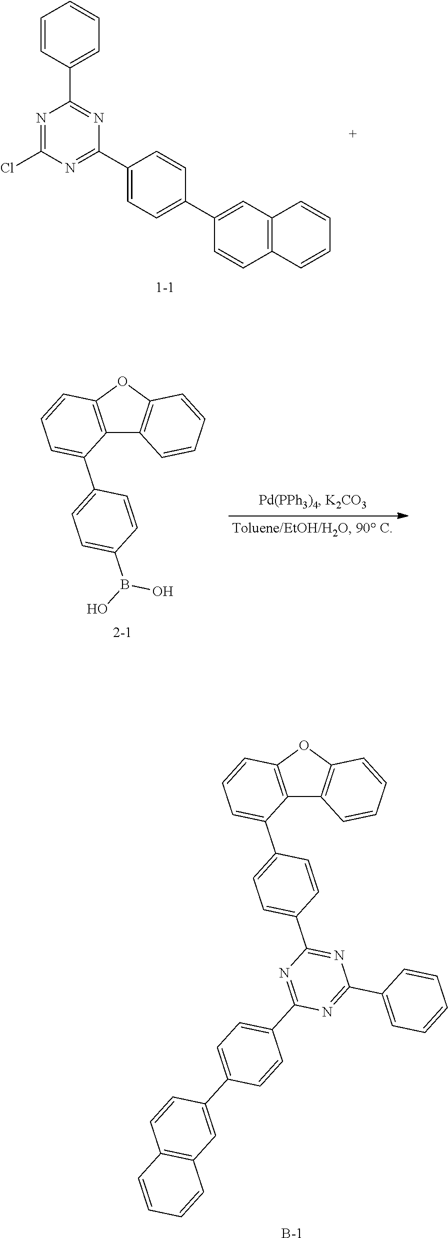

Under nitrogen protection, Intermediate 1-1 (8.2 g. 20.8 mmol), Intermediate 2-1 (6 g, 20.8 mmol), tetrakis(triphenylphosphine) palladium (721 mg, 0.6 mmol), potassium carbonate (5.7 g, 41.6 mmol) and a solvent (toluene (80 mL), ethanol (20 mL) and water (20 mL)) were added to a three-necked flask and reacted overnight at 90° C. After the reaction was completed, the system was cooled to room temperature, added with distilled water to precipitate a white solid, and filtered to obtain the solid. The solid was recrystallized from toluene to obtain Compound B-1 (9.3 g, with a yield of 74%). The product was confirmed as the target product with a molecular weight of 601.22.

### Synthesis Example 4: Synthesis of Compound B-4

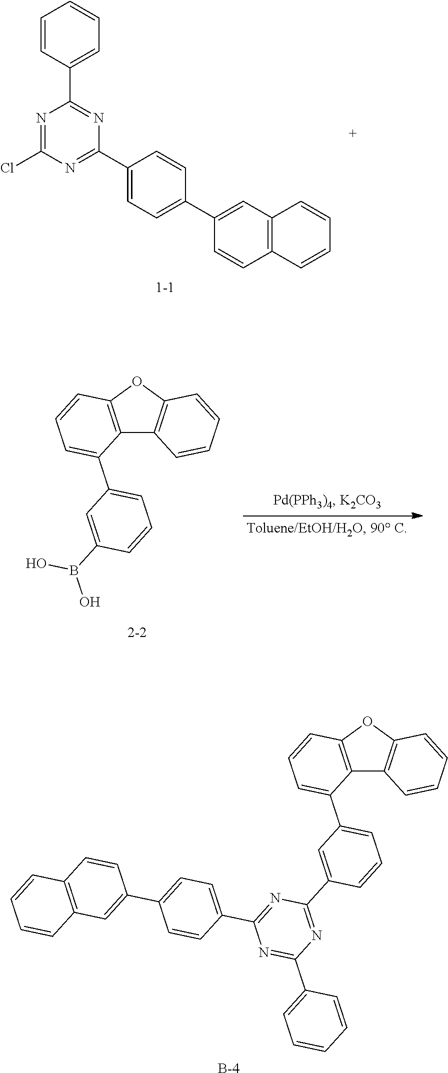

Under nitrogen protection, Intermediate 1-1 (6.9 g, 17.4 mmol), Intermediate 2-2 (5 g, 17.4 mmol), tetrakis(triphenylphosphine) palladium (603 mg, 0.5 mmol), potassium carbonate (4.8 g, 34.8 mmol) and a solvent (toluene (80 mL), ethanol (20 mL) and water (20 mL)) were added to a three-necked flask and reacted overnight at 90° C. After the reaction was completed, the system was cooled to room temperature, added with distilled water to precipitate a white solid, and filtered to obtain the solid. The solid was recrystallized from toluene to obtain Compound B-4 (8.2 g, with a yield of 78%). The product was confirmed as the target product with a molecular weight of 601.22.

Those skilled in the art will appreciate that the above preparation methods are merely exemplary. Those skilled in the art can obtain other compound structures selected in the present disclosure through modifications of the preparation methods.

Determination of a triplet energy level (T₁) of a compound: In the present disclosure, the triplet energy level (T₁) of the compound was determined at an ultralow temperature by utilizing the properties of triplet excitons with a long lifetime. Specifically, the compound to be tested was dissolved in a 2-methyltetrahydrofuran solvent to prepare a solution with a concentration of 10⁻⁵ M. The solution was loaded into a quartz tube, placed in a Dewar flask and cooled to 77 K. The solution of the compound to be tested was irradiated with a light source of 350 nm to measure a phosphorescence spectrum. The spectrum was measured using a spectrophotometer F98 produced by SHANGHAI LENGGUANG TECH. CO., LTD. In the phosphorescence spectrum, the vertical axis represents a phosphorescence intensity, and the horizontal axis represents a wavelength. A minimum value λ₁ (nm) of a peak on a short wavelength side of the phosphorescence spectrum was taken, and the wavelength value was substituted into the following conversion formula F₁ to calculate the triplet energy level of the compound to be tested. Conversion formula F₁: T₁ (eV)=1240/λ₁. According to the test results by the above method, triplet energy levels of some compounds of the present disclosure are recorded in Table 1.

TABLE 1
Triplet energy levels (T₁) of some compounds

| Compound No. | λ₁ (nm) | T₁ (eV) |
|---|---|---|
| Compound A-893 | 522 | 2.38 |
| Compound A-890 | 535 | 2.32 |
| Compound B-1 | 516 | 2.40 |
| Compound B-4 | 485 | 2.56 |

In the present disclosure, values of highest occupied molecular orbital (HOMO) energy levels and lowest unoccupied molecular orbital (LUMO) energy levels of all the compounds were measured by a cyclic voltammetry (CV) method. The test was conducted using an electrochemical workstation CorrTest CS120 produced by Wuhan Corrtest Instruments Corp., Ltd and using a three-electrode working system where a platinum disk electrode served as a working electrode, a Ag/AgNO₃ electrode served as a reference electrode, and a platinum wire electrode served as an auxiliary electrode. The test was conducted at a temperature of 25° C. With 0.1 mol/L tetrabutylammonium hexafluorophosphate as a supporting electrolyte and anhydrous DCM as a solvent, the compound to be tested was prepared into a 10⁻³ mol/L solution. Nitrogen was introduced into the solution for 10 min for oxygen removal before the test. The parameters of the instrument were set as follows: a scan rate of 100 mV/s, a potential interval of 0.5 mV and a test window of 1 V to −0.5 V. In the present disclosure, all “HOMO energy levels” and “LUMO energy levels” were expressed as negative values, and the smaller the value (i.e., the larger the absolute value), the deeper the energy level. “/” represents that the energy level was not tested.

TABLE 2
HOMO\LUMO energy levels of some compounds

| Compound | HOMO [eV] | LUMO [eV] |
|---|---|---|
| Compound A-893 | −5.344 | −2.534 |
| Compound A-890 | −5.326 | −2.532 |
| B-1 | / | −2.829 |
| B-4 | / | −2.811 |

In the present disclosure, the evaporation temperature of the compound was tested by a method of evaporating the compound to be tested by using an evaporator produced by Angstrom Engineering Incorporated. The compound to be tested was loaded into an evaporation source and evaporated at a rate of 2 Å/s and a vacuum degree of about 10⁻⁶ Torr, and the temperature required for evaporating the compound was the evaporation temperature. The evaporation temperatures required for evaporating Compound A-890, Compound A-893, Compound B-1 and Compound B-4 of the present disclosure by the above method are listed in Table 12.

TABLE 12
Evaporation temperatures of some compounds

| Compound No. | Evaporation Temperature (° C.) |
|---|---|
| Compound A-890 | 272 |
| Compound A-893 | 275 |
| Compound B-1 | 280 |
| Compound B-4 | 278 |

Multiple (typically three or more) raw materials are used to prepare an emission layer, which is conducive to obtaining a light-emitting device with better overall performance. However, if the device using multiple raw materials is prepared by the general preparation method, that is, each component is individually used as a separate evaporation source, the preparation process and cost increase significantly. A desired method is to pre-mix multiple components of materials to form a pre-mixture with high evaporation stability and use the pre-mixture as a single evaporation source, thereby reducing the complexity of a vacuum deposition process.

However, the stability of components in a film formed by evaporating a mixture has a relatively large effect on device performance. Therefore, the pre-mixture usable as a single evaporation source has to be co-evaporated stably, that is, a deviation between evaporation proportions in the compositions of films formed by evaporating the mixture should be as small as possible during the vacuum deposition process. Nevertheless, when two compounds are mixed, a potential interaction between the two compounds may affect evaporation and film formation stability, making it relatively difficult to achieve a stably co-evaporated mixture.

Through researches, the inventors provide a novel mixture comprising at least three hole and electron transport-type compounds having different structures from each other, wherein at least one hole transport-type compound contains an arylamino group. The mixture of the present disclosure can be stably co-evaporated from a single source. In particular, the mixture of the present disclosure comprising three or more different hole and electron transport-type compounds may select the hole and electron transport-type compounds with particular “heavy” and “light” evaporation characteristics to improve the evaporation and film formation stability of the mixture. The stability of the mixture can be demonstrated by analyzing the compositions of films formed from a single co-evaporation source containing the three-component pre-mixture. The details are described below.

### Mixture Example

Mixture Example 1: Compounds A-893, B-4 and B-1 were pre-melted and pre-mixed at a mass ratio of A-893:B-4:B-1=7:1:2 to form a mixture MX1 of the present disclosure. The mixture MX1 was ground into powder and loaded into an evaporation source, where the distance between the evaporation source and a glass substrate was set to 35-60 cm. The mixture MX1 was evaporated at a rate of 2 Å/s and a vacuum degree of about 10⁻⁶ Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 3.

The compositions (%) of the films deposited in sequence from the pre-mixture MX1, which were analyzed through HPLC, are recorded and shown in Table 3. HPLC analysis conditions: In the test, column used: ODS column; eluent: acetonitrile; detection wavelength: 235 nm.

TABLE 3
Proportions of components of the mixture MX1 in the films

| Film | A-893 (%) | B-4 + B-1 (%) |
|---|---|---|
| Film 1 | 69.375 | 30.625 |
| Film 2 | 69.372 | 30.628 |
| Film 3 | 69.414 | 30.586 |
| Film 4 | 69.418 | 30.582 |
| Film 5 | 69.538 | 30.462 |
| Film 6 | 69.684 | 30.316 |

Mixture Example 2: Compounds A-893, B-4 and B-1 were pre-melted and pre-mixed at a mass ratio of A-893:B-4:B-1=7:0.5:2.5 to form a mixture MX2 of the present disclosure. The pre-mixed mixture MX2 was ground into powder and loaded into an evaporation source, where the distance between the evaporation source and a glass substrate was set to 35-60 cm. The mixture MX2 was evaporated at a rate of 2 Å/s and a vacuum degree of about 10⁻⁶ Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 4.

The compositions (%) of the films deposited in sequence from the pre-mixture MX2, which were analyzed through HPLC, are recorded and shown in Table 4. HPLC analysis conditions: In the test, column used: ODS column; eluent: acetonitrile; detection wavelength: 235 nm.

TABLE 4
Proportions of components of the mixture MX2 in the films

| Film | A-893 (%) | B-4 + B-1 (%) |
|---|---|---|
| Film 1 | 70.464 | 29.536 |
| Film 2 | 70.835 | 29.165 |
| Film 3 | 70.662 | 29.338 |
| Film 4 | 70.541 | 29.459 |
| Film 5 | 70.393 | 29.607 |
| Film 6 | 70.474 | 29.526 |

Mixture Example 3: Compounds A-893, A-890 and B-1 were pre-melted and pre-mixed at a mass ratio of A-893:A-890:B-1=6:1:3 to form a mixture MX3 of the present disclosure. The pre-mixed mixture MX3 was ground into powder and loaded into an evaporation source, where the distance between the evaporation source and a glass substrate was set to 35-60 cm. The mixture MX3 was evaporated at a rate of 2 Å/s and a vacuum degree of about 10⁻⁶ Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 5.

The compositions (%) of the films deposited in sequence from the pre-mixture MX3, which were analyzed through HPLC, are recorded and shown in Table 5. HPLC analysis conditions: In the test, column used: ODS column; eluent: acetonitrile; detection wavelength: 235 nm.

TABLE 5
Proportions of components of the mixture MX3 in the films

| Film | A-893 + A-890 (%) | B-1 (%) |
|---|---|---|
| Film 1 | 70.037 | 29.963 |
| Film 2 | 70.293 | 29.707 |
| Film 3 | 70.278 | 29.722 |
| Film 4 | 70.212 | 29.788 |
| Film 5 | 70.140 | 29.860 |
| Film 6 | 70.285 | 29.715 |

Mixture Comparative Example 1: Compounds A-893 and B-1 were pre-melted and pre-mixed at a mass ratio of A-893:B-1=7:3 to form a comparative mixture C-MX1. The pre-mixed mixture was ground into powder and loaded into an evaporation source, where the distance between the evaporation source and a glass substrate was set to 35-60 cm. The mixture C-MX1 was co-evaporated at a rate of 2 Å/s and a vacuum degree of about 10⁻⁶ Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 6.

The compositions (%) of the films deposited in sequence from the two-component pre-mixture C-MX1, which were analyzed through HPLC, are recorded and shown in Table 6. HPLC analysis conditions: In the test, column used: ODS column; eluent: acetonitrile; detection wavelength: 235 nm.

TABLE 6
Proportions of components of the comparative
mixture C-MX1 in the films

| Film | A-893 (%) | B-1 (%) |
|---|---|---|
| Film 1 | 67.023 | 32.977 |
| Film 2 | 66.959 | 33.041 |
| Film 3 | 66.794 | 33.206 |
| Film 4 | 66.495 | 33.505 |
| Film 5 | 66.104 | 33.896 |
| Film 6 | 65.397 | 34.603 |

Mixture Comparative Example 2: Compounds A-893 and B-4 were pre-melted and pre-mixed at a mass ratio of A-893:B-4=7:3 to form a comparative mixture C-MX2. The pre-mixed mixture was ground into powder and loaded into an evaporation source, where the distance between the evaporation source and a glass substrate was set to 35-60 cm. The mixture was co-evaporated at a rate of 2 Å/s and a vacuum degree of about 10⁻⁶ Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 7.

The compositions (%) of the films deposited in sequence from the two-component pre-mixture C-MX2, which were analyzed through HPLC, are recorded and shown in Table 7. HPLC analysis conditions: In the test, column used: ODS column; eluent: acetonitrile; detection wavelength: 235 nm.

TABLE 7
Proportions of components of the comparative
mixture C-MX2 in the films

| Film | A-893 (%) | B-4 (%) |
|---|---|---|
| Film 1 | 64.165 | 35.835 |
| Film 2 | 65.223 | 34.777 |
| Film 3 | 66.358 | 33.642 |
| Film 4 | 68.000 | 32.000 |
| Film 5 | 70.329 | 29.671 |
| Film 6 | 72.663 | 27.337 |

Mixture Comparative Example 3: Compounds A-890 and B-1 were pre-melted and pre-mixed at a mass ratio of A-890:B-1=6:4 to form a comparative mixture C-MX3. The pre-mixed mixture was ground into powder and loaded into an evaporation source, where the distance between the evaporation source and a glass substrate was set to 35-60 cm. The mixture was co-evaporated at a rate of 2 Å/s and a vacuum degree of about 10% Torr and deposited onto the glass substrate. After a film with a thickness of 400 Å was deposited, the substrate was continually replaced without stopping the deposition or cooling of the evaporation source, thereby forming multiple films, each with a thickness of 400 Å. The compositions of the films were analyzed through HPLC, and the results were summarized in Table 8.

The compositions (%) of the films deposited in sequence from the two-component pre-mixture C-MX3, which were analyzed through HPLC, are recorded and shown in Table 8. HPLC analysis conditions: In the test, column used: ODS column; eluent: acetonitrile; detection wavelength: 235 nm.

TABLE 8
Proportions of components of the comparative
mixture C-MX3 in the films

| Film | A-890 (%) | B-1 (%) |
|---|---|---|
| Film 1 | 48.708 | 51.292 |
| Film 2 | 51.902 | 48.098 |
| Film 3 | 52.886 | 47.114 |
| Film 4 | 56.418 | 43.582 |
| Film 5 | 61.109 | 38.891 |
| Film 6 | 69.547 | 30.453 |

Discussion: As can be seen from the data in Table 3 to Table 8, the mixture of the present disclosure comprising three or more hole and electron transport-type compounds with different structures particularly selects the hole transport-type compound comprising the arylamino group in combination with two or more other compounds so that the desired stable co-evaporation from a single source can be achieved.

According to the data in Table 3 to Table 8, the stability in the mass proportions of a certain component in the films is calculated, where Cₘ represents a mass proportion of the compound in the m-th film, C₀ represents a mass proportion of the compound in the pre-mixture, |Cₘ−C₀| represents an absolute value of a difference between Ce and the mass proportion Cₘ of the compound in any one of the n films, wherein m is an integer selected from 1 to n, and |Cₘ−C₀|ₘₐₓ represents a maximum value of the absolute value of the difference between C₀ and the mass proportion Cₘ of the compound in any one of the n films. A-893 was used as examples in Tables 3, 4, 6 and 7. B-1 was used as examples in Tables 5 and 8. The data are shown in Table

TABLE 9
Stability data of the films

| Mixture No. | \|Cₘ − C₀\|ₘₐₓ | Mixture No. | \|Cₘ − C₀\|ₘₐₓ |
|---|---|---|---|
| MX1 | 0.628% | C-MX1 | 4.603% |
| MX2 | 0.835% | C-MX2 | 5.835% |
| MX3 | 0.293% | C-MX3 | 11.292% |

The above data were calculated as follows: with MX1 as an example, as can be seen from Mixture Example 1, C₀ of Compound A-893 was 70%, n=6, and m is selected from 1, 2, 3, 4, 5 or 6; |_{C1}−C₀|=0.625%, |C₂−C₀|=0.628%, |C₃−C₀|=0.586%, |C₄−C₀|=0.582%, |C₅−C₀|=0.462%, and |C₆−C₀|=0.316%; according to the above data, it can be determined that |Cₘ−C₀|ₘₐₓ=0.628%.

As can be seen from the data in Table 9, the mass proportions of components in the films prepared from each of the mixtures MX1 to MX3 only fluctuated slightly. The above data proved that the mixture of the present disclosure, when evaporated as a single evaporation source, has higher stability and can simplify a production process and reduce a production cost when used in an OLED device.

In particular, the inventors have further found that the hole and electron transport-type compounds with particular “heavy” and “light” evaporation characteristics are selected to be mixed to form the mixture of the present disclosure so that the evaporation stability of the mixture can be further improved. Specifically, as can be seen from the data in Table 6, the mass ratios of the hole transport-type compound A-893 in films 1 to 6 show an overall decreasing trend, that is, A-893 is lighter than B-1. Similarly, as can be seen from the data in Table 8, the mass ratios of the hole transport-type compound A-890 in films 1 to 6 show an overall increasing trend, that is, A-890 is heavier than B-1. In Mixture Example 3, the electron transport-type compound B-1, the hole transport-type compound A-890 “heavier” than B-1 and the hole transport-type compound A-893 “lighter” than B-1 were pre-mixed to form the mixture MX3. As can be seen from the data in Table 9, fluctuations of the component in the films prepared from MX3 were further reduced to even below 0.3%, and MX3 has further improved evaporation stability compared with MX1 and MX2 that have relatively high evaporation stability.

Additionally, when used to prepare the device, the mixture of the present disclosure can not only simplify the process but also obtain good overall device performance. To verify the above viewpoints of the inventors, several OLED device examples prepared using the pre-mixtures of the present disclosure are provided below.

### DEVICE EXAMPLE

### Device Example 1

Firstly, a glass substrate having an indium tin oxide (ITO) anode with a thickness of 120 nm was cleaned and then treated with oxygen plasma and UV ozone. After the treatment, the substrate was dried in a nitrogen-filled glovebox to remove moisture and then mounted on a substrate holder and placed in a vacuum chamber. Organic layers specified below were sequentially evaporated through vacuum thermal evaporation on the ITO anode at a rate of 0.01-5 Å/s and a vacuum degree of about 106 Torr. Compound HT and Compound HI were co-evaporated for use as a hole injection layer (HIL) with a thickness of 100 Å. Compound HT was used as a hole transporting layer (HTL) with a thickness of 400 Å. Compound EB was used as an electron blocking layer (EBL) with a thickness of 50 Å. Then, the mixture which served as the host and which was formed by pre-mixing Compound A-893, Compound A-890 and Compound B-1 (the mass ratio among Compound A-893, Compound A-890 and Compound B-1 in the mixture was 6:1:3) was loaded into one evaporation source and co-evaporated with Compound RD-1 serving as a dopant in another evaporation source as an emissive layer (EML) with a thickness of 400 Å. Compound HB was used as a hole blocking layer (HBL) with a thickness of 50 Å. On the HBL, Compound ET and 8-hydroxyquinolinolato-lithium (Liq) were co-evaporated for use as an electron transporting layer (ETL) with a thickness of 350 Å. Finally, 8-hydroxyquinolinolato-lithium (Liq) was evaporated for use as an electron injection layer (EIL) with a thickness of 10 Å, and aluminum was evaporated for use as a cathode with a thickness of 1200 Å. The device was transferred back to the glovebox and encapsulated with a glass lid to complete the device.

### Device Example 2

Device Example 2 was implemented in the same manner as Device Example 1 except that the mixture which served as the host and which was formed by pre-mixing Compound A-893, Compound B-4 and Compound B-1 (the mass ratio among Compound A-893, Compound B-4 and Compound B-1 in the mixture was 7:1:2) was loaded into one evaporation source and co-evaporated with Compound RD-1 serving as a dopant in another evaporation source as an emissive layer (EML) with a thickness of 400 Å.

### Device Example 3

Device Example 3 was implemented in the same manner as Device Example 2 except that the mixture which served as the host and which was formed by pre-mixing Compound A-893, Compound B-4 and Compound B-1 (the mass ratio among Compound A-893, Compound B-4 and Compound B-1 in the mixture was 7:0.5:2.5) was loaded into one evaporation source and co-evaporated with Compound RD-2 serving as a dopant (with a doping proportion of 3%) in another evaporation source as an emissive layer (EML) with a thickness of 400 Å.

Detailed structures and thicknesses of layers of the devices are shown in Table 10. A layer using more than one material is obtained by doping different compounds at their mass ratio as recorded.

TABLE 10
Device structures of Device Examples 1 to 3

| Device ID | HIL | HTL | EBL | EML | HBL | ETL |
|---|---|---|---|---|---|---|
| Example 1 | Compound | Compound | Compound | (Compound | Compound | Compound |
| | HT:Compound | HT | EB | A-893:Compound | HB | ET:Liq |
| | HI (97:3) | (400 Å) | (50 Å) | A-890:Compound | (50 Å) | (40:60) |
| | (100 Å) | | | B-1):Compound RD-1 | | (350 Å) |
| | | | | (98:2) (400 Å) | | |
| Example 2 | Compound | Compound | Compound | (Compound | Compound | Compound |
| | HT:Compound | HT | EB | A-893:Compound | HB | ET:Liq |
| | HI (97:3) | (400 Å) | (50 Å) | B-4:Compound | (50 Å) | (40:60) |
| | (100 Å) | | | B-1):Compound RD-1 | | (350 Å) |
| | | | | (98:2) (400 Å) | | |
| Example 3 | Compound | Compound | Compound | (Compound | Compound | Compound |
| | HT:Compound | HT | EB | A-893:Compound | HB | ET:Liq |
| | HI (97:3) | (400 Å) | (50 Å) | B-4:Compound | (50 Å) | (40:60) |
| | (100 Å) | | | B-1):Compound RD-2 | | (350 Å) |
| | | | | (97:3) (400 Å) | | |

The compounds used in the devices have the following structures:

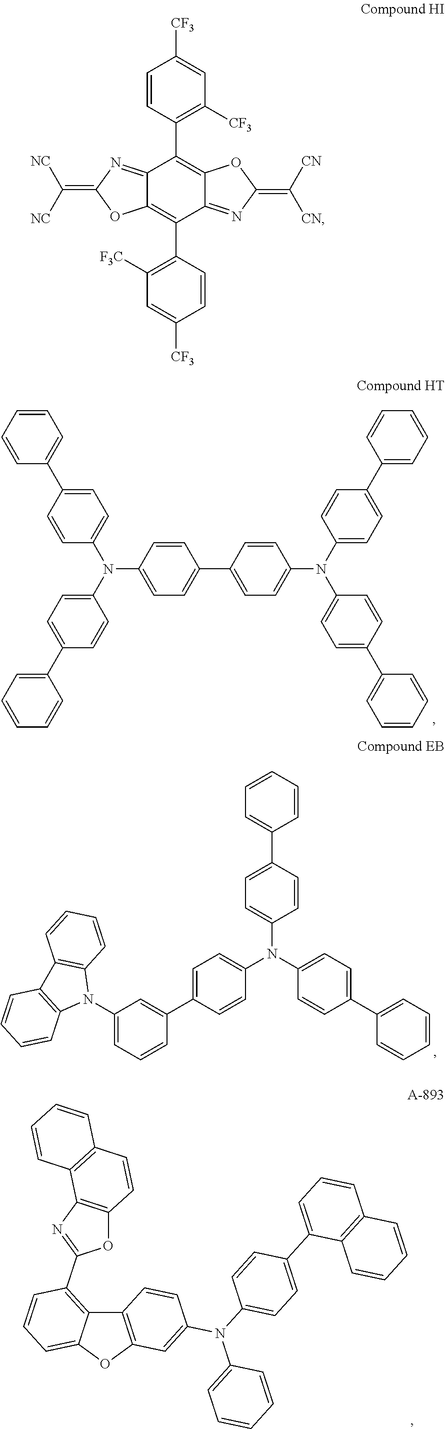 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(N(c2ccc(-c3cccc4ccccc34)cc2)c2ccc3c(c2)oc2cccc(-c4nc5c(ccc6ccccc65)o4)c23)cc1]

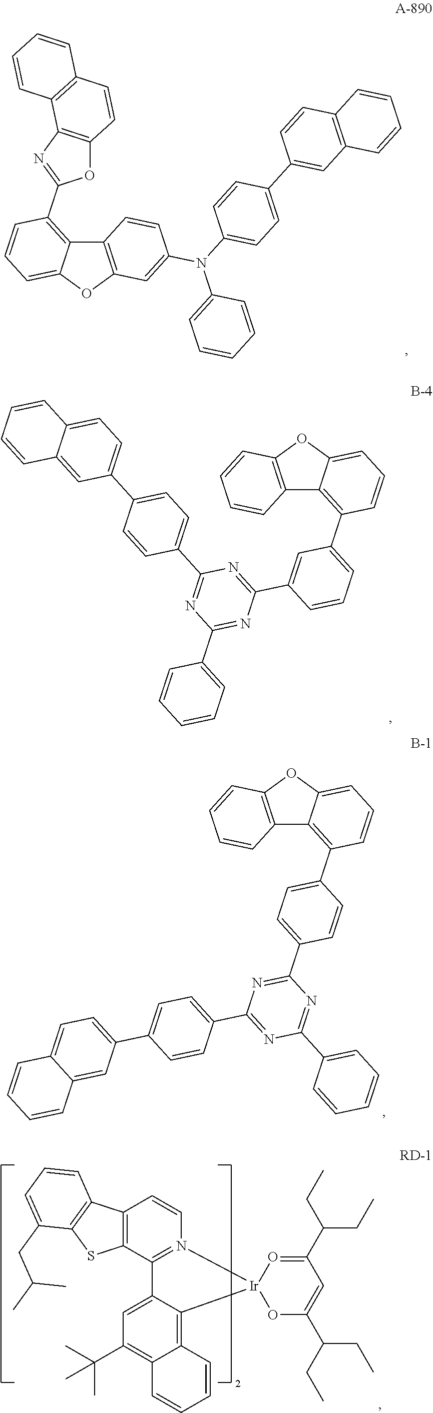

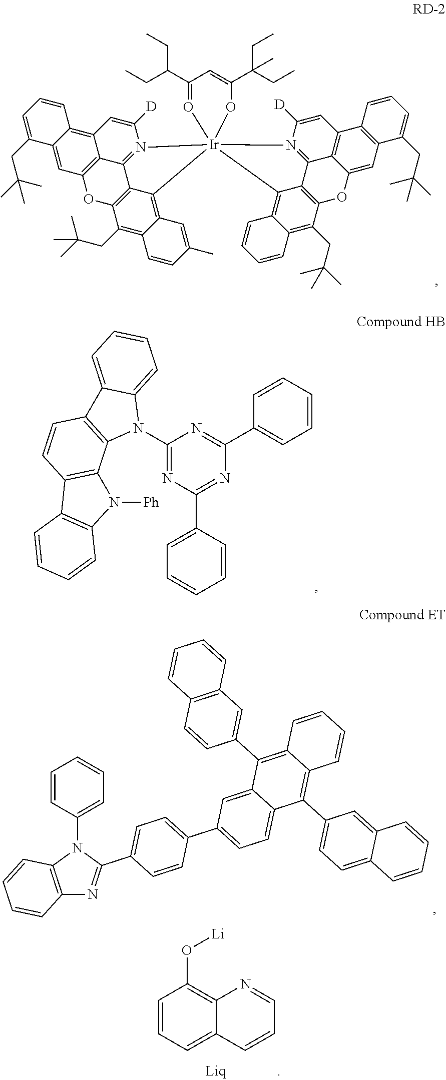

Table 11 lists the maximum emission wavelengths (λₘₐₓ), current efficiency (CE) and external quantum efficiency (EQE) of the device examples measured at a constant current of 10 mA/cm² and the device lifetimes (LT95) measured at a constant current of 80 mA/cm², where the device lifetime (LT95) refers to a time required for the device to decay to 95% of its initial brightness.

TABLE 11
Device data of Device Examples 1 to 3

| Device ID | λₘₐₓ (nm) | CE [cd/A] | EQE [%] | LT95 (h) |
|---|---|---|---|---|
| Example 1 | 622 | 29.2 | 27.4 | 279 |
| Example 2 | 622 | 30.0 | 28.0 | 310 |
| Example 3 | 621 | 29.5 | 27.3 | 255 |

### Discussion

As can be seen from the data in Table 11, the above devices were electroluminescent devices prepared by the emissive layers formed by co-evaporating the mixture of the present disclosure as a single evaporation source and an emissive material in another evaporation source. For example, the emissive layer of Device Example 1 was formed by co-evaporating the mixture of the present disclosure (formed by pre-mixing Compound A-893, Compound A-890 and Compound B-1) as a single evaporation source and Compound RD-1.

The data in Table 11 demonstrated that Device Examples 1 to 3 all had relatively high external quantum efficiency (EQE) and relatively long device lifetimes and exhibited good overall device performance. It can be seen that the mixtures of the present disclosure have high evaporation stability and can be used as a single evaporation source in the preparation process of the OLED device, which can simplify the production process and reduce the production cost. Moreover, Device Examples 1 to 3 using the mixtures as host materials have achieved good performance: relatively long lifetimes and relatively high efficiency.

The above data demonstrate that the novel mixture of the present disclosure comprising three electron and hole transporting materials with different structures selects a particular hole transporting material comprising the arylamine group in combination with two or more other materials so that the mixture has high evaporation stability. Such novel mixtures in combination with different phosphorescent doping materials can achieve very good device 5 performance and have broad application prospects.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. A mixture, comprising at least a first compound, a second compound and a third compound;
wherein the first compound is a hole transport-type compound, the second compound is an electron transport-type compound, and the third compound is selected from a hole transport-type compound or an electron transport-type compound;
the hole transport-type compound contains an arylamino group;
the first compound, the second compound and the third compound have chemical structures different from each other;
the mixture comprises a pre-mixture formed by pre-mixing the first compound, the second compound and the third compound, a mass proportion of at least one compound of the first compound, the second compound or the third compound in the mixture is C₀, and when the mixture is evaporated at a rate of 0.01-5 Å/s and a vacuum degree of 10⁻⁶ Torr or lower, the pre-mixture is evaporated on a surface positioned at a certain distance from the mixture to be evaporated to form n films, each with a certain thickness, and a mass proportion of the at least one compound in the n-th film is Cₙ, wherein n is an integer greater than or equal to 1; and
an absolute value of a difference between C₀ and a mass proportion Cₘ of the at least one compound in any one of the evaporated n films satisfies that |Cₘ−C₀|≤2%, wherein m is an integer selected from 1 to n.

2. The mixture according to claim 1, wherein the mass proportion of the at least one compound of the first compound, the second compound or the third compound in the mixture is C₀, and when the mixture is evaporated at a rate of 0.01-5 Å/s and a vacuum degree of 10⁻⁶ Torr or lower, the mixture is evaporated on the surface positioned at the certain distance from the mixture to be evaporated to form n films, each with a certain thickness, and the mass proportion of the at least one compound in the n-th film is Cₙ, wherein n is an integer greater than or equal to 1; and the absolute value of the difference between C₀ and the mass proportion Cₘ of the at least one compound in any one of the evaporated n films satisfies that |Cₘ−C₀|≤1.5%; preferably, |Cₘ−C₀|≤1.0%.

3. The mixture according to claim 1, wherein when the third compound is selected from the hole transport-type compound, the third compound is heavier than the second compound and the first compound is lighter than the second compound in evaporation characteristics; and
when the third compound is selected from the electron transport-type compound, the second compound is heavier than the first compound and the third compound is lighter than the first compound in evaporation characteristics.

4. The mixture according to claim 1, wherein when the first compound, the second compound and the third compound are separately evaporated at a rate of 0.01-5 Å/s and a vacuum degree of 10⁻⁶ Torr or lower, an absolute value of a difference between evaporation temperatures of any two of the first compound, the second compound and the third compound is less than 30° C.; preferably, the absolute value of the difference between the evaporation temperatures of any two of the first compound, the second compound and the third compound is less than 20° C.; more preferably, the absolute value of the difference between the evaporation temperatures of any two of the first compound, the second compound and the third compound is less than 10° C.

5. The mixture according to claim 1, wherein evaporation temperatures of the first compound, the second compound and the third compound are between 120° C. and 390° C.; preferably, the evaporation temperatures of the first compound, the second compound and the third compound are between 140° C. and 370° C.; more preferably, the evaporation temperatures of the first compound, the second compound and the third compound are between 160° C. and 360° C.; most preferably, the evaporation temperatures of the first compound, the second compound and the third compound are between 200° C. and 350° C.

6. The mixture according to claim 1, wherein at least one of the first compound, the second compound or the third compound has a triplet energy level T₁<2.65 eV; preferably, T₁<2.60 eV.

7. The mixture according to claim 1, wherein the hole transport-type compound and/or the electron transport-type compound contain at least one chemical group selected from the group consisting of oxazole, thiazole, benzoxazole, benzothiazole, naphthoxazole, naphthothiazole, benzothiophene, benzofuran, dibenzothiophene, dibenzofuran, aza-dibenzothiophene, azadibenzofuran, dibenzoselenophene, benzene, pyridine, pyrimidine, carbazole, azacarbazole, indolocarbazole, triphenylene, azatriphenylene, fluorene, silafluorene, naphthalene, quinoline, isoquinoline, quinazoline, quinoxaline, phenanthrene, azaphenanthrene and combinations thereof;
preferably, the hole transport-type compound contains a benzoxazole group or a naphthoxazole group, and the electron transport-type compound contains a triazine group.

8. The mixture according to claim 1, wherein the first compound has a structure represented by Formula 1: 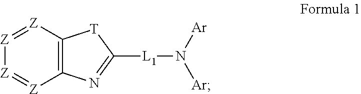
wherein
Ar is, at each occurrence identically or differently, selected from substituted or unsubstituted aryl having 6 to 30 carbon atoms, substituted or unsubstituted heteroaryl having 3 to 30 carbon atoms or a combination thereof;
L₁ is selected from a single bond, substituted or unsubstituted arylene having 6 to 30 carbon atoms, substituted or unsubstituted heteroarylene having 3 to 30 carbon atoms or a combination thereof;
Z is, at each occurrence identically or differently, selected from N or CR_{z}; and
T is selected from O, S or Se;
preferably, the first compound has a structure represented by Formula 1′: 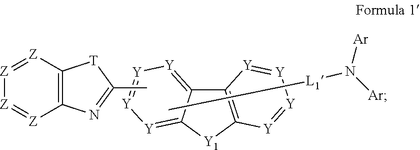
wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Y is, at each occurrence identically or differently, selected from N, C or CR_{y};
L₁′ is selected from a single bond, substituted or unsubstituted arylene having 6 to 30 carbon atoms, substituted or unsubstituted heteroarylene having 3 to 30 carbon atoms or a combination thereof;
T is selected from O, S or Se;
Z is, at each occurrence identically or differently, selected from N or CR_{z};
Y₁ is selected from O, S, Se, CR_{y1}R_{y1}, SiR_{y1}R_{y1} or NRₙ;
R_{z}, R_{y}, R_{y1} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring;
adjacent substituents R_{y} can be optionally joined to form a ring; and
adjacent substituents R_{y1} can be optionally joined to form a ring.

9. The mixture according to claim 1, wherein the first compound has a structure represented by Formula 1-1: 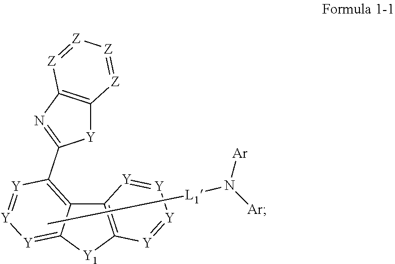
wherein Ar is, at each occurrence identically or differently, selected from substituted or unsubstituted aryl having 6 to 30 carbon atoms, substituted or unsubstituted heteroaryl having 3 to 30 carbon atoms or a combination thereof,
Y is, at each occurrence identically or differently, selected from N, C or CR_{y}, and at least one Y is selected from C and joined to L₁′;
L₁′ is selected from a single bond, substituted or unsubstituted arylene having 6 to 30 carbon atoms, substituted or unsubstituted heteroarylene having 3 to 30 carbon atoms or a combination thereof;
T is selected from O, S or Se;
Z is, at each occurrence identically or differently, selected from N or CR_{z};
Y₁ is selected from O, S, Se, CR_{y1}R_{y1}, SiR_{y1}R_{y1} or NRₙ;
R_{z}, R_{y}, R_{y1} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring;
adjacent substituents R_{y} can be optionally joined to form a ring; and
adjacent substituents R_{y1} can be optionally joined to form a ring;
preferably, the first compound has a structure represented by one of Formula 1-2 to Formula 1-4: 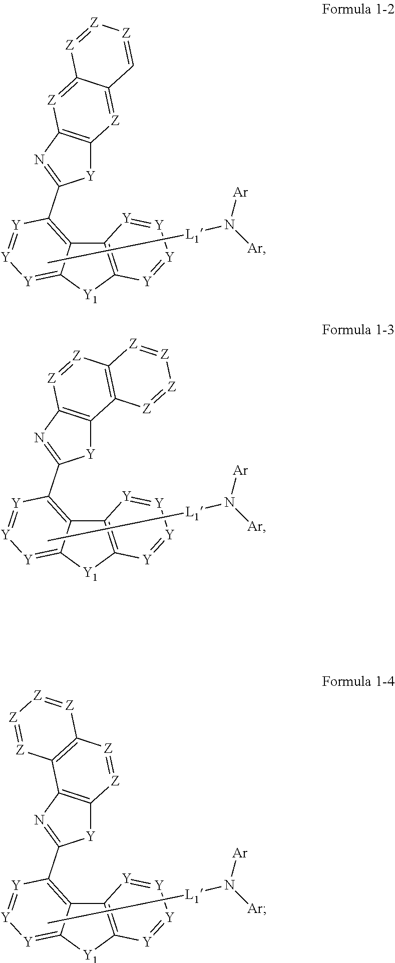
more preferably, the first compound has a structure represented by Formula 1-2 or Formula 1-4.

10. The mixture according to claim 8, wherein T is selected from O or S; preferably, T is selected from O.

11. The mixture according to claim 8, wherein Y₁, is selected from O, S, CR_{y1}R_{y1} or NRₙ; preferably, Y₁ is selected from O or S.

12. The mixture according to claim 8, wherein R_{z}, Rₙ, R_{y} and R_{y1} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms and combinations thereof; adjacent substituents R_{z} can be optionally joined to form a ring; and adjacent substituents R_{y1} can be optionally joined to form a ring;
preferably, R_{z}, Rₙ, R_{y} and R_{y1} are, at each occurrence identically or differently, selected from the group consisting of: hydrogen, deuterium, fluorine, phenyl, pyridyl, pyrimidinyl, vinyl, naphthyl, biphenyl, phenanthryl, triphenylenyl, dibenzofuryl, dibenzothienyl, carbazolyl, chrysenyl, methyl, ethyl, t-butyl, adamantyl, cyclohexyl, cyclopentyl and combinations thereof.

13. The mixture according to claim 1, wherein the first compound is selected from the group consisting of Compound A-1 to Compound A-1378, wherein specific structures of Compound A-1 to Compound A-1378 are as follows: 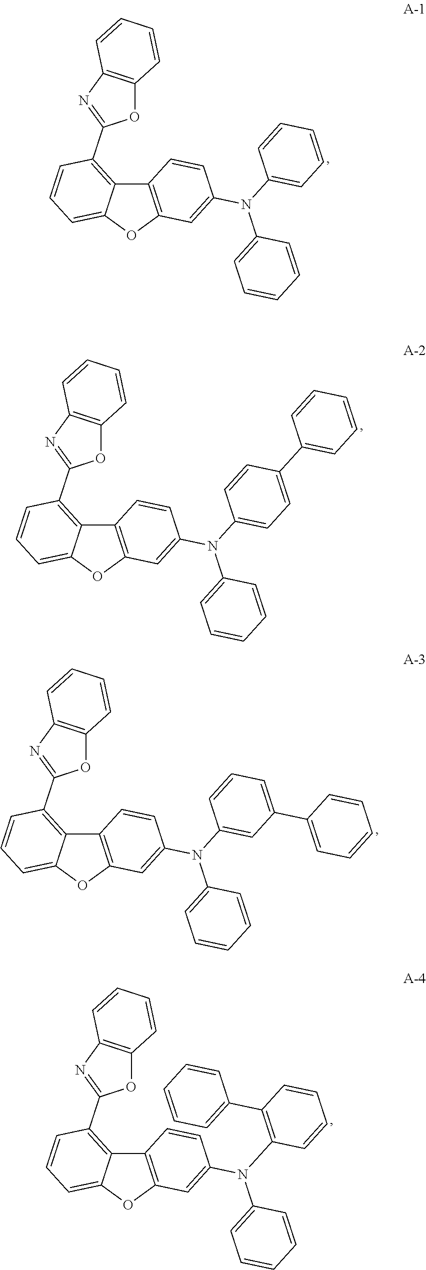 [SMILES: c1ccc(N(c2ccccc2)c2ccc3c(c2)oc2cccc(-c4nc5ccccc5o4)c23)cc1 ; c1ccc(-c2ccc(N(c3ccccc3)c3ccc4c(c3)oc3cccc(-c5nc6ccccc6o5)c34)cc2)cc1 ; c1ccc(-c2cccc(N(c3ccccc3)c3ccc4c(c3)oc3cccc(-c5nc6ccccc6o5)c34)c2)cc1 ; c1ccc(-c2ccccc2N(c2ccccc2)c2ccc3c(c2)oc2cccc(-c4nc5ccccc5o4)c23)cc1] 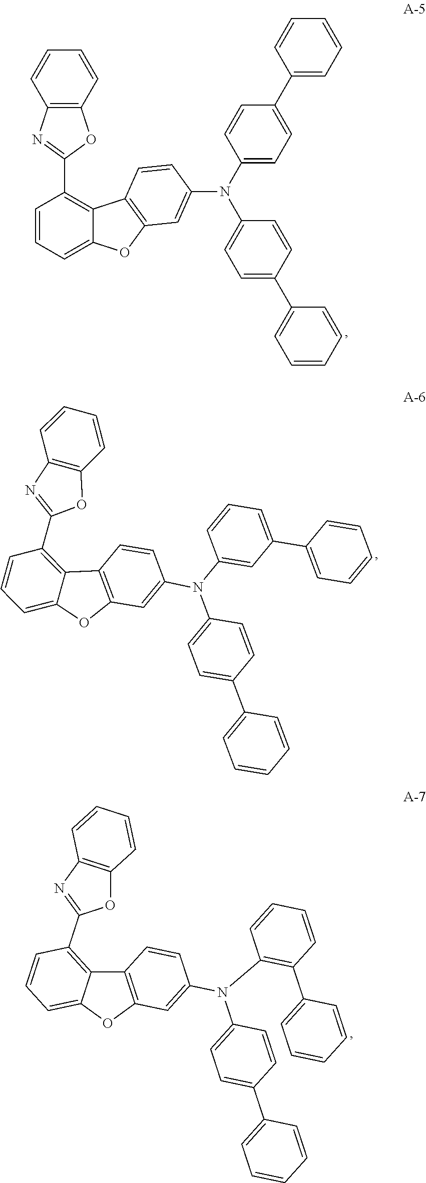 [SMILES: c1ccc(-c2ccc(N(c3ccc(-c4ccccc4)cc3)c3ccc4c(c3)oc3cccc(-c5nc6ccccc6o5)c34)cc2)cc1 ; c1ccc(-c2ccc(N(c3cccc(-c4ccccc4)c3)c3ccc4c(c3)oc3cccc(-c5nc6ccccc6o5)c34)cc2)cc1 ; c1ccc(-c2ccc(N(c3ccc4c(c3)oc3cccc(-c5nc6ccccc6o5)c34)c3ccccc3-c3ccccc3)cc2)cc1] 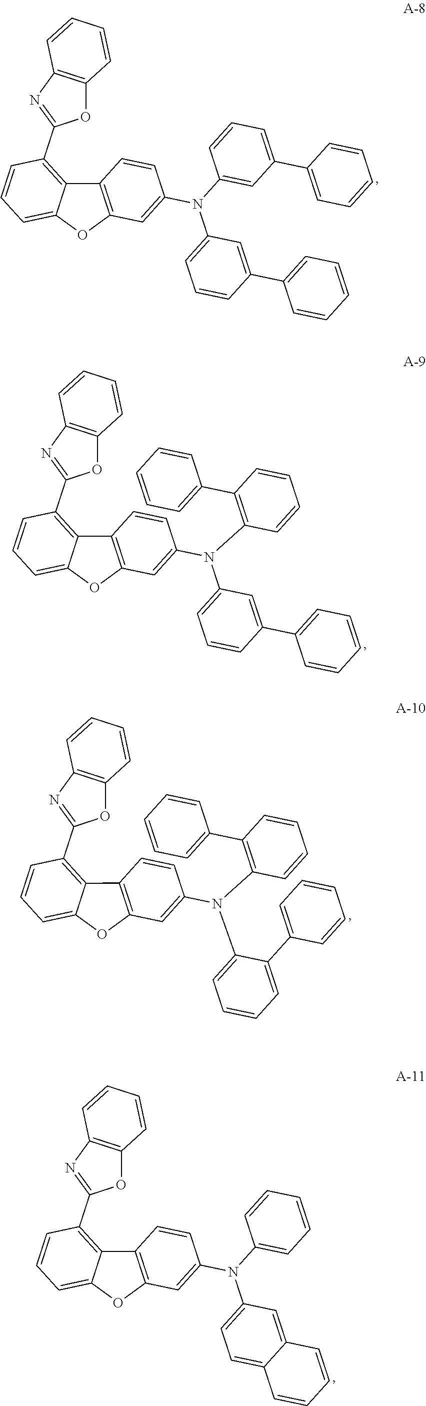 [SMILES: c1ccc(-c2cccc(N(c3cccc(-c4ccccc4)c3)c3ccc4c(c3)oc3cccc(-c5nc6ccccc6o5)c34)c2)cc1 ; c1ccc(-c2cccc(N(c3ccc4c(c3)oc3cccc(-c5nc6ccccc6o5)c34)c3ccccc3-c3ccccc3)c2)cc1 ; c1ccc(-c2ccccc2N(c2ccc3c(c2)oc2cccc(-c4nc5ccccc5o4)c23)c2ccccc2-c2ccccc2)cc1 ; c1ccc(N(c2ccc3ccccc3c2)c2ccc3c(c2)oc2cccc(-c4nc5ccccc5o4)c23)cc1] 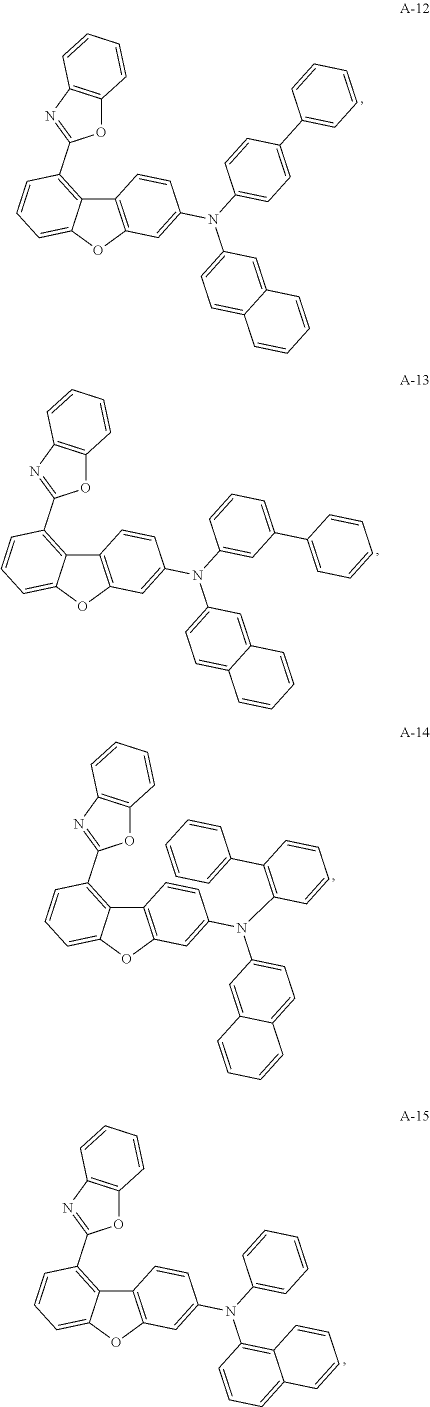 [SMILES: c1ccc(-c2ccc(N(c3ccc4ccccc4c3)c3ccc4c(c3)oc3cccc(-c5nc6ccccc6o5)c34)cc2)cc1 ; c1ccc(-c2cccc(N(c3ccc4ccccc4c3)c3ccc4c(c3)oc3cccc(-c5nc6ccccc6o5)c34)c2)cc1 ; c1ccc(-c2ccccc2N(c2ccc3ccccc3c2)c2ccc3c(c2)oc2cccc(-c4nc5ccccc5o4)c23)cc1 ; c1ccc(N(c2ccc3c(c2)oc2cccc(-c4nc5ccccc5o4)c23)c2cccc3ccccc23)cc1] 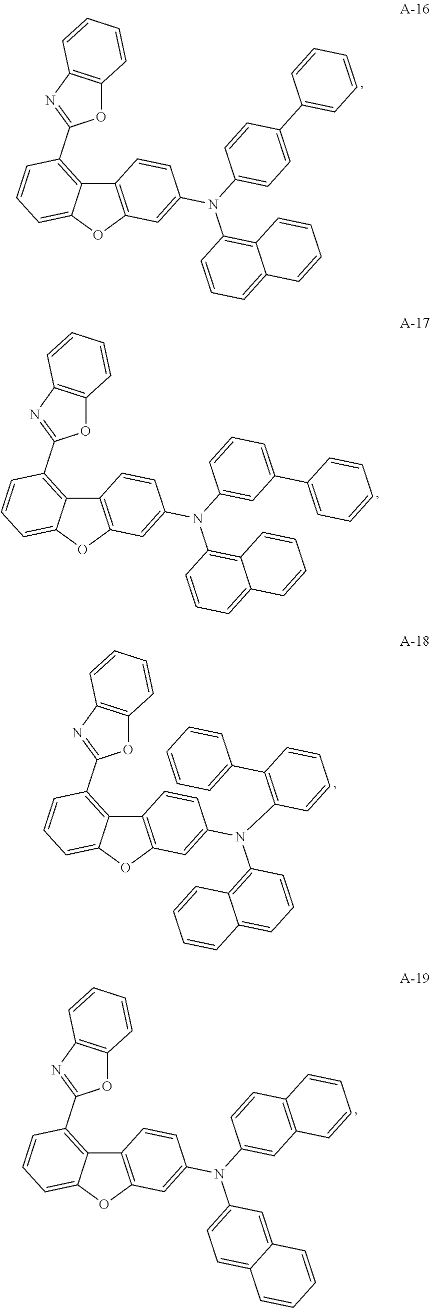 [SMILES: c1ccc(-c2ccc(N(c3ccc4c(c3)oc3cccc(-c5nc6ccccc6o5)c34)c3cccc4ccccc34)cc2)cc1 ; c1ccc(-c2cccc(N(c3ccc4c(c3)oc3cccc(-c5nc6ccccc6o5)c34)c3cccc4ccccc34)c2)cc1 ; c1ccc(-c2ccccc2N(c2ccc3c(c2)oc2cccc(-c4nc5ccccc5o4)c23)c2cccc3ccccc23)cc1 ; c1ccc2cc(N(c3ccc4ccccc4c3)c3ccc4c(c3)oc3cccc(-c5nc6ccccc6o5)c34)ccc2c1] 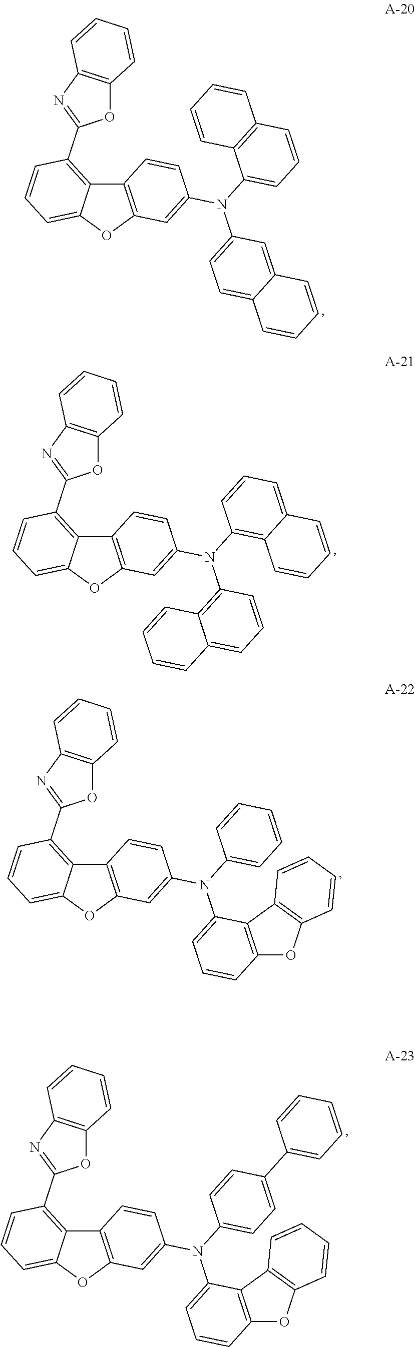 [SMILES: c1ccc2cc(N(c3ccc4c(c3)oc3cccc(-c5nc6ccccc6o5)c34)c3cccc4ccccc34)ccc2c1 ; c1ccc2c(N(c3ccc4c(c3)oc3cccc(-c5nc6ccccc6o5)c34)c3cccc4ccccc34)cccc2c1 ; c1ccc(N(c2ccc3c(c2)oc2cccc(-c4nc5ccccc5o4)c23)c2cccc3oc4ccccc4c23)cc1 ; c1ccc(-c2ccc(N(c3ccc4c(c3)oc3cccc(-c5nc6ccccc6o5)c34)c3cccc4oc5ccccc5c34)cc2)cc1] 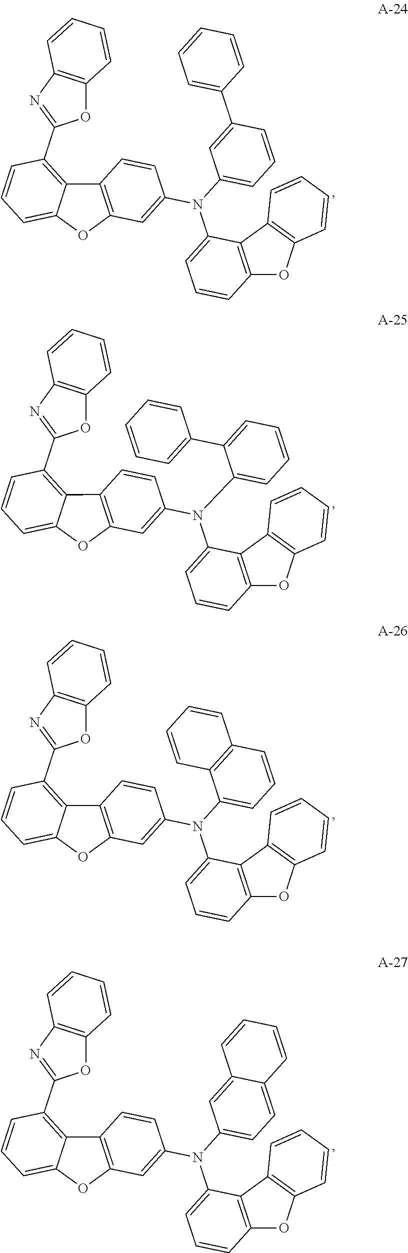 [SMILES: c1ccc(-c2cccc(N(c3ccc4c(c3)oc3cccc(-c5nc6ccccc6o5)c34)c3cccc4oc5ccccc5c34)c2)cc1 ; c1ccc(-c2ccccc2N(c2ccc3c(c2)oc2cccc(-c4nc5ccccc5o4)c23)c2cccc3oc4ccccc4c23)cc1 ; c1ccc2c(N(c3ccc4c(c3)oc3cccc(-c5nc6ccccc6o5)c34)c3cccc4oc5ccccc5c34)cccc2c1 ; c1ccc2cc(N(c3ccc4c(c3)oc3cccc(-c5nc6ccccc6o5)c34)c3cccc4oc5ccccc5c34)ccc2c1] 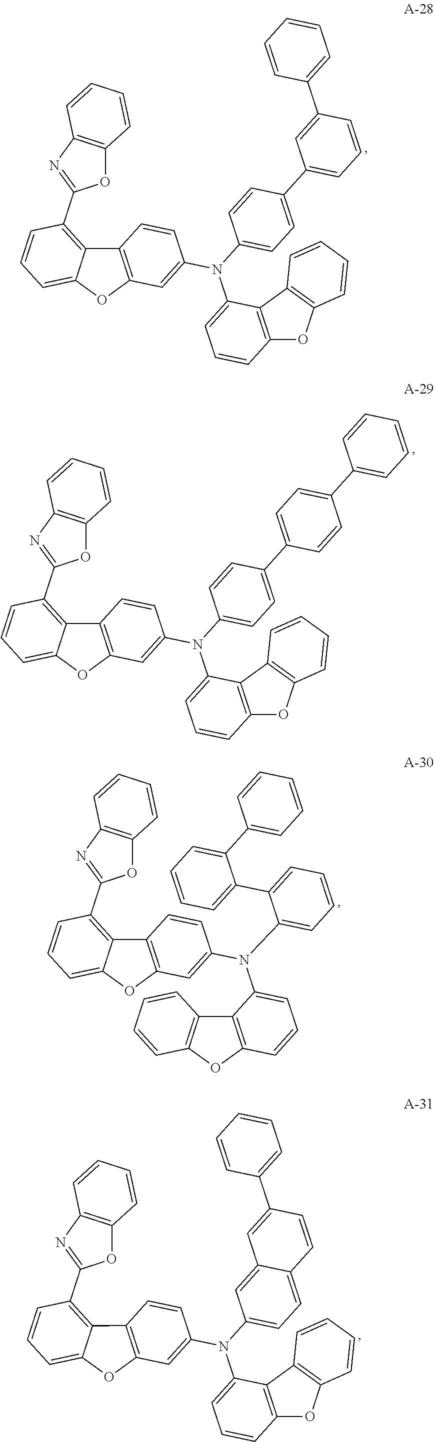 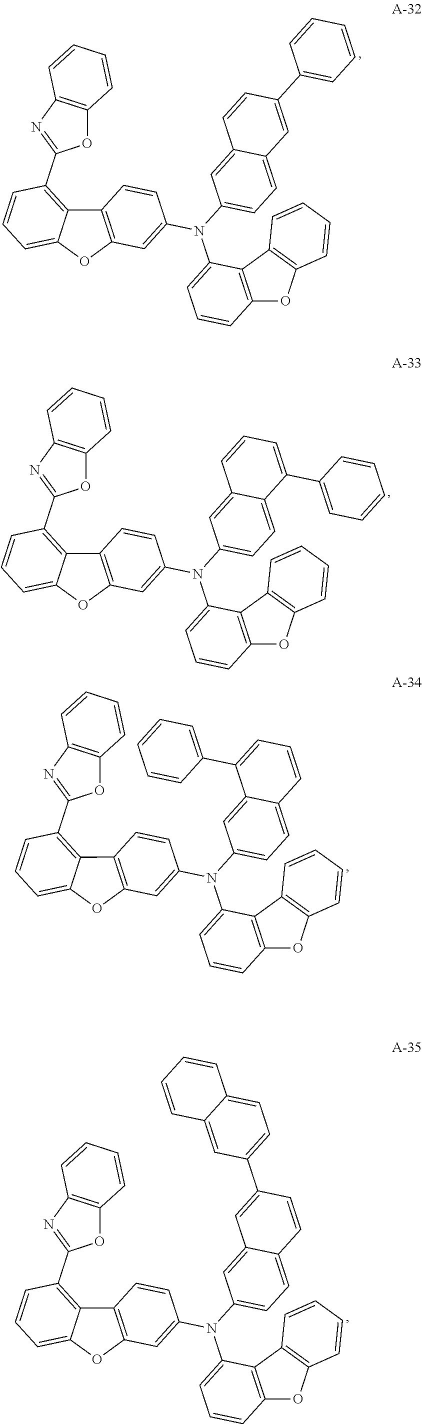 [SMILES: c1ccc(-c2ccc3cc(N(c4ccc5c(c4)oc4cccc(-c6nc7ccccc7o6)c45)c4cccc5oc6ccccc6c45)ccc3c2)cc1 ; c1ccc(-c2cccc3cc(N(c4ccc5c(c4)oc4cccc(-c6nc7ccccc7o6)c45)c4cccc5oc6ccccc6c45)ccc23)cc1 ; c1ccc(-c2cccc3ccc(N(c4ccc5c(c4)oc4cccc(-c6nc7ccccc7o6)c45)c4cccc5oc6ccccc6c45)cc23)cc1 ; c1ccc2cc(-c3ccc4ccc(N(c5ccc6c(c5)oc5cccc(-c7nc8ccccc8o7)c56)c5cccc6oc7ccccc7c56)cc4c3)ccc2c1] 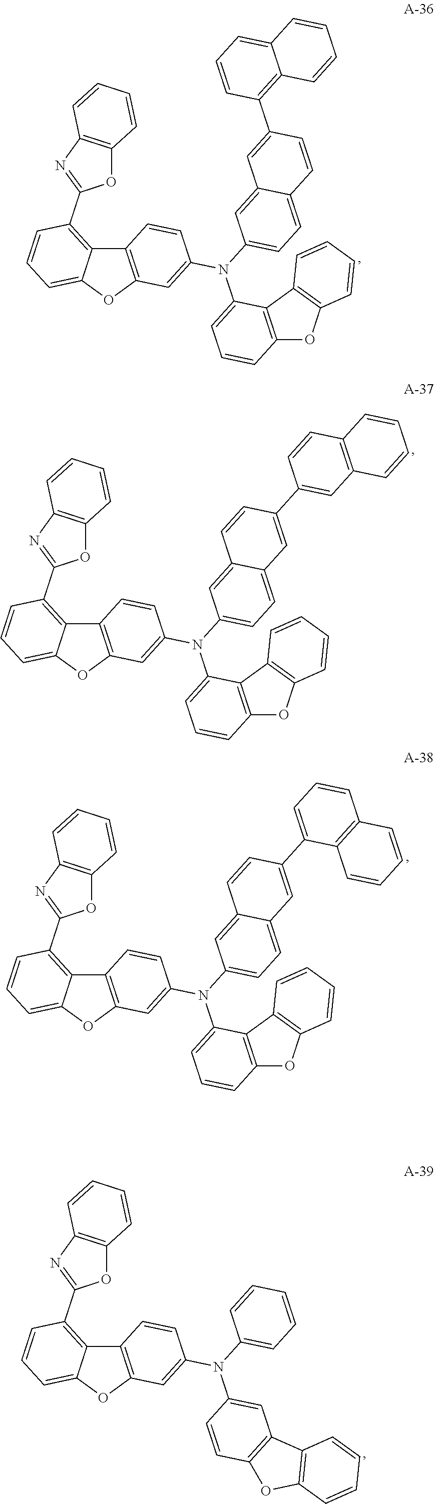 [SMILES: c1ccc2c(-c3ccc4ccc(N(c5ccc6c(c5)oc5cccc(-c7nc8ccccc8o7)c56)c5cccc6oc7ccccc7c56)cc4c3)cccc2c1 ; c1ccc2cc(-c3ccc4cc(N(c5ccc6c(c5)oc5cccc(-c7nc8ccccc8o7)c56)c5cccc6oc7ccccc7c56)ccc4c3)ccc2c1 ; c1ccc2c(-c3ccc4cc(N(c5ccc6c(c5)oc5cccc(-c7nc8ccccc8o7)c56)c5cccc6oc7ccccc7c56)ccc4c3)cccc2c1 ; c1ccc(N(c2ccc3c(c2)oc2cccc(-c4nc5ccccc5o4)c23)c2ccc3oc4ccccc4c3c2)cc1] 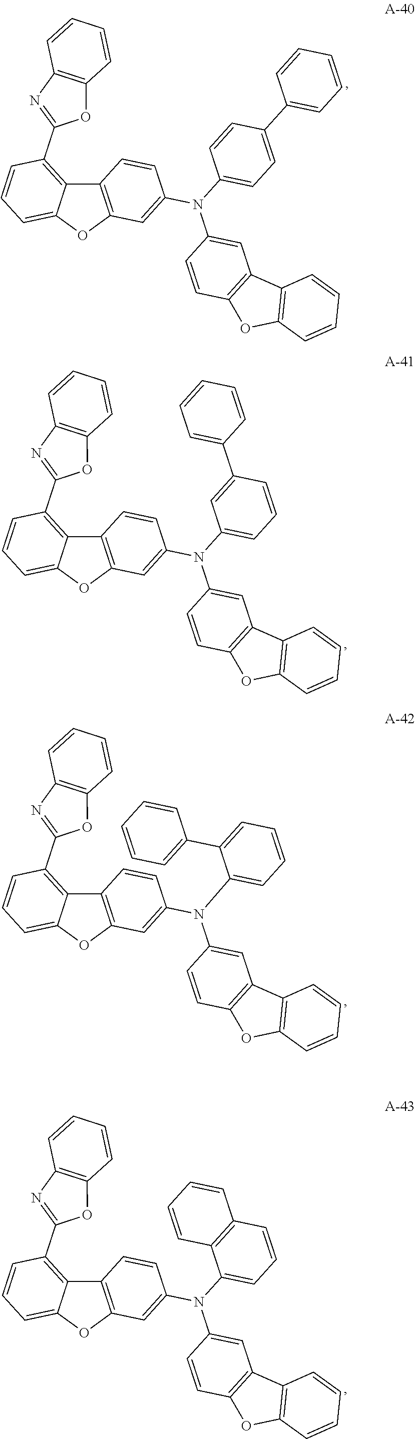 [SMILES: c1ccc(-c2ccc(N(c3ccc4c(c3)oc3cccc(-c5nc6ccccc6o5)c34)c3ccc4oc5ccccc5c4c3)cc2)cc1 ; c1ccc(-c2cccc(N(c3ccc4c(c3)oc3cccc(-c5nc6ccccc6o5)c34)c3ccc4oc5ccccc5c4c3)c2)cc1 ; c1ccc(-c2ccccc2N(c2ccc3c(c2)oc2cccc(-c4nc5ccccc5o4)c23)c2ccc3oc4ccccc4c3c2)cc1 ; c1ccc2c(N(c3ccc4c(c3)oc3cccc(-c5nc6ccccc6o5)c34)c3ccc4oc5ccccc5c4c3)cccc2c1] 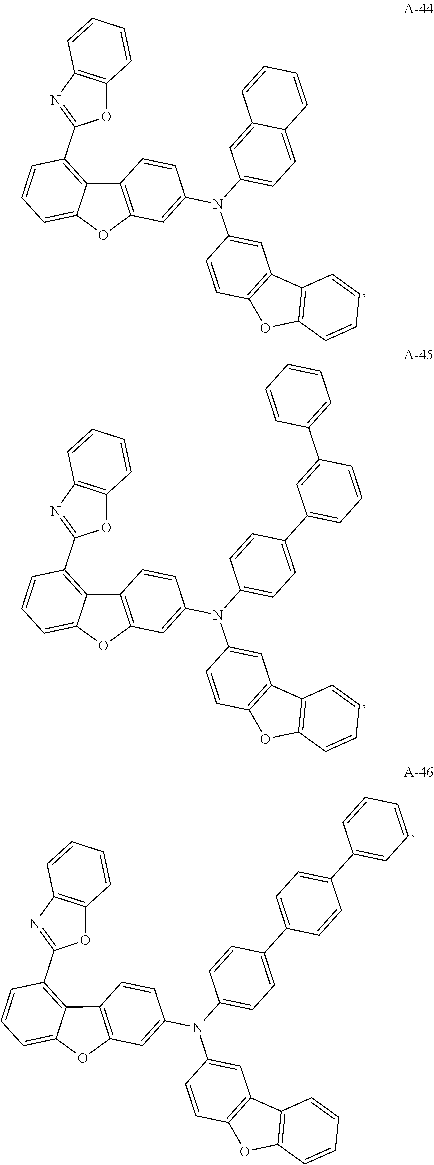 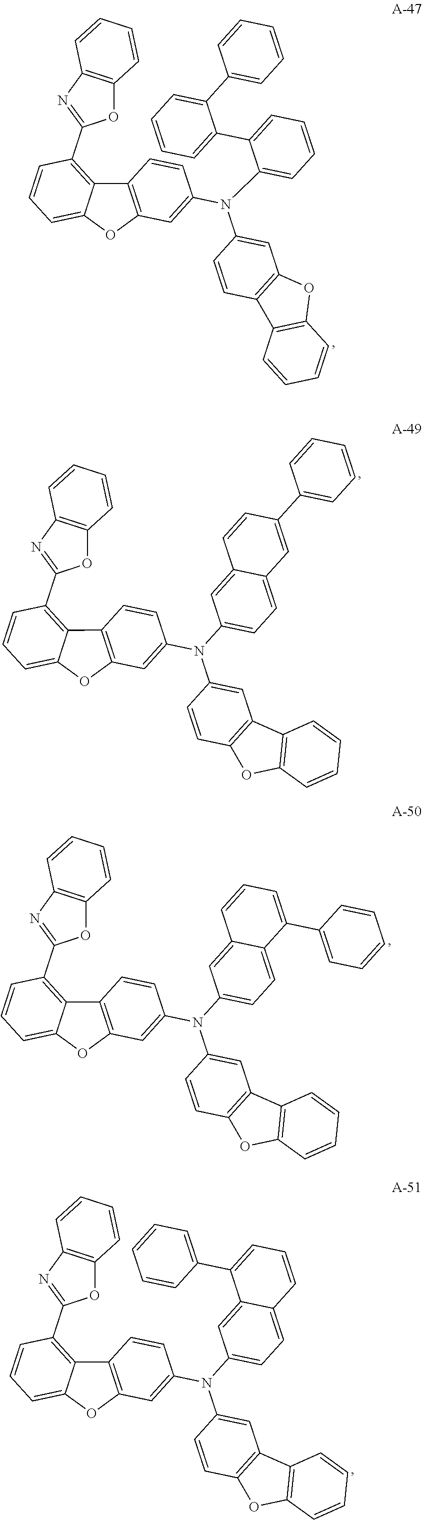 [SMILES: c1ccc(-c2ccccc2-c2ccccc2N(c2ccc3c(c2)oc2ccccc23)c2ccc3c(c2)oc2cccc(-c4nc5ccccc5o4)c23)cc1 ; c1ccc(-c2ccc3cc(N(c4ccc5c(c4)oc4cccc(-c6nc7ccccc7o6)c45)c4ccc5oc6ccccc6c5c4)ccc3c2)cc1 ; c1ccc(-c2cccc3cc(N(c4ccc5c(c4)oc4cccc(-c6nc7ccccc7o6)c45)c4ccc5oc6ccccc6c5c4)ccc23)cc1 ; c1ccc(-c2cccc3ccc(N(c4ccc5c(c4)oc4cccc(-c6nc7ccccc7o6)c45)c4ccc5oc6ccccc6c5c4)cc23)cc1] 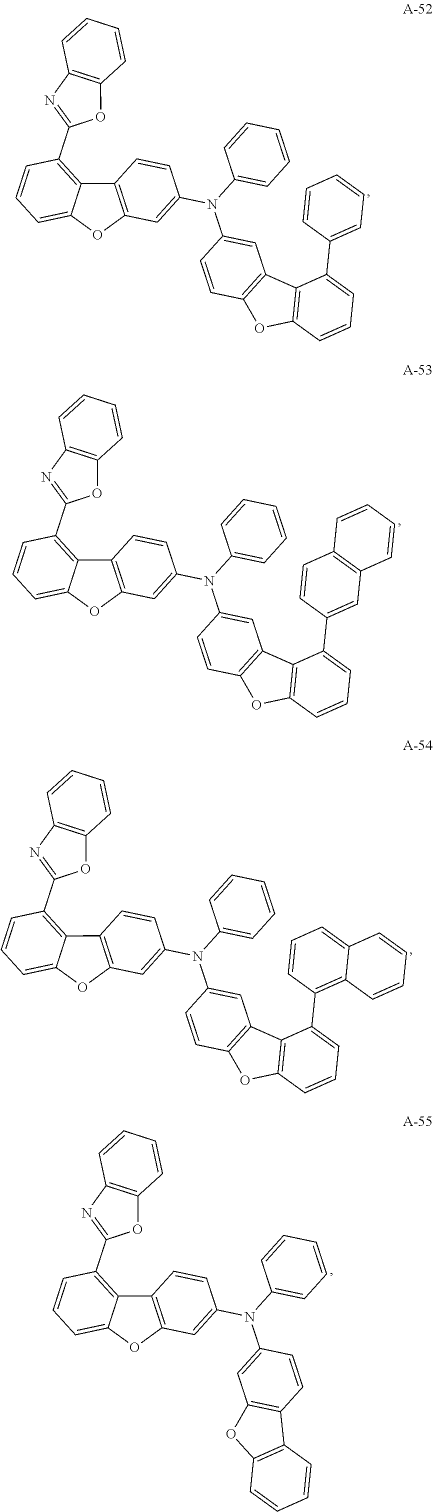 [SMILES: c1ccc(-c2cccc3oc4ccc(N(c5ccccc5)c5ccc6c(c5)oc5cccc(-c7nc8ccccc8o7)c56)cc4c23)cc1 ; c1ccc(N(c2ccc3c(c2)oc2cccc(-c4nc5ccccc5o4)c23)c2ccc3oc4cccc(-c5ccc6ccccc6c5)c4c3c2)cc1 ; c1ccc(N(c2ccc3c(c2)oc2cccc(-c4nc5ccccc5o4)c23)c2ccc3oc4cccc(-c5cccc6ccccc56)c4c3c2)cc1 ; c1ccc(N(c2ccc3c(c2)oc2ccccc23)c2ccc3c(c2)oc2cccc(-c4nc5ccccc5o4)c23)cc1] 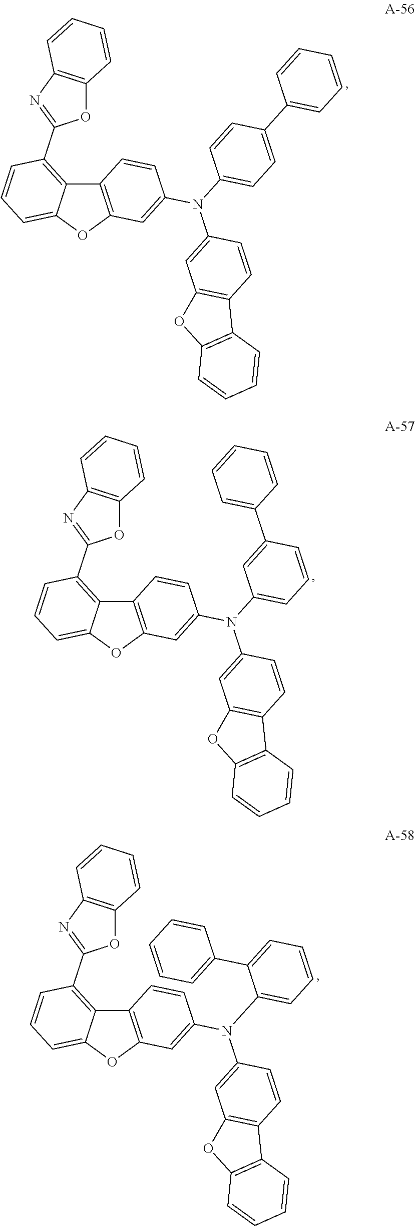 [SMILES: c1ccc(-c2ccc(N(c3ccc4c(c3)oc3ccccc34)c3ccc4c(c3)oc3cccc(-c5nc6ccccc6o5)c34)cc2)cc1 ; c1ccc(-c2cccc(N(c3ccc4c(c3)oc3ccccc34)c3ccc4c(c3)oc3cccc(-c5nc6ccccc6o5)c34)c2)cc1 ; c1ccc(-c2ccccc2N(c2ccc3c(c2)oc2ccccc23)c2ccc3c(c2)oc2cccc(-c4nc5ccccc5o4)c23)cc1] 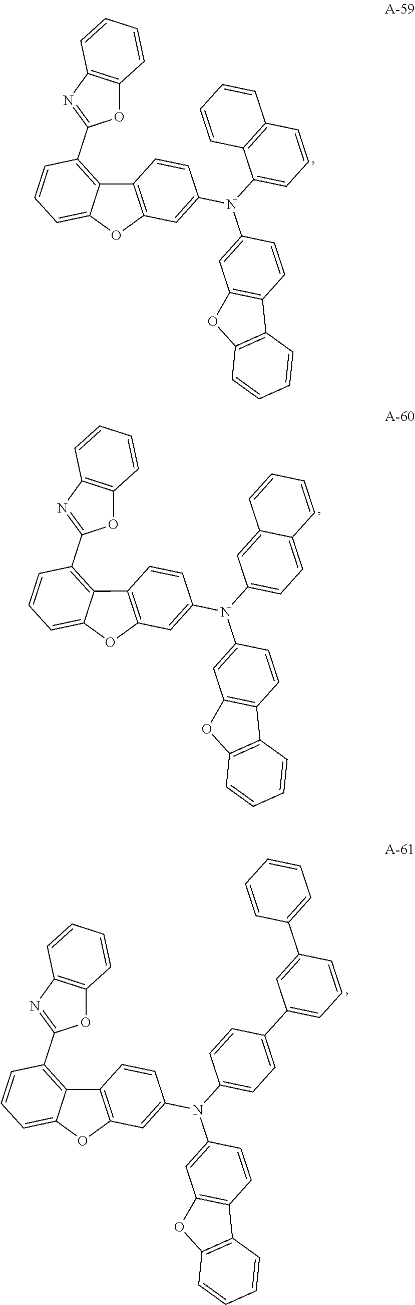 [SMILES: c1ccc2c(N(c3ccc4c(c3)oc3ccccc34)c3ccc4c(c3)oc3cccc(-c5nc6ccccc6o5)c34)cccc2c1 ; c1ccc2cc(N(c3ccc4c(c3)oc3ccccc34)c3ccc4c(c3)oc3cccc(-c5nc6ccccc6o5)c34)ccc2c1 ; c1ccc(-c2cccc(-c3ccc(N(c4ccc5c(c4)oc4ccccc45)c4ccc5c(c4)oc4cccc(-c6nc7ccccc7o6)c45)cc3)c2)cc1] 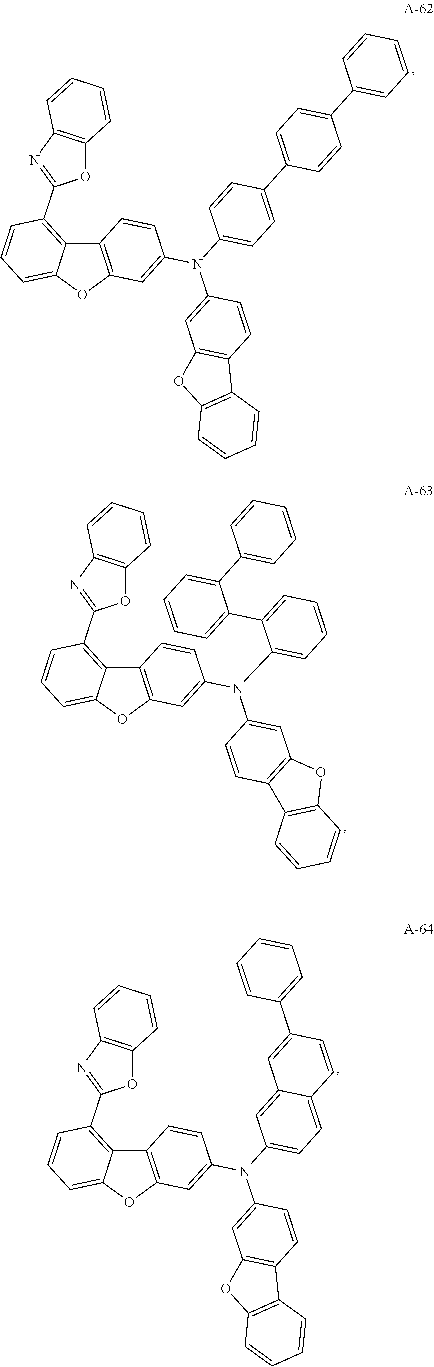 [SMILES: c1ccc(-c2ccc(-c3ccc(N(c4ccc5c(c4)oc4ccccc45)c4ccc5c(c4)oc4cccc(-c6nc7ccccc7o6)c45)cc3)cc2)cc1 ; c1ccc(-c2ccccc2-c2ccccc2N(c2ccc3c(c2)oc2ccccc23)c2ccc3c(c2)oc2cccc(-c4nc5ccccc5o4)c23)cc1 ; c1ccc(-c2ccc3ccc(N(c4ccc5c(c4)oc4ccccc45)c4ccc5c(c4)oc4cccc(-c6nc7ccccc7o6)c45)cc3c2)cc1] 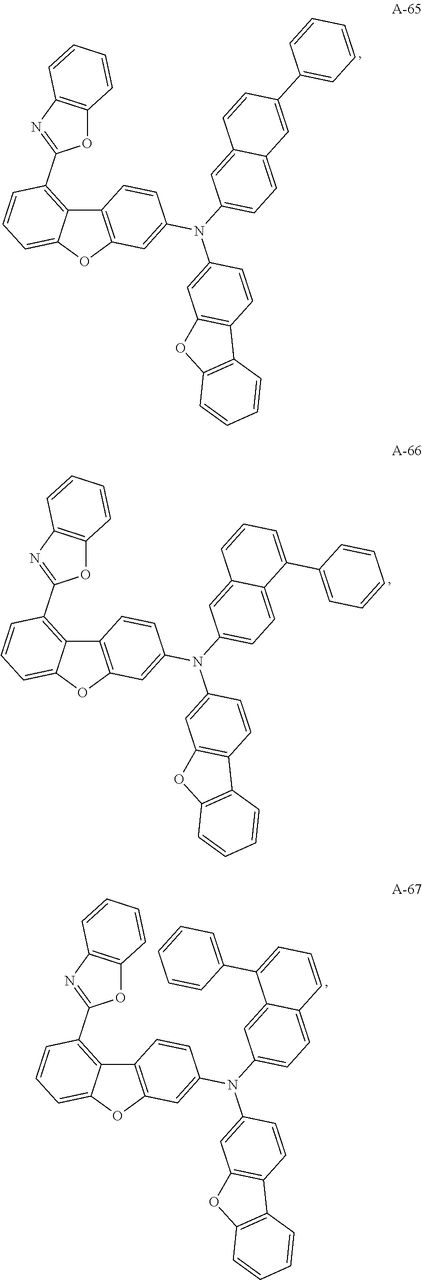 [SMILES: c1ccc(-c2ccc3cc(N(c4ccc5c(c4)oc4ccccc45)c4ccc5c(c4)oc4cccc(-c6nc7ccccc7o6)c45)ccc3c2)cc1 ; c1ccc(-c2cccc3cc(N(c4ccc5c(c4)oc4ccccc45)c4ccc5c(c4)oc4cccc(-c6nc7ccccc7o6)c45)ccc23)cc1 ; c1ccc(-c2cccc3ccc(N(c4ccc5c(c4)oc4ccccc45)c4ccc5c(c4)oc4cccc(-c6nc7ccccc7o6)c45)cc23)cc1] 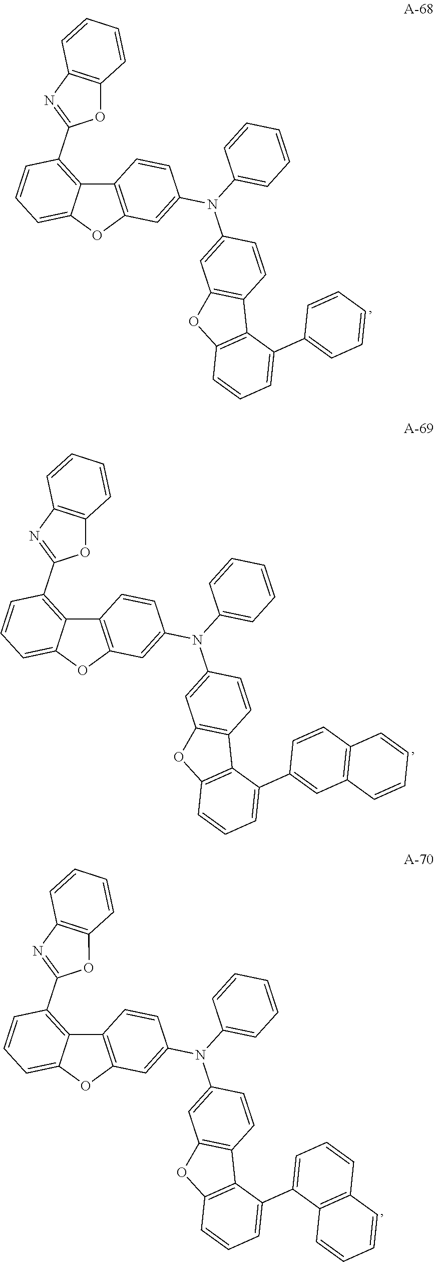 [SMILES: c1ccc(-c2cccc3oc4cc(N(c5ccccc5)c5ccc6c(c5)oc5cccc(-c7nc8ccccc8o7)c56)ccc4c23)cc1 ; c1ccc(N(c2ccc3c(c2)oc2cccc(-c4ccc5ccccc5c4)c23)c2ccc3c(c2)oc2cccc(-c4nc5ccccc5o4)c23)cc1 ; c1ccc(N(c2ccc3c(c2)oc2cccc(-c4nc5ccccc5o4)c23)c2ccc3c(c2)oc2cccc(-c4cccc5ccccc45)c23)cc1] 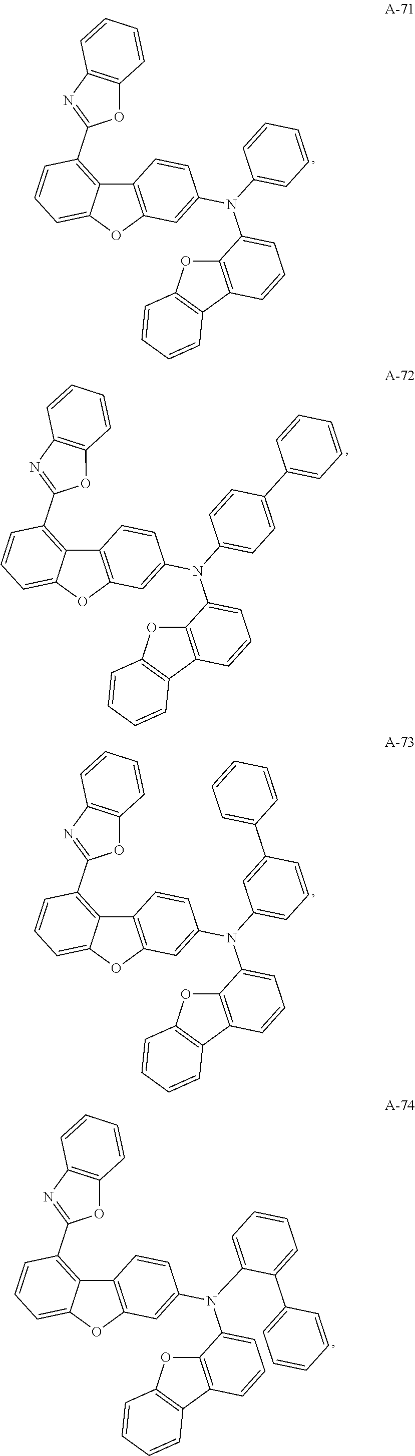 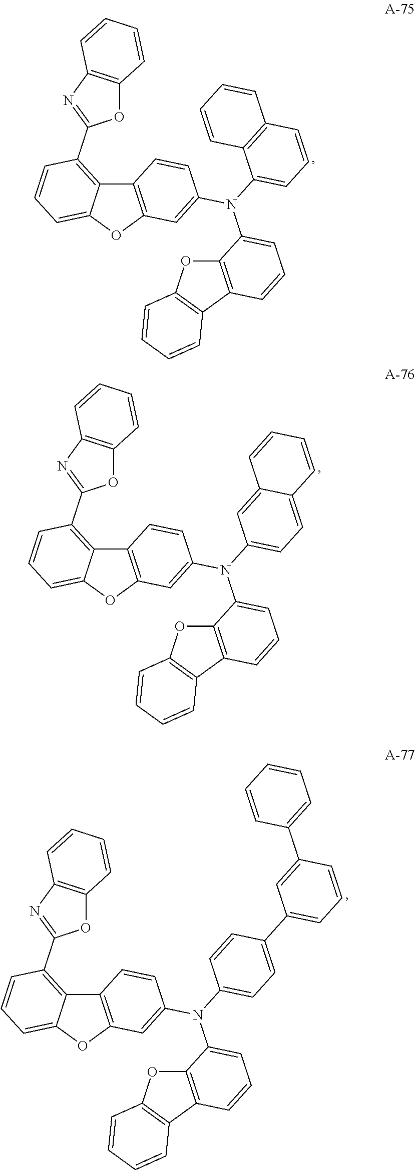 [SMILES: c1ccc2c(N(c3ccc4c(c3)oc3cccc(-c5nc6ccccc6o5)c34)c3cccc4c3oc3ccccc34)cccc2c1 ; c1ccc2cc(N(c3ccc4c(c3)oc3cccc(-c5nc6ccccc6o5)c34)c3cccc4c3oc3ccccc34)ccc2c1 ; c1ccc(-c2cccc(-c3ccc(N(c4ccc5c(c4)oc4cccc(-c6nc7ccccc7o6)c45)c4cccc5c4oc4ccccc45)cc3)c2)cc1] 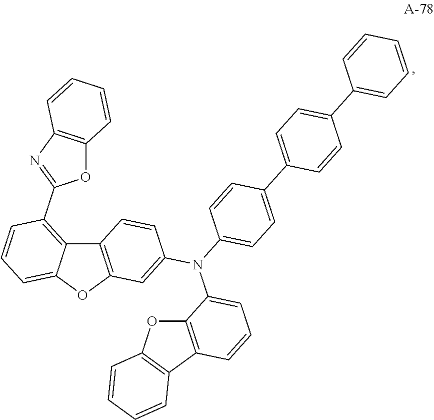 [SMILES: c1ccc(-c2ccc(-c3ccc(N(c4ccc5c(c4)oc4cccc(-c6nc7ccccc7o6)c45)c4cccc5c4oc4ccccc45)cc3)cc2)cc1] 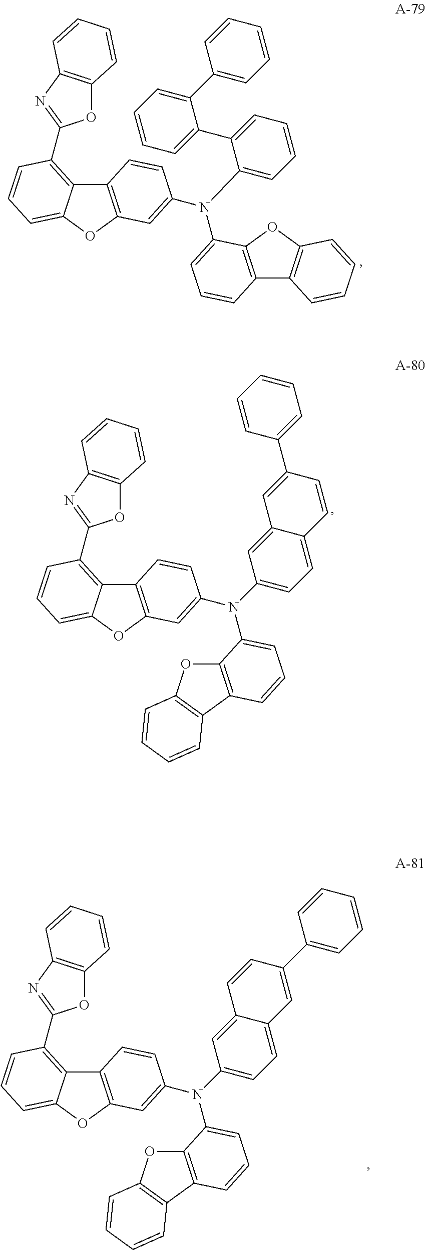 [SMILES: c1ccc(-c2ccccc2-c2ccccc2N(c2ccc3c(c2)oc2cccc(-c4nc5ccccc5o4)c23)c2cccc3c2oc2ccccc23)cc1 ; c1ccc(-c2ccc3ccc(N(c4ccc5c(c4)oc4cccc(-c6nc7ccccc7o6)c45)c4cccc5c4oc4ccccc45)cc3c2)cc1 ; c1ccc(-c2ccc3cc(N(c4ccc5c(c4)oc4cccc(-c6nc7ccccc7o6)c45)c4cccc5c4oc4ccccc45)ccc3c2)cc1] 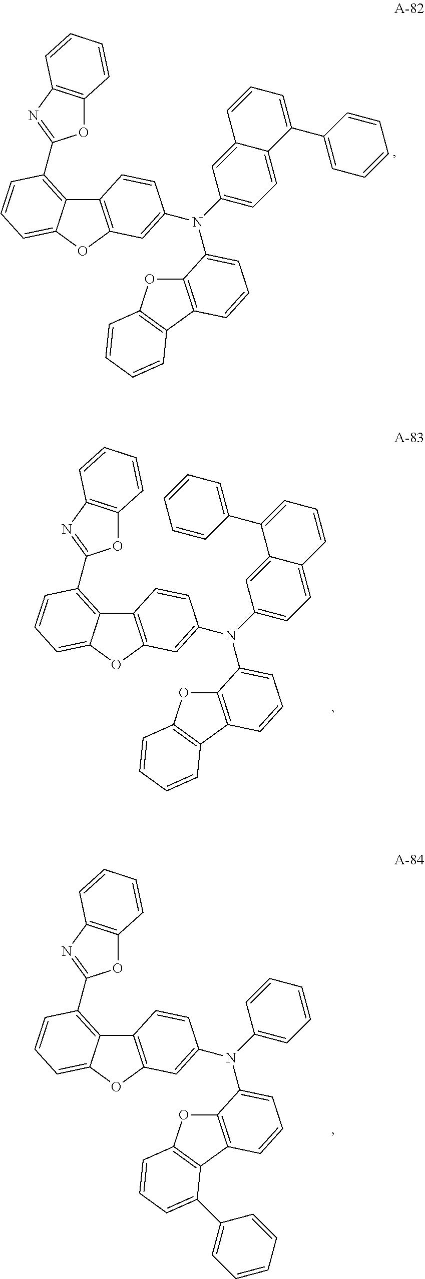 [SMILES: c1ccc(-c2cccc3cc(N(c4ccc5c(c4)oc4cccc(-c6nc7ccccc7o6)c45)c4cccc5c4oc4ccccc45)ccc23)cc1 ; c1ccc(-c2cccc3ccc(N(c4ccc5c(c4)oc4cccc(-c6nc7ccccc7o6)c45)c4cccc5c4oc4ccccc45)cc23)cc1 ; c1ccc(-c2cccc3oc4c(N(c5ccccc5)c5ccc6c(c5)oc5cccc(-c7nc8ccccc8o7)c56)cccc4c23)cc1] 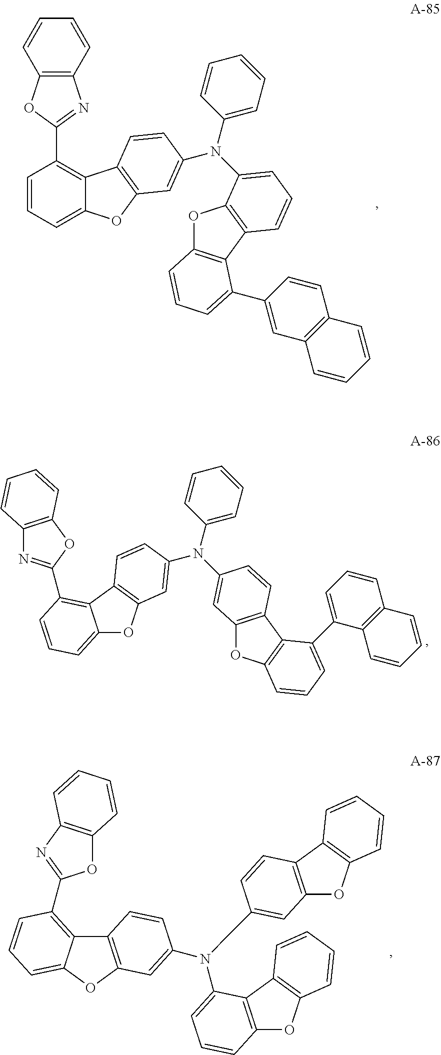 [SMILES: c1ccc(N(c2ccc3c(c2)oc2cccc(-c4nc5ccccc5o4)c23)c2cccc3c2oc2cccc(-c4ccc5ccccc5c4)c23)cc1 ; c1ccc(N(c2ccc3c(c2)oc2cccc(-c4nc5ccccc5o4)c23)c2ccc3c(c2)oc2cccc(-c4cccc5ccccc45)c23)cc1 ; c1ccc2oc(-c3cccc4oc5cc(N(c6ccc7c(c6)oc6ccccc67)c6cccc7oc8ccccc8c67)ccc5c34)nc2c1] 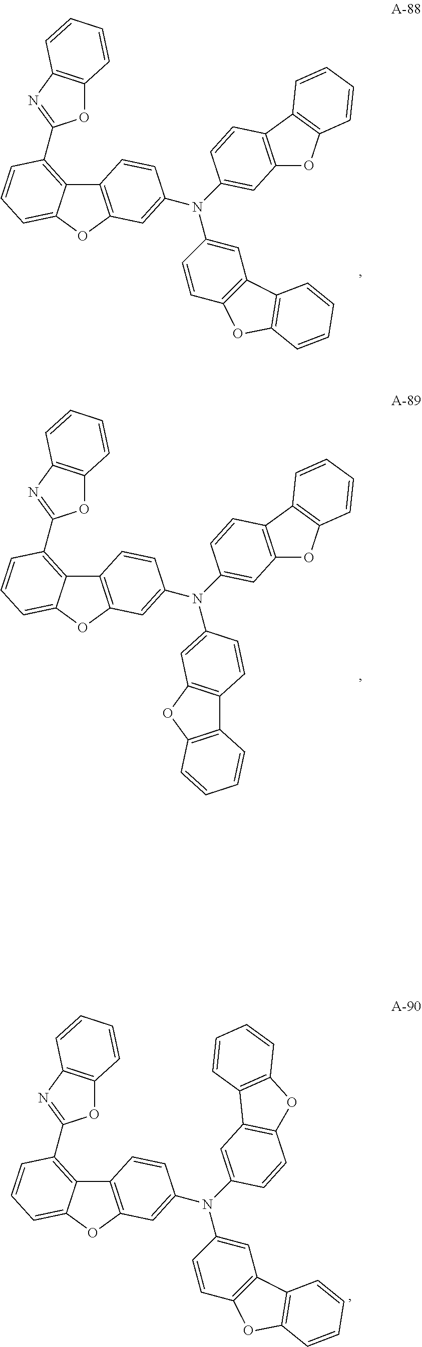 [SMILES: c1ccc2oc(-c3cccc4oc5cc(N(c6ccc7c(c6)oc6ccccc67)c6ccc7oc8ccccc8c7c6)ccc5c34)nc2c1 ; c1ccc2oc(-c3cccc4oc5cc(N(c6ccc7c(c6)oc6ccccc67)c6ccc7c(c6)oc6ccccc67)ccc5c34)nc2c1 ; c1ccc2oc(-c3cccc4oc5cc(N(c6ccc7oc8ccccc8c7c6)c6ccc7oc8ccccc8c7c6)ccc5c34)nc2c1] 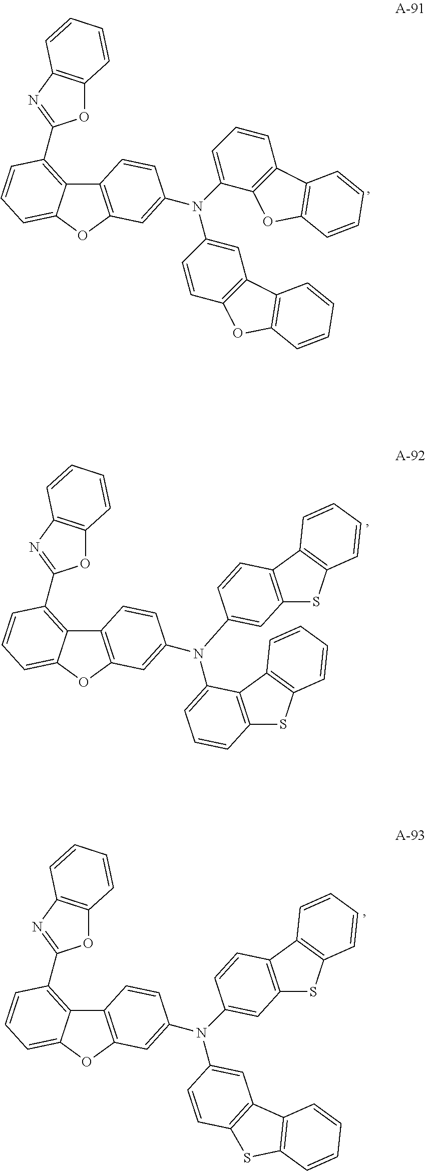 [SMILES: c1ccc2oc(-c3cccc4oc5cc(N(c6ccc7oc8ccccc8c7c6)c6cccc7c6oc6ccccc67)ccc5c34)nc2c1 ; c1ccc2oc(-c3cccc4oc5cc(N(c6ccc7c(c6)sc6ccccc67)c6cccc7sc8ccccc8c67)ccc5c34)nc2c1 ; c1ccc2oc(-c3cccc4oc5cc(N(c6ccc7c(c6)sc6ccccc67)c6ccc7sc8ccccc8c7c6)ccc5c34)nc2c1] 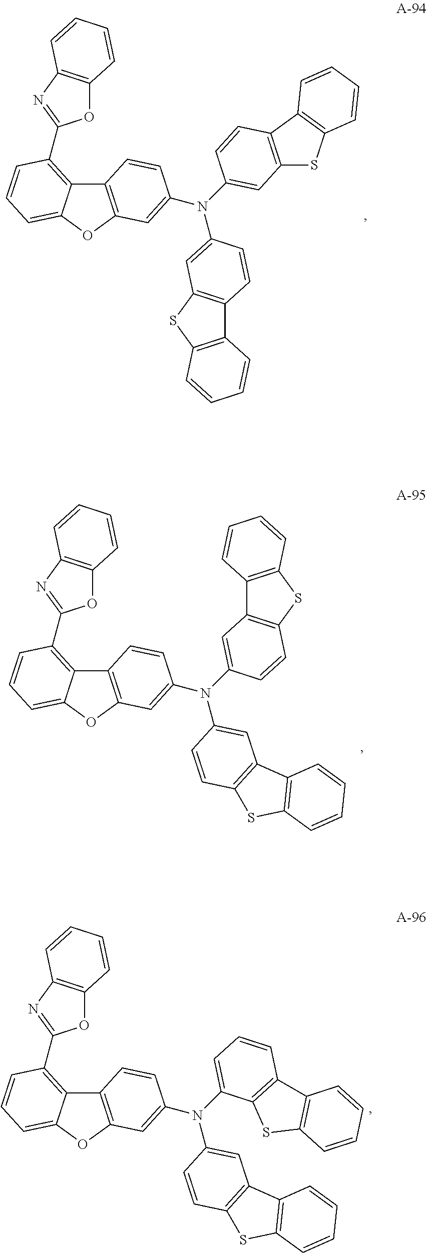 [SMILES: c1ccc2oc(-c3cccc4oc5cc(N(c6ccc7c(c6)sc6ccccc67)c6ccc7c(c6)sc6ccccc67)ccc5c34)nc2c1 ; c1ccc2oc(-c3cccc4oc5cc(N(c6ccc7sc8ccccc8c7c6)c6ccc7sc8ccccc8c7c6)ccc5c34)nc2c1 ; c1ccc2oc(-c3cccc4oc5cc(N(c6ccc7sc8ccccc8c7c6)c6cccc7c6sc6ccccc67)ccc5c34)nc2c1] 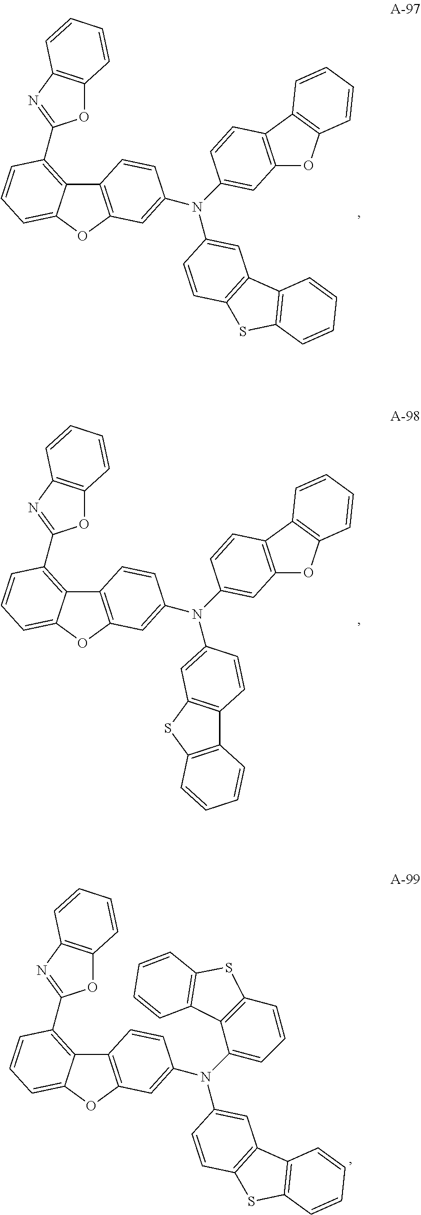 [SMILES: c1ccc2oc(-c3cccc4oc5cc(N(c6ccc7c(c6)oc6ccccc67)c6ccc7sc8ccccc8c7c6)ccc5c34)nc2c1 ; c1ccc2oc(-c3cccc4oc5cc(N(c6ccc7c(c6)oc6ccccc67)c6ccc7c(c6)sc6ccccc67)ccc5c34)nc2c1 ; c1ccc2oc(-c3cccc4oc5cc(N(c6ccc7sc8ccccc8c7c6)c6cccc7sc8ccccc8c67)ccc5c34)nc2c1] 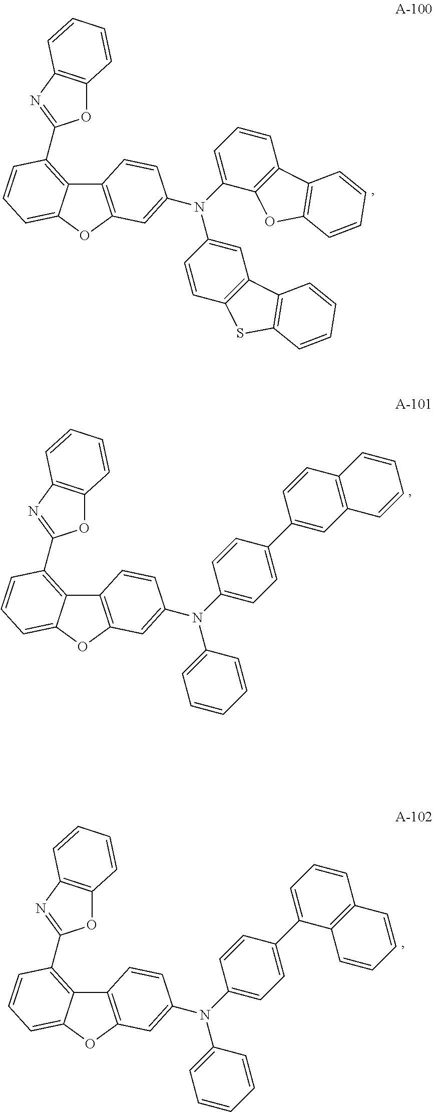 [SMILES: c1ccc2oc(-c3cccc4oc5cc(N(c6ccc7sc8ccccc8c7c6)c6cccc7c6oc6ccccc67)ccc5c34)nc2c1 ; c1ccc(N(c2ccc(-c3ccc4ccccc4c3)cc2)c2ccc3c(c2)oc2cccc(-c4nc5ccccc5o4)c23)cc1 ; c1ccc(N(c2ccc(-c3cccc4ccccc34)cc2)c2ccc3c(c2)oc2cccc(-c4nc5ccccc5o4)c23)cc1] 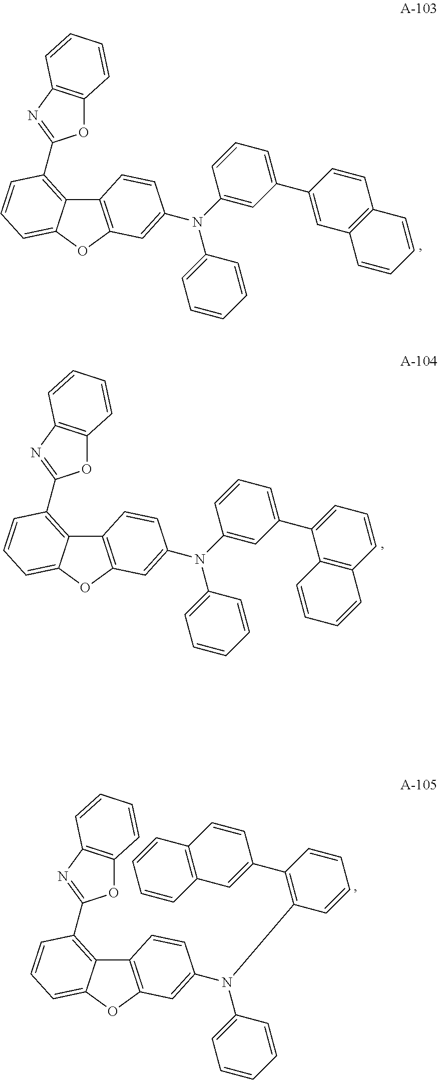 [SMILES: c1ccc(N(c2cccc(-c3ccc4ccccc4c3)c2)c2ccc3c(c2)oc2cccc(-c4nc5ccccc5o4)c23)cc1 ; c1ccc(N(c2cccc(-c3cccc4ccccc34)c2)c2ccc3c(c2)oc2cccc(-c4nc5ccccc5o4)c23)cc1 ; c1ccc(N(c2ccc3c(c2)oc2cccc(-c4nc5ccccc5o4)c23)c2ccccc2-c2ccc3ccccc3c2)cc1] 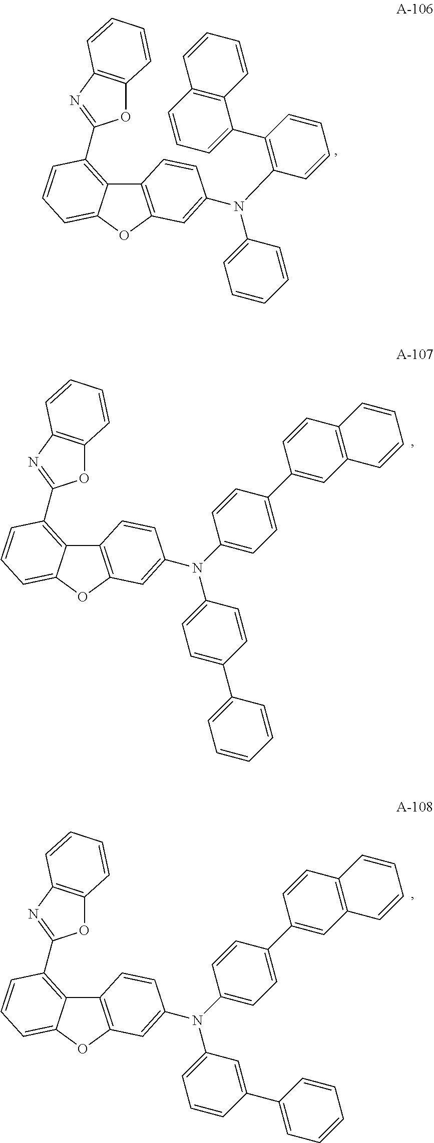 [SMILES: c1ccc(N(c2ccc3c(c2)oc2cccc(-c4nc5ccccc5o4)c23)c2ccccc2-c2cccc3ccccc23)cc1 ; c1ccc(-c2ccc(N(c3ccc(-c4ccc5ccccc5c4)cc3)c3ccc4c(c3)oc3cccc(-c5nc6ccccc6o5)c34)cc2)cc1 ; c1ccc(-c2cccc(N(c3ccc(-c4ccc5ccccc5c4)cc3)c3ccc4c(c3)oc3cccc(-c5nc6ccccc6o5)c34)c2)cc1] 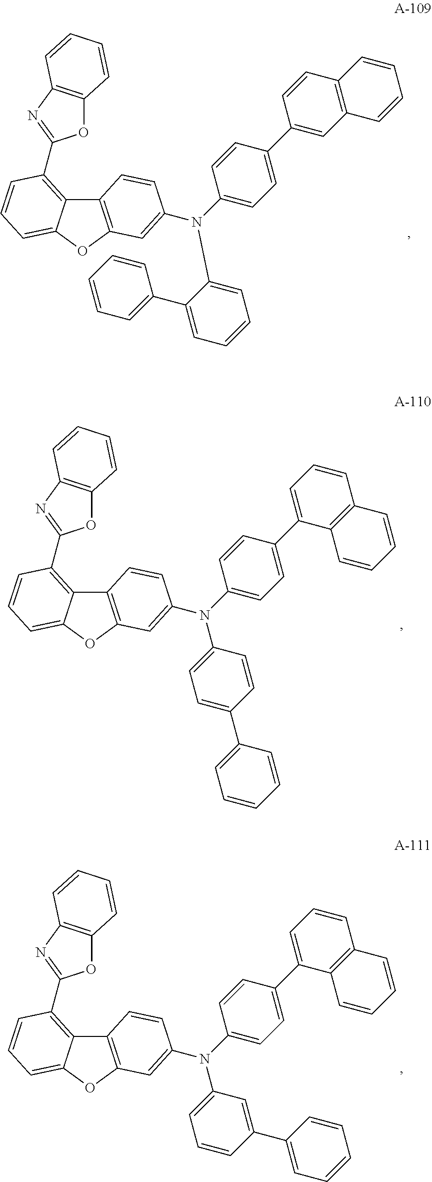 [SMILES: c1ccc(-c2ccccc2N(c2ccc(-c3ccc4ccccc4c3)cc2)c2ccc3c(c2)oc2cccc(-c4nc5ccccc5o4)c23)cc1 ; c1ccc(-c2ccc(N(c3ccc(-c4cccc5ccccc45)cc3)c3ccc4c(c3)oc3cccc(-c5nc6ccccc6o5)c34)cc2)cc1 ; c1ccc(-c2cccc(N(c3ccc(-c4cccc5ccccc45)cc3)c3ccc4c(c3)oc3cccc(-c5nc6ccccc6o5)c34)c2)cc1] 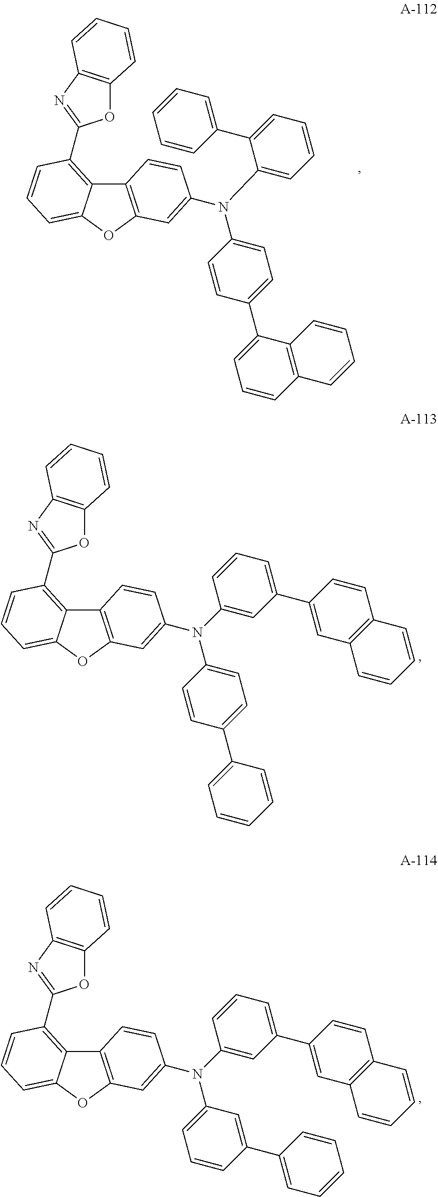 [SMILES: c1ccc(-c2ccccc2N(c2ccc(-c3cccc4ccccc34)cc2)c2ccc3c(c2)oc2cccc(-c4nc5ccccc5o4)c23)cc1 ; c1ccc(-c2ccc(N(c3cccc(-c4ccc5ccccc5c4)c3)c3ccc4c(c3)oc3cccc(-c5nc6ccccc6o5)c34)cc2)cc1 ; c1ccc(-c2cccc(N(c3cccc(-c4ccc5ccccc5c4)c3)c3ccc4c(c3)oc3cccc(-c5nc6ccccc6o5)c34)c2)cc1] 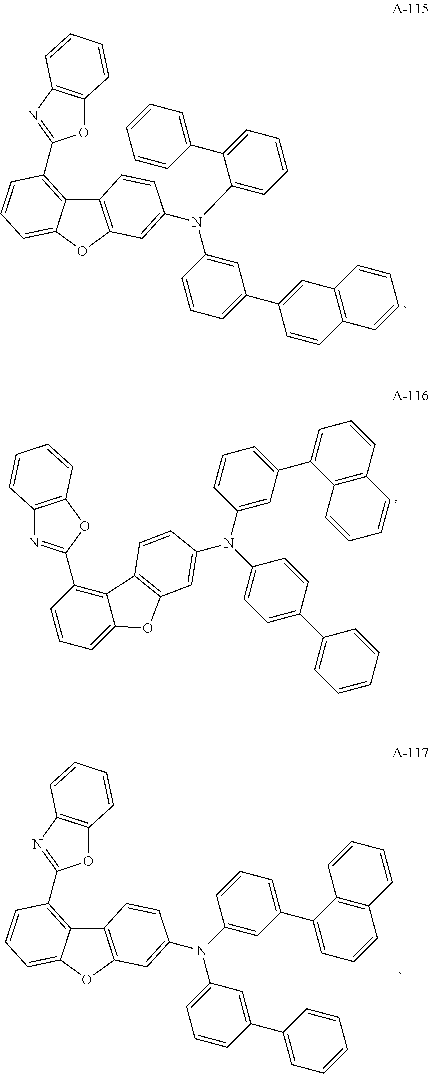 [SMILES: c1ccc(-c2ccccc2N(c2cccc(-c3ccc4ccccc4c3)c2)c2ccc3c(c2)oc2cccc(-c4nc5ccccc5o4)c23)cc1 ; c1ccc(-c2ccc(N(c3cccc(-c4cccc5ccccc45)c3)c3ccc4c(c3)oc3cccc(-c5nc6ccccc6o5)c34)cc2)cc1 ; c1ccc(-c2cccc(N(c3cccc(-c4cccc5ccccc45)c3)c3ccc4c(c3)oc3cccc(-c5nc6ccccc6o5)c34)c2)cc1] 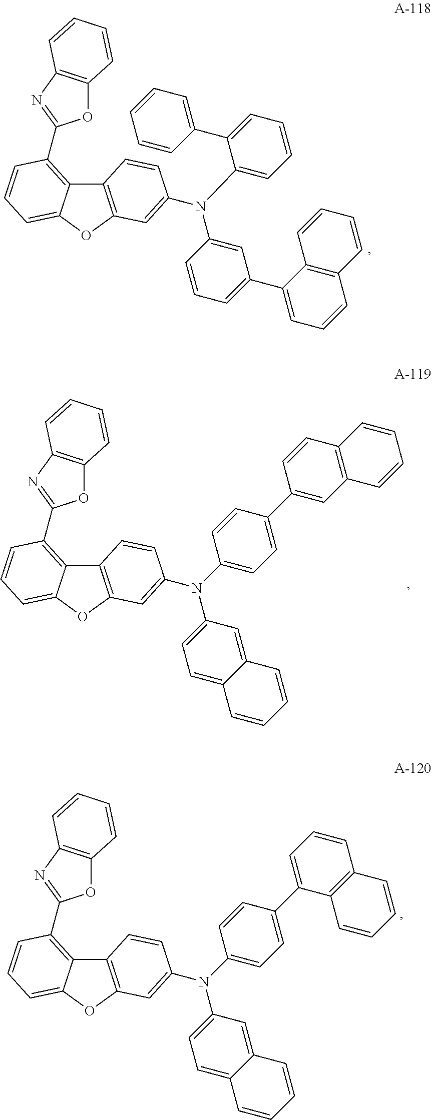 [SMILES: c1ccc(-c2ccccc2N(c2cccc(-c3cccc4ccccc34)c2)c2ccc3c(c2)oc2cccc(-c4nc5ccccc5o4)c23)cc1 ; c1ccc2cc(-c3ccc(N(c4ccc5ccccc5c4)c4ccc5c(c4)oc4cccc(-c6nc7ccccc7o6)c45)cc3)ccc2c1 ; c1ccc2cc(N(c3ccc(-c4cccc5ccccc45)cc3)c3ccc4c(c3)oc3cccc(-c5nc6ccccc6o5)c34)ccc2c1] 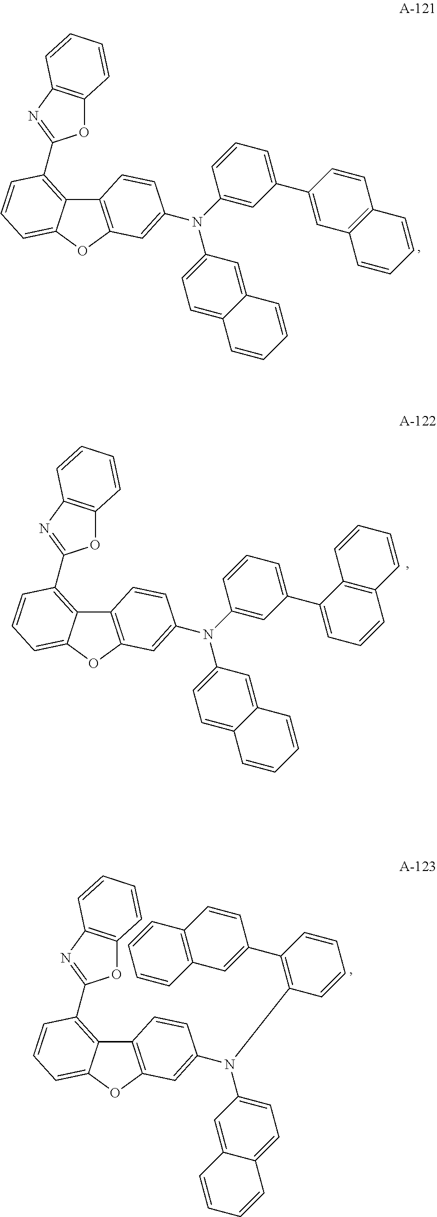 [SMILES: c1cc(-c2ccc3ccccc3c2)cc(N(c2ccc3ccccc3c2)c2ccc3c(c2)oc2cccc(-c4nc5ccccc5o4)c23)c1 ; c1cc(-c2cccc3ccccc23)cc(N(c2ccc3ccccc3c2)c2ccc3c(c2)oc2cccc(-c4nc5ccccc5o4)c23)c1 ; c1ccc(N(c2ccc3ccccc3c2)c2ccc3c(c2)oc2cccc(-c4nc5ccccc5o4)c23)c(-c2ccc3ccccc3c2)c1] 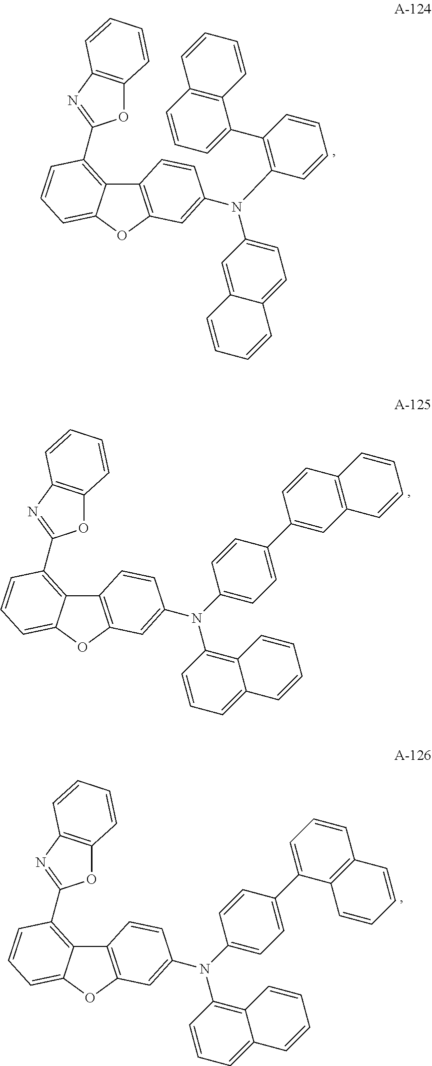 [SMILES: c1ccc(N(c2ccc3ccccc3c2)c2ccc3c(c2)oc2cccc(-c4nc5ccccc5o4)c23)c(-c2cccc3ccccc23)c1 ; c1ccc2cc(-c3ccc(N(c4ccc5c(c4)oc4cccc(-c6nc7ccccc7o6)c45)c4cccc5ccccc45)cc3)ccc2c1 ; c1ccc2c(-c3ccc(N(c4ccc5c(c4)oc4cccc(-c6nc7ccccc7o6)c45)c4cccc5ccccc45)cc3)cccc2c1] 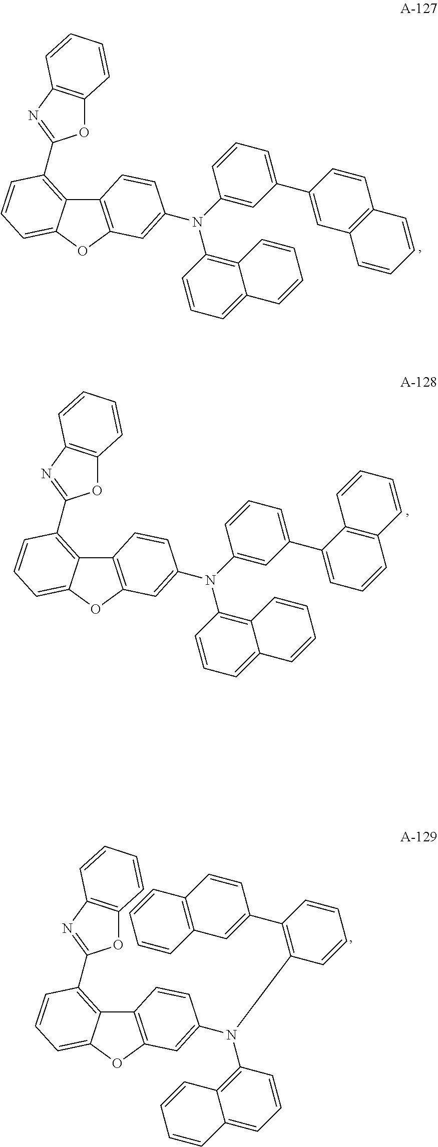 [SMILES: c1cc(-c2ccc3ccccc3c2)cc(N(c2ccc3c(c2)oc2cccc(-c4nc5ccccc5o4)c23)c2cccc3ccccc23)c1 ; c1cc(-c2cccc3ccccc23)cc(N(c2ccc3c(c2)oc2cccc(-c4nc5ccccc5o4)c23)c2cccc3ccccc23)c1 ; c1ccc(N(c2ccc3c(c2)oc2cccc(-c4nc5ccccc5o4)c23)c2cccc3ccccc23)c(-c2ccc3ccccc3c2)c1] 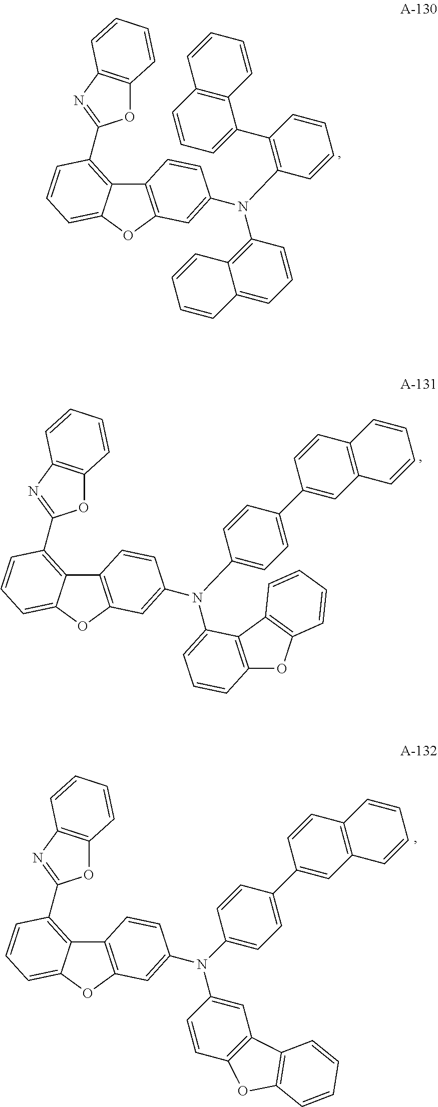 [SMILES: c1ccc(N(c2ccc3c(c2)oc2cccc(-c4nc5ccccc5o4)c23)c2cccc3ccccc23)c(-c2cccc3ccccc23)c1 ; c1ccc2cc(-c3ccc(N(c4ccc5c(c4)oc4cccc(-c6nc7ccccc7o6)c45)c4cccc5oc6ccccc6c45)cc3)ccc2c1 ; c1ccc2cc(-c3ccc(N(c4ccc5c(c4)oc4cccc(-c6nc7ccccc7o6)c45)c4ccc5oc6ccccc6c5c4)cc3)ccc2c1] 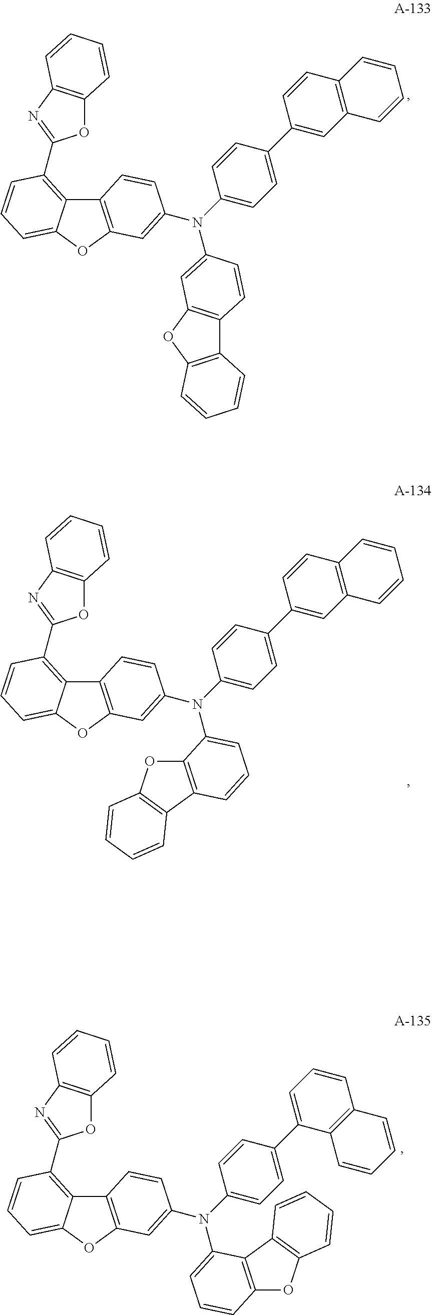 [SMILES: c1ccc2cc(-c3ccc(N(c4ccc5c(c4)oc4ccccc45)c4ccc5c(c4)oc4cccc(-c6nc7ccccc7o6)c45)cc3)ccc2c1 ; c1ccc2cc(-c3ccc(N(c4ccc5c(c4)oc4cccc(-c6nc7ccccc7o6)c45)c4cccc5c4oc4ccccc45)cc3)ccc2c1 ; c1ccc2c(-c3ccc(N(c4ccc5c(c4)oc4cccc(-c6nc7ccccc7o6)c45)c4cccc5oc6ccccc6c45)cc3)cccc2c1] 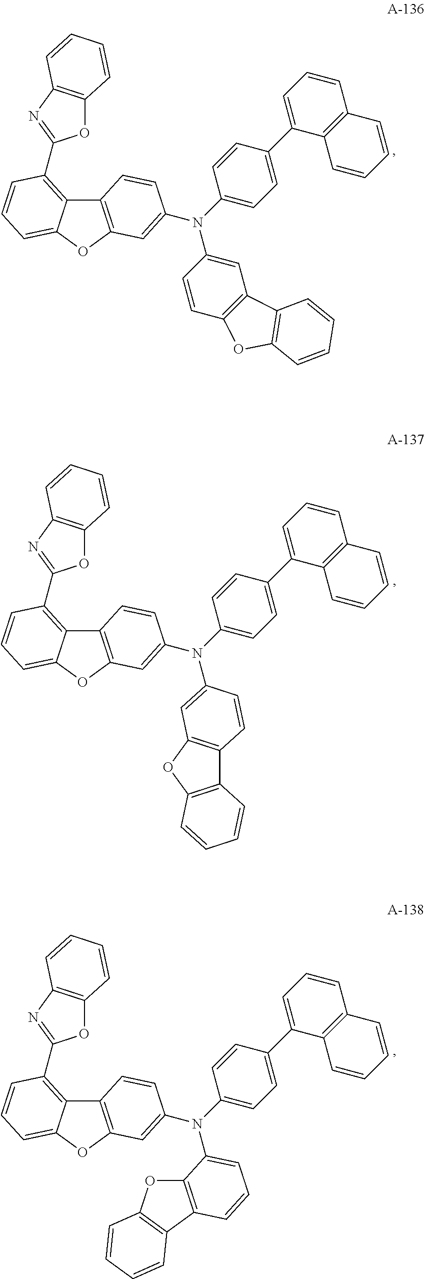 [SMILES: c1ccc2c(-c3ccc(N(c4ccc5c(c4)oc4cccc(-c6nc7ccccc7o6)c45)c4ccc5oc6ccccc6c5c4)cc3)cccc2c1 ; c1ccc2c(-c3ccc(N(c4ccc5c(c4)oc4ccccc45)c4ccc5c(c4)oc4cccc(-c6nc7ccccc7o6)c45)cc3)cccc2c1 ; c1ccc2c(-c3ccc(N(c4ccc5c(c4)oc4cccc(-c6nc7ccccc7o6)c45)c4cccc5c4oc4ccccc45)cc3)cccc2c1] 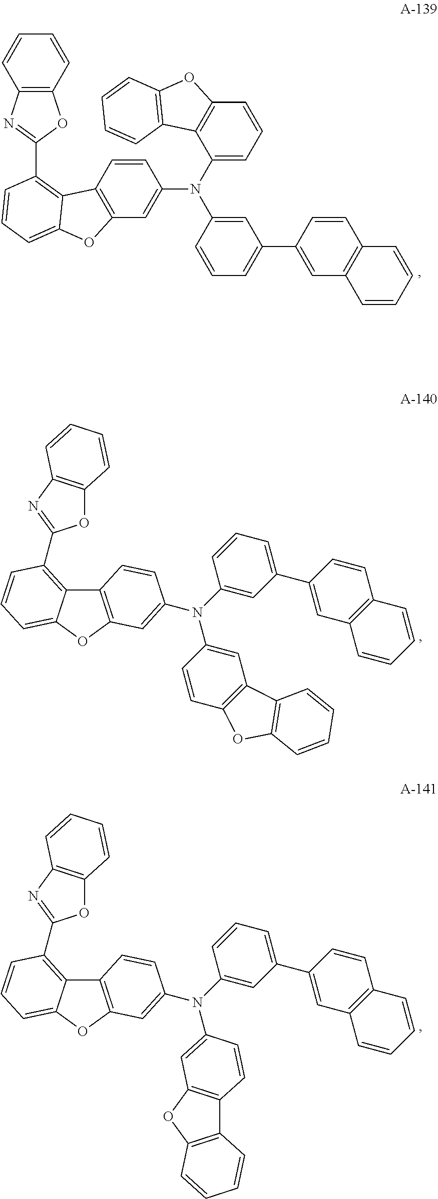 [SMILES: c1cc(-c2ccc3ccccc3c2)cc(N(c2ccc3c(c2)oc2cccc(-c4nc5ccccc5o4)c23)c2cccc3oc4ccccc4c23)c1 ; c1cc(-c2ccc3ccccc3c2)cc(N(c2ccc3c(c2)oc2cccc(-c4nc5ccccc5o4)c23)c2ccc3oc4ccccc4c3c2)c1 ; c1cc(-c2ccc3ccccc3c2)cc(N(c2ccc3c(c2)oc2ccccc23)c2ccc3c(c2)oc2cccc(-c4nc5ccccc5o4)c23)c1] 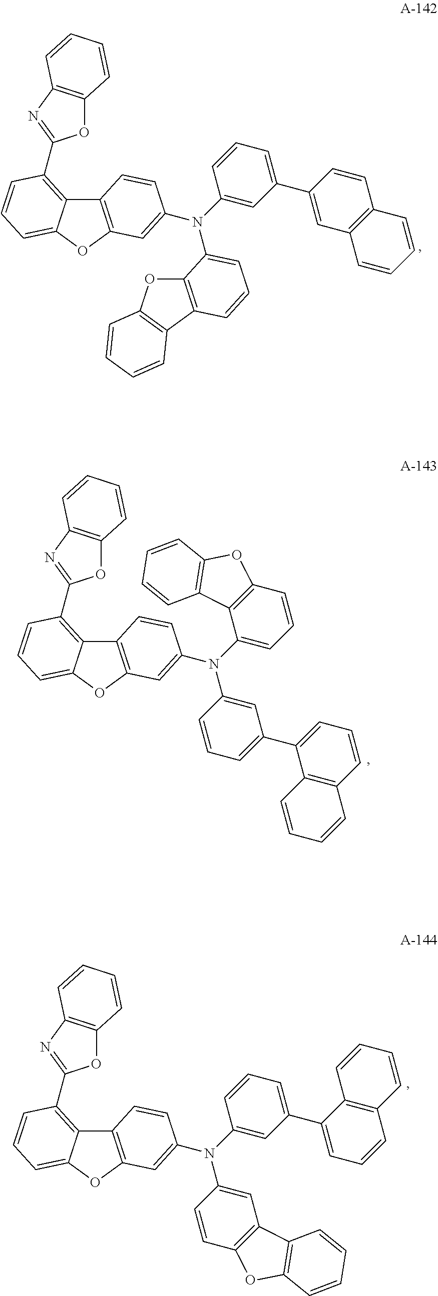 [SMILES: c1cc(-c2ccc3ccccc3c2)cc(N(c2ccc3c(c2)oc2cccc(-c4nc5ccccc5o4)c23)c2cccc3c2oc2ccccc23)c1 ; c1cc(-c2cccc3ccccc23)cc(N(c2ccc3c(c2)oc2cccc(-c4nc5ccccc5o4)c23)c2cccc3oc4ccccc4c23)c1 ; c1cc(-c2cccc3ccccc23)cc(N(c2ccc3c(c2)oc2cccc(-c4nc5ccccc5o4)c23)c2ccc3oc4ccccc4c3c2)c1] 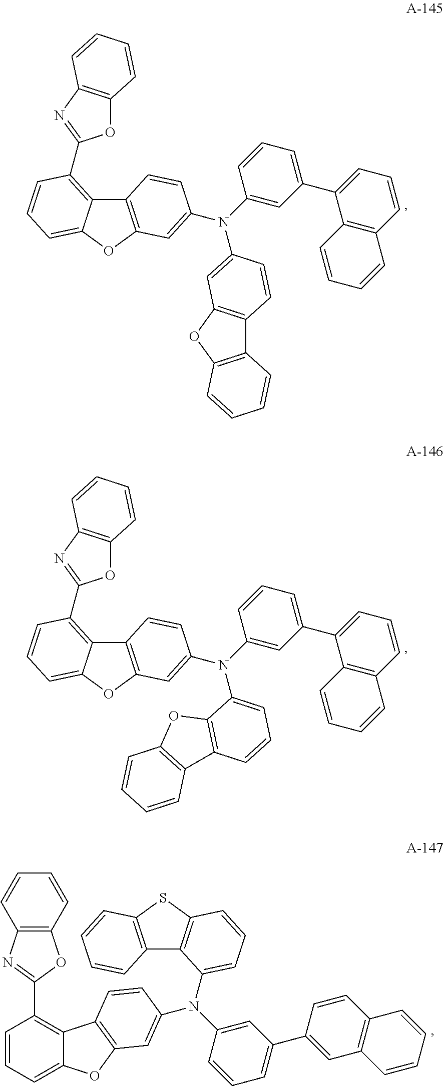 [SMILES: c1cc(-c2cccc3ccccc23)cc(N(c2ccc3c(c2)oc2ccccc23)c2ccc3c(c2)oc2cccc(-c4nc5ccccc5o4)c23)c1 ; c1cc(-c2cccc3ccccc23)cc(N(c2ccc3c(c2)oc2cccc(-c4nc5ccccc5o4)c23)c2cccc3c2oc2ccccc23)c1 ; c1cc(-c2ccc3ccccc3c2)cc(N(c2ccc3c(c2)oc2cccc(-c4nc5ccccc5o4)c23)c2cccc3sc4ccccc4c23)c1] 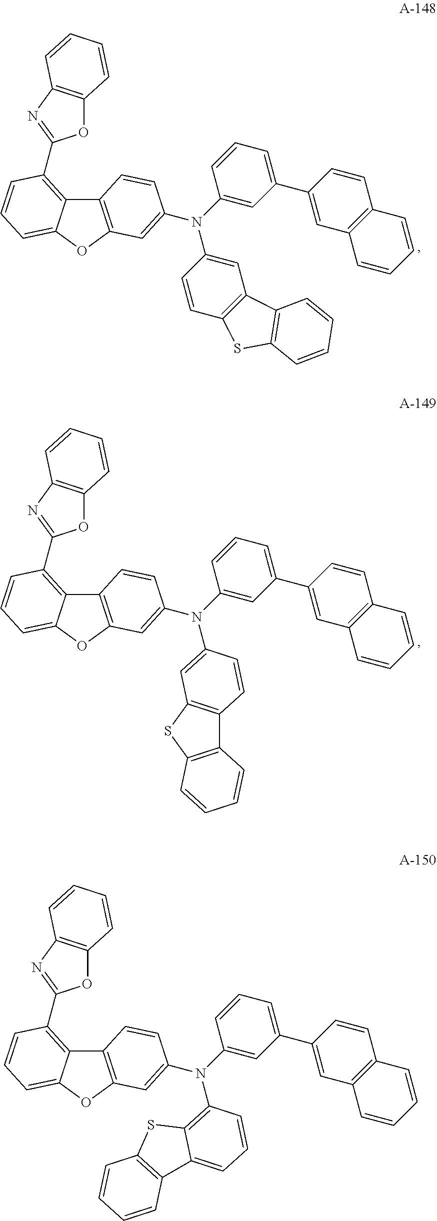 [SMILES: c1cc(-c2ccc3ccccc3c2)cc(N(c2ccc3c(c2)oc2cccc(-c4nc5ccccc5o4)c23)c2ccc3sc4ccccc4c3c2)c1 ; c1cc(-c2ccc3ccccc3c2)cc(N(c2ccc3c(c2)oc2cccc(-c4nc5ccccc5o4)c23)c2ccc3c(c2)sc2ccccc23)c1 ; c1cc(-c2ccc3ccccc3c2)cc(N(c2ccc3c(c2)oc2cccc(-c4nc5ccccc5o4)c23)c2cccc3c2sc2ccccc23)c1] 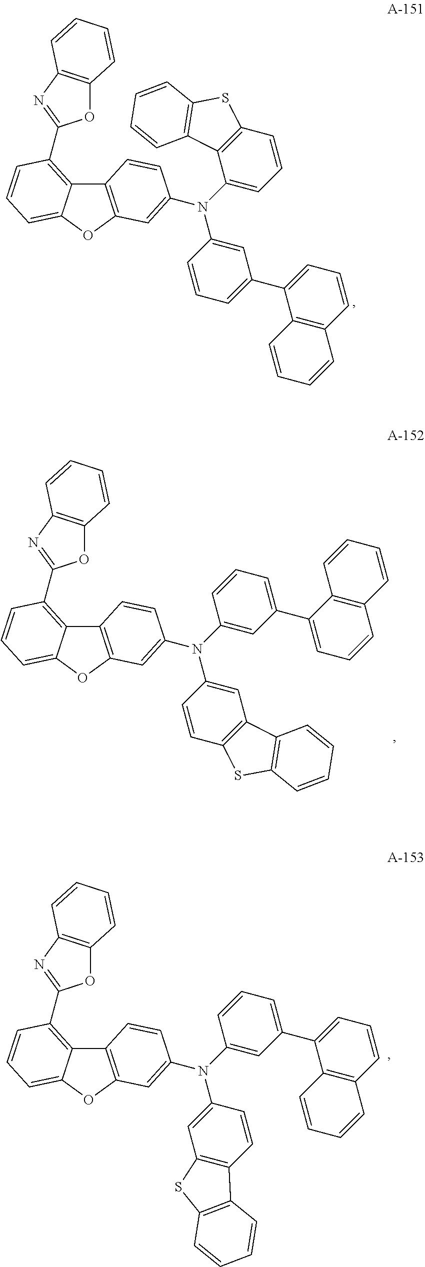 [SMILES: c1cc(-c2cccc3ccccc23)cc(N(c2ccc3c(c2)oc2cccc(-c4nc5ccccc5o4)c23)c2cccc3sc4ccccc4c23)c1 ; c1cc(-c2cccc3ccccc23)cc(N(c2ccc3c(c2)oc2cccc(-c4nc5ccccc5o4)c23)c2ccc3sc4ccccc4c3c2)c1 ; c1cc(-c2cccc3ccccc23)cc(N(c2ccc3c(c2)oc2cccc(-c4nc5ccccc5o4)c23)c2ccc3c(c2)sc2ccccc23)c1] 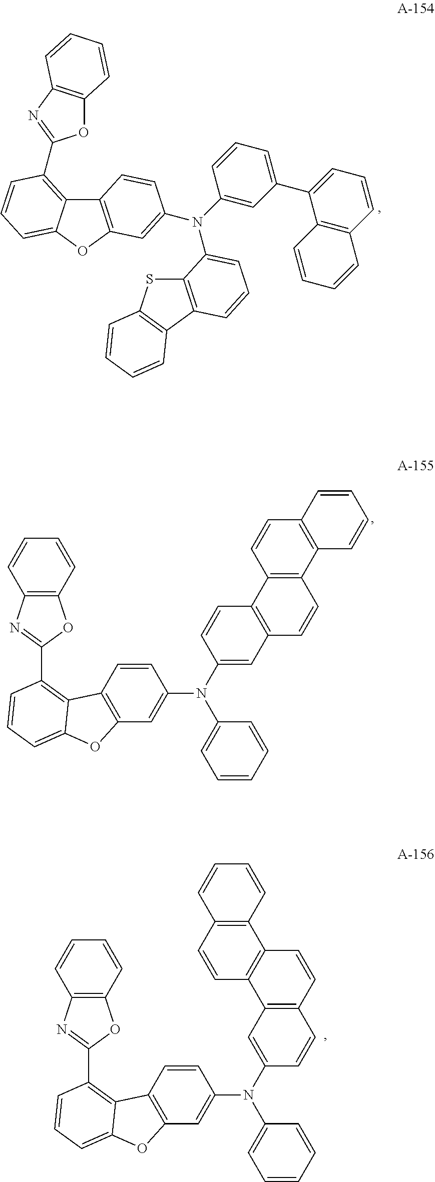 [SMILES: c1cc(-c2cccc3ccccc23)cc(N(c2ccc3c(c2)oc2cccc(-c4nc5ccccc5o4)c23)c2cccc3c2sc2ccccc23)c1 ; c1ccc(N(c2ccc3c(ccc4c5ccccc5ccc34)c2)c2ccc3c(c2)oc2cccc(-c4nc5ccccc5o4)c23)cc1 ; c1ccc(N(c2ccc3c(c2)oc2cccc(-c4nc5ccccc5o4)c23)c2ccc3ccc4c5ccccc5ccc4c3c2)cc1] 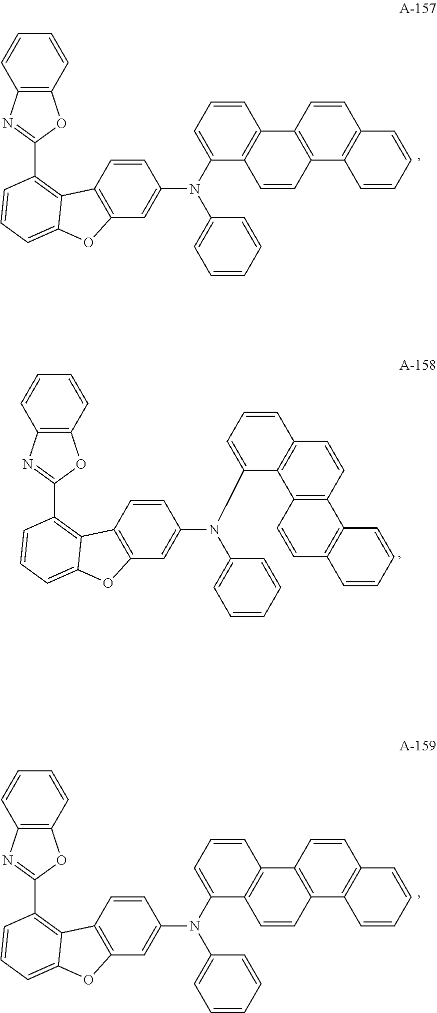 [SMILES: c1ccc(N(c2ccc3c(c2)oc2cccc(-c4nc5ccccc5o4)c23)c2cccc3c2ccc2c4ccccc4ccc32)cc1 ; c1ccc(N(c2ccc3c(c2)oc2cccc(-c4nc5ccccc5o4)c23)c2cccc3ccc4c5ccccc5ccc4c23)cc1 ; c1ccc(N(c2ccc3c(c2)oc2cccc(-c4nc5ccccc5o4)c23)c2cccc3c2ccc2c4ccccc4ccc32)cc1] 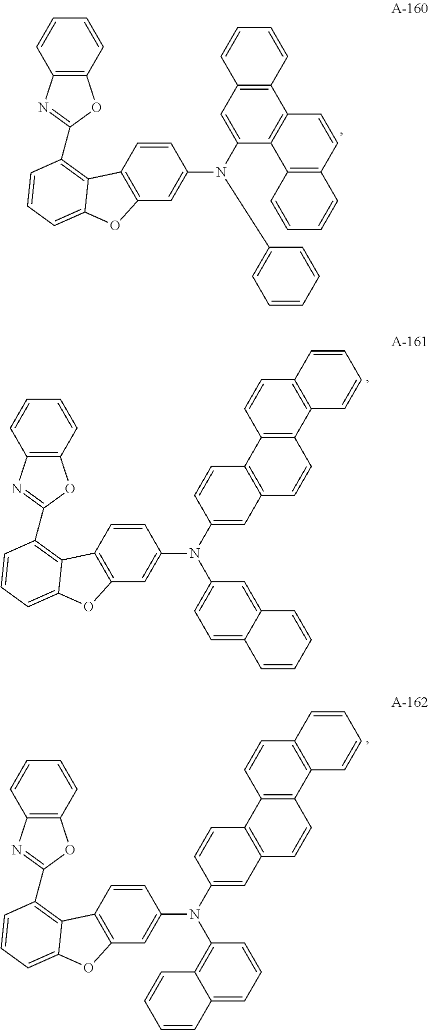 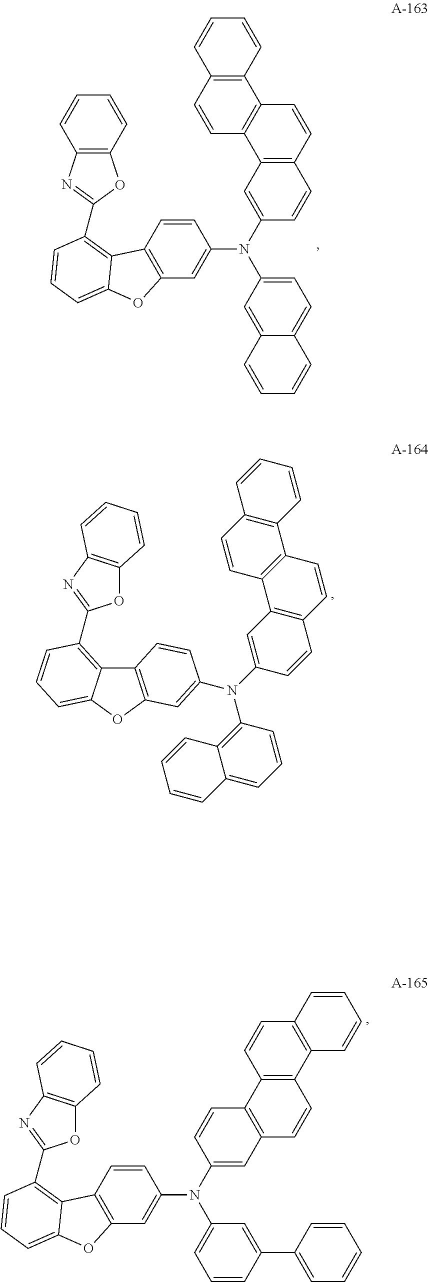 [SMILES: c1ccc2cc(N(c3ccc4c(c3)oc3cccc(-c5nc6ccccc6o5)c34)c3ccc4ccc5c6ccccc6ccc5c4c3)ccc2c1 ; c1ccc2c(N(c3ccc4c(c3)oc3cccc(-c5nc6ccccc6o5)c34)c3ccc4ccc5c6ccccc6ccc5c4c3)cccc2c1 ; c1ccc(-c2cccc(N(c3ccc4c(ccc5c6ccccc6ccc45)c3)c3ccc4c(c3)oc3cccc(-c5nc6ccccc6o5)c34)c2)cc1] 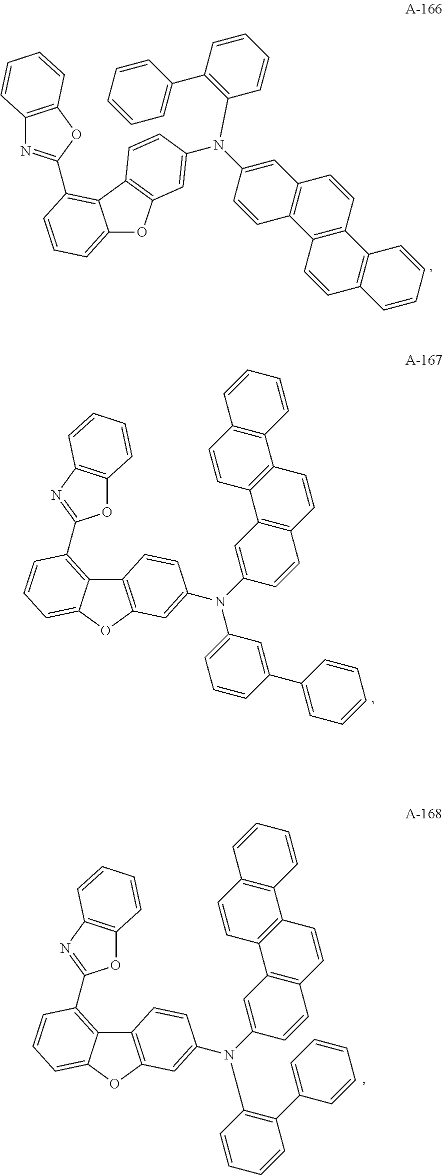 [SMILES: c1ccc(-c2ccccc2N(c2ccc3c(ccc4c5ccccc5ccc34)c2)c2ccc3c(c2)oc2cccc(-c4nc5ccccc5o4)c23)cc1 ; c1ccc(-c2cccc(N(c3ccc4c(c3)oc3cccc(-c5nc6ccccc6o5)c34)c3ccc4ccc5c6ccccc6ccc5c4c3)c2)cc1 ; c1ccc(-c2ccccc2N(c2ccc3c(c2)oc2cccc(-c4nc5ccccc5o4)c23)c2ccc3ccc4c5ccccc5ccc4c3c2)cc1] 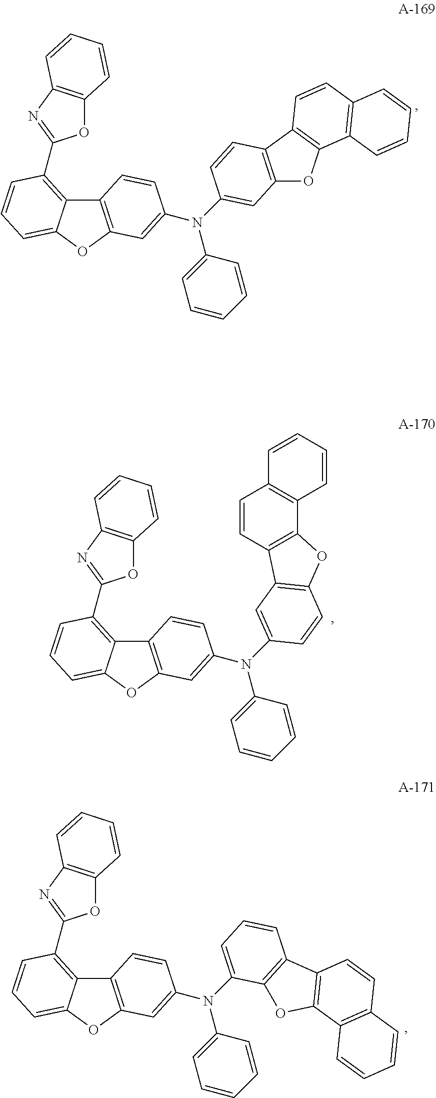 [SMILES: c1ccc(N(c2ccc3c(c2)oc2c4ccccc4ccc32)c2ccc3c(c2)oc2cccc(-c4nc5ccccc5o4)c23)cc1 ; c1ccc(N(c2ccc3c(c2)oc2cccc(-c4nc5ccccc5o4)c23)c2ccc3oc4c5ccccc5ccc4c3c2)cc1 ; c1ccc(N(c2ccc3c(c2)oc2cccc(-c4nc5ccccc5o4)c23)c2cccc3c2oc2c4ccccc4ccc32)cc1] 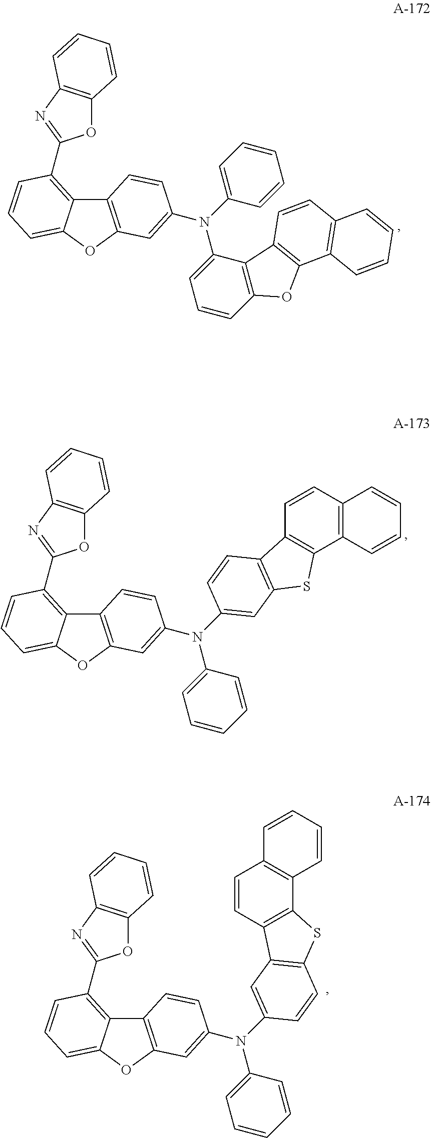 [SMILES: c1ccc(N(c2ccc3c(c2)oc2cccc(-c4nc5ccccc5o4)c23)c2cccc3oc4c5ccccc5ccc4c23)cc1 ; c1ccc(N(c2ccc3c(c2)oc2cccc(-c4nc5ccccc5o4)c23)c2ccc3c(c2)sc2c4ccccc4ccc32)cc1 ; c1ccc(N(c2ccc3c(c2)oc2cccc(-c4nc5ccccc5o4)c23)c2ccc3sc4c5ccccc5ccc4c3c2)cc1] 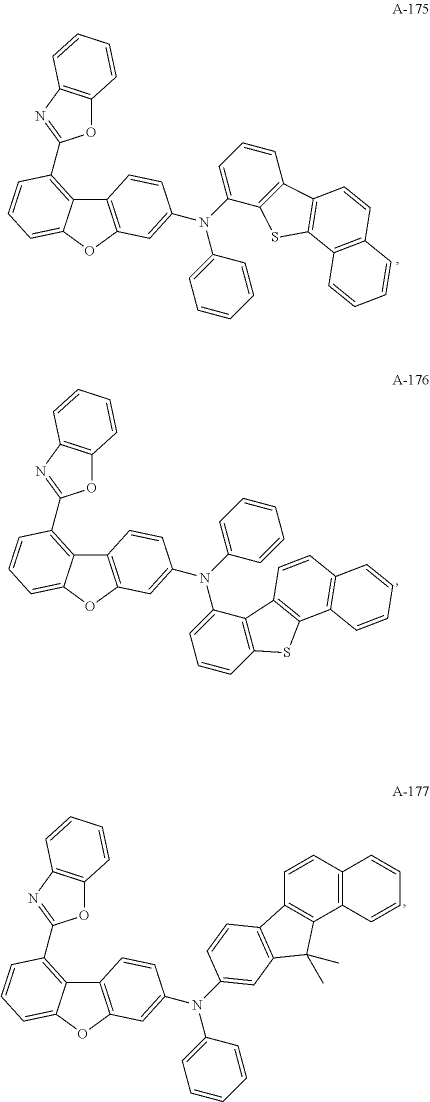 [SMILES: c1ccc(N(c2ccc3c(c2)oc2cccc(-c4nc5ccccc5o4)c23)c2cccc3c2sc2c4ccccc4ccc32)cc1 ; c1ccc(N(c2ccc3c(c2)oc2cccc(-c4nc5ccccc5o4)c23)c2cccc3sc4c5ccccc5ccc4c23)cc1 ; CC1(C)c2cc(N(c3ccccc3)c3ccc4c(c3)oc3cccc(-c5nc6ccccc6o5)c34)ccc2-c2ccc3ccccc3c21] 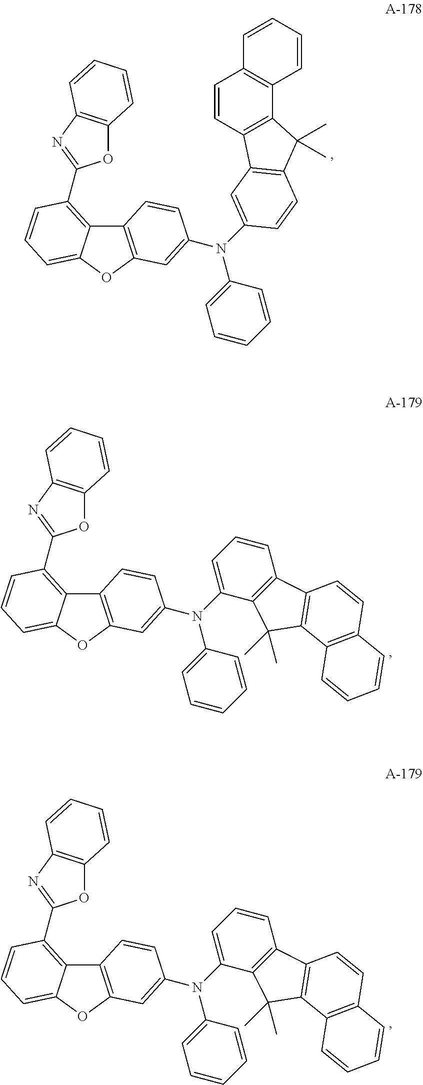 [SMILES: CC1(C)c2ccc(N(c3ccccc3)c3ccc4c(c3)oc3cccc(-c5nc6ccccc6o5)c34)cc2-c2ccc3ccccc3c21 ; CC1(C)c2c(cccc2N(c2ccccc2)c2ccc3c(c2)oc2cccc(-c4nc5ccccc5o4)c23)-c2ccc3ccccc3c21 ; CC1(C)c2c(cccc2N(c2ccccc2)c2ccc3c(c2)oc2cccc(-c4nc5ccccc5o4)c23)-c2ccc3ccccc3c21] 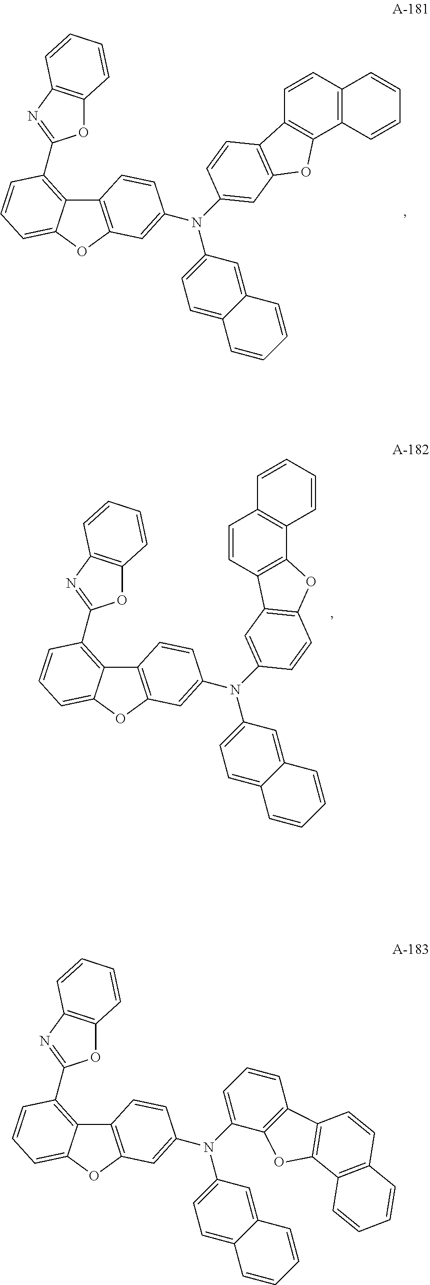 [SMILES: c1ccc2cc(N(c3ccc4c(c3)oc3c5ccccc5ccc43)c3ccc4c(c3)oc3cccc(-c5nc6ccccc6o5)c34)ccc2c1 ; c1ccc2cc(N(c3ccc4c(c3)oc3cccc(-c5nc6ccccc6o5)c34)c3ccc4oc5c6ccccc6ccc5c4c3)ccc2c1 ; c1ccc2cc(N(c3ccc4c(c3)oc3cccc(-c5nc6ccccc6o5)c34)c3cccc4c3oc3c5ccccc5ccc43)ccc2c1] 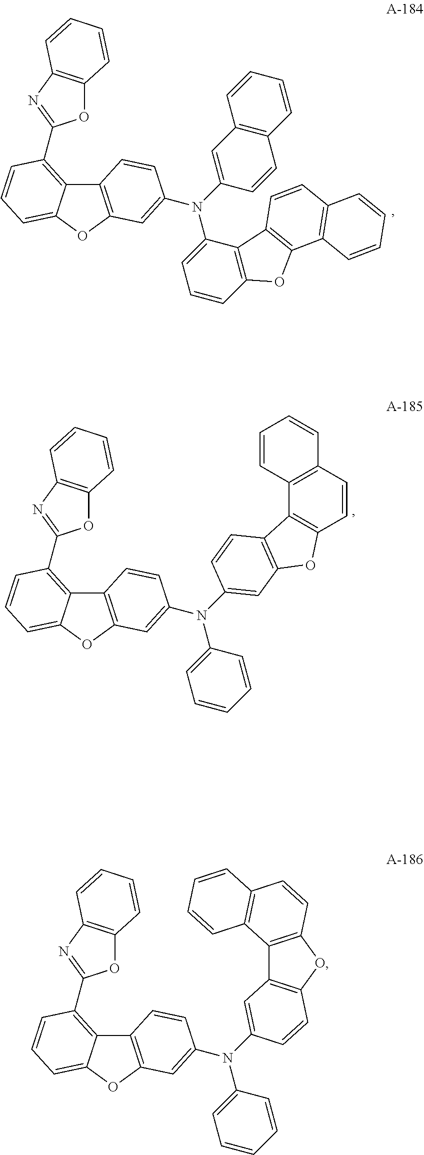 [SMILES: c1ccc2cc(N(c3ccc4c(c3)oc3cccc(-c5nc6ccccc6o5)c34)c3cccc4oc5c6ccccc6ccc5c34)ccc2c1 ; c1ccc(N(c2ccc3c(c2)oc2cccc(-c4nc5ccccc5o4)c23)c2ccc3c(c2)oc2ccc4ccccc4c23)cc1 ; c1ccc(N(c2ccc3c(c2)oc2cccc(-c4nc5ccccc5o4)c23)c2ccc3oc4ccc5ccccc5c4c3c2)cc1] 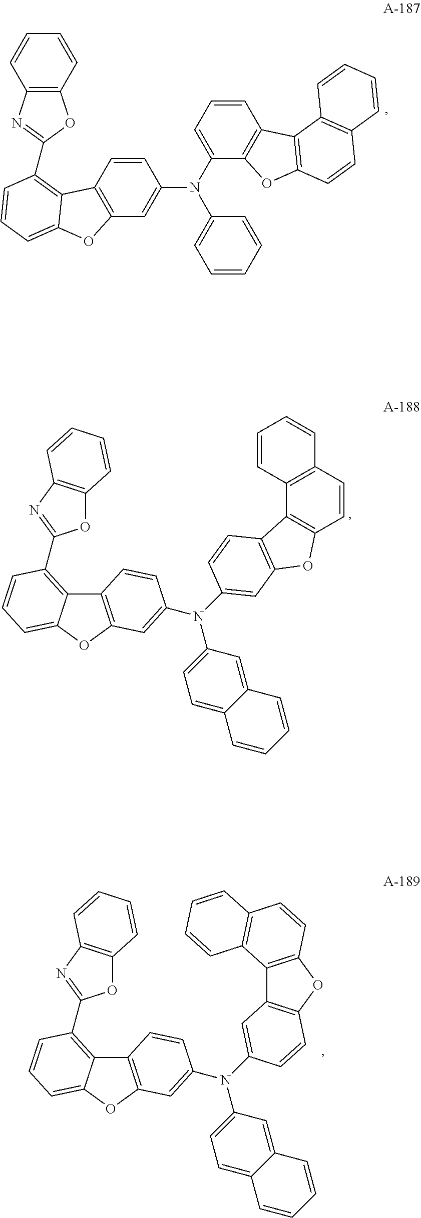 [SMILES: c1ccc(N(c2ccc3c(c2)oc2cccc(-c4nc5ccccc5o4)c23)c2cccc3c2oc2ccc4ccccc4c23)cc1 ; c1ccc2cc(N(c3ccc4c(c3)oc3cccc(-c5nc6ccccc6o5)c34)c3ccc4c(c3)oc3ccc5ccccc5c34)ccc2c1 ; c1ccc2cc(N(c3ccc4c(c3)oc3cccc(-c5nc6ccccc6o5)c34)c3ccc4oc5ccc6ccccc6c5c4c3)ccc2c1] 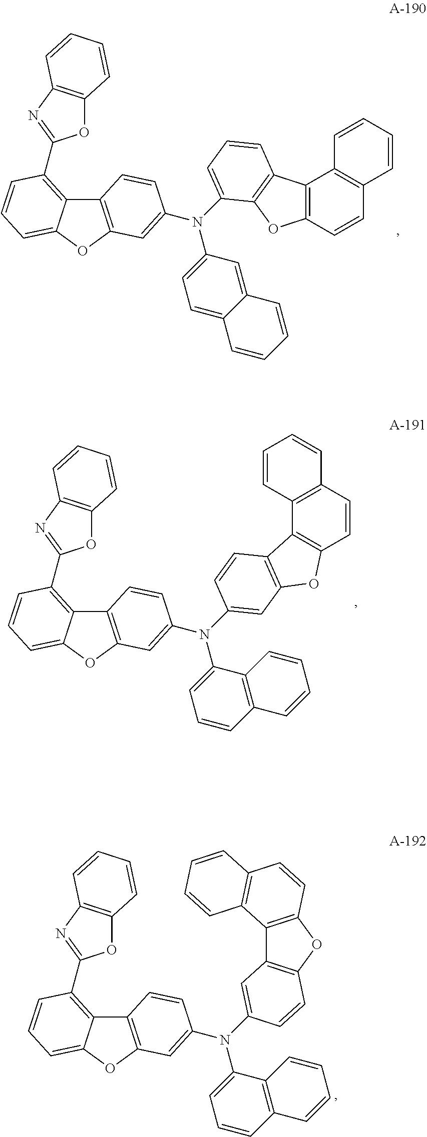 [SMILES: c1ccc2cc(N(c3ccc4c(c3)oc3cccc(-c5nc6ccccc6o5)c34)c3cccc4c3oc3ccc5ccccc5c34)ccc2c1 ; c1ccc2c(N(c3ccc4c(c3)oc3cccc(-c5nc6ccccc6o5)c34)c3ccc4c(c3)oc3ccc5ccccc5c34)cccc2c1 ; c1ccc2c(N(c3ccc4c(c3)oc3cccc(-c5nc6ccccc6o5)c34)c3ccc4oc5ccc6ccccc6c5c4c3)cccc2c1] 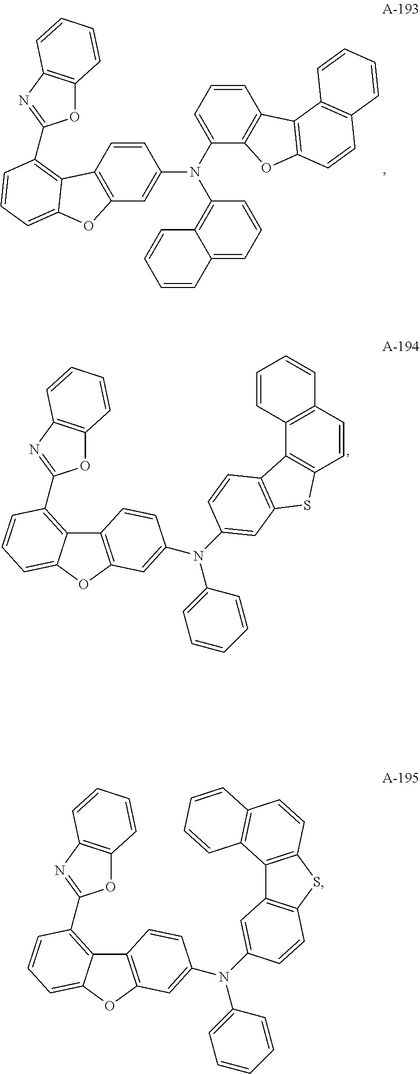 [SMILES: c1ccc2c(N(c3ccc4c(c3)oc3cccc(-c5nc6ccccc6o5)c34)c3cccc4c3oc3ccc5ccccc5c34)cccc2c1 ; c1ccc(N(c2ccc3c(c2)oc2cccc(-c4nc5ccccc5o4)c23)c2ccc3c(c2)sc2ccc4ccccc4c23)cc1 ; c1ccc(N(c2ccc3c(c2)oc2cccc(-c4nc5ccccc5o4)c23)c2ccc3sc4ccc5ccccc5c4c3c2)cc1] 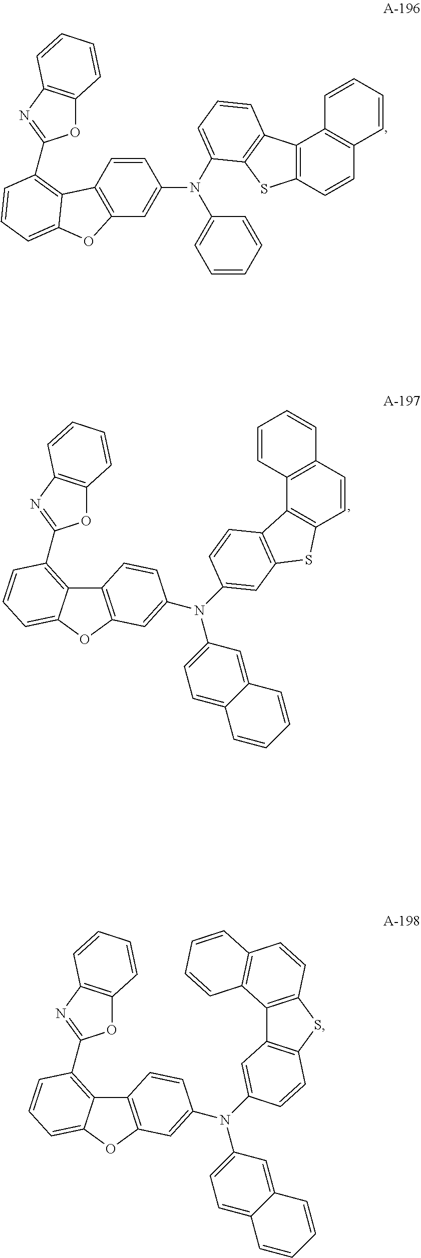 [SMILES: c1ccc(N(c2ccc3c(c2)oc2cccc(-c4nc5ccccc5o4)c23)c2cccc3c2sc2ccc4ccccc4c23)cc1 ; c1ccc2cc(N(c3ccc4c(c3)oc3cccc(-c5nc6ccccc6o5)c34)c3ccc4c(c3)sc3ccc5ccccc5c34)ccc2c1 ; c1ccc2cc(N(c3ccc4c(c3)oc3cccc(-c5nc6ccccc6o5)c34)c3ccc4sc5ccc6ccccc6c5c4c3)ccc2c1] 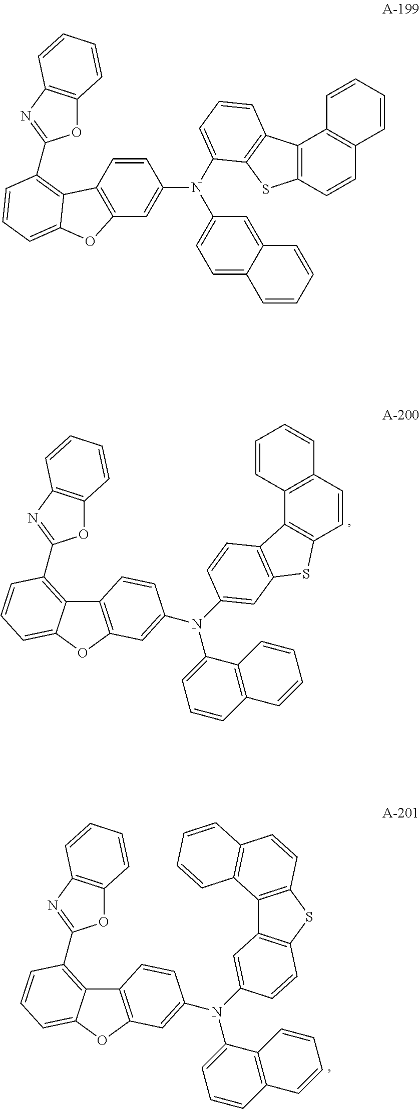 [SMILES: c1ccc2cc(N(c3ccc4c(c3)oc3cccc(-c5nc6ccccc6o5)c34)c3cccc4c3sc3ccc5ccccc5c34)ccc2c1 ; c1ccc2c(N(c3ccc4c(c3)oc3cccc(-c5nc6ccccc6o5)c34)c3ccc4c(c3)sc3ccc5ccccc5c34)cccc2c1 ; c1ccc2c(N(c3ccc4c(c3)oc3cccc(-c5nc6ccccc6o5)c34)c3ccc4sc5ccc6ccccc6c5c4c3)cccc2c1] 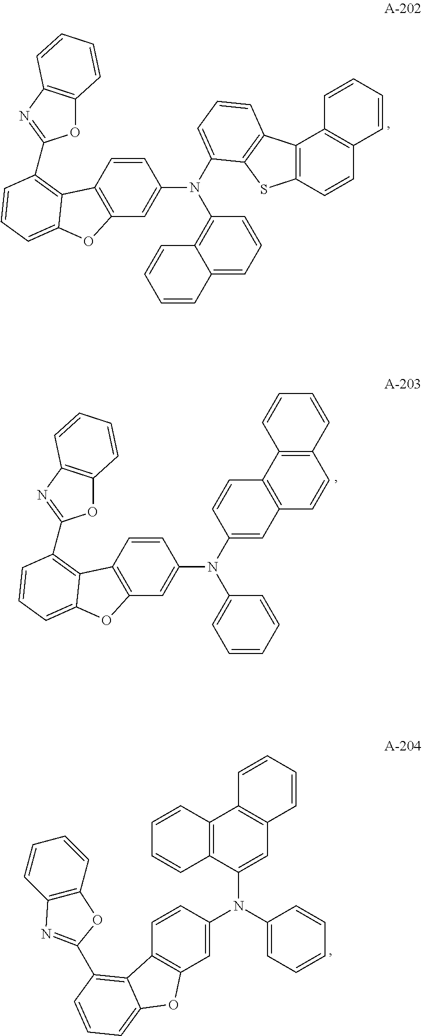 [SMILES: c1ccc2c(N(c3ccc4c(c3)oc3cccc(-c5nc6ccccc6o5)c34)c3cccc4c3sc3ccc5ccccc5c34)cccc2c1 ; c1ccc(N(c2ccc3c(ccc4ccccc43)c2)c2ccc3c(c2)oc2cccc(-c4nc5ccccc5o4)c23)cc1 ; c1ccc(N(c2ccc3c(c2)oc2cccc(-c4nc5ccccc5o4)c23)c2cc3ccccc3c3ccccc23)cc1] 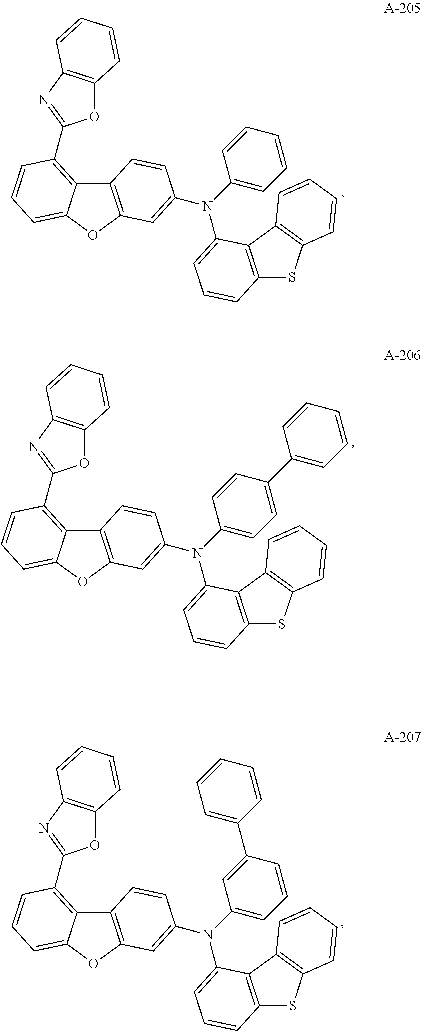 [SMILES: c1ccc(N(c2ccc3c(c2)oc2cccc(-c4nc5ccccc5o4)c23)c2cccc3sc4ccccc4c23)cc1 ; c1ccc(-c2ccc(N(c3ccc4c(c3)oc3cccc(-c5nc6ccccc6o5)c34)c3cccc4sc5ccccc5c34)cc2)cc1 ; c1ccc(-c2cccc(N(c3ccc4c(c3)oc3cccc(-c5nc6ccccc6o5)c34)c3cccc4sc5ccccc5c34)c2)cc1] 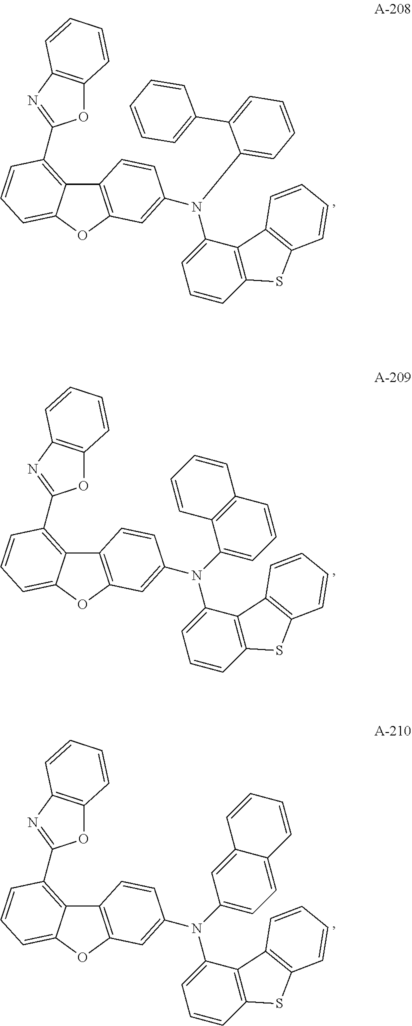 [SMILES: c1ccc(-c2ccccc2N(c2ccc3c(c2)oc2cccc(-c4nc5ccccc5o4)c23)c2cccc3sc4ccccc4c23)cc1 ; c1ccc2c(N(c3ccc4c(c3)oc3cccc(-c5nc6ccccc6o5)c34)c3cccc4sc5ccccc5c34)cccc2c1 ; c1ccc2cc(N(c3ccc4c(c3)oc3cccc(-c5nc6ccccc6o5)c34)c3cccc4sc5ccccc5c34)ccc2c1] 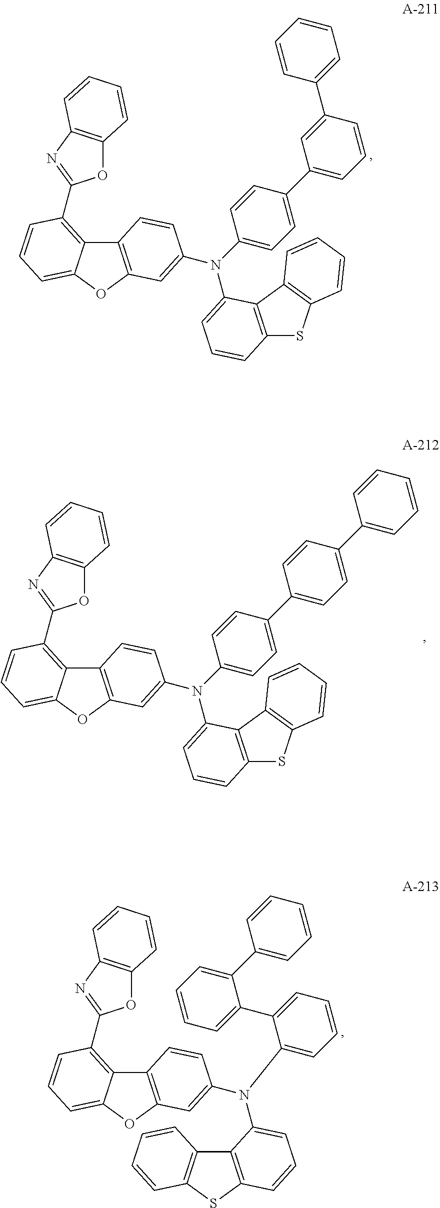 [SMILES: c1ccc(-c2cccc(-c3ccc(N(c4ccc5c(c4)oc4cccc(-c6nc7ccccc7o6)c45)c4cccc5sc6ccccc6c45)cc3)c2)cc1 ; c1ccc(-c2ccc(-c3ccc(N(c4ccc5c(c4)oc4cccc(-c6nc7ccccc7o6)c45)c4cccc5sc6ccccc6c45)cc3)cc2)cc1 ; c1ccc(-c2ccccc2-c2ccccc2N(c2ccc3c(c2)oc2cccc(-c4nc5ccccc5o4)c23)c2cccc3sc4ccccc4c23)cc1] 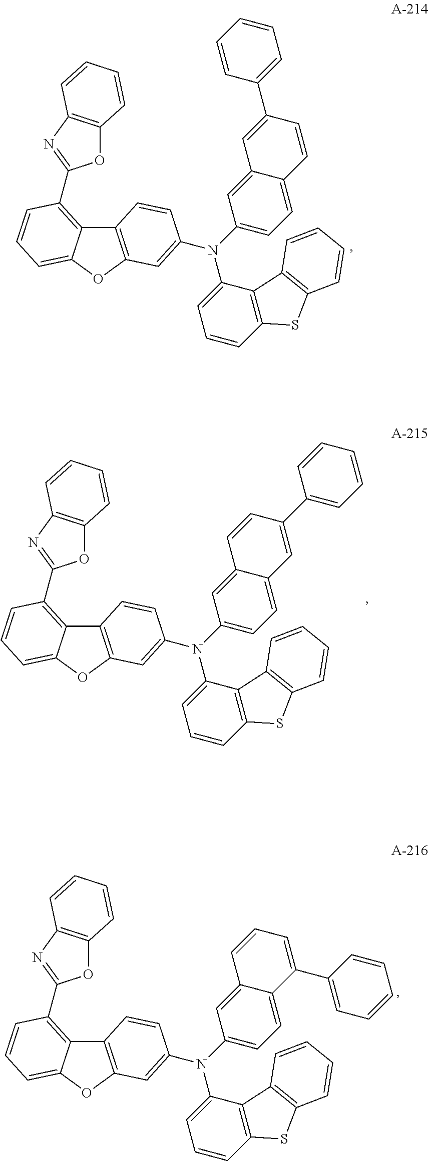 [SMILES: c1ccc(-c2ccc3ccc(N(c4ccc5c(c4)oc4cccc(-c6nc7ccccc7o6)c45)c4cccc5sc6ccccc6c45)cc3c2)cc1 ; c1ccc(-c2ccc3cc(N(c4ccc5c(c4)oc4cccc(-c6nc7ccccc7o6)c45)c4cccc5sc6ccccc6c45)ccc3c2)cc1 ; c1ccc(-c2cccc3cc(N(c4ccc5c(c4)oc4cccc(-c6nc7ccccc7o6)c45)c4cccc5sc6ccccc6c45)ccc23)cc1] 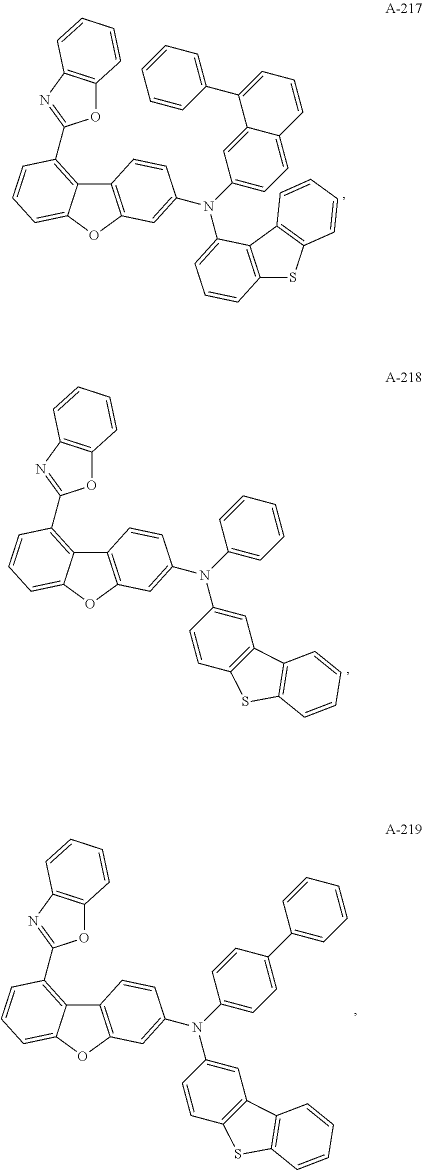 [SMILES: c1ccc(-c2cccc3ccc(N(c4ccc5c(c4)oc4cccc(-c6nc7ccccc7o6)c45)c4cccc5sc6ccccc6c45)cc23)cc1 ; c1ccc(N(c2ccc3c(c2)oc2cccc(-c4nc5ccccc5o4)c23)c2ccc3sc4ccccc4c3c2)cc1 ; c1ccc(-c2ccc(N(c3ccc4c(c3)oc3cccc(-c5nc6ccccc6o5)c34)c3ccc4sc5ccccc5c4c3)cc2)cc1] 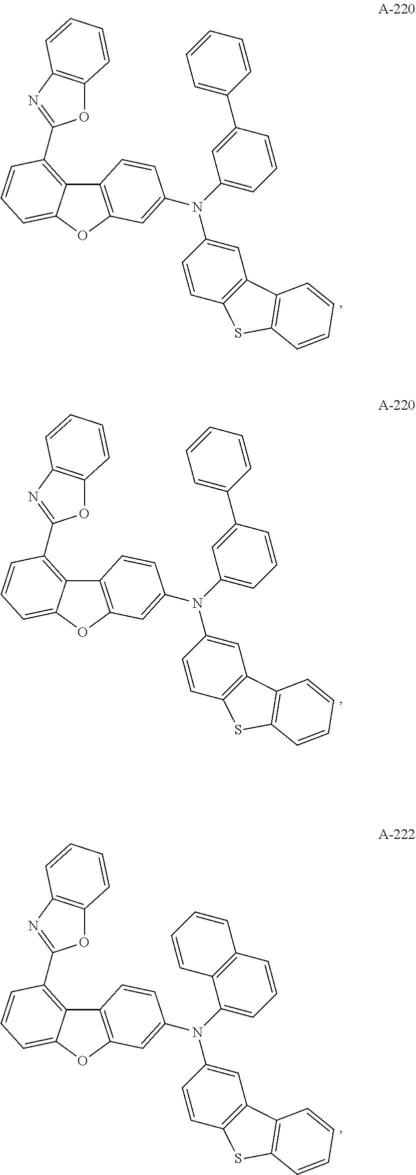 [SMILES: c1ccc(-c2cccc(N(c3ccc4c(c3)oc3cccc(-c5nc6ccccc6o5)c34)c3ccc4sc5ccccc5c4c3)c2)cc1 ; c1ccc(-c2cccc(N(c3ccc4c(c3)oc3cccc(-c5nc6ccccc6o5)c34)c3ccc4sc5ccccc5c4c3)c2)cc1 ; c1ccc2c(N(c3ccc4c(c3)oc3cccc(-c5nc6ccccc6o5)c34)c3ccc4sc5ccccc5c4c3)cccc2c1] 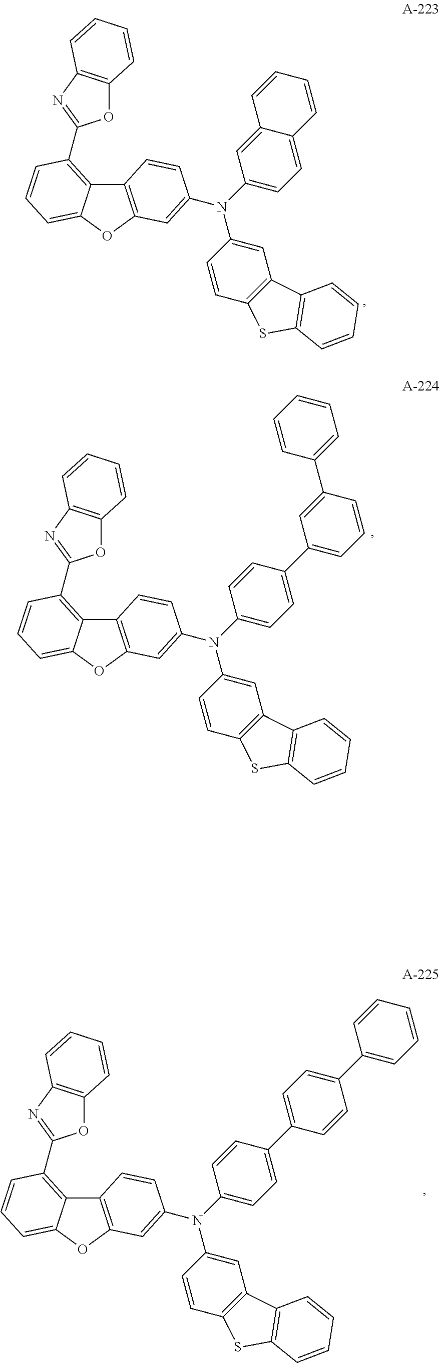 [SMILES: c1ccc2cc(N(c3ccc4c(c3)oc3cccc(-c5nc6ccccc6o5)c34)c3ccc4sc5ccccc5c4c3)ccc2c1 ; c1ccc(-c2cccc(-c3ccc(N(c4ccc5c(c4)oc4cccc(-c6nc7ccccc7o6)c45)c4ccc5sc6ccccc6c5c4)cc3)c2)cc1 ; c1ccc(-c2ccc(-c3ccc(N(c4ccc5c(c4)oc4cccc(-c6nc7ccccc7o6)c45)c4ccc5sc6ccccc6c5c4)cc3)cc2)cc1] 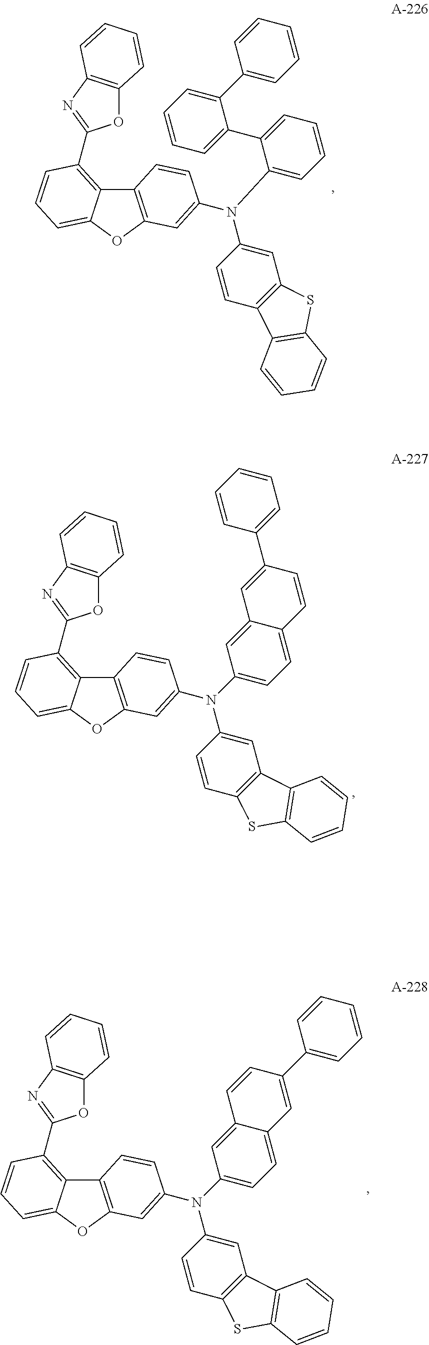 [SMILES: c1ccc(-c2ccccc2-c2ccccc2N(c2ccc3c(c2)oc2cccc(-c4nc5ccccc5o4)c23)c2ccc3c(c2)sc2ccccc23)cc1 ; c1ccc(-c2ccc3ccc(N(c4ccc5c(c4)oc4cccc(-c6nc7ccccc7o6)c45)c4ccc5sc6ccccc6c5c4)cc3c2)cc1 ; c1ccc(-c2ccc3cc(N(c4ccc5c(c4)oc4cccc(-c6nc7ccccc7o6)c45)c4ccc5sc6ccccc6c5c4)ccc3c2)cc1] 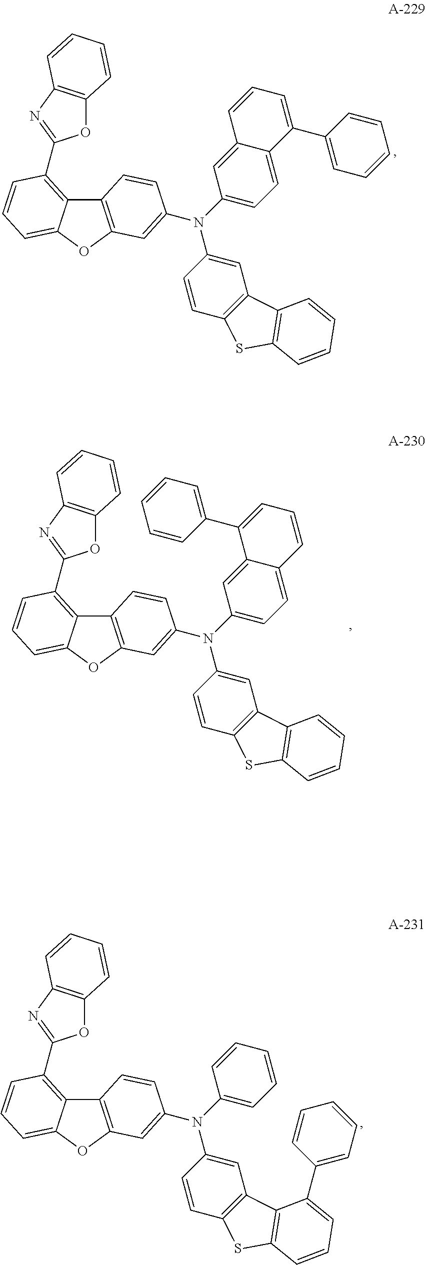 [SMILES: c1ccc(-c2cccc3cc(N(c4ccc5c(c4)oc4cccc(-c6nc7ccccc7o6)c45)c4ccc5sc6ccccc6c5c4)ccc23)cc1 ; c1ccc(-c2cccc3ccc(N(c4ccc5c(c4)oc4cccc(-c6nc7ccccc7o6)c45)c4ccc5sc6ccccc6c5c4)cc23)cc1 ; c1ccc(-c2cccc3sc4ccc(N(c5ccccc5)c5ccc6c(c5)oc5cccc(-c7nc8ccccc8o7)c56)cc4c23)cc1] 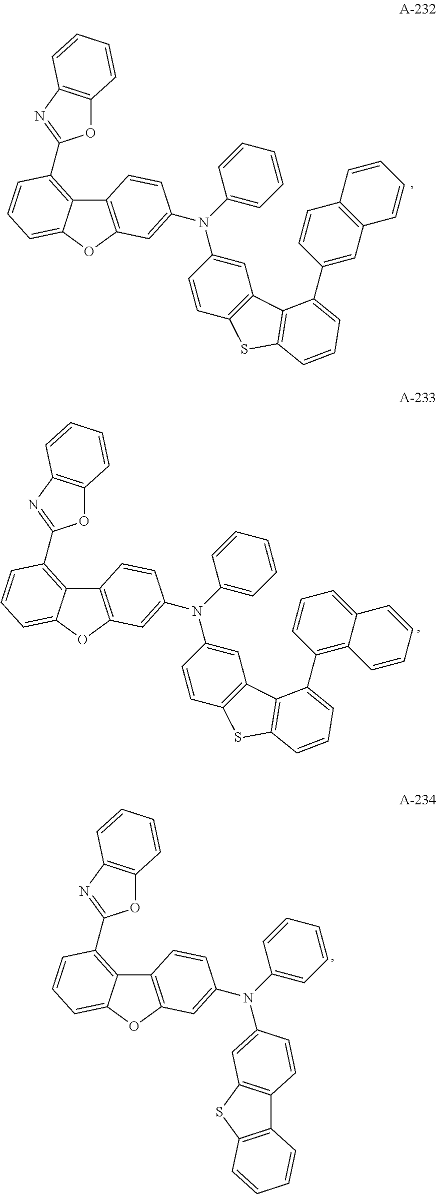 [SMILES: c1ccc(N(c2ccc3c(c2)oc2cccc(-c4nc5ccccc5o4)c23)c2ccc3sc4cccc(-c5ccc6ccccc6c5)c4c3c2)cc1 ; c1ccc(N(c2ccc3c(c2)oc2cccc(-c4nc5ccccc5o4)c23)c2ccc3sc4cccc(-c5cccc6ccccc56)c4c3c2)cc1 ; c1ccc(N(c2ccc3c(c2)oc2cccc(-c4nc5ccccc5o4)c23)c2ccc3c(c2)sc2ccccc23)cc1] 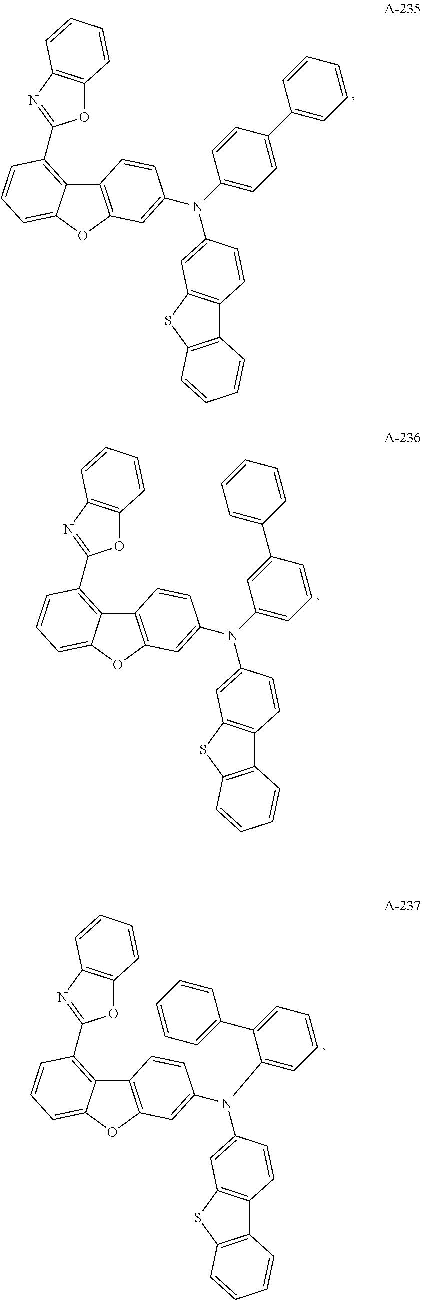 [SMILES: c1ccc(-c2ccc(N(c3ccc4c(c3)oc3cccc(-c5nc6ccccc6o5)c34)c3ccc4c(c3)sc3ccccc34)cc2)cc1 ; c1ccc(-c2cccc(N(c3ccc4c(c3)oc3cccc(-c5nc6ccccc6o5)c34)c3ccc4c(c3)sc3ccccc34)c2)cc1 ; c1ccc(-c2ccccc2N(c2ccc3c(c2)oc2cccc(-c4nc5ccccc5o4)c23)c2ccc3c(c2)sc2ccccc23)cc1] 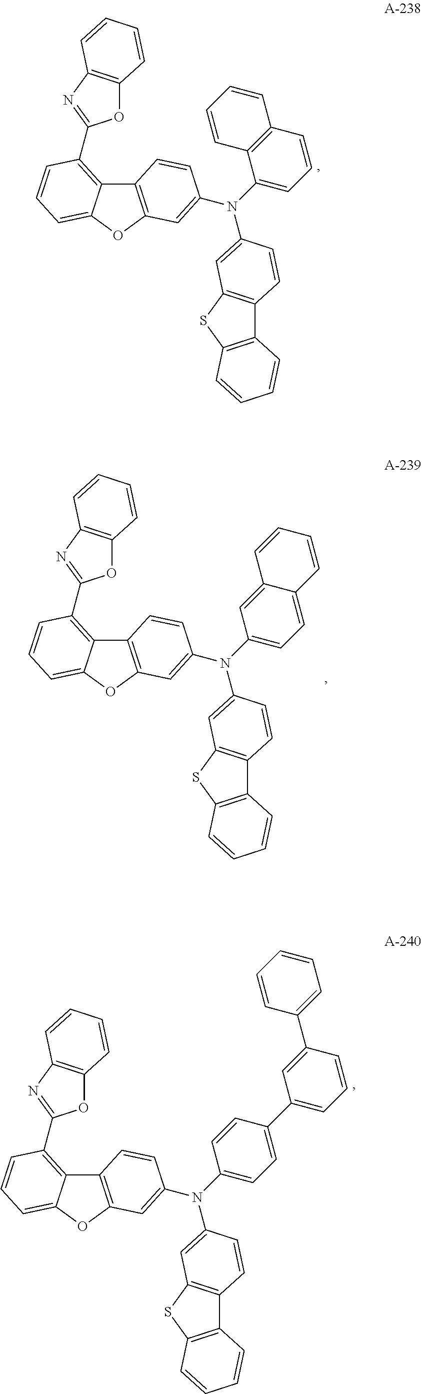 [SMILES: c1ccc2c(N(c3ccc4c(c3)oc3cccc(-c5nc6ccccc6o5)c34)c3ccc4c(c3)sc3ccccc34)cccc2c1 ; c1ccc2cc(N(c3ccc4c(c3)oc3cccc(-c5nc6ccccc6o5)c34)c3ccc4c(c3)sc3ccccc34)ccc2c1 ; c1ccc(-c2cccc(-c3ccc(N(c4ccc5c(c4)oc4cccc(-c6nc7ccccc7o6)c45)c4ccc5c(c4)sc4ccccc45)cc3)c2)cc1] 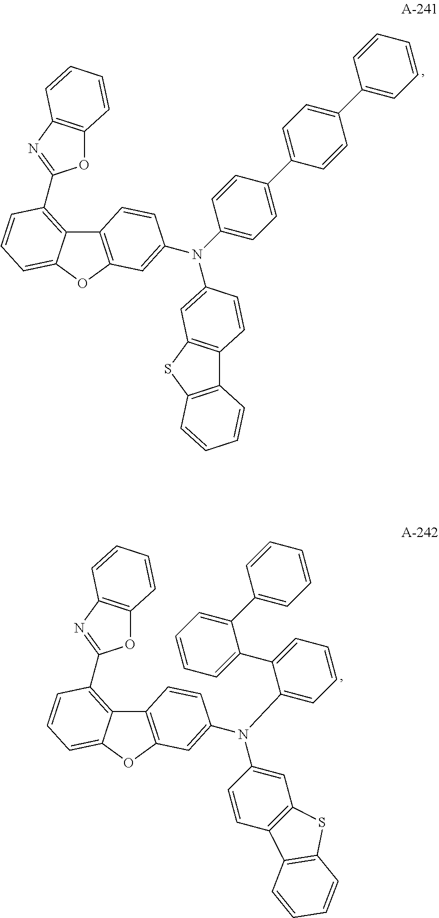 [SMILES: c1ccc(-c2ccc(-c3ccc(N(c4ccc5c(c4)oc4cccc(-c6nc7ccccc7o6)c45)c4ccc5c(c4)sc4ccccc45)cc3)cc2)cc1 ; c1ccc(-c2ccccc2-c2ccccc2N(c2ccc3c(c2)oc2cccc(-c4nc5ccccc5o4)c23)c2ccc3c(c2)sc2ccccc23)cc1] 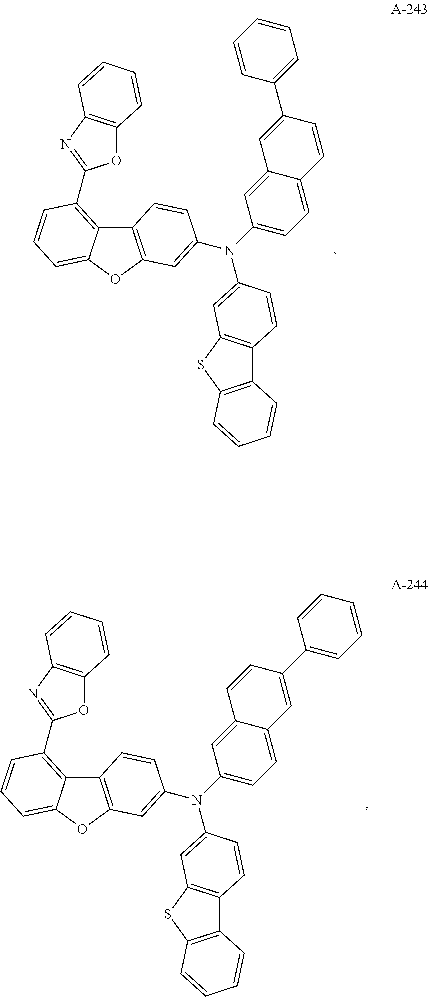 [SMILES: c1ccc(-c2ccc3ccc(N(c4ccc5c(c4)oc4cccc(-c6nc7ccccc7o6)c45)c4ccc5c(c4)sc4ccccc45)cc3c2)cc1 ; c1ccc(-c2ccc3cc(N(c4ccc5c(c4)oc4cccc(-c6nc7ccccc7o6)c45)c4ccc5c(c4)sc4ccccc45)ccc3c2)cc1] [chemical structure] [chemical structure] 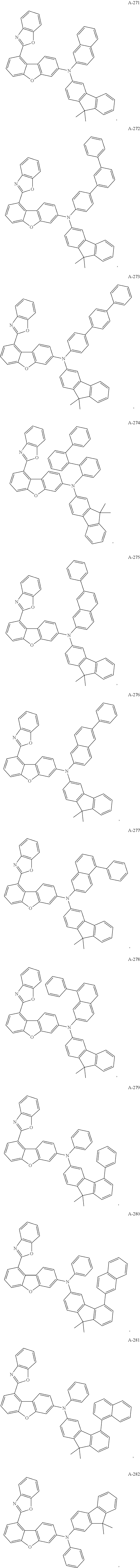 [chemical structure] 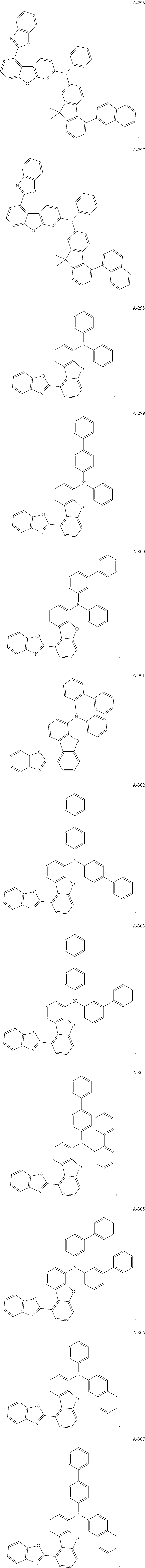 [chemical structure] 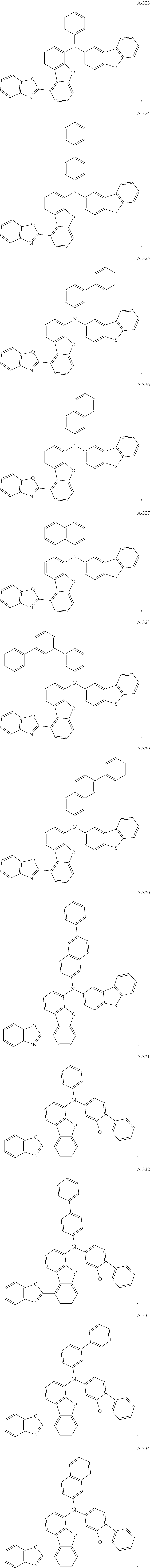 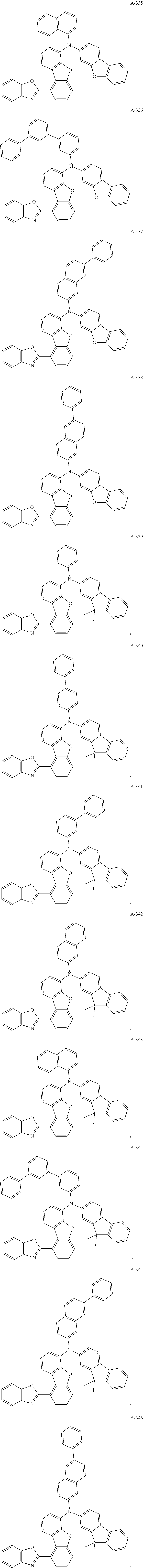 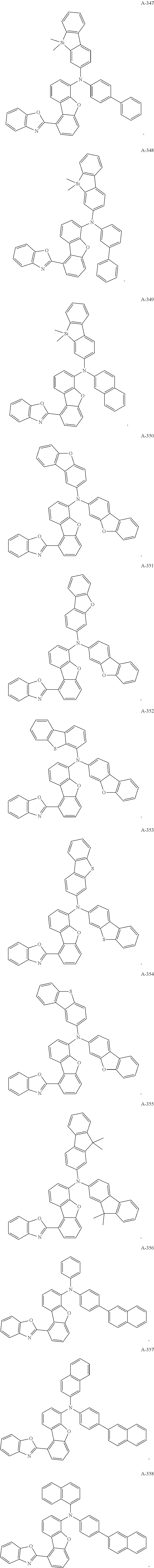 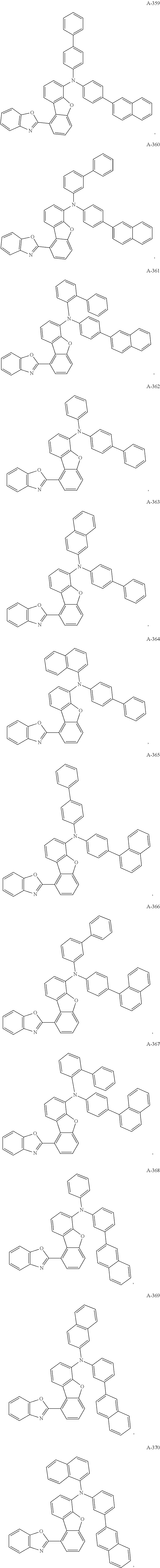 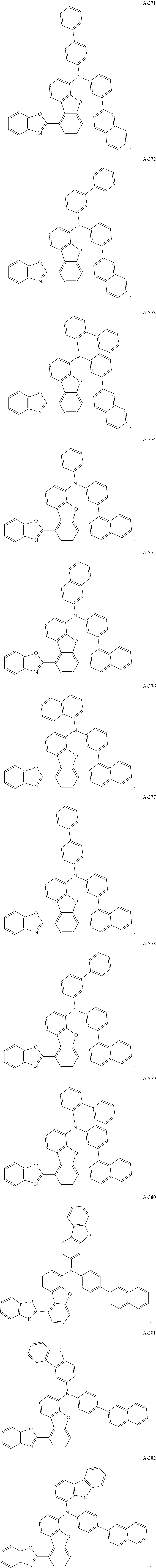 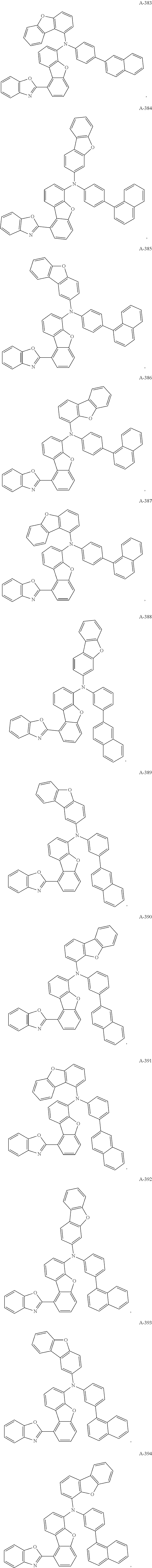 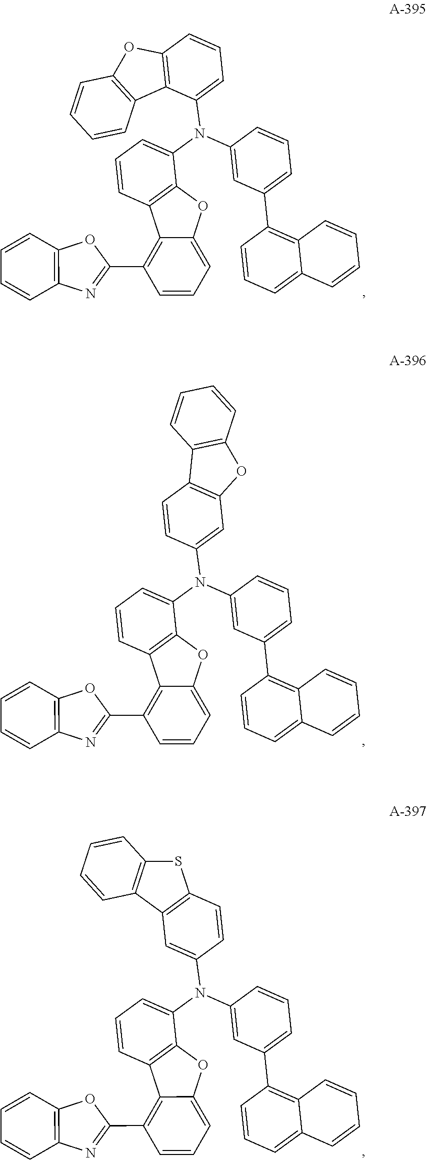 [SMILES: c1cc(-c2cccc3ccccc23)cc(N(c2cccc3c2oc2cccc(-c4nc5ccccc5o4)c23)c2cccc3oc4ccccc4c23)c1 ; c1cc(-c2cccc3ccccc23)cc(N(c2ccc3c(c2)oc2ccccc23)c2cccc3c2oc2cccc(-c4nc5ccccc5o4)c23)c1 ; c1cc(-c2cccc3ccccc23)cc(N(c2ccc3sc4ccccc4c3c2)c2cccc3c2oc2cccc(-c4nc5ccccc5o4)c23)c1] 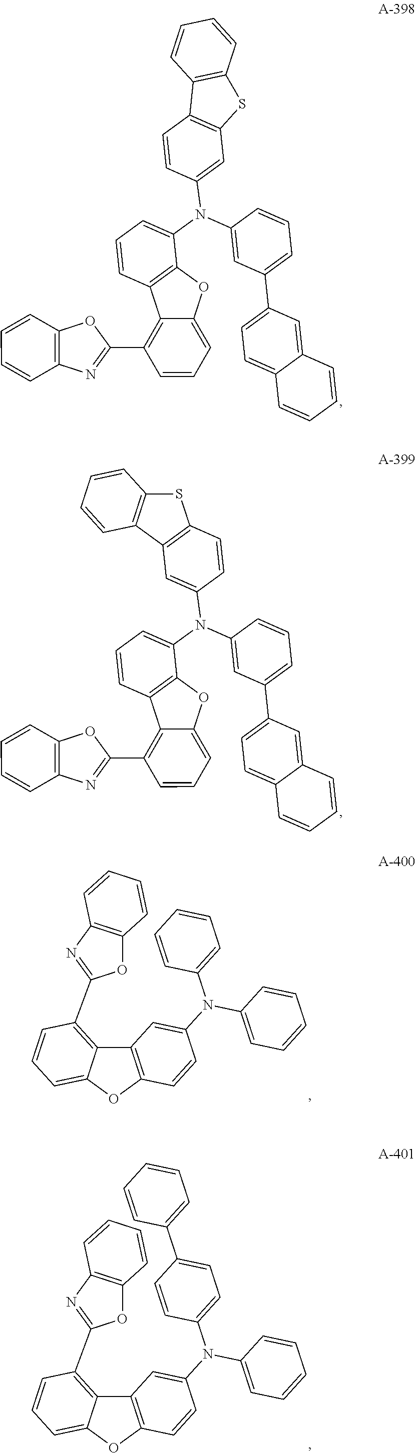 [SMILES: c1cc(-c2ccc3ccccc3c2)cc(N(c2ccc3c(c2)sc2ccccc23)c2cccc3c2oc2cccc(-c4nc5ccccc5o4)c23)c1 ; c1cc(-c2ccc3ccccc3c2)cc(N(c2ccc3sc4ccccc4c3c2)c2cccc3c2oc2cccc(-c4nc5ccccc5o4)c23)c1 ; c1ccc(N(c2ccccc2)c2ccc3oc4cccc(-c5nc6ccccc6o5)c4c3c2)cc1 ; c1ccc(-c2ccc(N(c3ccccc3)c3ccc4oc5cccc(-c6nc7ccccc7o6)c5c4c3)cc2)cc1] 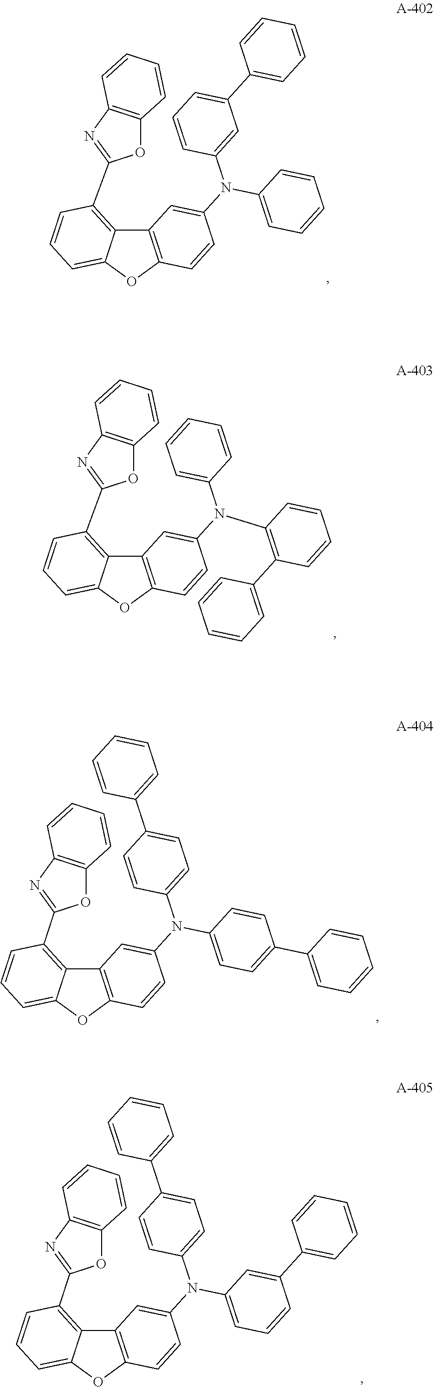 [SMILES: c1ccc(-c2cccc(N(c3ccccc3)c3ccc4oc5cccc(-c6nc7ccccc7o6)c5c4c3)c2)cc1 ; c1ccc(-c2ccccc2N(c2ccccc2)c2ccc3oc4cccc(-c5nc6ccccc6o5)c4c3c2)cc1 ; c1ccc(-c2ccc(N(c3ccc(-c4ccccc4)cc3)c3ccc4oc5cccc(-c6nc7ccccc7o6)c5c4c3)cc2)cc1 ; c1ccc(-c2ccc(N(c3cccc(-c4ccccc4)c3)c3ccc4oc5cccc(-c6nc7ccccc7o6)c5c4c3)cc2)cc1] 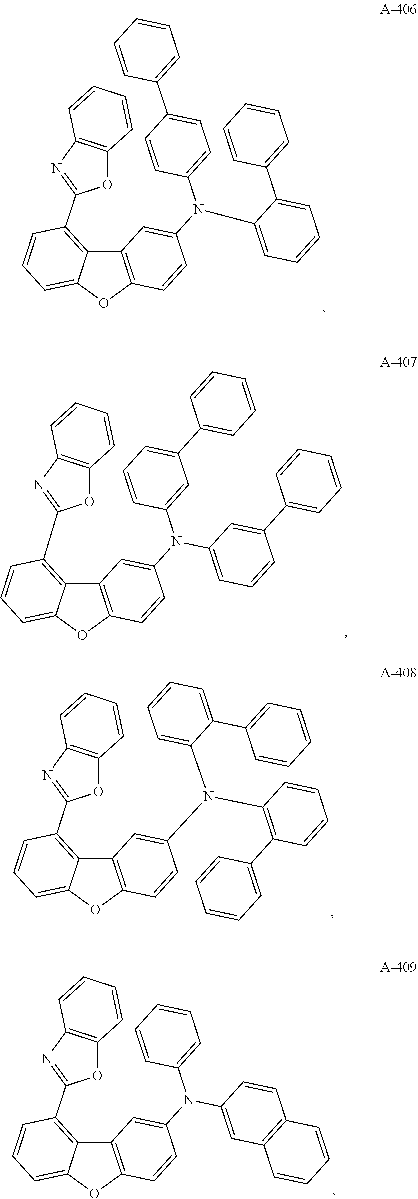 [SMILES: c1ccc(-c2ccc(N(c3ccc4oc5cccc(-c6nc7ccccc7o6)c5c4c3)c3ccccc3-c3ccccc3)cc2)cc1 ; c1ccc(-c2cccc(N(c3cccc(-c4ccccc4)c3)c3ccc4oc5cccc(-c6nc7ccccc7o6)c5c4c3)c2)cc1 ; c1ccc(-c2ccccc2N(c2ccc3oc4cccc(-c5nc6ccccc6o5)c4c3c2)c2ccccc2-c2ccccc2)cc1 ; c1ccc(N(c2ccc3ccccc3c2)c2ccc3oc4cccc(-c5nc6ccccc6o5)c4c3c2)cc1] 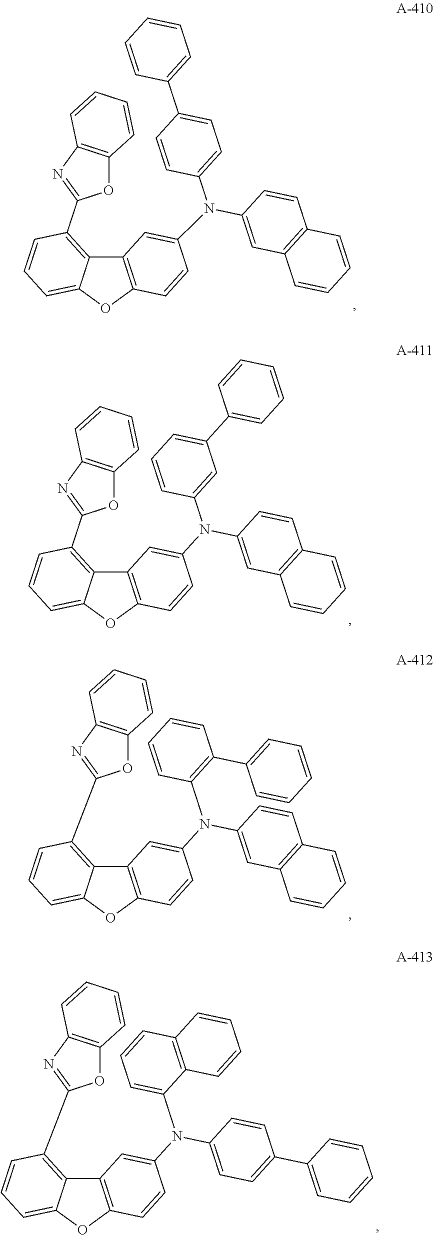 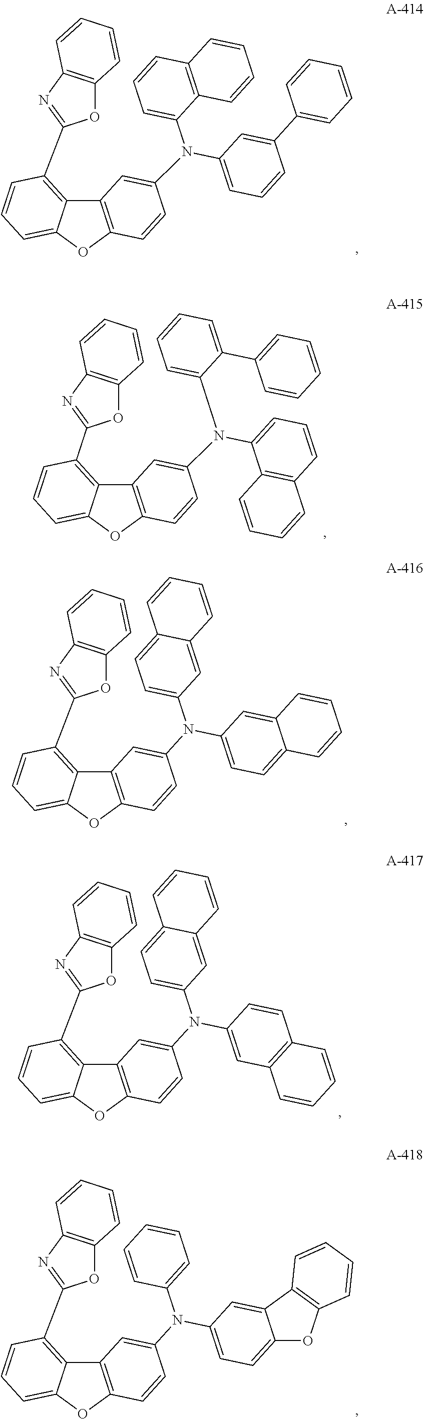 [SMILES: c1ccc(-c2cccc(N(c3ccc4oc5cccc(-c6nc7ccccc7o6)c5c4c3)c3cccc4ccccc34)c2)cc1 ; c1ccc(-c2ccccc2N(c2ccc3oc4cccc(-c5nc6ccccc6o5)c4c3c2)c2cccc3ccccc23)cc1 ; c1ccc2cc(N(c3ccc4ccccc4c3)c3ccc4oc5cccc(-c6nc7ccccc7o6)c5c4c3)ccc2c1 ; c1ccc2cc(N(c3ccc4ccccc4c3)c3ccc4oc5cccc(-c6nc7ccccc7o6)c5c4c3)ccc2c1 ; c1ccc(N(c2ccc3oc4ccccc4c3c2)c2ccc3oc4cccc(-c5nc6ccccc6o5)c4c3c2)cc1] 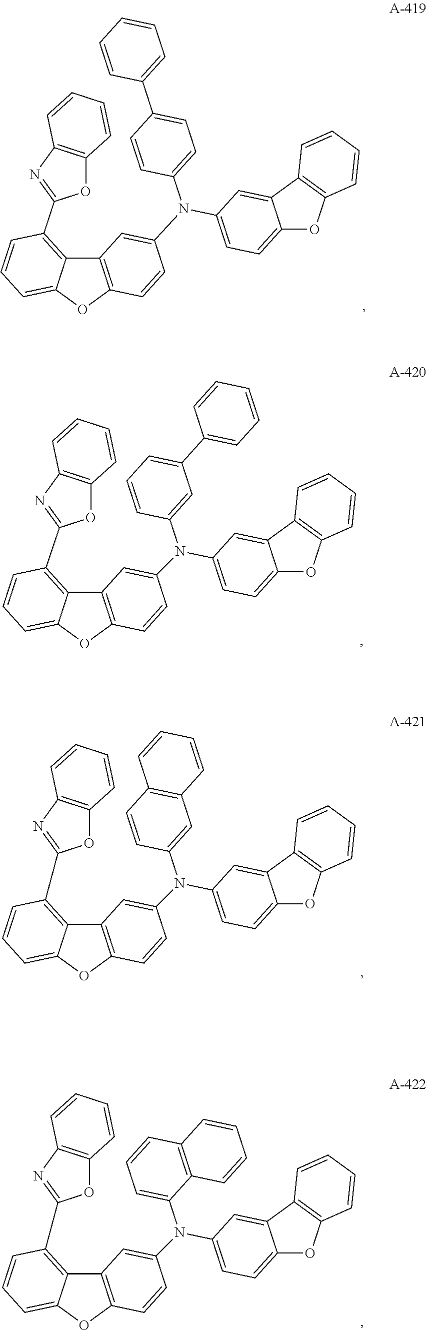 [SMILES: c1ccc(-c2ccc(N(c3ccc4oc5ccccc5c4c3)c3ccc4oc5cccc(-c6nc7ccccc7o6)c5c4c3)cc2)cc1 ; c1ccc(-c2cccc(N(c3ccc4oc5ccccc5c4c3)c3ccc4oc5cccc(-c6nc7ccccc7o6)c5c4c3)c2)cc1 ; c1ccc2cc(N(c3ccc4oc5ccccc5c4c3)c3ccc4oc5cccc(-c6nc7ccccc7o6)c5c4c3)ccc2c1 ; c1ccc2c(N(c3ccc4oc5ccccc5c4c3)c3ccc4oc5cccc(-c6nc7ccccc7o6)c5c4c3)cccc2c1] 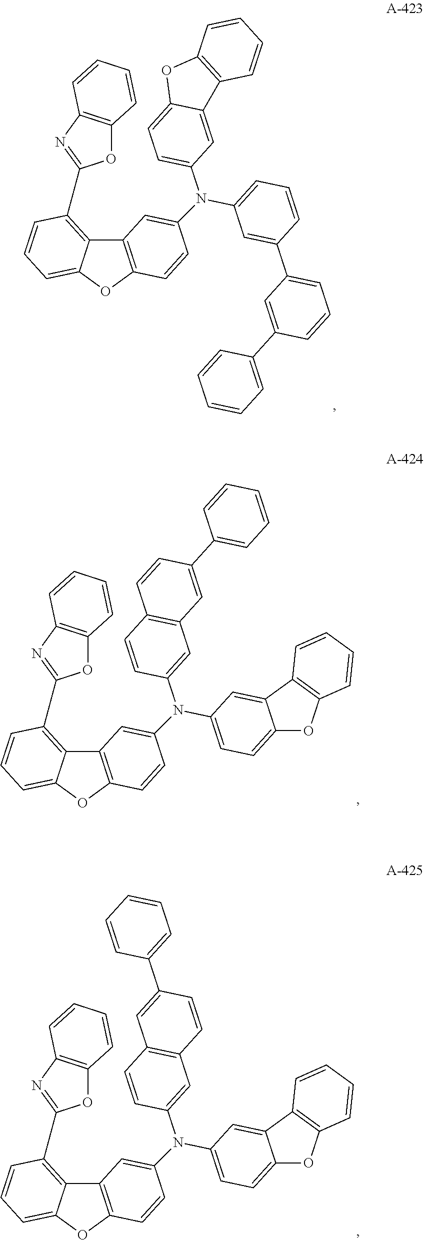 [SMILES: c1ccc(-c2cccc(-c3cccc(N(c4ccc5oc6ccccc6c5c4)c4ccc5oc6cccc(-c7nc8ccccc8o7)c6c5c4)c3)c2)cc1 ; c1ccc(-c2ccc3ccc(N(c4ccc5oc6ccccc6c5c4)c4ccc5oc6cccc(-c7nc8ccccc8o7)c6c5c4)cc3c2)cc1 ; c1ccc(-c2ccc3cc(N(c4ccc5oc6ccccc6c5c4)c4ccc5oc6cccc(-c7nc8ccccc8o7)c6c5c4)ccc3c2)cc1] 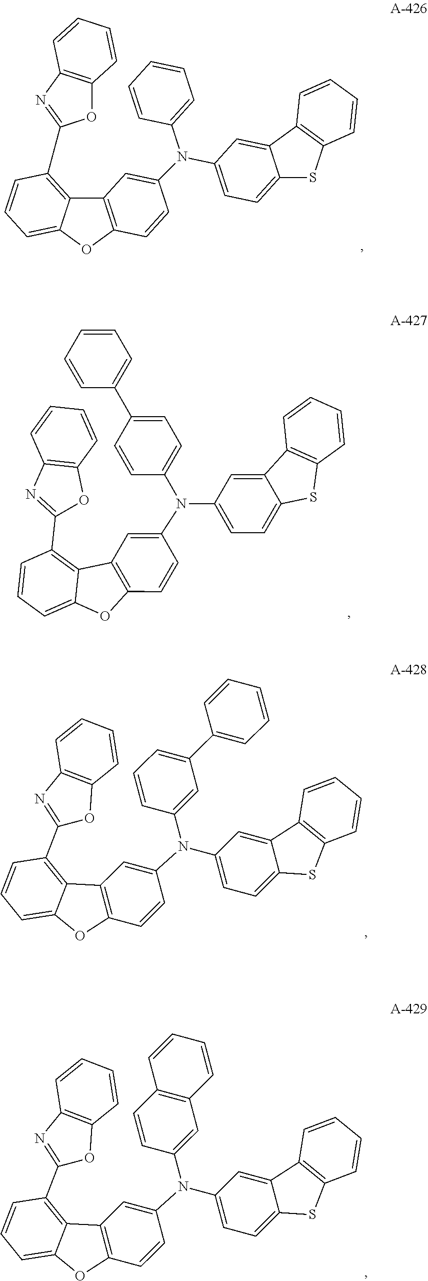 [SMILES: c1ccc(N(c2ccc3sc4ccccc4c3c2)c2ccc3oc4cccc(-c5nc6ccccc6o5)c4c3c2)cc1 ; c1ccc(-c2ccc(N(c3ccc4sc5ccccc5c4c3)c3ccc4oc5cccc(-c6nc7ccccc7o6)c5c4c3)cc2)cc1 ; c1ccc(-c2cccc(N(c3ccc4sc5ccccc5c4c3)c3ccc4oc5cccc(-c6nc7ccccc7o6)c5c4c3)c2)cc1 ; c1ccc2cc(N(c3ccc4sc5ccccc5c4c3)c3ccc4oc5cccc(-c6nc7ccccc7o6)c5c4c3)ccc2c1] 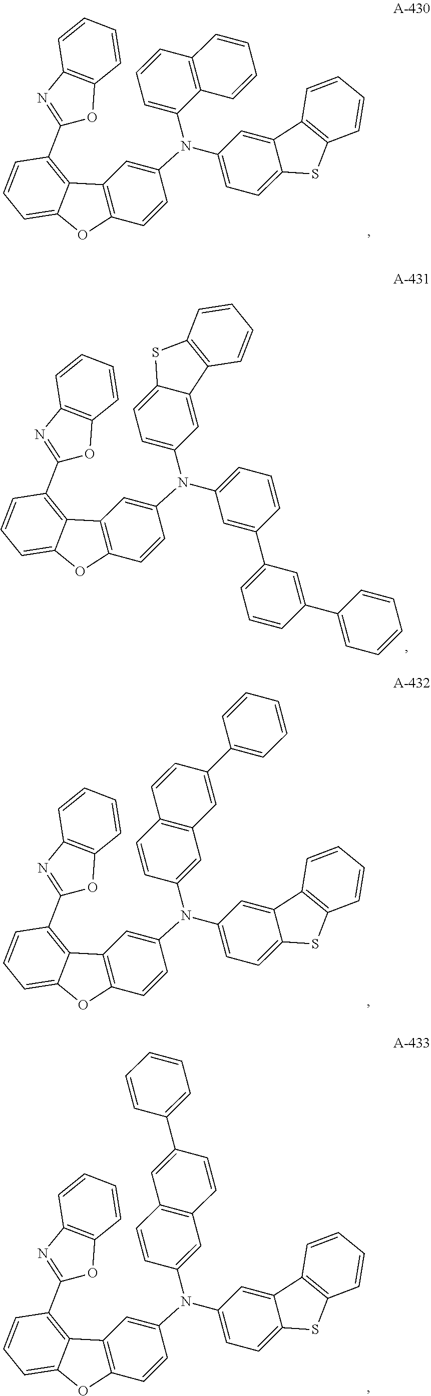 [SMILES: c1ccc2c(N(c3ccc4sc5ccccc5c4c3)c3ccc4oc5cccc(-c6nc7ccccc7o6)c5c4c3)cccc2c1 ; c1ccc(-c2cccc(-c3cccc(N(c4ccc5sc6ccccc6c5c4)c4ccc5oc6cccc(-c7nc8ccccc8o7)c6c5c4)c3)c2)cc1 ; c1ccc(-c2ccc3ccc(N(c4ccc5sc6ccccc6c5c4)c4ccc5oc6cccc(-c7nc8ccccc8o7)c6c5c4)cc3c2)cc1 ; c1ccc(-c2ccc3cc(N(c4ccc5sc6ccccc6c5c4)c4ccc5oc6cccc(-c7nc8ccccc8o7)c6c5c4)ccc3c2)cc1] 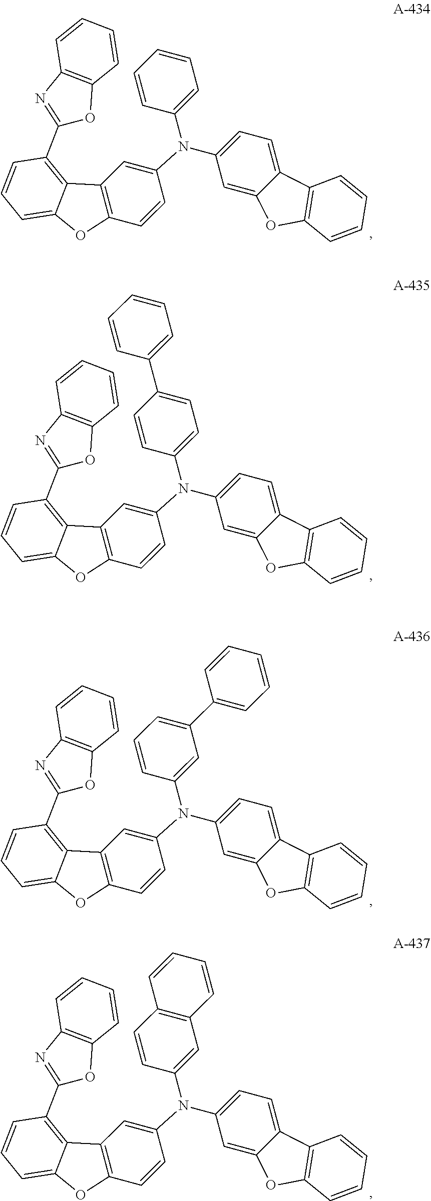 [SMILES: c1ccc(N(c2ccc3c(c2)oc2ccccc23)c2ccc3oc4cccc(-c5nc6ccccc6o5)c4c3c2)cc1 ; c1ccc(-c2ccc(N(c3ccc4c(c3)oc3ccccc34)c3ccc4oc5cccc(-c6nc7ccccc7o6)c5c4c3)cc2)cc1 ; c1ccc(-c2cccc(N(c3ccc4c(c3)oc3ccccc34)c3ccc4oc5cccc(-c6nc7ccccc7o6)c5c4c3)c2)cc1 ; c1ccc2cc(N(c3ccc4c(c3)oc3ccccc34)c3ccc4oc5cccc(-c6nc7ccccc7o6)c5c4c3)ccc2c1] 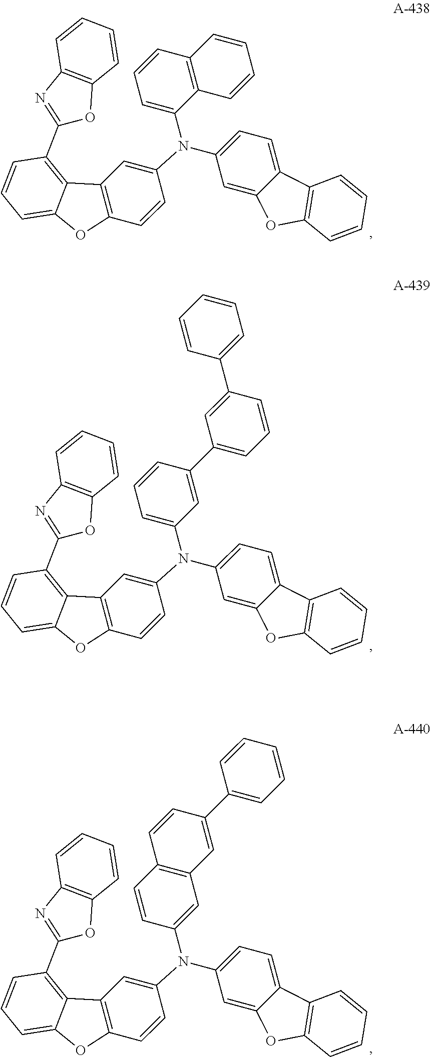 [SMILES: c1ccc2c(N(c3ccc4c(c3)oc3ccccc34)c3ccc4oc5cccc(-c6nc7ccccc7o6)c5c4c3)cccc2c1 ; c1ccc(-c2cccc(-c3cccc(N(c4ccc5c(c4)oc4ccccc45)c4ccc5oc6cccc(-c7nc8ccccc8o7)c6c5c4)c3)c2)cc1 ; c1ccc(-c2ccc3ccc(N(c4ccc5c(c4)oc4ccccc45)c4ccc5oc6cccc(-c7nc8ccccc8o7)c6c5c4)cc3c2)cc1] 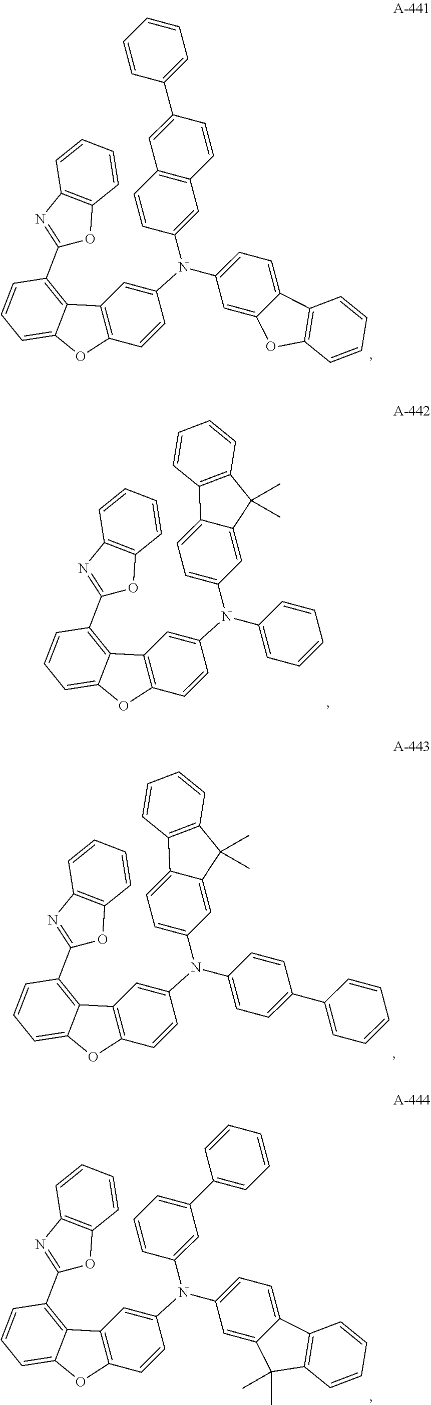 [SMILES: c1ccc(-c2ccc3cc(N(c4ccc5c(c4)oc4ccccc45)c4ccc5oc6cccc(-c7nc8ccccc8o7)c6c5c4)ccc3c2)cc1 ; CC1(C)c2ccccc2-c2ccc(N(c3ccccc3)c3ccc4oc5cccc(-c6nc7ccccc7o6)c5c4c3)cc21 ; CC1(C)c2ccccc2-c2ccc(N(c3ccc(-c4ccccc4)cc3)c3ccc4oc5cccc(-c6nc7ccccc7o6)c5c4c3)cc21 ; CC1(C)c2ccccc2-c2ccc(N(c3cccc(-c4ccccc4)c3)c3ccc4oc5cccc(-c6nc7ccccc7o6)c5c4c3)cc21] 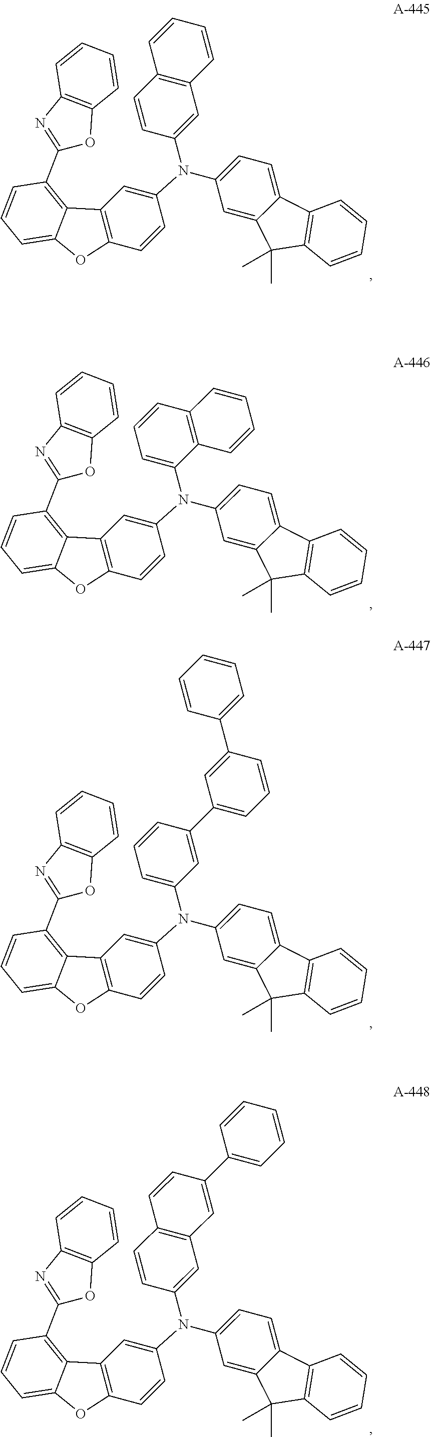 [SMILES: CC1(C)c2ccccc2-c2ccc(N(c3ccc4ccccc4c3)c3ccc4oc5cccc(-c6nc7ccccc7o6)c5c4c3)cc21 ; CC1(C)c2ccccc2-c2ccc(N(c3ccc4oc5cccc(-c6nc7ccccc7o6)c5c4c3)c3cccc4ccccc34)cc21 ; CC1(C)c2ccccc2-c2ccc(N(c3cccc(-c4cccc(-c5ccccc5)c4)c3)c3ccc4oc5cccc(-c6nc7ccccc7o6)c5c4c3)cc21 ; CC1(C)c2ccccc2-c2ccc(N(c3ccc4ccc(-c5ccccc5)cc4c3)c3ccc4oc5cccc(-c6nc7ccccc7o6)c5c4c3)cc21] 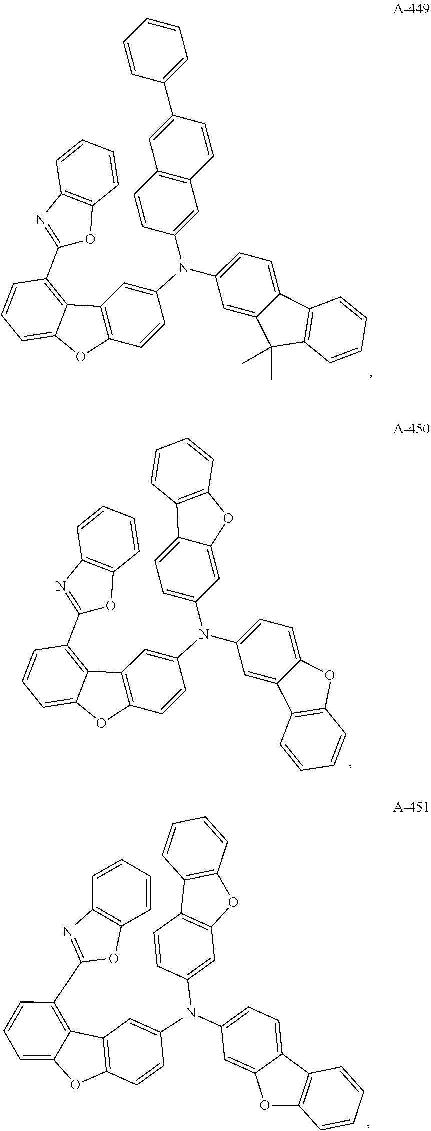 [SMILES: CC1(C)c2ccccc2-c2ccc(N(c3ccc4cc(-c5ccccc5)ccc4c3)c3ccc4oc5cccc(-c6nc7ccccc7o6)c5c4c3)cc21 ; c1ccc2oc(-c3cccc4oc5ccc(N(c6ccc7c(c6)oc6ccccc67)c6ccc7oc8ccccc8c7c6)cc5c34)nc2c1 ; c1ccc2oc(-c3cccc4oc5ccc(N(c6ccc7c(c6)oc6ccccc67)c6ccc7c(c6)oc6ccccc67)cc5c34)nc2c1] 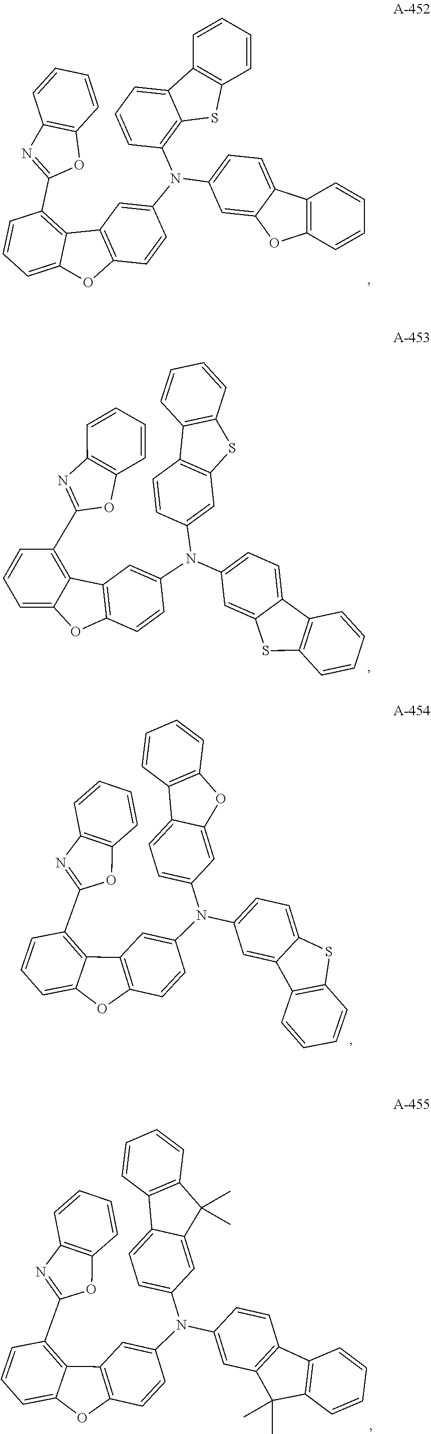 [SMILES: c1ccc2oc(-c3cccc4oc5ccc(N(c6ccc7c(c6)oc6ccccc67)c6cccc7c6sc6ccccc67)cc5c34)nc2c1 ; c1ccc2oc(-c3cccc4oc5ccc(N(c6ccc7c(c6)sc6ccccc67)c6ccc7c(c6)sc6ccccc67)cc5c34)nc2c1 ; c1ccc2oc(-c3cccc4oc5ccc(N(c6ccc7c(c6)oc6ccccc67)c6ccc7sc8ccccc8c7c6)cc5c34)nc2c1 ; CC1(C)c2ccccc2-c2ccc(N(c3ccc4c(c3)C(C)(C)c3ccccc3-4)c3ccc4oc5cccc(-c6nc7ccccc7o6)c5c4c3)cc21] 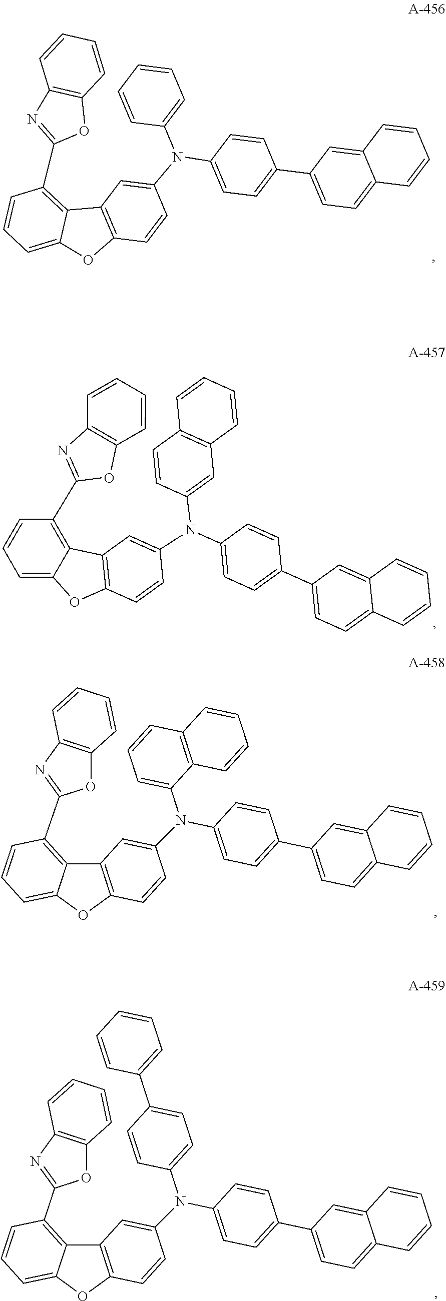 [SMILES: c1ccc(N(c2ccc(-c3ccc4ccccc4c3)cc2)c2ccc3oc4cccc(-c5nc6ccccc6o5)c4c3c2)cc1 ; c1ccc2cc(-c3ccc(N(c4ccc5ccccc5c4)c4ccc5oc6cccc(-c7nc8ccccc8o7)c6c5c4)cc3)ccc2c1 ; c1ccc2cc(-c3ccc(N(c4ccc5oc6cccc(-c7nc8ccccc8o7)c6c5c4)c4cccc5ccccc45)cc3)ccc2c1 ; c1ccc(-c2ccc(N(c3ccc(-c4ccc5ccccc5c4)cc3)c3ccc4oc5cccc(-c6nc7ccccc7o6)c5c4c3)cc2)cc1] 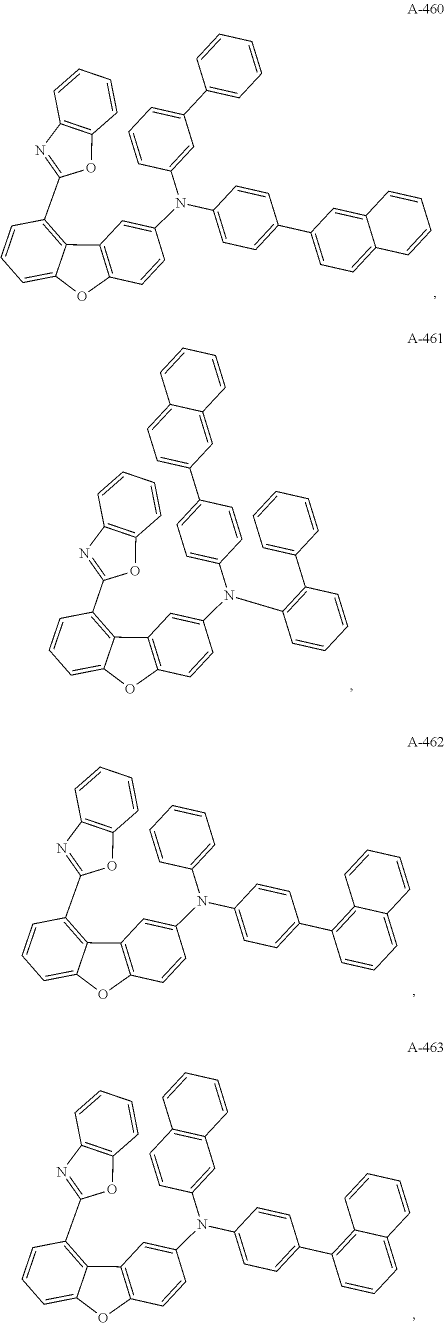 [SMILES: c1ccc(-c2cccc(N(c3ccc(-c4ccc5ccccc5c4)cc3)c3ccc4oc5cccc(-c6nc7ccccc7o6)c5c4c3)c2)cc1 ; c1ccc(-c2ccccc2N(c2ccc(-c3ccc4ccccc4c3)cc2)c2ccc3oc4cccc(-c5nc6ccccc6o5)c4c3c2)cc1 ; c1ccc(N(c2ccc(-c3cccc4ccccc34)cc2)c2ccc3oc4cccc(-c5nc6ccccc6o5)c4c3c2)cc1 ; c1ccc2cc(N(c3ccc(-c4cccc5ccccc45)cc3)c3ccc4oc5cccc(-c6nc7ccccc7o6)c5c4c3)ccc2c1] 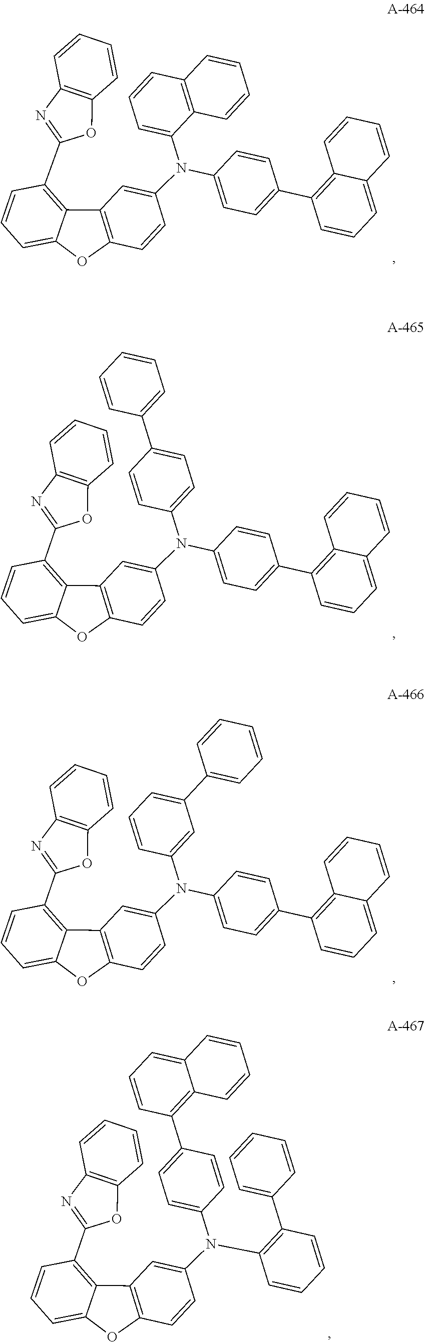 [SMILES: c1ccc2c(-c3ccc(N(c4ccc5oc6cccc(-c7nc8ccccc8o7)c6c5c4)c4cccc5ccccc45)cc3)cccc2c1 ; c1ccc(-c2ccc(N(c3ccc(-c4cccc5ccccc45)cc3)c3ccc4oc5cccc(-c6nc7ccccc7o6)c5c4c3)cc2)cc1 ; c1ccc(-c2cccc(N(c3ccc(-c4cccc5ccccc45)cc3)c3ccc4oc5cccc(-c6nc7ccccc7o6)c5c4c3)c2)cc1 ; c1ccc(-c2ccccc2N(c2ccc(-c3cccc4ccccc34)cc2)c2ccc3oc4cccc(-c5nc6ccccc6o5)c4c3c2)cc1] 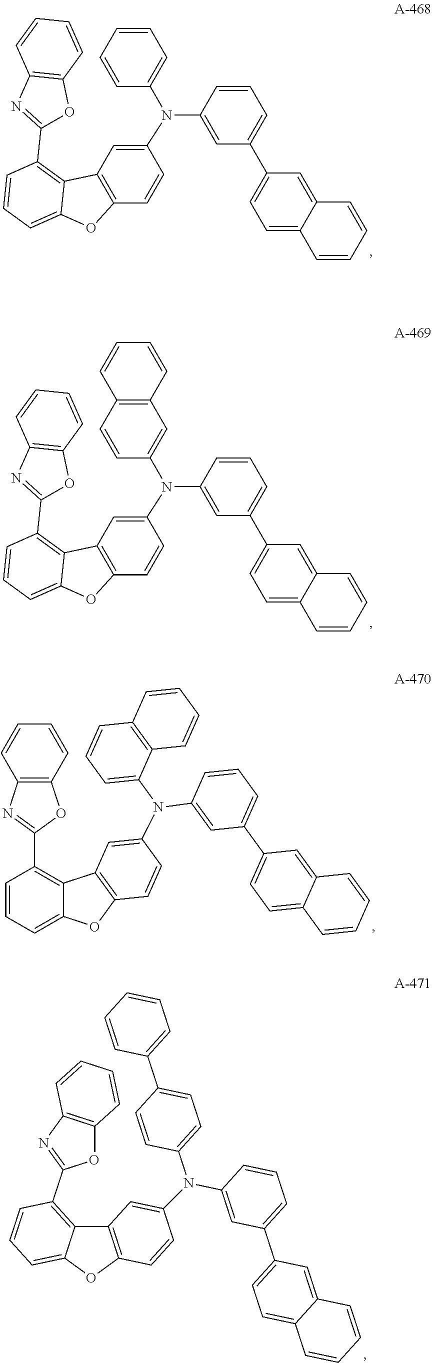 [SMILES: c1ccc(N(c2cccc(-c3ccc4ccccc4c3)c2)c2ccc3oc4cccc(-c5nc6ccccc6o5)c4c3c2)cc1 ; c1cc(-c2ccc3ccccc3c2)cc(N(c2ccc3ccccc3c2)c2ccc3oc4cccc(-c5nc6ccccc6o5)c4c3c2)c1 ; c1cc(-c2ccc3ccccc3c2)cc(N(c2ccc3oc4cccc(-c5nc6ccccc6o5)c4c3c2)c2cccc3ccccc23)c1 ; c1ccc(-c2ccc(N(c3cccc(-c4ccc5ccccc5c4)c3)c3ccc4oc5cccc(-c6nc7ccccc7o6)c5c4c3)cc2)cc1] 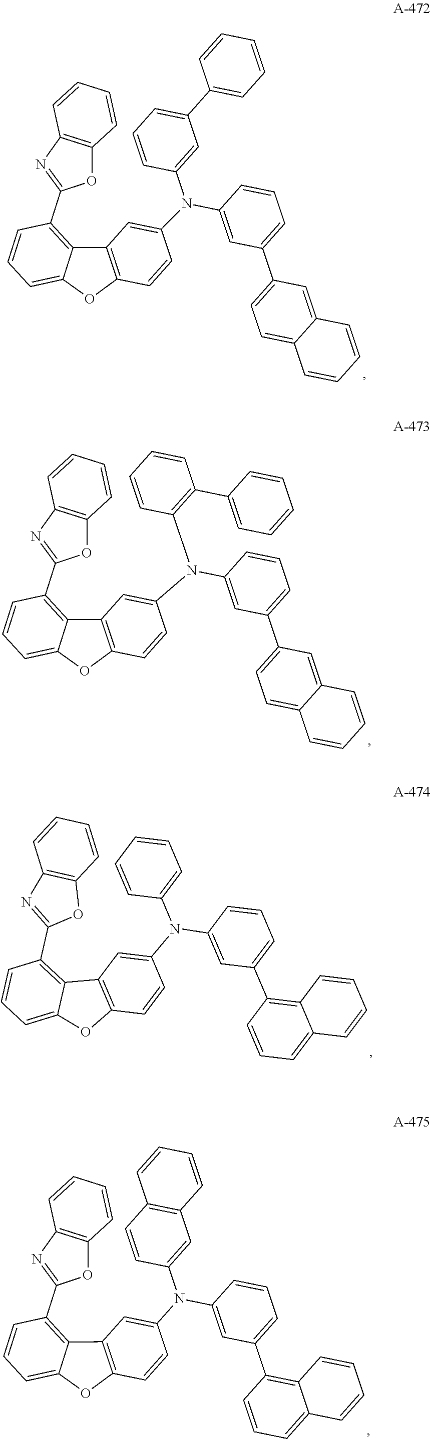 [SMILES: c1ccc(-c2cccc(N(c3cccc(-c4ccc5ccccc5c4)c3)c3ccc4oc5cccc(-c6nc7ccccc7o6)c5c4c3)c2)cc1 ; c1ccc(-c2ccccc2N(c2cccc(-c3ccc4ccccc4c3)c2)c2ccc3oc4cccc(-c5nc6ccccc6o5)c4c3c2)cc1 ; c1ccc(N(c2cccc(-c3cccc4ccccc34)c2)c2ccc3oc4cccc(-c5nc6ccccc6o5)c4c3c2)cc1 ; c1cc(-c2cccc3ccccc23)cc(N(c2ccc3ccccc3c2)c2ccc3oc4cccc(-c5nc6ccccc6o5)c4c3c2)c1] 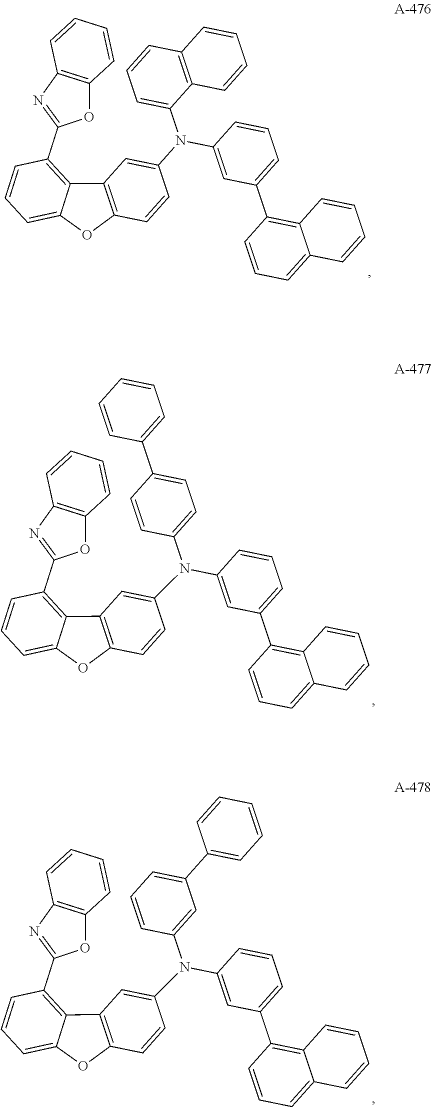 [SMILES: c1cc(-c2cccc3ccccc23)cc(N(c2ccc3oc4cccc(-c5nc6ccccc6o5)c4c3c2)c2cccc3ccccc23)c1 ; c1ccc(-c2ccc(N(c3cccc(-c4cccc5ccccc45)c3)c3ccc4oc5cccc(-c6nc7ccccc7o6)c5c4c3)cc2)cc1 ; c1ccc(-c2cccc(N(c3cccc(-c4cccc5ccccc45)c3)c3ccc4oc5cccc(-c6nc7ccccc7o6)c5c4c3)c2)cc1] 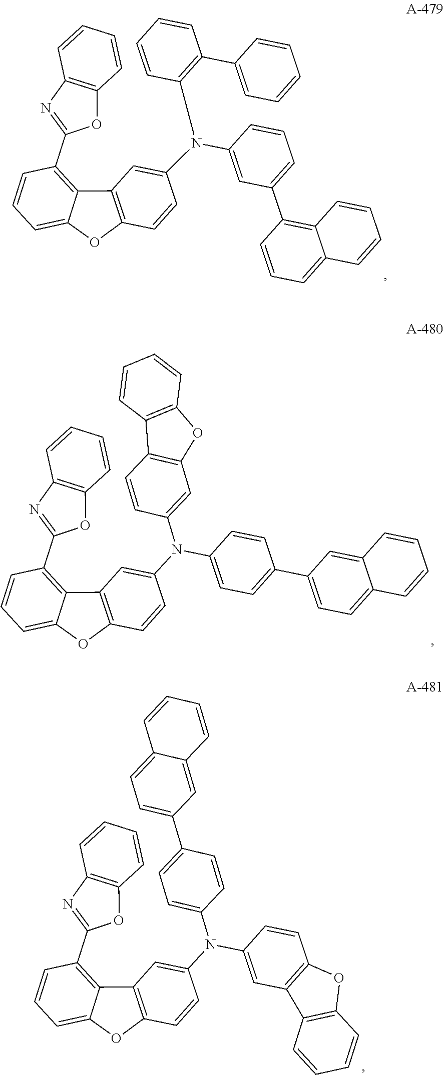 [SMILES: c1ccc(-c2ccccc2N(c2cccc(-c3cccc4ccccc34)c2)c2ccc3oc4cccc(-c5nc6ccccc6o5)c4c3c2)cc1 ; c1ccc2cc(-c3ccc(N(c4ccc5c(c4)oc4ccccc45)c4ccc5oc6cccc(-c7nc8ccccc8o7)c6c5c4)cc3)ccc2c1 ; c1ccc2cc(-c3ccc(N(c4ccc5oc6ccccc6c5c4)c4ccc5oc6cccc(-c7nc8ccccc8o7)c6c5c4)cc3)ccc2c1] 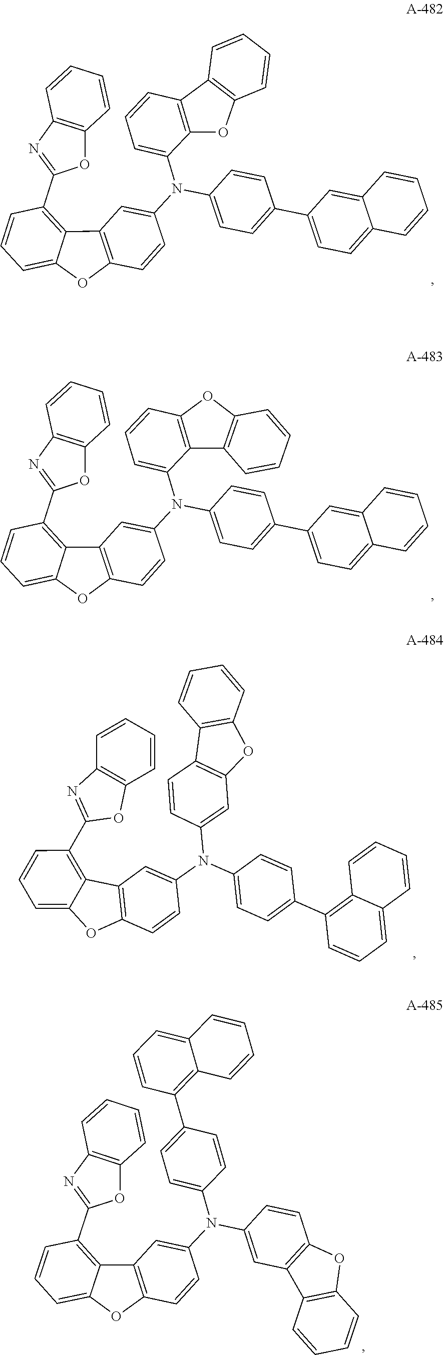 [SMILES: c1ccc2cc(-c3ccc(N(c4ccc5oc6cccc(-c7nc8ccccc8o7)c6c5c4)c4cccc5c4oc4ccccc45)cc3)ccc2c1 ; c1ccc2cc(-c3ccc(N(c4ccc5oc6cccc(-c7nc8ccccc8o7)c6c5c4)c4cccc5oc6ccccc6c45)cc3)ccc2c1 ; c1ccc2c(-c3ccc(N(c4ccc5c(c4)oc4ccccc45)c4ccc5oc6cccc(-c7nc8ccccc8o7)c6c5c4)cc3)cccc2c1 ; c1ccc2c(-c3ccc(N(c4ccc5oc6ccccc6c5c4)c4ccc5oc6cccc(-c7nc8ccccc8o7)c6c5c4)cc3)cccc2c1] 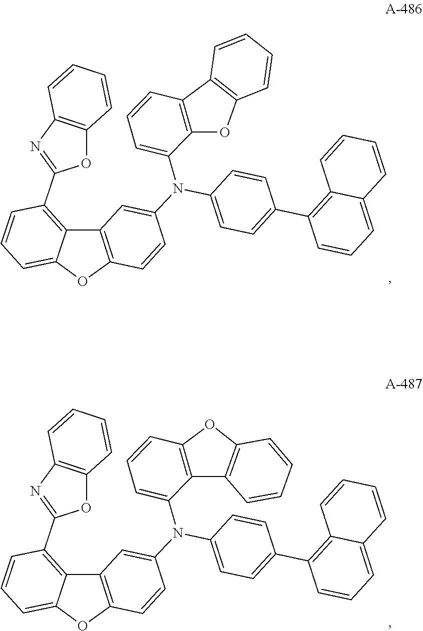 [SMILES: c1ccc2c(-c3ccc(N(c4ccc5oc6cccc(-c7nc8ccccc8o7)c6c5c4)c4cccc5c4oc4ccccc45)cc3)cccc2c1 ; c1ccc2c(-c3ccc(N(c4ccc5oc6cccc(-c7nc8ccccc8o7)c6c5c4)c4cccc5oc6ccccc6c45)cc3)cccc2c1] 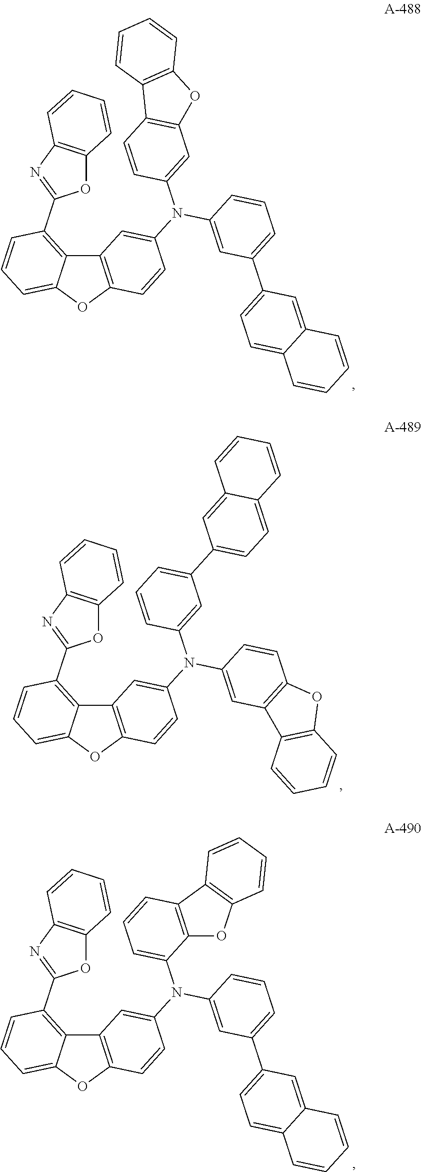 [SMILES: c1cc(-c2ccc3ccccc3c2)cc(N(c2ccc3c(c2)oc2ccccc23)c2ccc3oc4cccc(-c5nc6ccccc6o5)c4c3c2)c1 ; c1cc(-c2ccc3ccccc3c2)cc(N(c2ccc3oc4ccccc4c3c2)c2ccc3oc4cccc(-c5nc6ccccc6o5)c4c3c2)c1 ; c1cc(-c2ccc3ccccc3c2)cc(N(c2ccc3oc4cccc(-c5nc6ccccc6o5)c4c3c2)c2cccc3c2oc2ccccc23)c1] 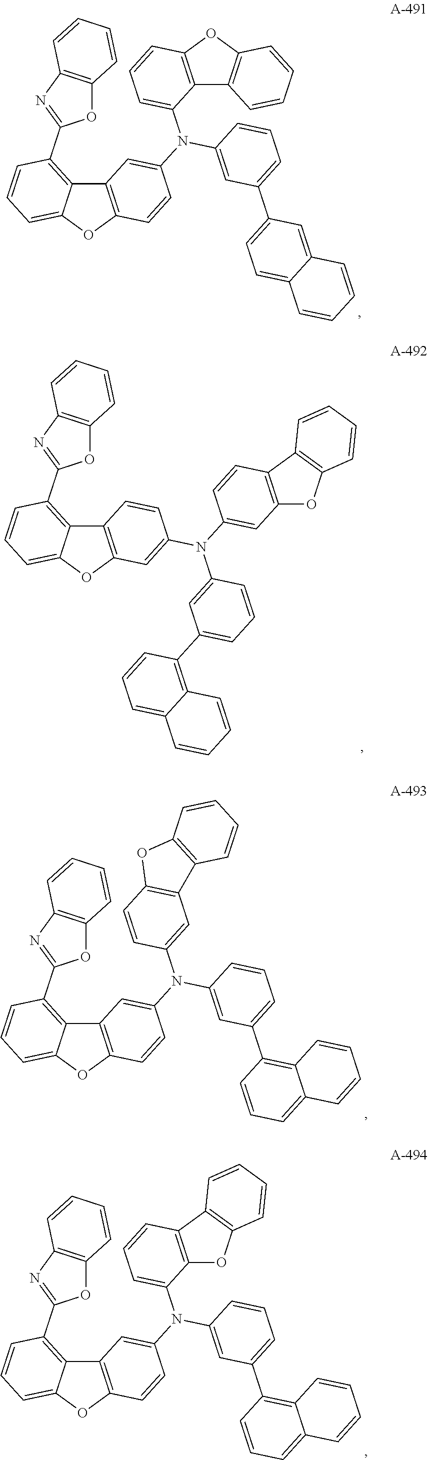 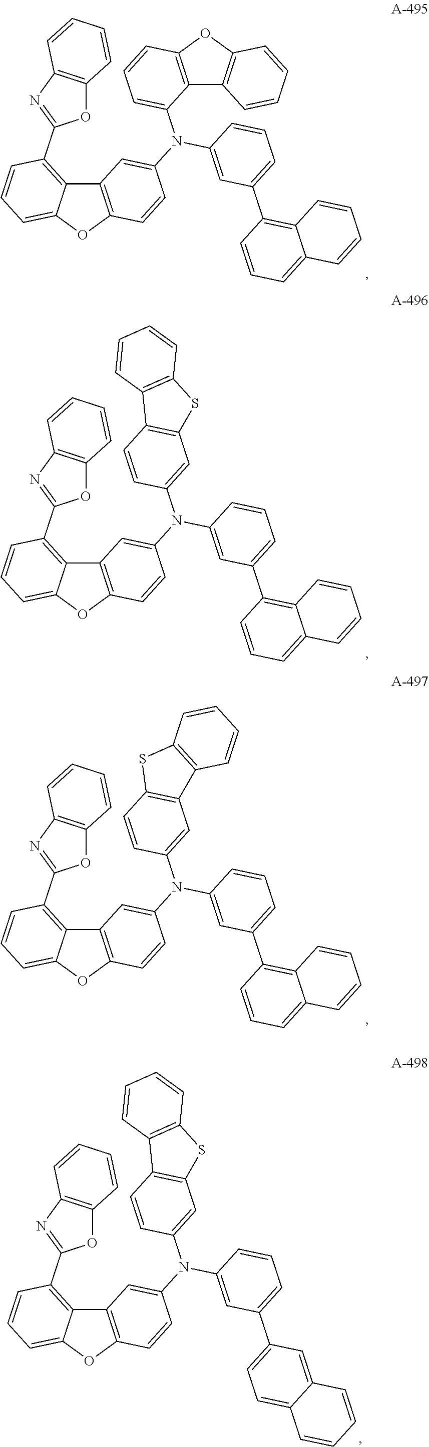 [SMILES: c1cc(-c2cccc3ccccc23)cc(N(c2ccc3oc4cccc(-c5nc6ccccc6o5)c4c3c2)c2cccc3oc4ccccc4c23)c1 ; c1cc(-c2cccc3ccccc23)cc(N(c2ccc3c(c2)sc2ccccc23)c2ccc3oc4cccc(-c5nc6ccccc6o5)c4c3c2)c1 ; c1cc(-c2cccc3ccccc23)cc(N(c2ccc3sc4ccccc4c3c2)c2ccc3oc4cccc(-c5nc6ccccc6o5)c4c3c2)c1 ; c1cc(-c2ccc3ccccc3c2)cc(N(c2ccc3c(c2)sc2ccccc23)c2ccc3oc4cccc(-c5nc6ccccc6o5)c4c3c2)c1] 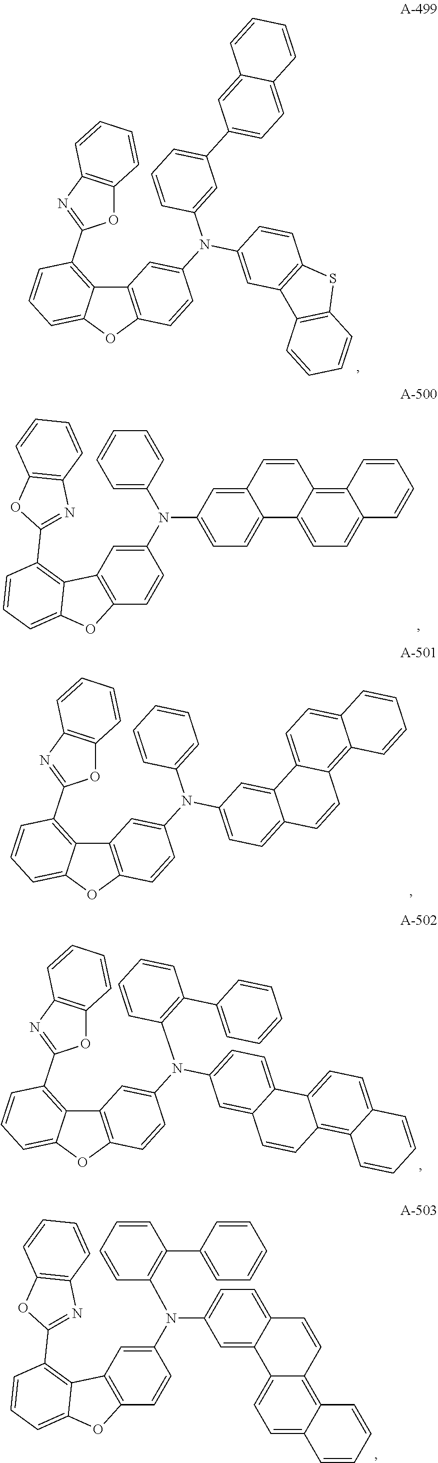 [SMILES: c1cc(-c2ccc3ccccc3c2)cc(N(c2ccc3sc4ccccc4c3c2)c2ccc3oc4cccc(-c5nc6ccccc6o5)c4c3c2)c1 ; c1ccc(N(c2ccc3c(ccc4c5ccccc5ccc34)c2)c2ccc3oc4cccc(-c5nc6ccccc6o5)c4c3c2)cc1 ; c1ccc(N(c2ccc3ccc4c5ccccc5ccc4c3c2)c2ccc3oc4cccc(-c5nc6ccccc6o5)c4c3c2)cc1 ; c1ccc(-c2ccccc2N(c2ccc3c(ccc4c5ccccc5ccc34)c2)c2ccc3oc4cccc(-c5nc6ccccc6o5)c4c3c2)cc1 ; c1ccc(-c2ccccc2N(c2ccc3ccc4c5ccccc5ccc4c3c2)c2ccc3oc4cccc(-c5nc6ccccc6o5)c4c3c2)cc1] 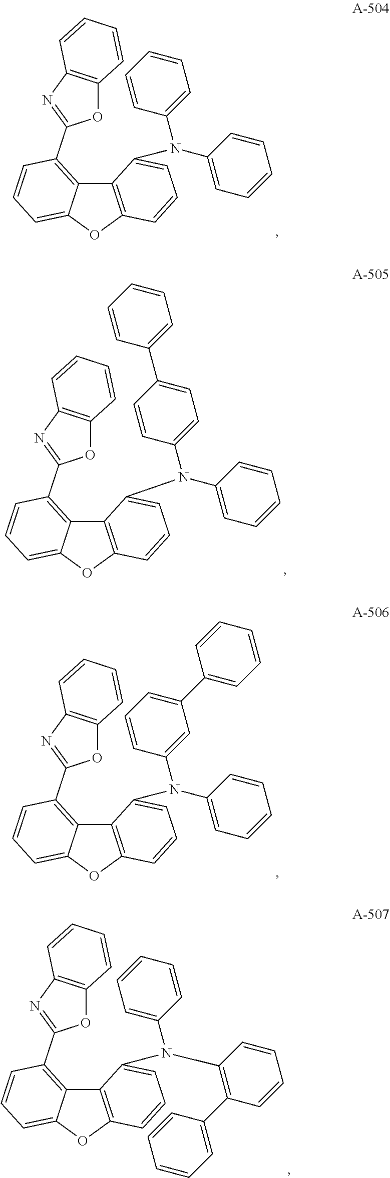 [SMILES: c1ccc(N(c2ccccc2)c2cccc3oc4cccc(-c5nc6ccccc6o5)c4c23)cc1 ; c1ccc(-c2ccc(N(c3ccccc3)c3cccc4oc5cccc(-c6nc7ccccc7o6)c5c34)cc2)cc1 ; c1ccc(-c2cccc(N(c3ccccc3)c3cccc4oc5cccc(-c6nc7ccccc7o6)c5c34)c2)cc1 ; c1ccc(-c2ccccc2N(c2ccccc2)c2cccc3oc4cccc(-c5nc6ccccc6o5)c4c23)cc1] 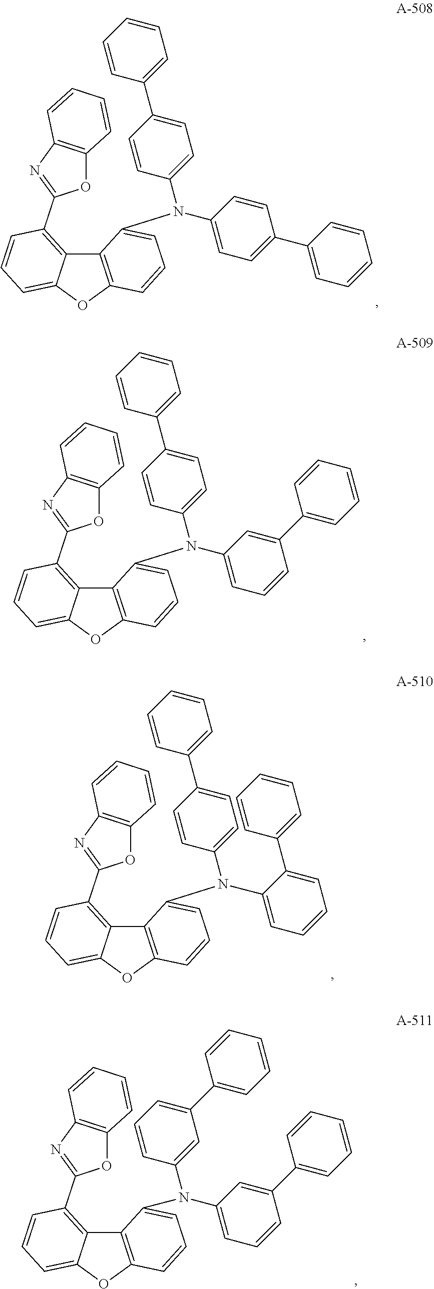 [SMILES: c1ccc(-c2ccc(N(c3ccc(-c4ccccc4)cc3)c3cccc4oc5cccc(-c6nc7ccccc7o6)c5c34)cc2)cc1 ; c1ccc(-c2ccc(N(c3cccc(-c4ccccc4)c3)c3cccc4oc5cccc(-c6nc7ccccc7o6)c5c34)cc2)cc1 ; c1ccc(-c2ccc(N(c3ccccc3-c3ccccc3)c3cccc4oc5cccc(-c6nc7ccccc7o6)c5c34)cc2)cc1 ; c1ccc(-c2cccc(N(c3cccc(-c4ccccc4)c3)c3cccc4oc5cccc(-c6nc7ccccc7o6)c5c34)c2)cc1] 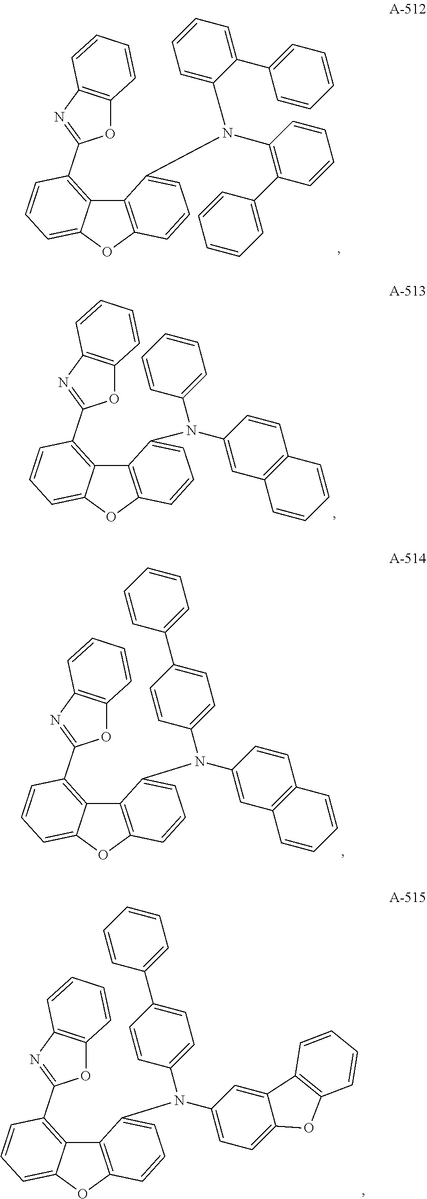 [SMILES: c1ccc(-c2ccccc2N(c2ccccc2-c2ccccc2)c2cccc3oc4cccc(-c5nc6ccccc6o5)c4c23)cc1 ; c1ccc(N(c2ccc3ccccc3c2)c2cccc3oc4cccc(-c5nc6ccccc6o5)c4c23)cc1 ; c1ccc(-c2ccc(N(c3ccc4ccccc4c3)c3cccc4oc5cccc(-c6nc7ccccc7o6)c5c34)cc2)cc1 ; c1ccc(-c2ccc(N(c3ccc4oc5ccccc5c4c3)c3cccc4oc5cccc(-c6nc7ccccc7o6)c5c34)cc2)cc1] 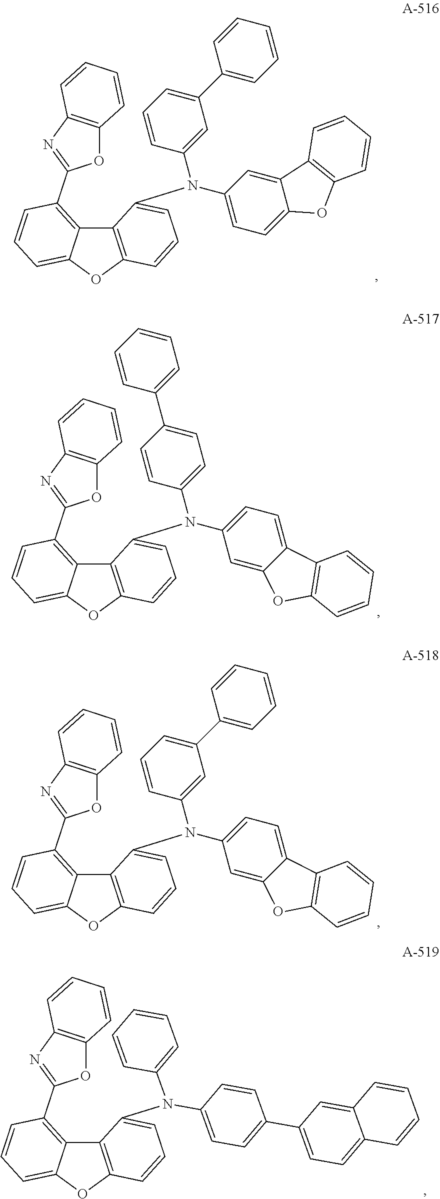 [SMILES: c1ccc(-c2cccc(N(c3ccc4oc5ccccc5c4c3)c3cccc4oc5cccc(-c6nc7ccccc7o6)c5c34)c2)cc1 ; c1ccc(-c2ccc(N(c3ccc4c(c3)oc3ccccc34)c3cccc4oc5cccc(-c6nc7ccccc7o6)c5c34)cc2)cc1 ; c1ccc(-c2cccc(N(c3ccc4c(c3)oc3ccccc34)c3cccc4oc5cccc(-c6nc7ccccc7o6)c5c34)c2)cc1 ; c1ccc(N(c2ccc(-c3ccc4ccccc4c3)cc2)c2cccc3oc4cccc(-c5nc6ccccc6o5)c4c23)cc1] 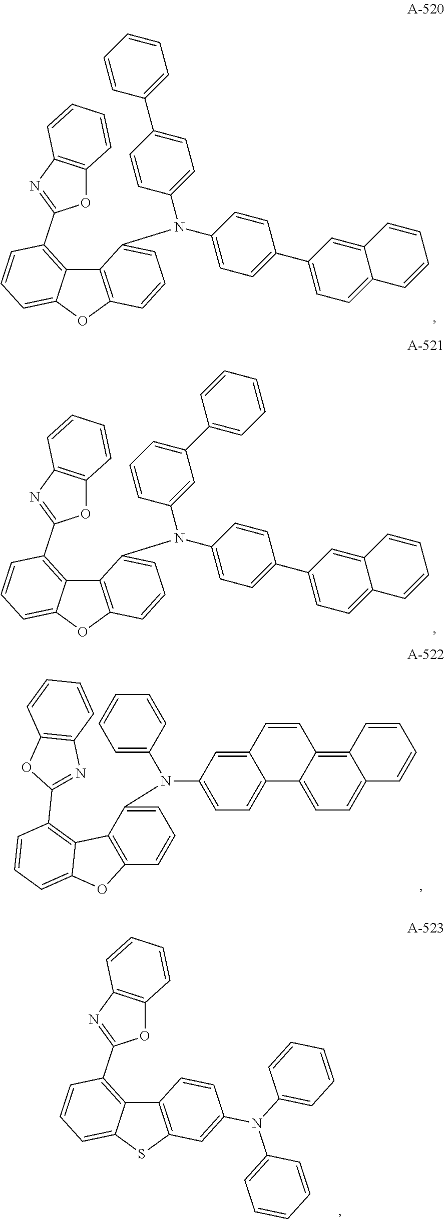 [SMILES: c1ccc(-c2ccc(N(c3ccc(-c4ccc5ccccc5c4)cc3)c3cccc4oc5cccc(-c6nc7ccccc7o6)c5c34)cc2)cc1 ; c1ccc(-c2cccc(N(c3ccc(-c4ccc5ccccc5c4)cc3)c3cccc4oc5cccc(-c6nc7ccccc7o6)c5c34)c2)cc1 ; c1ccc(N(c2ccc3c(ccc4c5ccccc5ccc34)c2)c2cccc3oc4cccc(-c5nc6ccccc6o5)c4c23)cc1 ; c1ccc(N(c2ccccc2)c2ccc3c(c2)sc2cccc(-c4nc5ccccc5o4)c23)cc1] 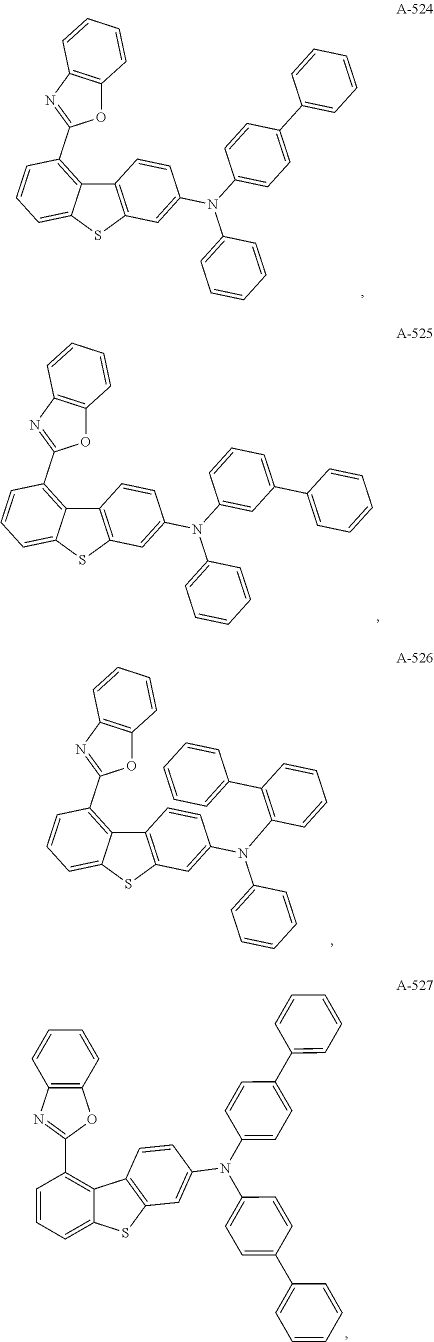 [SMILES: c1ccc(-c2ccc(N(c3ccccc3)c3ccc4c(c3)sc3cccc(-c5nc6ccccc6o5)c34)cc2)cc1 ; c1ccc(-c2cccc(N(c3ccccc3)c3ccc4c(c3)sc3cccc(-c5nc6ccccc6o5)c34)c2)cc1 ; c1ccc(-c2ccccc2N(c2ccccc2)c2ccc3c(c2)sc2cccc(-c4nc5ccccc5o4)c23)cc1 ; c1ccc(-c2ccc(N(c3ccc(-c4ccccc4)cc3)c3ccc4c(c3)sc3cccc(-c5nc6ccccc6o5)c34)cc2)cc1] 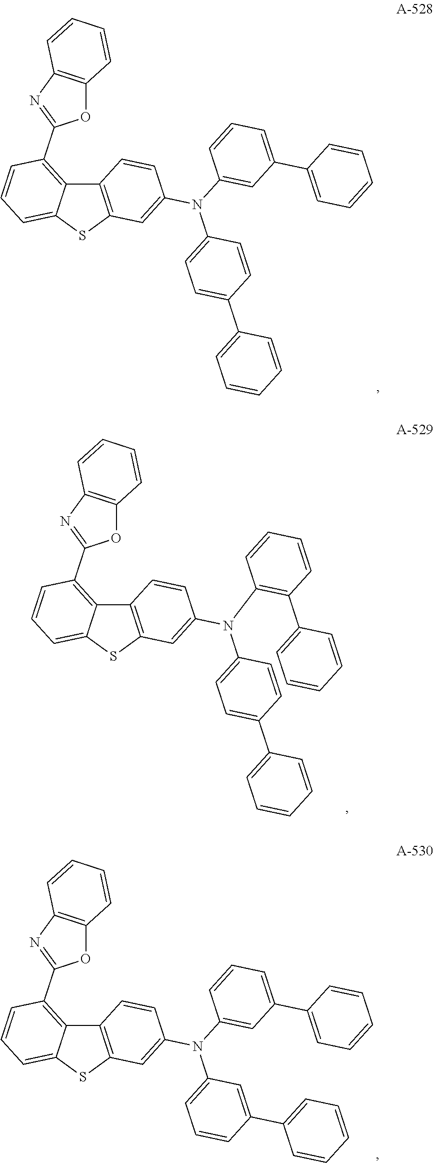 [SMILES: c1ccc(-c2ccc(N(c3cccc(-c4ccccc4)c3)c3ccc4c(c3)sc3cccc(-c5nc6ccccc6o5)c34)cc2)cc1 ; c1ccc(-c2ccc(N(c3ccc4c(c3)sc3cccc(-c5nc6ccccc6o5)c34)c3ccccc3-c3ccccc3)cc2)cc1 ; c1ccc(-c2cccc(N(c3cccc(-c4ccccc4)c3)c3ccc4c(c3)sc3cccc(-c5nc6ccccc6o5)c34)c2)cc1] 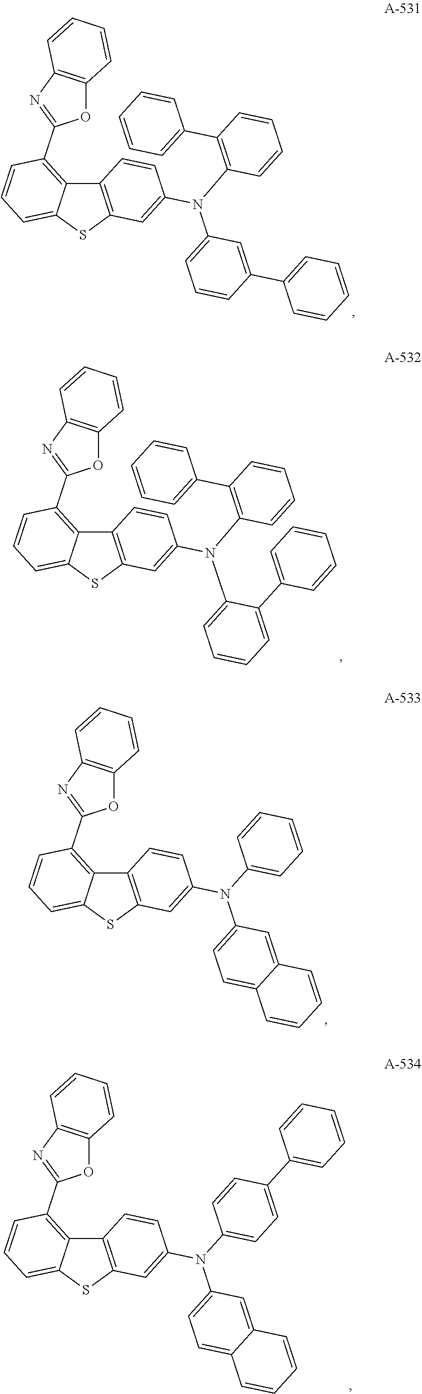 [SMILES: c1ccc(-c2cccc(N(c3ccc4c(c3)sc3cccc(-c5nc6ccccc6o5)c34)c3ccccc3-c3ccccc3)c2)cc1 ; c1ccc(-c2ccccc2N(c2ccc3c(c2)sc2cccc(-c4nc5ccccc5o4)c23)c2ccccc2-c2ccccc2)cc1 ; c1ccc(N(c2ccc3ccccc3c2)c2ccc3c(c2)sc2cccc(-c4nc5ccccc5o4)c23)cc1 ; c1ccc(-c2ccc(N(c3ccc4ccccc4c3)c3ccc4c(c3)sc3cccc(-c5nc6ccccc6o5)c34)cc2)cc1] 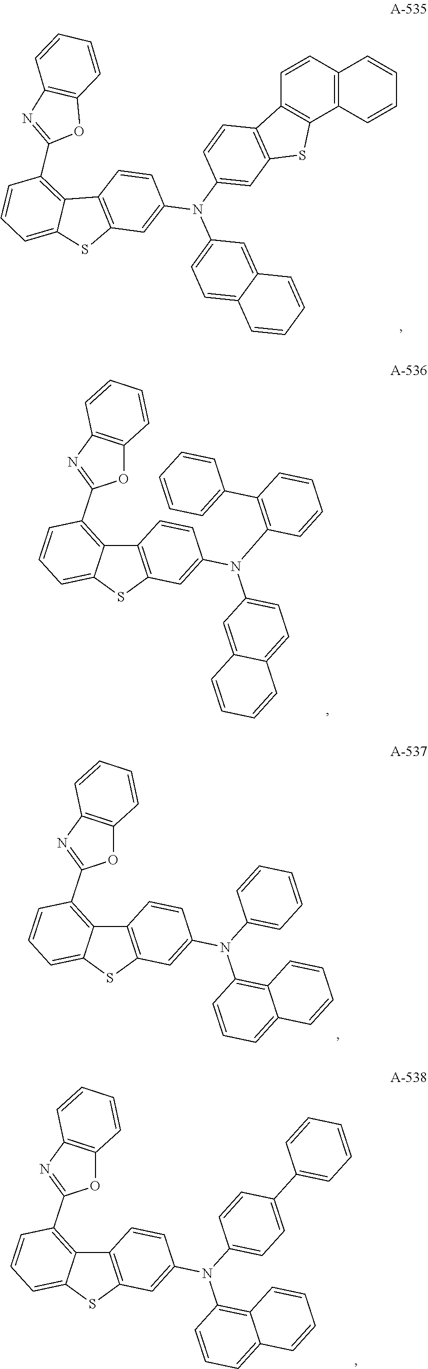 [SMILES: c1ccc2cc(N(c3ccc4c(c3)sc3c5ccccc5ccc43)c3ccc4c(c3)sc3cccc(-c5nc6ccccc6o5)c34)ccc2c1 ; c1ccc(-c2ccccc2N(c2ccc3ccccc3c2)c2ccc3c(c2)sc2cccc(-c4nc5ccccc5o4)c23)cc1 ; c1ccc(N(c2ccc3c(c2)sc2cccc(-c4nc5ccccc5o4)c23)c2cccc3ccccc23)cc1 ; c1ccc(-c2ccc(N(c3ccc4c(c3)sc3cccc(-c5nc6ccccc6o5)c34)c3cccc4ccccc34)cc2)cc1] 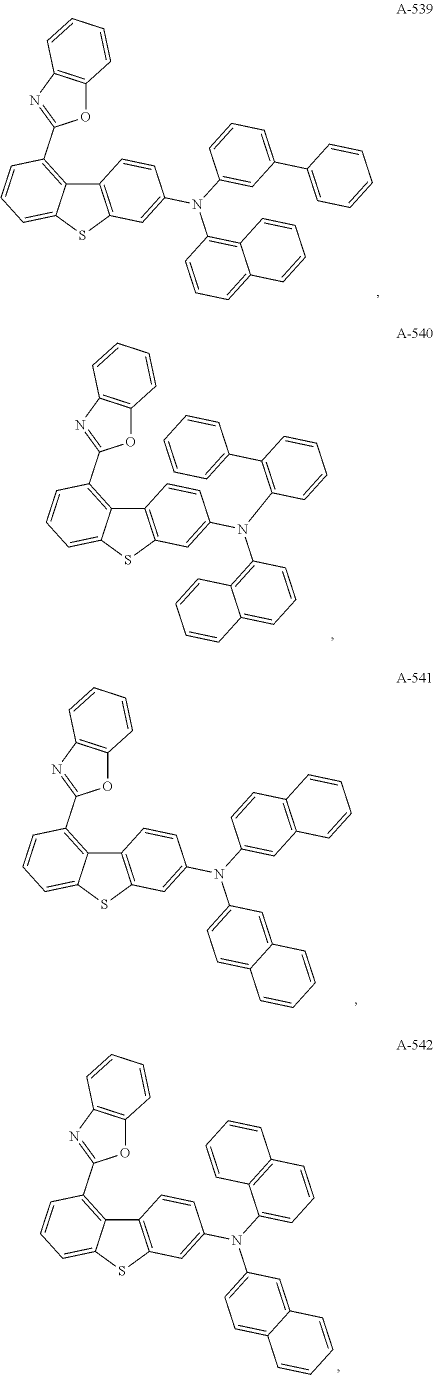 [SMILES: c1ccc(-c2cccc(N(c3ccc4c(c3)sc3cccc(-c5nc6ccccc6o5)c34)c3cccc4ccccc34)c2)cc1 ; c1ccc(-c2ccccc2N(c2ccc3c(c2)sc2cccc(-c4nc5ccccc5o4)c23)c2cccc3ccccc23)cc1 ; c1ccc2cc(N(c3ccc4ccccc4c3)c3ccc4c(c3)sc3cccc(-c5nc6ccccc6o5)c34)ccc2c1 ; c1ccc2cc(N(c3ccc4c(c3)sc3cccc(-c5nc6ccccc6o5)c34)c3cccc4ccccc34)ccc2c1] 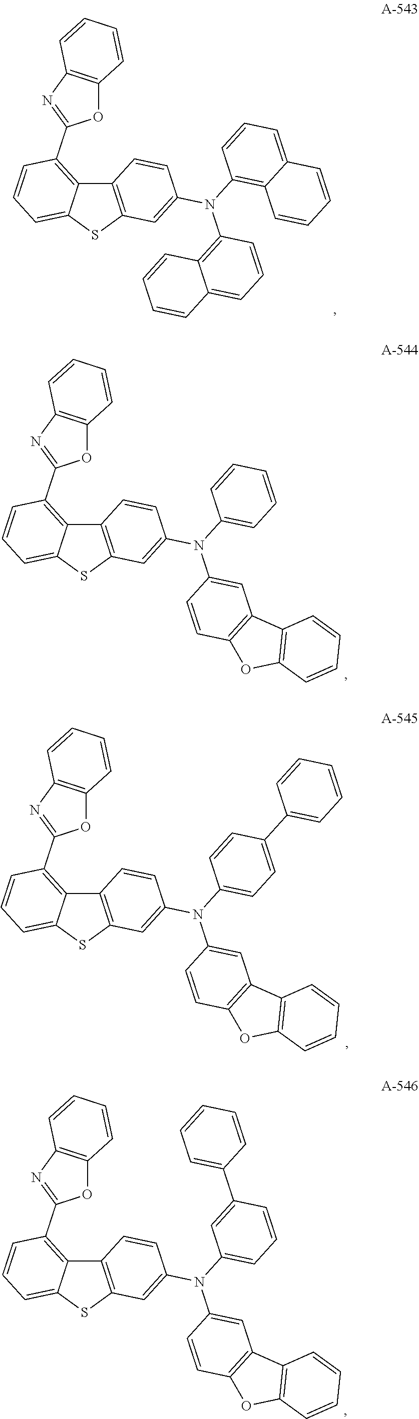 [SMILES: c1ccc2c(N(c3ccc4c(c3)sc3cccc(-c5nc6ccccc6o5)c34)c3cccc4ccccc34)cccc2c1 ; c1ccc(N(c2ccc3c(c2)sc2cccc(-c4nc5ccccc5o4)c23)c2ccc3oc4ccccc4c3c2)cc1 ; c1ccc(-c2ccc(N(c3ccc4c(c3)sc3cccc(-c5nc6ccccc6o5)c34)c3ccc4oc5ccccc5c4c3)cc2)cc1 ; c1ccc(-c2cccc(N(c3ccc4c(c3)sc3cccc(-c5nc6ccccc6o5)c34)c3ccc4oc5ccccc5c4c3)c2)cc1] 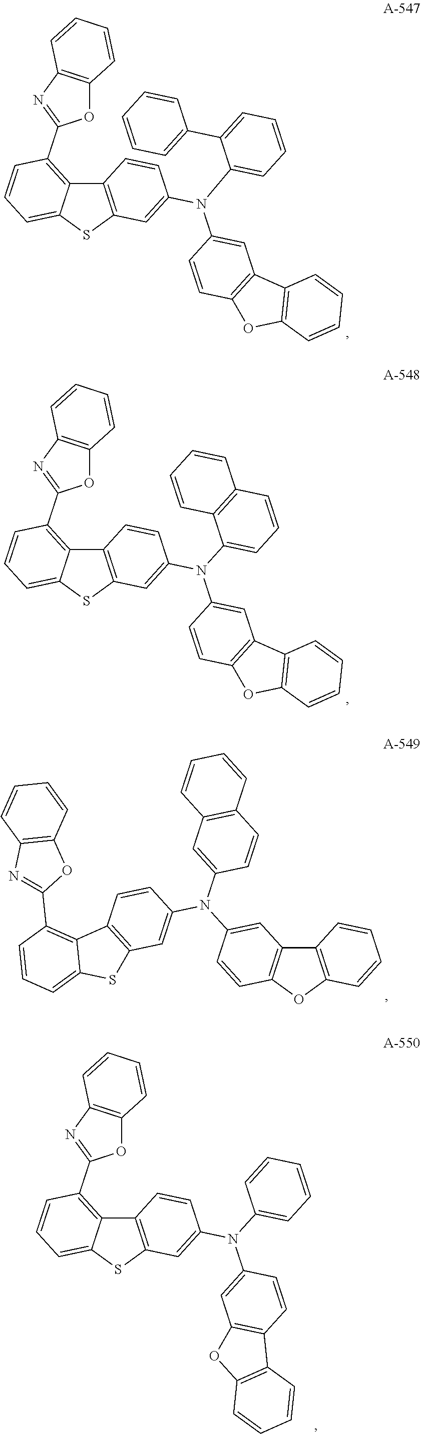 [SMILES: c1ccc(-c2ccccc2N(c2ccc3c(c2)sc2cccc(-c4nc5ccccc5o4)c23)c2ccc3oc4ccccc4c3c2)cc1 ; c1ccc2c(N(c3ccc4c(c3)sc3cccc(-c5nc6ccccc6o5)c34)c3ccc4oc5ccccc5c4c3)cccc2c1 ; c1ccc2cc(N(c3ccc4c(c3)sc3cccc(-c5nc6ccccc6o5)c34)c3ccc4oc5ccccc5c4c3)ccc2c1 ; c1ccc(N(c2ccc3c(c2)oc2ccccc23)c2ccc3c(c2)sc2cccc(-c4nc5ccccc5o4)c23)cc1] 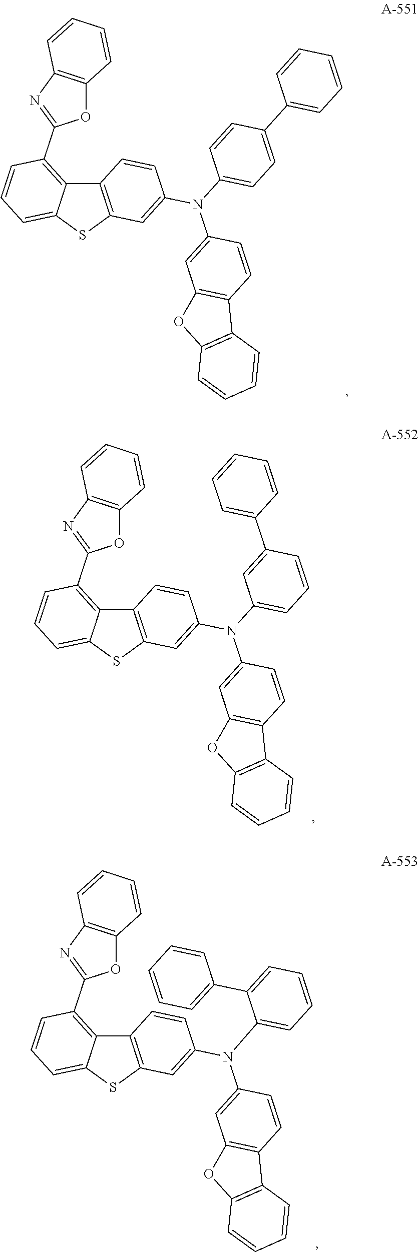 [SMILES: c1ccc(-c2ccc(N(c3ccc4c(c3)oc3ccccc34)c3ccc4c(c3)sc3cccc(-c5nc6ccccc6o5)c34)cc2)cc1 ; c1ccc(-c2cccc(N(c3ccc4c(c3)oc3ccccc34)c3ccc4c(c3)sc3cccc(-c5nc6ccccc6o5)c34)c2)cc1 ; c1ccc(-c2ccccc2N(c2ccc3c(c2)oc2ccccc23)c2ccc3c(c2)sc2cccc(-c4nc5ccccc5o4)c23)cc1] 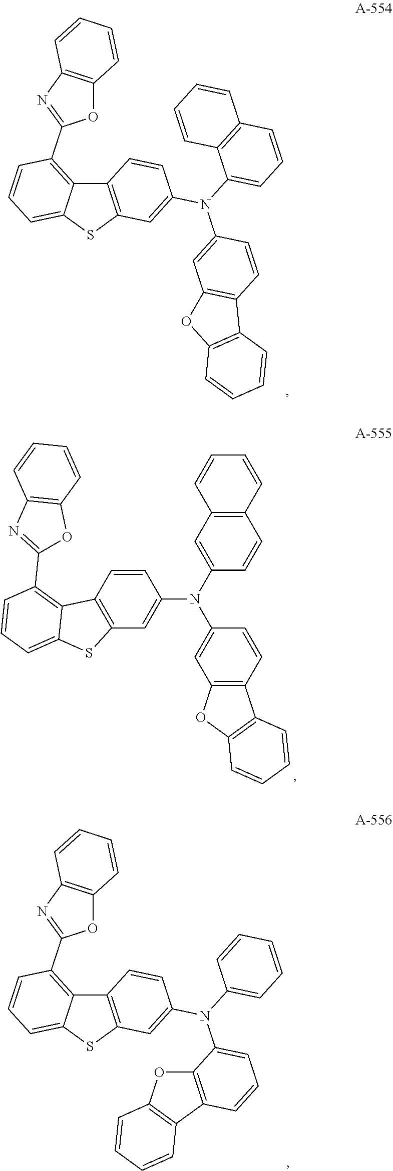 [SMILES: c1ccc2c(N(c3ccc4c(c3)oc3ccccc34)c3ccc4c(c3)sc3cccc(-c5nc6ccccc6o5)c34)cccc2c1 ; c1ccc2cc(N(c3ccc4c(c3)oc3ccccc34)c3ccc4c(c3)sc3cccc(-c5nc6ccccc6o5)c34)ccc2c1 ; c1ccc(N(c2ccc3c(c2)sc2cccc(-c4nc5ccccc5o4)c23)c2cccc3c2oc2ccccc23)cc1] 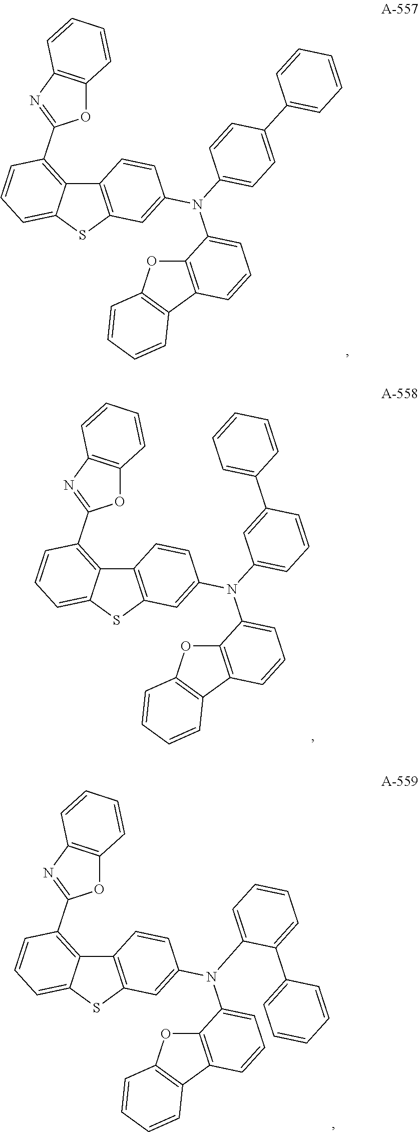 [SMILES: c1ccc(-c2ccc(N(c3ccc4c(c3)sc3cccc(-c5nc6ccccc6o5)c34)c3cccc4c3oc3ccccc34)cc2)cc1 ; c1ccc(-c2cccc(N(c3ccc4c(c3)sc3cccc(-c5nc6ccccc6o5)c34)c3cccc4c3oc3ccccc34)c2)cc1 ; c1ccc(-c2ccccc2N(c2ccc3c(c2)sc2cccc(-c4nc5ccccc5o4)c23)c2cccc3c2oc2ccccc23)cc1] 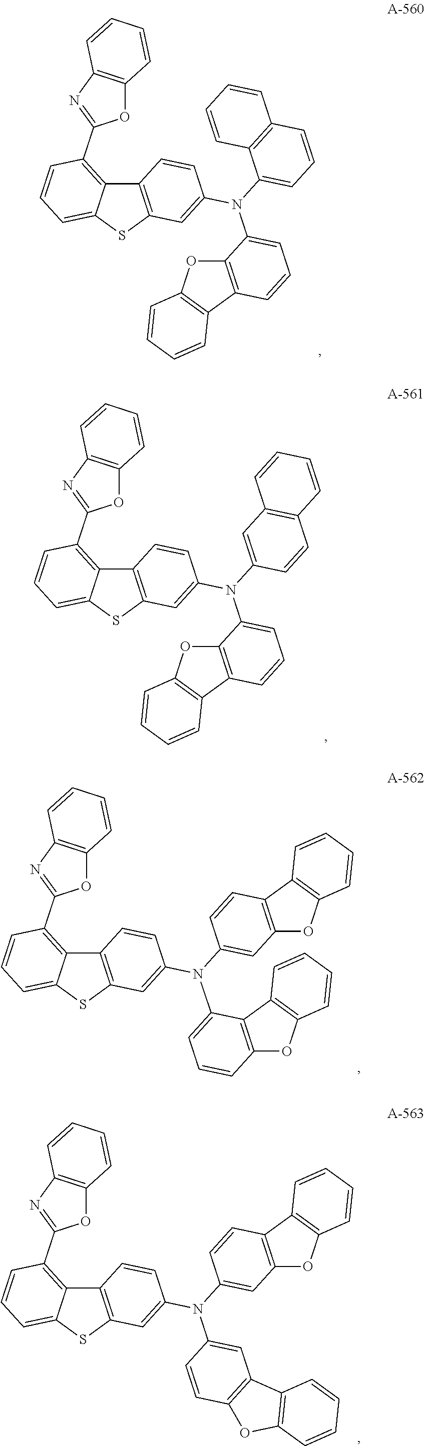 [SMILES: c1ccc2c(N(c3ccc4c(c3)sc3cccc(-c5nc6ccccc6o5)c34)c3cccc4c3oc3ccccc34)cccc2c1 ; c1ccc2cc(N(c3ccc4c(c3)sc3cccc(-c5nc6ccccc6o5)c34)c3cccc4c3oc3ccccc34)ccc2c1 ; c1ccc2oc(-c3cccc4sc5cc(N(c6ccc7c(c6)oc6ccccc67)c6cccc7oc8ccccc8c67)ccc5c34)nc2c1 ; c1ccc2oc(-c3cccc4sc5cc(N(c6ccc7c(c6)oc6ccccc67)c6ccc7oc8ccccc8c7c6)ccc5c34)nc2c1] 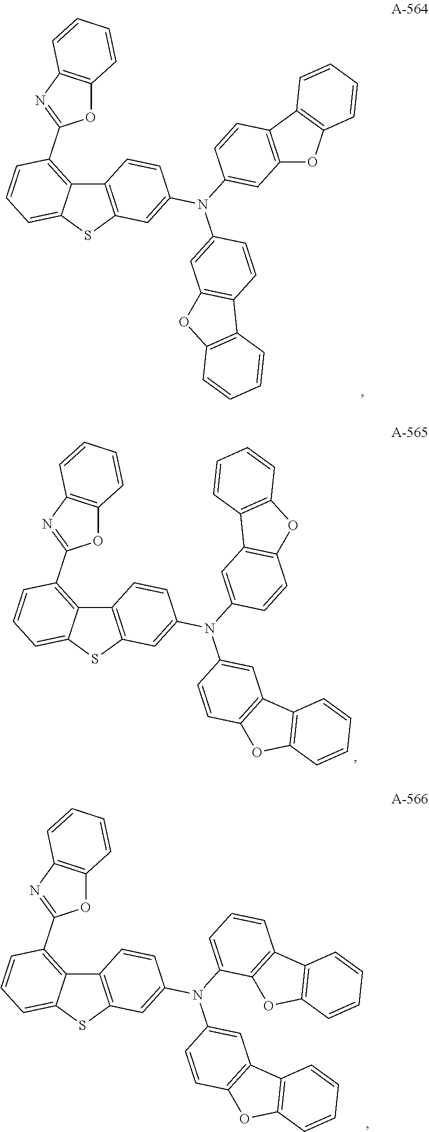 [SMILES: c1ccc2oc(-c3cccc4sc5cc(N(c6ccc7c(c6)oc6ccccc67)c6ccc7c(c6)oc6ccccc67)ccc5c34)nc2c1 ; c1ccc2oc(-c3cccc4sc5cc(N(c6ccc7oc8ccccc8c7c6)c6ccc7oc8ccccc8c7c6)ccc5c34)nc2c1 ; c1ccc2oc(-c3cccc4sc5cc(N(c6ccc7oc8ccccc8c7c6)c6cccc7c6oc6ccccc67)ccc5c34)nc2c1] 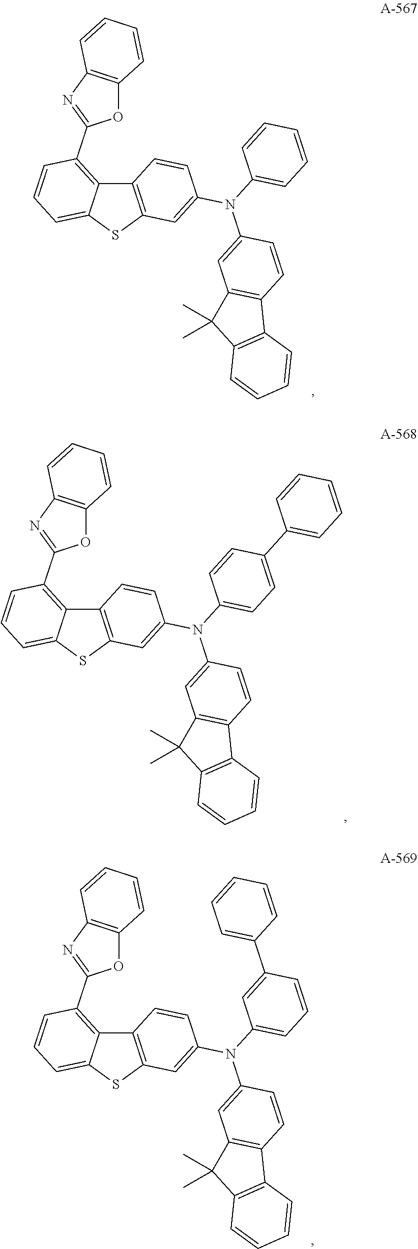 [SMILES: CC1(C)c2ccccc2-c2ccc(N(c3ccccc3)c3ccc4c(c3)sc3cccc(-c5nc6ccccc6o5)c34)cc21 ; CC1(C)c2ccccc2-c2ccc(N(c3ccc(-c4ccccc4)cc3)c3ccc4c(c3)sc3cccc(-c5nc6ccccc6o5)c34)cc21 ; CC1(C)c2ccccc2-c2ccc(N(c3cccc(-c4ccccc4)c3)c3ccc4c(c3)sc3cccc(-c5nc6ccccc6o5)c34)cc21] 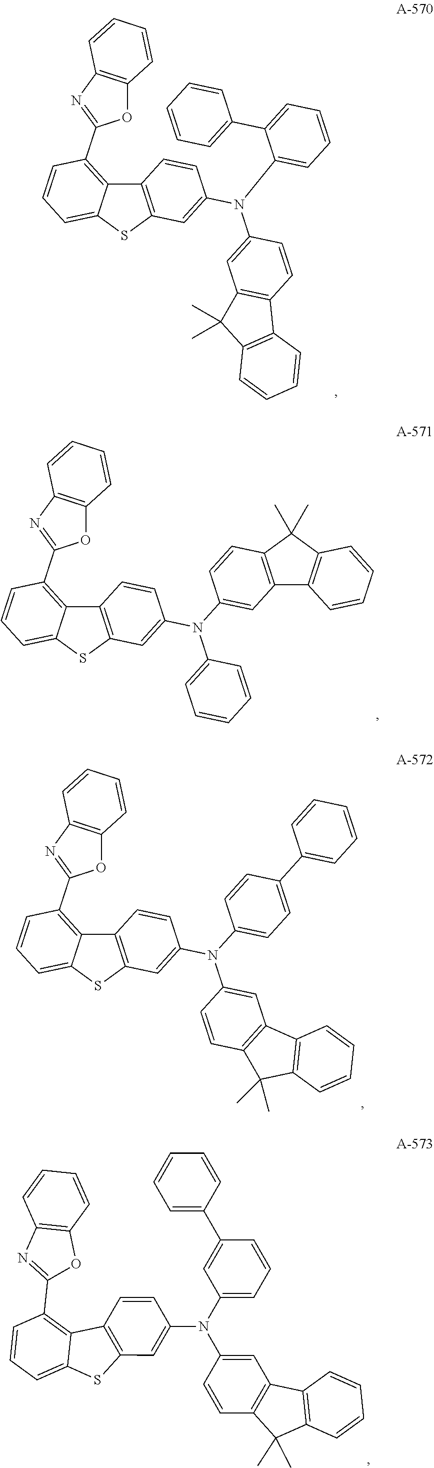 [SMILES: CC1(C)c2ccccc2-c2ccc(N(c3ccc4c(c3)sc3cccc(-c5nc6ccccc6o5)c34)c3ccccc3-c3ccccc3)cc21 ; CC1(C)c2ccccc2-c2cc(N(c3ccccc3)c3ccc4c(c3)sc3cccc(-c5nc6ccccc6o5)c34)ccc21 ; CC1(C)c2ccccc2-c2cc(N(c3ccc(-c4ccccc4)cc3)c3ccc4c(c3)sc3cccc(-c5nc6ccccc6o5)c34)ccc21 ; CC1(C)c2ccccc2-c2cc(N(c3cccc(-c4ccccc4)c3)c3ccc4c(c3)sc3cccc(-c5nc6ccccc6o5)c34)ccc21] 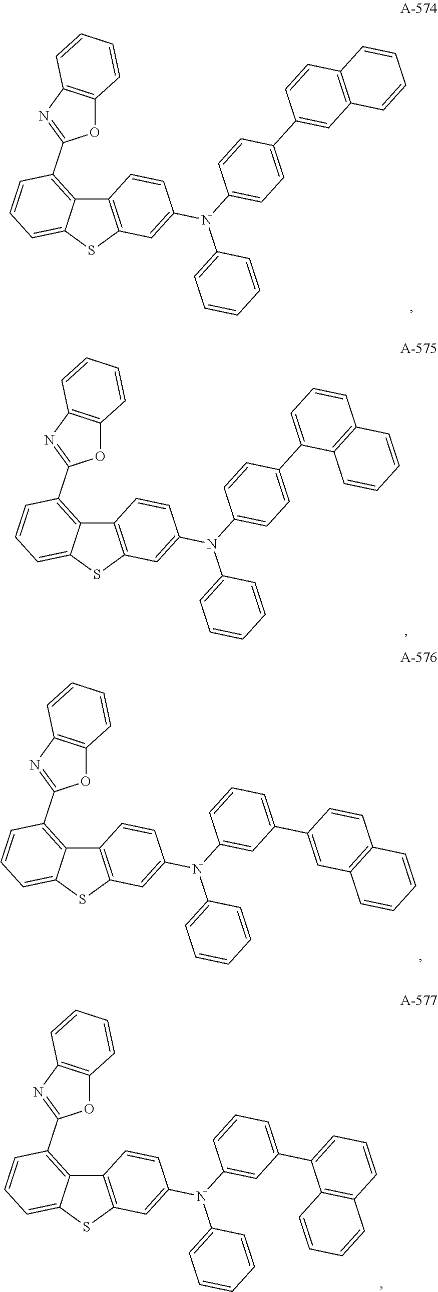 [SMILES: c1ccc(N(c2ccc(-c3ccc4ccccc4c3)cc2)c2ccc3c(c2)sc2cccc(-c4nc5ccccc5o4)c23)cc1 ; c1ccc(N(c2ccc(-c3cccc4ccccc34)cc2)c2ccc3c(c2)sc2cccc(-c4nc5ccccc5o4)c23)cc1 ; c1ccc(N(c2cccc(-c3ccc4ccccc4c3)c2)c2ccc3c(c2)sc2cccc(-c4nc5ccccc5o4)c23)cc1 ; c1ccc(N(c2cccc(-c3cccc4ccccc34)c2)c2ccc3c(c2)sc2cccc(-c4nc5ccccc5o4)c23)cc1] 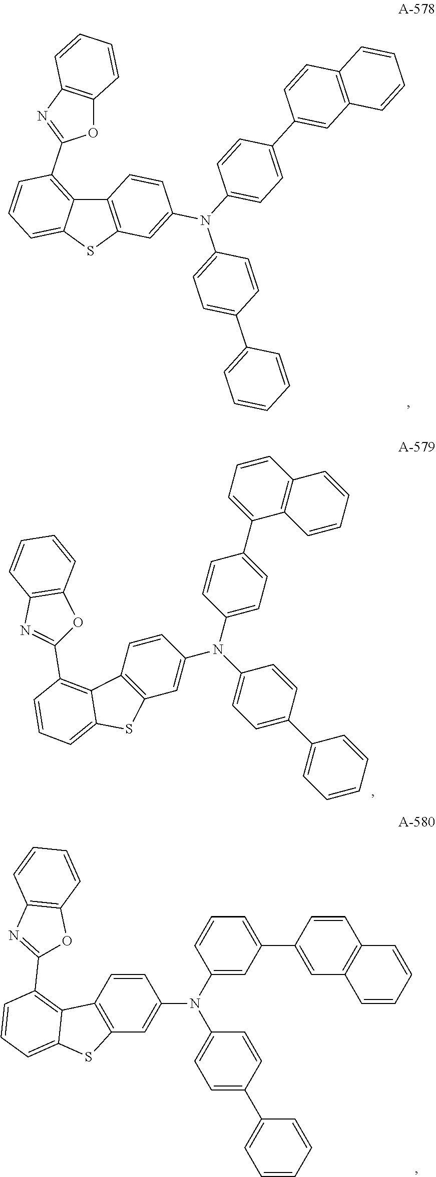 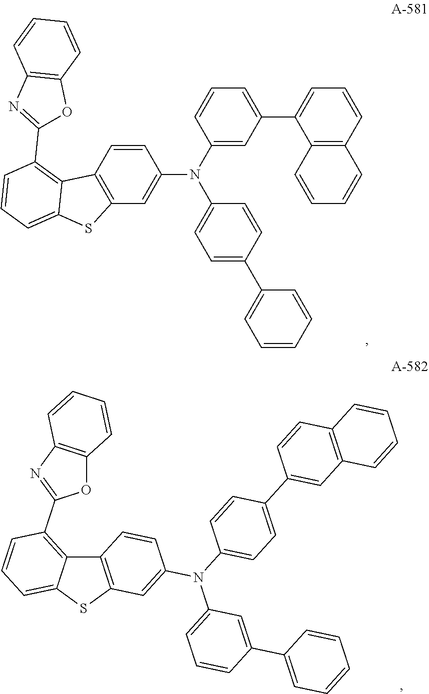 [SMILES: c1ccc(-c2ccc(N(c3cccc(-c4cccc5ccccc45)c3)c3ccc4c(c3)sc3cccc(-c5nc6ccccc6o5)c34)cc2)cc1 ; c1ccc(-c2cccc(N(c3ccc(-c4ccc5ccccc5c4)cc3)c3ccc4c(c3)sc3cccc(-c5nc6ccccc6o5)c34)c2)cc1] 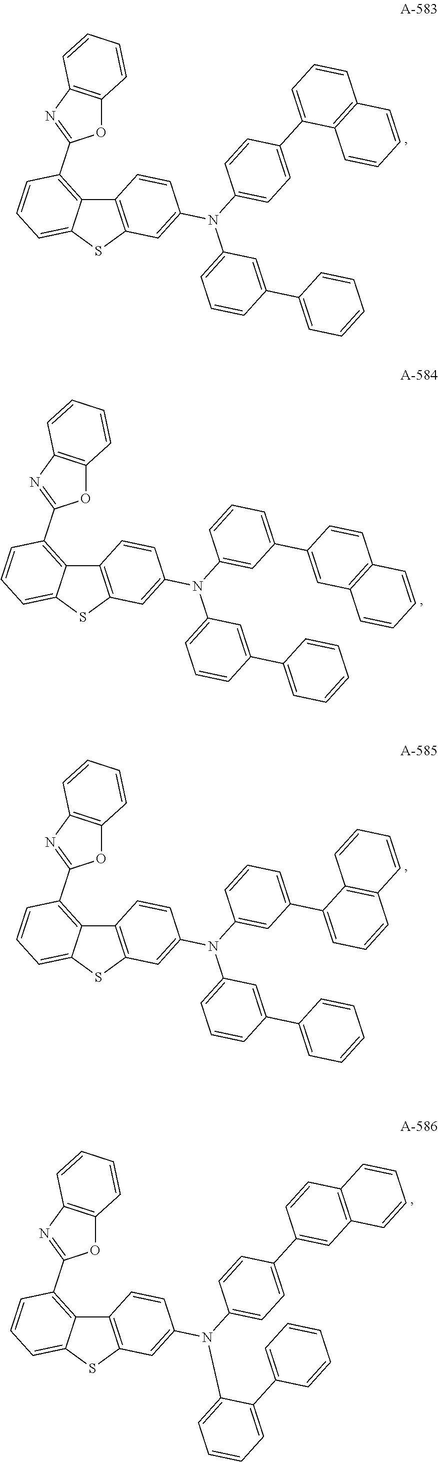 [SMILES: c1ccc(-c2cccc(N(c3ccc(-c4cccc5ccccc45)cc3)c3ccc4c(c3)sc3cccc(-c5nc6ccccc6o5)c34)c2)cc1 ; c1ccc(-c2cccc(N(c3cccc(-c4ccc5ccccc5c4)c3)c3ccc4c(c3)sc3cccc(-c5nc6ccccc6o5)c34)c2)cc1 ; c1ccc(-c2cccc(N(c3cccc(-c4cccc5ccccc45)c3)c3ccc4c(c3)sc3cccc(-c5nc6ccccc6o5)c34)c2)cc1 ; c1ccc(-c2ccccc2N(c2ccc(-c3ccc4ccccc4c3)cc2)c2ccc3c(c2)sc2cccc(-c4nc5ccccc5o4)c23)cc1] 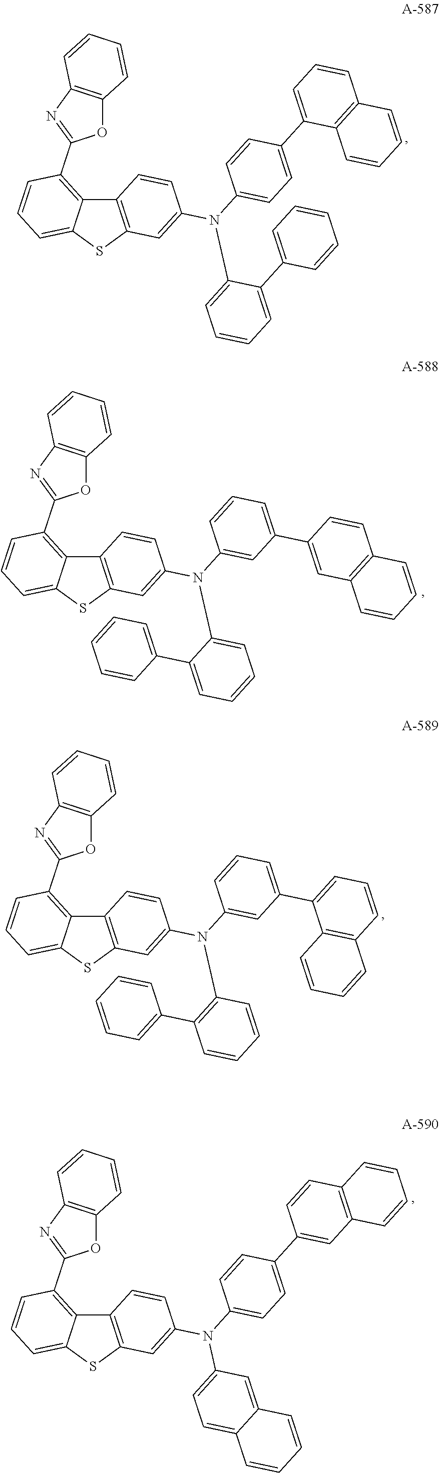 [SMILES: c1ccc(-c2ccccc2N(c2ccc(-c3cccc4ccccc34)cc2)c2ccc3c(c2)sc2cccc(-c4nc5ccccc5o4)c23)cc1 ; c1ccc(-c2ccccc2N(c2cccc(-c3ccc4ccccc4c3)c2)c2ccc3c(c2)sc2cccc(-c4nc5ccccc5o4)c23)cc1 ; c1ccc(-c2ccccc2N(c2cccc(-c3cccc4ccccc34)c2)c2ccc3c(c2)sc2cccc(-c4nc5ccccc5o4)c23)cc1 ; c1ccc2cc(-c3ccc(N(c4ccc5ccccc5c4)c4ccc5c(c4)sc4cccc(-c6nc7ccccc7o6)c45)cc3)ccc2c1] 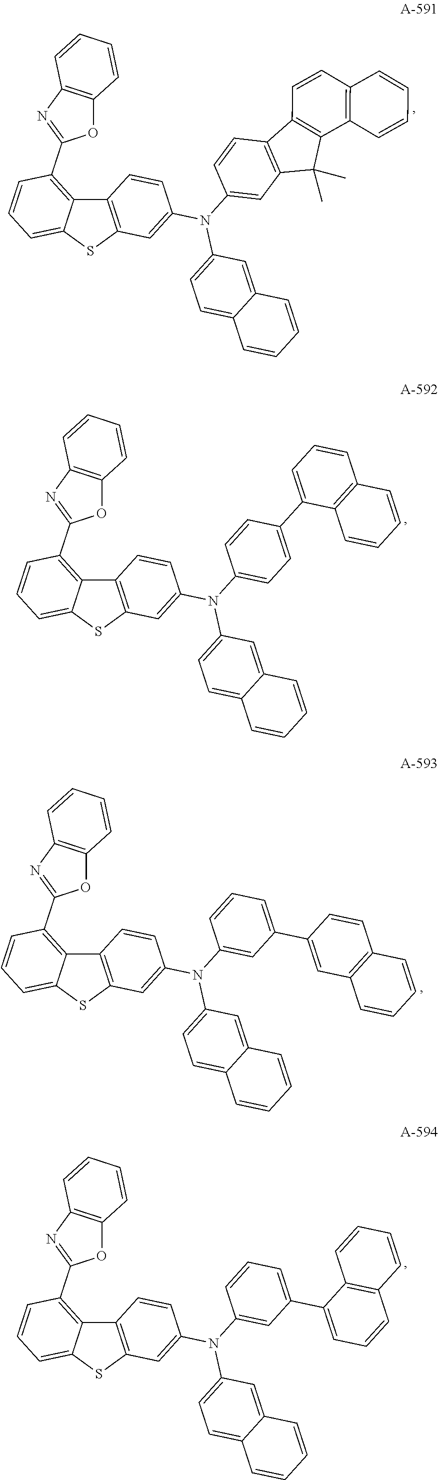 [SMILES: CC1(C)c2cc(N(c3ccc4ccccc4c3)c3ccc4c(c3)sc3cccc(-c5nc6ccccc6o5)c34)ccc2-c2ccc3ccccc3c21 ; c1ccc2cc(N(c3ccc(-c4cccc5ccccc45)cc3)c3ccc4c(c3)sc3cccc(-c5nc6ccccc6o5)c34)ccc2c1 ; c1cc(-c2ccc3ccccc3c2)cc(N(c2ccc3ccccc3c2)c2ccc3c(c2)sc2cccc(-c4nc5ccccc5o4)c23)c1 ; c1cc(-c2cccc3ccccc23)cc(N(c2ccc3ccccc3c2)c2ccc3c(c2)sc2cccc(-c4nc5ccccc5o4)c23)c1] 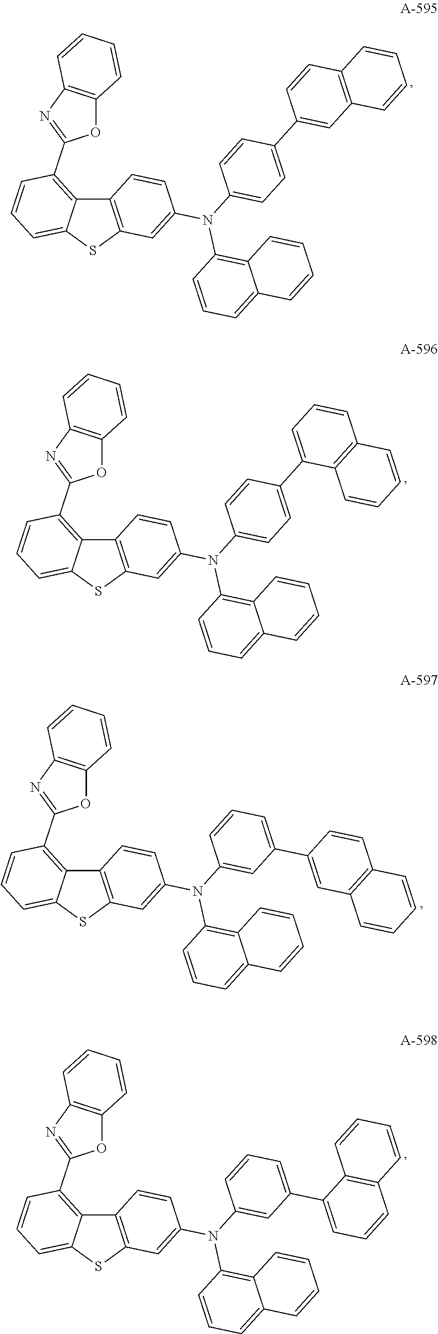 [SMILES: c1ccc2cc(-c3ccc(N(c4ccc5c(c4)sc4cccc(-c6nc7ccccc7o6)c45)c4cccc5ccccc45)cc3)ccc2c1 ; c1ccc2c(-c3ccc(N(c4ccc5c(c4)sc4cccc(-c6nc7ccccc7o6)c45)c4cccc5ccccc45)cc3)cccc2c1 ; c1cc(-c2ccc3ccccc3c2)cc(N(c2ccc3c(c2)sc2cccc(-c4nc5ccccc5o4)c23)c2cccc3ccccc23)c1 ; c1cc(-c2cccc3ccccc23)cc(N(c2ccc3c(c2)sc2cccc(-c4nc5ccccc5o4)c23)c2cccc3ccccc23)c1] 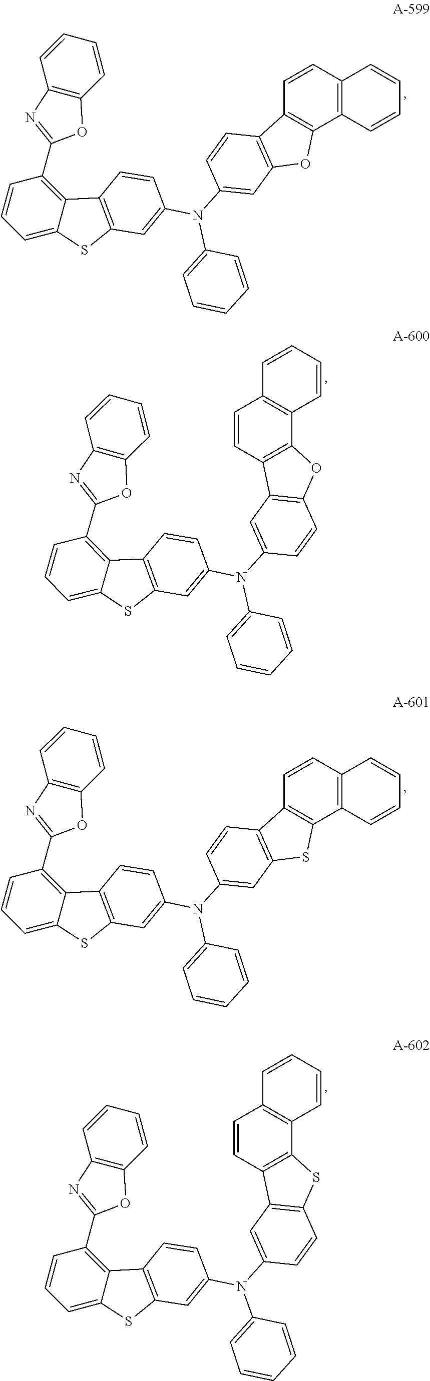 [SMILES: c1ccc(N(c2ccc3c(c2)oc2c4ccccc4ccc32)c2ccc3c(c2)sc2cccc(-c4nc5ccccc5o4)c23)cc1 ; c1ccc(N(c2ccc3c(c2)sc2cccc(-c4nc5ccccc5o4)c23)c2ccc3oc4c5ccccc5ccc4c3c2)cc1 ; c1ccc(N(c2ccc3c(c2)sc2c4ccccc4ccc32)c2ccc3c(c2)sc2cccc(-c4nc5ccccc5o4)c23)cc1 ; c1ccc(N(c2ccc3c(c2)sc2cccc(-c4nc5ccccc5o4)c23)c2ccc3sc4c5ccccc5ccc4c3c2)cc1] 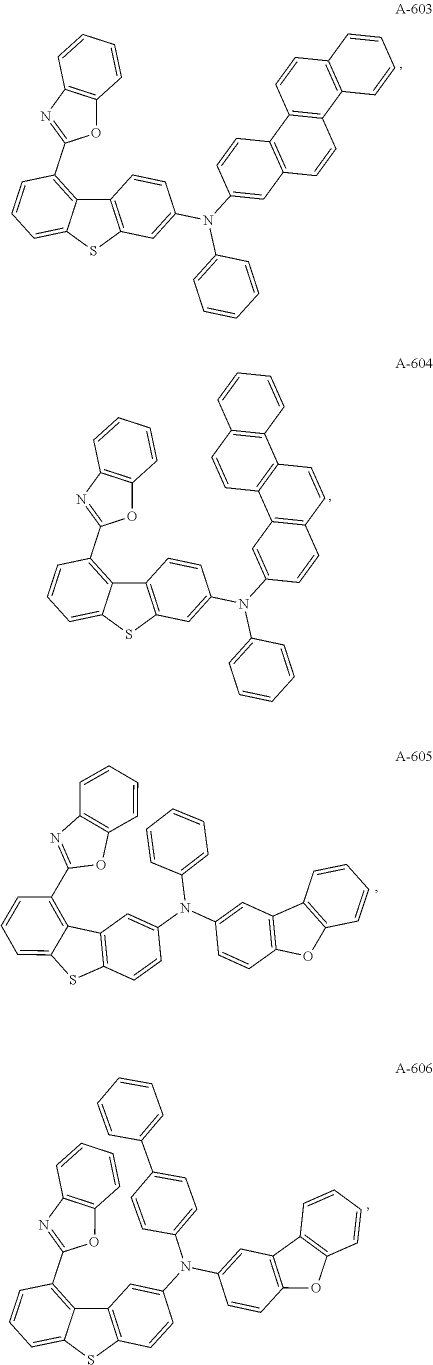 [SMILES: c1ccc(N(c2ccc3c(ccc4c5ccccc5ccc34)c2)c2ccc3c(c2)sc2cccc(-c4nc5ccccc5o4)c23)cc1 ; c1ccc(N(c2ccc3c(c2)sc2cccc(-c4nc5ccccc5o4)c23)c2ccc3ccc4c5ccccc5ccc4c3c2)cc1 ; c1ccc(N(c2ccc3oc4ccccc4c3c2)c2ccc3sc4cccc(-c5nc6ccccc6o5)c4c3c2)cc1 ; c1ccc(-c2ccc(N(c3ccc4oc5ccccc5c4c3)c3ccc4sc5cccc(-c6nc7ccccc7o6)c5c4c3)cc2)cc1] 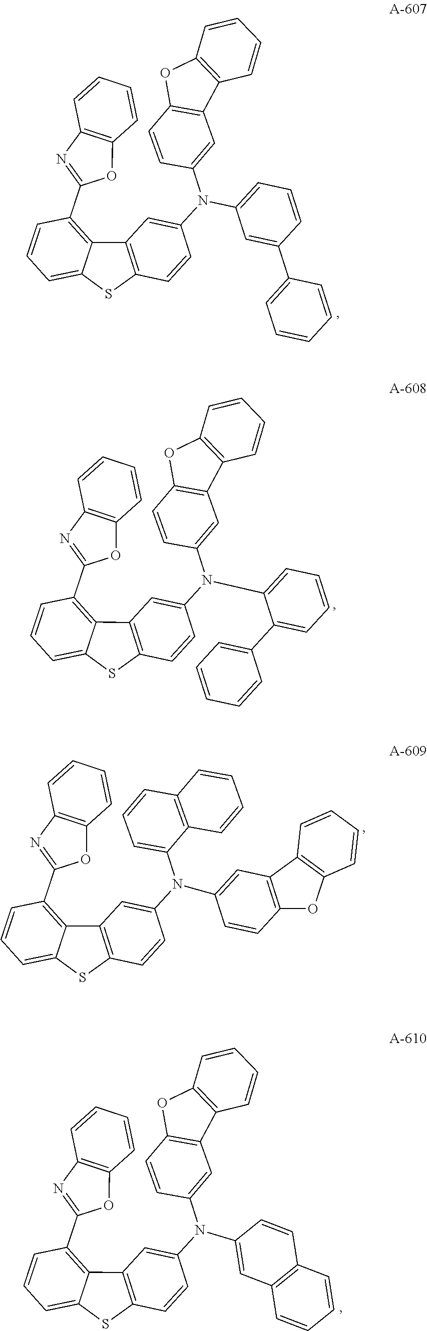 [SMILES: c1ccc(-c2cccc(N(c3ccc4oc5ccccc5c4c3)c3ccc4sc5cccc(-c6nc7ccccc7o6)c5c4c3)c2)cc1 ; c1ccc(-c2ccccc2N(c2ccc3oc4ccccc4c3c2)c2ccc3sc4cccc(-c5nc6ccccc6o5)c4c3c2)cc1 ; c1ccc2c(N(c3ccc4oc5ccccc5c4c3)c3ccc4sc5cccc(-c6nc7ccccc7o6)c5c4c3)cccc2c1 ; c1ccc2cc(N(c3ccc4oc5ccccc5c4c3)c3ccc4sc5cccc(-c6nc7ccccc7o6)c5c4c3)ccc2c1] 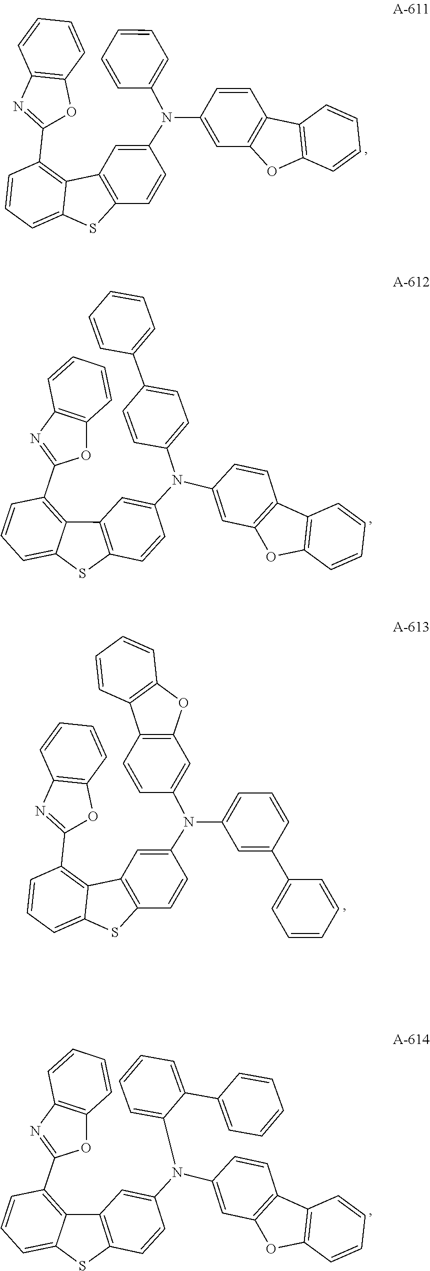 [SMILES: c1ccc(N(c2ccc3c(c2)oc2ccccc23)c2ccc3sc4cccc(-c5nc6ccccc6o5)c4c3c2)cc1 ; c1ccc(-c2ccc(N(c3ccc4c(c3)oc3ccccc34)c3ccc4sc5cccc(-c6nc7ccccc7o6)c5c4c3)cc2)cc1 ; c1ccc(-c2cccc(N(c3ccc4c(c3)oc3ccccc34)c3ccc4sc5cccc(-c6nc7ccccc7o6)c5c4c3)c2)cc1 ; c1ccc(-c2ccccc2N(c2ccc3c(c2)oc2ccccc23)c2ccc3sc4cccc(-c5nc6ccccc6o5)c4c3c2)cc1] 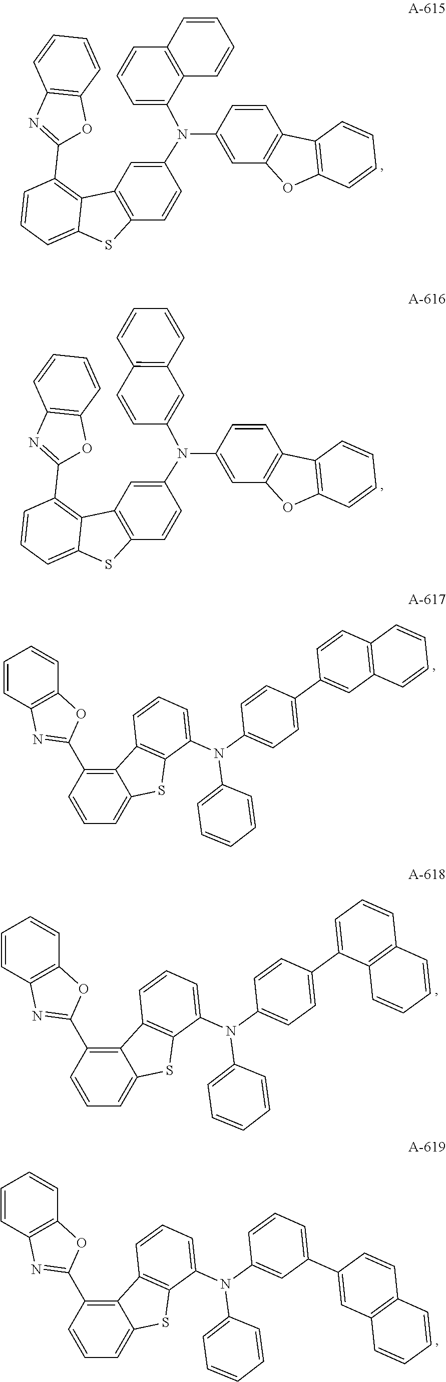 [SMILES: c1ccc2c(N(c3ccc4c(c3)oc3ccccc34)c3ccc4sc5cccc(-c6nc7ccccc7o6)c5c4c3)cccc2c1 ; c1ccc2cc(N(c3ccc4c(c3)oc3ccccc34)c3ccc4sc5cccc(-c6nc7ccccc7o6)c5c4c3)ccc2c1 ; c1ccc(N(c2ccc(-c3ccc4ccccc4c3)cc2)c2cccc3c2sc2cccc(-c4nc5ccccc5o4)c23)cc1 ; c1ccc(N(c2ccc(-c3cccc4ccccc34)cc2)c2cccc3c2sc2cccc(-c4nc5ccccc5o4)c23)cc1 ; c1ccc(N(c2cccc(-c3ccc4ccccc4c3)c2)c2cccc3c2sc2cccc(-c4nc5ccccc5o4)c23)cc1] 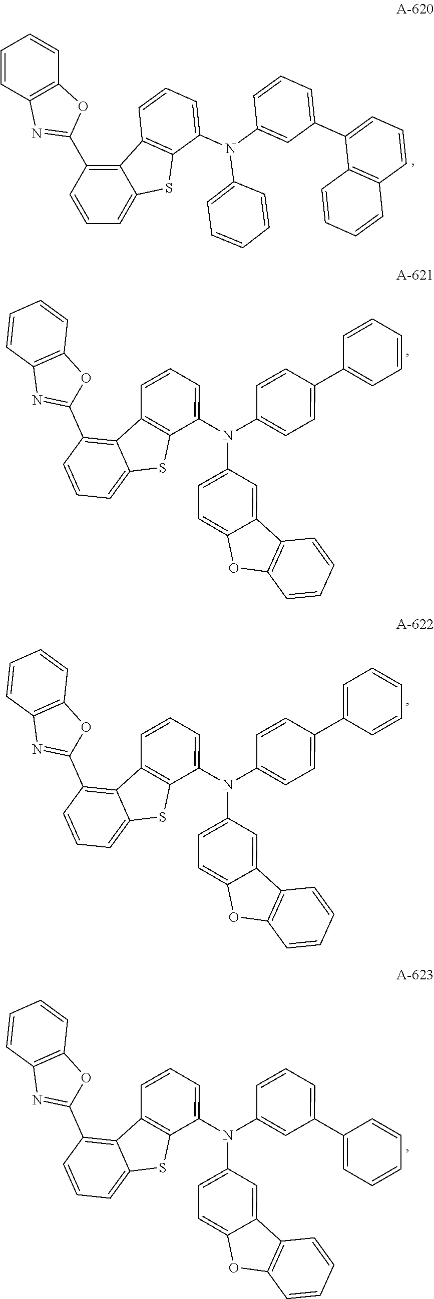 [SMILES: c1ccc(N(c2cccc(-c3cccc4ccccc34)c2)c2cccc3c2sc2cccc(-c4nc5ccccc5o4)c23)cc1 ; c1ccc(-c2ccc(N(c3ccc4oc5ccccc5c4c3)c3cccc4c3sc3cccc(-c5nc6ccccc6o5)c34)cc2)cc1 ; c1ccc(-c2ccc(N(c3ccc4oc5ccccc5c4c3)c3cccc4c3sc3cccc(-c5nc6ccccc6o5)c34)cc2)cc1 ; c1ccc(-c2cccc(N(c3ccc4oc5ccccc5c4c3)c3cccc4c3sc3cccc(-c5nc6ccccc6o5)c34)c2)cc1] 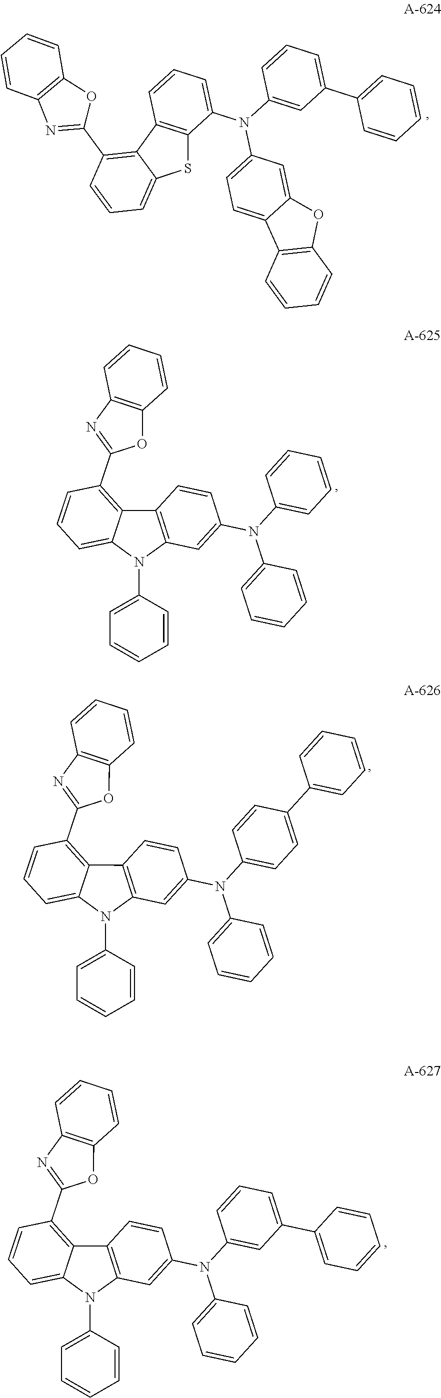 [SMILES: c1ccc(-c2cccc(N(c3ccc4c(c3)oc3ccccc34)c3cccc4c3sc3cccc(-c5nc6ccccc6o5)c34)c2)cc1 ; c1ccc(N(c2ccccc2)c2ccc3c4c(-c5nc6ccccc6o5)cccc4n(-c4ccccc4)c3c2)cc1 ; c1ccc(-c2ccc(N(c3ccccc3)c3ccc4c5c(-c6nc7ccccc7o6)cccc5n(-c5ccccc5)c4c3)cc2)cc1 ; c1ccc(-c2cccc(N(c3ccccc3)c3ccc4c5c(-c6nc7ccccc7o6)cccc5n(-c5ccccc5)c4c3)c2)cc1] 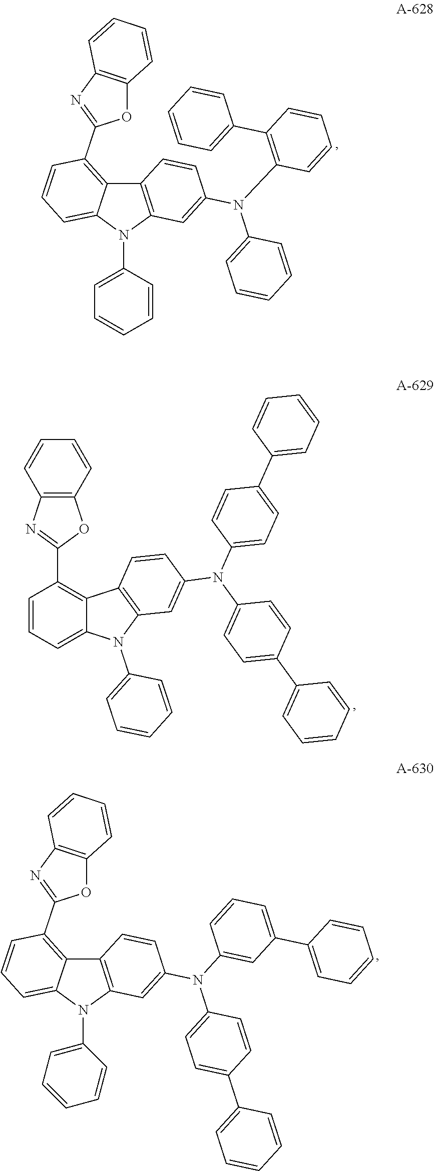 [SMILES: c1ccc(-c2ccccc2N(c2ccccc2)c2ccc3c4c(-c5nc6ccccc6o5)cccc4n(-c4ccccc4)c3c2)cc1 ; c1ccc(-c2ccc(N(c3ccc(-c4ccccc4)cc3)c3ccc4c5c(-c6nc7ccccc7o6)cccc5n(-c5ccccc5)c4c3)cc2)cc1 ; c1ccc(-c2ccc(N(c3cccc(-c4ccccc4)c3)c3ccc4c5c(-c6nc7ccccc7o6)cccc5n(-c5ccccc5)c4c3)cc2)cc1] 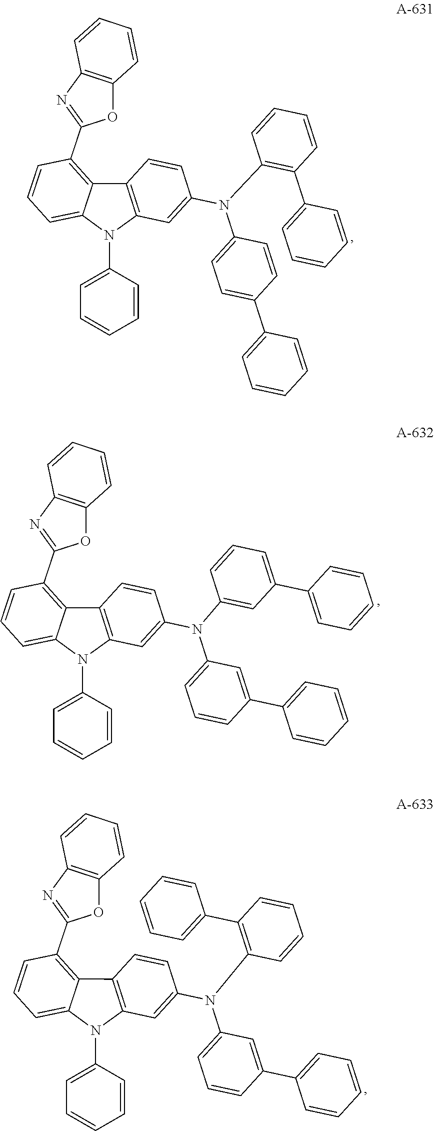 [SMILES: c1ccc(-c2ccc(N(c3ccc4c5c(-c6nc7ccccc7o6)cccc5n(-c5ccccc5)c4c3)c3ccccc3-c3ccccc3)cc2)cc1 ; c1ccc(-c2cccc(N(c3cccc(-c4ccccc4)c3)c3ccc4c5c(-c6nc7ccccc7o6)cccc5n(-c5ccccc5)c4c3)c2)cc1 ; c1ccc(-c2cccc(N(c3ccc4c5c(-c6nc7ccccc7o6)cccc5n(-c5ccccc5)c4c3)c3ccccc3-c3ccccc3)c2)cc1] 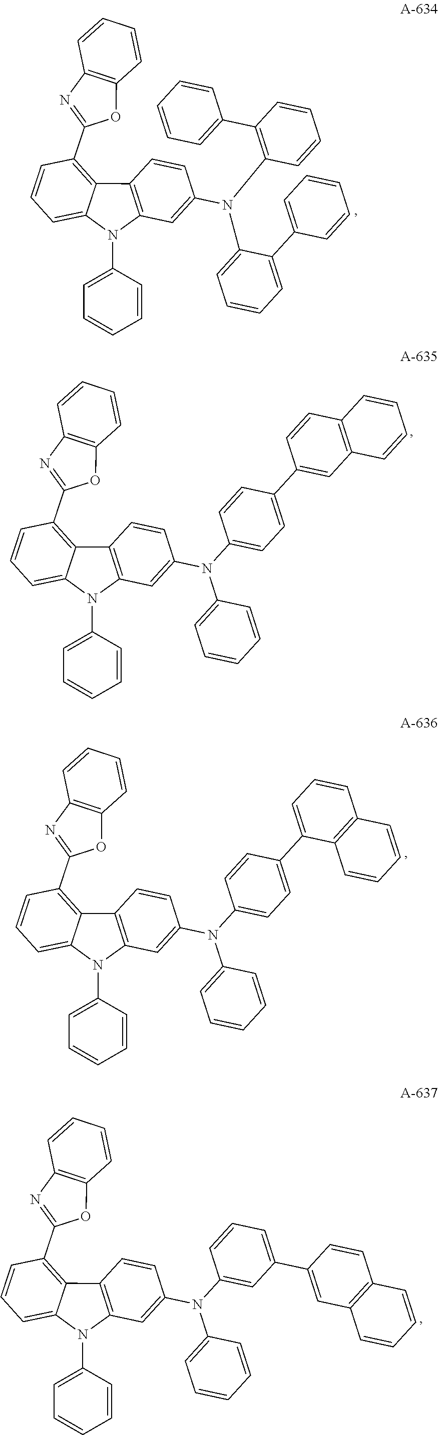 [SMILES: c1ccc(-c2ccccc2N(c2ccc3c4c(-c5nc6ccccc6o5)cccc4n(-c4ccccc4)c3c2)c2ccccc2-c2ccccc2)cc1 ; c1ccc(N(c2ccc(-c3ccc4ccccc4c3)cc2)c2ccc3c4c(-c5nc6ccccc6o5)cccc4n(-c4ccccc4)c3c2)cc1 ; c1ccc(N(c2ccc(-c3cccc4ccccc34)cc2)c2ccc3c4c(-c5nc6ccccc6o5)cccc4n(-c4ccccc4)c3c2)cc1 ; c1ccc(N(c2cccc(-c3ccc4ccccc4c3)c2)c2ccc3c4c(-c5nc6ccccc6o5)cccc4n(-c4ccccc4)c3c2)cc1] 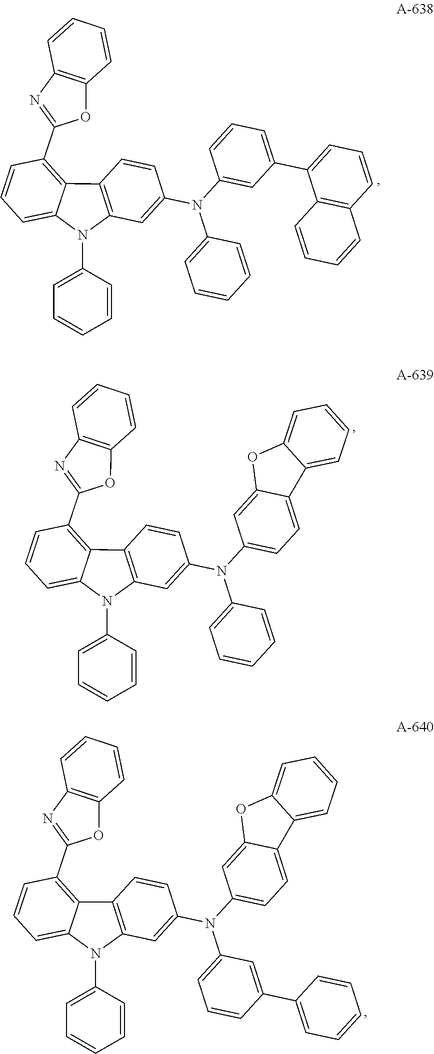 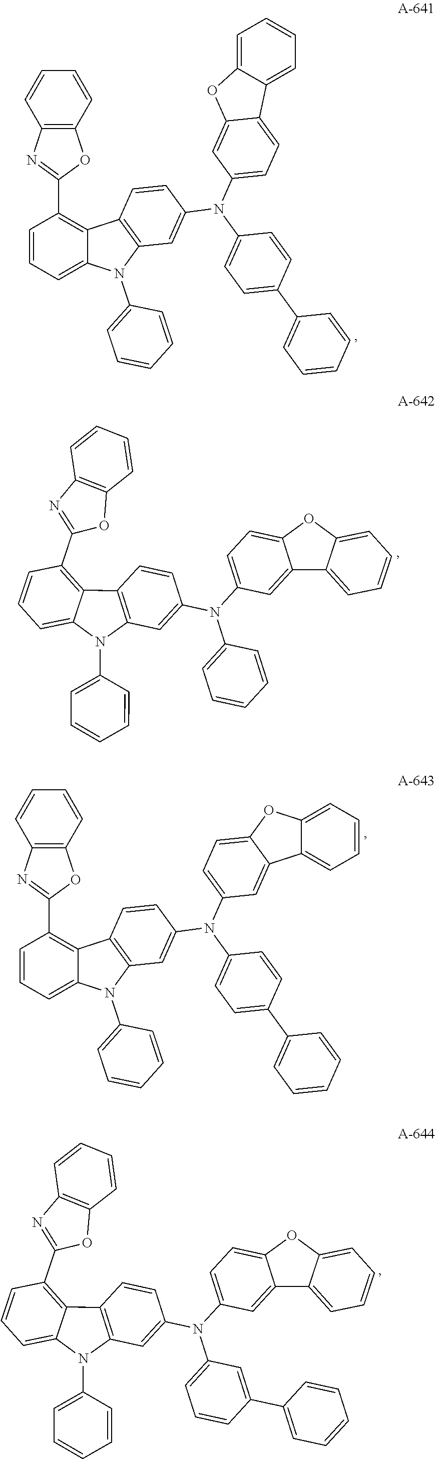 [SMILES: c1ccc(-c2ccc(N(c3ccc4c(c3)oc3ccccc34)c3ccc4c5c(-c6nc7ccccc7o6)cccc5n(-c5ccccc5)c4c3)cc2)cc1 ; c1ccc(N(c2ccc3oc4ccccc4c3c2)c2ccc3c4c(-c5nc6ccccc6o5)cccc4n(-c4ccccc4)c3c2)cc1 ; c1ccc(-c2ccc(N(c3ccc4oc5ccccc5c4c3)c3ccc4c5c(-c6nc7ccccc7o6)cccc5n(-c5ccccc5)c4c3)cc2)cc1 ; c1ccc(-c2cccc(N(c3ccc4oc5ccccc5c4c3)c3ccc4c5c(-c6nc7ccccc7o6)cccc5n(-c5ccccc5)c4c3)c2)cc1] 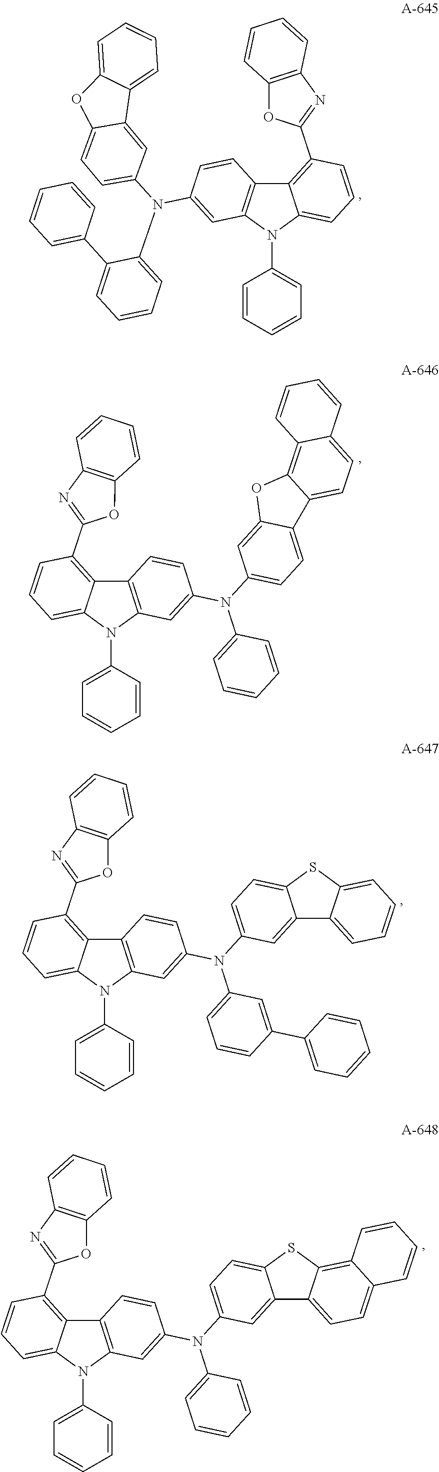 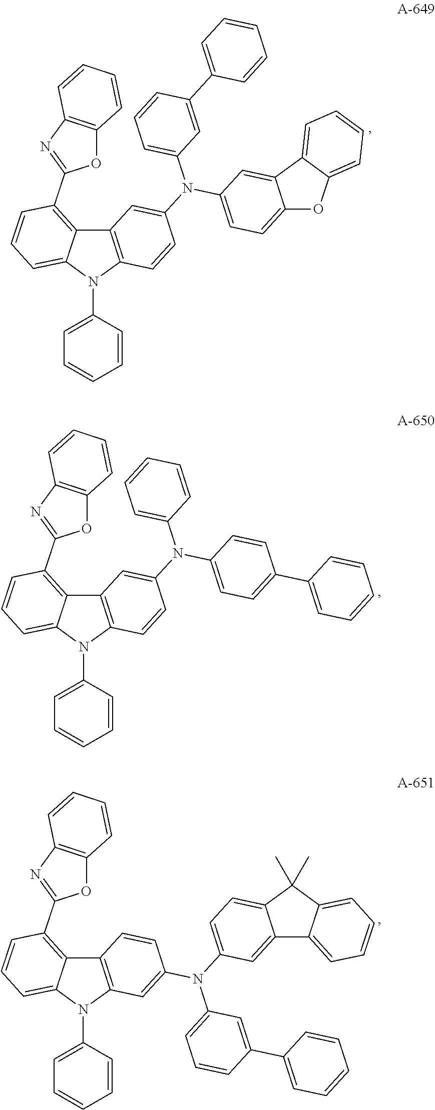 [SMILES: c1ccc(-c2cccc(N(c3ccc4oc5ccccc5c4c3)c3ccc4c(c3)c3c(-c5nc6ccccc6o5)cccc3n4-c3ccccc3)c2)cc1 ; c1ccc(-c2ccc(N(c3ccccc3)c3ccc4c(c3)c3c(-c5nc6ccccc6o5)cccc3n4-c3ccccc3)cc2)cc1 ; CC1(C)c2ccccc2-c2cc(N(c3cccc(-c4ccccc4)c3)c3ccc4c5c(-c6nc7ccccc7o6)cccc5n(-c5ccccc5)c4c3)ccc21] 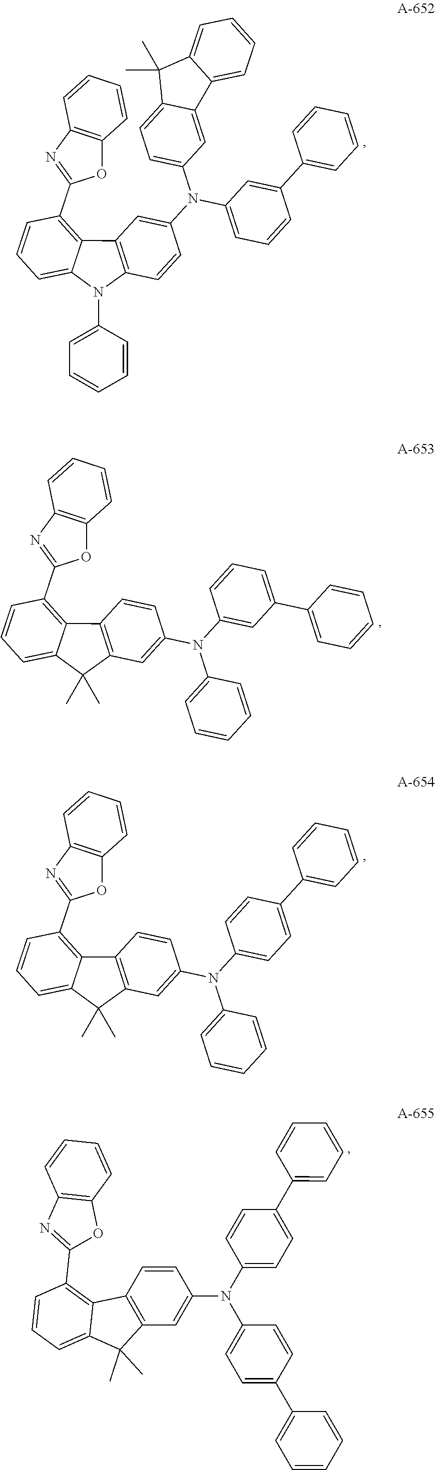 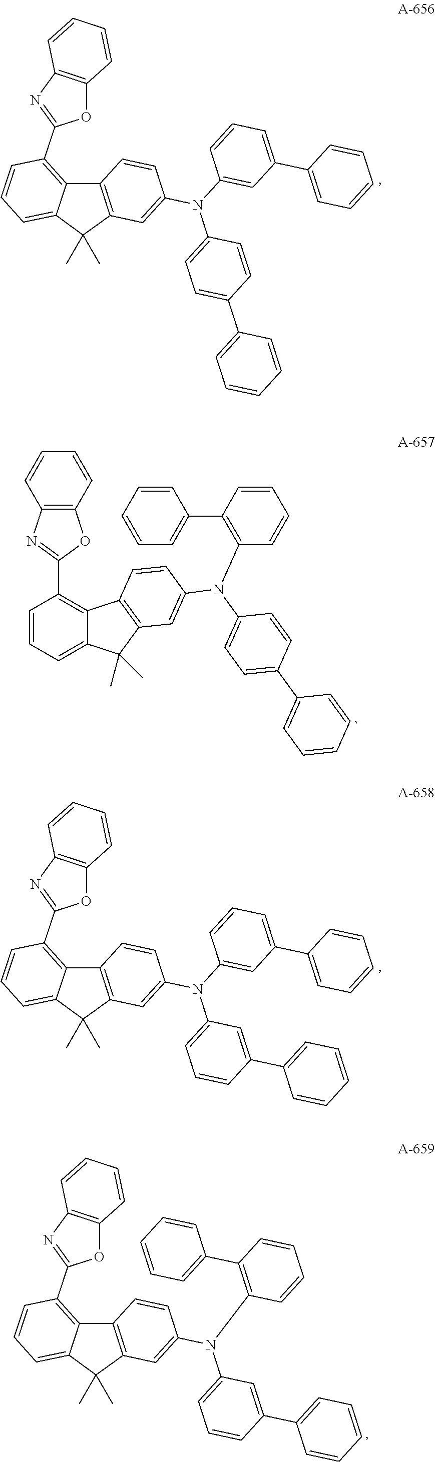 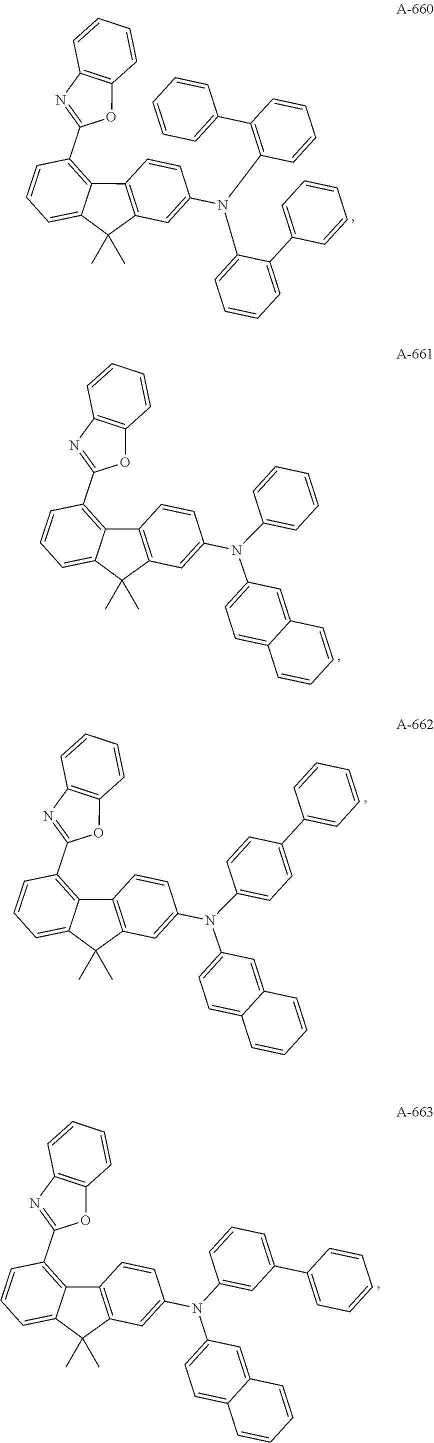 [SMILES: CC1(C)c2cc(N(c3ccccc3-c3ccccc3)c3ccccc3-c3ccccc3)ccc2-c2c(-c3nc4ccccc4o3)cccc21 ; CC1(C)c2cc(N(c3ccccc3)c3ccc4ccccc4c3)ccc2-c2c(-c3nc4ccccc4o3)cccc21 ; CC1(C)c2cc(N(c3ccc(-c4ccccc4)cc3)c3ccc4ccccc4c3)ccc2-c2c(-c3nc4ccccc4o3)cccc21 ; CC1(C)c2cc(N(c3cccc(-c4ccccc4)c3)c3ccc4ccccc4c3)ccc2-c2c(-c3nc4ccccc4o3)cccc21] 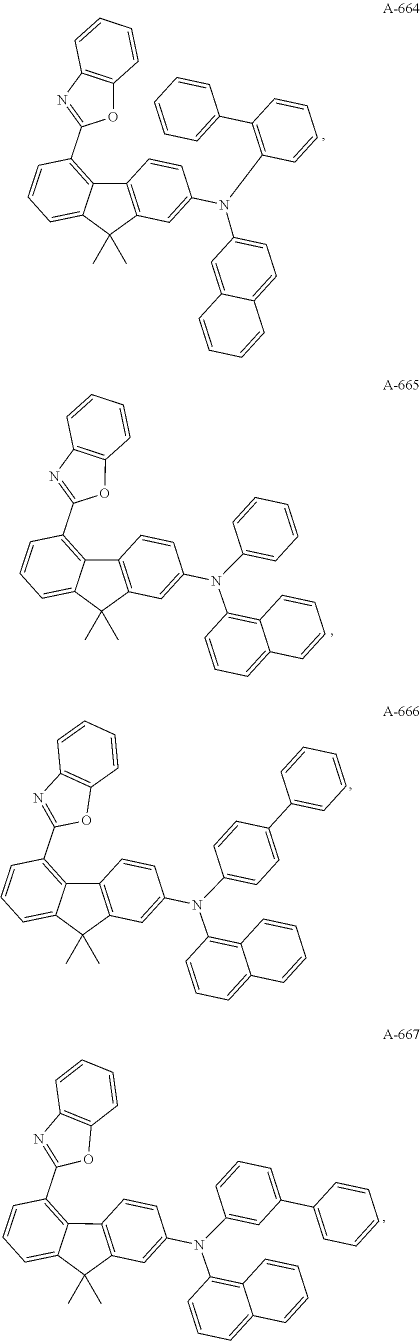 [SMILES: CC1(C)c2cc(N(c3ccc4ccccc4c3)c3ccccc3-c3ccccc3)ccc2-c2c(-c3nc4ccccc4o3)cccc21 ; CC1(C)c2cc(N(c3ccccc3)c3cccc4ccccc34)ccc2-c2c(-c3nc4ccccc4o3)cccc21 ; CC1(C)c2cc(N(c3ccc(-c4ccccc4)cc3)c3cccc4ccccc34)ccc2-c2c(-c3nc4ccccc4o3)cccc21 ; CC1(C)c2cc(N(c3cccc(-c4ccccc4)c3)c3cccc4ccccc34)ccc2-c2c(-c3nc4ccccc4o3)cccc21] 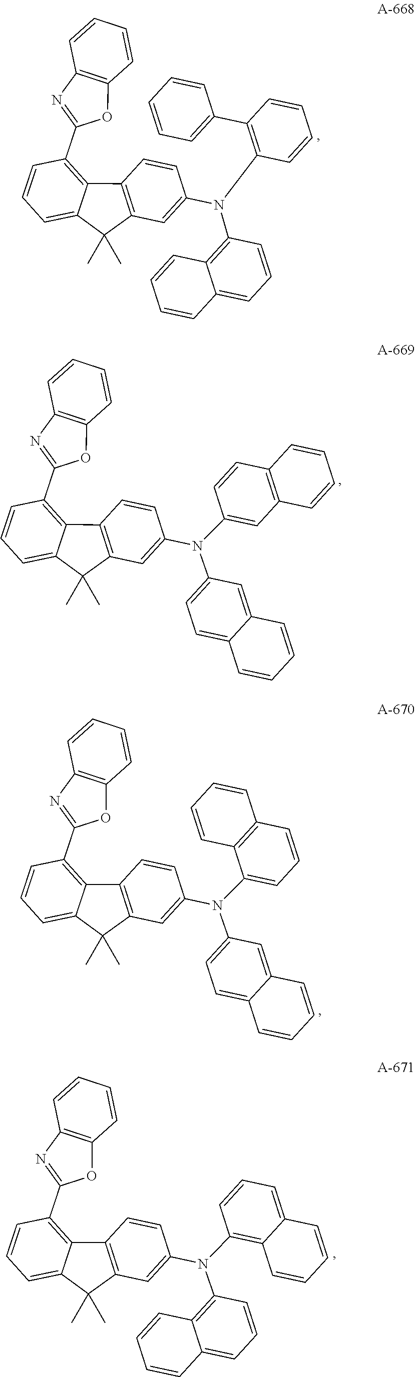 [SMILES: CC1(C)c2cc(N(c3ccccc3-c3ccccc3)c3cccc4ccccc34)ccc2-c2c(-c3nc4ccccc4o3)cccc21 ; CC1(C)c2cc(N(c3ccc4ccccc4c3)c3ccc4ccccc4c3)ccc2-c2c(-c3nc4ccccc4o3)cccc21 ; CC1(C)c2cc(N(c3ccc4ccccc4c3)c3cccc4ccccc34)ccc2-c2c(-c3nc4ccccc4o3)cccc21 ; CC1(C)c2cc(N(c3cccc4ccccc34)c3cccc4ccccc34)ccc2-c2c(-c3nc4ccccc4o3)cccc21] 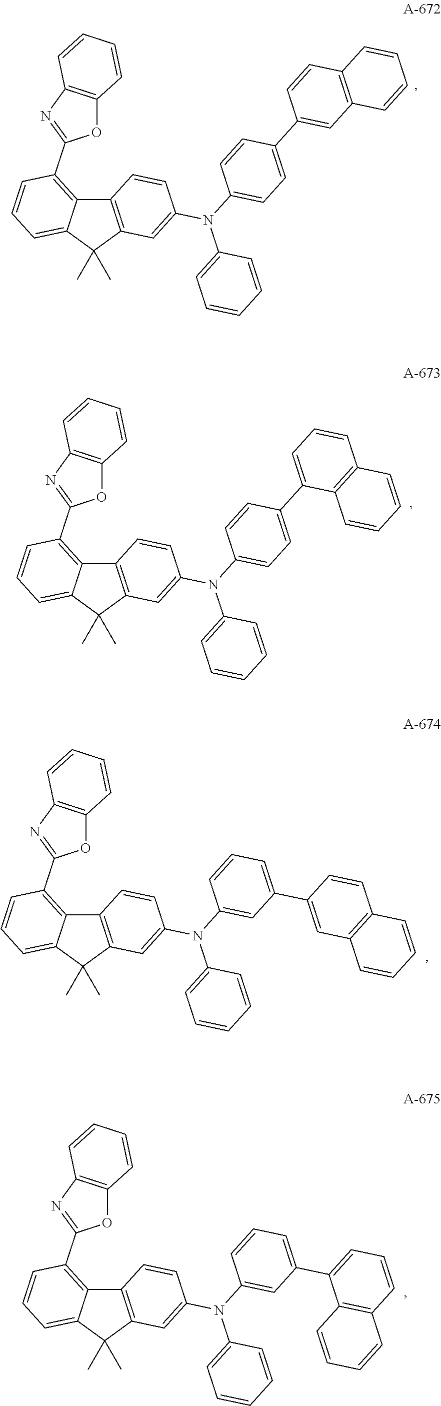 [SMILES: CC1(C)c2cc(N(c3ccccc3)c3ccc(-c4ccc5ccccc5c4)cc3)ccc2-c2c(-c3nc4ccccc4o3)cccc21 ; CC1(C)c2cc(N(c3ccccc3)c3ccc(-c4cccc5ccccc45)cc3)ccc2-c2c(-c3nc4ccccc4o3)cccc21 ; CC1(C)c2cc(N(c3ccccc3)c3cccc(-c4ccc5ccccc5c4)c3)ccc2-c2c(-c3nc4ccccc4o3)cccc21 ; CC1(C)c2cc(N(c3ccccc3)c3cccc(-c4cccc5ccccc45)c3)ccc2-c2c(-c3nc4ccccc4o3)cccc21] 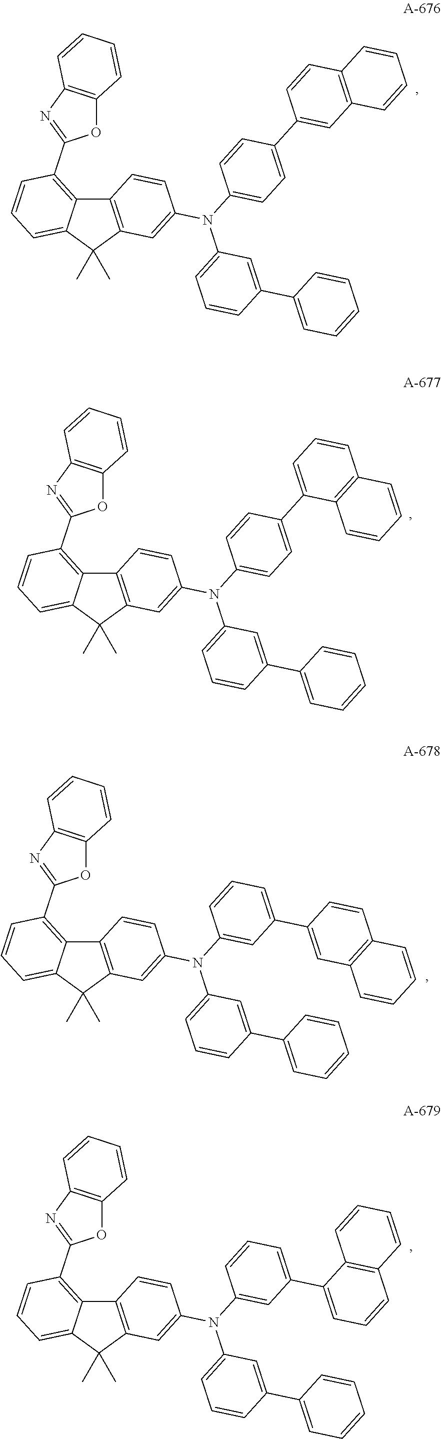 [SMILES: CC1(C)c2cc(N(c3ccc(-c4ccc5ccccc5c4)cc3)c3cccc(-c4ccccc4)c3)ccc2-c2c(-c3nc4ccccc4o3)cccc21 ; CC1(C)c2cc(N(c3ccc(-c4cccc5ccccc45)cc3)c3cccc(-c4ccccc4)c3)ccc2-c2c(-c3nc4ccccc4o3)cccc21 ; CC1(C)c2cc(N(c3cccc(-c4ccccc4)c3)c3cccc(-c4ccc5ccccc5c4)c3)ccc2-c2c(-c3nc4ccccc4o3)cccc21 ; CC1(C)c2cc(N(c3cccc(-c4ccccc4)c3)c3cccc(-c4cccc5ccccc45)c3)ccc2-c2c(-c3nc4ccccc4o3)cccc21] 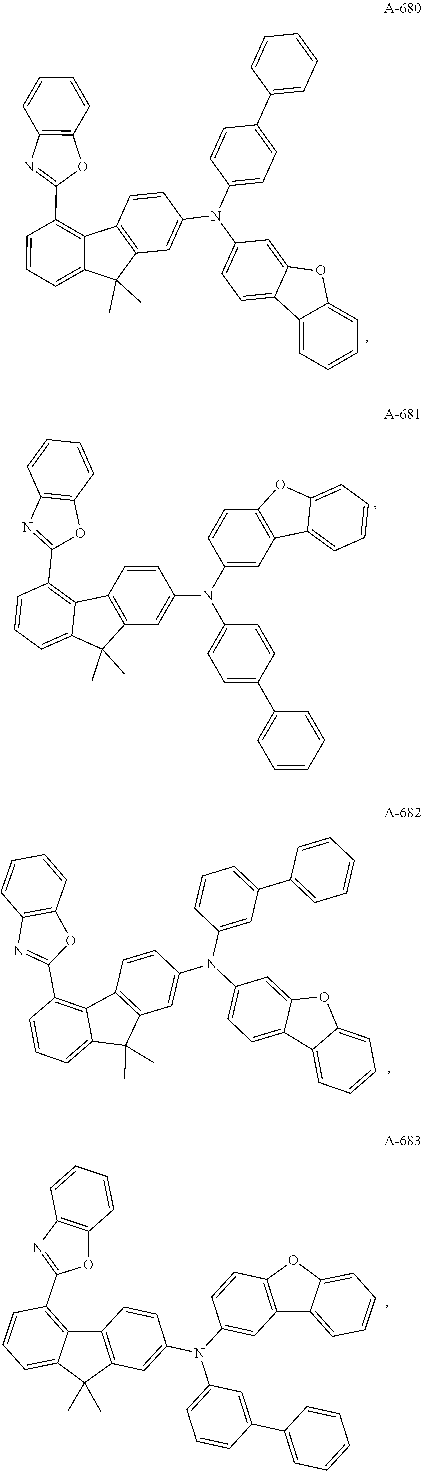 [SMILES: CC1(C)c2cc(N(c3ccc(-c4ccccc4)cc3)c3ccc4c(c3)oc3ccccc34)ccc2-c2c(-c3nc4ccccc4o3)cccc21 ; CC1(C)c2cc(N(c3ccc(-c4ccccc4)cc3)c3ccc4oc5ccccc5c4c3)ccc2-c2c(-c3nc4ccccc4o3)cccc21 ; CC1(C)c2cc(N(c3cccc(-c4ccccc4)c3)c3ccc4c(c3)oc3ccccc34)ccc2-c2c(-c3nc4ccccc4o3)cccc21 ; CC1(C)c2cc(N(c3cccc(-c4ccccc4)c3)c3ccc4oc5ccccc5c4c3)ccc2-c2c(-c3nc4ccccc4o3)cccc21] 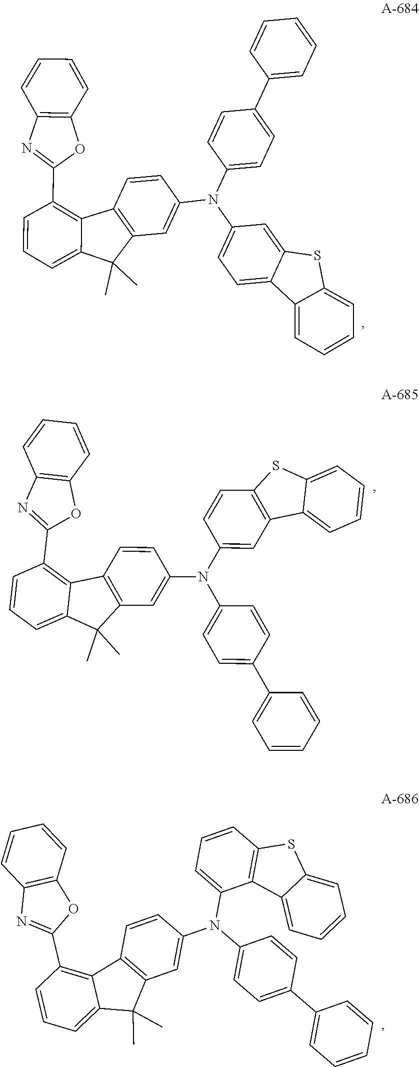 [SMILES: CC1(C)c2cc(N(c3ccc(-c4ccccc4)cc3)c3ccc4c(c3)sc3ccccc34)ccc2-c2c(-c3nc4ccccc4o3)cccc21 ; CC1(C)c2cc(N(c3ccc(-c4ccccc4)cc3)c3ccc4sc5ccccc5c4c3)ccc2-c2c(-c3nc4ccccc4o3)cccc21 ; CC1(C)c2cc(N(c3ccc(-c4ccccc4)cc3)c3cccc4sc5ccccc5c34)ccc2-c2c(-c3nc4ccccc4o3)cccc21] 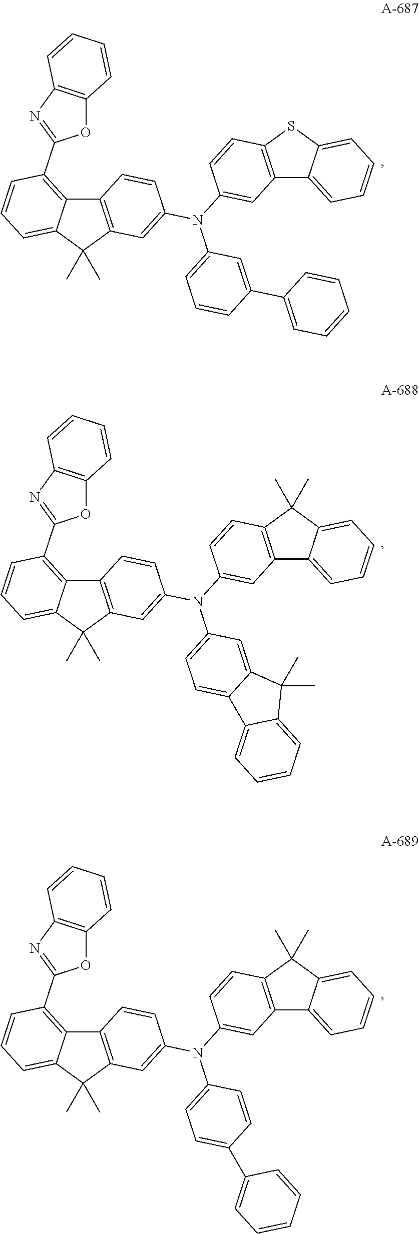 [SMILES: CC1(C)c2cc(N(c3cccc(-c4ccccc4)c3)c3ccc4sc5ccccc5c4c3)ccc2-c2c(-c3nc4ccccc4o3)cccc21 ; CC1(C)c2ccccc2-c2cc(N(c3ccc4c(c3)C(C)(C)c3ccccc3-4)c3ccc4c(c3)C(C)(C)c3cccc(-c5nc6ccccc6o5)c3-4)ccc21 ; CC1(C)c2ccccc2-c2cc(N(c3ccc(-c4ccccc4)cc3)c3ccc4c(c3)C(C)(C)c3cccc(-c5nc6ccccc6o5)c3-4)ccc21] 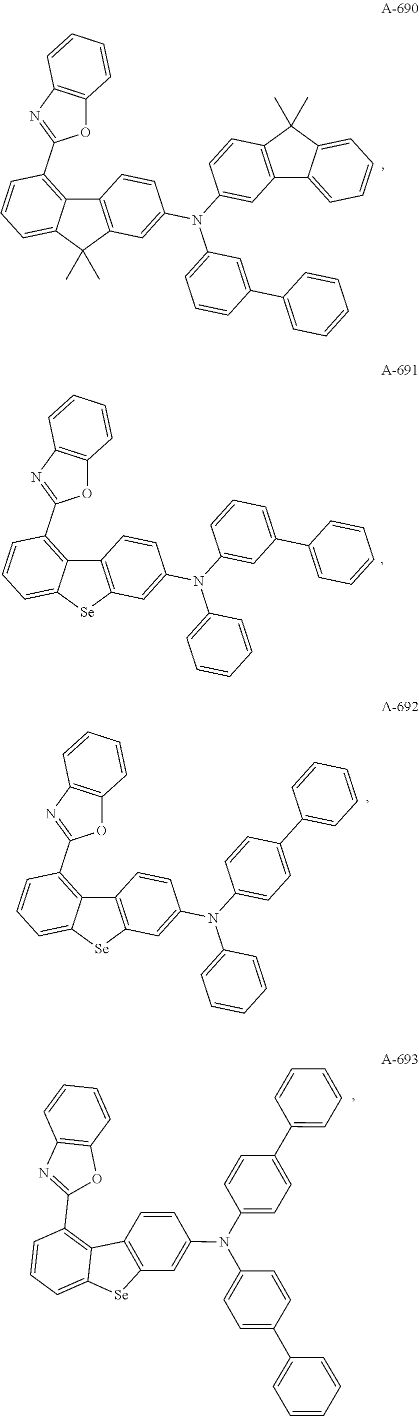 [SMILES: CC1(C)c2ccccc2-c2cc(N(c3cccc(-c4ccccc4)c3)c3ccc4c(c3)C(C)(C)c3cccc(-c5nc6ccccc6o5)c3-4)ccc21 ; c1ccc(-c2cccc(N(c3ccccc3)c3ccc4c(c3)[se]c3cccc(-c5nc6ccccc6o5)c34)c2)cc1 ; c1ccc(-c2ccc(N(c3ccccc3)c3ccc4c(c3)[se]c3cccc(-c5nc6ccccc6o5)c34)cc2)cc1 ; c1ccc(-c2ccc(N(c3ccc(-c4ccccc4)cc3)c3ccc4c(c3)[se]c3cccc(-c5nc6ccccc6o5)c34)cc2)cc1] 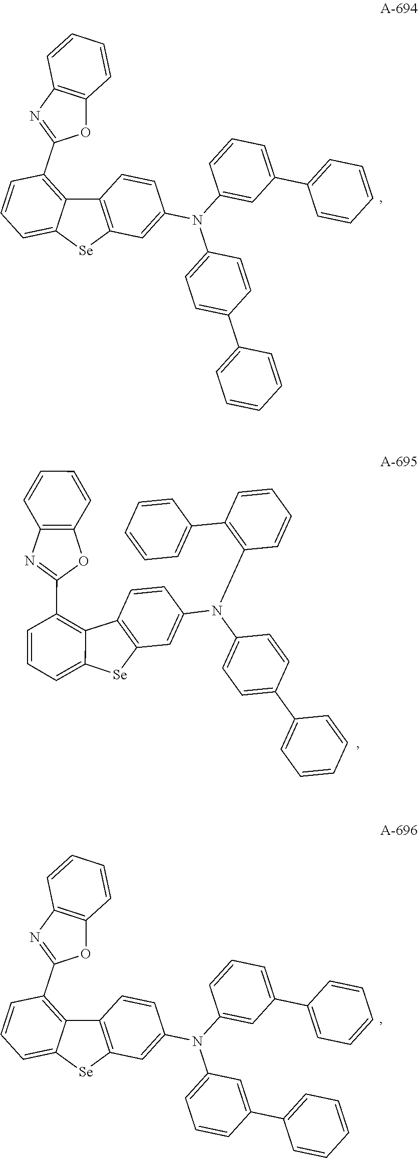 [SMILES: c1ccc(-c2ccc(N(c3cccc(-c4ccccc4)c3)c3ccc4c(c3)[se]c3cccc(-c5nc6ccccc6o5)c34)cc2)cc1 ; c1ccc(-c2ccc(N(Cc3ccccc3-c3ccccc3)c3ccc4c(c3)[se]c3cccc(-c5nc6ccccc6o5)c34)cc2)cc1 ; c1ccc(-c2cccc(N(c3cccc(-c4ccccc4)c3)c3ccc4c(c3)[se]c3cccc(-c5nc6ccccc6o5)c34)c2)cc1] 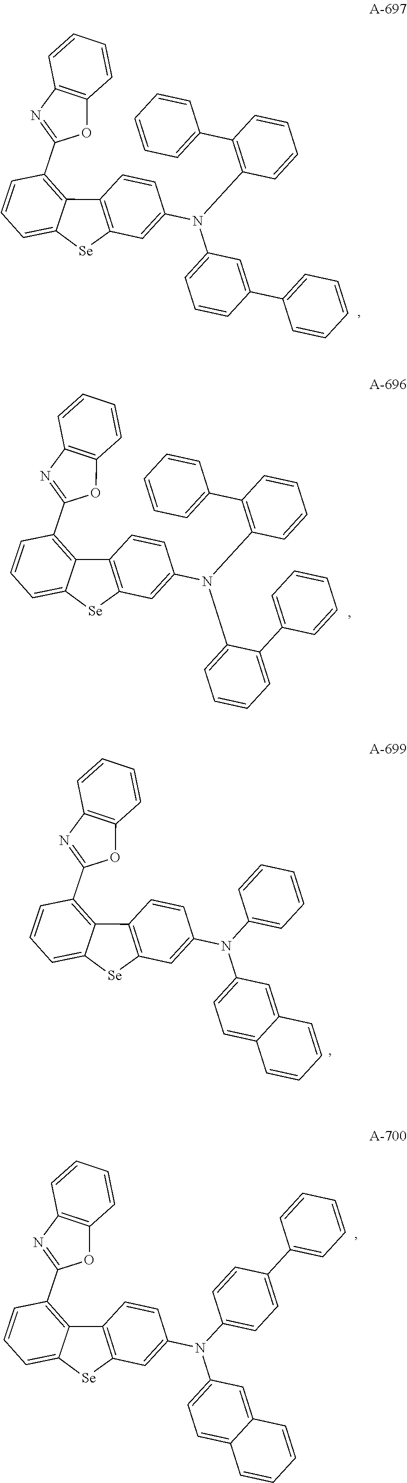 [SMILES: c1ccc(-c2cccc(N(Cc3ccccc3-c3ccccc3)c3ccc4c(c3)[se]c3cccc(-c5nc6ccccc6o5)c34)c2)cc1 ; c1ccc(-c2ccccc2CN(Cc2ccccc2-c2ccccc2)c2ccc3c(c2)[se]c2cccc(-c4nc5ccccc5o4)c23)cc1 ; c1ccc(N(c2ccc3ccccc3c2)c2ccc3c(c2)[se]c2cccc(-c4nc5ccccc5o4)c23)cc1 ; c1ccc(-c2ccc(N(c3ccc4ccccc4c3)c3ccc4c(c3)[se]c3cccc(-c5nc6ccccc6o5)c34)cc2)cc1] 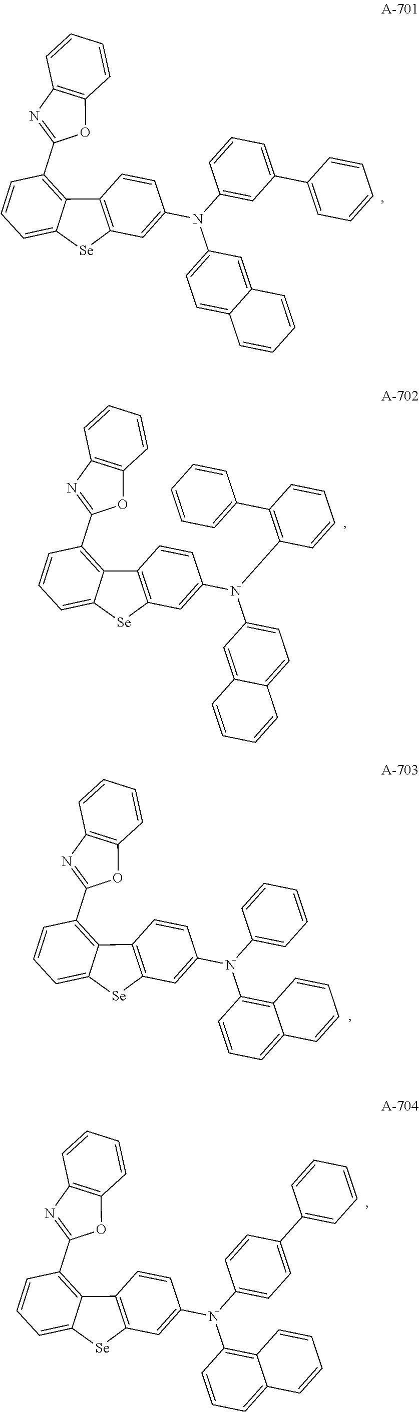 [SMILES: c1ccc(-c2cccc(N(c3ccc4ccccc4c3)c3ccc4c(c3)[se]c3cccc(-c5nc6ccccc6o5)c34)c2)cc1 ; c1ccc(-c2ccccc2CN(c2ccc3ccccc3c2)c2ccc3c(c2)[se]c2cccc(-c4nc5ccccc5o4)c23)cc1 ; c1ccc(N(c2ccc3c(c2)[se]c2cccc(-c4nc5ccccc5o4)c23)c2cccc3ccccc23)cc1 ; c1ccc(-c2ccc(N(c3ccc4c(c3)[se]c3cccc(-c5nc6ccccc6o5)c34)c3cccc4ccccc34)cc2)cc1] 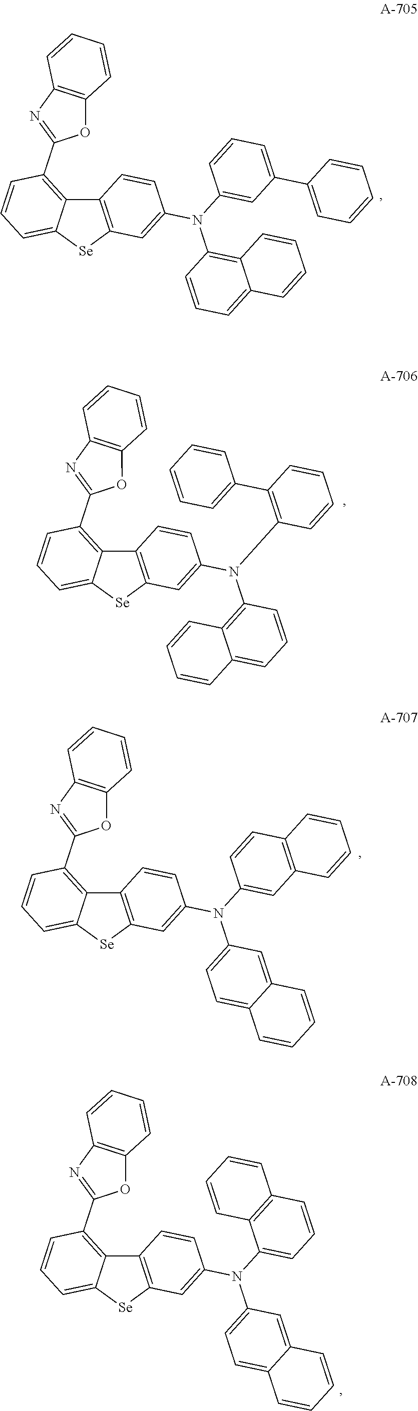 [SMILES: c1ccc(-c2cccc(N(c3ccc4c(c3)[se]c3cccc(-c5nc6ccccc6o5)c34)c3cccc4ccccc34)c2)cc1 ; c1ccc(-c2ccccc2CN(c2ccc3c(c2)[se]c2cccc(-c4nc5ccccc5o4)c23)c2cccc3ccccc23)cc1 ; c1ccc2cc(N(c3ccc4ccccc4c3)c3ccc4c(c3)[se]c3cccc(-c5nc6ccccc6o5)c34)ccc2c1 ; c1ccc2cc(N(c3ccc4c(c3)[se]c3cccc(-c5nc6ccccc6o5)c34)c3cccc4ccccc34)ccc2c1] 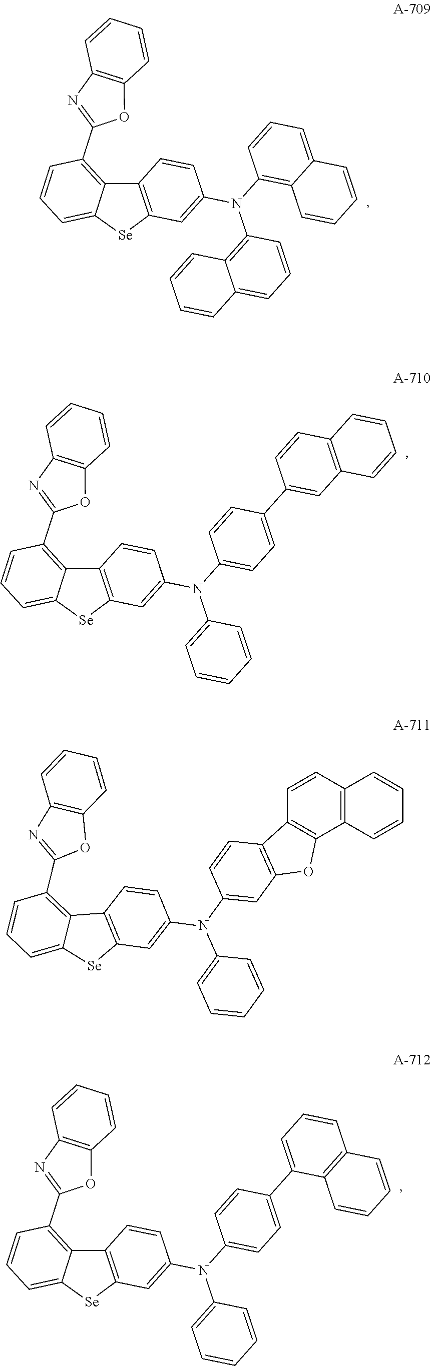 [SMILES: c1ccc2c(N(c3ccc4c(c3)[se]c3cccc(-c5nc6ccccc6o5)c34)c3cccc4ccccc34)cccc2c1 ; c1ccc(N(c2ccc(-c3ccc4ccccc4c3)cc2)c2ccc3c(c2)[se]c2cccc(-c4nc5ccccc5o4)c23)cc1 ; c1ccc(N(c2ccc3c(c2)oc2c4ccccc4ccc32)c2ccc3c(c2)[se]c2cccc(-c4nc5ccccc5o4)c23)cc1 ; c1ccc(N(c2ccc(-c3cccc4ccccc34)cc2)c2ccc3c(c2)[se]c2cccc(-c4nc5ccccc5o4)c23)cc1] 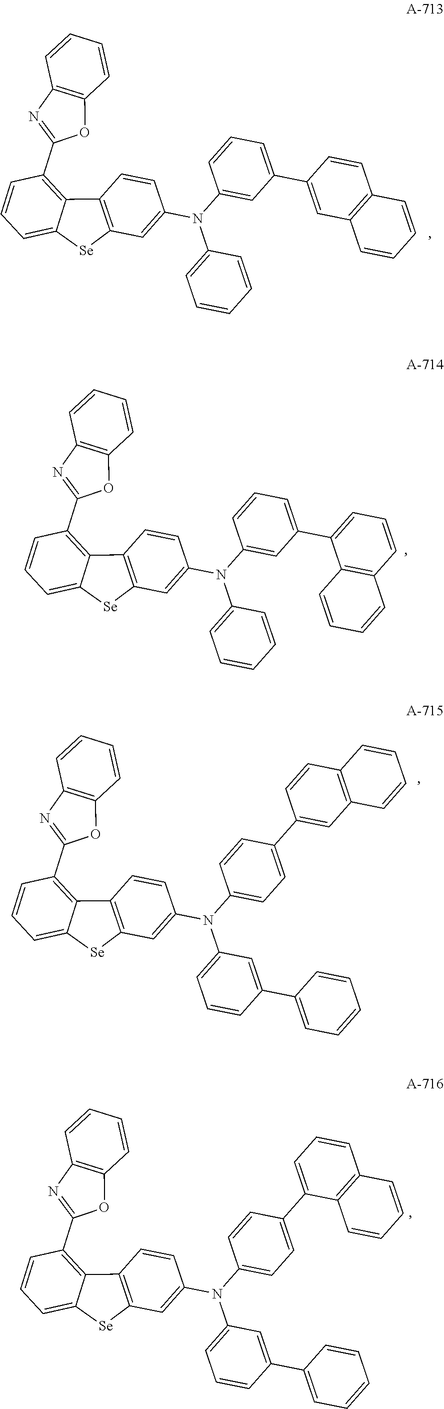 [SMILES: c1ccc(N(c2cccc(-c3ccc4ccccc4c3)c2)c2ccc3c(c2)[se]c2cccc(-c4nc5ccccc5o4)c23)cc1 ; c1ccc(N(c2cccc(-c3cccc4ccccc34)c2)c2ccc3c(c2)[se]c2cccc(-c4nc5ccccc5o4)c23)cc1 ; c1ccc(-c2cccc(N(c3ccc(-c4ccc5ccccc5c4)cc3)c3ccc4c(c3)[se]c3cccc(-c5nc6ccccc6o5)c34)c2)cc1 ; c1ccc(-c2cccc(N(c3ccc(-c4cccc5ccccc45)cc3)c3ccc4c(c3)[se]c3cccc(-c5nc6ccccc6o5)c34)c2)cc1] 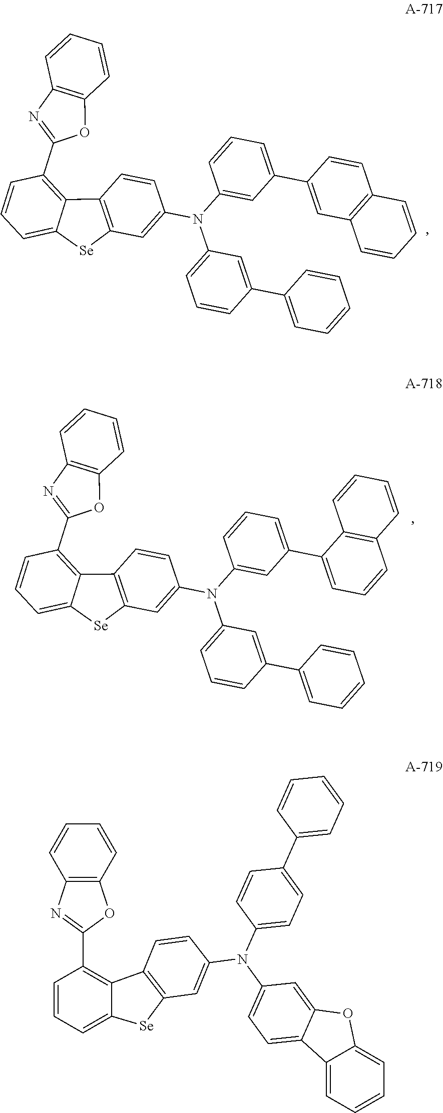 [SMILES: c1ccc(-c2cccc(N(c3cccc(-c4ccc5ccccc5c4)c3)c3ccc4c(c3)[se]c3cccc(-c5nc6ccccc6o5)c34)c2)cc1 ; c1ccc(-c2cccc(N(c3cccc(-c4cccc5ccccc45)c3)c3ccc4c(c3)[se]c3cccc(-c5nc6ccccc6o5)c34)c2)cc1 ; c1ccc(-c2ccc(N(c3ccc4c(c3)oc3ccccc34)c3ccc4c(c3)[se]c3cccc(-c5nc6ccccc6o5)c34)cc2)cc1] 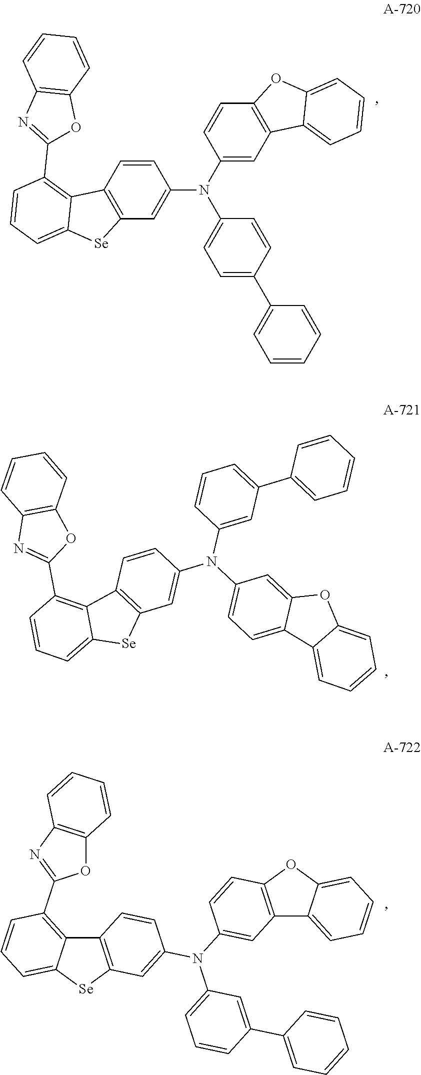 [SMILES: c1ccc(-c2ccc(N(c3ccc4c(c3)[se]c3cccc(-c5nc6ccccc6o5)c34)c3ccc4oc5ccccc5c4c3)cc2)cc1 ; c1ccc(-c2cccc(N(c3ccc4c(c3)oc3ccccc34)c3ccc4c(c3)[se]c3cccc(-c5nc6ccccc6o5)c34)c2)cc1 ; c1ccc(-c2cccc(N(c3ccc4c(c3)[se]c3cccc(-c5nc6ccccc6o5)c34)c3ccc4oc5ccccc5c4c3)c2)cc1] 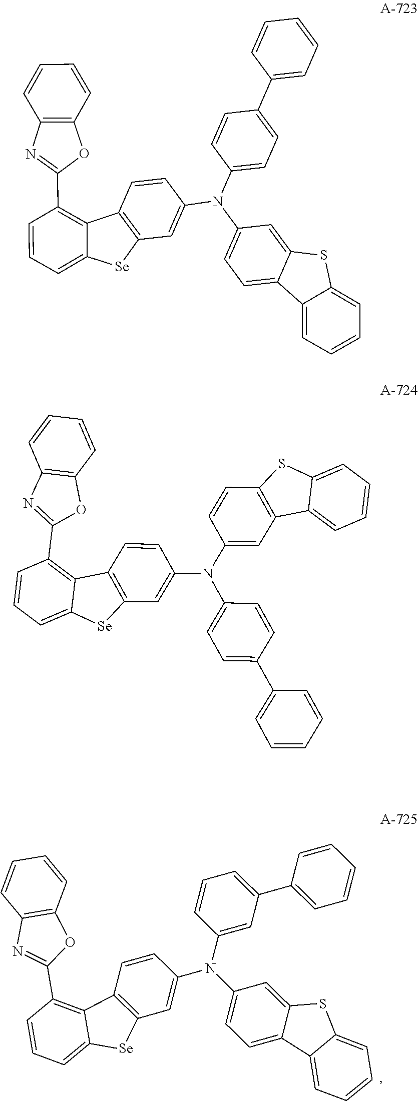 [SMILES: c1ccc(-c2ccc(N(c3ccc4c(c3)sc3ccccc34)c3ccc4c(c3)[se]c3cccc(-c5nc6ccccc6o5)c34)cc2)cc1 ; c1ccc(-c2ccc(N(c3ccc4c(c3)[se]c3cccc(-c5nc6ccccc6o5)c34)c3ccc4sc5ccccc5c4c3)cc2)cc1 ; c1ccc(-c2cccc(N(c3ccc4c(c3)sc3ccccc34)c3ccc4c(c3)[se]c3cccc(-c5nc6ccccc6o5)c34)c2)cc1] 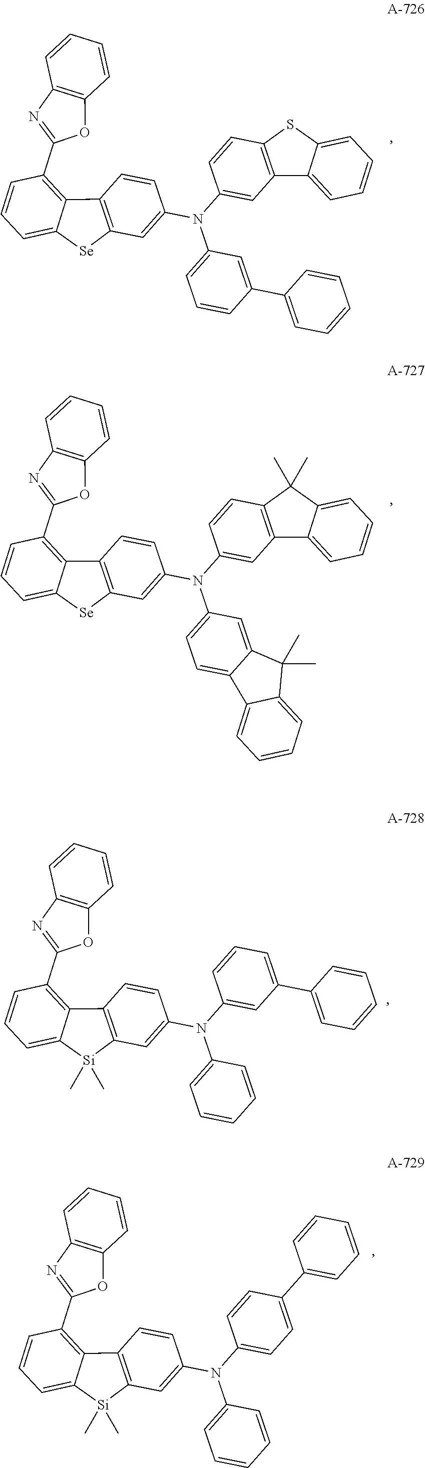 [SMILES: c1ccc(-c2cccc(N(c3ccc4c(c3)[se]c3cccc(-c5nc6ccccc6o5)c34)c3ccc4sc5ccccc5c4c3)c2)cc1 ; CC1(C)c2ccccc2-c2cc(N(c3ccc4c(c3)C(C)(C)c3ccccc3-4)c3ccc4c(c3)[se]c3cccc(-c5nc6ccccc6o5)c34)ccc21 ; C[Si]1(C)c2cc(N(c3ccccc3)c3cccc(-c4ccccc4)c3)ccc2-c2c(-c3nc4ccccc4o3)cccc21 ; C[Si]1(C)c2cc(N(c3ccccc3)c3ccc(-c4ccccc4)cc3)ccc2-c2c(-c3nc4ccccc4o3)cccc21] 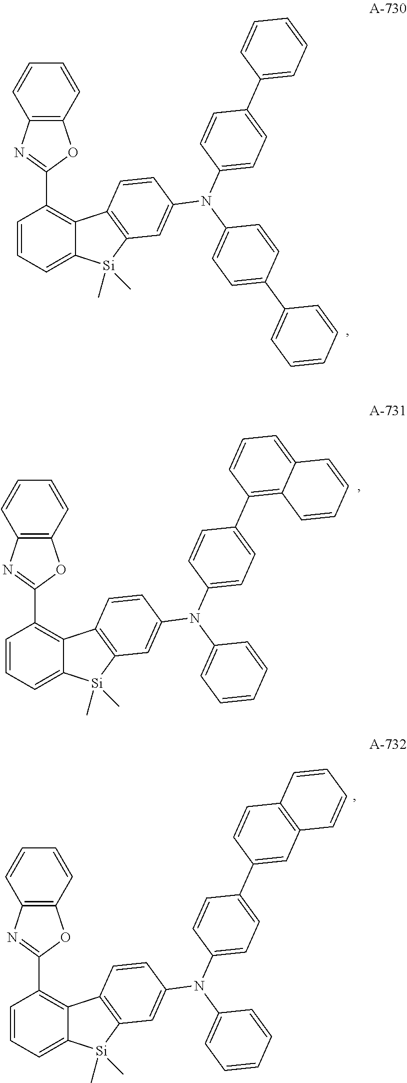 [SMILES: C[Si]1(C)c2cc(N(c3ccc(-c4ccccc4)cc3)c3ccc(-c4ccccc4)cc3)ccc2-c2c(-c3nc4ccccc4o3)cccc21 ; C[Si]1(C)c2cc(N(c3ccccc3)c3ccc(-c4cccc5ccccc45)cc3)ccc2-c2c(-c3nc4ccccc4o3)cccc21 ; C[Si]1(C)c2cc(N(c3ccccc3)c3ccc(-c4ccc5ccccc5c4)cc3)ccc2-c2c(-c3nc4ccccc4o3)cccc21] 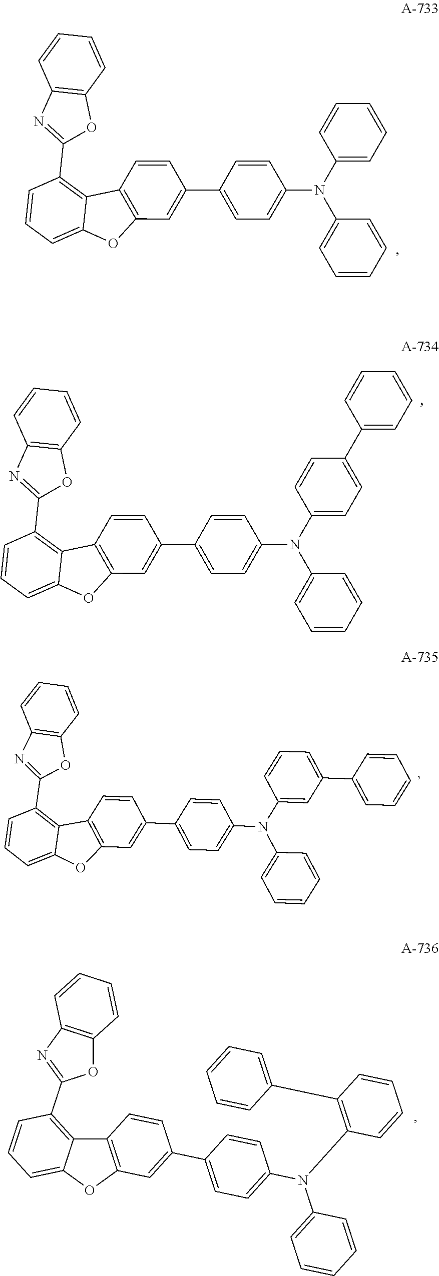 [SMILES: c1ccc(N(c2ccccc2)c2ccc(-c3ccc4c(c3)oc3cccc(-c5nc6ccccc6o5)c34)cc2)cc1 ; c1ccc(-c2ccc(N(c3ccccc3)c3ccc(-c4ccc5c(c4)oc4cccc(-c6nc7ccccc7o6)c45)cc3)cc2)cc1 ; c1ccc(-c2cccc(N(c3ccccc3)c3ccc(-c4ccc5c(c4)oc4cccc(-c6nc7ccccc7o6)c45)cc3)c2)cc1 ; c1ccc(Cc2ccccc2CN(c2ccccc2)c2ccc(-c3ccc4c(c3)oc3cccc(-c5nc6ccccc6o5)c34)cc2)cc1] 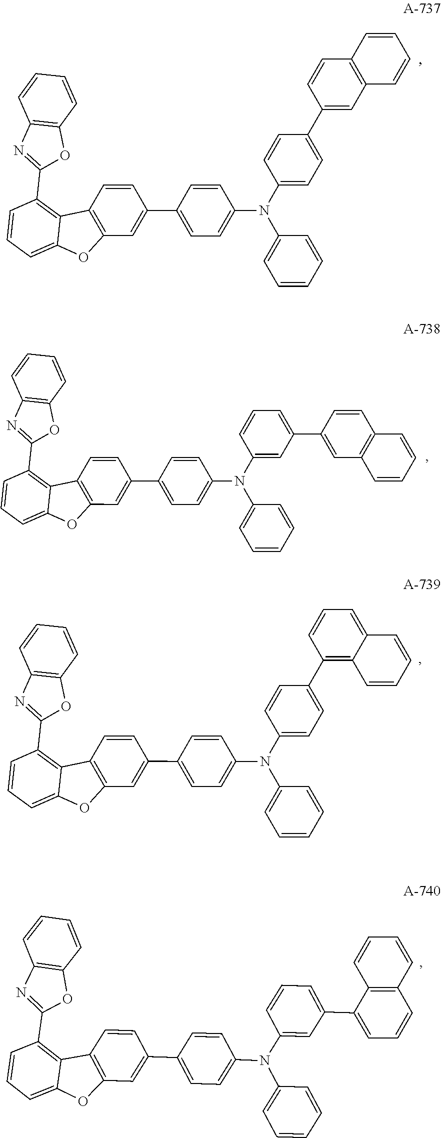 [SMILES: c1ccc(N(c2ccc(-c3ccc4ccccc4c3)cc2)c2ccc(-c3ccc4c(c3)oc3cccc(-c5nc6ccccc6o5)c34)cc2)cc1 ; c1ccc(N(c2ccc(-c3ccc4c(c3)oc3cccc(-c5nc6ccccc6o5)c34)cc2)c2cccc(-c3ccc4ccccc4c3)c2)cc1 ; c1ccc(N(c2ccc(-c3ccc4c(c3)oc3cccc(-c5nc6ccccc6o5)c34)cc2)c2ccc(-c3cccc4ccccc34)cc2)cc1 ; c1ccc(N(c2ccc(-c3ccc4c(c3)oc3cccc(-c5nc6ccccc6o5)c34)cc2)c2cccc(-c3cccc4ccccc34)c2)cc1] 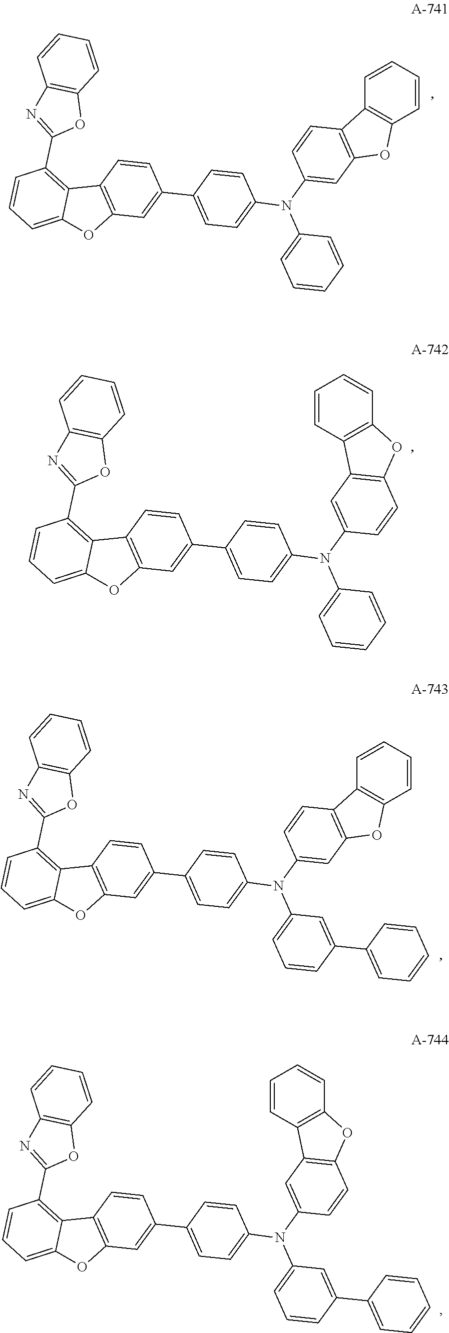 [SMILES: c1ccc(N(c2ccc(-c3ccc4c(c3)oc3cccc(-c5nc6ccccc6o5)c34)cc2)c2ccc3c(c2)oc2ccccc23)cc1 ; c1ccc(N(c2ccc(-c3ccc4c(c3)oc3cccc(-c5nc6ccccc6o5)c34)cc2)c2ccc3oc4ccccc4c3c2)cc1 ; c1ccc(-c2cccc(N(c3ccc(-c4ccc5c(c4)oc4cccc(-c6nc7ccccc7o6)c45)cc3)c3ccc4c(c3)oc3ccccc34)c2)cc1 ; c1ccc(-c2cccc(N(c3ccc(-c4ccc5c(c4)oc4cccc(-c6nc7ccccc7o6)c45)cc3)c3ccc4oc5ccccc5c4c3)c2)cc1] 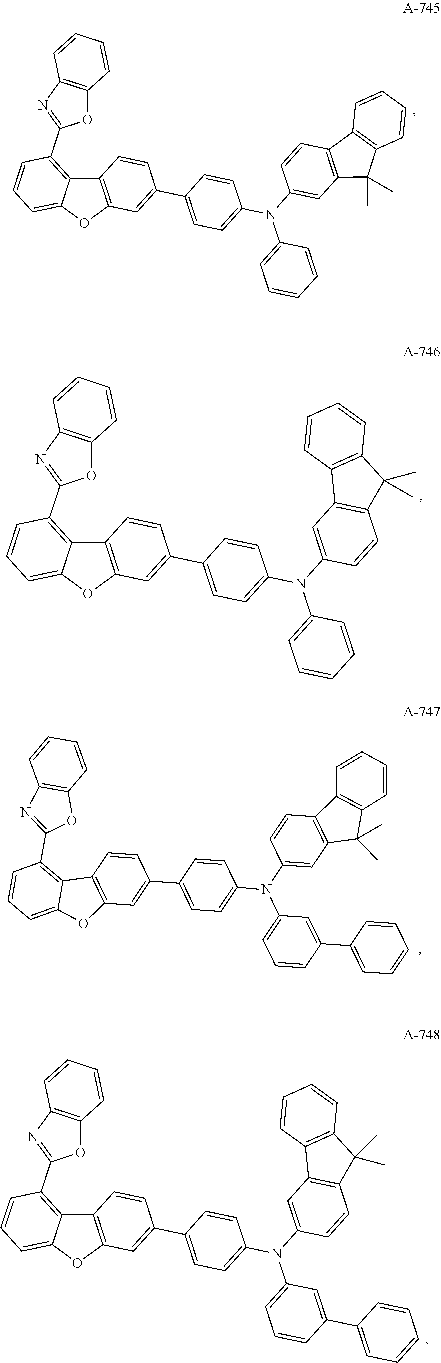 [SMILES: CC1(C)c2ccccc2-c2ccc(N(c3ccccc3)c3ccc(-c4ccc5c(c4)oc4cccc(-c6nc7ccccc7o6)c45)cc3)cc21 ; CC1(C)c2ccccc2-c2cc(N(c3ccccc3)c3ccc(-c4ccc5c(c4)oc4cccc(-c6nc7ccccc7o6)c45)cc3)ccc21 ; CC1(C)c2ccccc2-c2ccc(N(c3ccc(-c4ccc5c(c4)oc4cccc(-c6nc7ccccc7o6)c45)cc3)c3cccc(-c4ccccc4)c3)cc21 ; CC1(C)c2ccccc2-c2cc(N(c3ccc(-c4ccc5c(c4)oc4cccc(-c6nc7ccccc7o6)c45)cc3)c3cccc(-c4ccccc4)c3)ccc21] 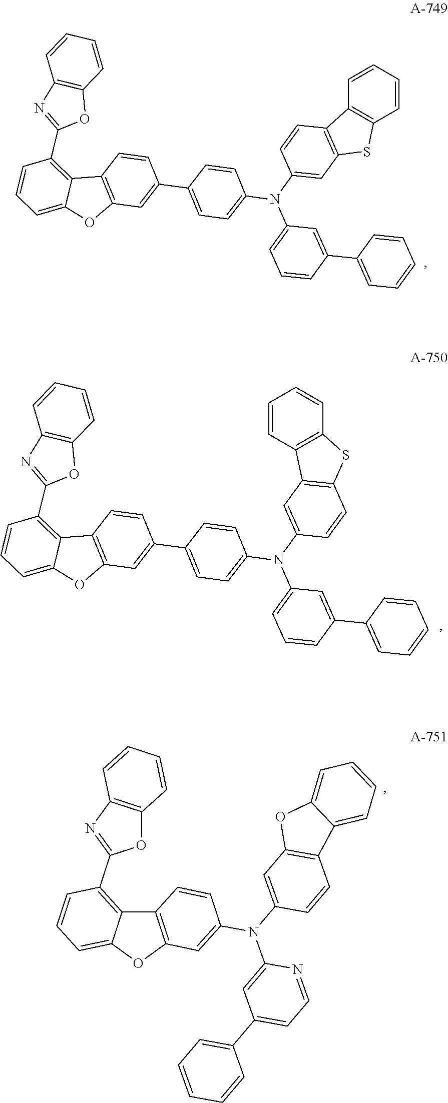 [SMILES: c1ccc(-c2cccc(N(c3ccc(-c4ccc5c(c4)oc4cccc(-c6nc7ccccc7o6)c45)cc3)c3ccc4c(c3)sc3ccccc34)c2)cc1 ; c1ccc(-c2cccc(N(c3ccc(-c4ccc5c(c4)oc4cccc(-c6nc7ccccc7o6)c45)cc3)c3ccc4sc5ccccc5c4c3)c2)cc1 ; c1ccc(-c2ccnc(N(c3ccc4c(c3)oc3ccccc34)c3ccc4c(c3)oc3cccc(-c5nc6ccccc6o5)c34)c2)cc1] 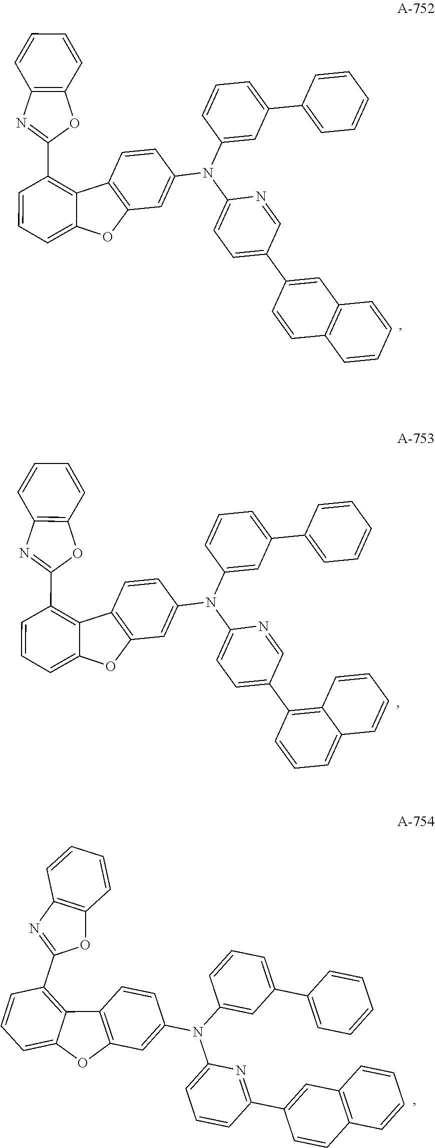 [SMILES: c1ccc(-c2cccc(N(c3ccc4c(c3)oc3cccc(-c5nc6ccccc6o5)c34)c3ccc(-c4ccc5ccccc5c4)cn3)c2)cc1 ; c1ccc(-c2cccc(N(c3ccc4c(c3)oc3cccc(-c5nc6ccccc6o5)c34)c3ccc(-c4cccc5ccccc45)cn3)c2)cc1 ; c1ccc(-c2cccc(N(c3ccc4c(c3)oc3cccc(-c5nc6ccccc6o5)c34)c3cccc(-c4ccc5ccccc5c4)n3)c2)cc1] 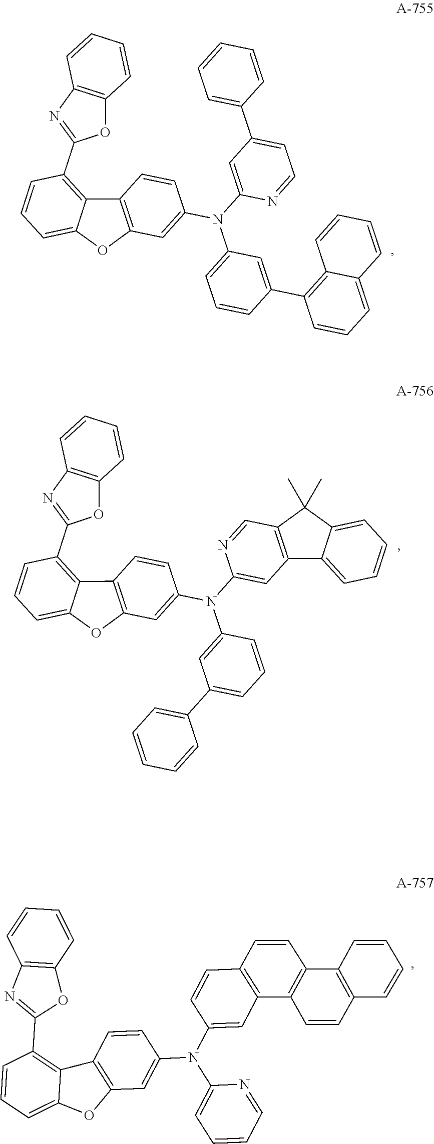 [SMILES: c1ccc(-c2ccnc(N(c3cccc(-c4cccc5ccccc45)c3)c3ccc4c(c3)oc3cccc(-c5nc6ccccc6o5)c34)c2)cc1 ; CC1(C)c2ccccc2-c2cc(N(c3cccc(-c4ccccc4)c3)c3ccc4c(c3)oc3cccc(-c5nc6ccccc6o5)c34)ncc21 ; c1ccc(N(c2ccc3c(c2)oc2cccc(-c4nc5ccccc5o4)c23)c2ccc3ccc4c5ccccc5ccc4c3c2)nc1] 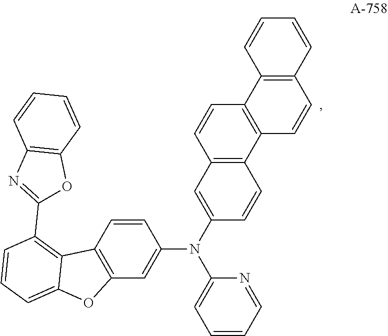 [SMILES: c1ccc(N(c2ccc3c(ccc4c5ccccc5ccc34)c2)c2ccc3c(c2)oc2cccc(-c4nc5ccccc5o4)c23)nc1] 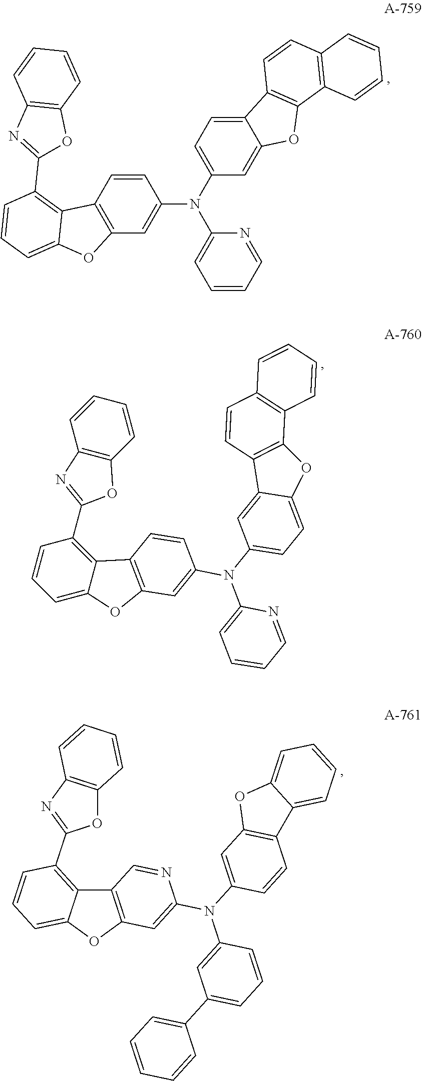 [SMILES: c1ccc(N(c2ccc3c(c2)oc2c4ccccc4ccc32)c2ccc3c(c2)oc2cccc(-c4nc5ccccc5o4)c23)nc1 ; c1ccc(N(c2ccc3c(c2)oc2cccc(-c4nc5ccccc5o4)c23)c2ccc3oc4c5ccccc5ccc4c3c2)nc1 ; c1ccc(-c2cccc(N(c3ccc4c(c3)oc3ccccc34)c3cc4oc5cccc(-c6nc7ccccc7o6)c5c4cn3)c2)cc1] 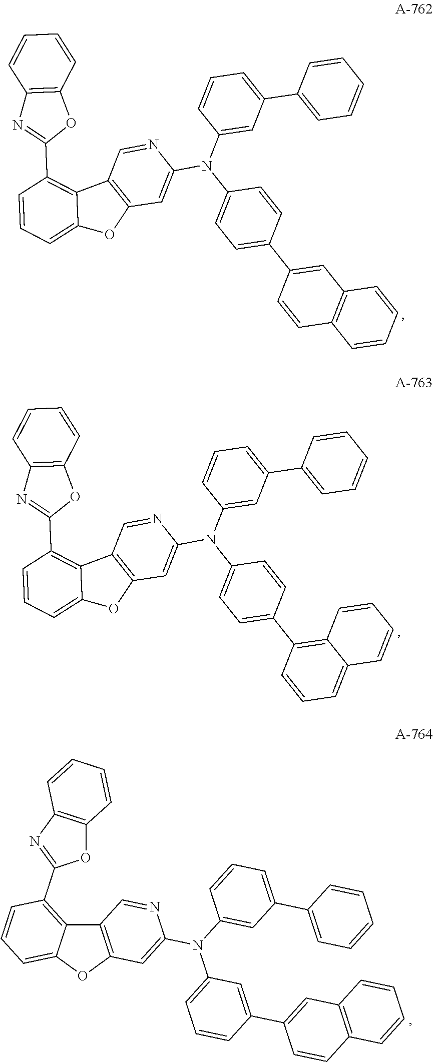 [SMILES: c1ccc(-c2cccc(N(c3ccc(-c4ccc5ccccc5c4)cc3)c3cc4oc5cccc(-c6nc7ccccc7o6)c5c4cn3)c2)cc1 ; c1ccc(-c2cccc(N(c3ccc(-c4cccc5ccccc45)cc3)c3cc4oc5cccc(-c6nc7ccccc7o6)c5c4cn3)c2)cc1 ; c1ccc(-c2cccc(N(c3cccc(-c4ccc5ccccc5c4)c3)c3cc4oc5cccc(-c6nc7ccccc7o6)c5c4cn3)c2)cc1] 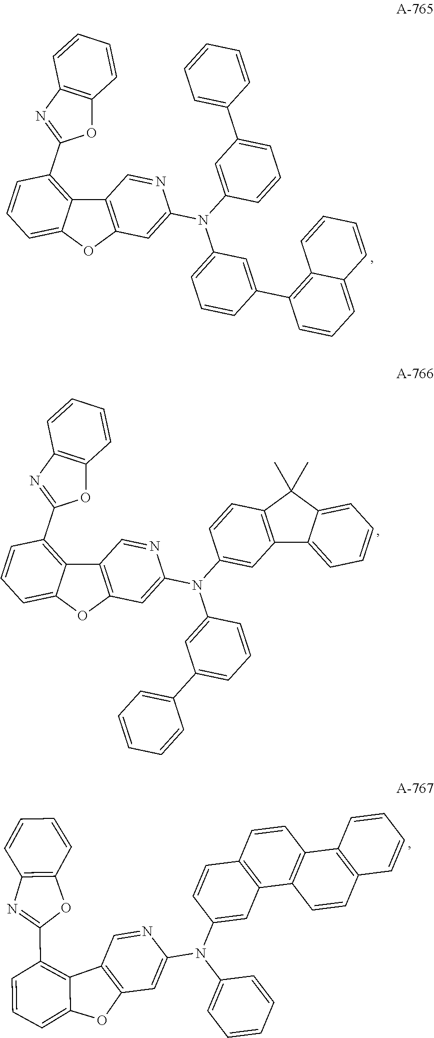 [SMILES: c1ccc(-c2cccc(N(c3cccc(-c4cccc5ccccc45)c3)c3cc4oc5cccc(-c6nc7ccccc7o6)c5c4cn3)c2)cc1 ; CC1(C)c2ccccc2-c2cc(N(c3cccc(-c4ccccc4)c3)c3cc4oc5cccc(-c6nc7ccccc7o6)c5c4cn3)ccc21 ; c1ccc(N(c2ccc3ccc4c5ccccc5ccc4c3c2)c2cc3oc4cccc(-c5nc6ccccc6o5)c4c3cn2)cc1] 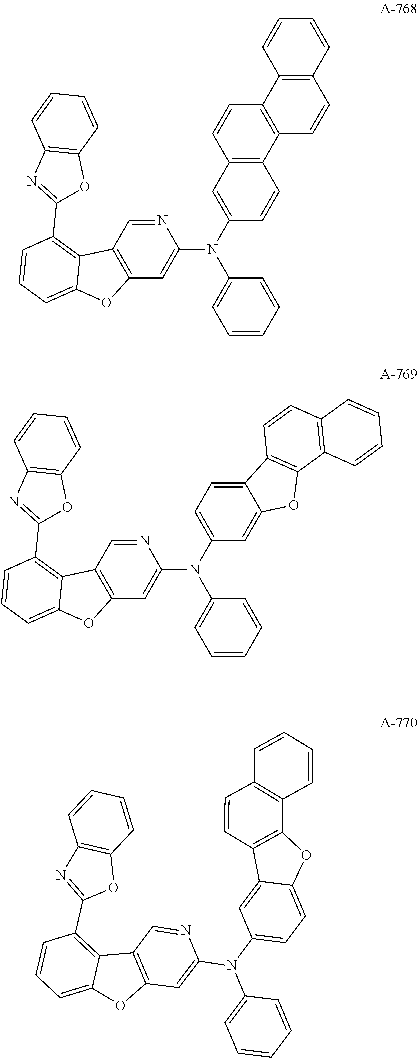 [SMILES: c1ccc(N(c2ccc3c(ccc4c5ccccc5ccc34)c2)c2cc3oc4cccc(-c5nc6ccccc6o5)c4c3cn2)cc1 ; c1ccc(N(c2ccc3c(c2)oc2c4ccccc4ccc32)c2cc3oc4cccc(-c5nc6ccccc6o5)c4c3cn2)cc1 ; c1ccc(N(c2ccc3oc4c5ccccc5ccc4c3c2)c2cc3oc4cccc(-c5nc6ccccc6o5)c4c3cn2)cc1] 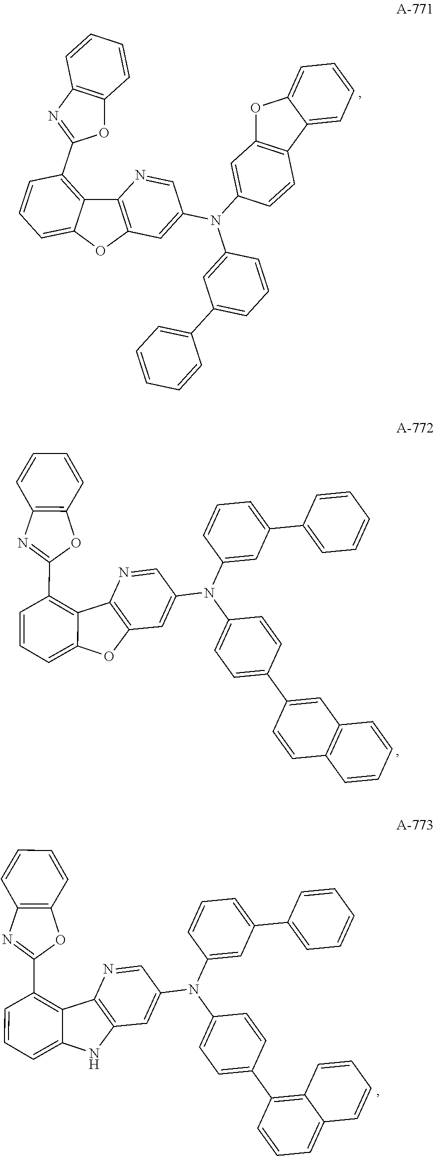 [SMILES: c1ccc(-c2cccc(N(c3ccc4c(c3)oc3ccccc34)c3cnc4c(c3)oc3cccc(-c5nc6ccccc6o5)c34)c2)cc1 ; c1ccc(-c2cccc(N(c3ccc(-c4ccc5ccccc5c4)cc3)c3cnc4c(c3)oc3cccc(-c5nc6ccccc6o5)c34)c2)cc1 ; c1ccc(-c2cccc(N(c3ccc(-c4cccc5ccccc45)cc3)c3cnc4c(c3)[nH]c3cccc(-c5nc6ccccc6o5)c34)c2)cc1] 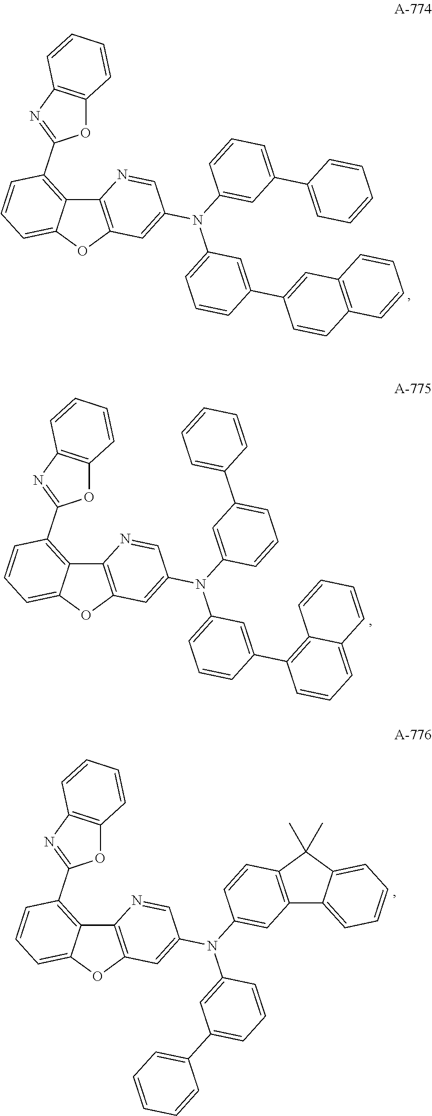 [SMILES: c1ccc(-c2cccc(N(c3cccc(-c4ccc5ccccc5c4)c3)c3cnc4c(c3)oc3cccc(-c5nc6ccccc6o5)c34)c2)cc1 ; c1ccc(-c2cccc(N(c3cccc(-c4cccc5ccccc45)c3)c3cnc4c(c3)oc3cccc(-c5nc6ccccc6o5)c34)c2)cc1 ; CC1(C)c2ccccc2-c2cc(N(c3cccc(-c4ccccc4)c3)c3cnc4c(c3)oc3cccc(-c5nc6ccccc6o5)c34)ccc21] 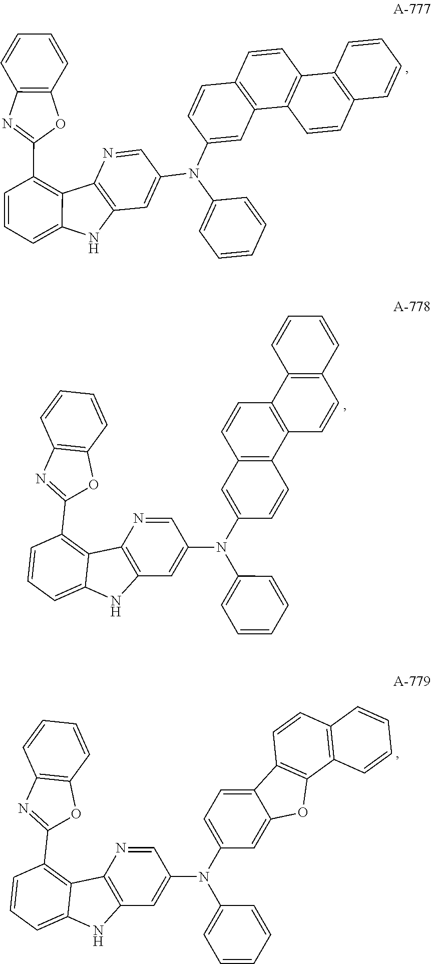 [SMILES: c1ccc(N(c2cnc3c(c2)[nH]c2cccc(-c4nc5ccccc5o4)c23)c2ccc3ccc4c5ccccc5ccc4c3c2)cc1 ; c1ccc(N(c2ccc3c(ccc4c5ccccc5ccc34)c2)c2cnc3c(c2)[nH]c2cccc(-c4nc5ccccc5o4)c23)cc1 ; c1ccc(N(c2cnc3c(c2)[nH]c2cccc(-c4nc5ccccc5o4)c23)c2ccc3c(c2)oc2c4ccccc4ccc32)cc1] 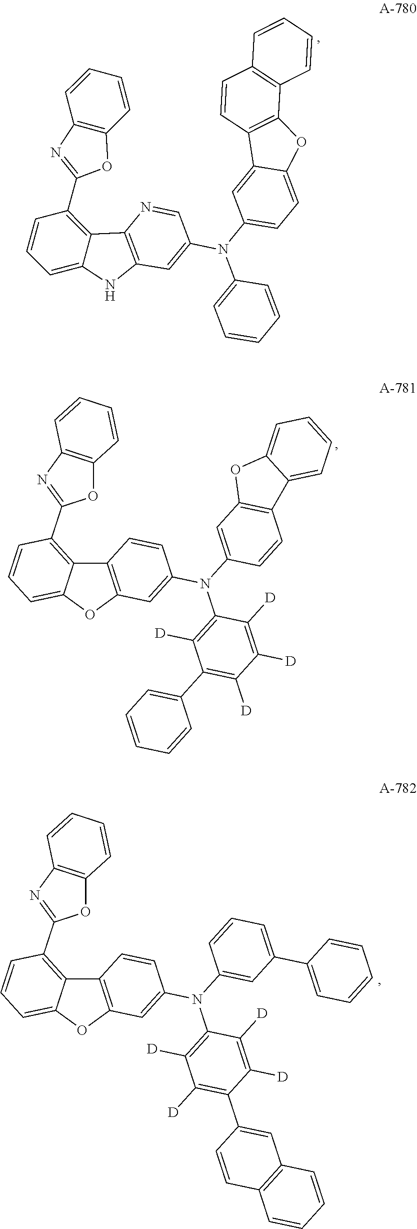 [SMILES: c1ccc(N(c2cnc3c(c2)[nH]c2cccc(-c4nc5ccccc5o4)c23)c2ccc3oc4c5ccccc5ccc4c3c2)cc1 ; [2H]c1c([2H])c(-c2ccccc2)c([2H])c(N(c2ccc3c(c2)oc2ccccc23)c2ccc3c(c2)oc2cccc(-c4nc5ccccc5o4)c23)c1[2H] ; [2H]c1c([2H])c(N(c2cccc(-c3ccccc3)c2)c2ccc3c(c2)oc2cccc(-c4nc5ccccc5o4)c23)c([2H])c([2H])c1-c1ccc2ccccc2c1] 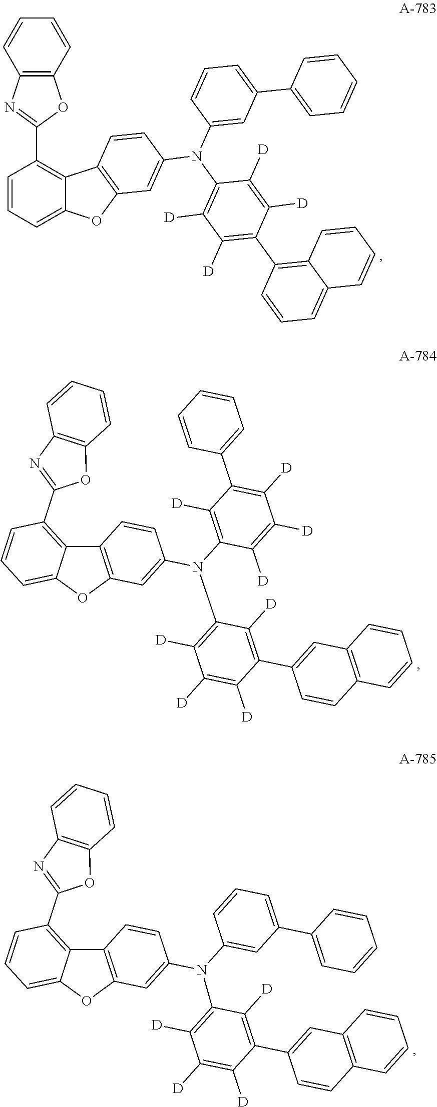 [SMILES: [2H]c1c([2H])c(N(c2cccc(-c3ccccc3)c2)c2ccc3c(c2)oc2cccc(-c4nc5ccccc5o4)c23)c([2H])c([2H])c1-c1cccc2ccccc12 ; [2H]c1c([2H])c(-c2ccccc2)c([2H])c(N(c2ccc3c(c2)oc2cccc(-c4nc5ccccc5o4)c23)c2c([2H])c([2H])c([2H])c(-c3ccc4ccccc4c3)c2[2H])c1[2H] ; [2H]c1c([2H])c(-c2ccc3ccccc3c2)c([2H])c(N(c2cccc(-c3ccccc3)c2)c2ccc3c(c2)oc2cccc(-c4nc5ccccc5o4)c23)c1[2H]] 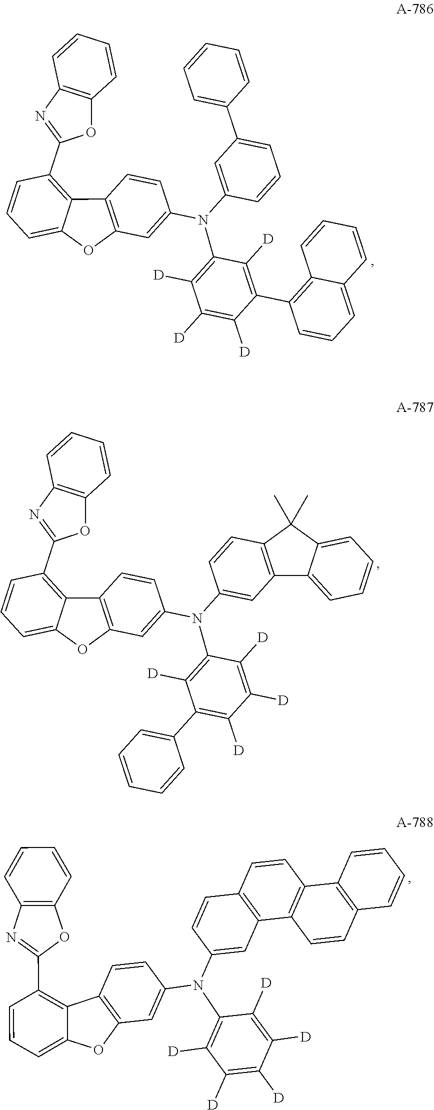 [SMILES: [2H]c1c([2H])c(-c2cccc3ccccc23)c([2H])c(N(c2cccc(-c3ccccc3)c2)c2ccc3c(c2)oc2cccc(-c4nc5ccccc5o4)c23)c1[2H] ; [2H]c1c([2H])c(-c2ccccc2)c([2H])c(N(c2ccc3c(c2)-c2ccccc2C3(C)C)c2ccc3c(c2)oc2cccc(-c4nc5ccccc5o4)c23)c1[2H] ; [2H]c1c([2H])c([2H])c(N(c2ccc3c(c2)oc2cccc(-c4nc5ccccc5o4)c23)c2ccc3ccc4c5ccccc5ccc4c3c2)c([2H])c1[2H]] 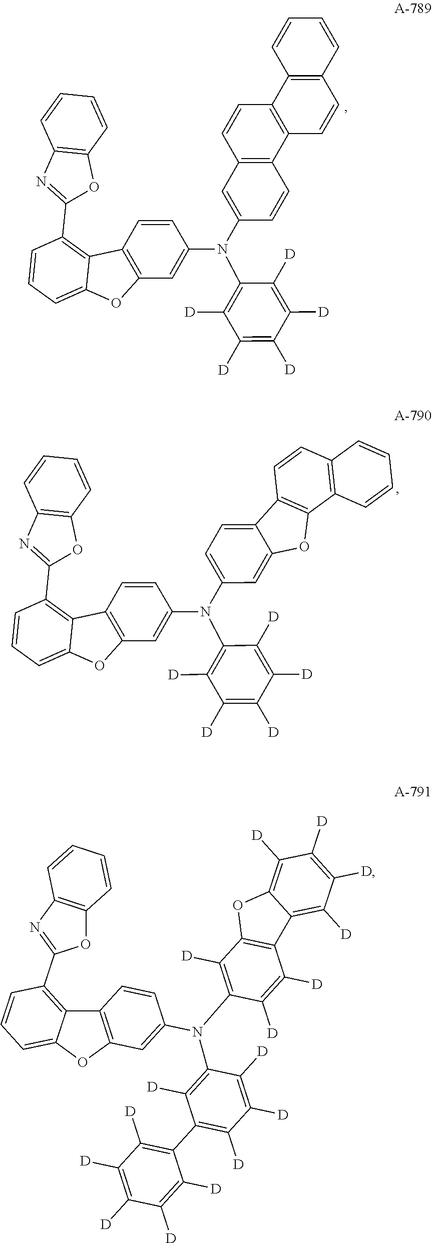 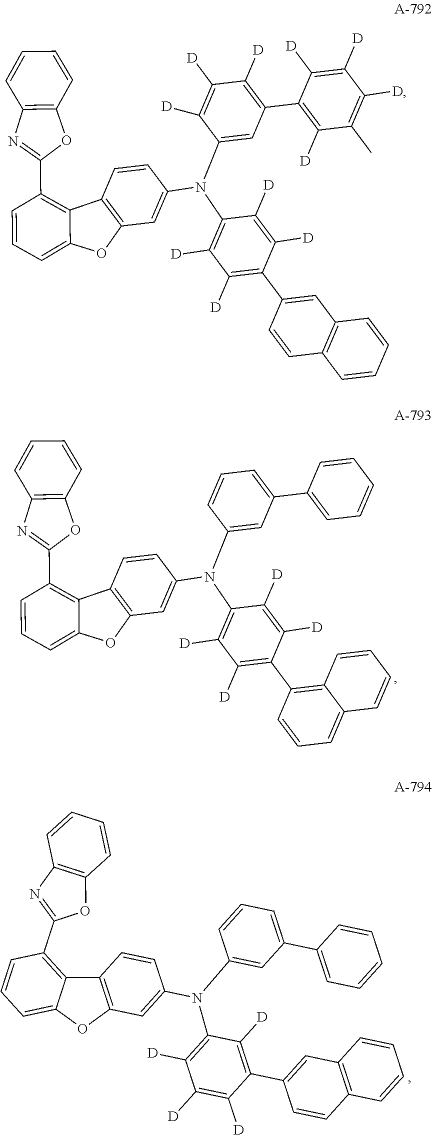 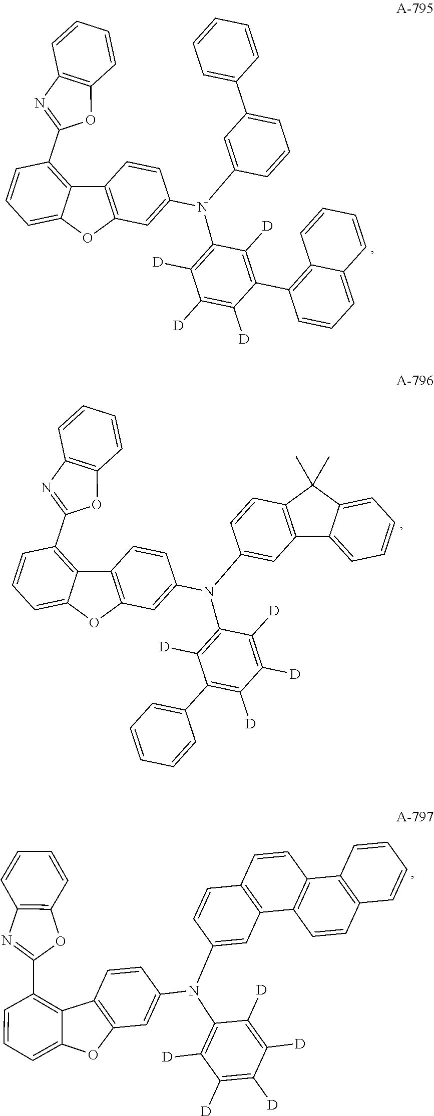 [SMILES: [2H]c1c([2H])c(-c2cccc3ccccc23)c([2H])c(N(c2cccc(-c3ccccc3)c2)c2ccc3c(c2)oc2cccc(-c4nc5ccccc5o4)c23)c1[2H] ; [2H]c1c([2H])c(-c2ccccc2)c([2H])c(N(c2ccc3c(c2)-c2ccccc2C3(C)C)c2ccc3c(c2)oc2cccc(-c4nc5ccccc5o4)c23)c1[2H] ; [2H]c1c([2H])c([2H])c(N(c2ccc3c(c2)oc2cccc(-c4nc5ccccc5o4)c23)c2ccc3ccc4c5ccccc5ccc4c3c2)c([2H])c1[2H]] 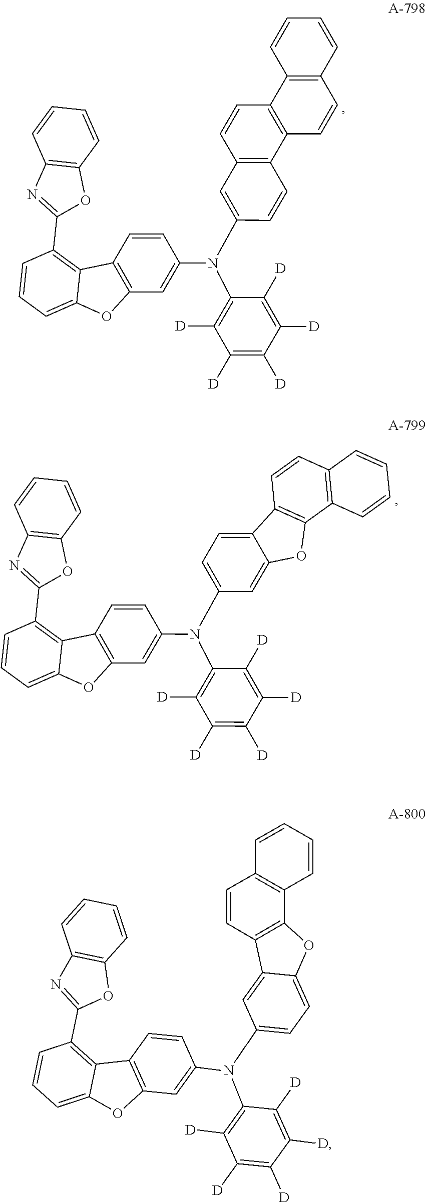 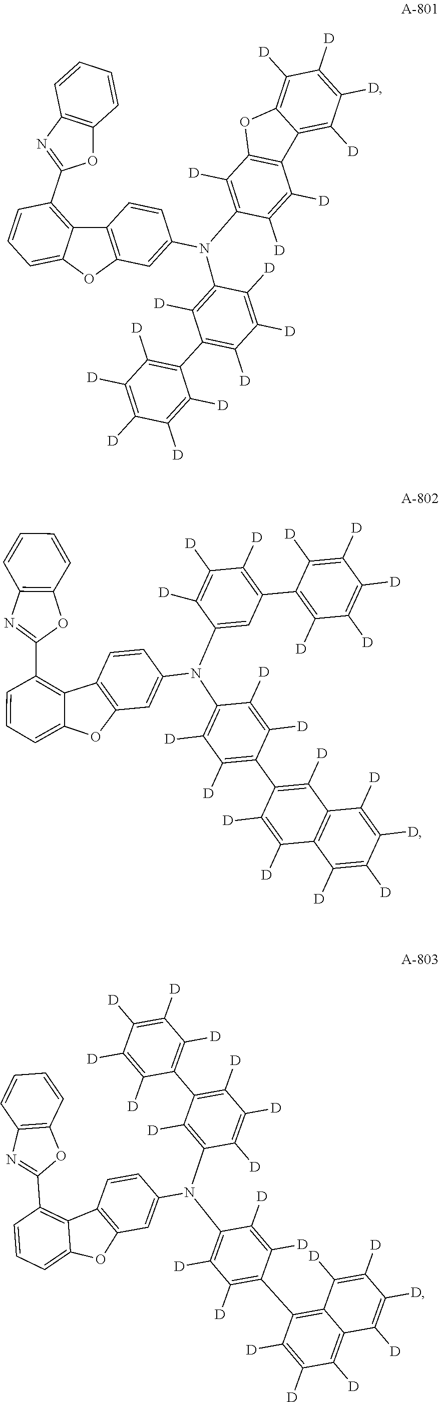 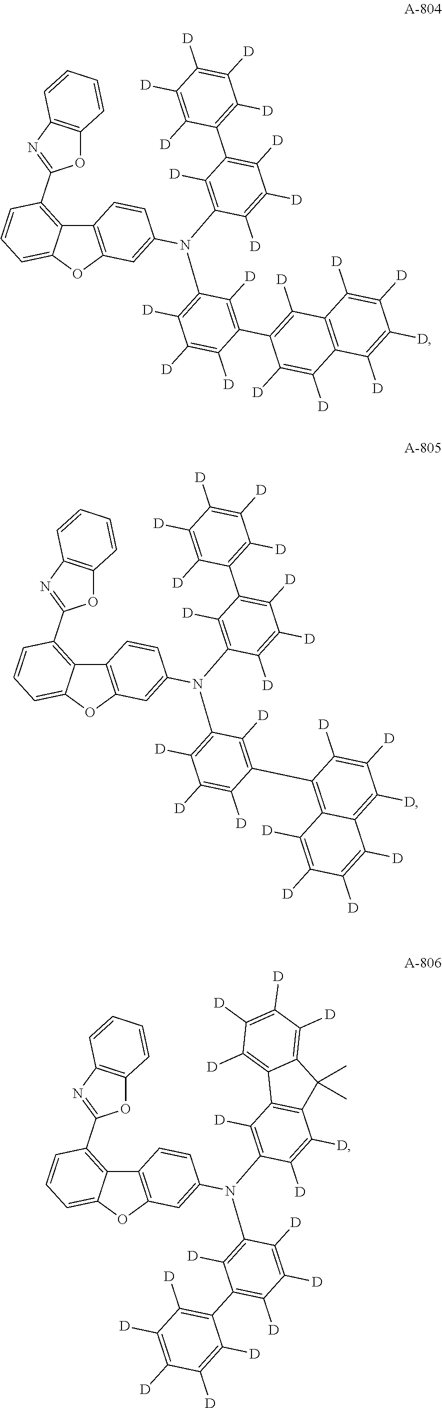 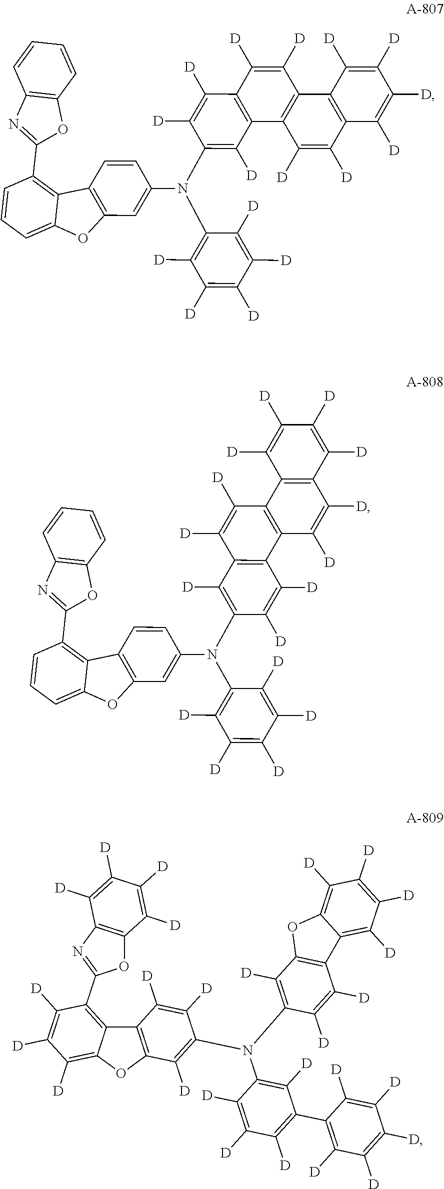 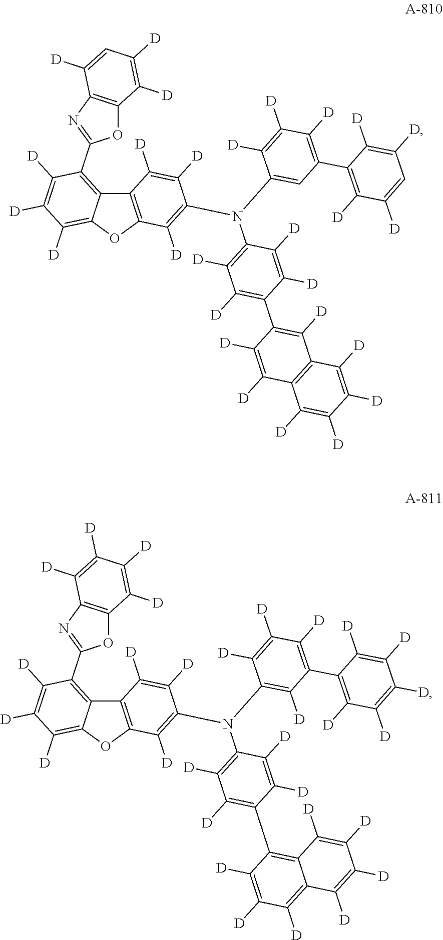 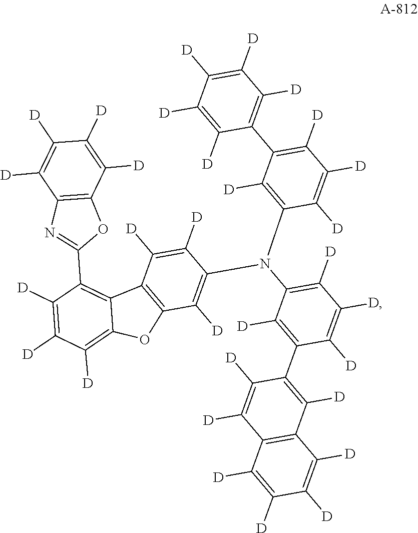 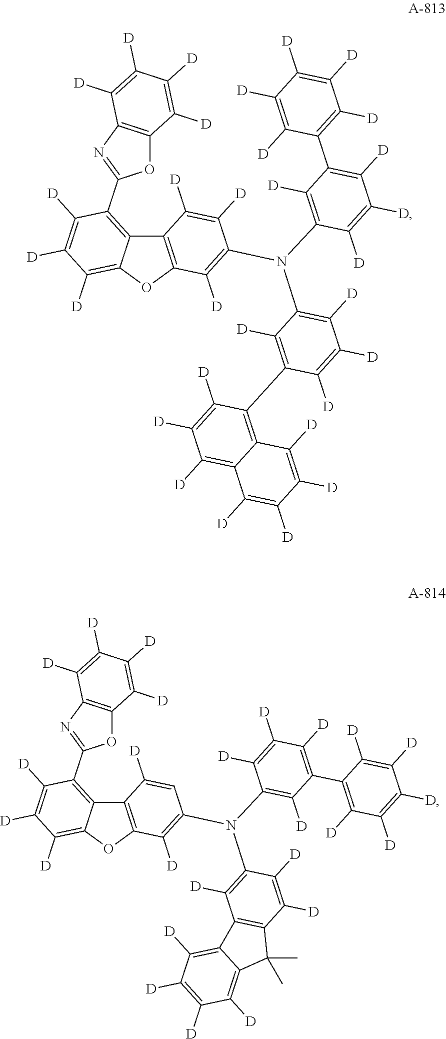 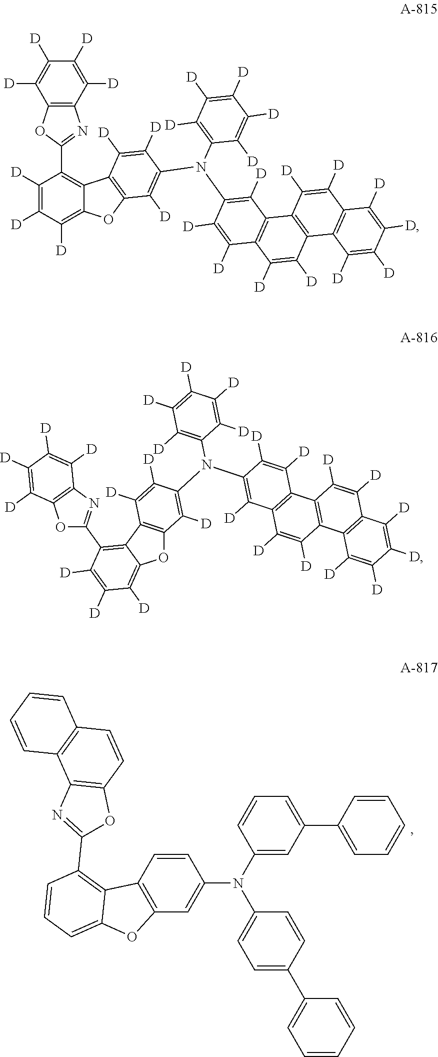 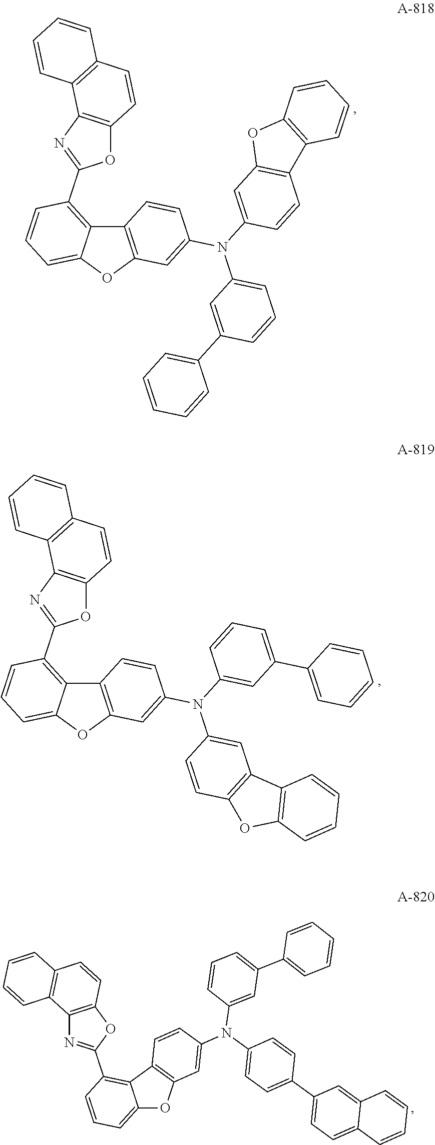 [SMILES: c1ccc(-c2cccc(N(c3ccc4c(c3)oc3ccccc34)c3ccc4c(c3)oc3cccc(-c5nc6c(ccc7ccccc76)o5)c34)c2)cc1 ; c1ccc(-c2cccc(N(c3ccc4c(c3)oc3cccc(-c5nc6c(ccc7ccccc76)o5)c34)c3ccc4oc5ccccc5c4c3)c2)cc1 ; c1ccc(-c2cccc(N(c3ccc(-c4ccc5ccccc5c4)cc3)c3ccc4c(c3)oc3cccc(-c5nc6c(ccc7ccccc76)o5)c34)c2)cc1] 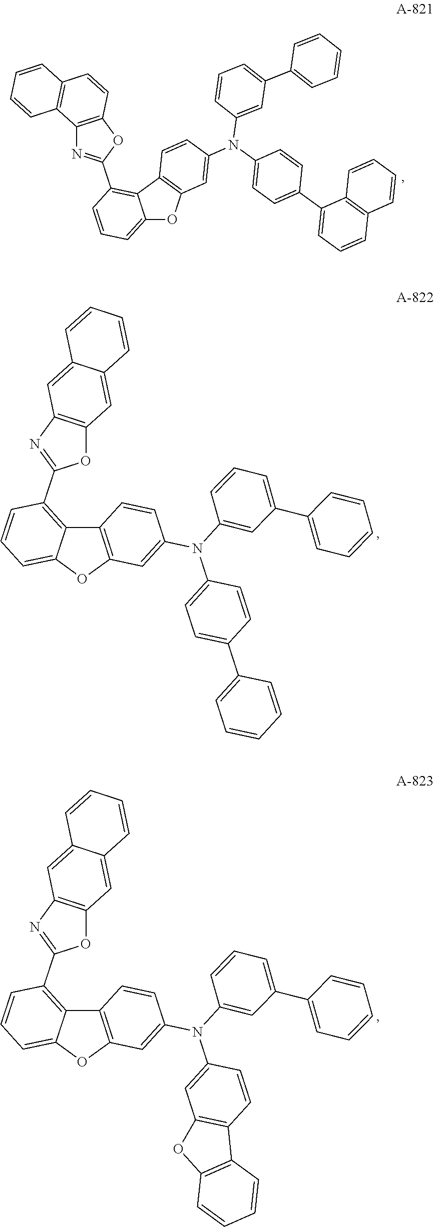 [SMILES: c1ccc(-c2cccc(N(c3ccc(-c4cccc5ccccc45)cc3)c3ccc4c(c3)oc3cccc(-c5nc6c(ccc7ccccc76)o5)c34)c2)cc1 ; c1ccc(-c2ccc(N(c3cccc(-c4ccccc4)c3)c3ccc4c(c3)oc3cccc(-c5nc6cc7ccccc7cc6o5)c34)cc2)cc1 ; c1ccc(-c2cccc(N(c3ccc4c(c3)oc3ccccc34)c3ccc4c(c3)oc3cccc(-c5nc6cc7ccccc7cc6o5)c34)c2)cc1] 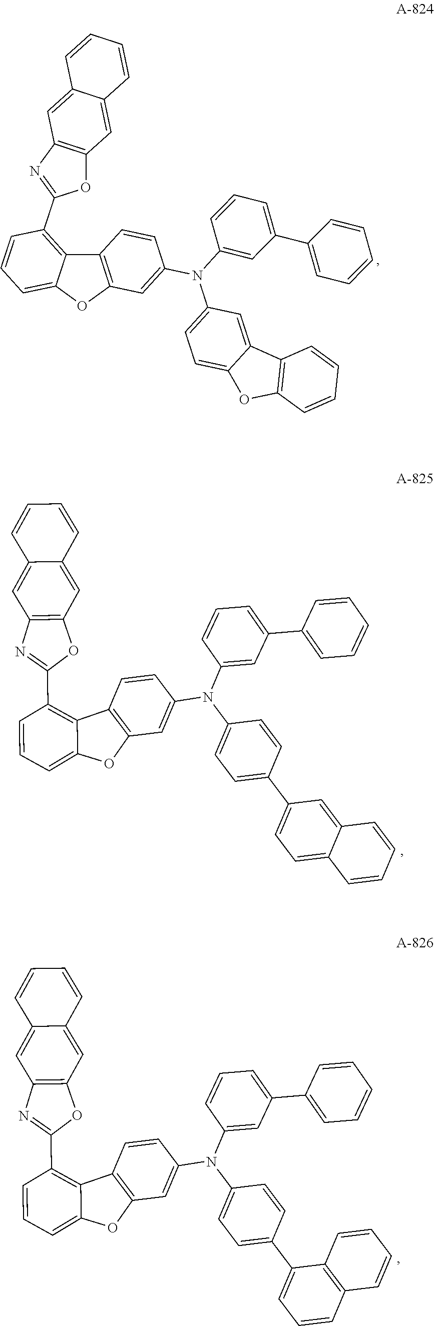 [SMILES: c1ccc(-c2cccc(N(c3ccc4c(c3)oc3cccc(-c5nc6cc7ccccc7cc6o5)c34)c3ccc4oc5ccccc5c4c3)c2)cc1 ; c1ccc(-c2cccc(N(c3ccc(-c4ccc5ccccc5c4)cc3)c3ccc4c(c3)oc3cccc(-c5nc6cc7ccccc7cc6o5)c34)c2)cc1 ; c1ccc(-c2cccc(N(c3ccc(-c4cccc5ccccc45)cc3)c3ccc4c(c3)oc3cccc(-c5nc6cc7ccccc7cc6o5)c34)c2)cc1] 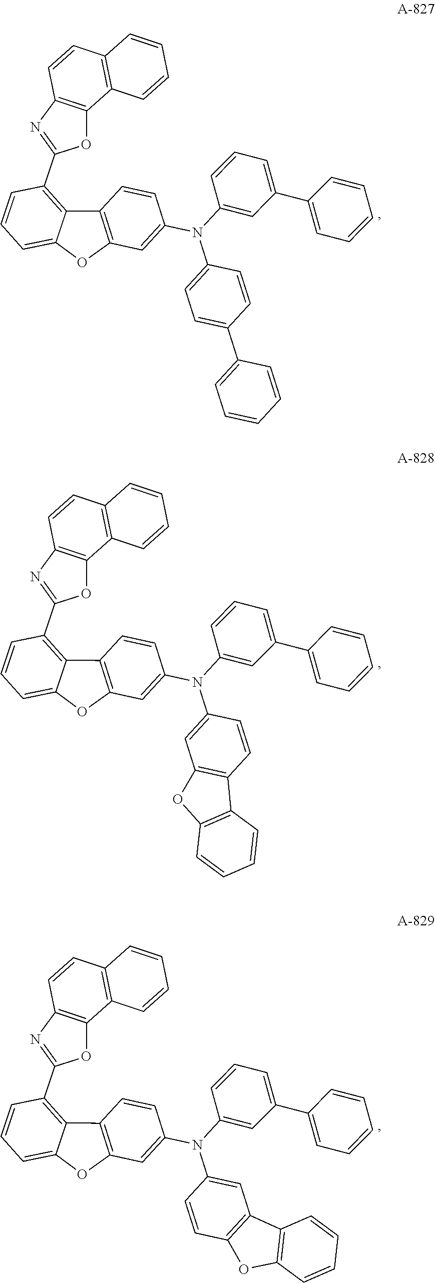 [SMILES: c1ccc(-c2ccc(N(c3cccc(-c4ccccc4)c3)c3ccc4c(c3)oc3cccc(-c5nc6ccc7ccccc7c6o5)c34)cc2)cc1 ; c1ccc(-c2cccc(N(c3ccc4c(c3)oc3ccccc34)c3ccc4c(c3)oc3cccc(-c5nc6ccc7ccccc7c6o5)c34)c2)cc1 ; c1ccc(-c2cccc(N(c3ccc4c(c3)oc3cccc(-c5nc6ccc7ccccc7c6o5)c34)c3ccc4oc5ccccc5c4c3)c2)cc1] 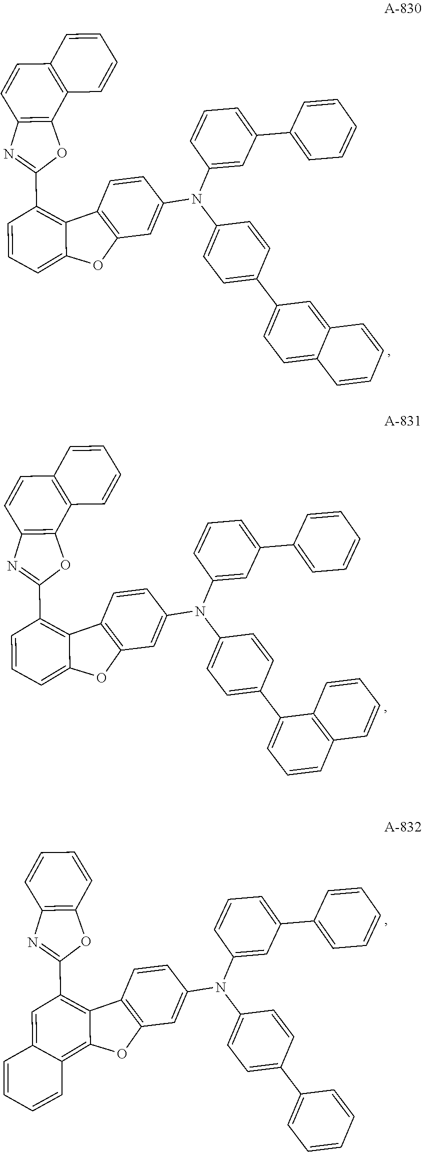 [SMILES: c1ccc(-c2cccc(N(c3ccc(-c4ccc5ccccc5c4)cc3)c3ccc4c(c3)oc3cccc(-c5nc6ccc7ccccc7c6o5)c34)c2)cc1 ; c1ccc(-c2cccc(N(c3ccc(-c4cccc5ccccc45)cc3)c3ccc4c(c3)oc3cccc(-c5nc6ccc7ccccc7c6o5)c34)c2)cc1 ; c1ccc(-c2ccc(N(c3cccc(-c4ccccc4)c3)c3ccc4c(c3)oc3c5ccccc5cc(-c5nc6ccccc6o5)c43)cc2)cc1] 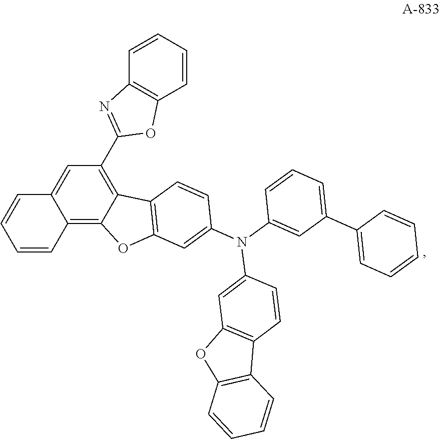 [SMILES: c1ccc(-c2cccc(N(c3ccc4c(c3)oc3ccccc34)c3ccc4c(c3)oc3c5ccccc5cc(-c5nc6ccccc6o5)c43)c2)cc1] 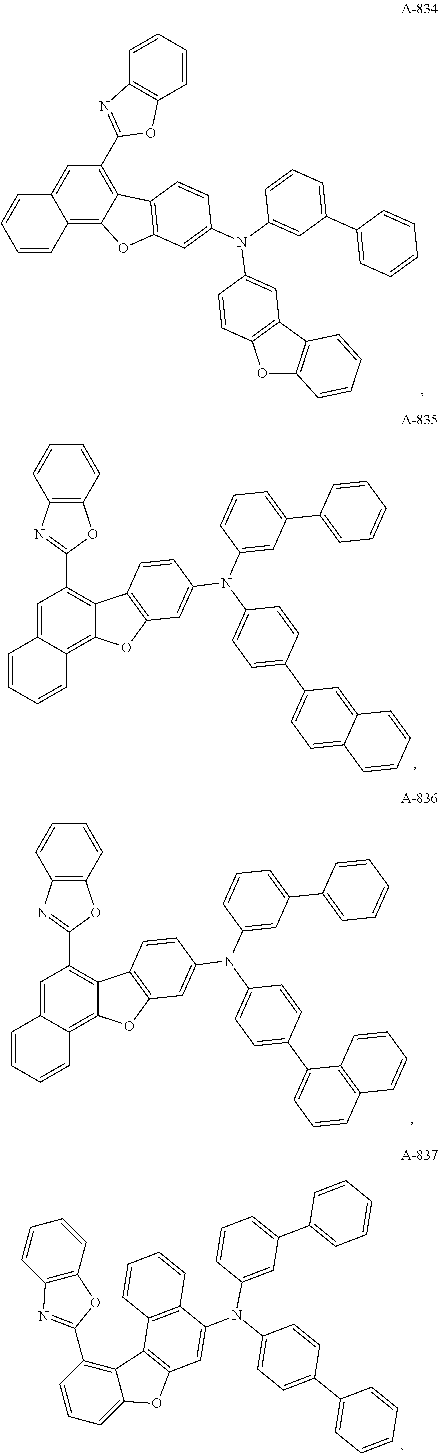 [SMILES: c1ccc(-c2cccc(N(c3ccc4c(c3)oc3c5ccccc5cc(-c5nc6ccccc6o5)c43)c3ccc4oc5ccccc5c4c3)c2)cc1 ; c1ccc(-c2cccc(N(c3ccc(-c4ccc5ccccc5c4)cc3)c3ccc4c(c3)oc3c5ccccc5cc(-c5nc6ccccc6o5)c43)c2)cc1 ; c1ccc(-c2cccc(N(c3ccc(-c4cccc5ccccc45)cc3)c3ccc4c(c3)oc3c5ccccc5cc(-c5nc6ccccc6o5)c43)c2)cc1 ; c1ccc(-c2ccc(N(c3cccc(-c4ccccc4)c3)c3cc4oc5cccc(-c6nc7ccccc7o6)c5c4c4ccccc34)cc2)cc1] 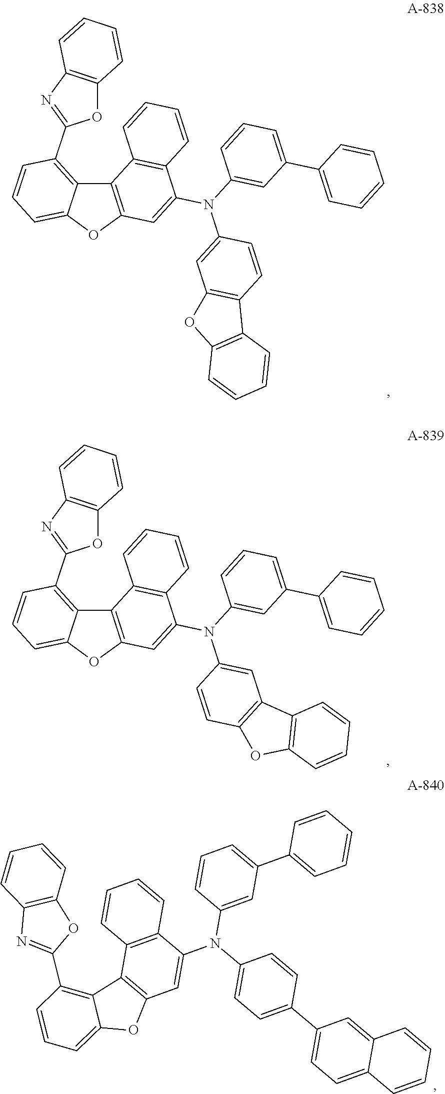 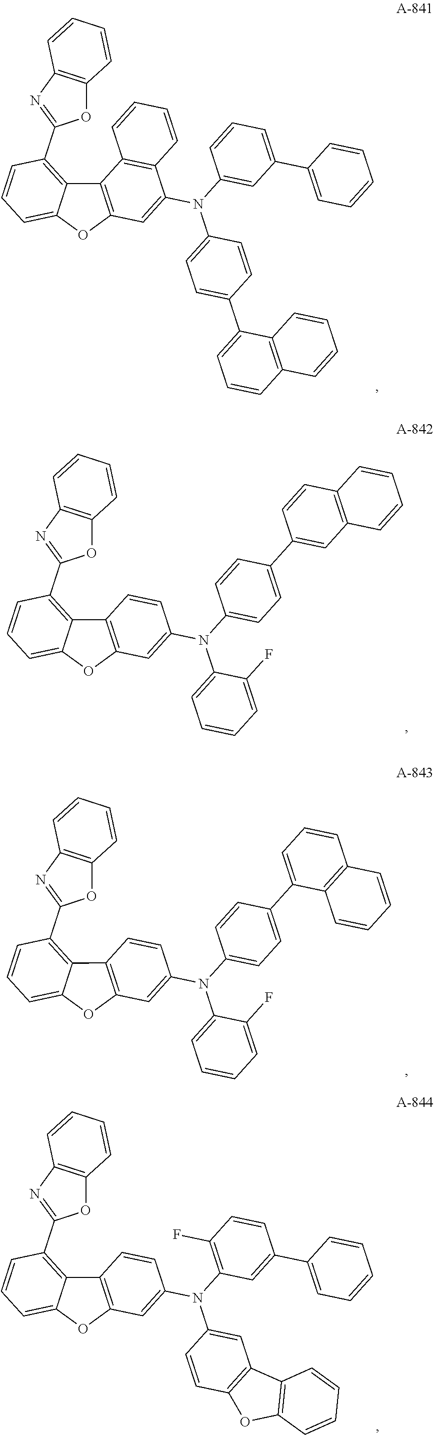 [SMILES: c1ccc(-c2cccc(N(c3ccc(-c4cccc5ccccc45)cc3)c3cc4oc5cccc(-c6nc7ccccc7o6)c5c4c4ccccc34)c2)cc1 ; Fc1ccccc1N(c1ccc(-c2ccc3ccccc3c2)cc1)c1ccc2c(c1)oc1cccc(-c3nc4ccccc4o3)c12 ; Fc1ccccc1N(c1ccc(-c2cccc3ccccc23)cc1)c1ccc2c(c1)oc1cccc(-c3nc4ccccc4o3)c12 ; Fc1ccc(-c2ccccc2)cc1N(c1ccc2c(c1)oc1cccc(-c3nc4ccccc4o3)c12)c1ccc2oc3ccccc3c2c1] 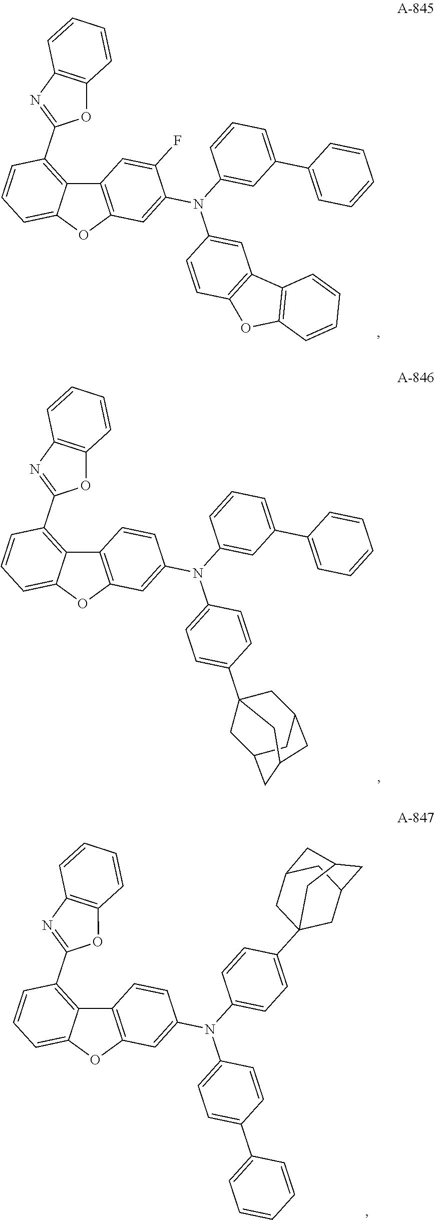 [SMILES: Fc1cc2c(cc1N(c1cccc(-c3ccccc3)c1)c1ccc3oc4ccccc4c3c1)oc1cccc(-c3nc4ccccc4o3)c12 ; c1ccc(-c2cccc(N(c3ccc(C45CC6CC(CC(C6)C4)C5)cc3)c3ccc4c(c3)oc3cccc(-c5nc6ccccc6o5)c34)c2)cc1 ; c1ccc(-c2ccc(N(c3ccc(C45CC6CC(CC(C6)C4)C5)cc3)c3ccc4c(c3)oc3cccc(-c5nc6ccccc6o5)c34)cc2)cc1] 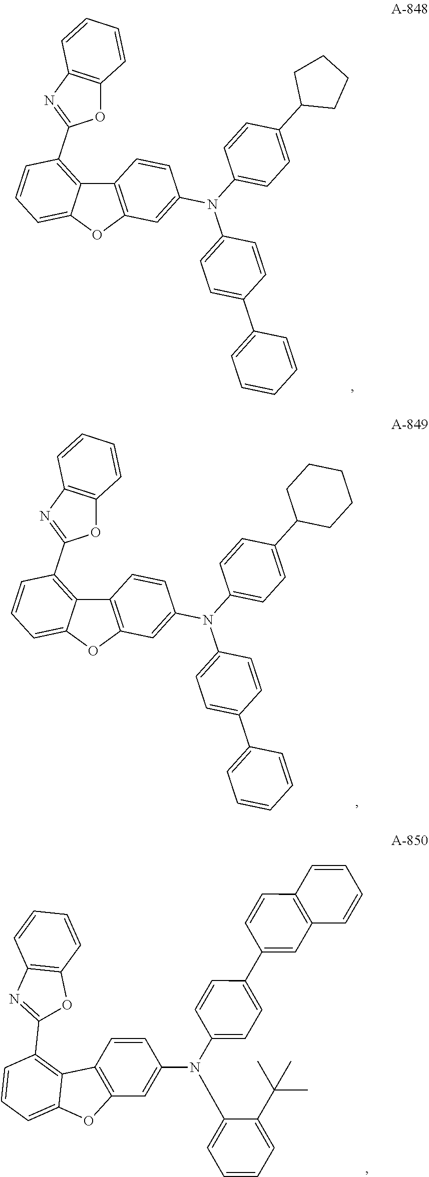 [SMILES: c1ccc(-c2ccc(N(c3ccc(C4CCCC4)cc3)c3ccc4c(c3)oc3cccc(-c5nc6ccccc6o5)c34)cc2)cc1 ; c1ccc(-c2ccc(N(c3ccc(C4CCCCC4)cc3)c3ccc4c(c3)oc3cccc(-c5nc6ccccc6o5)c34)cc2)cc1 ; CC(C)(C)c1ccccc1N(c1ccc(-c2ccc3ccccc3c2)cc1)c1ccc2c(c1)oc1cccc(-c3nc4ccccc4o3)c12] 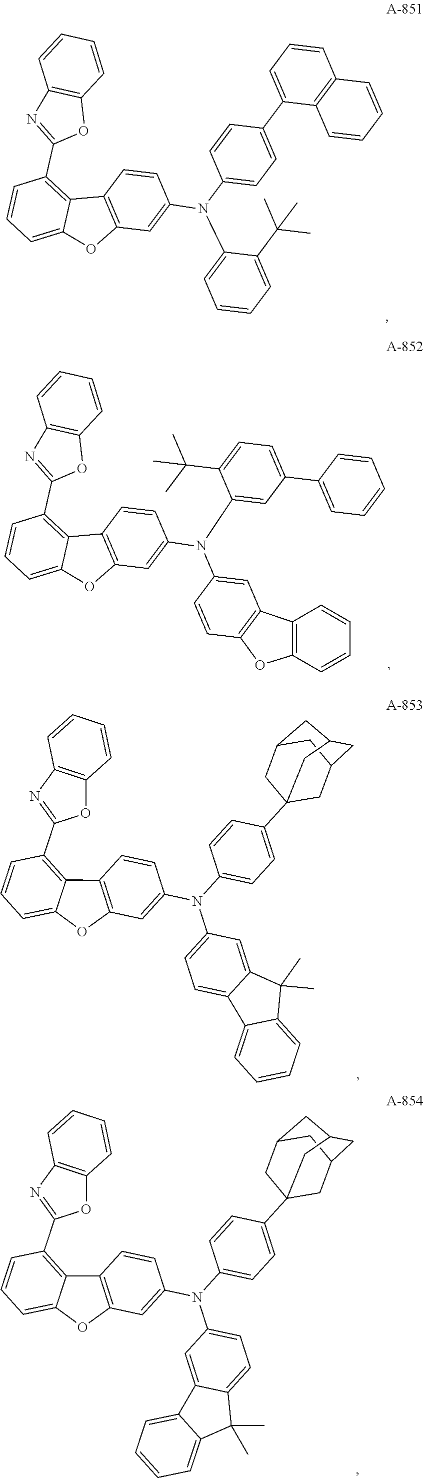 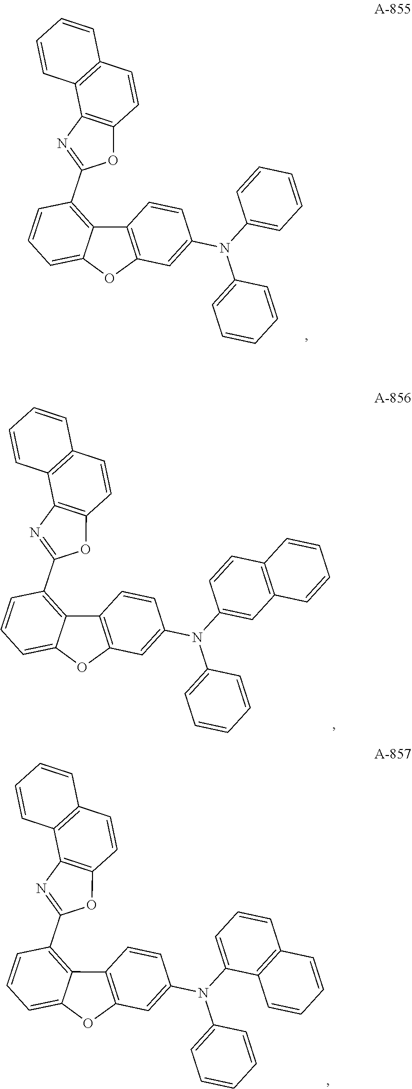 [SMILES: c1ccc(N(c2ccccc2)c2ccc3c(c2)oc2cccc(-c4nc5c(ccc6ccccc65)o4)c23)cc1 ; c1ccc(N(c2ccc3ccccc3c2)c2ccc3c(c2)oc2cccc(-c4nc5c(ccc6ccccc65)o4)c23)cc1 ; c1ccc(N(c2ccc3c(c2)oc2cccc(-c4nc5c(ccc6ccccc65)o4)c23)c2cccc3ccccc23)cc1] 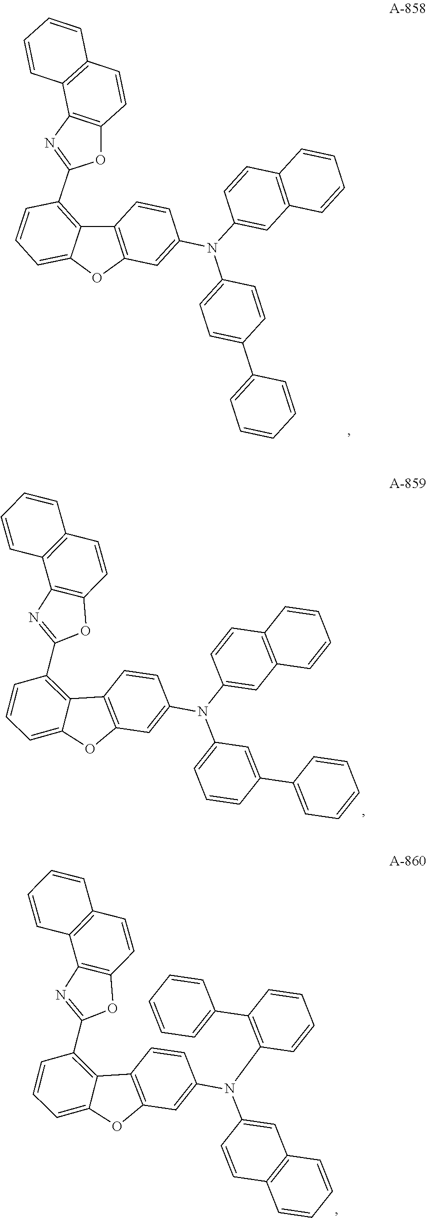 [SMILES: c1ccc(-c2ccc(N(c3ccc4ccccc4c3)c3ccc4c(c3)oc3cccc(-c5nc6c(ccc7ccccc76)o5)c34)cc2)cc1 ; c1ccc(-c2cccc(N(c3ccc4ccccc4c3)c3ccc4c(c3)oc3cccc(-c5nc6c(ccc7ccccc76)o5)c34)c2)cc1 ; c1ccc(-c2ccccc2N(c2ccc3ccccc3c2)c2ccc3c(c2)oc2cccc(-c4nc5c(ccc6ccccc65)o4)c23)cc1] 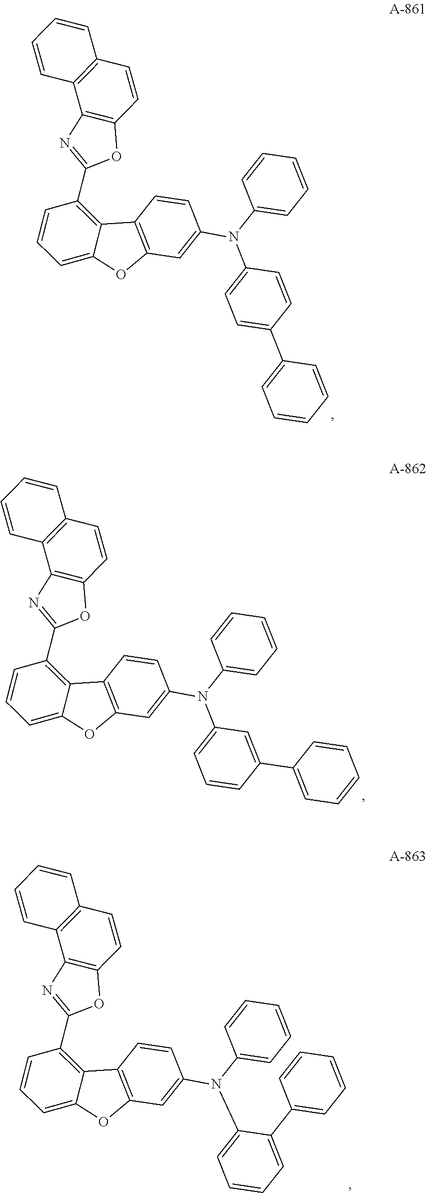 [SMILES: c1ccc(-c2ccc(N(c3ccccc3)c3ccc4c(c3)oc3cccc(-c5nc6c(ccc7ccccc76)o5)c34)cc2)cc1 ; c1ccc(-c2cccc(N(c3ccccc3)c3ccc4c(c3)oc3cccc(-c5nc6c(ccc7ccccc76)o5)c34)c2)cc1 ; c1ccc(-c2ccccc2N(c2ccccc2)c2ccc3c(c2)oc2cccc(-c4nc5c(ccc6ccccc65)o4)c23)cc1] 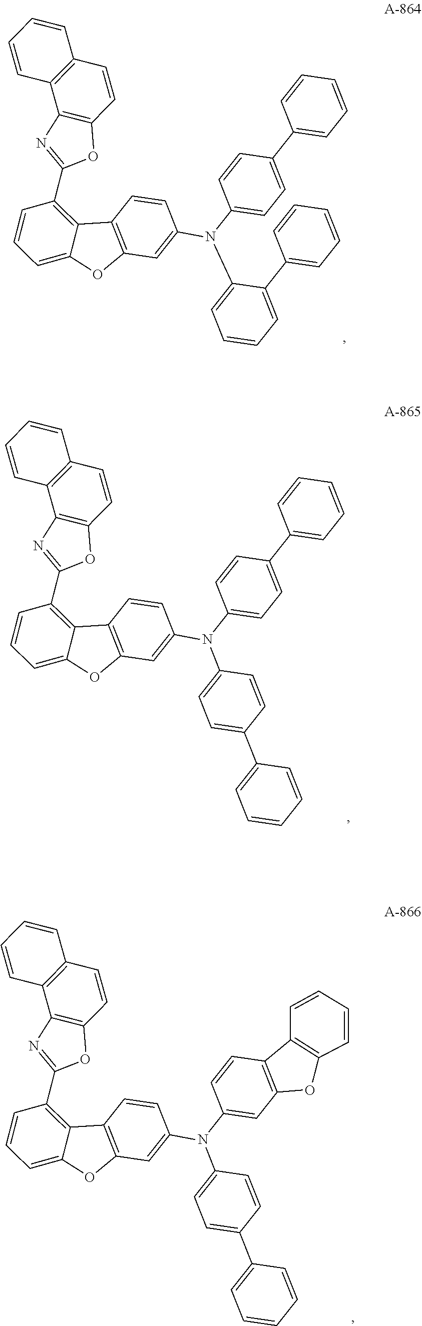 [SMILES: c1ccc(-c2ccc(N(c3ccc4c(c3)oc3cccc(-c5nc6c(ccc7ccccc76)o5)c34)c3ccccc3-c3ccccc3)cc2)cc1 ; c1ccc(-c2ccc(N(c3ccc(-c4ccccc4)cc3)c3ccc4c(c3)oc3cccc(-c5nc6c(ccc7ccccc76)o5)c34)cc2)cc1 ; c1ccc(-c2ccc(N(c3ccc4c(c3)oc3ccccc34)c3ccc4c(c3)oc3cccc(-c5nc6c(ccc7ccccc76)o5)c34)cc2)cc1] 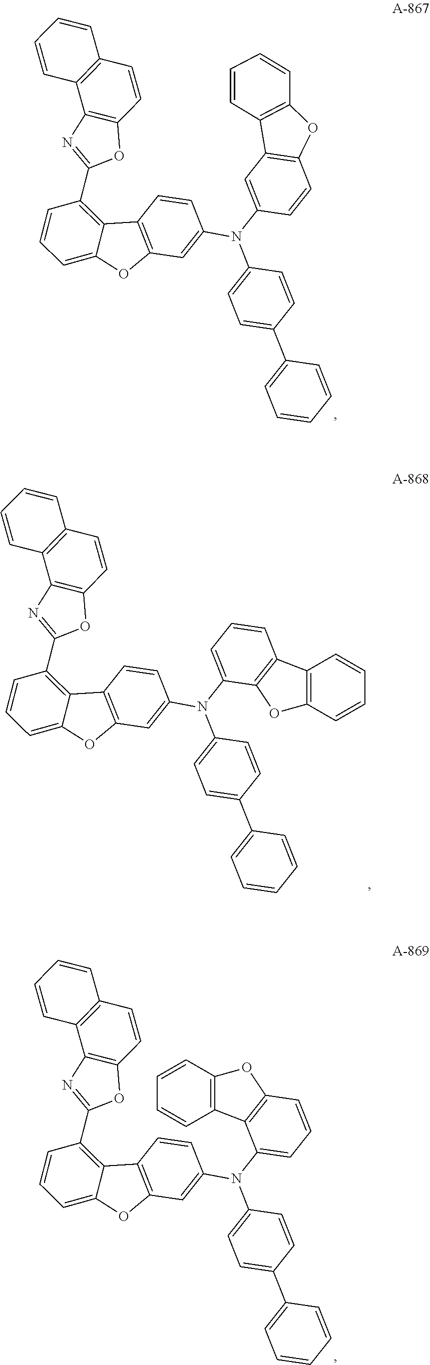 [SMILES: c1ccc(-c2ccc(N(c3ccc4c(c3)oc3cccc(-c5nc6c(ccc7ccccc76)o5)c34)c3ccc4oc5ccccc5c4c3)cc2)cc1 ; c1ccc(-c2ccc(N(c3ccc4c(c3)oc3cccc(-c5nc6c(ccc7ccccc76)o5)c34)c3cccc4c3oc3ccccc34)cc2)cc1 ; c1ccc(-c2ccc(N(c3ccc4c(c3)oc3cccc(-c5nc6c(ccc7ccccc76)o5)c34)c3cccc4oc5ccccc5c34)cc2)cc1] 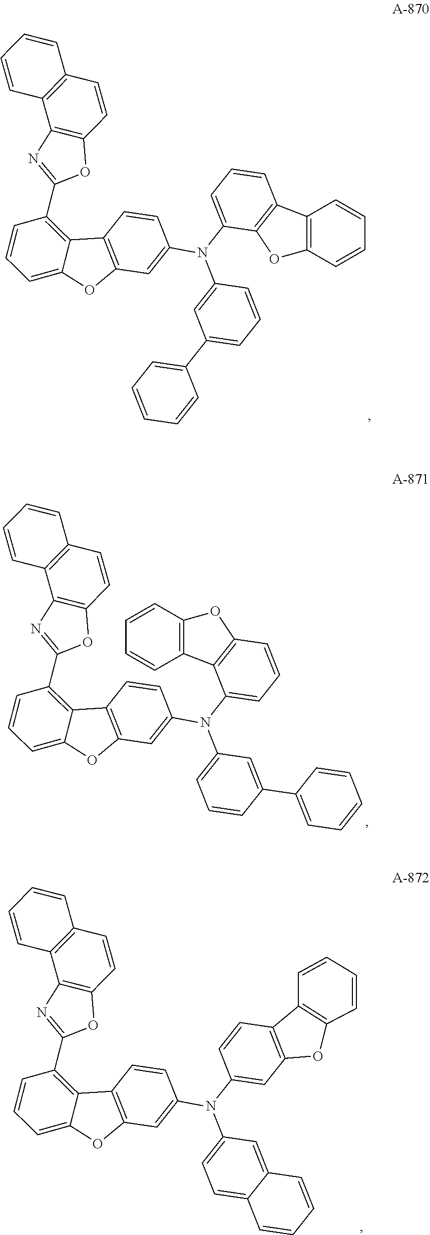 [SMILES: c1ccc(-c2cccc(N(c3ccc4c(c3)oc3cccc(-c5nc6c(ccc7ccccc76)o5)c34)c3cccc4c3oc3ccccc34)c2)cc1 ; c1ccc(-c2cccc(N(c3ccc4c(c3)oc3cccc(-c5nc6c(ccc7ccccc76)o5)c34)c3cccc4oc5ccccc5c34)c2)cc1 ; c1ccc2cc(N(c3ccc4c(c3)oc3ccccc34)c3ccc4c(c3)oc3cccc(-c5nc6c(ccc7ccccc76)o5)c34)ccc2c1] 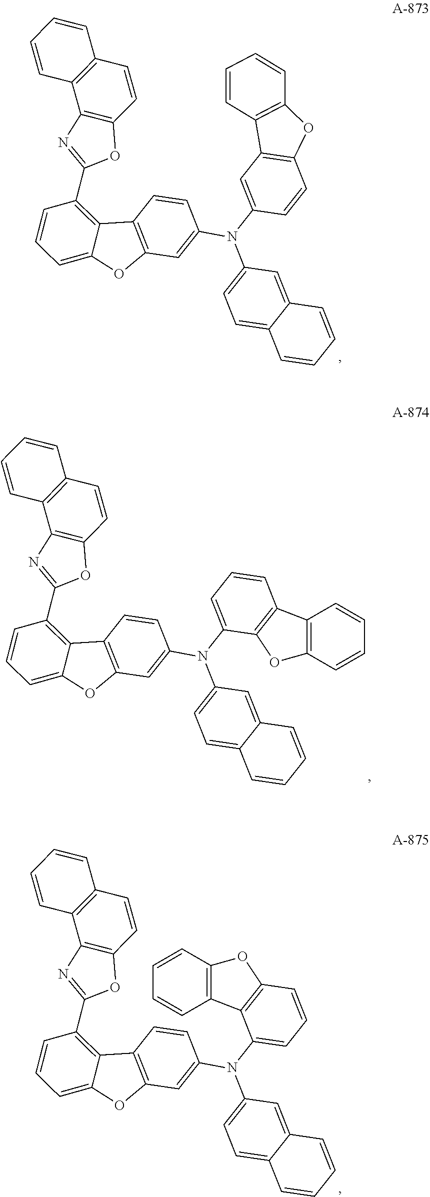 [SMILES: c1ccc2cc(N(c3ccc4c(c3)oc3cccc(-c5nc6c(ccc7ccccc76)o5)c34)c3ccc4oc5ccccc5c4c3)ccc2c1 ; c1ccc2cc(N(c3ccc4c(c3)oc3cccc(-c5nc6c(ccc7ccccc76)o5)c34)c3cccc4c3oc3ccccc34)ccc2c1 ; c1ccc2cc(N(c3ccc4c(c3)oc3cccc(-c5nc6c(ccc7ccccc76)o5)c34)c3cccc4oc5ccccc5c34)ccc2c1] 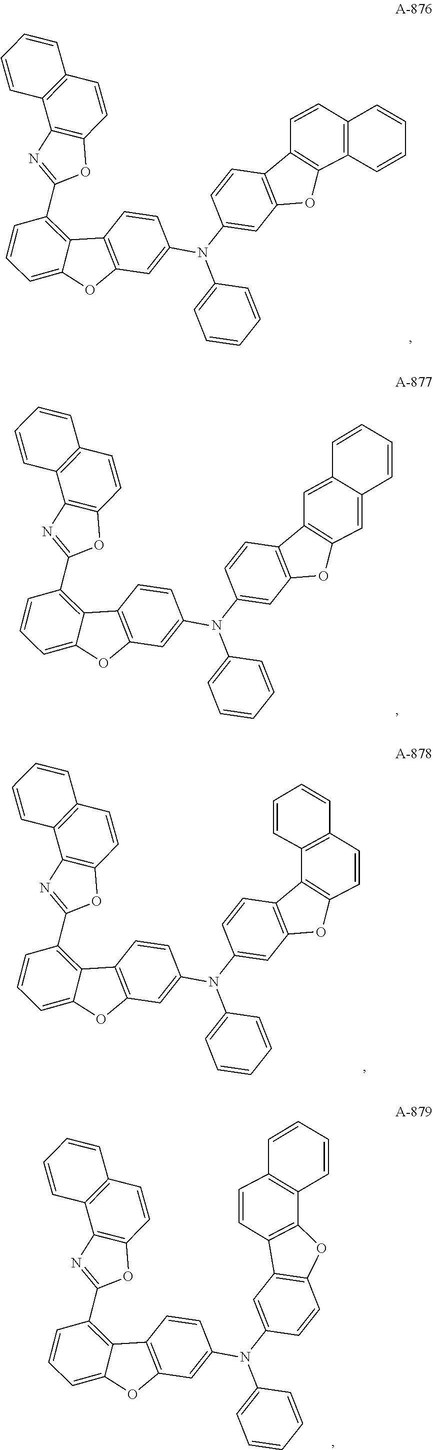 [SMILES: c1ccc(N(c2ccc3c(c2)oc2c4ccccc4ccc32)c2ccc3c(c2)oc2cccc(-c4nc5c(ccc6ccccc65)o4)c23)cc1 ; c1ccc(N(c2ccc3c(c2)oc2cc4ccccc4cc23)c2ccc3c(c2)oc2cccc(-c4nc5c(ccc6ccccc65)o4)c23)cc1 ; c1ccc(N(c2ccc3c(c2)oc2cccc(-c4nc5c(ccc6ccccc65)o4)c23)c2ccc3c(c2)oc2ccc4ccccc4c23)cc1 ; c1ccc(N(c2ccc3c(c2)oc2cccc(-c4nc5c(ccc6ccccc65)o4)c23)c2ccc3oc4c5ccccc5ccc4c3c2)cc1] 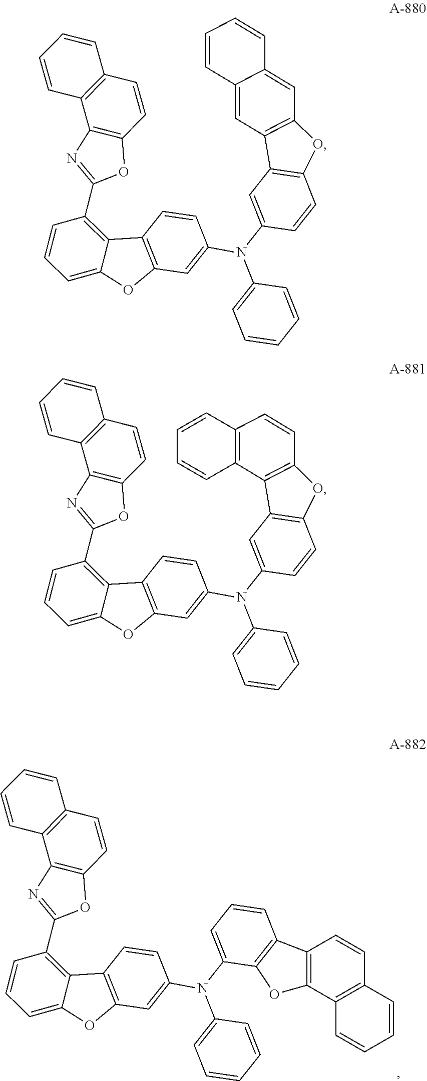 [SMILES: c1ccc(N(c2ccc3c(c2)oc2cccc(-c4nc5c(ccc6ccccc65)o4)c23)c2ccc3oc4cc5ccccc5cc4c3c2)cc1 ; c1ccc(N(c2ccc3c(c2)oc2cccc(-c4nc5c(ccc6ccccc65)o4)c23)c2ccc3oc4ccc5ccccc5c4c3c2)cc1 ; c1ccc(N(c2ccc3c(c2)oc2cccc(-c4nc5c(ccc6ccccc65)o4)c23)c2cccc3c2oc2c4ccccc4ccc32)cc1] 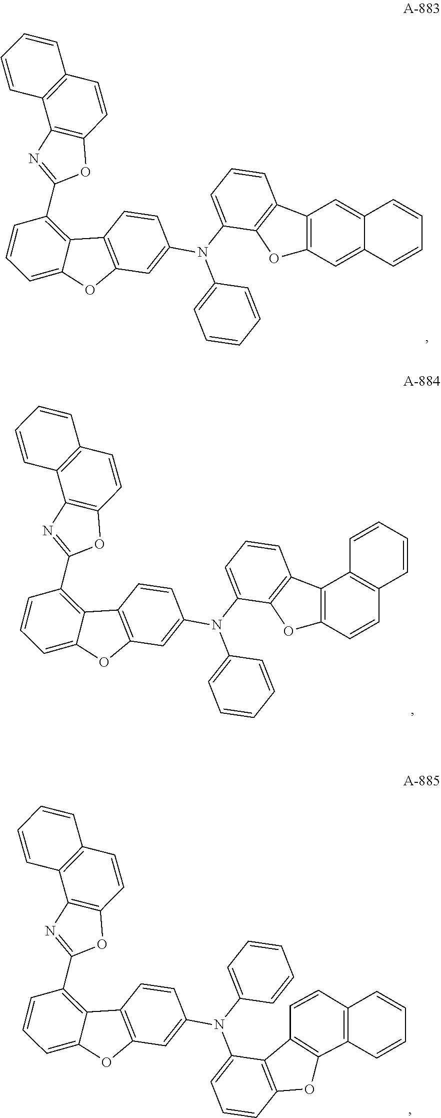 [SMILES: c1ccc(N(c2ccc3c(c2)oc2cccc(-c4nc5c(ccc6ccccc65)o4)c23)c2cccc3c2oc2cc4ccccc4cc23)cc1 ; c1ccc(N(c2ccc3c(c2)oc2cccc(-c4nc5c(ccc6ccccc65)o4)c23)c2cccc3c2oc2ccc4ccccc4c23)cc1 ; c1ccc(N(c2ccc3c(c2)oc2cccc(-c4nc5c(ccc6ccccc65)o4)c23)c2cccc3oc4c5ccccc5ccc4c23)cc1] 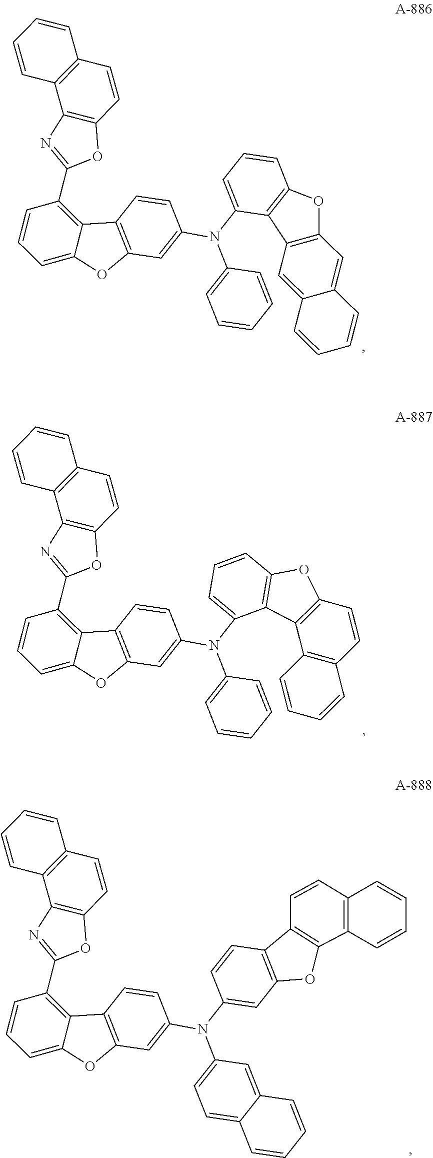 [SMILES: c1ccc(N(c2ccc3c(c2)oc2cccc(-c4nc5c(ccc6ccccc65)o4)c23)c2cccc3oc4cc5ccccc5cc4c23)cc1 ; c1ccc(N(c2ccc3c(c2)oc2cccc(-c4nc5c(ccc6ccccc65)o4)c23)c2cccc3oc4ccc5ccccc5c4c23)cc1 ; c1ccc2cc(N(c3ccc4c(c3)oc3c5ccccc5ccc43)c3ccc4c(c3)oc3cccc(-c5nc6c(ccc7ccccc76)o5)c34)ccc2c1] 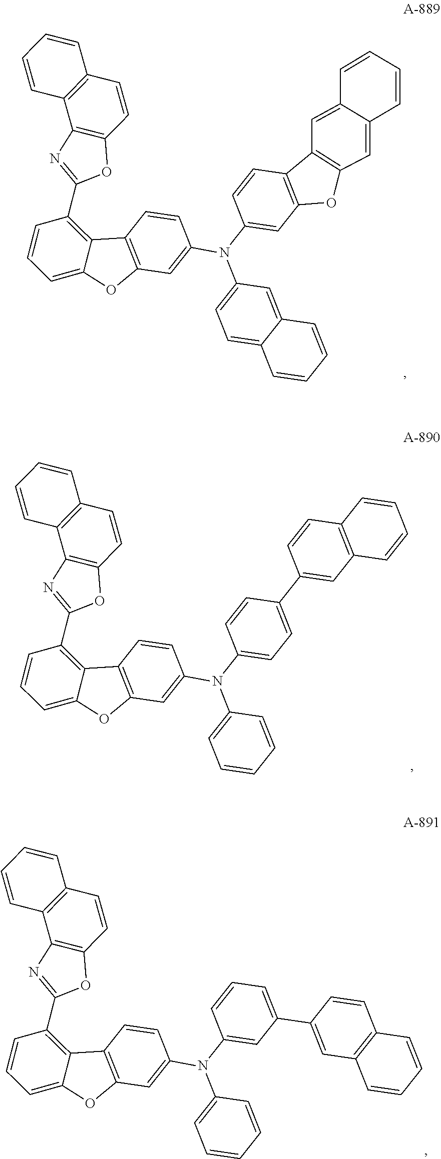 [SMILES: c1ccc2cc(N(c3ccc4c(c3)oc3cc5ccccc5cc34)c3ccc4c(c3)oc3cccc(-c5nc6c(ccc7ccccc76)o5)c34)ccc2c1 ; c1ccc(N(c2ccc(-c3ccc4ccccc4c3)cc2)c2ccc3c(c2)oc2cccc(-c4nc5c(ccc6ccccc65)o4)c23)cc1 ; c1ccc(N(c2cccc(-c3ccc4ccccc4c3)c2)c2ccc3c(c2)oc2cccc(-c4nc5c(ccc6ccccc65)o4)c23)cc1] 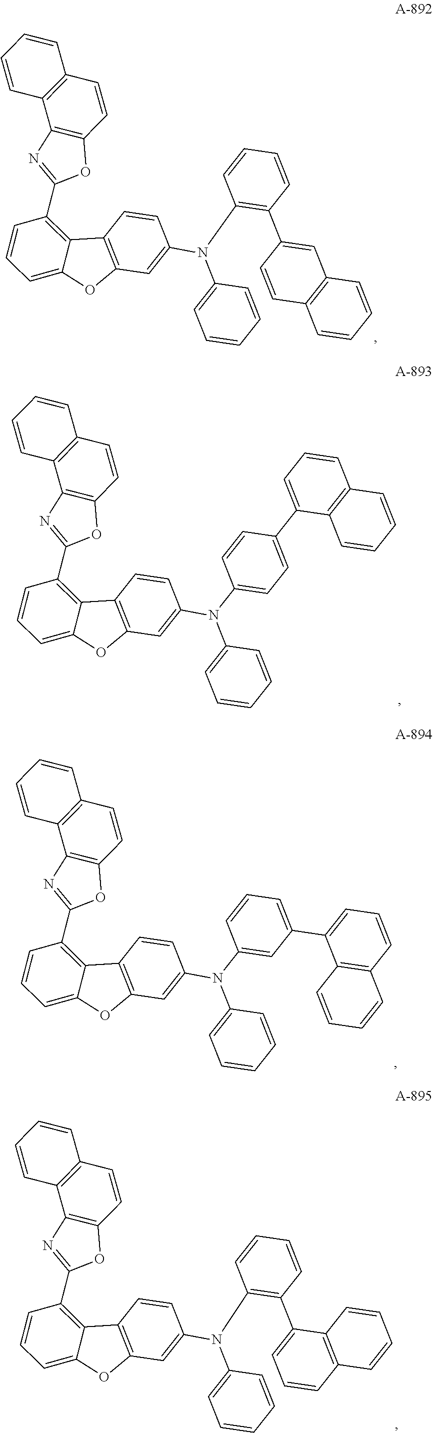 [SMILES: c1ccc(N(c2ccc3c(c2)oc2cccc(-c4nc5c(ccc6ccccc65)o4)c23)c2ccccc2-c2ccc3ccccc3c2)cc1 ; c1ccc(N(c2ccc(-c3cccc4ccccc34)cc2)c2ccc3c(c2)oc2cccc(-c4nc5c(ccc6ccccc65)o4)c23)cc1 ; c1ccc(N(c2cccc(-c3cccc4ccccc34)c2)c2ccc3c(c2)oc2cccc(-c4nc5c(ccc6ccccc65)o4)c23)cc1 ; c1ccc(N(c2ccc3c(c2)oc2cccc(-c4nc5c(ccc6ccccc65)o4)c23)c2ccccc2-c2cccc3ccccc23)cc1] 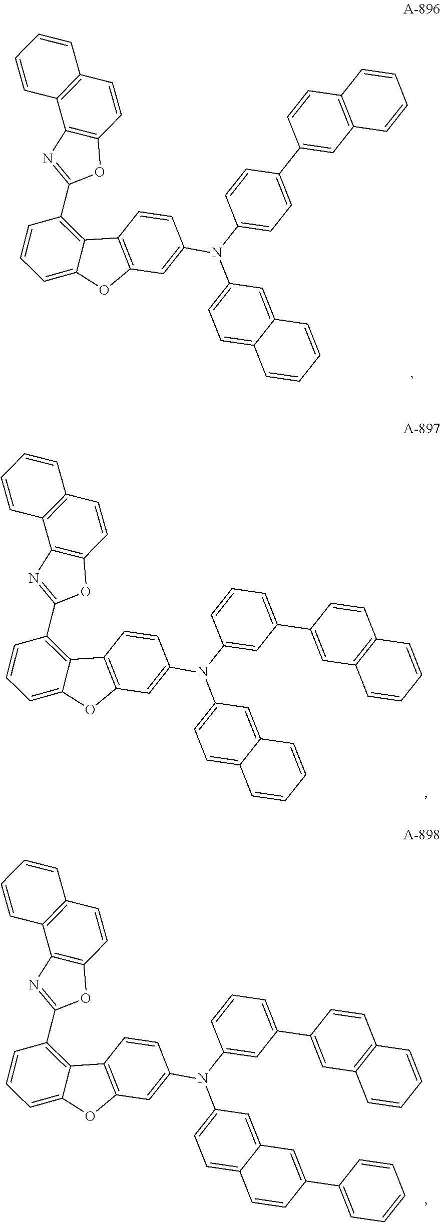 [SMILES: c1ccc2cc(-c3ccc(N(c4ccc5ccccc5c4)c4ccc5c(c4)oc4cccc(-c6nc7c(ccc8ccccc87)o6)c45)cc3)ccc2c1 ; c1cc(-c2ccc3ccccc3c2)cc(N(c2ccc3ccccc3c2)c2ccc3c(c2)oc2cccc(-c4nc5c(ccc6ccccc65)o4)c23)c1 ; c1ccc(-c2ccc3ccc(N(c4cccc(-c5ccc6ccccc6c5)c4)c4ccc5c(c4)oc4cccc(-c6nc7c(ccc8ccccc87)o6)c45)cc3c2)cc1] 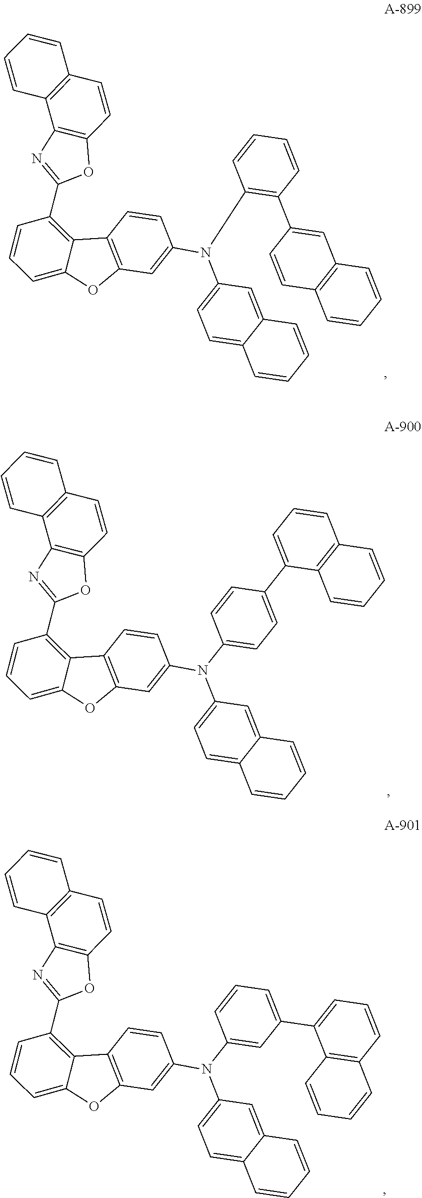 [SMILES: c1ccc(N(c2ccc3ccccc3c2)c2ccc3c(c2)oc2cccc(-c4nc5c(ccc6ccccc65)o4)c23)c(-c2ccc3ccccc3c2)c1 ; c1ccc2cc(N(c3ccc(-c4cccc5ccccc45)cc3)c3ccc4c(c3)oc3cccc(-c5nc6c(ccc7ccccc76)o5)c34)ccc2c1 ; c1cc(-c2cccc3ccccc23)cc(N(c2ccc3ccccc3c2)c2ccc3c(c2)oc2cccc(-c4nc5c(ccc6ccccc65)o4)c23)c1] 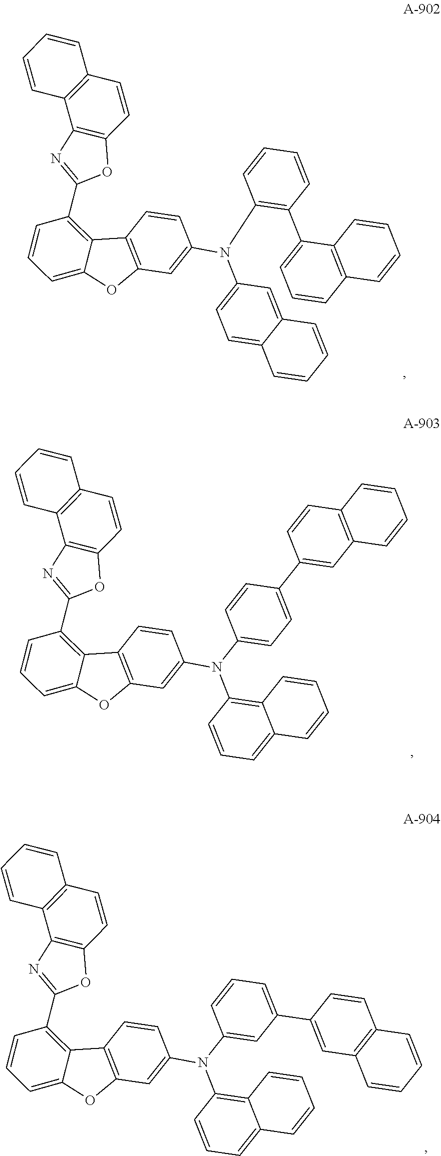 [SMILES: c1ccc(N(c2ccc3ccccc3c2)c2ccc3c(c2)oc2cccc(-c4nc5c(ccc6ccccc65)o4)c23)c(-c2cccc3ccccc23)c1 ; c1ccc2cc(-c3ccc(N(c4ccc5c(c4)oc4cccc(-c6nc7c(ccc8ccccc87)o6)c45)c4cccc5ccccc45)cc3)ccc2c1 ; c1cc(-c2ccc3ccccc3c2)cc(N(c2ccc3c(c2)oc2cccc(-c4nc5c(ccc6ccccc65)o4)c23)c2cccc3ccccc23)c1] 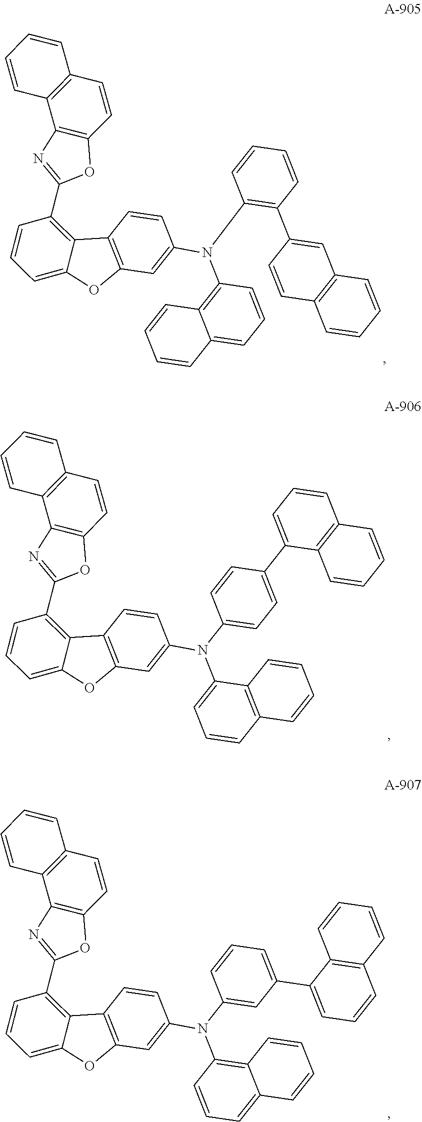 [SMILES: c1ccc(N(c2ccc3c(c2)oc2cccc(-c4nc5c(ccc6ccccc65)o4)c23)c2cccc3ccccc23)c(-c2ccc3ccccc3c2)c1 ; c1ccc2c(-c3ccc(N(c4ccc5c(c4)oc4cccc(-c6nc7c(ccc8ccccc87)o6)c45)c4cccc5ccccc45)cc3)cccc2c1 ; c1cc(-c2cccc3ccccc23)cc(N(c2ccc3c(c2)oc2cccc(-c4nc5c(ccc6ccccc65)o4)c23)c2cccc3ccccc23)c1] 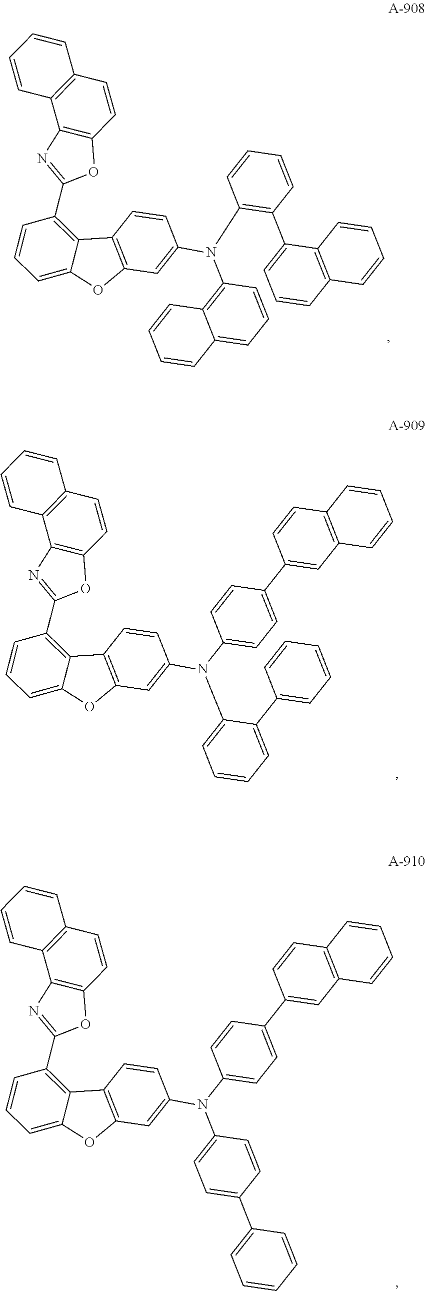 [SMILES: c1ccc(N(c2ccc3c(c2)oc2cccc(-c4nc5c(ccc6ccccc65)o4)c23)c2cccc3ccccc23)c(-c2cccc3ccccc23)c1 ; c1ccc(-c2ccccc2N(c2ccc(-c3ccc4ccccc4c3)cc2)c2ccc3c(c2)oc2cccc(-c4nc5c(ccc6ccccc65)o4)c23)cc1 ; c1ccc(-c2ccc(N(c3ccc(-c4ccc5ccccc5c4)cc3)c3ccc4c(c3)oc3cccc(-c5nc6c(ccc7ccccc76)o5)c34)cc2)cc1] 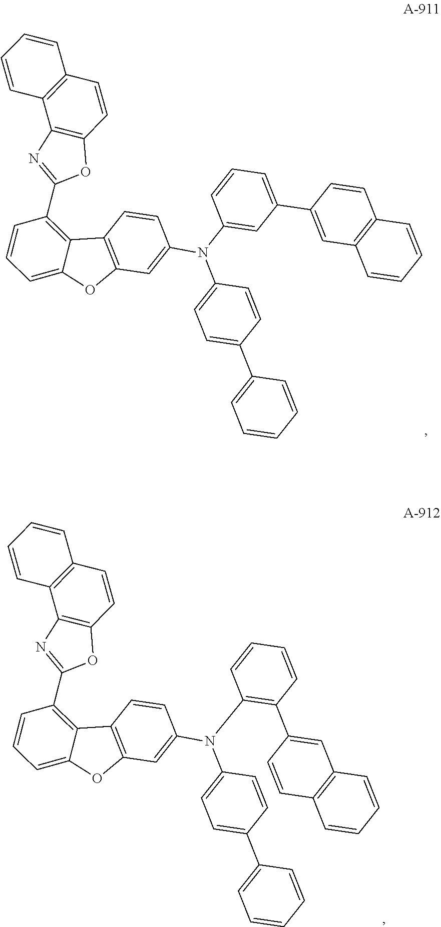 [SMILES: c1ccc(-c2ccc(N(c3cccc(-c4ccc5ccccc5c4)c3)c3ccc4c(c3)oc3cccc(-c5nc6c(ccc7ccccc76)o5)c34)cc2)cc1 ; c1ccc(-c2ccc(N(c3ccc4c(c3)oc3cccc(-c5nc6c(ccc7ccccc76)o5)c34)c3ccccc3-c3ccc4ccccc4c3)cc2)cc1] 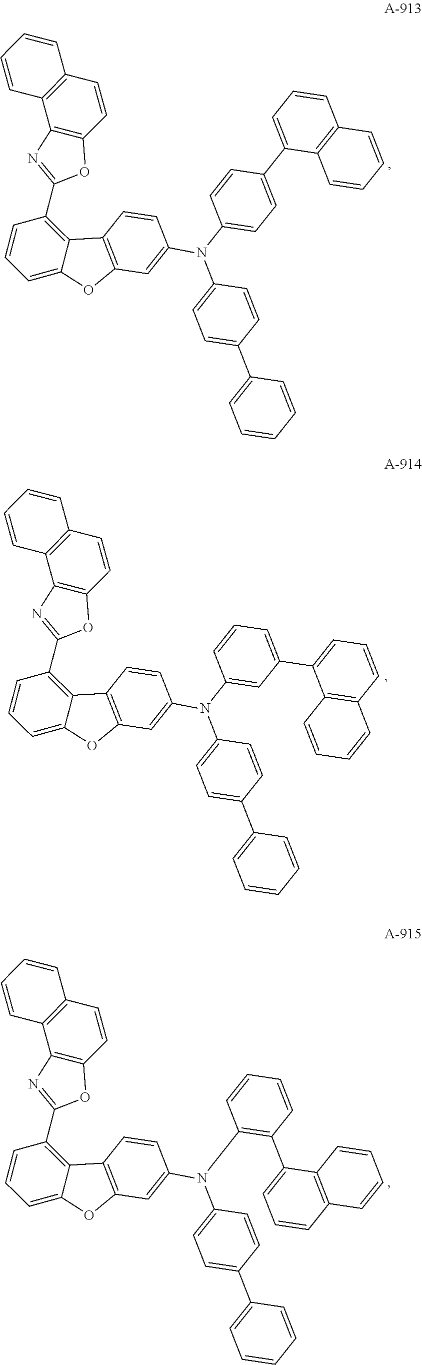 [SMILES: c1ccc(-c2ccc(N(c3ccc(-c4cccc5ccccc45)cc3)c3ccc4c(c3)oc3cccc(-c5nc6c(ccc7ccccc76)o5)c34)cc2)cc1 ; c1ccc(-c2ccc(N(c3cccc(-c4cccc5ccccc45)c3)c3ccc4c(c3)oc3cccc(-c5nc6c(ccc7ccccc76)o5)c34)cc2)cc1 ; c1ccc(-c2ccc(N(c3ccc4c(c3)oc3cccc(-c5nc6c(ccc7ccccc76)o5)c34)c3ccccc3-c3cccc4ccccc34)cc2)cc1] 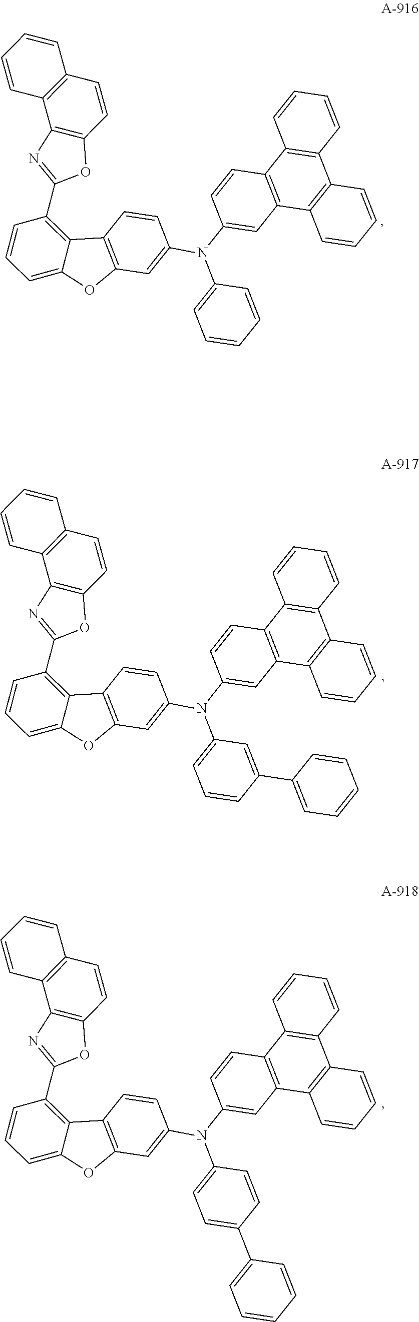 [SMILES: c1ccc(N(c2ccc3c(c2)oc2cccc(-c4nc5c(ccc6ccccc65)o4)c23)c2ccc3c4ccccc4c4ccccc4c3c2)cc1 ; c1ccc(-c2cccc(N(c3ccc4c(c3)oc3cccc(-c5nc6c(ccc7ccccc76)o5)c34)c3ccc4c5ccccc5c5ccccc5c4c3)c2)cc1 ; c1ccc(-c2ccc(N(c3ccc4c(c3)oc3cccc(-c5nc6c(ccc7ccccc76)o5)c34)c3ccc4c5ccccc5c5ccccc5c4c3)cc2)cc1] 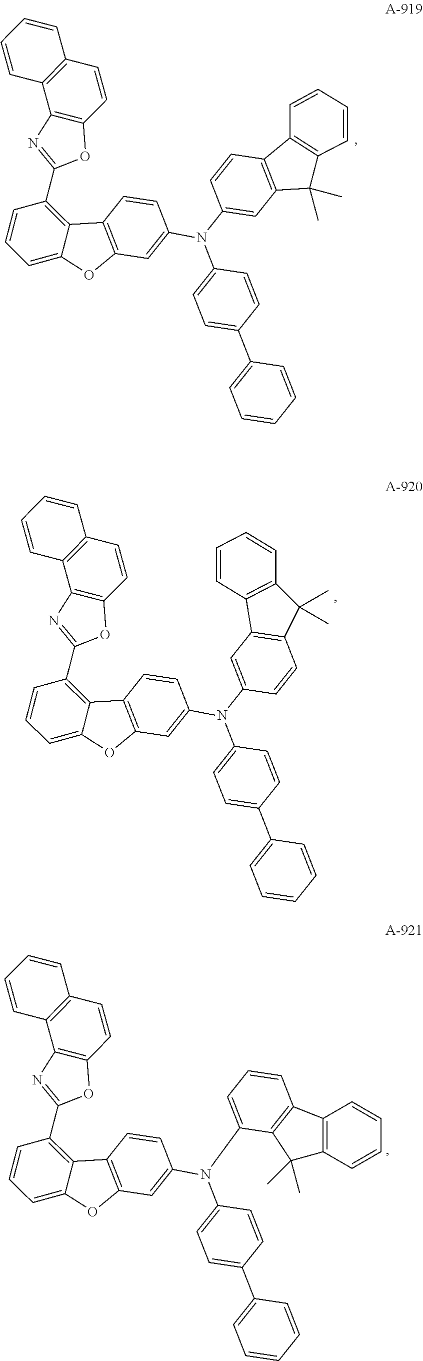 [SMILES: CC1(C)c2ccccc2-c2ccc(N(c3ccc(-c4ccccc4)cc3)c3ccc4c(c3)oc3cccc(-c5nc6c(ccc7ccccc76)o5)c34)cc21 ; CC1(C)c2ccccc2-c2cc(N(c3ccc(-c4ccccc4)cc3)c3ccc4c(c3)oc3cccc(-c5nc6c(ccc7ccccc76)o5)c34)ccc21 ; CC1(C)c2ccccc2-c2cccc(N(c3ccc(-c4ccccc4)cc3)c3ccc4c(c3)oc3cccc(-c5nc6c(ccc7ccccc76)o5)c34)c21] 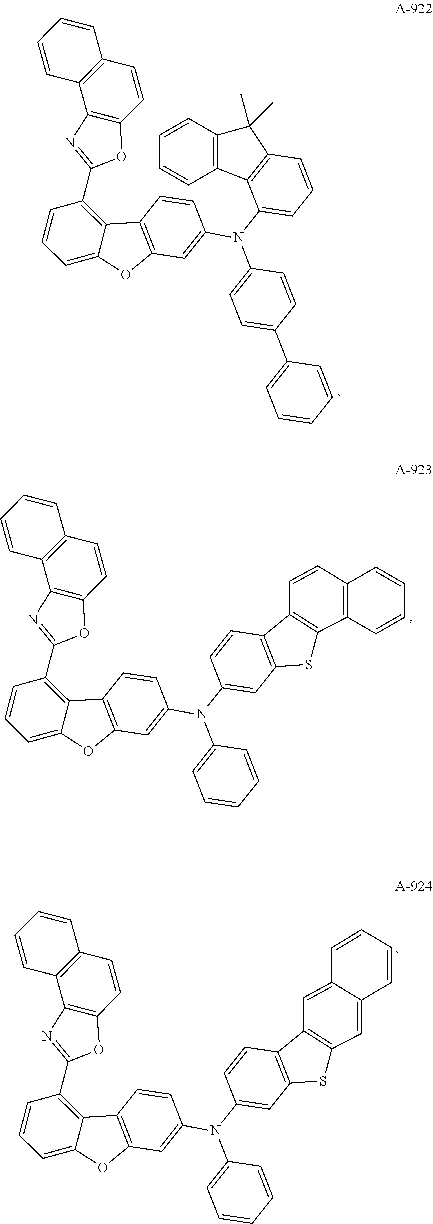 [SMILES: CC1(C)c2ccccc2-c2c(N(c3ccc(-c4ccccc4)cc3)c3ccc4c(c3)oc3cccc(-c5nc6c(ccc7ccccc76)o5)c34)cccc21 ; c1ccc(N(c2ccc3c(c2)oc2cccc(-c4nc5c(ccc6ccccc65)o4)c23)c2ccc3c(c2)sc2c4ccccc4ccc32)cc1 ; c1ccc(N(c2ccc3c(c2)oc2cccc(-c4nc5c(ccc6ccccc65)o4)c23)c2ccc3c(c2)sc2cc4ccccc4cc23)cc1] 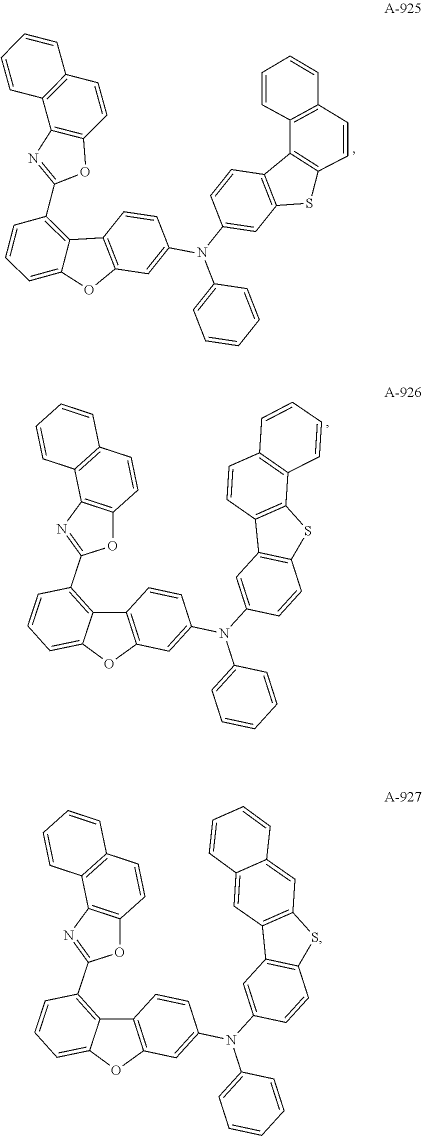 [SMILES: c1ccc(N(c2ccc3c(c2)oc2cccc(-c4nc5c(ccc6ccccc65)o4)c23)c2ccc3c(c2)sc2ccc4ccccc4c23)cc1 ; c1ccc(N(c2ccc3c(c2)oc2cccc(-c4nc5c(ccc6ccccc65)o4)c23)c2ccc3sc4c5ccccc5ccc4c3c2)cc1 ; c1ccc(N(c2ccc3c(c2)oc2cccc(-c4nc5c(ccc6ccccc65)o4)c23)c2ccc3sc4cc5ccccc5cc4c3c2)cc1] 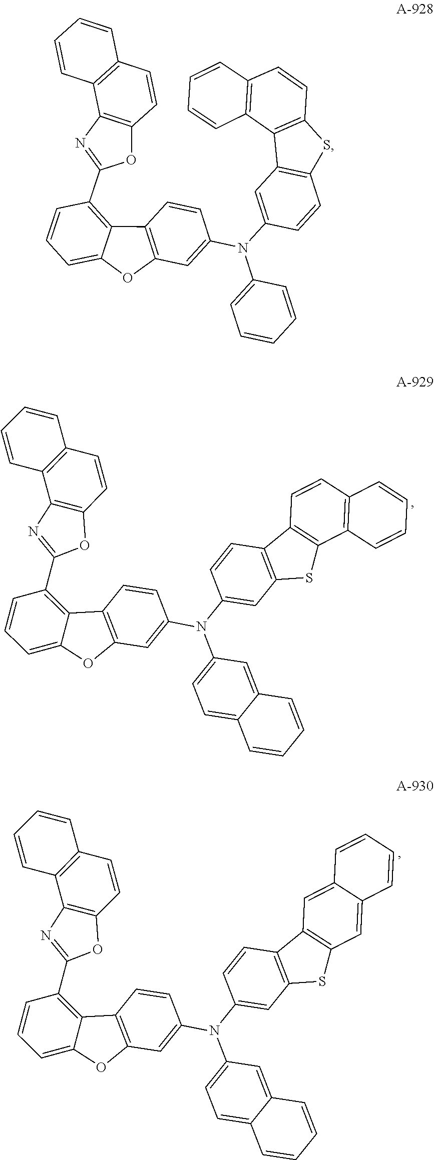 [SMILES: c1ccc(N(c2ccc3c(c2)oc2cccc(-c4nc5c(ccc6ccccc65)o4)c23)c2ccc3sc4ccc5ccccc5c4c3c2)cc1 ; c1ccc2cc(N(c3ccc4c(c3)oc3cccc(-c5nc6c(ccc7ccccc76)o5)c34)c3ccc4c(c3)sc3c5ccccc5ccc43)ccc2c1 ; c1ccc2cc(N(c3ccc4c(c3)oc3cccc(-c5nc6c(ccc7ccccc76)o5)c34)c3ccc4c(c3)sc3cc5ccccc5cc34)ccc2c1] 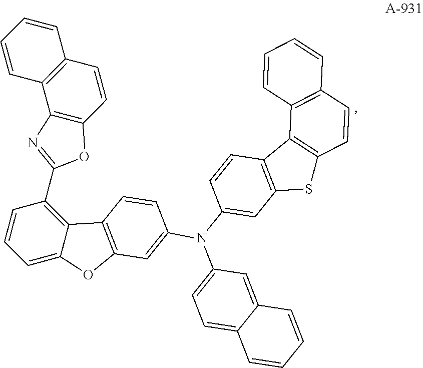 [SMILES: c1ccc2cc(N(c3ccc4c(c3)oc3cccc(-c5nc6c(ccc7ccccc76)o5)c34)c3ccc4c(c3)sc3ccc5ccccc5c34)ccc2c1] 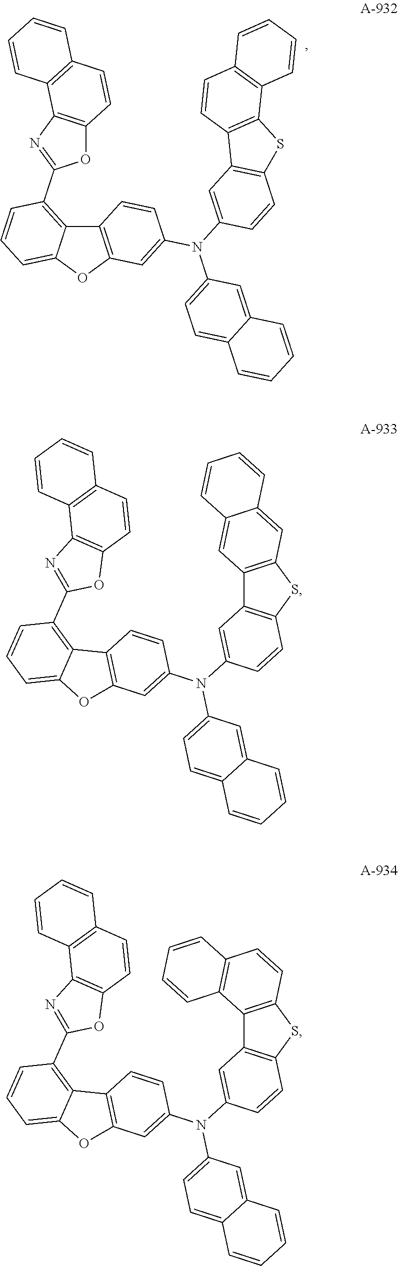 [SMILES: c1ccc2cc(N(c3ccc4c(c3)oc3cccc(-c5nc6c(ccc7ccccc76)o5)c34)c3ccc4sc5c6ccccc6ccc5c4c3)ccc2c1 ; c1ccc2cc(N(c3ccc4c(c3)oc3cccc(-c5nc6c(ccc7ccccc76)o5)c34)c3ccc4sc5cc6ccccc6cc5c4c3)ccc2c1 ; c1ccc2cc(N(c3ccc4c(c3)oc3cccc(-c5nc6c(ccc7ccccc76)o5)c34)c3ccc4sc5ccc6ccccc6c5c4c3)ccc2c1] 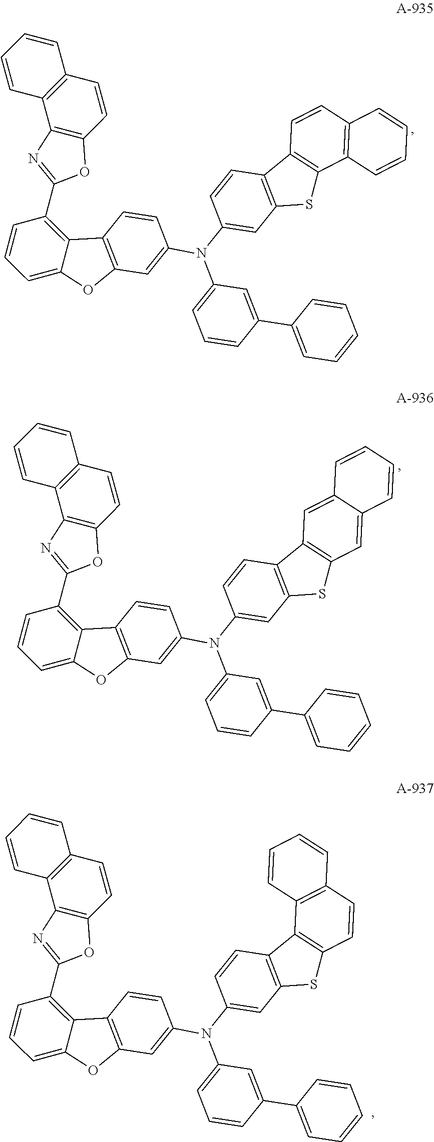 [SMILES: c1ccc(-c2cccc(N(c3ccc4c(c3)oc3cccc(-c5nc6c(ccc7ccccc76)o5)c34)c3ccc4c(c3)sc3c5ccccc5ccc43)c2)cc1 ; c1ccc(-c2cccc(N(c3ccc4c(c3)oc3cccc(-c5nc6c(ccc7ccccc76)o5)c34)c3ccc4c(c3)sc3cc5ccccc5cc34)c2)cc1 ; c1ccc(-c2cccc(N(c3ccc4c(c3)oc3cccc(-c5nc6c(ccc7ccccc76)o5)c34)c3ccc4c(c3)sc3ccc5ccccc5c34)c2)cc1] 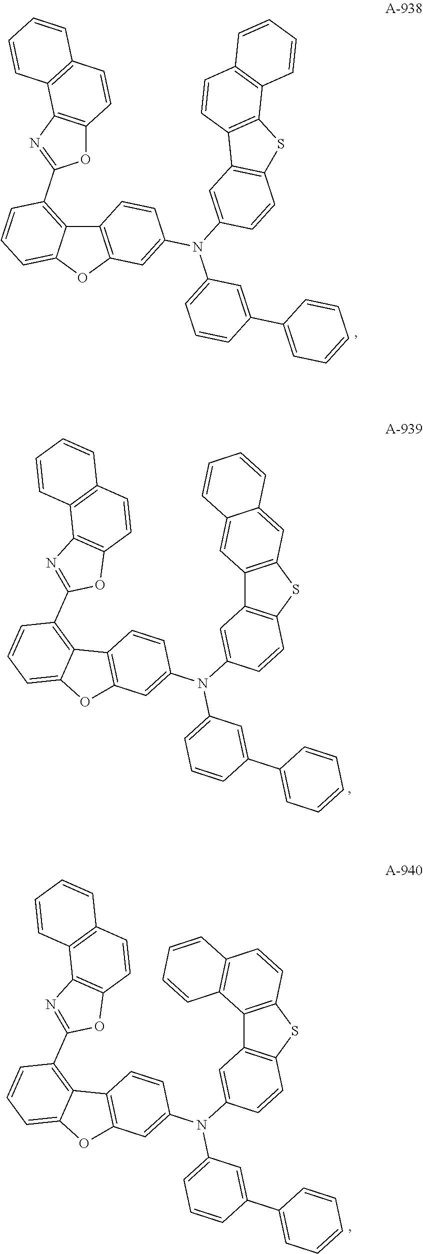 [SMILES: c1ccc(-c2cccc(N(c3ccc4c(c3)oc3cccc(-c5nc6c(ccc7ccccc76)o5)c34)c3ccc4sc5c6ccccc6ccc5c4c3)c2)cc1 ; c1ccc(-c2cccc(N(c3ccc4c(c3)oc3cccc(-c5nc6c(ccc7ccccc76)o5)c34)c3ccc4sc5cc6ccccc6cc5c4c3)c2)cc1 ; c1ccc(-c2cccc(N(c3ccc4c(c3)oc3cccc(-c5nc6c(ccc7ccccc76)o5)c34)c3ccc4sc5ccc6ccccc6c5c4c3)c2)cc1] 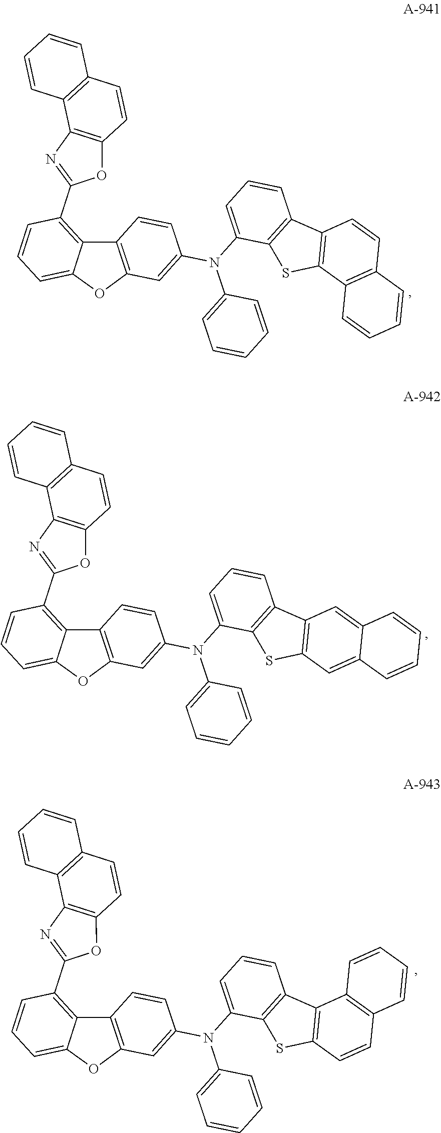 [SMILES: c1ccc(N(c2ccc3c(c2)oc2cccc(-c4nc5c(ccc6ccccc65)o4)c23)c2cccc3c2sc2c4ccccc4ccc32)cc1 ; c1ccc(N(c2ccc3c(c2)oc2cccc(-c4nc5c(ccc6ccccc65)o4)c23)c2cccc3c2sc2cc4ccccc4cc23)cc1 ; c1ccc(N(c2ccc3c(c2)oc2cccc(-c4nc5c(ccc6ccccc65)o4)c23)c2cccc3c2sc2ccc4ccccc4c23)cc1] 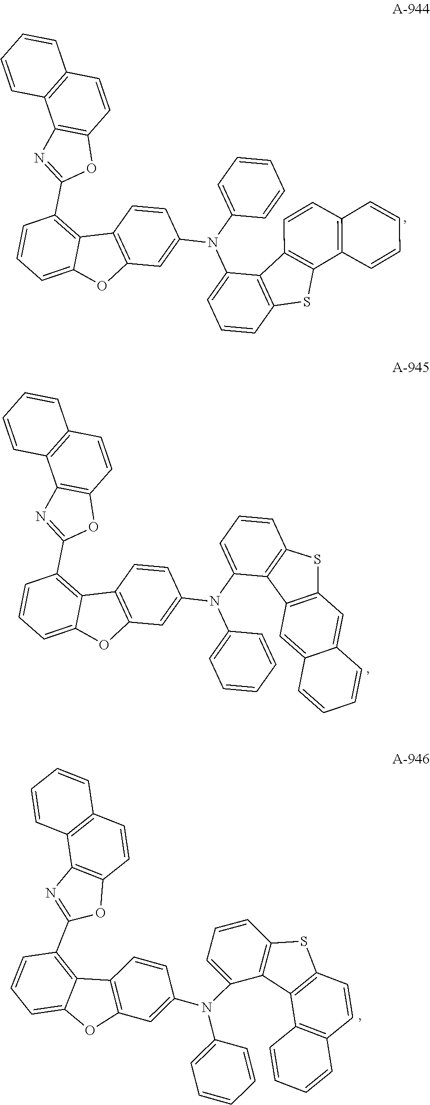 [SMILES: c1ccc(N(c2ccc3c(c2)oc2cccc(-c4nc5c(ccc6ccccc65)o4)c23)c2cccc3sc4c5ccccc5ccc4c23)cc1 ; c1ccc(N(c2ccc3c(c2)oc2cccc(-c4nc5c(ccc6ccccc65)o4)c23)c2cccc3sc4cc5ccccc5cc4c23)cc1 ; c1ccc(N(c2ccc3c(c2)oc2cccc(-c4nc5c(ccc6ccccc65)o4)c23)c2cccc3sc4ccc5ccccc5c4c23)cc1] 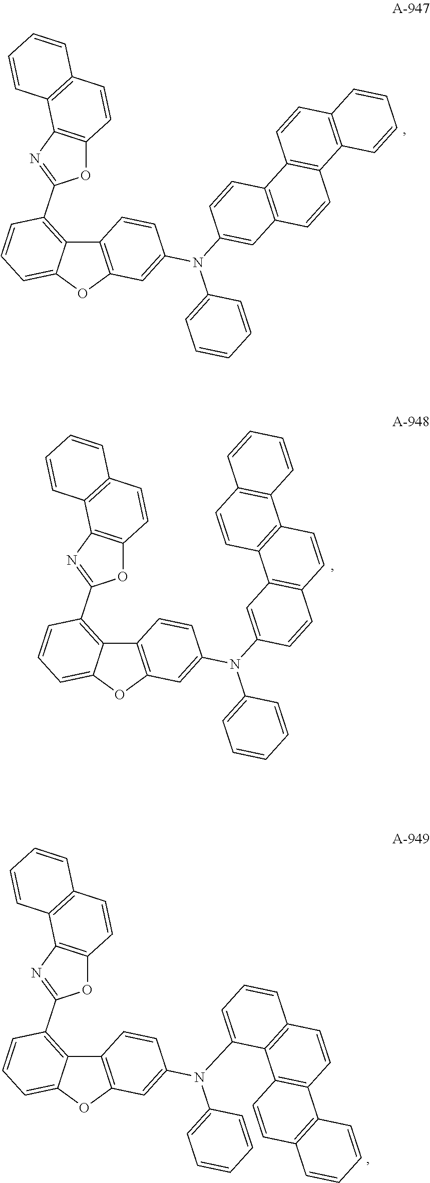 [SMILES: c1ccc(N(c2ccc3c(ccc4c5ccccc5ccc34)c2)c2ccc3c(c2)oc2cccc(-c4nc5c(ccc6ccccc65)o4)c23)cc1 ; c1ccc(N(c2ccc3c(c2)oc2cccc(-c4nc5c(ccc6ccccc65)o4)c23)c2ccc3ccc4c5ccccc5ccc4c3c2)cc1 ; c1ccc(N(c2ccc3c(c2)oc2cccc(-c4nc5c(ccc6ccccc65)o4)c23)c2cccc3ccc4c5ccccc5ccc4c23)cc1] 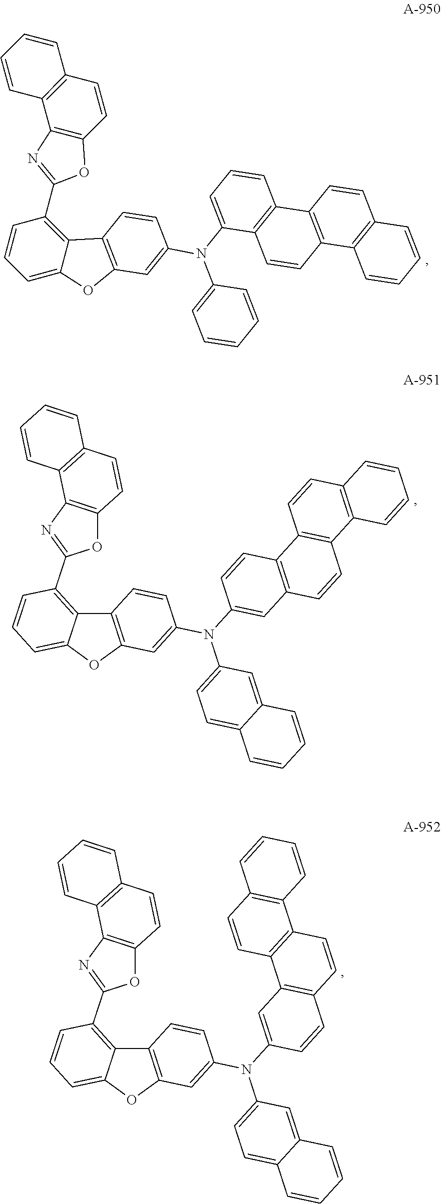 [SMILES: c1ccc(N(c2ccc3c(c2)oc2cccc(-c4nc5c(ccc6ccccc65)o4)c23)c2cccc3c2ccc2c4ccccc4ccc32)cc1 ; c1ccc2cc(N(c3ccc4c(ccc5c6ccccc6ccc45)c3)c3ccc4c(c3)oc3cccc(-c5nc6c(ccc7ccccc76)o5)c34)ccc2c1 ; c1ccc2cc(N(c3ccc4c(c3)oc3cccc(-c5nc6c(ccc7ccccc76)o5)c34)c3ccc4ccc5c6ccccc6ccc5c4c3)ccc2c1] 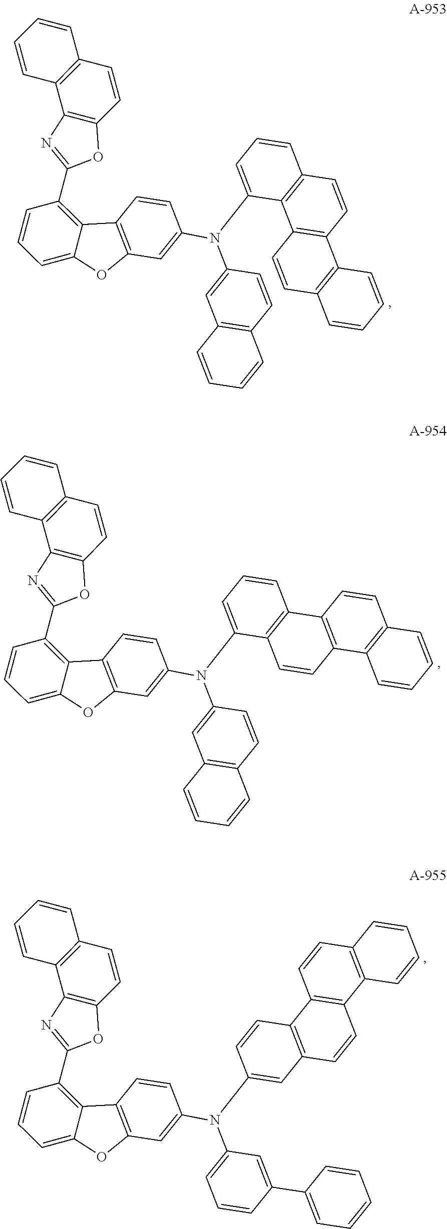 [SMILES: c1ccc2cc(N(c3ccc4c(c3)oc3cccc(-c5nc6c(ccc7ccccc76)o5)c34)c3cccc4ccc5c6ccccc6ccc5c34)ccc2c1 ; c1ccc2cc(N(c3ccc4c(c3)oc3cccc(-c5nc6c(ccc7ccccc76)o5)c34)c3cccc4c3ccc3c5ccccc5ccc43)ccc2c1 ; c1ccc(-c2cccc(N(c3ccc4c(ccc5c6ccccc6ccc45)c3)c3ccc4c(c3)oc3cccc(-c5nc6c(ccc7ccccc76)o5)c34)c2)cc1] 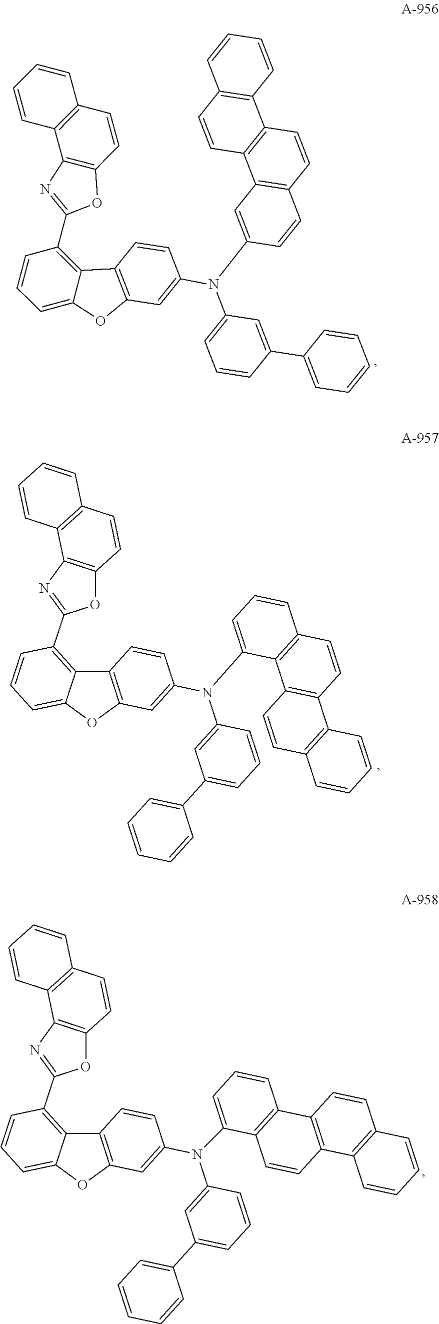 [SMILES: c1ccc(-c2cccc(N(c3ccc4c(c3)oc3cccc(-c5nc6c(ccc7ccccc76)o5)c34)c3ccc4ccc5c6ccccc6ccc5c4c3)c2)cc1 ; c1ccc(-c2cccc(N(c3ccc4c(c3)oc3cccc(-c5nc6c(ccc7ccccc76)o5)c34)c3cccc4ccc5c6ccccc6ccc5c34)c2)cc1 ; c1ccc(-c2cccc(N(c3ccc4c(c3)oc3cccc(-c5nc6c(ccc7ccccc76)o5)c34)c3cccc4c3ccc3c5ccccc5ccc43)c2)cc1] 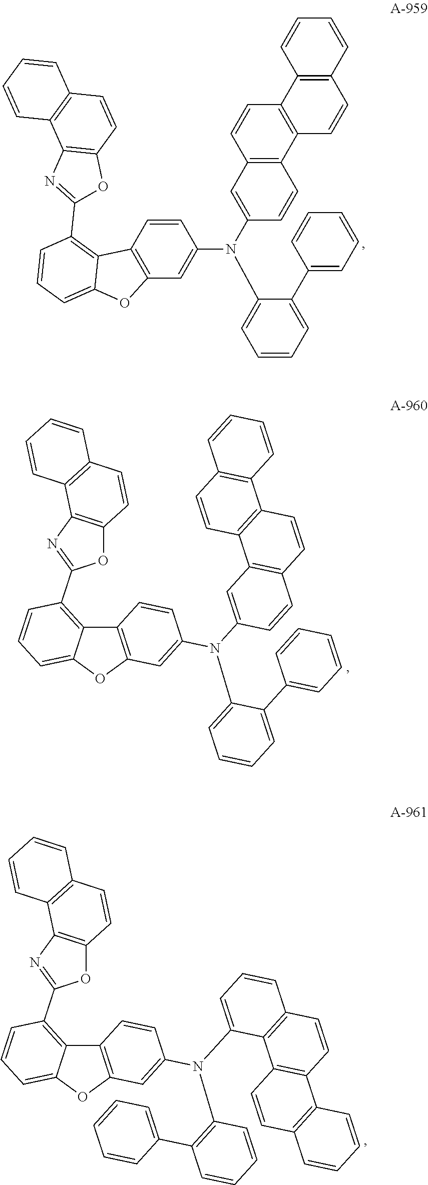 [SMILES: c1ccc(-c2ccccc2N(c2ccc3c(ccc4c5ccccc5ccc34)c2)c2ccc3c(c2)oc2cccc(-c4nc5c(ccc6ccccc65)o4)c23)cc1 ; c1ccc(-c2ccccc2N(c2ccc3c(c2)oc2cccc(-c4nc5c(ccc6ccccc65)o4)c23)c2ccc3ccc4c5ccccc5ccc4c3c2)cc1 ; c1ccc(-c2ccccc2N(c2ccc3c(c2)oc2cccc(-c4nc5c(ccc6ccccc65)o4)c23)c2cccc3ccc4c5ccccc5ccc4c23)cc1] 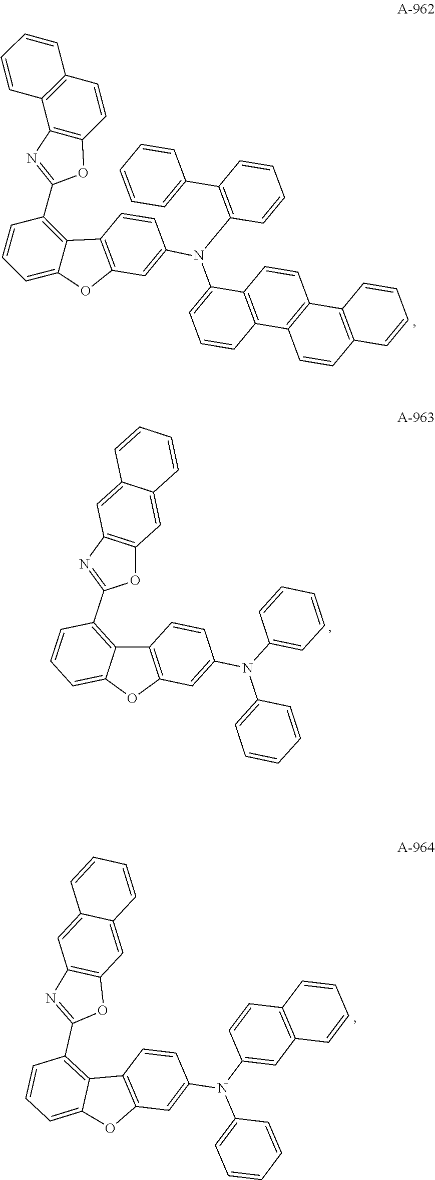 [SMILES: c1ccc(-c2ccccc2N(c2ccc3c(c2)oc2cccc(-c4nc5c(ccc6ccccc65)o4)c23)c2cccc3c2ccc2c4ccccc4ccc32)cc1 ; c1ccc(N(c2ccccc2)c2ccc3c(c2)oc2cccc(-c4nc5cc6ccccc6cc5o4)c23)cc1 ; c1ccc(N(c2ccc3ccccc3c2)c2ccc3c(c2)oc2cccc(-c4nc5cc6ccccc6cc5o4)c23)cc1] 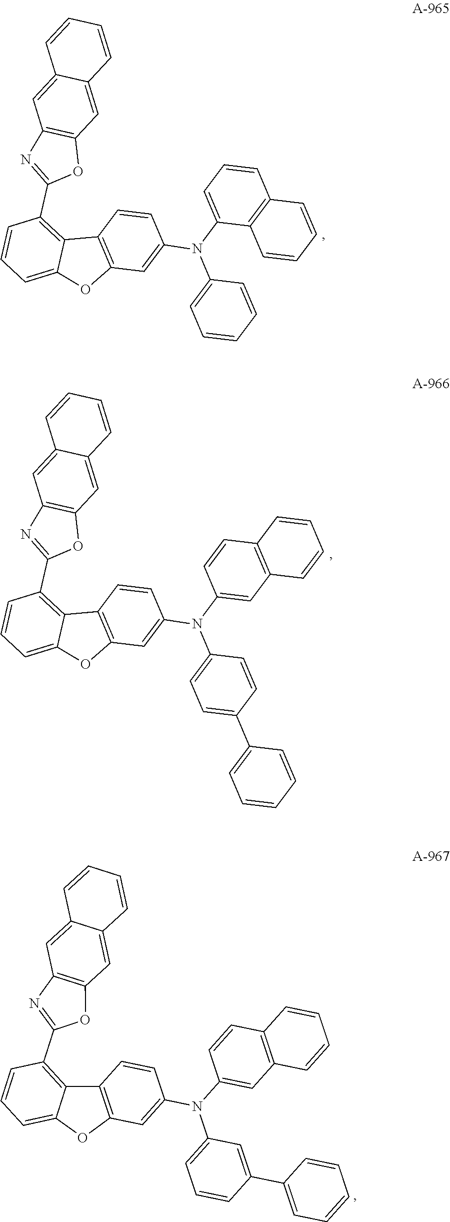 [SMILES: c1ccc(N(c2ccc3c(c2)oc2cccc(-c4nc5cc6ccccc6cc5o4)c23)c2cccc3ccccc23)cc1 ; c1ccc(-c2ccc(N(c3ccc4ccccc4c3)c3ccc4c(c3)oc3cccc(-c5nc6cc7ccccc7cc6o5)c34)cc2)cc1 ; c1ccc(-c2cccc(N(c3ccc4ccccc4c3)c3ccc4c(c3)oc3cccc(-c5nc6cc7ccccc7cc6o5)c34)c2)cc1] 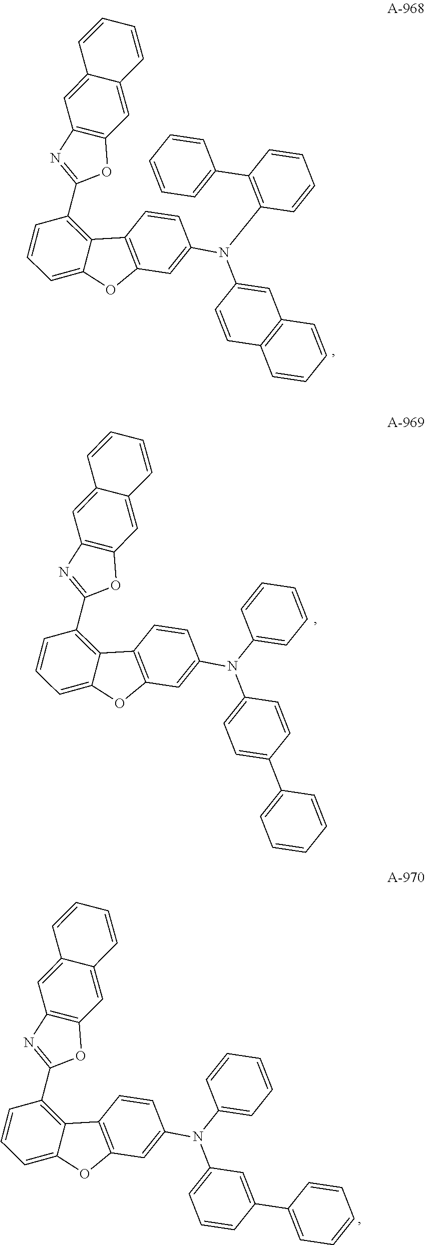 [SMILES: c1ccc(-c2ccccc2N(c2ccc3ccccc3c2)c2ccc3c(c2)oc2cccc(-c4nc5cc6ccccc6cc5o4)c23)cc1 ; c1ccc(-c2ccc(N(c3ccccc3)c3ccc4c(c3)oc3cccc(-c5nc6cc7ccccc7cc6o5)c34)cc2)cc1 ; c1ccc(-c2cccc(N(c3ccccc3)c3ccc4c(c3)oc3cccc(-c5nc6cc7ccccc7cc6o5)c34)c2)cc1] 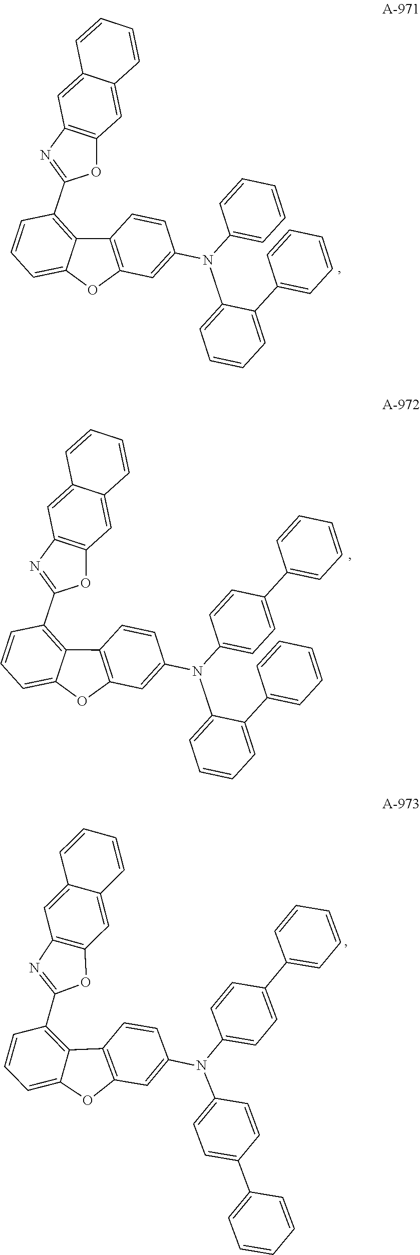 [SMILES: c1ccc(-c2ccccc2N(c2ccccc2)c2ccc3c(c2)oc2cccc(-c4nc5cc6ccccc6cc5o4)c23)cc1 ; c1ccc(-c2ccc(N(c3ccc4c(c3)oc3cccc(-c5nc6cc7ccccc7cc6o5)c34)c3ccccc3-c3ccccc3)cc2)cc1 ; c1ccc(-c2ccc(N(c3ccc(-c4ccccc4)cc3)c3ccc4c(c3)oc3cccc(-c5nc6cc7ccccc7cc6o5)c34)cc2)cc1] 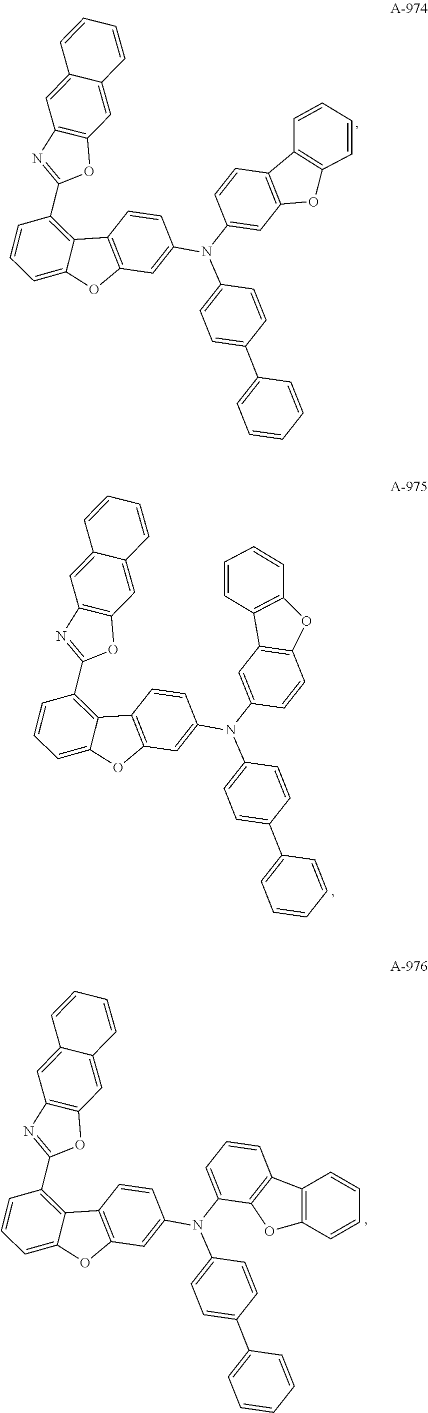 [SMILES: c1ccc(-c2ccc(N(c3ccc4c(c3)oc3ccccc34)c3ccc4c(c3)oc3cccc(-c5nc6cc7ccccc7cc6o5)c34)cc2)cc1 ; c1ccc(-c2ccc(N(c3ccc4c(c3)oc3cccc(-c5nc6cc7ccccc7cc6o5)c34)c3ccc4oc5ccccc5c4c3)cc2)cc1 ; c1ccc(-c2ccc(N(c3ccc4c(c3)oc3cccc(-c5nc6cc7ccccc7cc6o5)c34)c3cccc4c3oc3ccccc34)cc2)cc1] 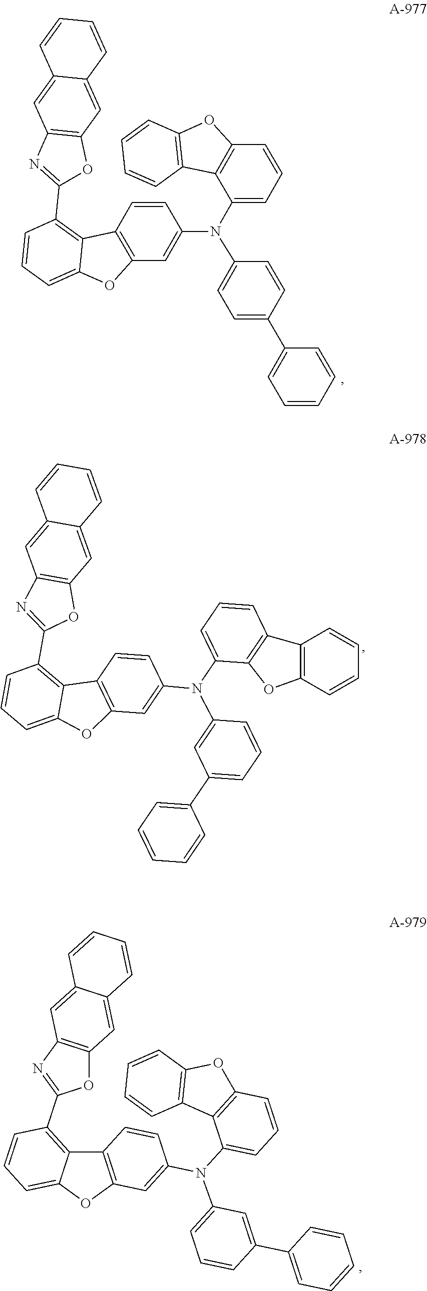 [SMILES: c1ccc(-c2ccc(N(c3ccc4c(c3)oc3cccc(-c5nc6cc7ccccc7cc6o5)c34)c3cccc4oc5ccccc5c34)cc2)cc1 ; c1ccc(-c2cccc(N(c3ccc4c(c3)oc3cccc(-c5nc6cc7ccccc7cc6o5)c34)c3cccc4c3oc3ccccc34)c2)cc1 ; c1ccc(-c2cccc(N(c3ccc4c(c3)oc3cccc(-c5nc6cc7ccccc7cc6o5)c34)c3cccc4oc5ccccc5c34)c2)cc1] 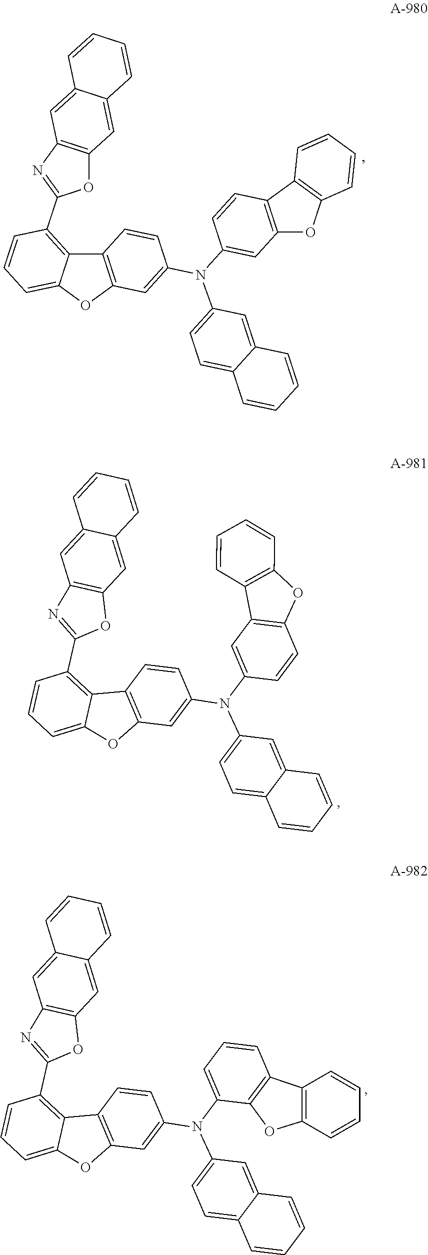 [SMILES: c1ccc2cc(N(c3ccc4c(c3)oc3ccccc34)c3ccc4c(c3)oc3cccc(-c5nc6cc7ccccc7cc6o5)c34)ccc2c1 ; c1ccc2cc(N(c3ccc4c(c3)oc3cccc(-c5nc6cc7ccccc7cc6o5)c34)c3ccc4oc5ccccc5c4c3)ccc2c1 ; c1ccc2cc(N(c3ccc4c(c3)oc3cccc(-c5nc6cc7ccccc7cc6o5)c34)c3cccc4c3oc3ccccc34)ccc2c1] 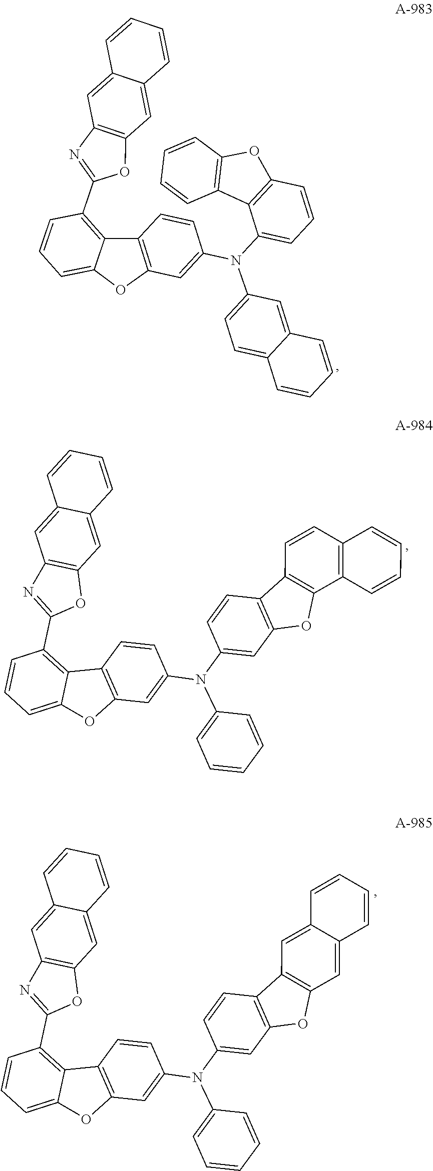 [SMILES: c1ccc2cc(N(c3ccc4c(c3)oc3cccc(-c5nc6cc7ccccc7cc6o5)c34)c3cccc4oc5ccccc5c34)ccc2c1 ; c1ccc(N(c2ccc3c(c2)oc2c4ccccc4ccc32)c2ccc3c(c2)oc2cccc(-c4nc5cc6ccccc6cc5o4)c23)cc1 ; c1ccc(N(c2ccc3c(c2)oc2cc4ccccc4cc23)c2ccc3c(c2)oc2cccc(-c4nc5cc6ccccc6cc5o4)c23)cc1] 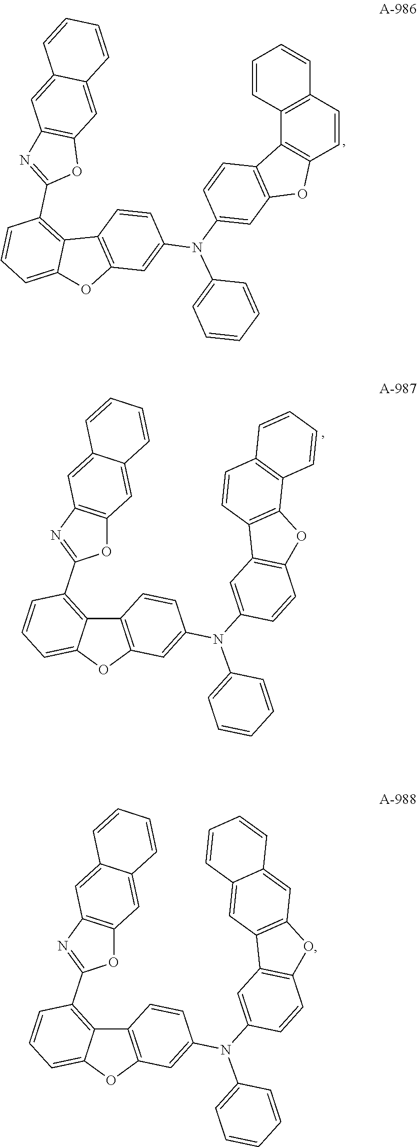 [SMILES: c1ccc(N(c2ccc3c(c2)oc2cccc(-c4nc5cc6ccccc6cc5o4)c23)c2ccc3c(c2)oc2ccc4ccccc4c23)cc1 ; c1ccc(N(c2ccc3c(c2)oc2cccc(-c4nc5cc6ccccc6cc5o4)c23)c2ccc3oc4c5ccccc5ccc4c3c2)cc1 ; c1ccc(N(c2ccc3c(c2)oc2cccc(-c4nc5cc6ccccc6cc5o4)c23)c2ccc3oc4cc5ccccc5cc4c3c2)cc1] 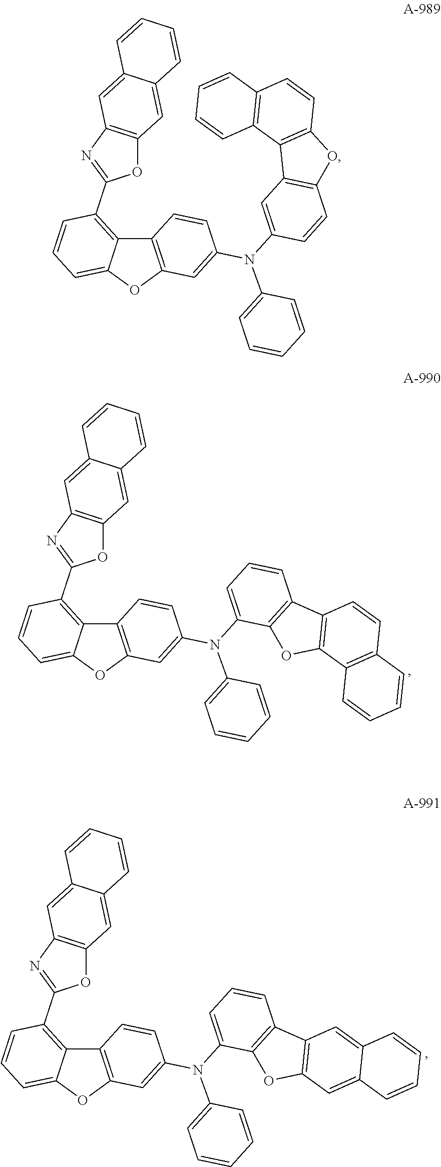 [SMILES: c1ccc(N(c2ccc3c(c2)oc2cccc(-c4nc5cc6ccccc6cc5o4)c23)c2ccc3oc4ccc5ccccc5c4c3c2)cc1 ; c1ccc(N(c2ccc3c(c2)oc2cccc(-c4nc5cc6ccccc6cc5o4)c23)c2cccc3c2oc2c4ccccc4ccc32)cc1 ; c1ccc(N(c2ccc3c(c2)oc2cccc(-c4nc5cc6ccccc6cc5o4)c23)c2cccc3c2oc2cc4ccccc4cc23)cc1] 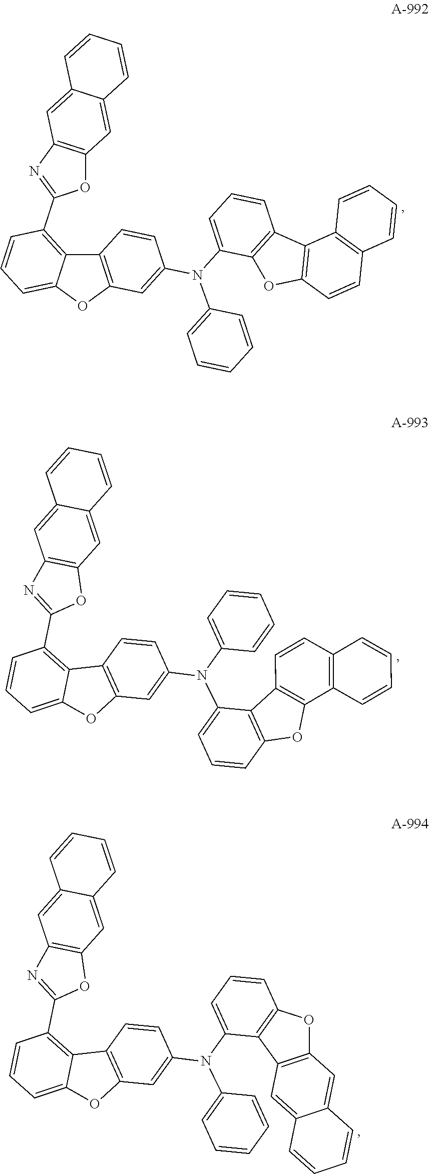 [SMILES: c1ccc(N(c2ccc3c(c2)oc2cccc(-c4nc5cc6ccccc6cc5o4)c23)c2cccc3c2oc2ccc4ccccc4c23)cc1 ; c1ccc(N(c2ccc3c(c2)oc2cccc(-c4nc5cc6ccccc6cc5o4)c23)c2cccc3oc4c5ccccc5ccc4c23)cc1 ; c1ccc(N(c2ccc3c(c2)oc2cccc(-c4nc5cc6ccccc6cc5o4)c23)c2cccc3oc4cc5ccccc5cc4c23)cc1] 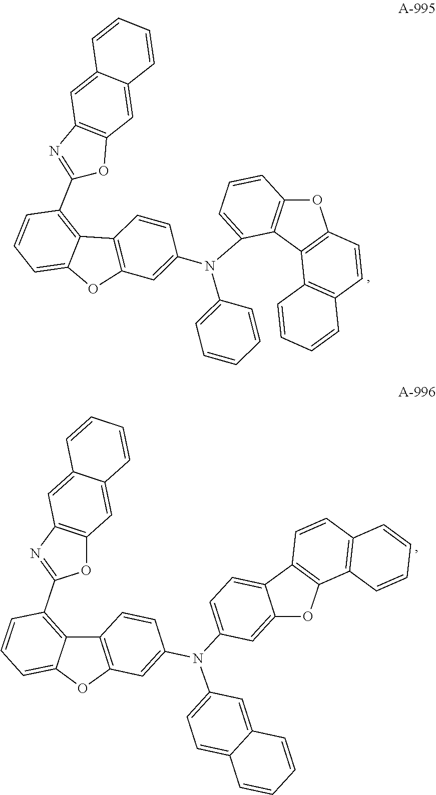 [SMILES: c1ccc(N(c2ccc3c(c2)oc2cccc(-c4nc5cc6ccccc6cc5o4)c23)c2cccc3oc4ccc5ccccc5c4c23)cc1 ; c1ccc2cc(N(c3ccc4c(c3)oc3c5ccccc5ccc43)c3ccc4c(c3)oc3cccc(-c5nc6cc7ccccc7cc6o5)c34)ccc2c1] 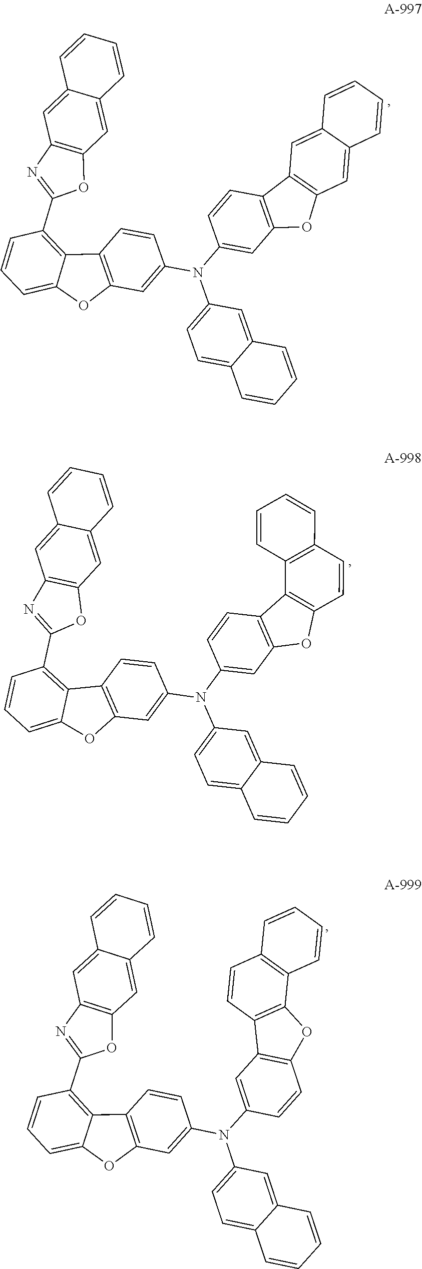 [SMILES: c1ccc2cc(N(c3ccc4c(c3)oc3cc5ccccc5cc34)c3ccc4c(c3)oc3cccc(-c5nc6cc7ccccc7cc6o5)c34)ccc2c1 ; c1ccc2cc(N(c3ccc4c(c3)oc3cccc(-c5nc6cc7ccccc7cc6o5)c34)c3ccc4c(c3)oc3ccc5ccccc5c34)ccc2c1 ; c1ccc2cc(N(c3ccc4c(c3)oc3cccc(-c5nc6cc7ccccc7cc6o5)c34)c3ccc4oc5c6ccccc6ccc5c4c3)ccc2c1] 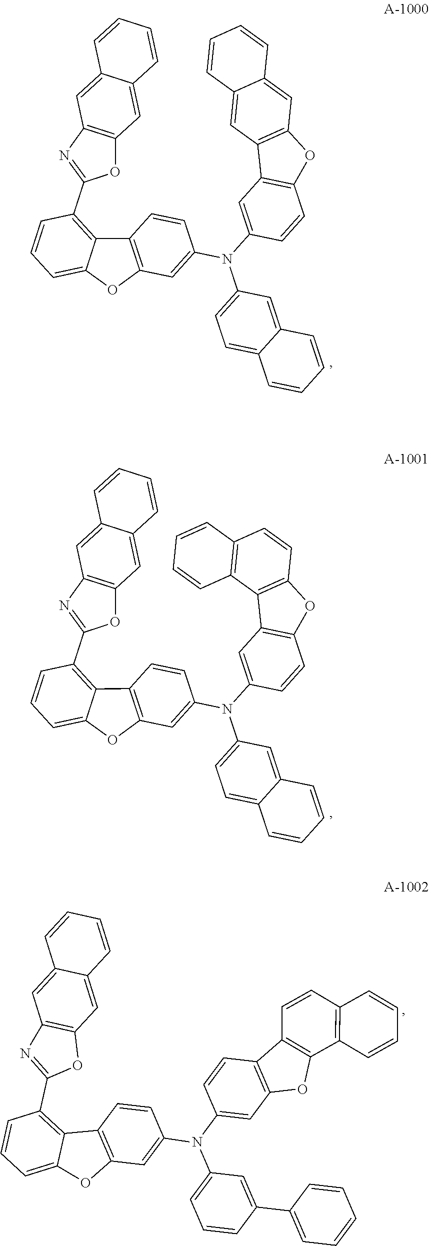 [SMILES: c1ccc2cc(N(c3ccc4c(c3)oc3cccc(-c5nc6cc7ccccc7cc6o5)c34)c3ccc4oc5cc6ccccc6cc5c4c3)ccc2c1 ; c1ccc2cc(N(c3ccc4c(c3)oc3cccc(-c5nc6cc7ccccc7cc6o5)c34)c3ccc4oc5ccc6ccccc6c5c4c3)ccc2c1 ; c1ccc(-c2cccc(N(c3ccc4c(c3)oc3c5ccccc5ccc43)c3ccc4c(c3)oc3cccc(-c5nc6cc7ccccc7cc6o5)c34)c2)cc1] 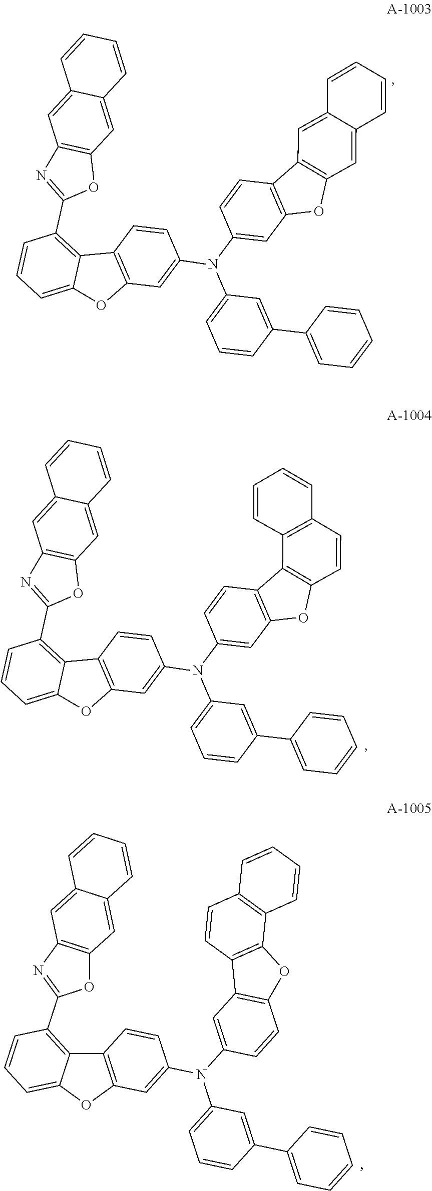 [SMILES: c1ccc(-c2cccc(N(c3ccc4c(c3)oc3cc5ccccc5cc34)c3ccc4c(c3)oc3cccc(-c5nc6cc7ccccc7cc6o5)c34)c2)cc1 ; c1ccc(-c2cccc(N(c3ccc4c(c3)oc3cccc(-c5nc6cc7ccccc7cc6o5)c34)c3ccc4c(c3)oc3ccc5ccccc5c34)c2)cc1 ; c1ccc(-c2cccc(N(c3ccc4c(c3)oc3cccc(-c5nc6cc7ccccc7cc6o5)c34)c3ccc4oc5c6ccccc6ccc5c4c3)c2)cc1] 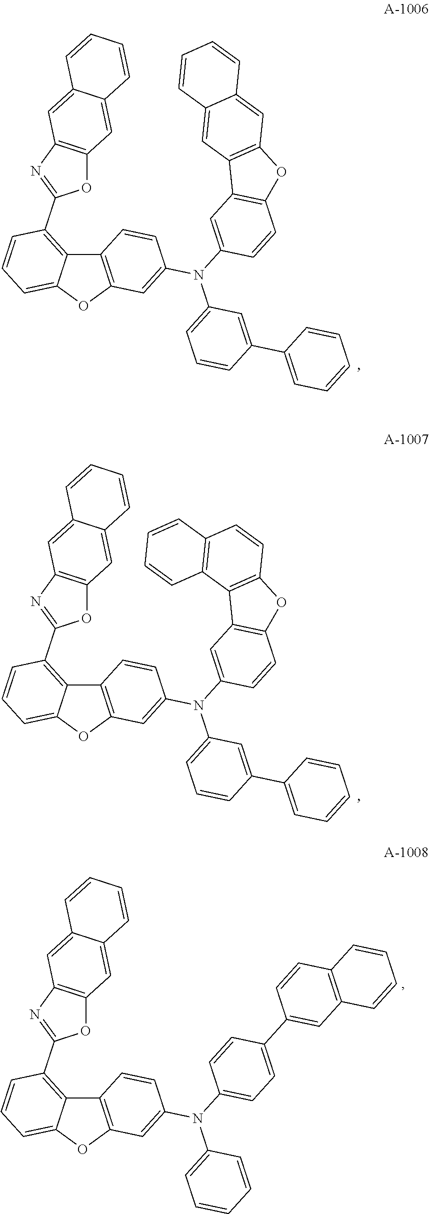 [SMILES: c1ccc(-c2cccc(N(c3ccc4c(c3)oc3cccc(-c5nc6cc7ccccc7cc6o5)c34)c3ccc4oc5cc6ccccc6cc5c4c3)c2)cc1 ; c1ccc(-c2cccc(N(c3ccc4c(c3)oc3cccc(-c5nc6cc7ccccc7cc6o5)c34)c3ccc4oc5ccc6ccccc6c5c4c3)c2)cc1 ; c1ccc(N(c2ccc(-c3ccc4ccccc4c3)cc2)c2ccc3c(c2)oc2cccc(-c4nc5cc6ccccc6cc5o4)c23)cc1] 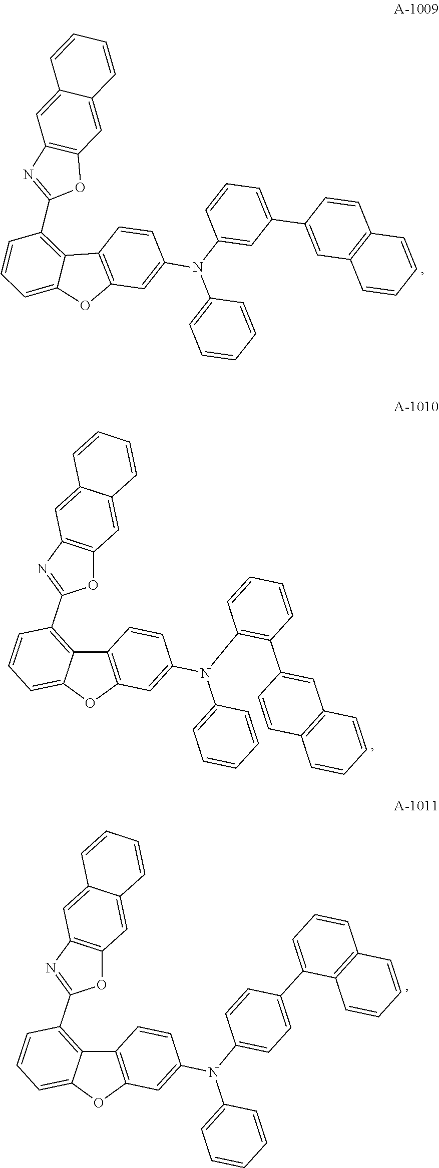 [SMILES: c1ccc(N(c2cccc(-c3ccc4ccccc4c3)c2)c2ccc3c(c2)oc2cccc(-c4nc5cc6ccccc6cc5o4)c23)cc1 ; c1ccc(N(c2ccc3c(c2)oc2cccc(-c4nc5cc6ccccc6cc5o4)c23)c2ccccc2-c2ccc3ccccc3c2)cc1 ; c1ccc(N(c2ccc(-c3cccc4ccccc34)cc2)c2ccc3c(c2)oc2cccc(-c4nc5cc6ccccc6cc5o4)c23)cc1] 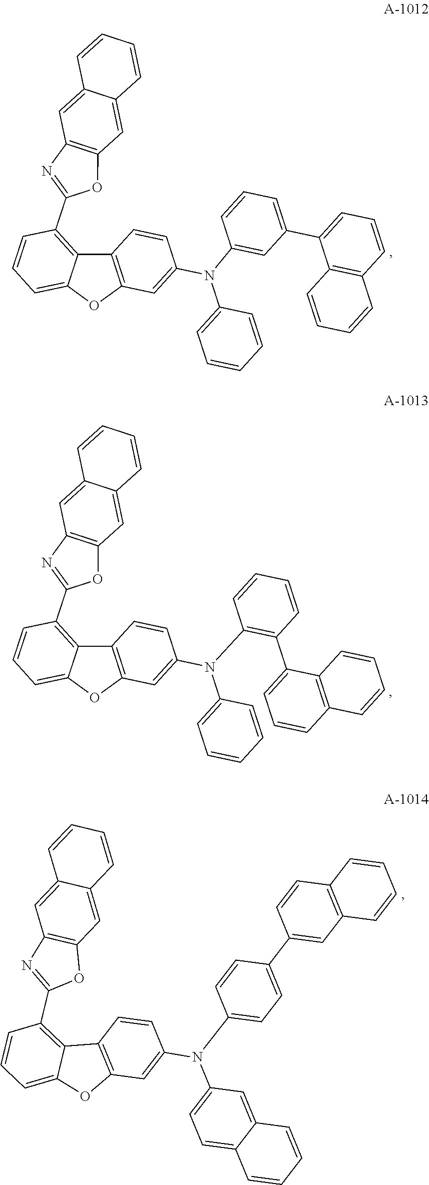 [SMILES: c1ccc(N(c2cccc(-c3cccc4ccccc34)c2)c2ccc3c(c2)oc2cccc(-c4nc5cc6ccccc6cc5o4)c23)cc1 ; c1ccc(N(c2ccc3c(c2)oc2cccc(-c4nc5cc6ccccc6cc5o4)c23)c2ccccc2-c2cccc3ccccc23)cc1 ; c1ccc2cc(-c3ccc(N(c4ccc5ccccc5c4)c4ccc5c(c4)oc4cccc(-c6nc7cc8ccccc8cc7o6)c45)cc3)ccc2c1] 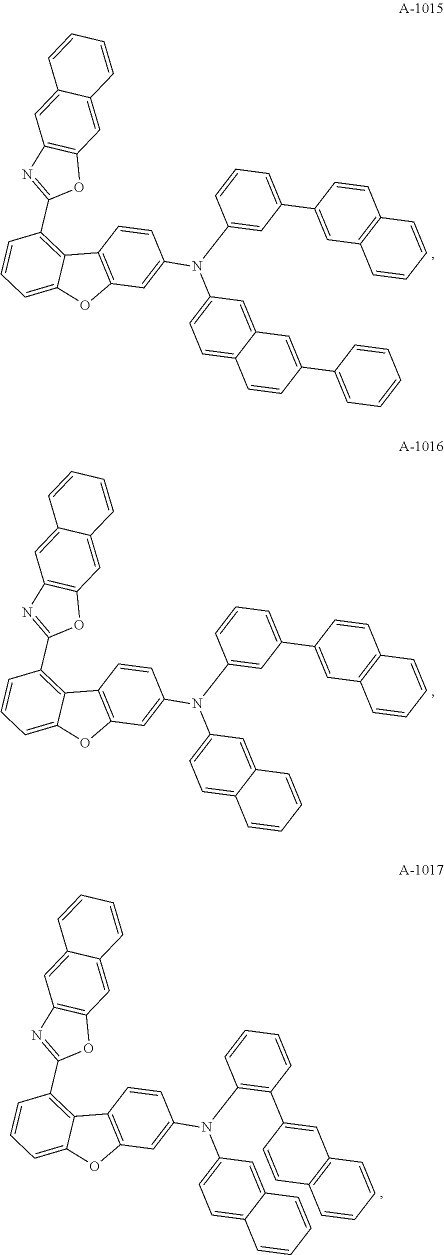 [SMILES: c1ccc(-c2ccc3ccc(N(c4cccc(-c5ccc6ccccc6c5)c4)c4ccc5c(c4)oc4cccc(-c6nc7cc8ccccc8cc7o6)c45)cc3c2)cc1 ; c1cc(-c2ccc3ccccc3c2)cc(N(c2ccc3ccccc3c2)c2ccc3c(c2)oc2cccc(-c4nc5cc6ccccc6cc5o4)c23)c1 ; c1ccc(N(c2ccc3ccccc3c2)c2ccc3c(c2)oc2cccc(-c4nc5cc6ccccc6cc5o4)c23)c(-c2ccc3ccccc3c2)c1] 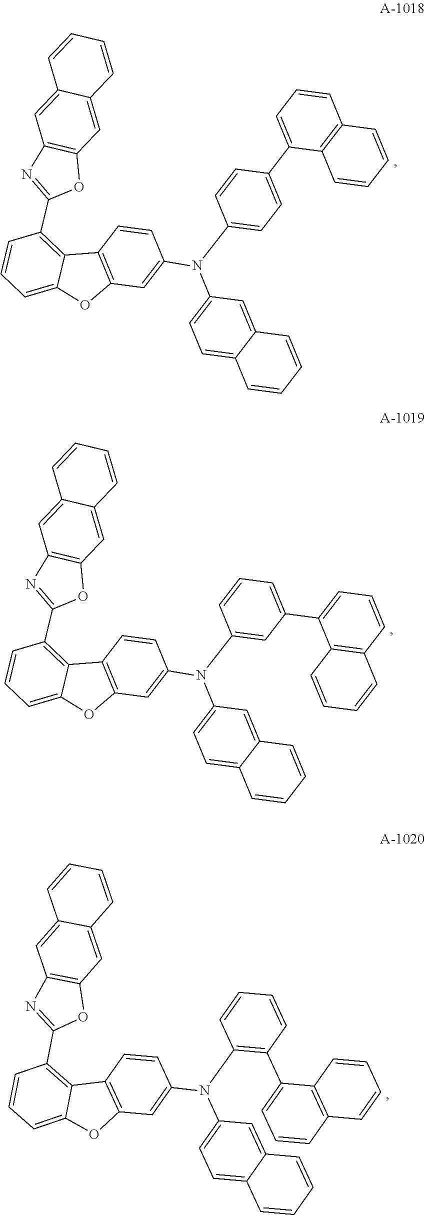 [SMILES: c1ccc2cc(N(c3ccc(-c4cccc5ccccc45)cc3)c3ccc4c(c3)oc3cccc(-c5nc6cc7ccccc7cc6o5)c34)ccc2c1 ; c1cc(-c2cccc3ccccc23)cc(N(c2ccc3ccccc3c2)c2ccc3c(c2)oc2cccc(-c4nc5cc6ccccc6cc5o4)c23)c1 ; c1ccc(N(c2ccc3ccccc3c2)c2ccc3c(c2)oc2cccc(-c4nc5cc6ccccc6cc5o4)c23)c(-c2cccc3ccccc23)c1] 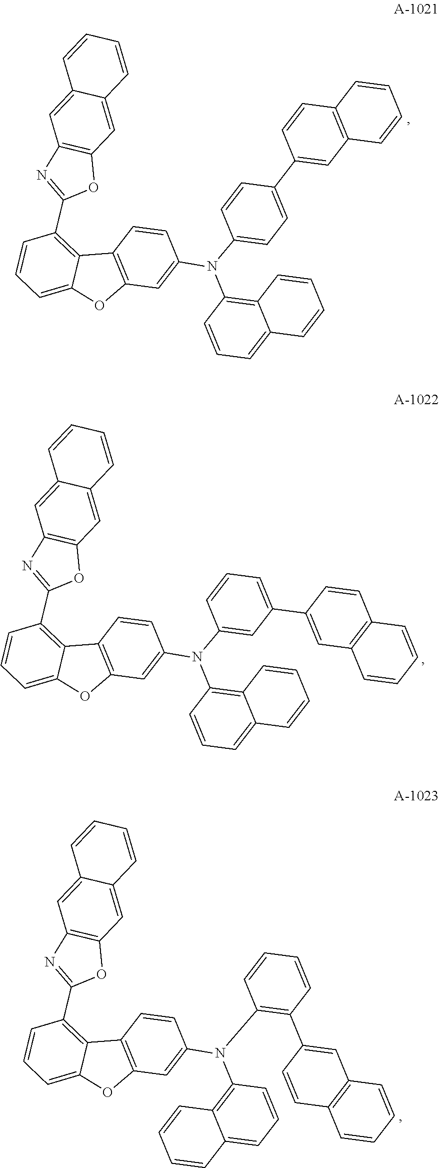 [SMILES: c1ccc2cc(-c3ccc(N(c4ccc5c(c4)oc4cccc(-c6nc7cc8ccccc8cc7o6)c45)c4cccc5ccccc45)cc3)ccc2c1 ; c1cc(-c2ccc3ccccc3c2)cc(N(c2ccc3c(c2)oc2cccc(-c4nc5cc6ccccc6cc5o4)c23)c2cccc3ccccc23)c1 ; c1ccc(N(c2ccc3c(c2)oc2cccc(-c4nc5cc6ccccc6cc5o4)c23)c2cccc3ccccc23)c(-c2ccc3ccccc3c2)c1] 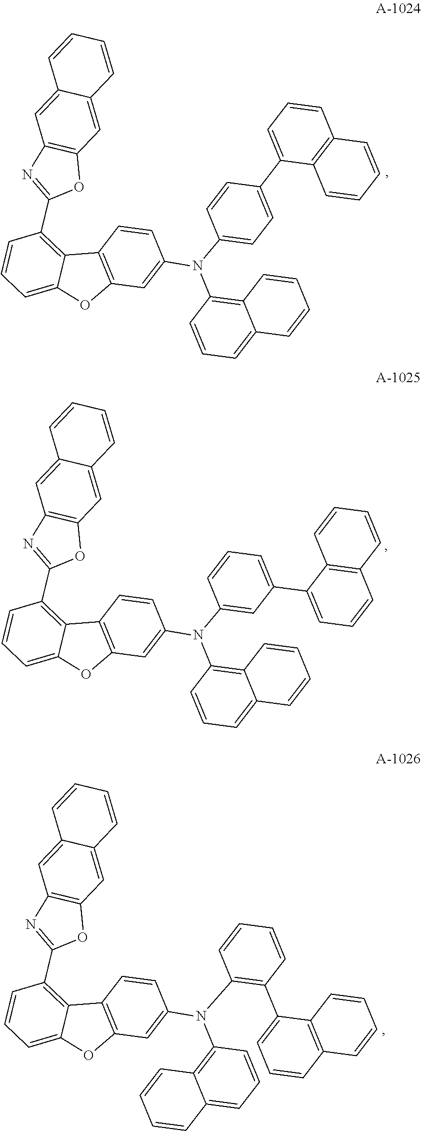 [SMILES: c1ccc2cc3oc(-c4cccc5oc6cc(N(c7ccc(-c8cccc9ccccc89)cc7)c7cccc8ccccc78)ccc6c45)nc3cc2c1 ; c1cc(-c2cccc3ccccc23)cc(N(c2ccc3c(c2)oc2cccc(-c4nc5cc6ccccc6cc5o4)c23)c2cccc3ccccc23)c1 ; c1ccc(N(c2ccc3c(c2)oc2cccc(-c4nc5cc6ccccc6cc5o4)c23)c2cccc3ccccc23)c(-c2cccc3ccccc23)c1] 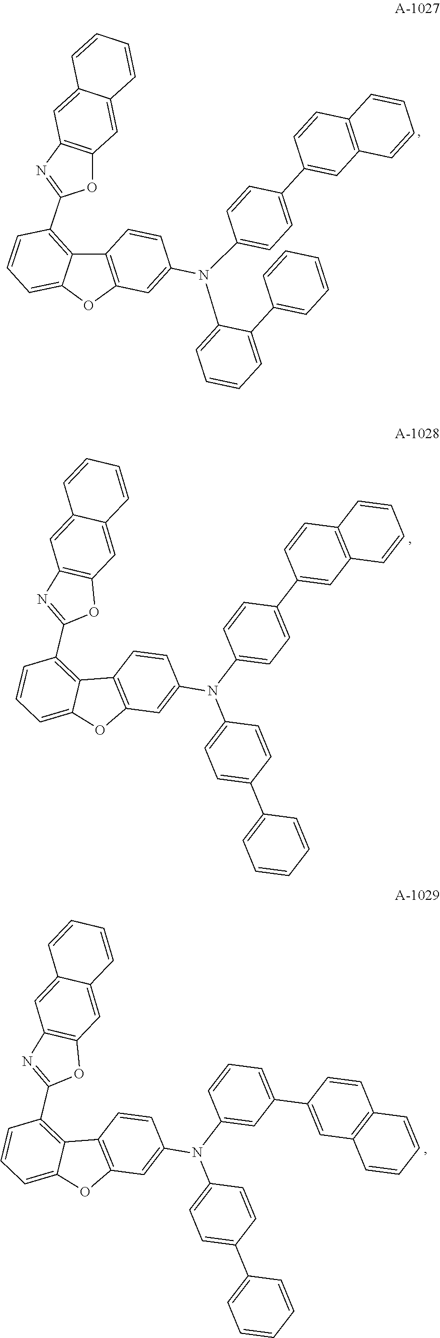 [SMILES: c1ccc(-c2ccccc2N(c2ccc(-c3ccc4ccccc4c3)cc2)c2ccc3c(c2)oc2cccc(-c4nc5cc6ccccc6cc5o4)c23)cc1 ; c1ccc(-c2ccc(N(c3ccc(-c4ccc5ccccc5c4)cc3)c3ccc4c(c3)oc3cccc(-c5nc6cc7ccccc7cc6o5)c34)cc2)cc1 ; c1ccc(-c2ccc(N(c3cccc(-c4ccc5ccccc5c4)c3)c3ccc4c(c3)oc3cccc(-c5nc6cc7ccccc7cc6o5)c34)cc2)cc1] 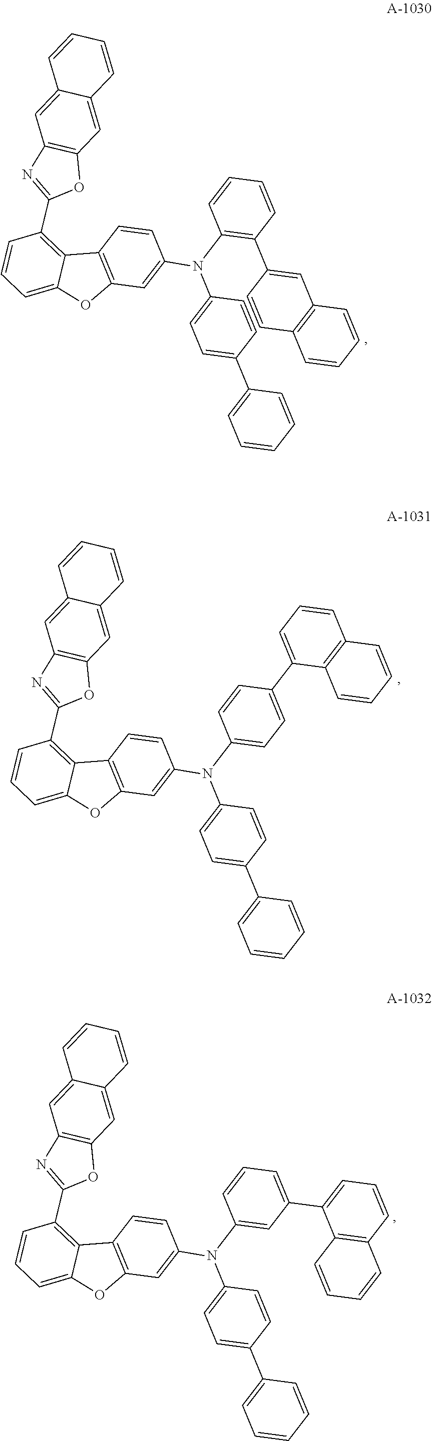 [SMILES: c1ccc(-c2ccc(N(c3ccc4c(c3)oc3cccc(-c5nc6cc7ccccc7cc6o5)c34)c3ccccc3-c3ccc4ccccc4c3)cc2)cc1 ; c1ccc(-c2ccc(N(c3ccc(-c4cccc5ccccc45)cc3)c3ccc4c(c3)oc3cccc(-c5nc6cc7ccccc7cc6o5)c34)cc2)cc1 ; c1ccc(-c2ccc(N(c3cccc(-c4cccc5ccccc45)c3)c3ccc4c(c3)oc3cccc(-c5nc6cc7ccccc7cc6o5)c34)cc2)cc1] 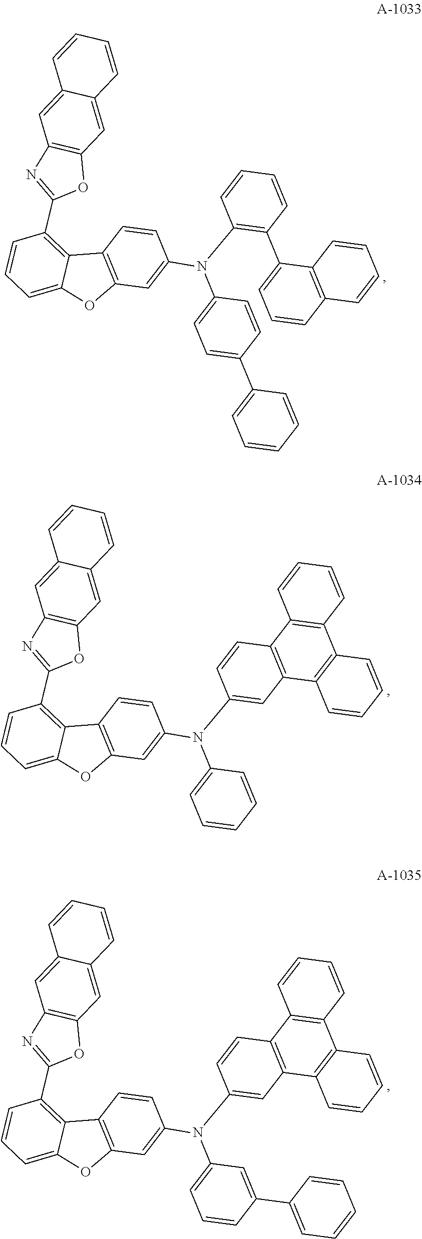 [SMILES: c1ccc(-c2ccc(N(c3ccc4c(c3)oc3cccc(-c5nc6cc7ccccc7cc6o5)c34)c3ccccc3-c3cccc4ccccc34)cc2)cc1 ; c1ccc(N(c2ccc3c(c2)oc2cccc(-c4nc5cc6ccccc6cc5o4)c23)c2ccc3c4ccccc4c4ccccc4c3c2)cc1 ; c1ccc(-c2cccc(N(c3ccc4c(c3)oc3cccc(-c5nc6cc7ccccc7cc6o5)c34)c3ccc4c5ccccc5c5ccccc5c4c3)c2)cc1] 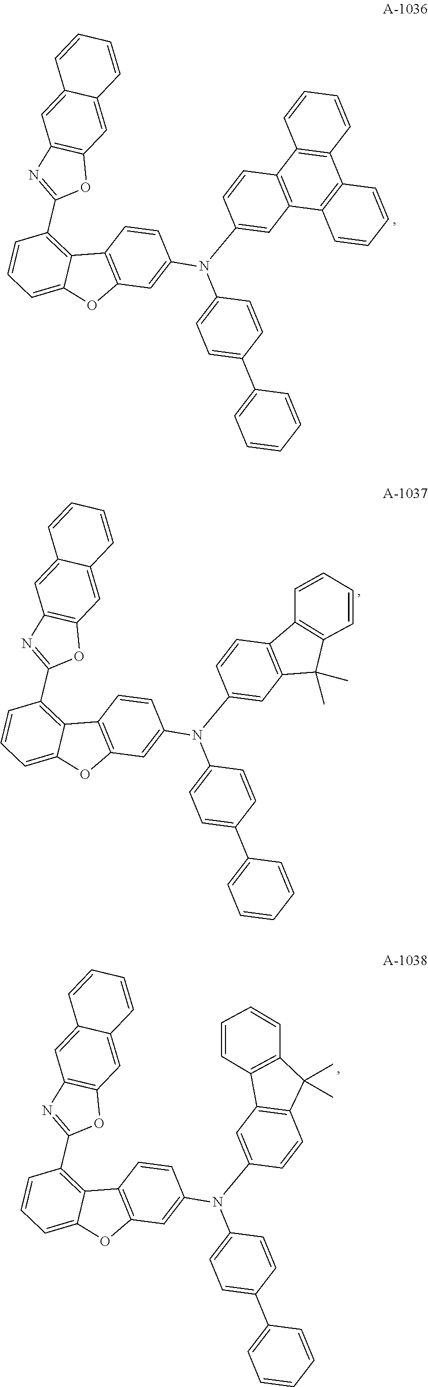 [SMILES: c1ccc(-c2ccc(N(c3ccc4c(c3)oc3cccc(-c5nc6cc7ccccc7cc6o5)c34)c3ccc4c5ccccc5c5ccccc5c4c3)cc2)cc1 ; CC1(C)c2ccccc2-c2ccc(N(c3ccc(-c4ccccc4)cc3)c3ccc4c(c3)oc3cccc(-c5nc6cc7ccccc7cc6o5)c34)cc21 ; CC1(C)c2ccccc2-c2cc(N(c3ccc(-c4ccccc4)cc3)c3ccc4c(c3)oc3cccc(-c5nc6cc7ccccc7cc6o5)c34)ccc21] 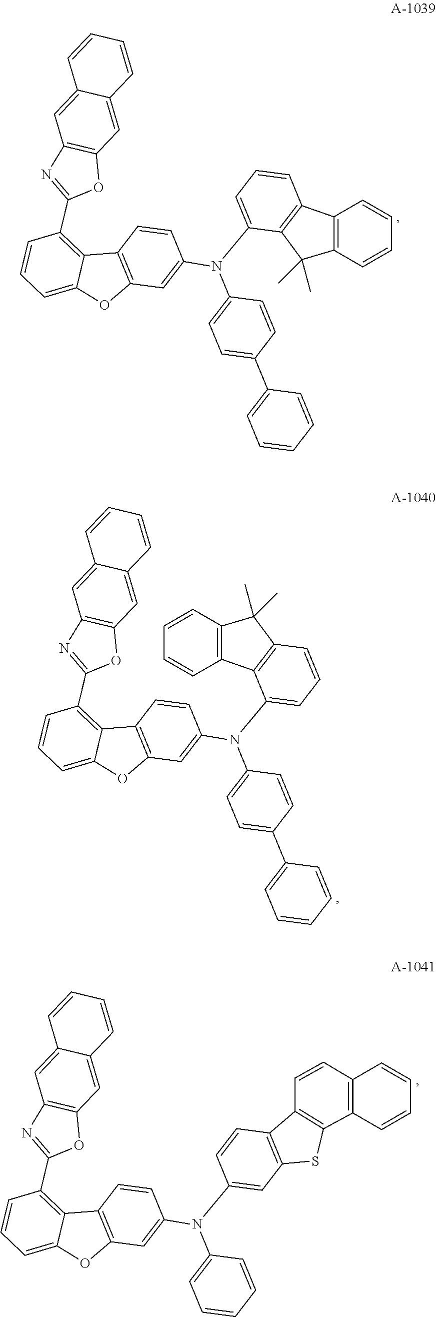 [SMILES: CC1(C)c2ccccc2-c2cccc(N(c3ccc(-c4ccccc4)cc3)c3ccc4c(c3)oc3cccc(-c5nc6cc7ccccc7cc6o5)c34)c21 ; CC1(C)c2ccccc2-c2c(N(c3ccc(-c4ccccc4)cc3)c3ccc4c(c3)oc3cccc(-c5nc6cc7ccccc7cc6o5)c34)cccc21 ; c1ccc(N(c2ccc3c(c2)oc2cccc(-c4nc5cc6ccccc6cc5o4)c23)c2ccc3c(c2)sc2c4ccccc4ccc32)cc1] 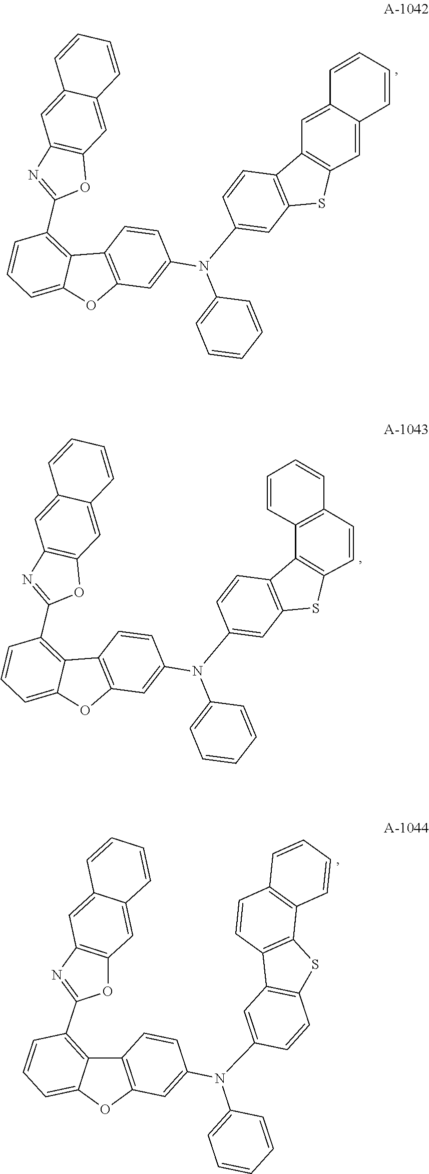 [SMILES: c1ccc(N(c2ccc3c(c2)oc2cccc(-c4nc5cc6ccccc6cc5o4)c23)c2ccc3c(c2)sc2cc4ccccc4cc23)cc1 ; c1ccc(N(c2ccc3c(c2)oc2cccc(-c4nc5cc6ccccc6cc5o4)c23)c2ccc3c(c2)sc2ccc4ccccc4c23)cc1 ; c1ccc(N(c2ccc3c(c2)oc2cccc(-c4nc5cc6ccccc6cc5o4)c23)c2ccc3sc4c5ccccc5ccc4c3c2)cc1] 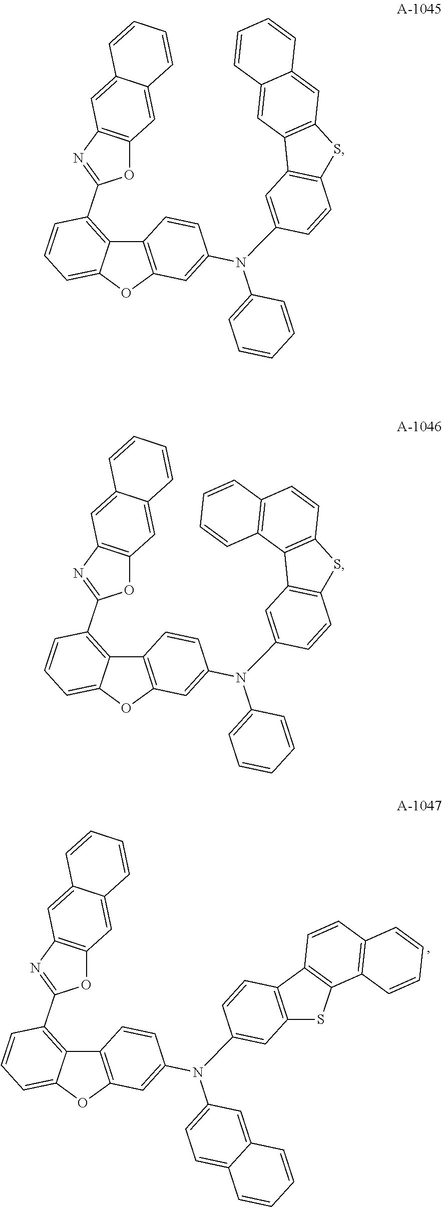 [SMILES: c1ccc(N(c2ccc3c(c2)oc2cccc(-c4nc5cc6ccccc6cc5o4)c23)c2ccc3sc4cc5ccccc5cc4c3c2)cc1 ; c1ccc(N(c2ccc3c(c2)oc2cccc(-c4nc5cc6ccccc6cc5o4)c23)c2ccc3sc4ccc5ccccc5c4c3c2)cc1 ; c1ccc2cc(N(c3ccc4c(c3)oc3cccc(-c5nc6cc7ccccc7cc6o5)c34)c3ccc4c(c3)sc3c5ccccc5ccc43)ccc2c1] 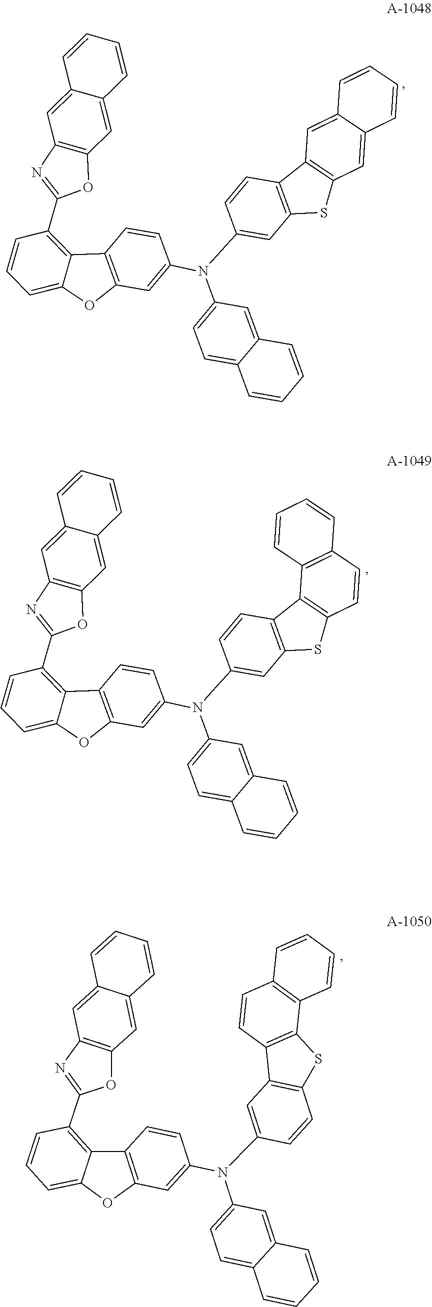 [SMILES: c1ccc2cc(N(c3ccc4c(c3)oc3cccc(-c5nc6cc7ccccc7cc6o5)c34)c3ccc4c(c3)sc3cc5ccccc5cc34)ccc2c1 ; c1ccc2cc(N(c3ccc4c(c3)oc3cccc(-c5nc6cc7ccccc7cc6o5)c34)c3ccc4c(c3)sc3ccc5ccccc5c34)ccc2c1 ; c1ccc2cc(N(c3ccc4c(c3)oc3cccc(-c5nc6cc7ccccc7cc6o5)c34)c3ccc4sc5c6ccccc6ccc5c4c3)ccc2c1] 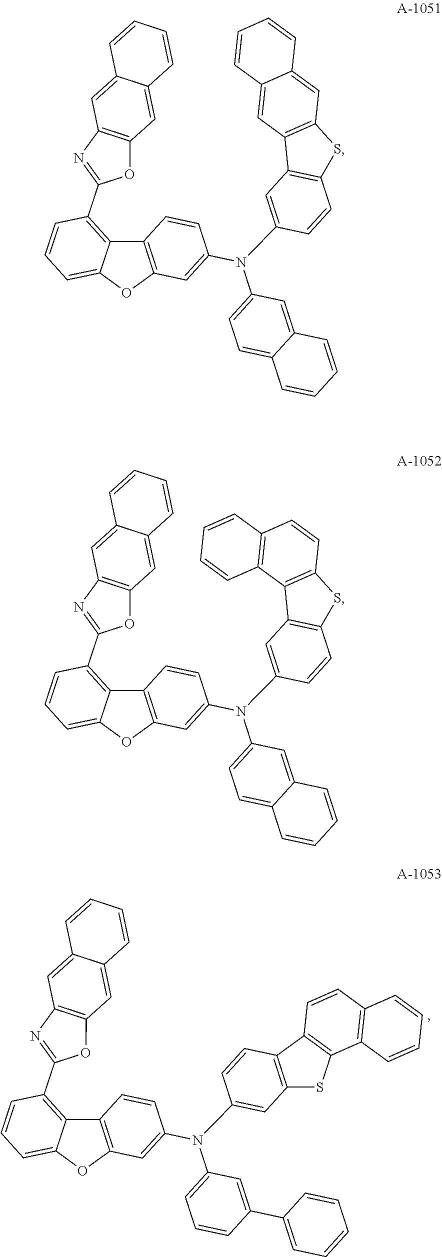 [SMILES: c1ccc2cc(N(c3ccc4c(c3)oc3cccc(-c5nc6cc7ccccc7cc6o5)c34)c3ccc4sc5cc6ccccc6cc5c4c3)ccc2c1 ; c1ccc2cc(N(c3ccc4c(c3)oc3cccc(-c5nc6cc7ccccc7cc6o5)c34)c3ccc4sc5ccc6ccccc6c5c4c3)ccc2c1 ; c1ccc(-c2cccc(N(c3ccc4c(c3)oc3cccc(-c5nc6cc7ccccc7cc6o5)c34)c3ccc4c(c3)sc3c5ccccc5ccc43)c2)cc1] 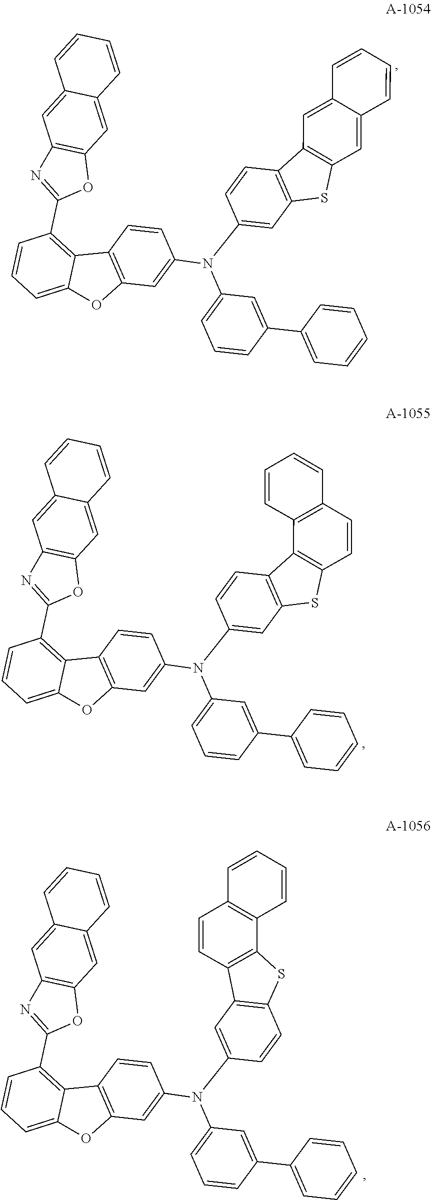 [SMILES: c1ccc(-c2cccc(N(c3ccc4c(c3)oc3cccc(-c5nc6cc7ccccc7cc6o5)c34)c3ccc4c(c3)sc3cc5ccccc5cc34)c2)cc1 ; c1ccc(-c2cccc(N(c3ccc4c(c3)oc3cccc(-c5nc6cc7ccccc7cc6o5)c34)c3ccc4c(c3)sc3ccc5ccccc5c34)c2)cc1 ; c1ccc(-c2cccc(N(c3ccc4c(c3)oc3cccc(-c5nc6cc7ccccc7cc6o5)c34)c3ccc4sc5c6ccccc6ccc5c4c3)c2)cc1] 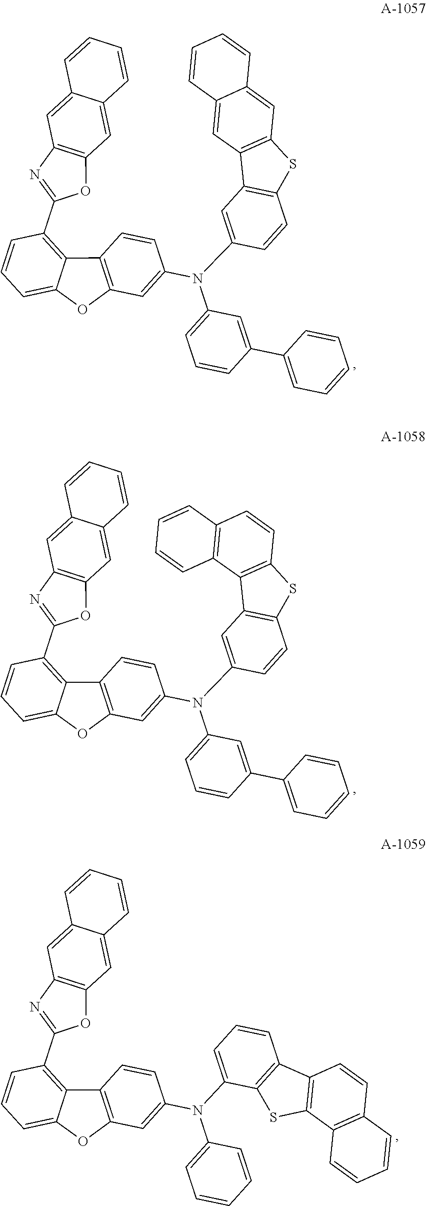 [SMILES: c1ccc(-c2cccc(N(c3ccc4c(c3)oc3cccc(-c5nc6cc7ccccc7cc6o5)c34)c3ccc4sc5cc6ccccc6cc5c4c3)c2)cc1 ; c1ccc(-c2cccc(N(c3ccc4c(c3)oc3cccc(-c5nc6cc7ccccc7cc6o5)c34)c3ccc4sc5ccc6ccccc6c5c4c3)c2)cc1 ; c1ccc(N(c2ccc3c(c2)oc2cccc(-c4nc5cc6ccccc6cc5o4)c23)c2cccc3c2sc2c4ccccc4ccc32)cc1] 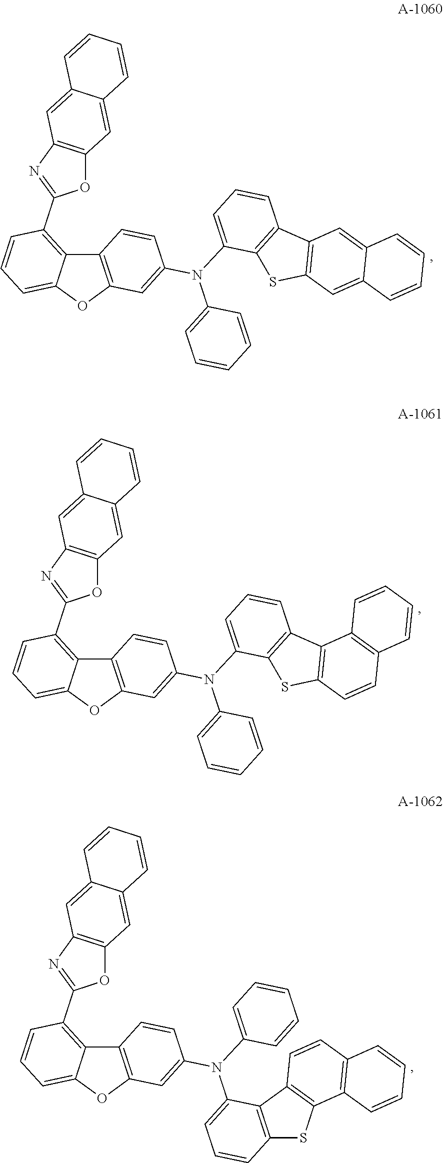 [SMILES: c1ccc(N(c2ccc3c(c2)oc2cccc(-c4nc5cc6ccccc6cc5o4)c23)c2cccc3c2sc2cc4ccccc4cc23)cc1 ; c1ccc(N(c2ccc3c(c2)oc2cccc(-c4nc5cc6ccccc6cc5o4)c23)c2cccc3c2sc2ccc4ccccc4c23)cc1 ; c1ccc(N(c2ccc3c(c2)oc2cccc(-c4nc5cc6ccccc6cc5o4)c23)c2cccc3sc4c5ccccc5ccc4c23)cc1] 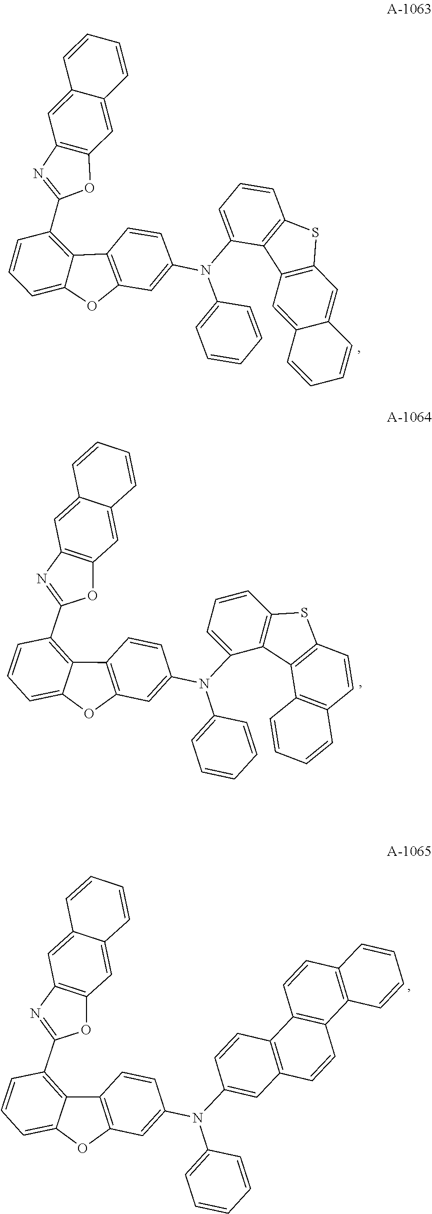 [SMILES: c1ccc(N(c2ccc3c(c2)oc2cccc(-c4nc5cc6ccccc6cc5o4)c23)c2cccc3sc4cc5ccccc5cc4c23)cc1 ; c1ccc(N(c2ccc3c(c2)oc2cccc(-c4nc5cc6ccccc6cc5o4)c23)c2cccc3sc4ccc5ccccc5c4c23)cc1 ; c1ccc(N(c2ccc3c(ccc4c5ccccc5ccc34)c2)c2ccc3c(c2)oc2cccc(-c4nc5cc6ccccc6cc5o4)c23)cc1] 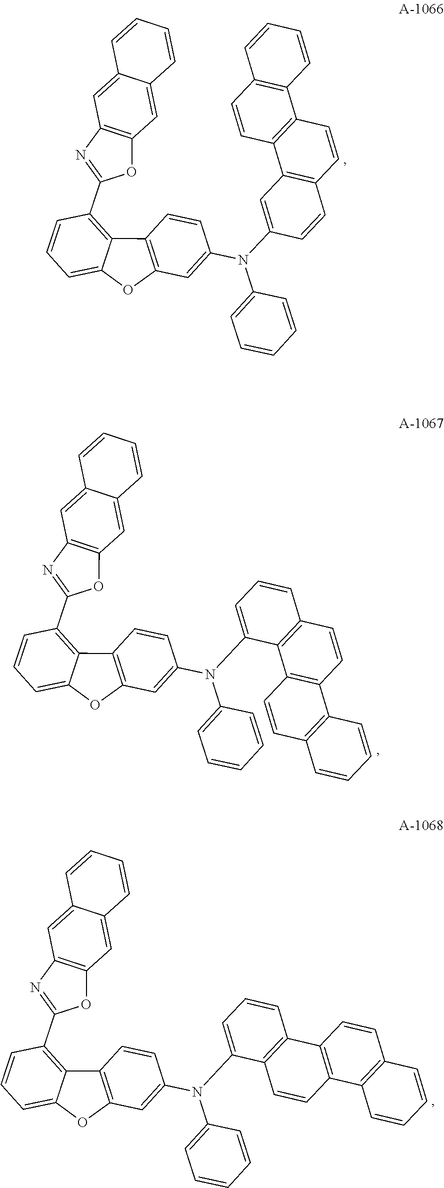 [SMILES: c1ccc(N(c2ccc3c(c2)oc2cccc(-c4nc5cc6ccccc6cc5o4)c23)c2ccc3ccc4c5ccccc5ccc4c3c2)cc1 ; c1ccc(N(c2ccc3c(c2)oc2cccc(-c4nc5cc6ccccc6cc5o4)c23)c2cccc3ccc4c5ccccc5ccc4c23)cc1 ; c1ccc(N(c2ccc3c(c2)oc2cccc(-c4nc5cc6ccccc6cc5o4)c23)c2cccc3c2ccc2c4ccccc4ccc32)cc1] 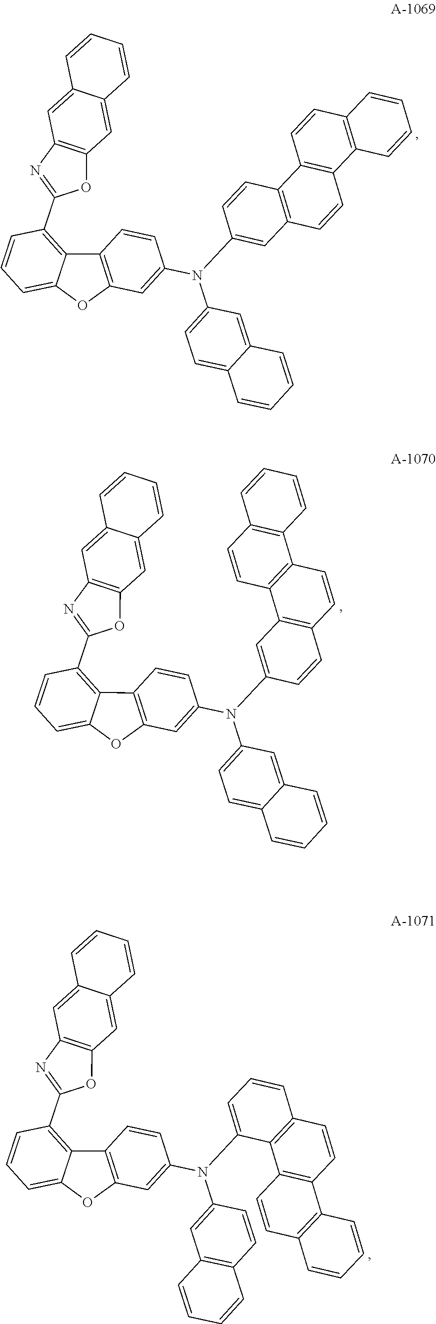 [SMILES: c1ccc2cc(N(c3ccc4c(ccc5c6ccccc6ccc45)c3)c3ccc4c(c3)oc3cccc(-c5nc6cc7ccccc7cc6o5)c34)ccc2c1 ; c1ccc2cc(N(c3ccc4c(c3)oc3cccc(-c5nc6cc7ccccc7cc6o5)c34)c3ccc4ccc5c6ccccc6ccc5c4c3)ccc2c1 ; c1ccc2cc(N(c3ccc4c(c3)oc3cccc(-c5nc6cc7ccccc7cc6o5)c34)c3cccc4ccc5c6ccccc6ccc5c34)ccc2c1] 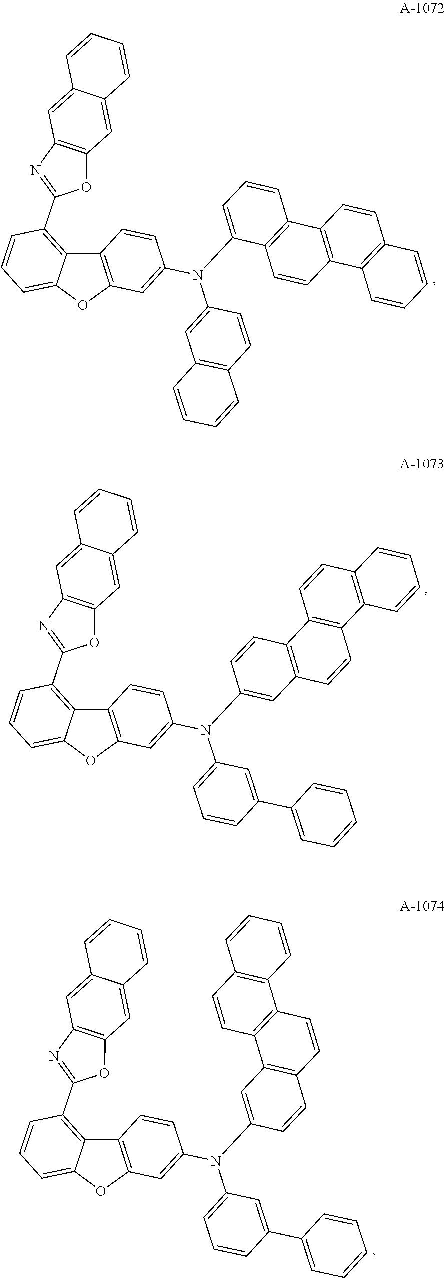 [SMILES: c1ccc2cc(N(c3ccc4c(c3)oc3cccc(-c5nc6cc7ccccc7cc6o5)c34)c3cccc4c3ccc3c5ccccc5ccc43)ccc2c1 ; c1ccc(-c2cccc(N(c3ccc4c(ccc5c6ccccc6ccc45)c3)c3ccc4c(c3)oc3cccc(-c5nc6cc7ccccc7cc6o5)c34)c2)cc1 ; c1ccc(-c2cccc(N(c3ccc4c(c3)oc3cccc(-c5nc6cc7ccccc7cc6o5)c34)c3ccc4ccc5c6ccccc6ccc5c4c3)c2)cc1] 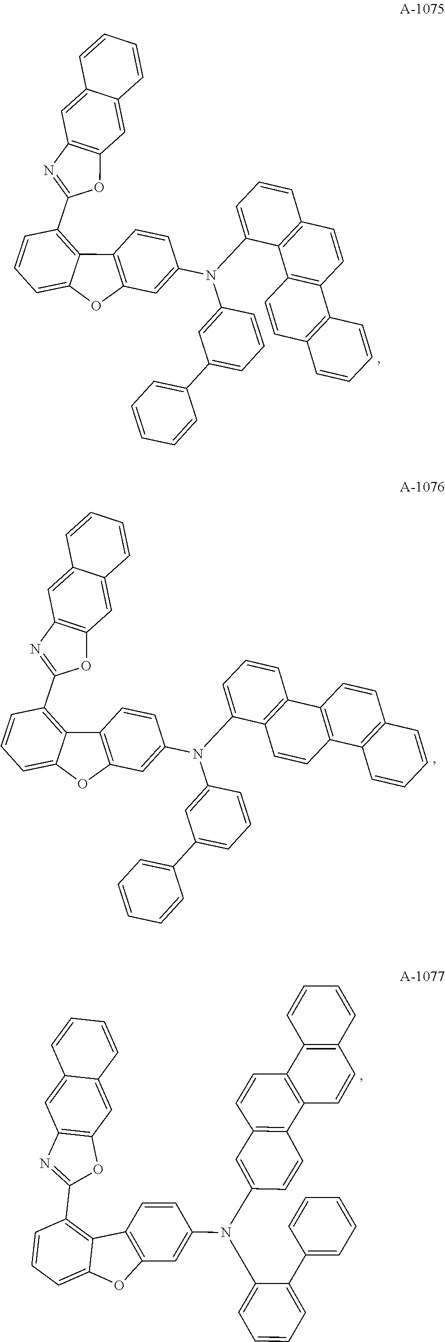 [SMILES: c1ccc(-c2cccc(N(c3ccc4c(c3)oc3cccc(-c5nc6cc7ccccc7cc6o5)c34)c3cccc4ccc5c6ccccc6ccc5c34)c2)cc1 ; c1ccc(-c2cccc(N(c3ccc4c(c3)oc3cccc(-c5nc6cc7ccccc7cc6o5)c34)c3cccc4c3ccc3c5ccccc5ccc43)c2)cc1 ; c1ccc(-c2ccccc2N(c2ccc3c(ccc4c5ccccc5ccc34)c2)c2ccc3c(c2)oc2cccc(-c4nc5cc6ccccc6cc5o4)c23)cc1] 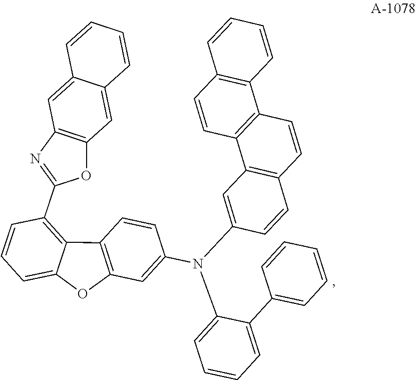 [SMILES: c1ccc(-c2ccccc2N(c2ccc3c(c2)oc2cccc(-c4nc5cc6ccccc6cc5o4)c23)c2ccc3ccc4c5ccccc5ccc4c3c2)cc1] 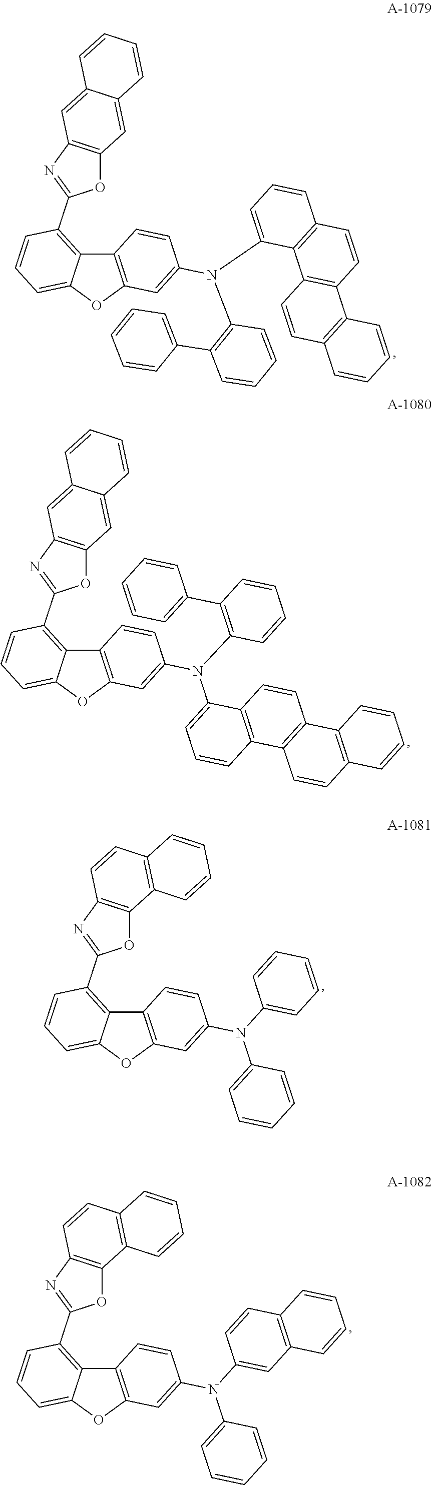 [SMILES: c1ccc(-c2ccccc2N(c2ccc3c(c2)oc2cccc(-c4nc5cc6ccccc6cc5o4)c23)c2cccc3ccc4c5ccccc5ccc4c23)cc1 ; c1ccc(-c2ccccc2N(c2ccc3c(c2)oc2cccc(-c4nc5cc6ccccc6cc5o4)c23)c2cccc3c2ccc2c4ccccc4ccc32)cc1 ; c1ccc(N(c2ccccc2)c2ccc3c(c2)oc2cccc(-c4nc5ccc6ccccc6c5o4)c23)cc1 ; c1ccc(N(c2ccc3ccccc3c2)c2ccc3c(c2)oc2cccc(-c4nc5ccc6ccccc6c5o4)c23)cc1] 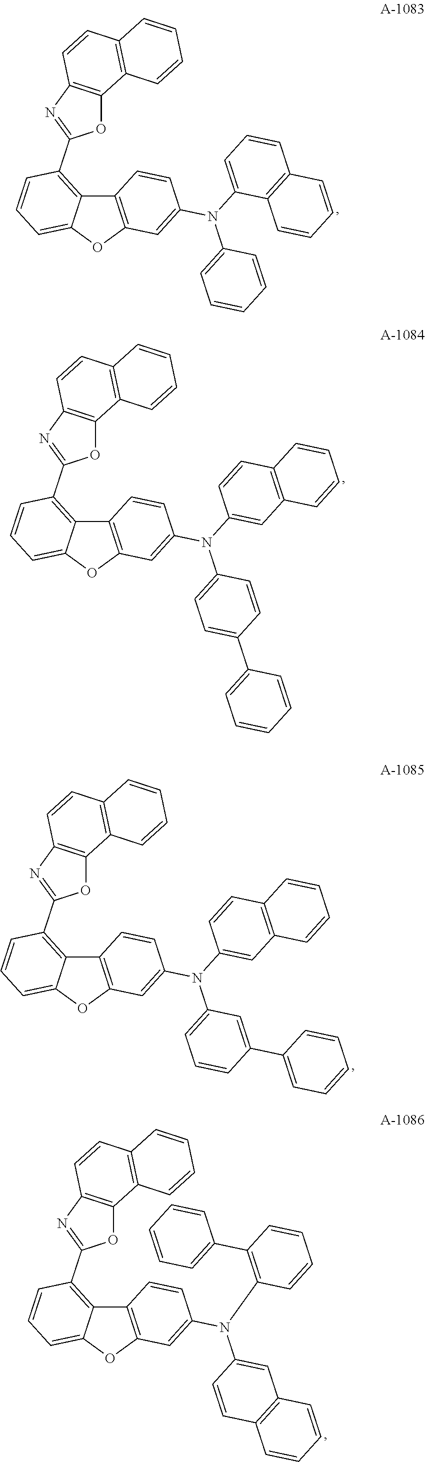 [SMILES: c1ccc(N(c2ccc3c(c2)oc2cccc(-c4nc5ccc6ccccc6c5o4)c23)c2cccc3ccccc23)cc1 ; c1ccc(-c2ccc(N(c3ccc4ccccc4c3)c3ccc4c(c3)oc3cccc(-c5nc6ccc7ccccc7c6o5)c34)cc2)cc1 ; c1ccc(-c2cccc(N(c3ccc4ccccc4c3)c3ccc4c(c3)oc3cccc(-c5nc6ccc7ccccc7c6o5)c34)c2)cc1 ; c1ccc(-c2ccccc2N(c2ccc3ccccc3c2)c2ccc3c(c2)oc2cccc(-c4nc5ccc6ccccc6c5o4)c23)cc1] 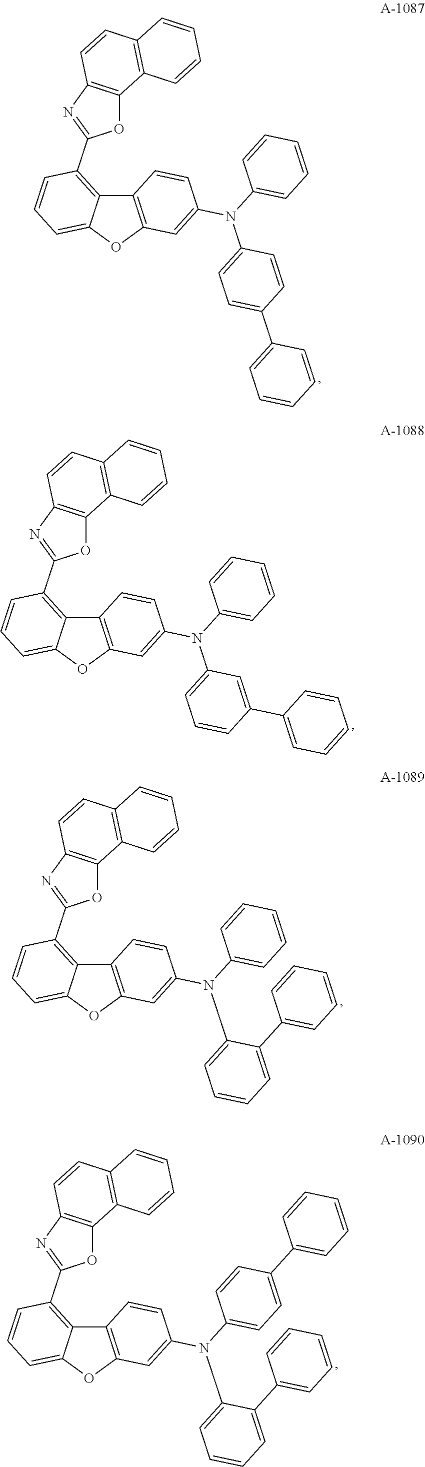 [SMILES: c1ccc(-c2ccc(N(c3ccccc3)c3ccc4c(c3)oc3cccc(-c5nc6ccc7ccccc7c6o5)c34)cc2)cc1 ; c1ccc(-c2cccc(N(c3ccccc3)c3ccc4c(c3)oc3cccc(-c5nc6ccc7ccccc7c6o5)c34)c2)cc1 ; c1ccc(-c2ccccc2N(c2ccccc2)c2ccc3c(c2)oc2cccc(-c4nc5ccc6ccccc6c5o4)c23)cc1 ; c1ccc(-c2ccc(N(c3ccc4c(c3)oc3cccc(-c5nc6ccc7ccccc7c6o5)c34)c3ccccc3-c3ccccc3)cc2)cc1] 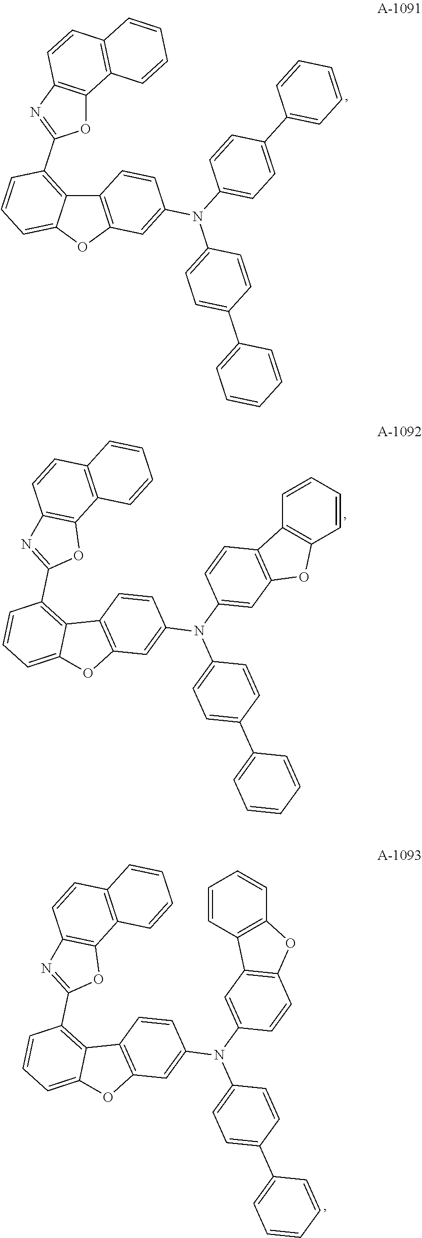 [SMILES: c1ccc(-c2ccc(N(c3ccc(-c4ccccc4)cc3)c3ccc4c(c3)oc3cccc(-c5nc6ccc7ccccc7c6o5)c34)cc2)cc1 ; c1ccc(-c2ccc(N(c3ccc4c(c3)oc3ccccc34)c3ccc4c(c3)oc3cccc(-c5nc6ccc7ccccc7c6o5)c34)cc2)cc1 ; c1ccc(-c2ccc(N(c3ccc4c(c3)oc3cccc(-c5nc6ccc7ccccc7c6o5)c34)c3ccc4oc5ccccc5c4c3)cc2)cc1] 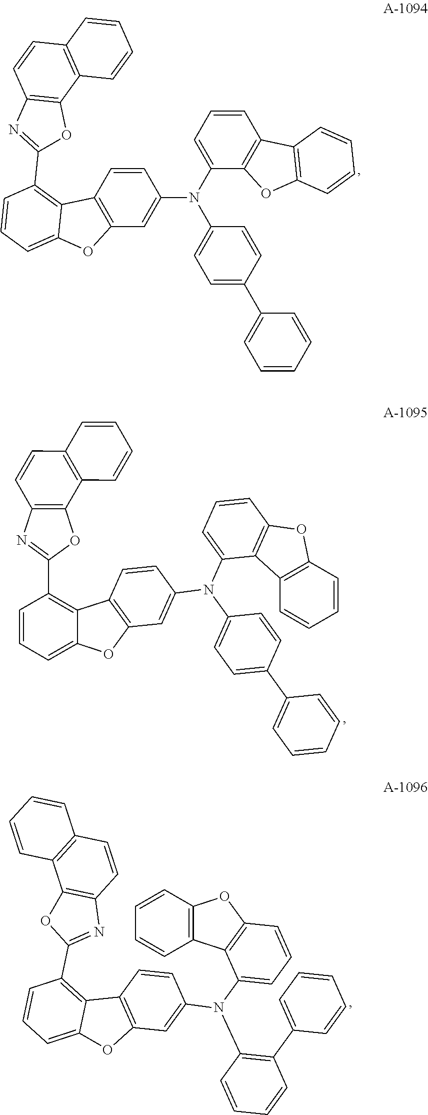 [SMILES: c1ccc(-c2ccc(N(c3ccc4c(c3)oc3cccc(-c5nc6ccc7ccccc7c6o5)c34)c3cccc4c3oc3ccccc34)cc2)cc1 ; c1ccc(-c2ccc(N(c3ccc4c(c3)oc3cccc(-c5nc6ccc7ccccc7c6o5)c34)c3cccc4oc5ccccc5c34)cc2)cc1 ; c1ccc(-c2ccccc2N(c2ccc3c(c2)oc2cccc(-c4nc5ccc6ccccc6c5o4)c23)c2cccc3oc4ccccc4c23)cc1] 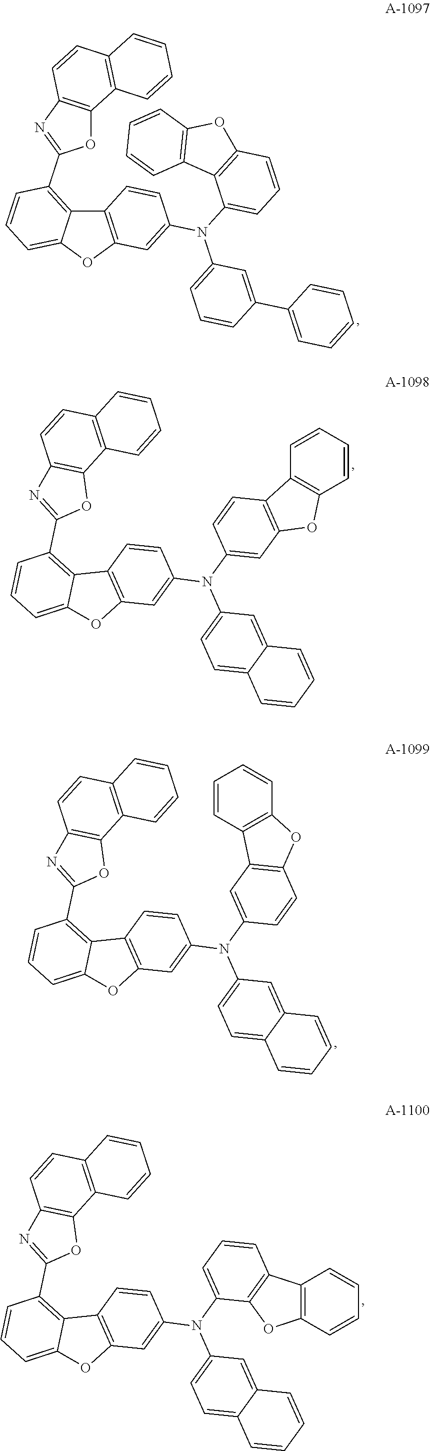 [SMILES: c1ccc(-c2cccc(N(c3ccc4c(c3)oc3cccc(-c5nc6ccc7ccccc7c6o5)c34)c3cccc4oc5ccccc5c34)c2)cc1 ; c1ccc2cc(N(c3ccc4c(c3)oc3ccccc34)c3ccc4c(c3)oc3cccc(-c5nc6ccc7ccccc7c6o5)c34)ccc2c1 ; c1ccc2cc(N(c3ccc4c(c3)oc3cccc(-c5nc6ccc7ccccc7c6o5)c34)c3ccc4oc5ccccc5c4c3)ccc2c1 ; c1ccc2cc(N(c3ccc4c(c3)oc3cccc(-c5nc6ccc7ccccc7c6o5)c34)c3cccc4c3oc3ccccc34)ccc2c1] 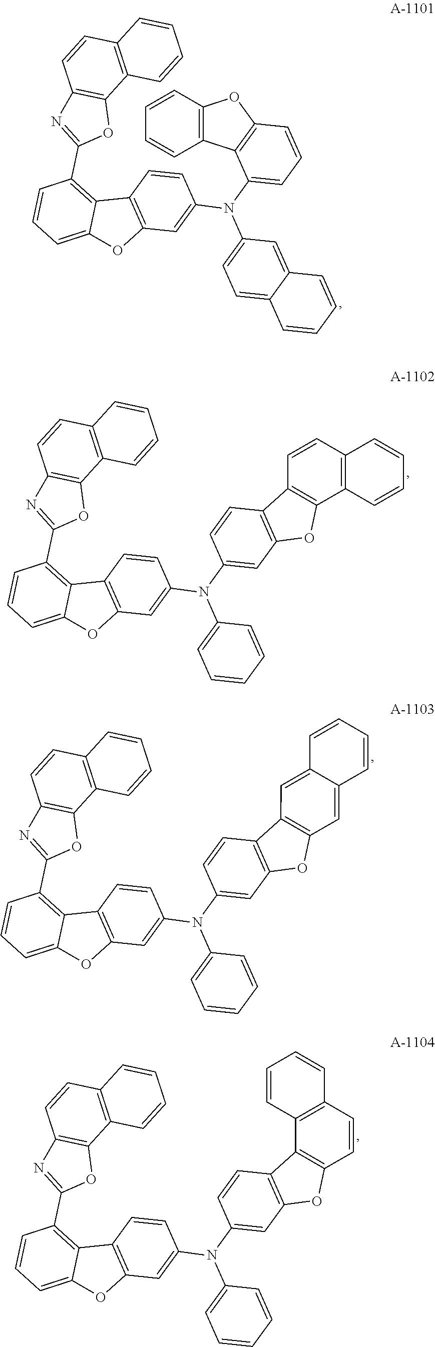 [SMILES: c1ccc2cc(N(c3ccc4c(c3)oc3cccc(-c5nc6ccc7ccccc7c6o5)c34)c3cccc4oc5ccccc5c34)ccc2c1 ; c1ccc(N(c2ccc3c(c2)oc2c4ccccc4ccc32)c2ccc3c(c2)oc2cccc(-c4nc5ccc6ccccc6c5o4)c23)cc1 ; c1ccc(N(c2ccc3c(c2)oc2cc4ccccc4cc23)c2ccc3c(c2)oc2cccc(-c4nc5ccc6ccccc6c5o4)c23)cc1 ; c1ccc(N(c2ccc3c(c2)oc2cccc(-c4nc5ccc6ccccc6c5o4)c23)c2ccc3c(c2)oc2ccc4ccccc4c23)cc1] 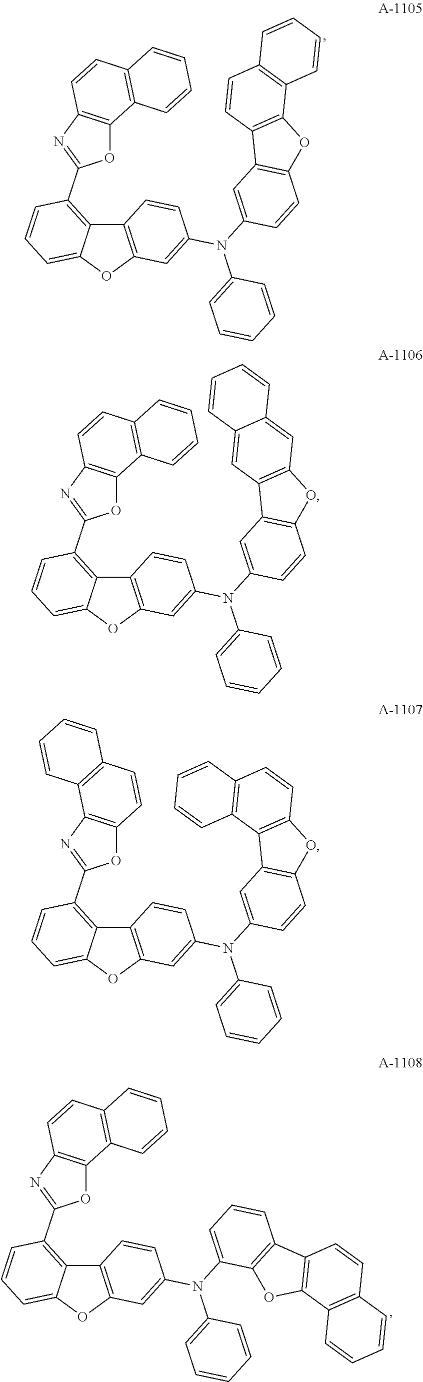 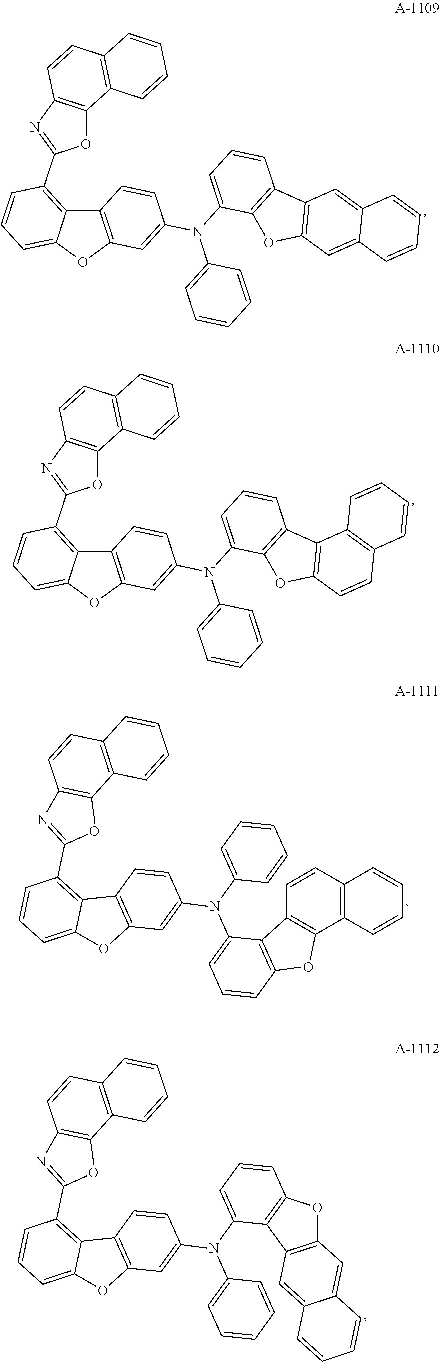 [SMILES: c1ccc(N(c2ccc3c(c2)oc2cccc(-c4nc5ccc6ccccc6c5o4)c23)c2cccc3c2oc2cc4ccccc4cc23)cc1 ; c1ccc(N(c2ccc3c(c2)oc2cccc(-c4nc5ccc6ccccc6c5o4)c23)c2cccc3c2oc2ccc4ccccc4c23)cc1 ; c1ccc(N(c2ccc3c(c2)oc2cccc(-c4nc5ccc6ccccc6c5o4)c23)c2cccc3oc4c5ccccc5ccc4c23)cc1 ; c1ccc(N(c2ccc3c(c2)oc2cccc(-c4nc5ccc6ccccc6c5o4)c23)c2cccc3oc4cc5ccccc5cc4c23)cc1] 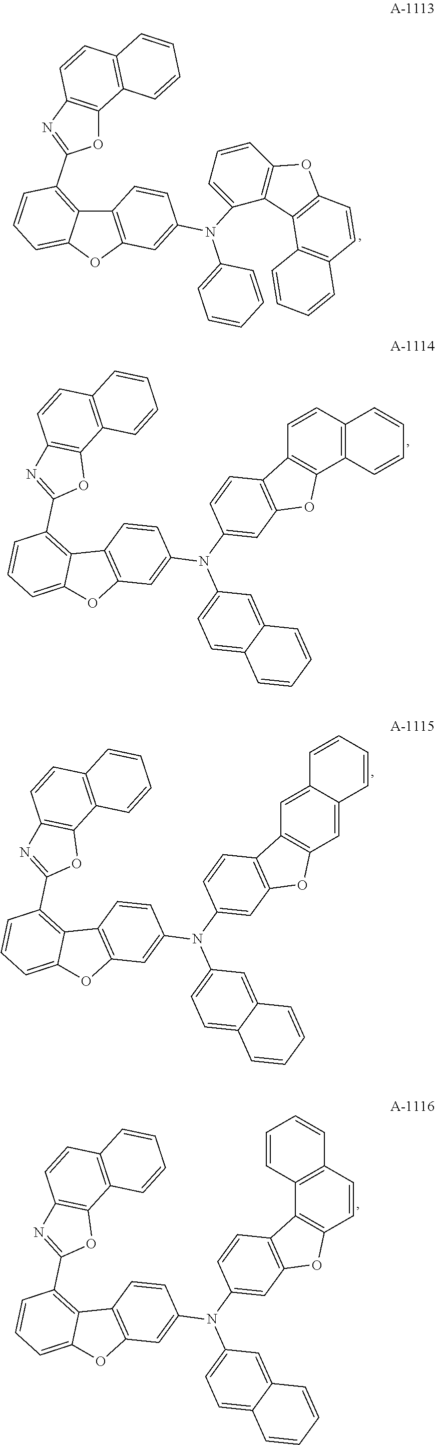 [SMILES: c1ccc(N(c2ccc3c(c2)oc2cccc(-c4nc5ccc6ccccc6c5o4)c23)c2cccc3oc4ccc5ccccc5c4c23)cc1 ; c1ccc2cc(N(c3ccc4c(c3)oc3c5ccccc5ccc43)c3ccc4c(c3)oc3cccc(-c5nc6ccc7ccccc7c6o5)c34)ccc2c1 ; c1ccc2cc(N(c3ccc4c(c3)oc3cc5ccccc5cc34)c3ccc4c(c3)oc3cccc(-c5nc6ccc7ccccc7c6o5)c34)ccc2c1 ; c1ccc2cc(N(c3ccc4c(c3)oc3cccc(-c5nc6ccc7ccccc7c6o5)c34)c3ccc4c(c3)oc3ccc5ccccc5c34)ccc2c1] 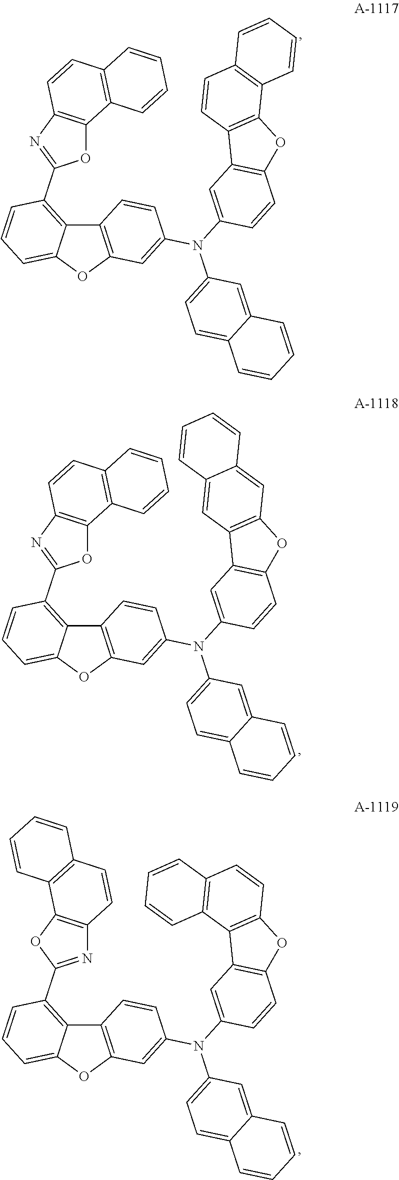 [SMILES: c1ccc2cc(N(c3ccc4c(c3)oc3cccc(-c5nc6ccc7ccccc7c6o5)c34)c3ccc4oc5c6ccccc6ccc5c4c3)ccc2c1 ; c1ccc2cc(N(c3ccc4c(c3)oc3cccc(-c5nc6ccc7ccccc7c6o5)c34)c3ccc4oc5cc6ccccc6cc5c4c3)ccc2c1 ; c1ccc2cc(N(c3ccc4c(c3)oc3cccc(-c5nc6ccc7ccccc7c6o5)c34)c3ccc4oc5ccc6ccccc6c5c4c3)ccc2c1] 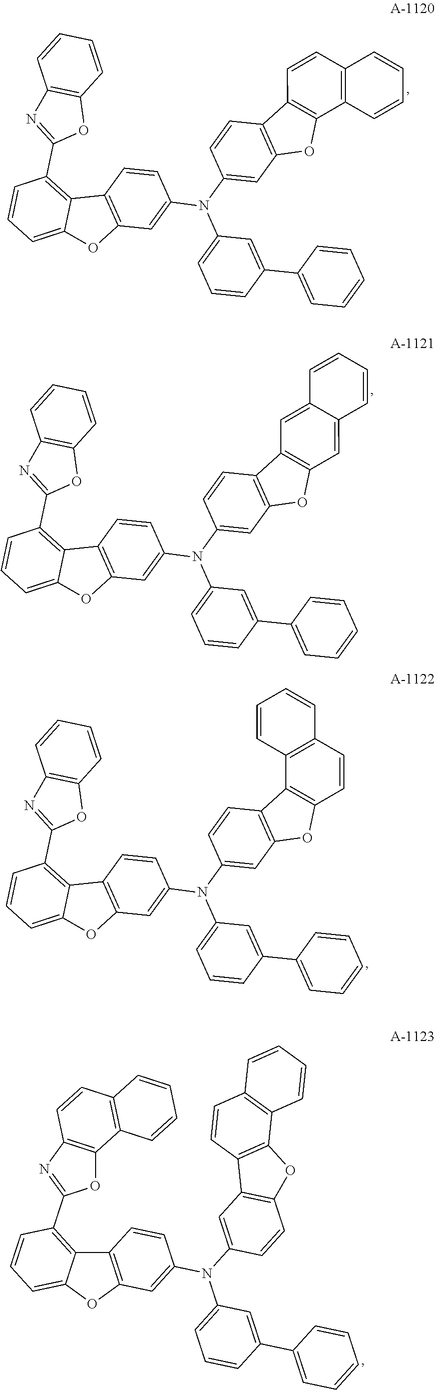 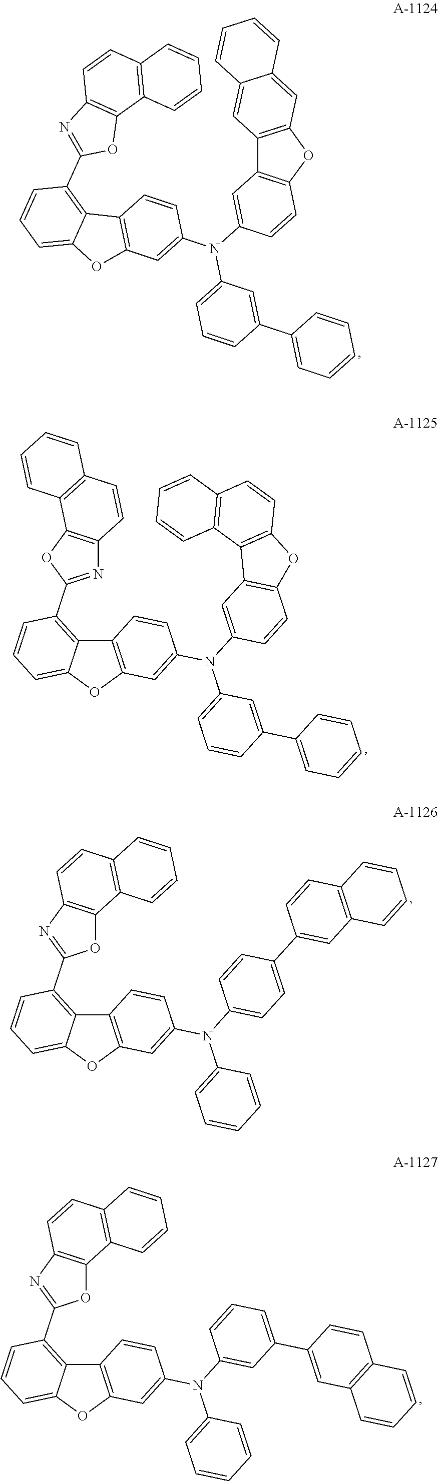 [SMILES: c1ccc(-c2cccc(N(c3ccc4c(c3)oc3cccc(-c5nc6ccc7ccccc7c6o5)c34)c3ccc4oc5cc6ccccc6cc5c4c3)c2)cc1 ; c1ccc(-c2cccc(N(c3ccc4c(c3)oc3cccc(-c5nc6ccc7ccccc7c6o5)c34)c3ccc4oc5ccc6ccccc6c5c4c3)c2)cc1 ; c1ccc(N(c2ccc(-c3ccc4ccccc4c3)cc2)c2ccc3c(c2)oc2cccc(-c4nc5ccc6ccccc6c5o4)c23)cc1 ; c1ccc(N(c2cccc(-c3ccc4ccccc4c3)c2)c2ccc3c(c2)oc2cccc(-c4nc5ccc6ccccc6c5o4)c23)cc1] 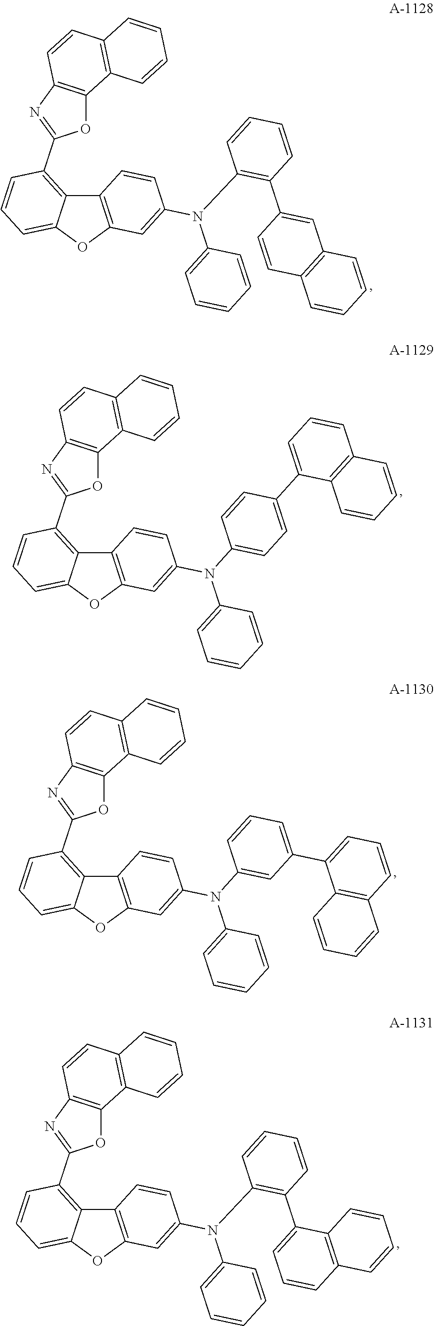 [SMILES: c1ccc(N(c2ccc3c(c2)oc2cccc(-c4nc5ccc6ccccc6c5o4)c23)c2ccccc2-c2ccc3ccccc3c2)cc1 ; c1ccc(N(c2ccc(-c3cccc4ccccc34)cc2)c2ccc3c(c2)oc2cccc(-c4nc5ccc6ccccc6c5o4)c23)cc1 ; c1ccc(N(c2cccc(-c3cccc4ccccc34)c2)c2ccc3c(c2)oc2cccc(-c4nc5ccc6ccccc6c5o4)c23)cc1 ; c1ccc(N(c2ccc3c(c2)oc2cccc(-c4nc5ccc6ccccc6c5o4)c23)c2ccccc2-c2cccc3ccccc23)cc1] 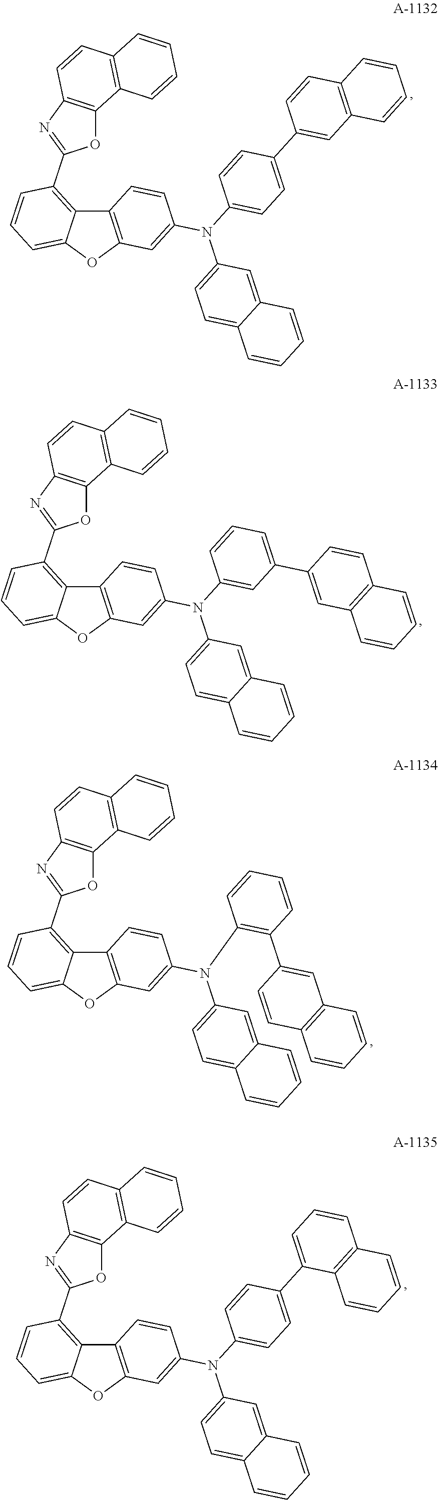 [SMILES: c1ccc2cc(-c3ccc(N(c4ccc5ccccc5c4)c4ccc5c(c4)oc4cccc(-c6nc7ccc8ccccc8c7o6)c45)cc3)ccc2c1 ; c1cc(-c2ccc3ccccc3c2)cc(N(c2ccc3ccccc3c2)c2ccc3c(c2)oc2cccc(-c4nc5ccc6ccccc6c5o4)c23)c1 ; c1ccc(N(c2ccc3ccccc3c2)c2ccc3c(c2)oc2cccc(-c4nc5ccc6ccccc6c5o4)c23)c(-c2ccc3ccccc3c2)c1 ; c1ccc2cc(N(c3ccc(-c4cccc5ccccc45)cc3)c3ccc4c(c3)oc3cccc(-c5nc6ccc7ccccc7c6o5)c34)ccc2c1] 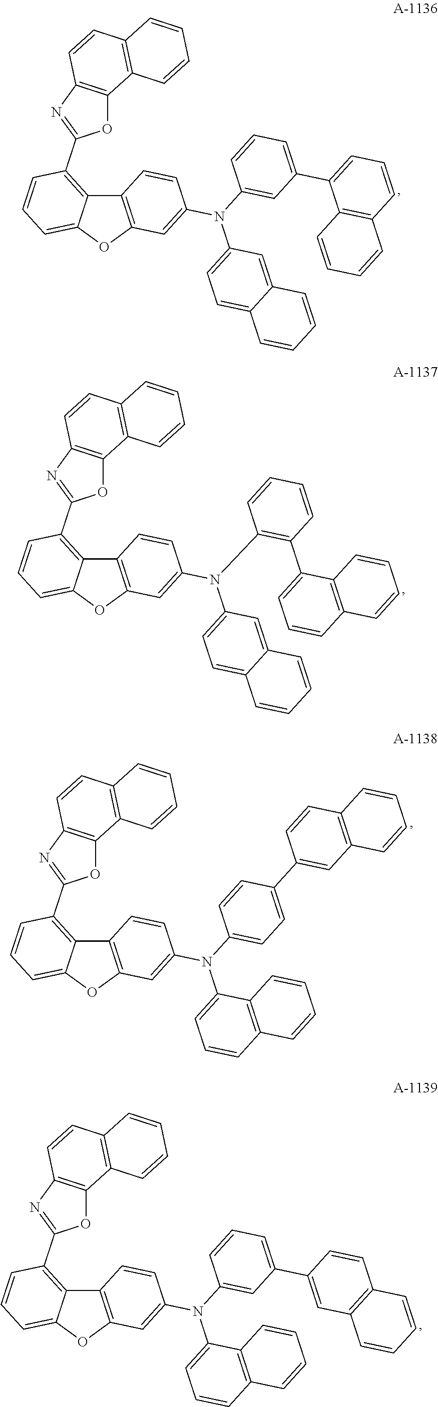 [SMILES: c1cc(-c2cccc3ccccc23)cc(N(c2ccc3ccccc3c2)c2ccc3c(c2)oc2cccc(-c4nc5ccc6ccccc6c5o4)c23)c1 ; c1ccc(N(c2ccc3ccccc3c2)c2ccc3c(c2)oc2cccc(-c4nc5ccc6ccccc6c5o4)c23)c(-c2cccc3ccccc23)c1 ; c1ccc2cc(-c3ccc(N(c4ccc5c(c4)oc4cccc(-c6nc7ccc8ccccc8c7o6)c45)c4cccc5ccccc45)cc3)ccc2c1 ; c1cc(-c2ccc3ccccc3c2)cc(N(c2ccc3c(c2)oc2cccc(-c4nc5ccc6ccccc6c5o4)c23)c2cccc3ccccc23)c1] 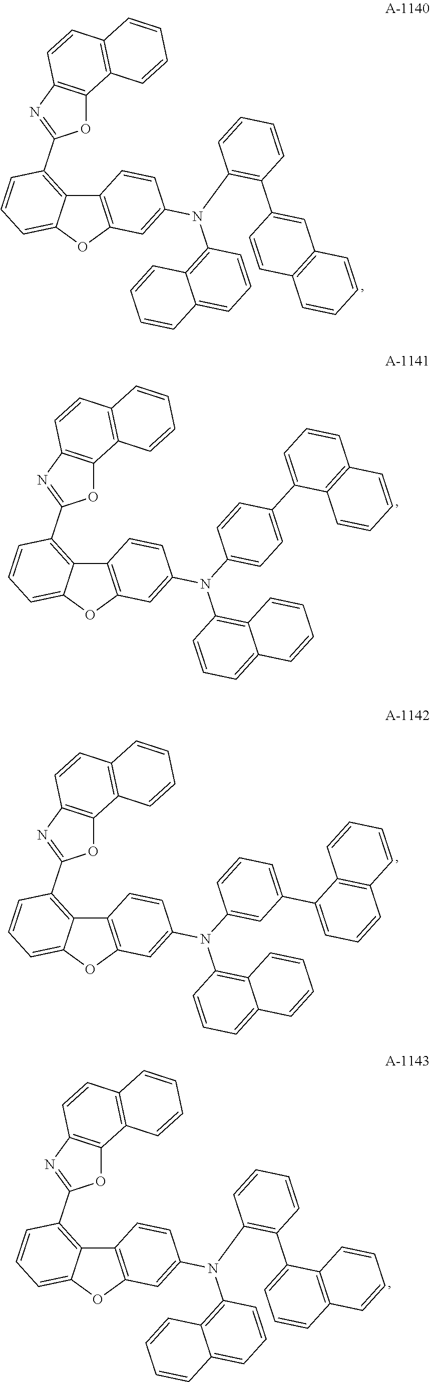 [SMILES: c1ccc(N(c2ccc3c(c2)oc2cccc(-c4nc5ccc6ccccc6c5o4)c23)c2cccc3ccccc23)c(-c2ccc3ccccc3c2)c1 ; c1ccc2c(-c3ccc(N(c4ccc5c(c4)oc4cccc(-c6nc7ccc8ccccc8c7o6)c45)c4cccc5ccccc45)cc3)cccc2c1 ; c1cc(-c2cccc3ccccc23)cc(N(c2ccc3c(c2)oc2cccc(-c4nc5ccc6ccccc6c5o4)c23)c2cccc3ccccc23)c1 ; c1ccc(N(c2ccc3c(c2)oc2cccc(-c4nc5ccc6ccccc6c5o4)c23)c2cccc3ccccc23)c(-c2cccc3ccccc23)c1] 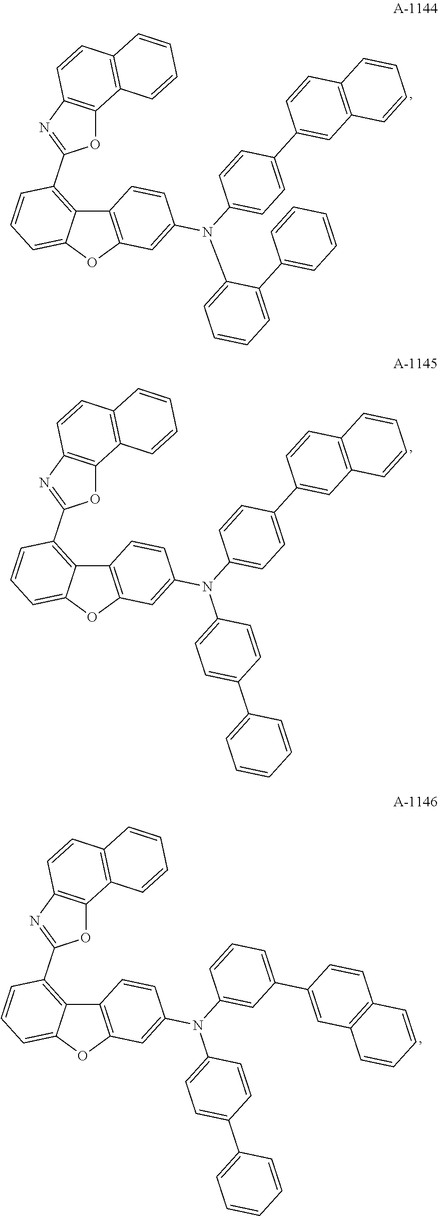 [SMILES: c1ccc(-c2ccccc2N(c2ccc(-c3ccc4ccccc4c3)cc2)c2ccc3c(c2)oc2cccc(-c4nc5ccc6ccccc6c5o4)c23)cc1 ; c1ccc(-c2ccc(N(c3ccc(-c4ccc5ccccc5c4)cc3)c3ccc4c(c3)oc3cccc(-c5nc6ccc7ccccc7c6o5)c34)cc2)cc1 ; c1ccc(-c2ccc(N(c3cccc(-c4ccc5ccccc5c4)c3)c3ccc4c(c3)oc3cccc(-c5nc6ccc7ccccc7c6o5)c34)cc2)cc1] 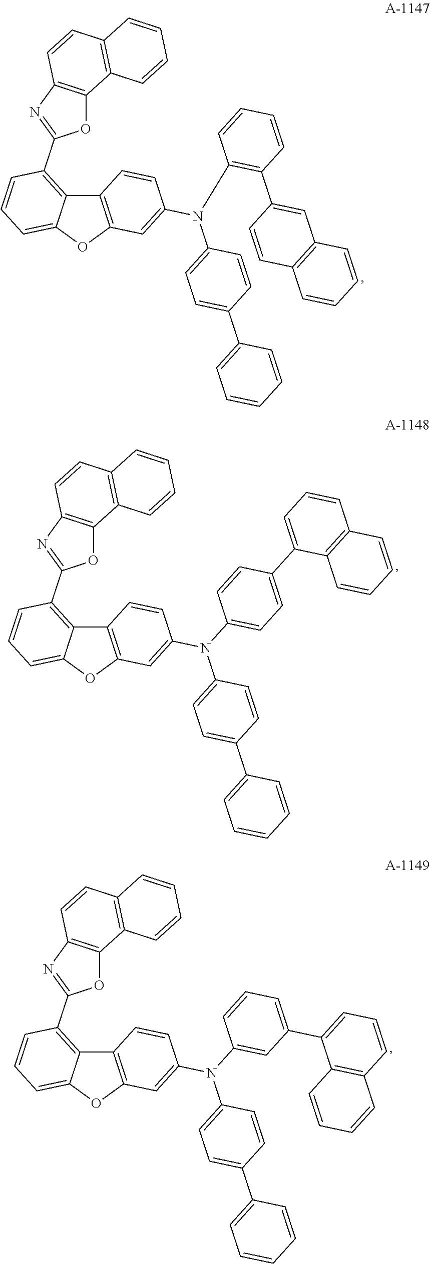 [SMILES: c1ccc(-c2ccc(N(c3ccc4c(c3)oc3cccc(-c5nc6ccc7ccccc7c6o5)c34)c3ccccc3-c3ccc4ccccc4c3)cc2)cc1 ; c1ccc(-c2ccc(N(c3ccc(-c4cccc5ccccc45)cc3)c3ccc4c(c3)oc3cccc(-c5nc6ccc7ccccc7c6o5)c34)cc2)cc1 ; c1ccc(-c2ccc(N(c3cccc(-c4cccc5ccccc45)c3)c3ccc4c(c3)oc3cccc(-c5nc6ccc7ccccc7c6o5)c34)cc2)cc1] 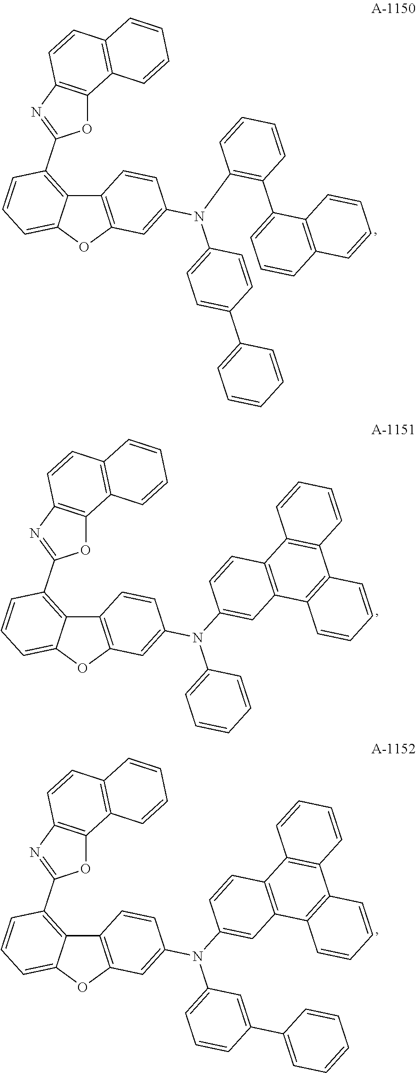 [SMILES: c1ccc(-c2ccc(N(c3ccc4c(c3)oc3cccc(-c5nc6ccc7ccccc7c6o5)c34)c3ccccc3-c3cccc4ccccc34)cc2)cc1 ; c1ccc(N(c2ccc3c(c2)oc2cccc(-c4nc5ccc6ccccc6c5o4)c23)c2ccc3c4ccccc4c4ccccc4c3c2)cc1 ; c1ccc(-c2cccc(N(c3ccc4c(c3)oc3cccc(-c5nc6ccc7ccccc7c6o5)c34)c3ccc4c5ccccc5c5ccccc5c4c3)c2)cc1] 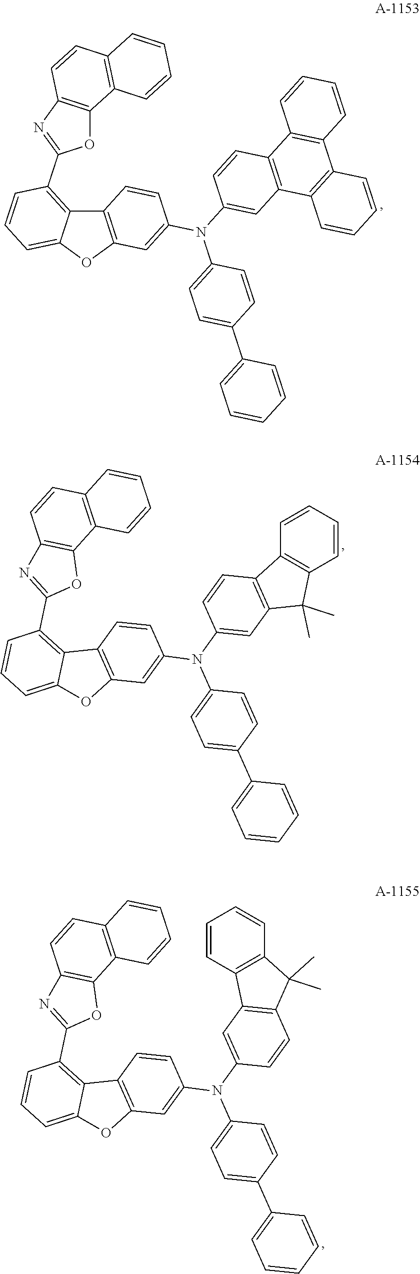 [SMILES: c1ccc(-c2ccc(N(c3ccc4c(c3)oc3cccc(-c5nc6ccc7ccccc7c6o5)c34)c3ccc4c5ccccc5c5ccccc5c4c3)cc2)cc1 ; CC1(C)c2ccccc2-c2ccc(N(c3ccc(-c4ccccc4)cc3)c3ccc4c(c3)oc3cccc(-c5nc6ccc7ccccc7c6o5)c34)cc21 ; CC1(C)c2ccccc2-c2cc(N(c3ccc(-c4ccccc4)cc3)c3ccc4c(c3)oc3cccc(-c5nc6ccc7ccccc7c6o5)c34)ccc21] 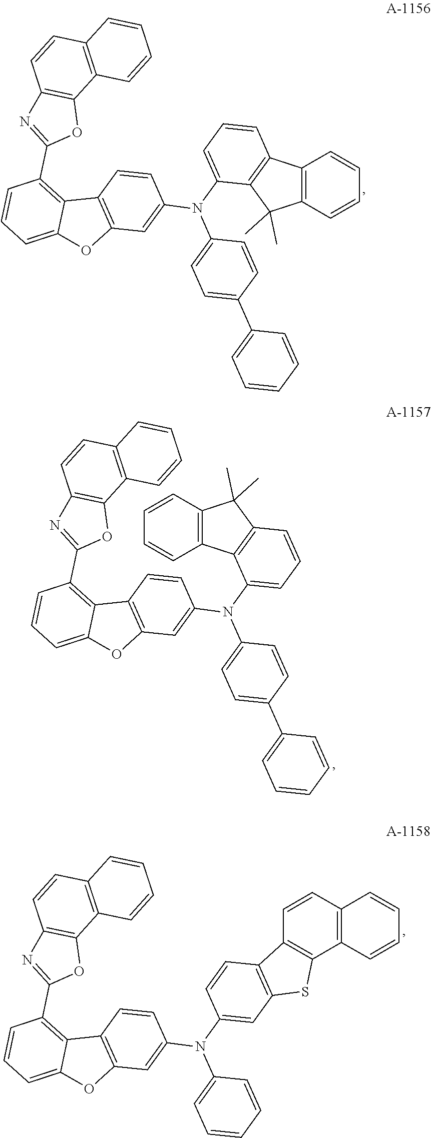 [SMILES: CC1(C)c2ccccc2-c2cccc(N(c3ccc(-c4ccccc4)cc3)c3ccc4c(c3)oc3cccc(-c5nc6ccc7ccccc7c6o5)c34)c21 ; CC1(C)c2ccccc2-c2c(N(c3ccc(-c4ccccc4)cc3)c3ccc4c(c3)oc3cccc(-c5nc6ccc7ccccc7c6o5)c34)cccc21 ; c1ccc(N(c2ccc3c(c2)oc2cccc(-c4nc5ccc6ccccc6c5o4)c23)c2ccc3c(c2)sc2c4ccccc4ccc32)cc1] 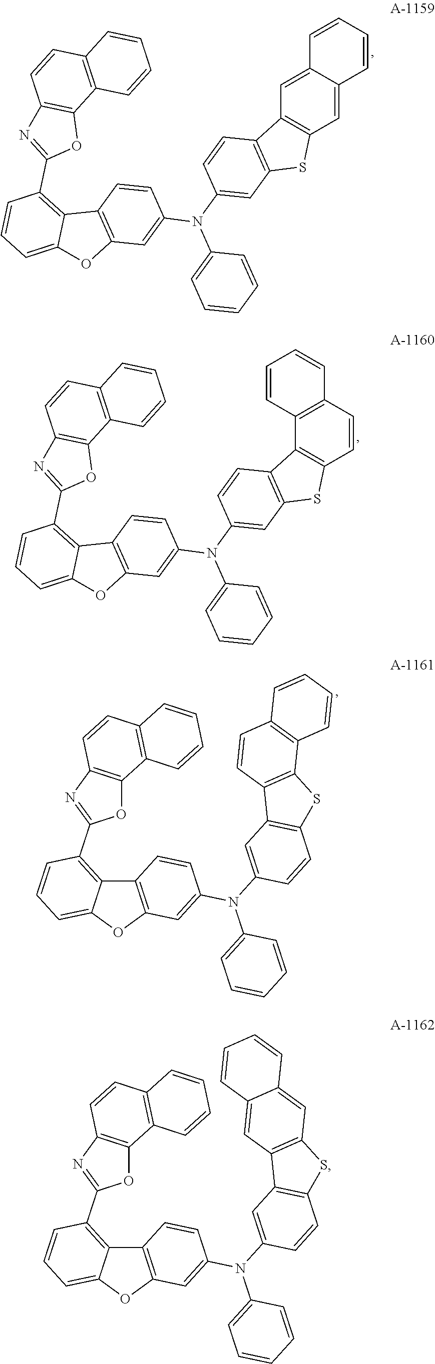 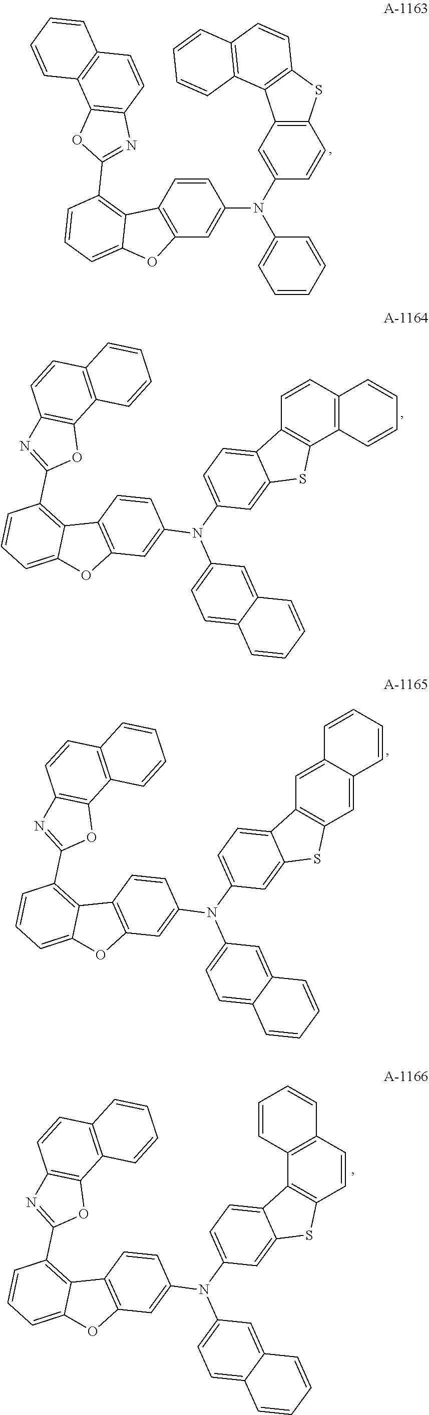 [SMILES: c1ccc(N(c2ccc3c(c2)oc2cccc(-c4nc5ccc6ccccc6c5o4)c23)c2ccc3sc4ccc5ccccc5c4c3c2)cc1 ; c1ccc2cc(N(c3ccc4c(c3)oc3cccc(-c5nc6ccc7ccccc7c6o5)c34)c3ccc4c(c3)sc3c5ccccc5ccc43)ccc2c1 ; c1ccc2cc(N(c3ccc4c(c3)oc3cccc(-c5nc6ccc7ccccc7c6o5)c34)c3ccc4c(c3)sc3cc5ccccc5cc34)ccc2c1 ; c1ccc2cc(N(c3ccc4c(c3)oc3cccc(-c5nc6ccc7ccccc7c6o5)c34)c3ccc4c(c3)sc3ccc5ccccc5c34)ccc2c1] 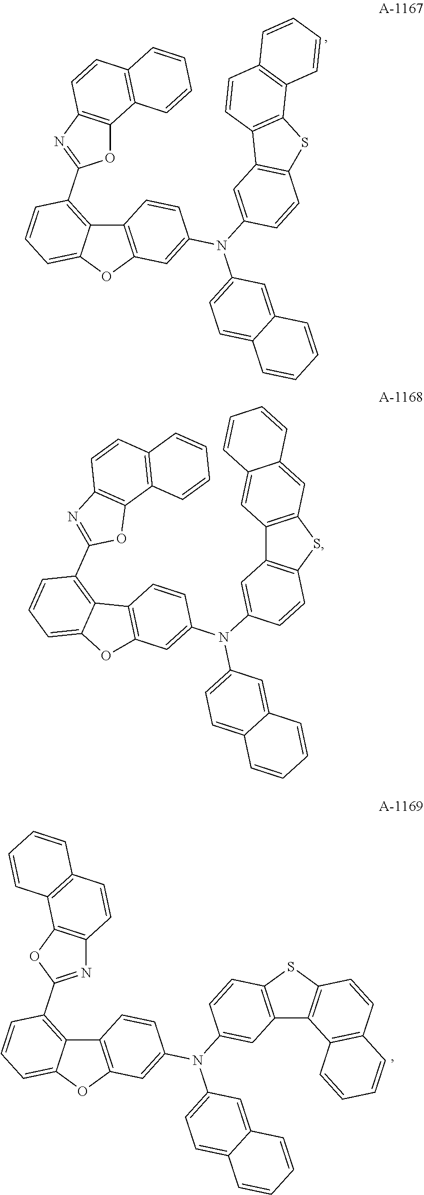 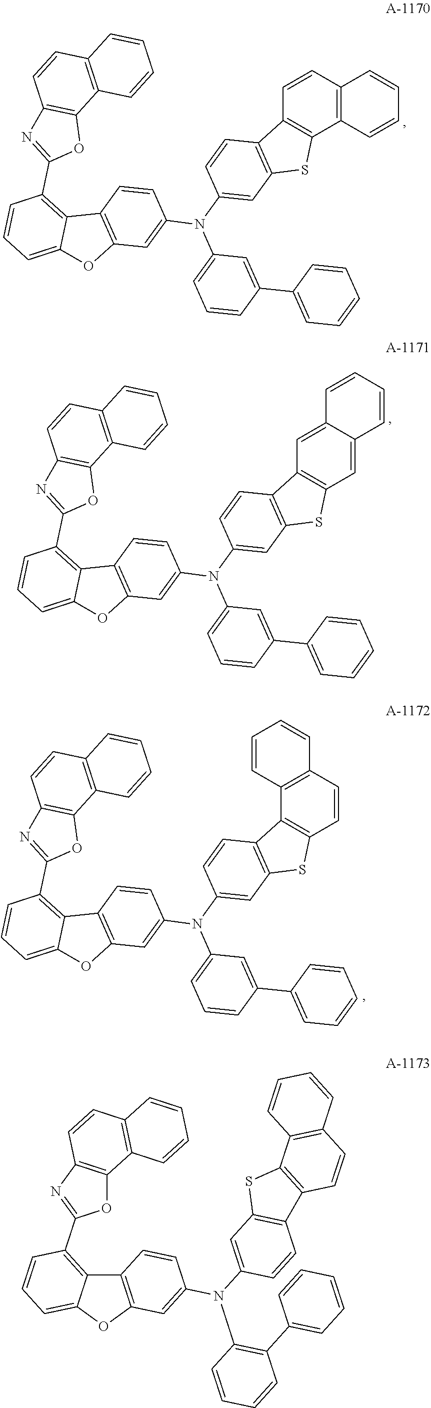 [SMILES: c1ccc(-c2cccc(N(c3ccc4c(c3)oc3cccc(-c5nc6ccc7ccccc7c6o5)c34)c3ccc4c(c3)sc3c5ccccc5ccc43)c2)cc1 ; c1ccc(-c2cccc(N(c3ccc4c(c3)oc3cccc(-c5nc6ccc7ccccc7c6o5)c34)c3ccc4c(c3)sc3cc5ccccc5cc34)c2)cc1 ; c1ccc(-c2cccc(N(c3ccc4c(c3)oc3cccc(-c5nc6ccc7ccccc7c6o5)c34)c3ccc4c(c3)sc3ccc5ccccc5c34)c2)cc1 ; c1ccc(-c2ccccc2N(c2ccc3c(c2)oc2cccc(-c4nc5ccc6ccccc6c5o4)c23)c2ccc3c(c2)sc2c4ccccc4ccc32)cc1] 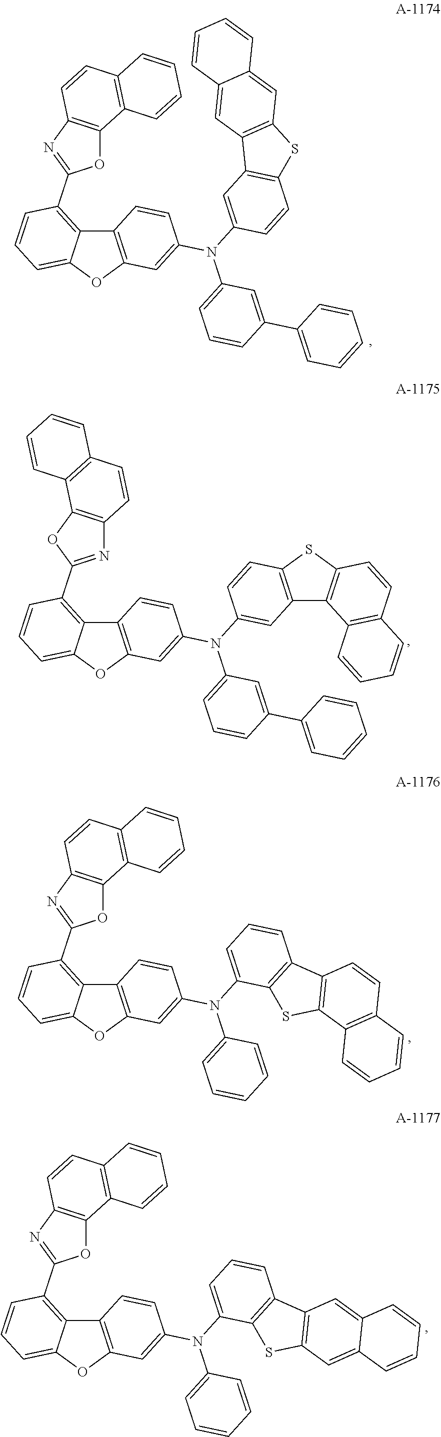 [SMILES: c1ccc(-c2cccc(N(c3ccc4c(c3)oc3cccc(-c5nc6ccc7ccccc7c6o5)c34)c3ccc4sc5cc6ccccc6cc5c4c3)c2)cc1 ; c1ccc(-c2cccc(N(c3ccc4c(c3)oc3cccc(-c5nc6ccc7ccccc7c6o5)c34)c3ccc4sc5ccc6ccccc6c5c4c3)c2)cc1 ; c1ccc(N(c2ccc3c(c2)oc2cccc(-c4nc5ccc6ccccc6c5o4)c23)c2cccc3c2sc2c4ccccc4ccc32)cc1 ; c1ccc(N(c2ccc3c(c2)oc2cccc(-c4nc5ccc6ccccc6c5o4)c23)c2cccc3c2sc2cc4ccccc4cc23)cc1] 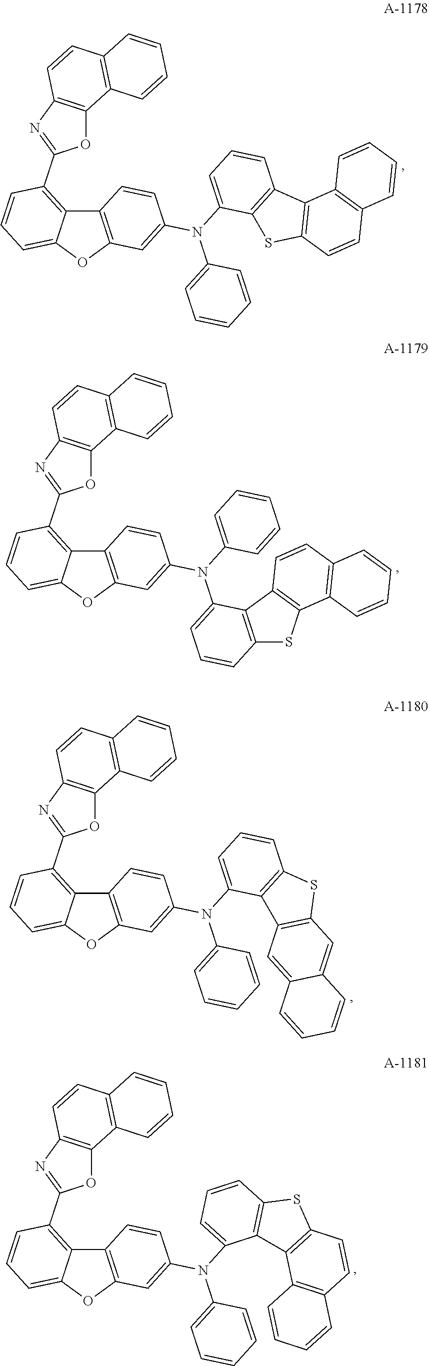 [SMILES: c1ccc(N(c2ccc3c(c2)oc2cccc(-c4nc5ccc6ccccc6c5o4)c23)c2cccc3c2sc2ccc4ccccc4c23)cc1 ; c1ccc(N(c2ccc3c(c2)oc2cccc(-c4nc5ccc6ccccc6c5o4)c23)c2cccc3sc4c5ccccc5ccc4c23)cc1 ; c1ccc(N(c2ccc3c(c2)oc2cccc(-c4nc5ccc6ccccc6c5o4)c23)c2cccc3sc4cc5ccccc5cc4c23)cc1 ; c1ccc(N(c2ccc3c(c2)oc2cccc(-c4nc5ccc6ccccc6c5o4)c23)c2cccc3sc4ccc5ccccc5c4c23)cc1] 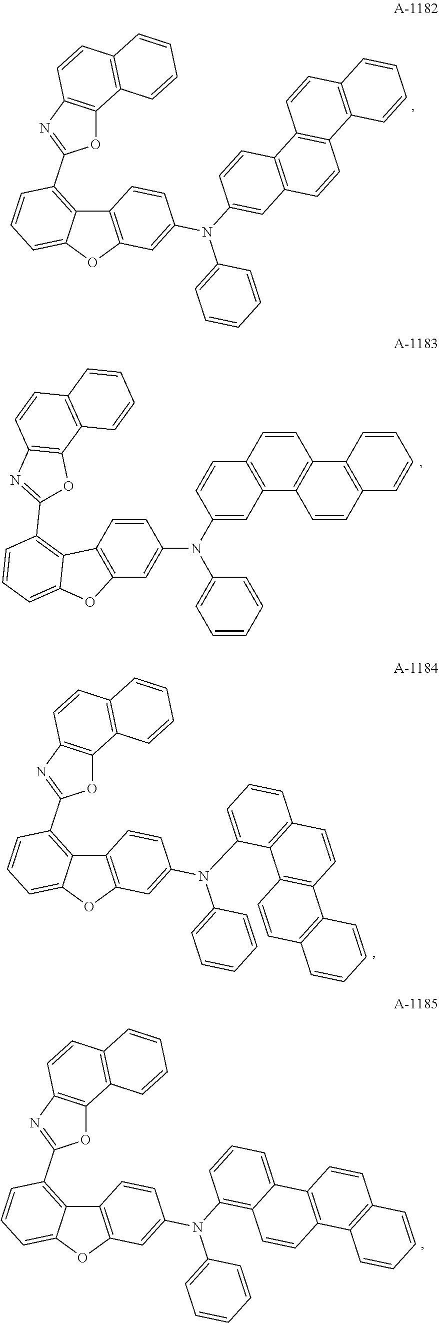 [SMILES: c1ccc(N(c2ccc3c(ccc4c5ccccc5ccc34)c2)c2ccc3c(c2)oc2cccc(-c4nc5ccc6ccccc6c5o4)c23)cc1 ; c1ccc(N(c2ccc3c(c2)oc2cccc(-c4nc5ccc6ccccc6c5o4)c23)c2ccc3ccc4c5ccccc5ccc4c3c2)cc1 ; c1ccc(N(c2ccc3c(c2)oc2cccc(-c4nc5ccc6ccccc6c5o4)c23)c2cccc3ccc4c5ccccc5ccc4c23)cc1 ; c1ccc(N(c2ccc3c(c2)oc2cccc(-c4nc5ccc6ccccc6c5o4)c23)c2cccc3c2ccc2c4ccccc4ccc32)cc1] 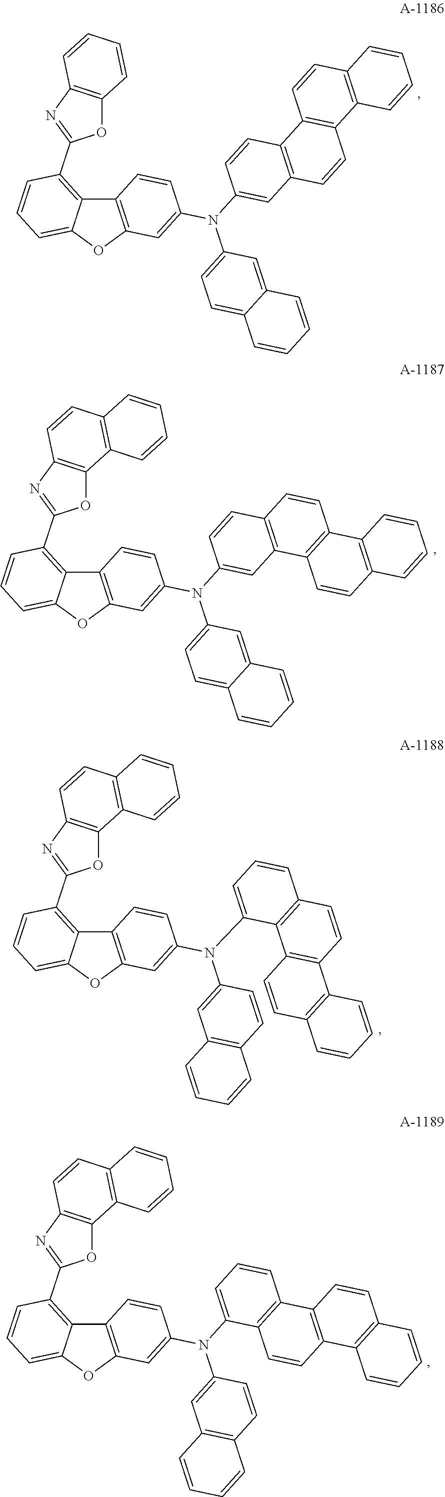 [SMILES: c1ccc2cc(N(c3ccc4c(ccc5c6ccccc6ccc45)c3)c3ccc4c(c3)oc3cccc(-c5nc6ccccc6o5)c34)ccc2c1 ; c1ccc2cc(N(c3ccc4c(c3)oc3cccc(-c5nc6ccc7ccccc7c6o5)c34)c3ccc4ccc5c6ccccc6ccc5c4c3)ccc2c1 ; c1ccc2cc(N(c3ccc4c(c3)oc3cccc(-c5nc6ccc7ccccc7c6o5)c34)c3cccc4ccc5c6ccccc6ccc5c34)ccc2c1 ; c1ccc2cc(N(c3ccc4c(c3)oc3cccc(-c5nc6ccc7ccccc7c6o5)c34)c3cccc4c3ccc3c5ccccc5ccc43)ccc2c1] 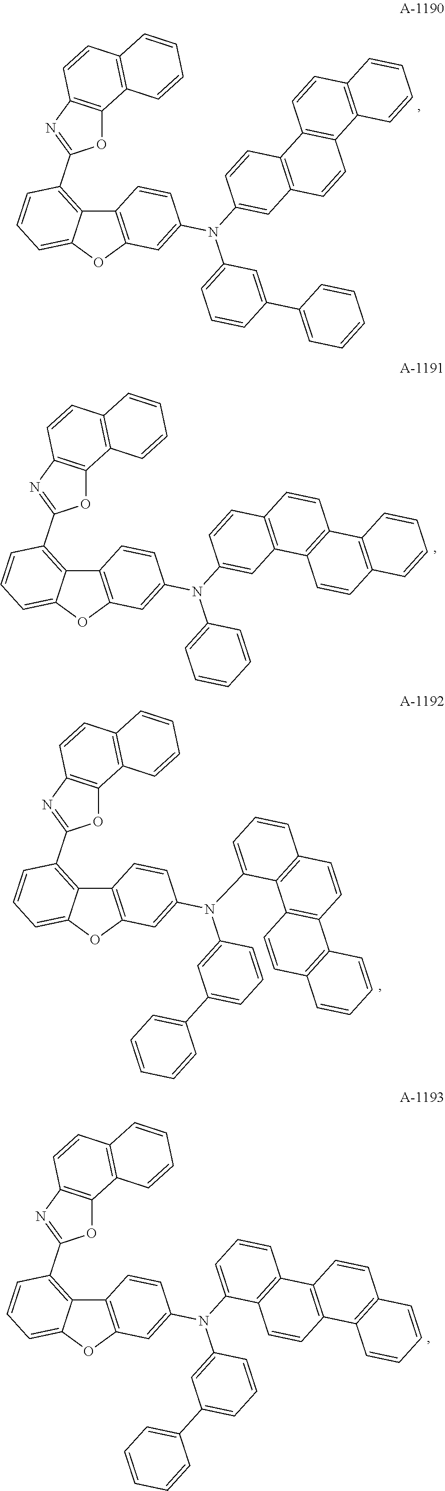 [SMILES: c1ccc(-c2cccc(N(c3ccc4c(ccc5c6ccccc6ccc45)c3)c3ccc4c(c3)oc3cccc(-c5nc6ccc7ccccc7c6o5)c34)c2)cc1 ; c1ccc(N(c2ccc3c(c2)oc2cccc(-c4nc5ccc6ccccc6c5o4)c23)c2ccc3ccc4c5ccccc5ccc4c3c2)cc1 ; c1ccc(-c2cccc(N(c3ccc4c(c3)oc3cccc(-c5nc6ccc7ccccc7c6o5)c34)c3cccc4ccc5c6ccccc6ccc5c34)c2)cc1 ; c1ccc(-c2cccc(N(c3ccc4c(c3)oc3cccc(-c5nc6ccc7ccccc7c6o5)c34)c3cccc4c3ccc3c5ccccc5ccc43)c2)cc1] 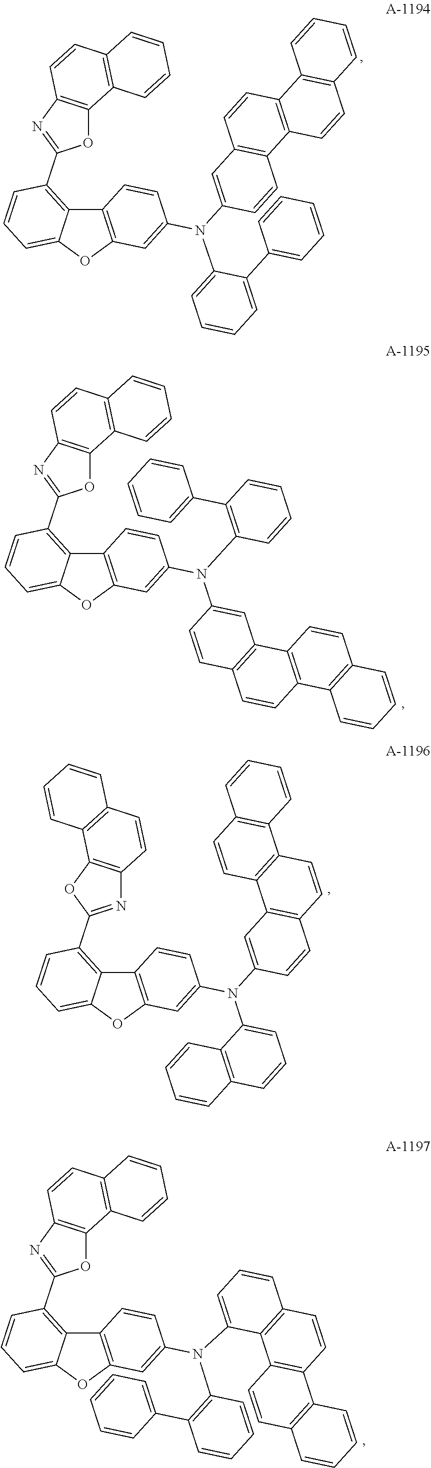 [SMILES: c1ccc(-c2ccccc2N(c2ccc3c(ccc4c5ccccc5ccc34)c2)c2ccc3c(c2)oc2cccc(-c4nc5ccc6ccccc6c5o4)c23)cc1 ; c1ccc(-c2ccccc2N(c2ccc3c(c2)oc2cccc(-c4nc5ccc6ccccc6c5o4)c23)c2ccc3ccc4c5ccccc5ccc4c3c2)cc1 ; c1ccc2c(N(c3ccc4c(c3)oc3cccc(-c5nc6ccc7ccccc7c6o5)c34)c3ccc4ccc5c6ccccc6ccc5c4c3)cccc2c1 ; c1ccc(-c2ccccc2N(c2ccc3c(c2)oc2cccc(-c4nc5ccc6ccccc6c5o4)c23)c2cccc3ccc4c5ccccc5ccc4c23)cc1] 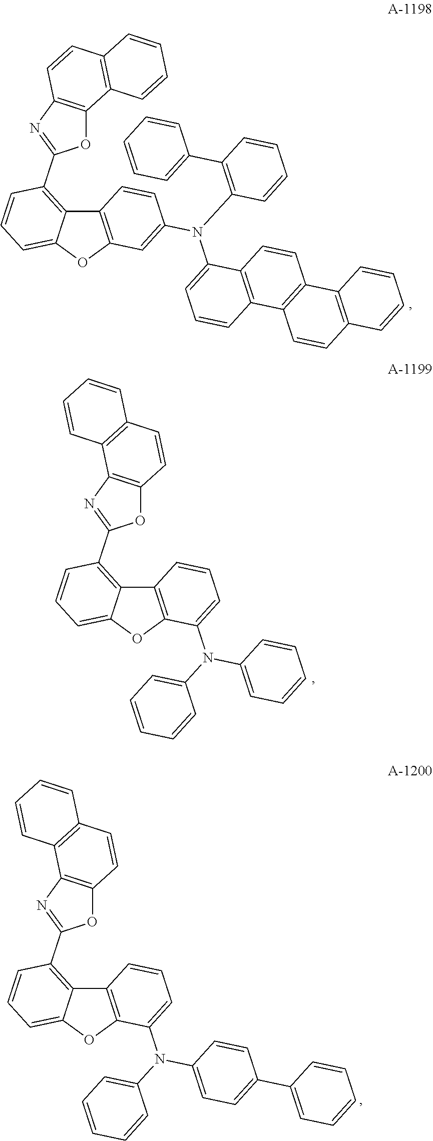 [SMILES: c1ccc(-c2ccccc2N(c2ccc3c(c2)oc2cccc(-c4nc5ccc6ccccc6c5o4)c23)c2cccc3c2ccc2c4ccccc4ccc32)cc1 ; c1ccc(N(c2ccccc2)c2cccc3c2oc2cccc(-c4nc5c(ccc6ccccc65)o4)c23)cc1 ; c1ccc(-c2ccc(N(c3ccccc3)c3cccc4c3oc3cccc(-c5nc6c(ccc7ccccc76)o5)c34)cc2)cc1] 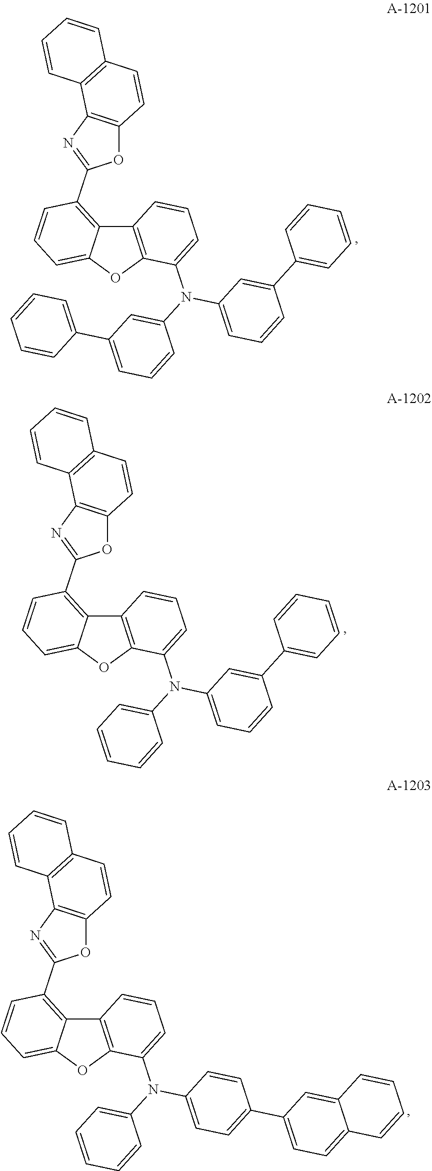 [SMILES: c1ccc(-c2cccc(N(c3cccc(-c4ccccc4)c3)c3cccc4c3oc3cccc(-c5nc6c(ccc7ccccc76)o5)c34)c2)cc1 ; c1ccc(-c2cccc(N(c3ccccc3)c3cccc4c3oc3cccc(-c5nc6c(ccc7ccccc76)o5)c34)c2)cc1 ; c1ccc(N(c2ccc(-c3ccc4ccccc4c3)cc2)c2cccc3c2oc2cccc(-c4nc5c(ccc6ccccc65)o4)c23)cc1] 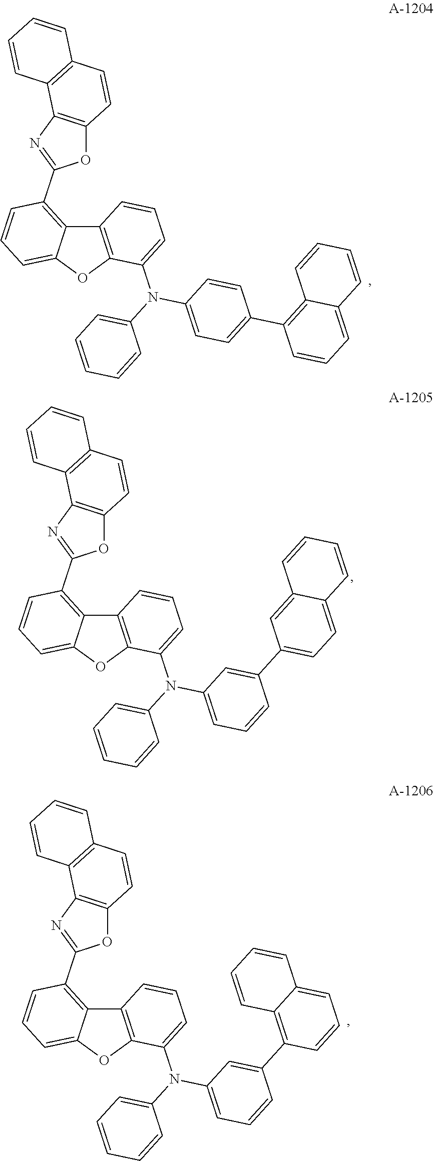 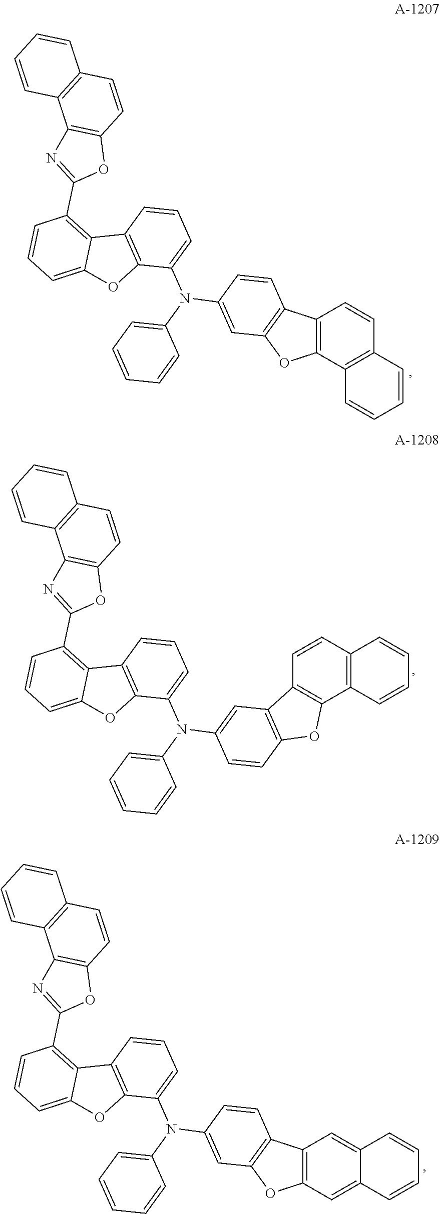 [SMILES: c1ccc(N(c2ccc3c(c2)oc2c4ccccc4ccc32)c2cccc3c2oc2cccc(-c4nc5c(ccc6ccccc65)o4)c23)cc1 ; c1ccc(N(c2ccc3oc4c5ccccc5ccc4c3c2)c2cccc3c2oc2cccc(-c4nc5c(ccc6ccccc65)o4)c23)cc1 ; c1ccc(N(c2ccc3c(c2)oc2cc4ccccc4cc23)c2cccc3c2oc2cccc(-c4nc5c(ccc6ccccc65)o4)c23)cc1] 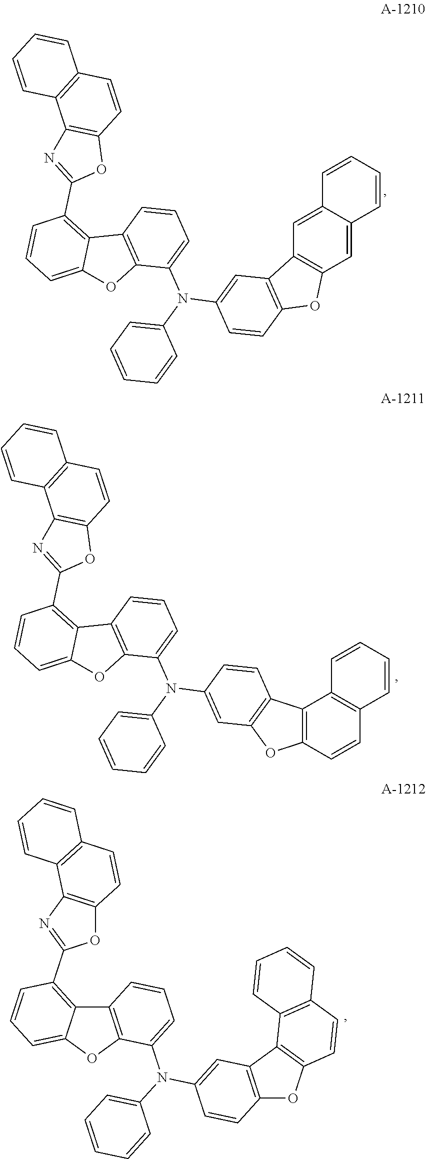 [SMILES: c1ccc(N(c2ccc3oc4cc5ccccc5cc4c3c2)c2cccc3c2oc2cccc(-c4nc5c(ccc6ccccc65)o4)c23)cc1 ; c1ccc(N(c2ccc3c(c2)oc2ccc4ccccc4c23)c2cccc3c2oc2cccc(-c4nc5c(ccc6ccccc65)o4)c23)cc1 ; c1ccc(N(c2ccc3oc4ccc5ccccc5c4c3c2)c2cccc3c2oc2cccc(-c4nc5c(ccc6ccccc65)o4)c23)cc1] 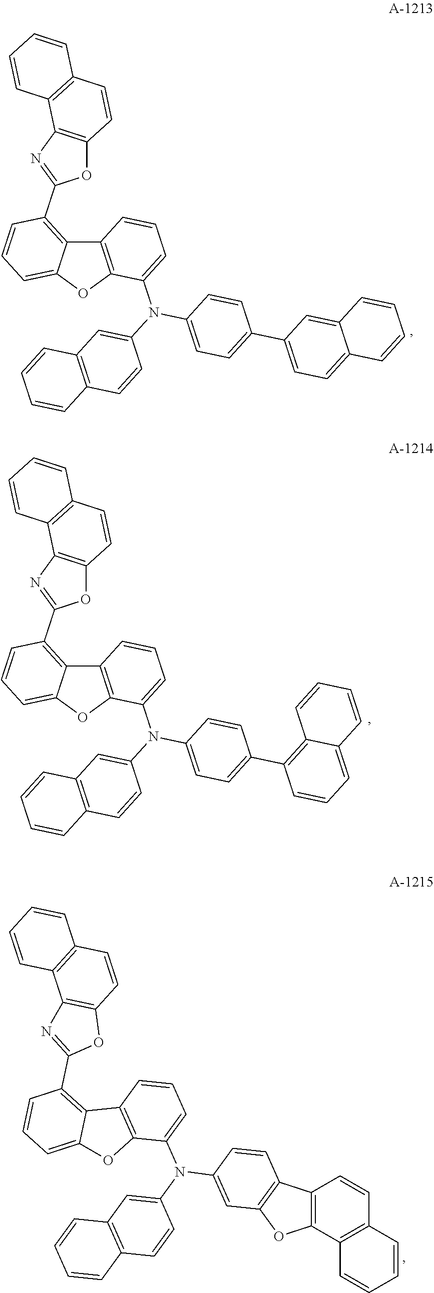 [SMILES: c1ccc2cc(-c3ccc(N(c4ccc5ccccc5c4)c4cccc5c4oc4cccc(-c6nc7c(ccc8ccccc87)o6)c45)cc3)ccc2c1 ; c1ccc2cc(N(c3ccc(-c4cccc5ccccc45)cc3)c3cccc4c3oc3cccc(-c5nc6c(ccc7ccccc76)o5)c34)ccc2c1 ; c1ccc2cc(N(c3ccc4c(c3)oc3c5ccccc5ccc43)c3cccc4c3oc3cccc(-c5nc6c(ccc7ccccc76)o5)c34)ccc2c1] 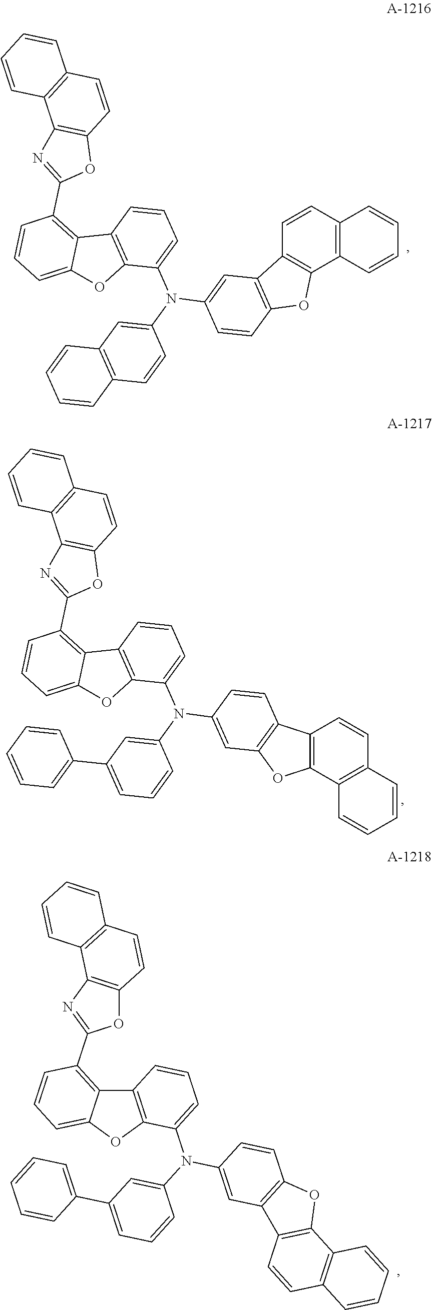 [SMILES: c1ccc2cc(N(c3ccc4oc5c6ccccc6ccc5c4c3)c3cccc4c3oc3cccc(-c5nc6c(ccc7ccccc76)o5)c34)ccc2c1 ; c1ccc(-c2cccc(N(c3ccc4c(c3)oc3c5ccccc5ccc43)c3cccc4c3oc3cccc(-c5nc6c(ccc7ccccc76)o5)c34)c2)cc1 ; c1ccc(-c2cccc(N(c3ccc4oc5c6ccccc6ccc5c4c3)c3cccc4c3oc3cccc(-c5nc6c(ccc7ccccc76)o5)c34)c2)cc1] 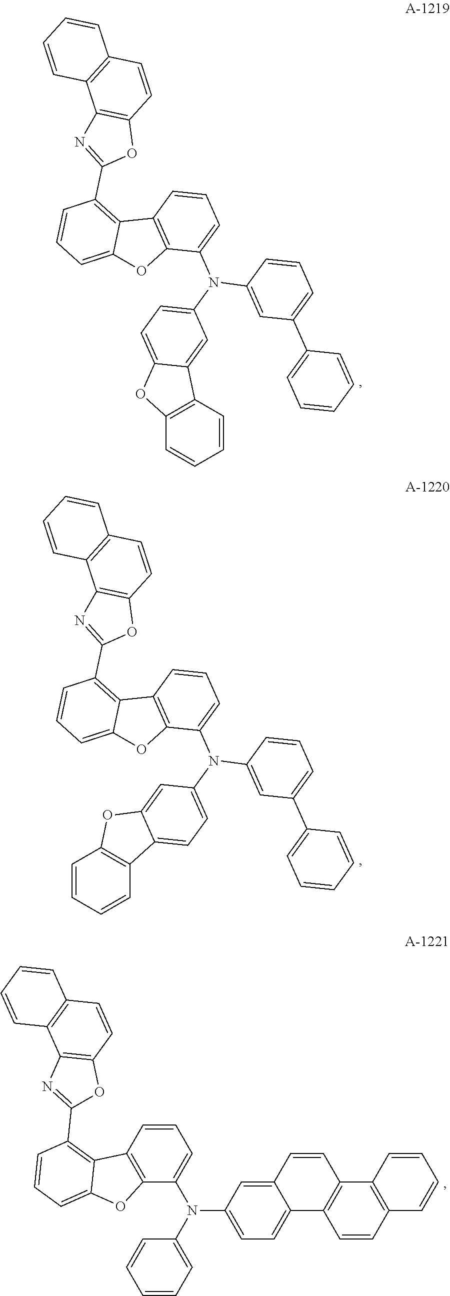 [SMILES: c1ccc(-c2cccc(N(c3ccc4oc5ccccc5c4c3)c3cccc4c3oc3cccc(-c5nc6c(ccc7ccccc76)o5)c34)c2)cc1 ; c1ccc(-c2cccc(N(c3ccc4c(c3)oc3ccccc34)c3cccc4c3oc3cccc(-c5nc6c(ccc7ccccc76)o5)c34)c2)cc1 ; c1ccc(N(c2ccc3c(ccc4c5ccccc5ccc34)c2)c2cccc3c2oc2cccc(-c4nc5c(ccc6ccccc65)o4)c23)cc1] 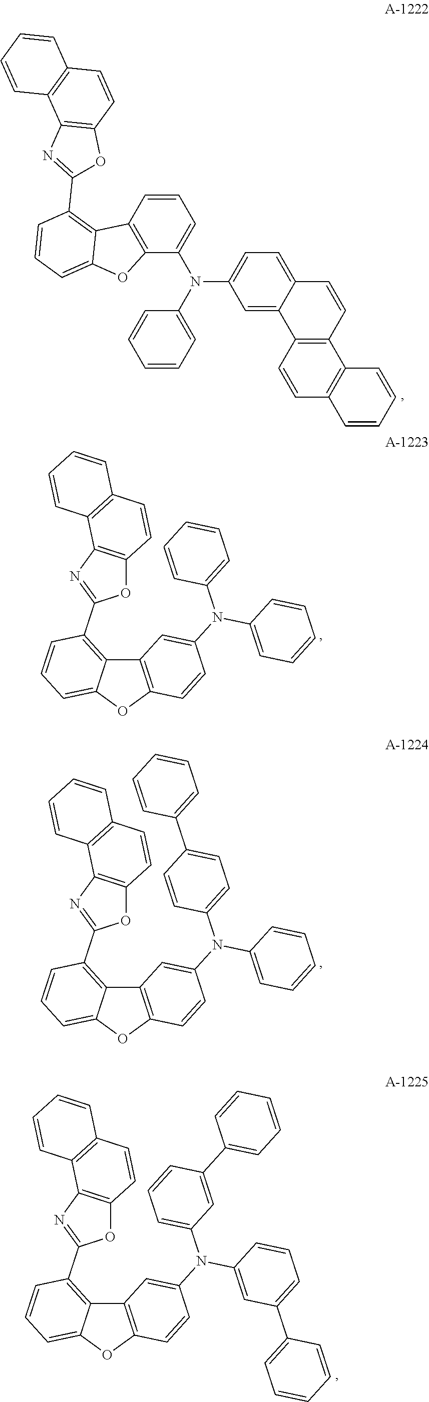 [SMILES: c1ccc(N(c2ccc3ccc4c5ccccc5ccc4c3c2)c2cccc3c2oc2cccc(-c4nc5c(ccc6ccccc65)o4)c23)cc1 ; c1ccc(N(c2ccccc2)c2ccc3oc4cccc(-c5nc6c(ccc7ccccc76)o5)c4c3c2)cc1 ; c1ccc(-c2ccc(N(c3ccccc3)c3ccc4oc5cccc(-c6nc7c(ccc8ccccc87)o6)c5c4c3)cc2)cc1 ; c1ccc(-c2cccc(N(c3cccc(-c4ccccc4)c3)c3ccc4oc5cccc(-c6nc7c(ccc8ccccc87)o6)c5c4c3)c2)cc1] 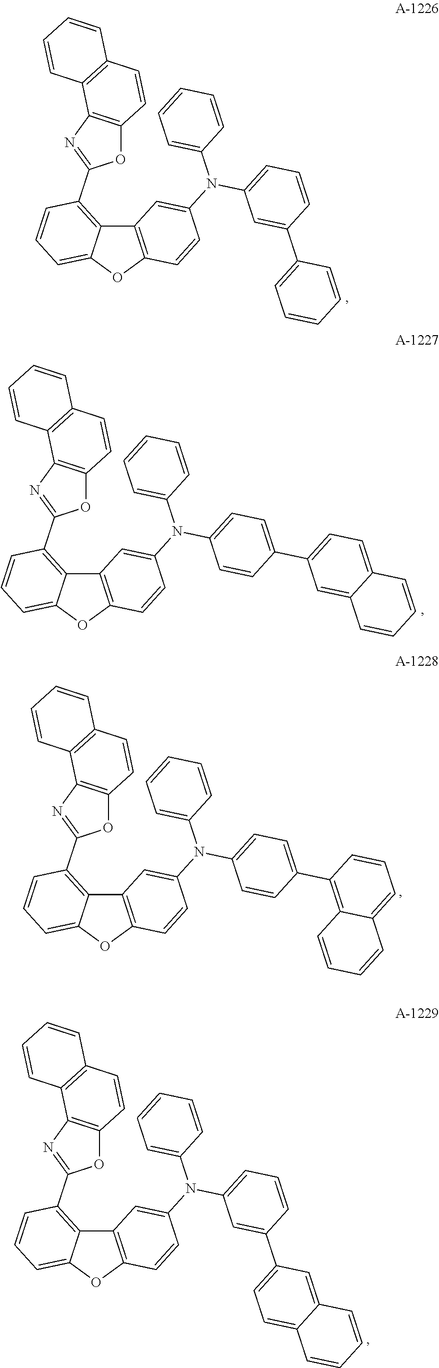 [SMILES: c1ccc(-c2cccc(N(c3ccccc3)c3ccc4oc5cccc(-c6nc7c(ccc8ccccc87)o6)c5c4c3)c2)cc1 ; c1ccc(N(c2ccc(-c3ccc4ccccc4c3)cc2)c2ccc3oc4cccc(-c5nc6c(ccc7ccccc76)o5)c4c3c2)cc1 ; c1ccc(N(c2ccc(-c3cccc4ccccc34)cc2)c2ccc3oc4cccc(-c5nc6c(ccc7ccccc76)o5)c4c3c2)cc1 ; c1ccc(N(c2cccc(-c3ccc4ccccc4c3)c2)c2ccc3oc4cccc(-c5nc6c(ccc7ccccc76)o5)c4c3c2)cc1] 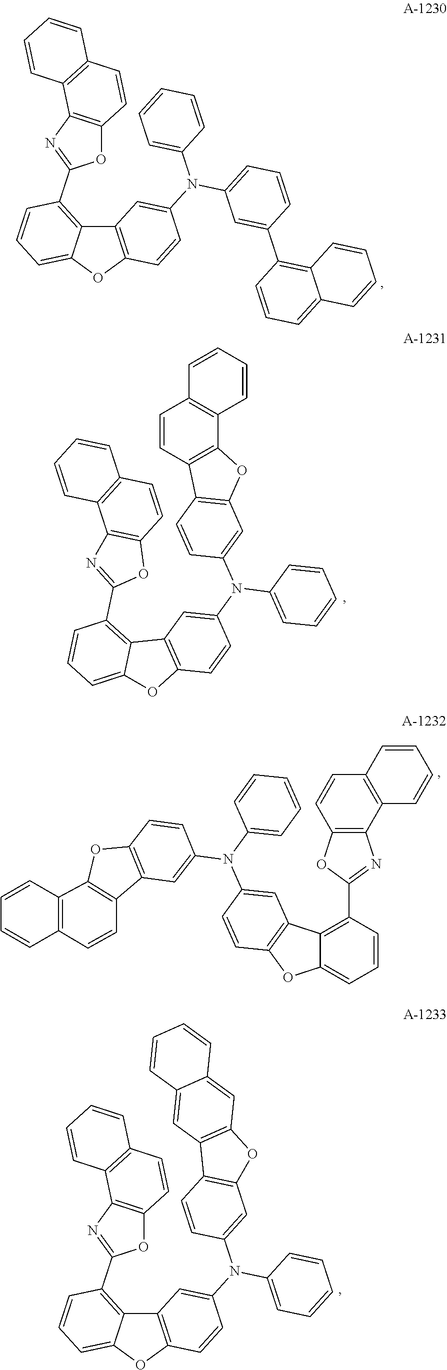 [SMILES: c1ccc(N(c2cccc(-c3cccc4ccccc34)c2)c2ccc3oc4cccc(-c5nc6c(ccc7ccccc76)o5)c4c3c2)cc1 ; c1ccc(N(c2ccc3c(c2)oc2c4ccccc4ccc32)c2ccc3oc4cccc(-c5nc6c(ccc7ccccc76)o5)c4c3c2)cc1 ; c1ccc(N(c2ccc3oc4c5ccccc5ccc4c3c2)c2ccc3oc4cccc(-c5nc6c(ccc7ccccc76)o5)c4c3c2)cc1 ; c1ccc(N(c2ccc3c(c2)oc2cc4ccccc4cc23)c2ccc3oc4cccc(-c5nc6c(ccc7ccccc76)o5)c4c3c2)cc1] 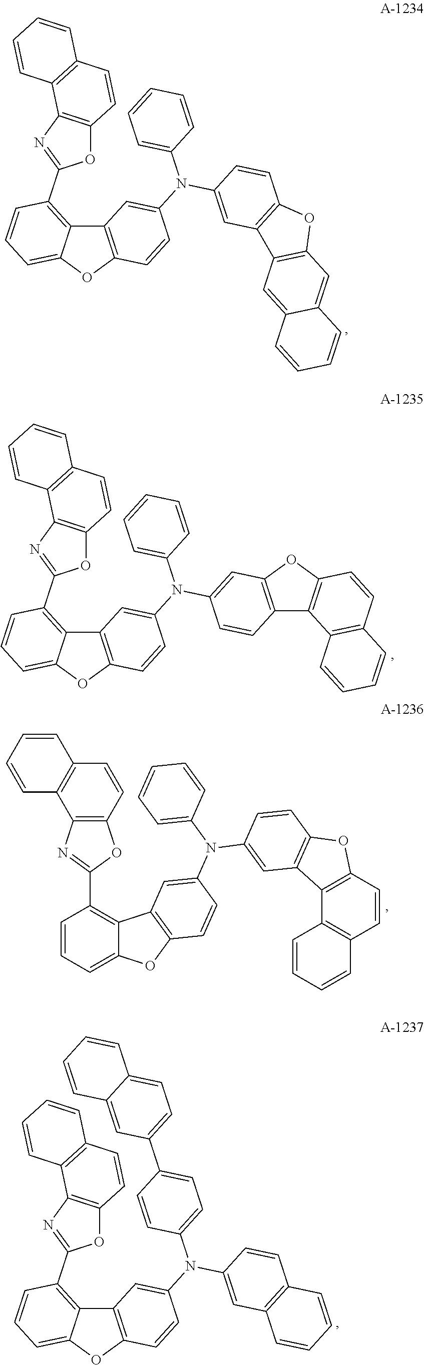 [SMILES: c1ccc(N(c2ccc3oc4cc5ccccc5cc4c3c2)c2ccc3oc4cccc(-c5nc6c(ccc7ccccc76)o5)c4c3c2)cc1 ; c1ccc(N(c2ccc3c(c2)oc2ccc4ccccc4c23)c2ccc3oc4cccc(-c5nc6c(ccc7ccccc76)o5)c4c3c2)cc1 ; c1ccc(N(c2ccc3oc4cccc(-c5nc6c(ccc7ccccc76)o5)c4c3c2)c2ccc3oc4ccc5ccccc5c4c3c2)cc1 ; c1ccc2cc(-c3ccc(N(c4ccc5ccccc5c4)c4ccc5oc6cccc(-c7nc8c(ccc9ccccc98)o7)c6c5c4)cc3)ccc2c1] 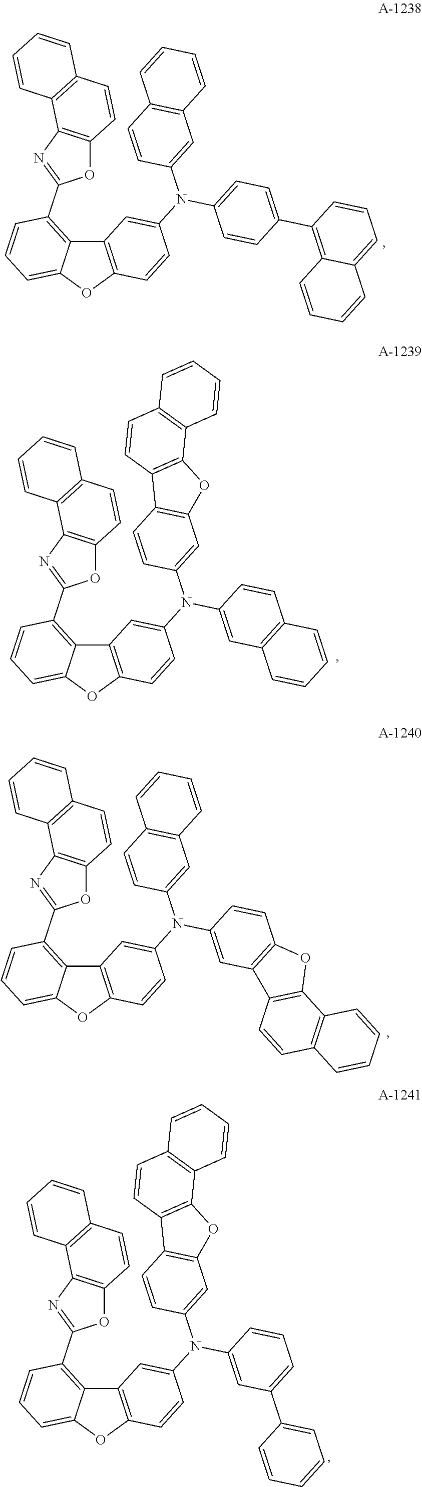 [SMILES: c1ccc2cc(N(c3ccc(-c4cccc5ccccc45)cc3)c3ccc4oc5cccc(-c6nc7c(ccc8ccccc87)o6)c5c4c3)ccc2c1 ; c1ccc2cc(N(c3ccc4c(c3)oc3c5ccccc5ccc43)c3ccc4oc5cccc(-c6nc7c(ccc8ccccc87)o6)c5c4c3)ccc2c1 ; c1ccc2cc(N(c3ccc4oc5c6ccccc6ccc5c4c3)c3ccc4oc5cccc(-c6nc7c(ccc8ccccc87)o6)c5c4c3)ccc2c1 ; c1ccc(-c2cccc(N(c3ccc4c(c3)oc3c5ccccc5ccc43)c3ccc4oc5cccc(-c6nc7c(ccc8ccccc87)o6)c5c4c3)c2)cc1] 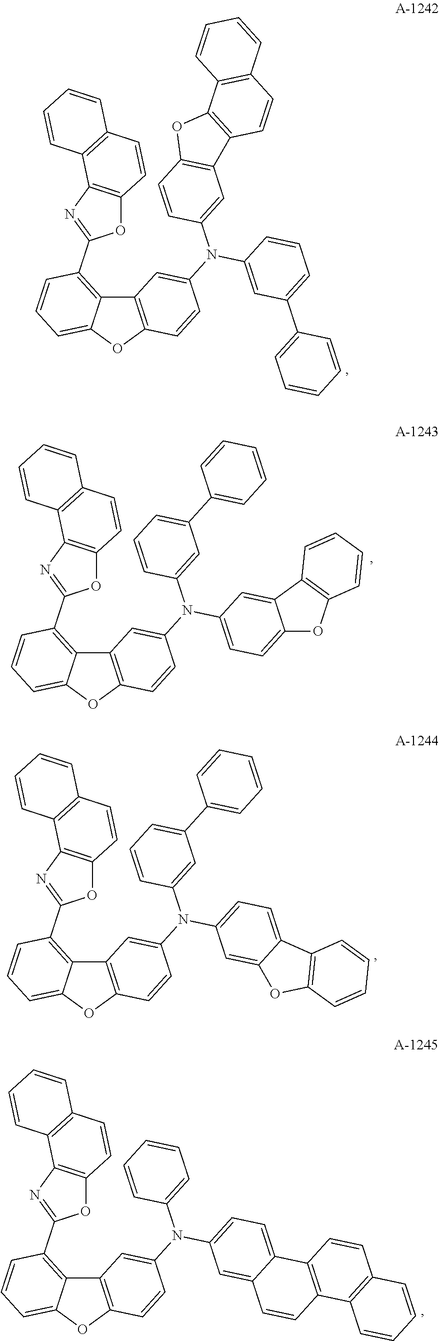 [SMILES: c1ccc(-c2cccc(N(c3ccc4oc5c6ccccc6ccc5c4c3)c3ccc4oc5cccc(-c6nc7c(ccc8ccccc87)o6)c5c4c3)c2)cc1 ; c1ccc(-c2cccc(N(c3ccc4oc5ccccc5c4c3)c3ccc4oc5cccc(-c6nc7c(ccc8ccccc87)o6)c5c4c3)c2)cc1 ; c1ccc(-c2cccc(N(c3ccc4c(c3)oc3ccccc34)c3ccc4oc5cccc(-c6nc7c(ccc8ccccc87)o6)c5c4c3)c2)cc1 ; c1ccc(N(c2ccc3c(ccc4c5ccccc5ccc34)c2)c2ccc3oc4cccc(-c5nc6c(ccc7ccccc76)o5)c4c3c2)cc1] 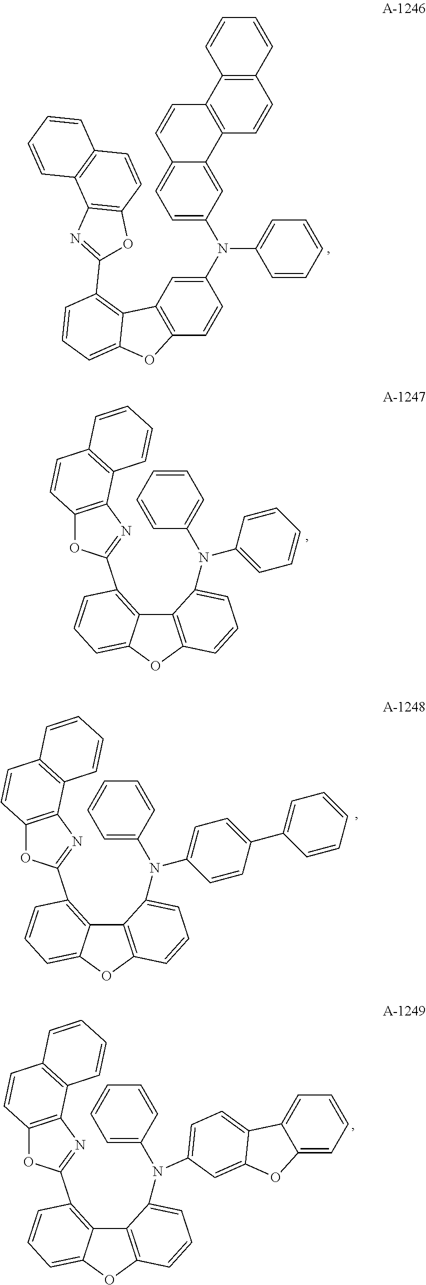 [SMILES: c1ccc(N(c2ccc3ccc4c5ccccc5ccc4c3c2)c2ccc3oc4cccc(-c5nc6c(ccc7ccccc76)o5)c4c3c2)cc1 ; c1ccc(N(c2ccccc2)c2cccc3oc4cccc(-c5nc6c(ccc7ccccc76)o5)c4c23)cc1 ; c1ccc(-c2ccc(N(c3ccccc3)c3cccc4oc5cccc(-c6nc7c(ccc8ccccc87)o6)c5c34)cc2)cc1 ; c1ccc(N(c2ccc3c(c2)oc2ccccc23)c2cccc3oc4cccc(-c5nc6c(ccc7ccccc76)o5)c4c23)cc1] 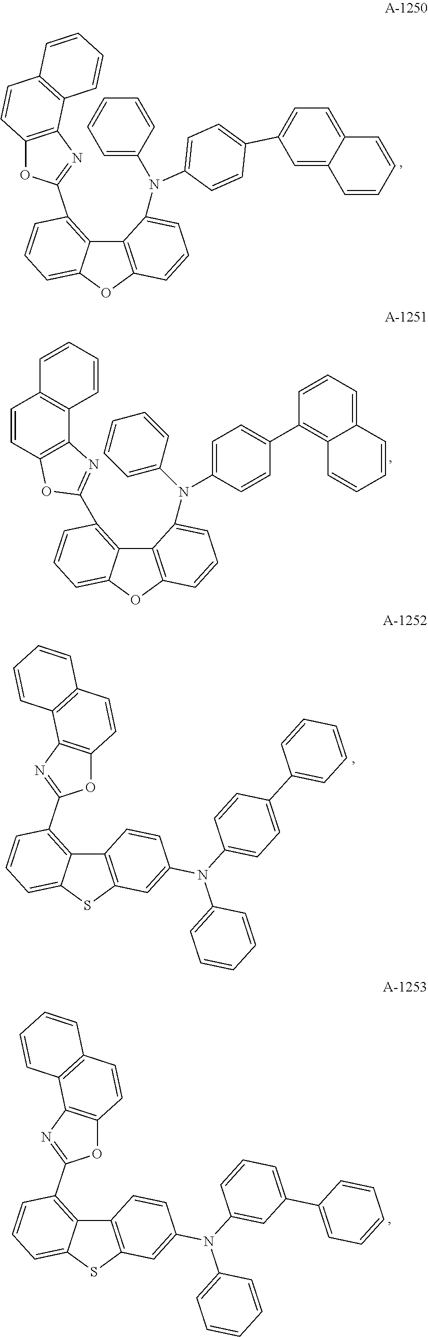 [SMILES: c1ccc(N(c2ccc(-c3ccc4ccccc4c3)cc2)c2cccc3oc4cccc(-c5nc6c(ccc7ccccc76)o5)c4c23)cc1 ; c1ccc(N(c2ccc(-c3cccc4ccccc34)cc2)c2cccc3oc4cccc(-c5nc6c(ccc7ccccc76)o5)c4c23)cc1 ; c1ccc(-c2ccc(N(c3ccccc3)c3ccc4c(c3)sc3cccc(-c5nc6c(ccc7ccccc76)o5)c34)cc2)cc1 ; c1ccc(-c2cccc(N(c3ccccc3)c3ccc4c(c3)sc3cccc(-c5nc6c(ccc7ccccc76)o5)c34)c2)cc1] 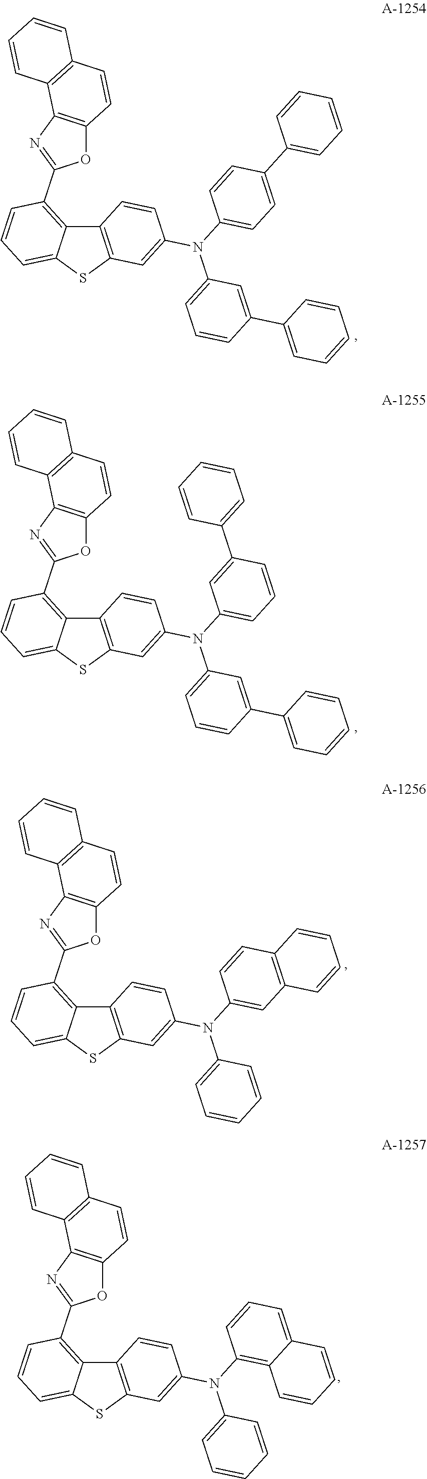 [SMILES: c1ccc(-c2ccc(N(c3cccc(-c4ccccc4)c3)c3ccc4c(c3)sc3cccc(-c5nc6c(ccc7ccccc76)o5)c34)cc2)cc1 ; c1ccc(-c2cccc(N(c3cccc(-c4ccccc4)c3)c3ccc4c(c3)sc3cccc(-c5nc6c(ccc7ccccc76)o5)c34)c2)cc1 ; c1ccc(N(c2ccc3ccccc3c2)c2ccc3c(c2)sc2cccc(-c4nc5c(ccc6ccccc65)o4)c23)cc1 ; c1ccc(N(c2ccc3c(c2)sc2cccc(-c4nc5c(ccc6ccccc65)o4)c23)c2cccc3ccccc23)cc1] 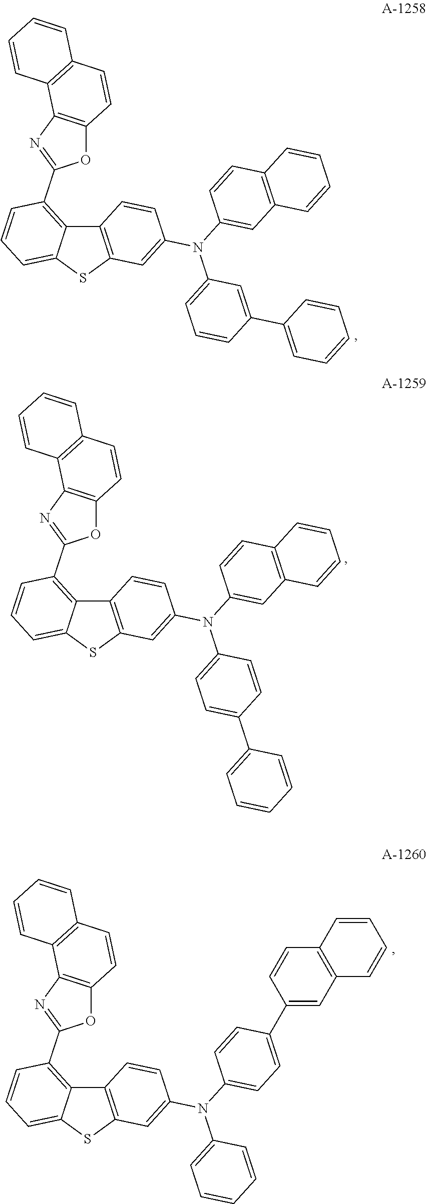 [SMILES: c1ccc(-c2cccc(N(c3ccc4ccccc4c3)c3ccc4c(c3)sc3cccc(-c5nc6c(ccc7ccccc76)o5)c34)c2)cc1 ; c1ccc(-c2ccc(N(c3ccc4ccccc4c3)c3ccc4c(c3)sc3cccc(-c5nc6c(ccc7ccccc76)o5)c34)cc2)cc1 ; c1ccc(N(c2ccc(-c3ccc4ccccc4c3)cc2)c2ccc3c(c2)sc2cccc(-c4nc5c(ccc6ccccc65)o4)c23)cc1] 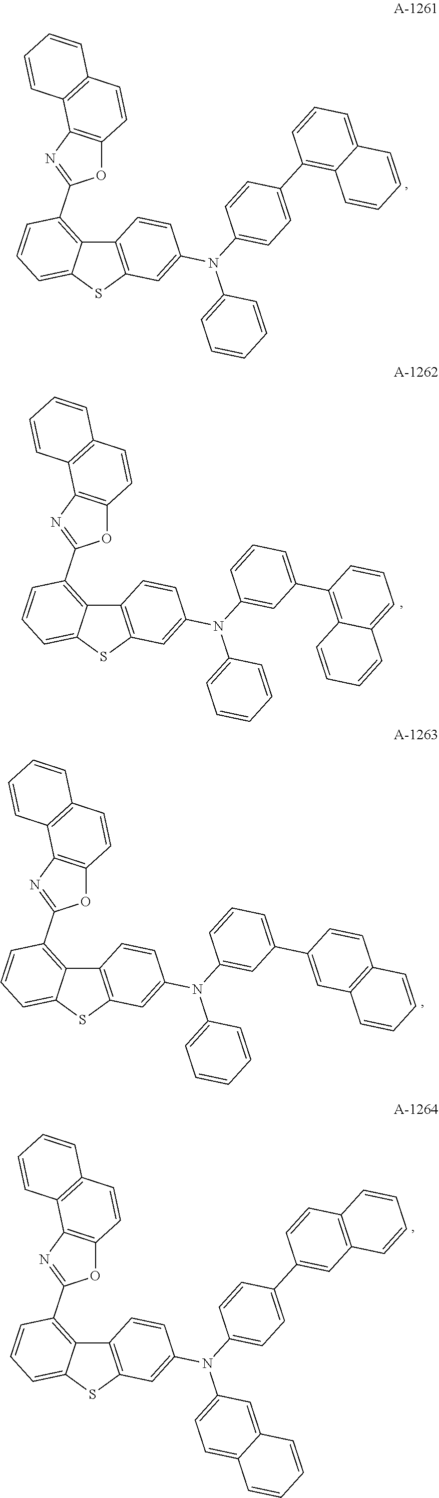 [SMILES: c1ccc(N(c2ccc(-c3cccc4ccccc34)cc2)c2ccc3c(c2)sc2cccc(-c4nc5c(ccc6ccccc65)o4)c23)cc1 ; c1ccc(N(c2cccc(-c3cccc4ccccc34)c2)c2ccc3c(c2)sc2cccc(-c4nc5c(ccc6ccccc65)o4)c23)cc1 ; c1ccc(N(c2cccc(-c3ccc4ccccc4c3)c2)c2ccc3c(c2)sc2cccc(-c4nc5c(ccc6ccccc65)o4)c23)cc1 ; c1ccc2cc(-c3ccc(N(c4ccc5ccccc5c4)c4ccc5c(c4)sc4cccc(-c6nc7c(ccc8ccccc87)o6)c45)cc3)ccc2c1] 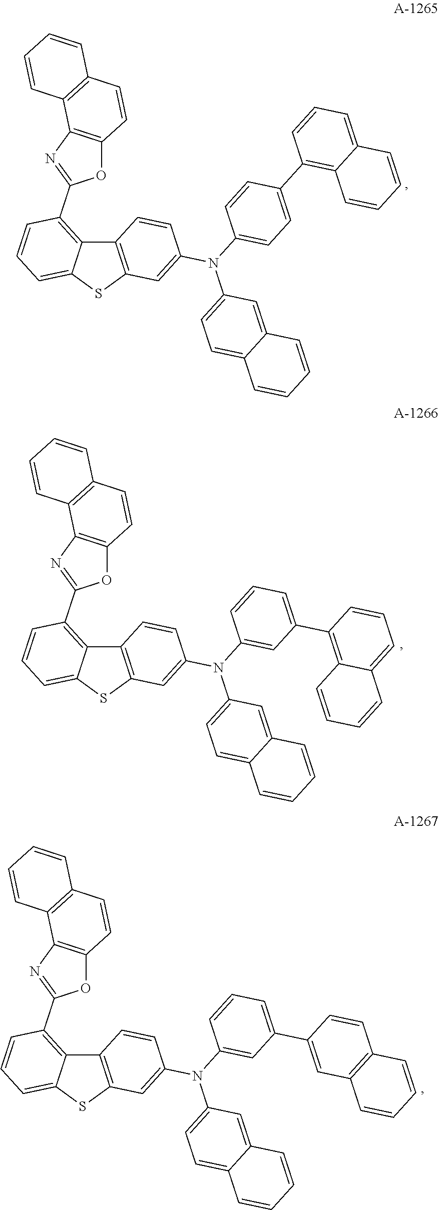 [SMILES: c1ccc2cc(N(c3ccc(-c4cccc5ccccc45)cc3)c3ccc4c(c3)sc3cccc(-c5nc6c(ccc7ccccc76)o5)c34)ccc2c1 ; c1cc(-c2cccc3ccccc23)cc(N(c2ccc3ccccc3c2)c2ccc3c(c2)sc2cccc(-c4nc5c(ccc6ccccc65)o4)c23)c1 ; c1cc(-c2ccc3ccccc3c2)cc(N(c2ccc3ccccc3c2)c2ccc3c(c2)sc2cccc(-c4nc5c(ccc6ccccc65)o4)c23)c1] 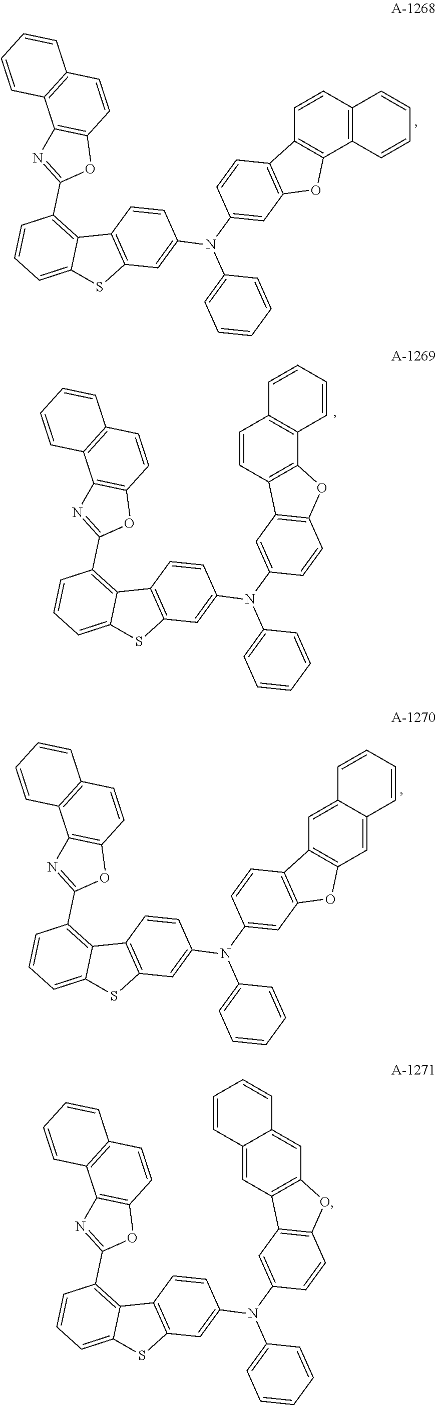 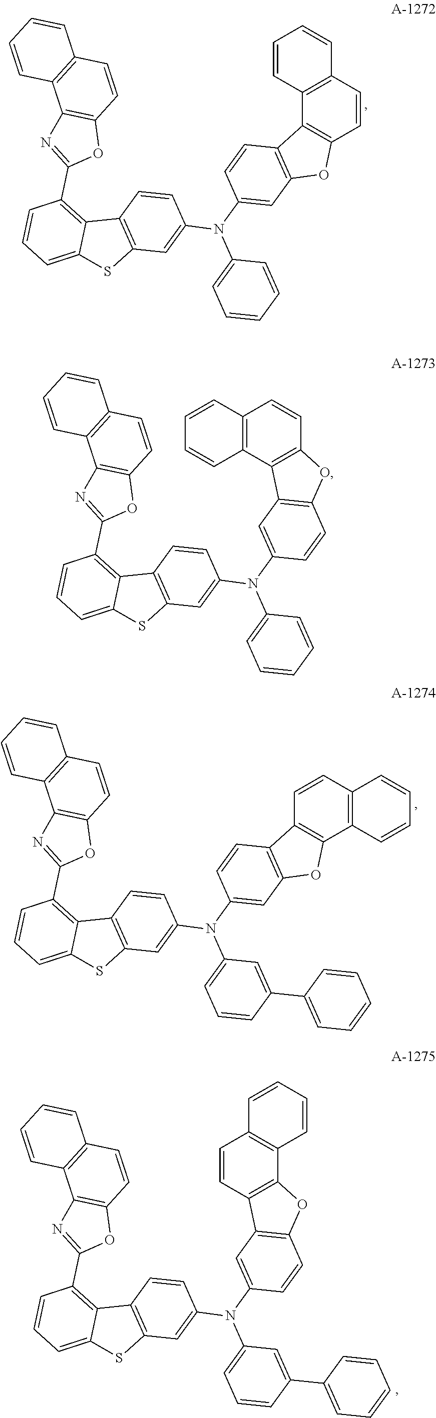 [SMILES: c1ccc(N(c2ccc3c(c2)oc2ccc4ccccc4c23)c2ccc3c(c2)sc2cccc(-c4nc5c(ccc6ccccc65)o4)c23)cc1 ; c1ccc(N(c2ccc3c(c2)sc2cccc(-c4nc5c(ccc6ccccc65)o4)c23)c2ccc3oc4ccc5ccccc5c4c3c2)cc1 ; c1ccc(-c2cccc(N(c3ccc4c(c3)oc3c5ccccc5ccc43)c3ccc4c(c3)sc3cccc(-c5nc6c(ccc7ccccc76)o5)c34)c2)cc1 ; c1ccc(-c2cccc(N(c3ccc4c(c3)sc3cccc(-c5nc6c(ccc7ccccc76)o5)c34)c3ccc4oc5c6ccccc6ccc5c4c3)c2)cc1] 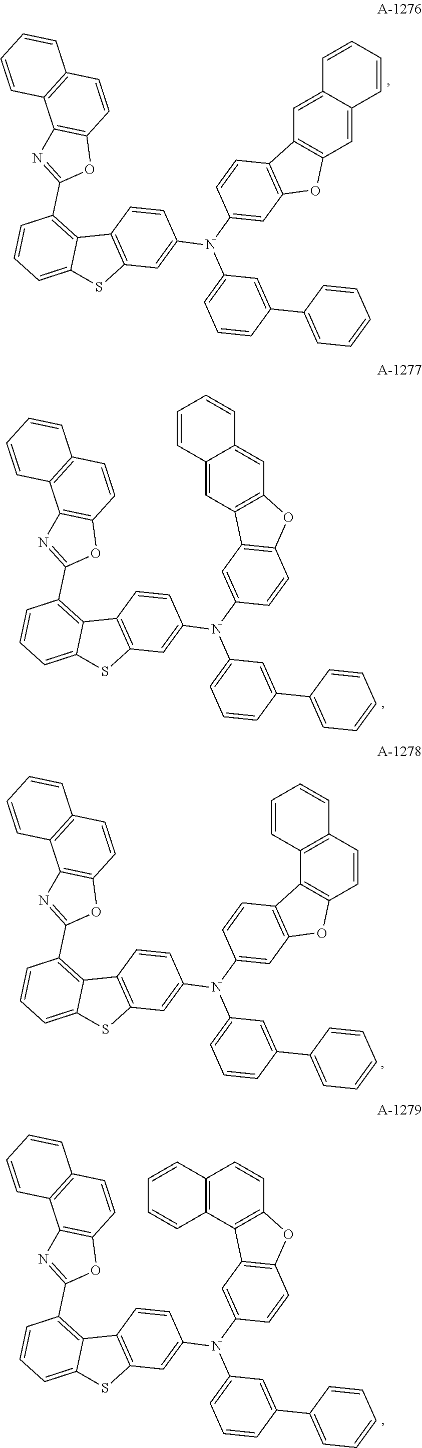 [SMILES: c1ccc(-c2cccc(N(c3ccc4c(c3)oc3cc5ccccc5cc34)c3ccc4c(c3)sc3cccc(-c5nc6c(ccc7ccccc76)o5)c34)c2)cc1 ; c1ccc(-c2cccc(N(c3ccc4c(c3)sc3cccc(-c5nc6c(ccc7ccccc76)o5)c34)c3ccc4oc5cc6ccccc6cc5c4c3)c2)cc1 ; c1ccc(-c2cccc(N(c3ccc4c(c3)oc3ccc5ccccc5c34)c3ccc4c(c3)sc3cccc(-c5nc6c(ccc7ccccc76)o5)c34)c2)cc1 ; c1ccc(-c2cccc(N(c3ccc4c(c3)sc3cccc(-c5nc6c(ccc7ccccc76)o5)c34)c3ccc4oc5ccc6ccccc6c5c4c3)c2)cc1] 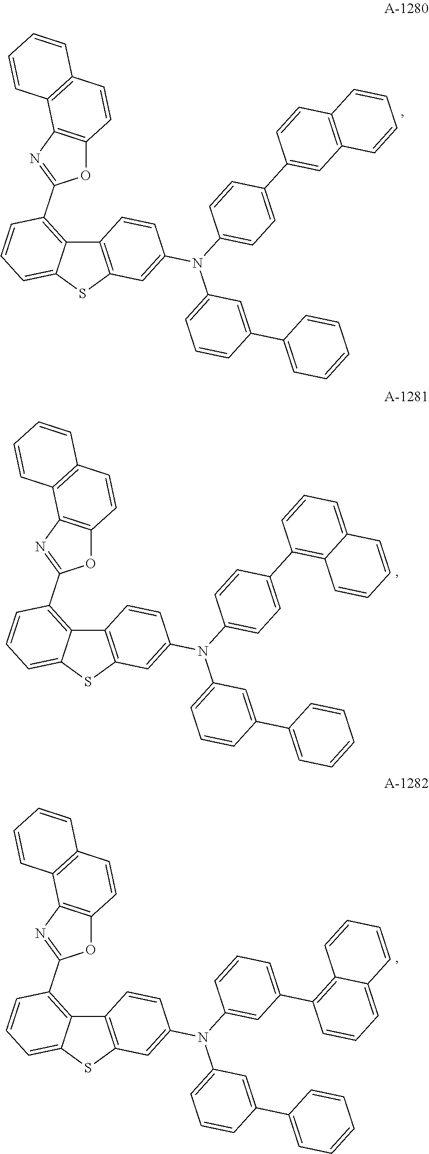 [SMILES: c1ccc(-c2cccc(N(c3ccc(-c4ccc5ccccc5c4)cc3)c3ccc4c(c3)sc3cccc(-c5nc6c(ccc7ccccc76)o5)c34)c2)cc1 ; c1ccc(-c2cccc(N(c3ccc(-c4cccc5ccccc45)cc3)c3ccc4c(c3)sc3cccc(-c5nc6c(ccc7ccccc76)o5)c34)c2)cc1 ; c1ccc(-c2cccc(N(c3cccc(-c4cccc5ccccc45)c3)c3ccc4c(c3)sc3cccc(-c5nc6c(ccc7ccccc76)o5)c34)c2)cc1] 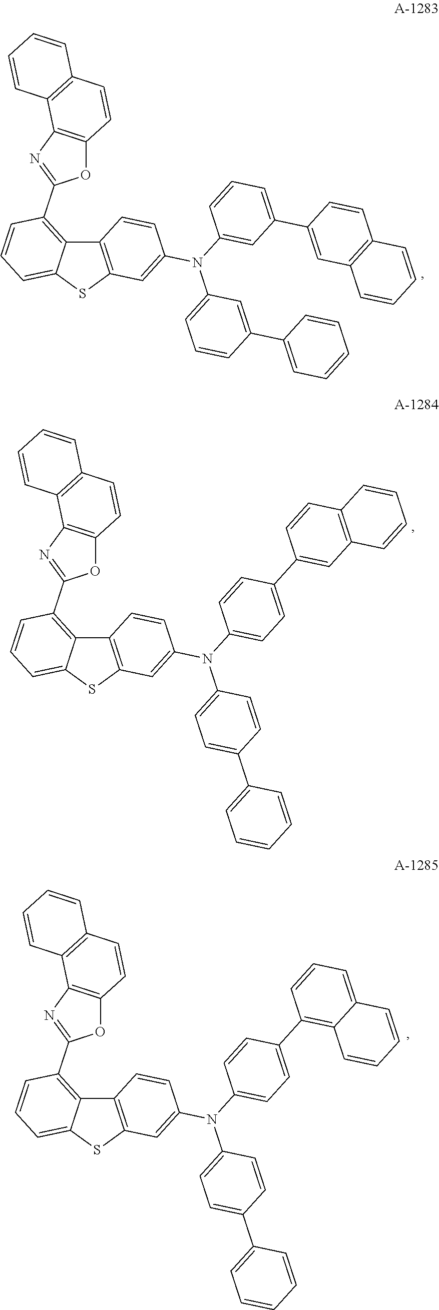 [SMILES: c1ccc(-c2cccc(N(c3cccc(-c4ccc5ccccc5c4)c3)c3ccc4c(c3)sc3cccc(-c5nc6c(ccc7ccccc76)o5)c34)c2)cc1 ; c1ccc(-c2ccc(N(c3ccc(-c4ccc5ccccc5c4)cc3)c3ccc4c(c3)sc3cccc(-c5nc6c(ccc7ccccc76)o5)c34)cc2)cc1 ; c1ccc(-c2ccc(N(c3ccc(-c4cccc5ccccc45)cc3)c3ccc4c(c3)sc3cccc(-c5nc6c(ccc7ccccc76)o5)c34)cc2)cc1] 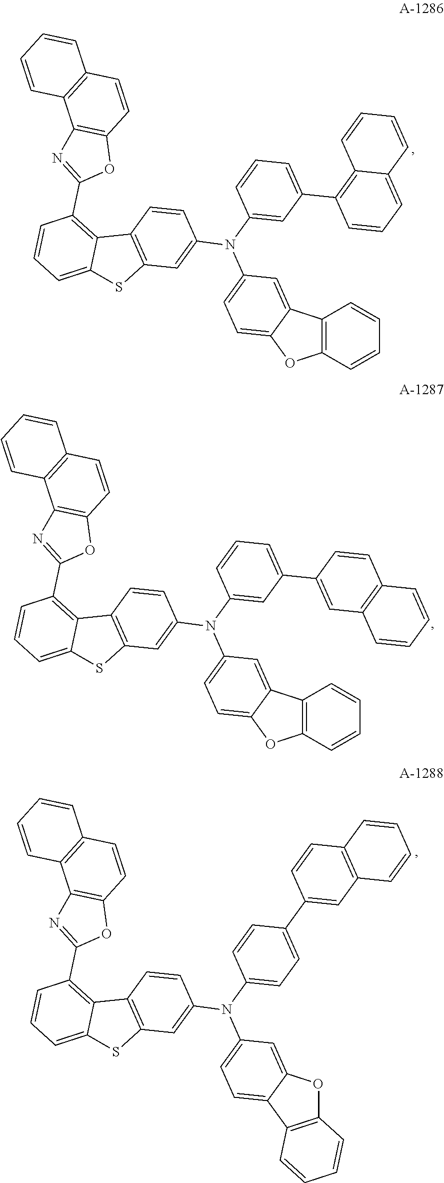 [SMILES: c1cc(-c2cccc3ccccc23)cc(N(c2ccc3c(c2)sc2cccc(-c4nc5c(ccc6ccccc65)o4)c23)c2ccc3oc4ccccc4c3c2)c1 ; c1cc(-c2ccc3ccccc3c2)cc(N(c2ccc3c(c2)sc2cccc(-c4nc5c(ccc6ccccc65)o4)c23)c2ccc3oc4ccccc4c3c2)c1 ; c1ccc2cc(-c3ccc(N(c4ccc5c(c4)oc4ccccc45)c4ccc5c(c4)sc4cccc(-c6nc7c(ccc8ccccc87)o6)c45)cc3)ccc2c1] 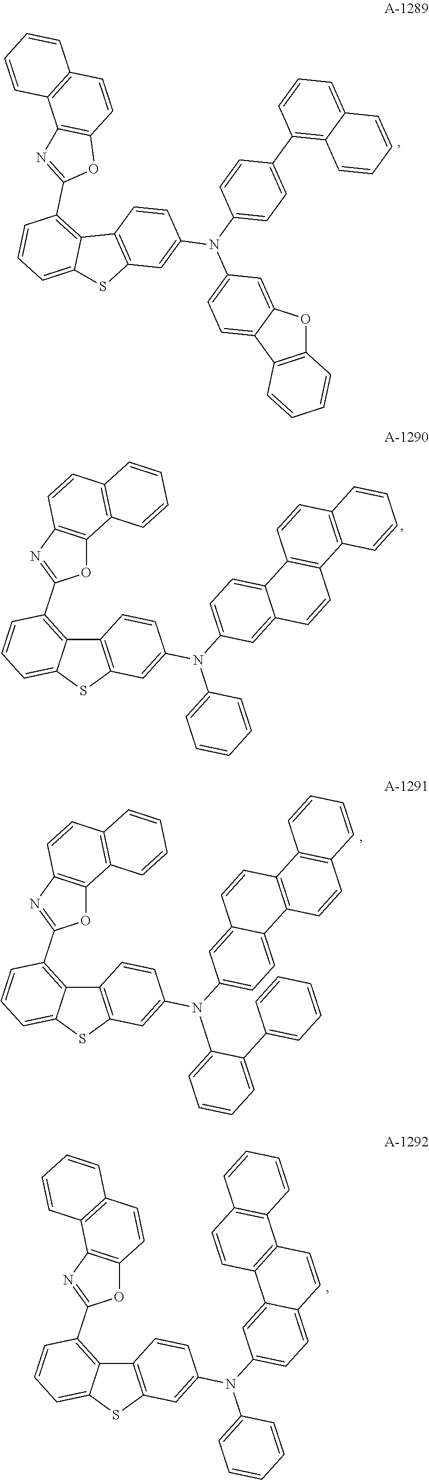 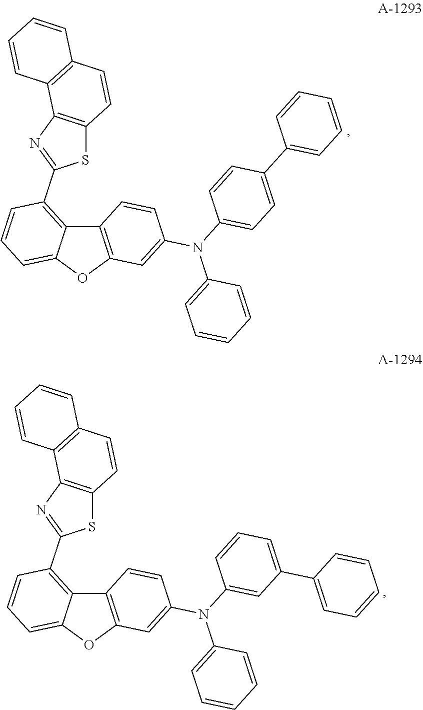 [SMILES: c1ccc(-c2ccc(N(c3ccccc3)c3ccc4c(c3)oc3cccc(-c5nc6c(ccc7ccccc76)s5)c34)cc2)cc1 ; c1ccc(-c2cccc(N(c3ccccc3)c3ccc4c(c3)oc3cccc(-c5nc6c(ccc7ccccc76)s5)c34)c2)cc1] 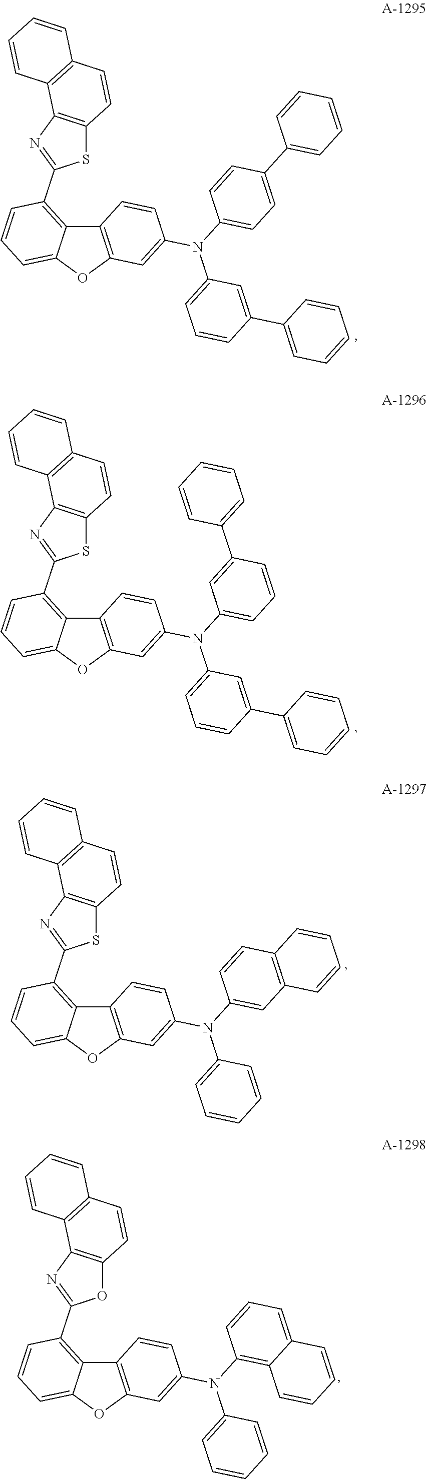 [SMILES: c1ccc(-c2ccc(N(c3cccc(-c4ccccc4)c3)c3ccc4c(c3)oc3cccc(-c5nc6c(ccc7ccccc76)s5)c34)cc2)cc1 ; c1ccc(-c2cccc(N(c3cccc(-c4ccccc4)c3)c3ccc4c(c3)oc3cccc(-c5nc6c(ccc7ccccc76)s5)c34)c2)cc1 ; c1ccc(N(c2ccc3ccccc3c2)c2ccc3c(c2)oc2cccc(-c4nc5c(ccc6ccccc65)s4)c23)cc1 ; c1ccc(N(c2ccc3c(c2)oc2cccc(-c4nc5c(ccc6ccccc65)o4)c23)c2cccc3ccccc23)cc1] 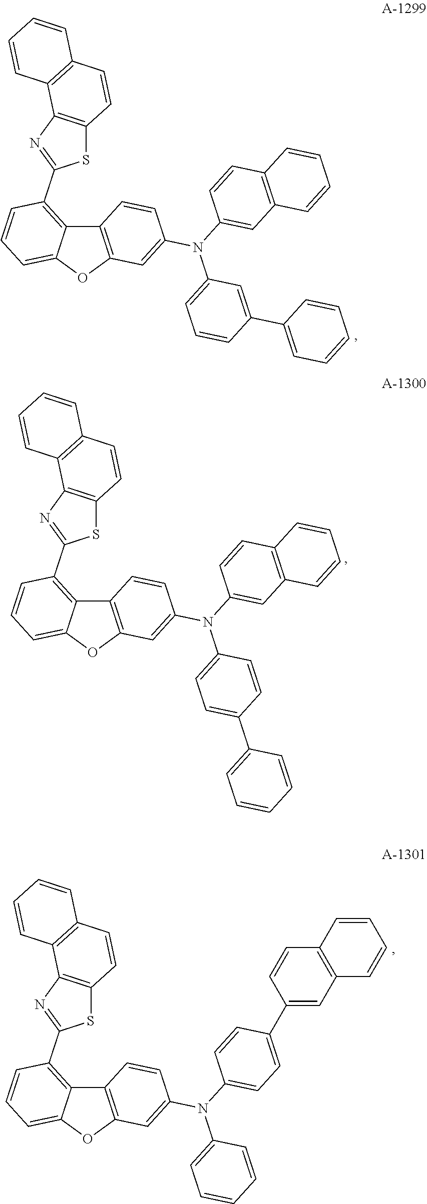 [SMILES: c1ccc(-c2cccc(N(c3ccc4ccccc4c3)c3ccc4c(c3)oc3cccc(-c5nc6c(ccc7ccccc76)s5)c34)c2)cc1 ; c1ccc(-c2ccc(N(c3ccc4ccccc4c3)c3ccc4c(c3)oc3cccc(-c5nc6c(ccc7ccccc76)s5)c34)cc2)cc1 ; c1ccc(N(c2ccc(-c3ccc4ccccc4c3)cc2)c2ccc3c(c2)oc2cccc(-c4nc5c(ccc6ccccc65)s4)c23)cc1] 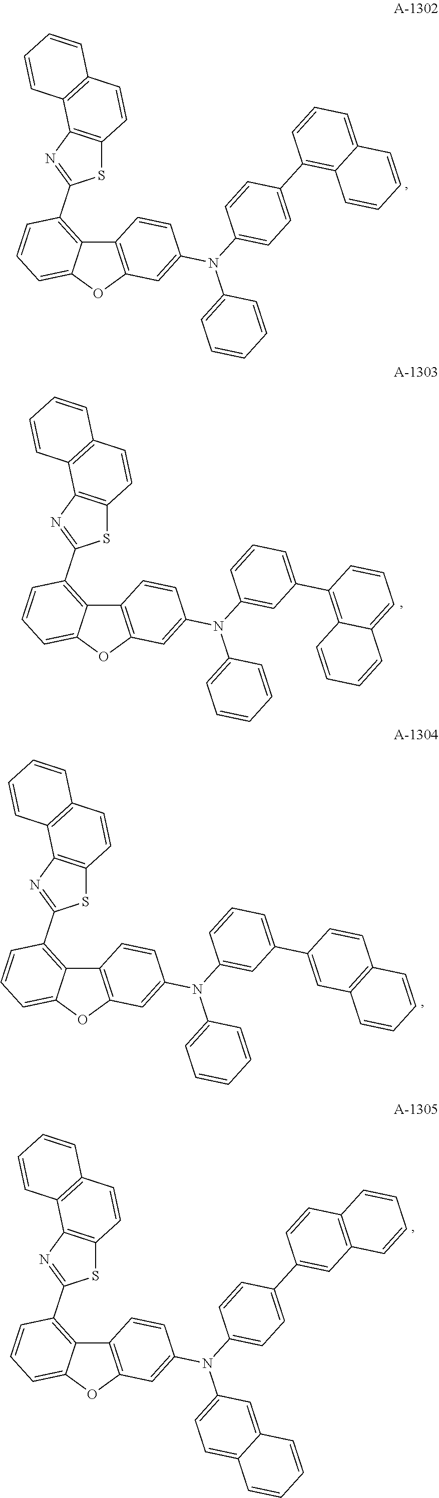 [SMILES: c1ccc(N(c2ccc(-c3cccc4ccccc34)cc2)c2ccc3c(c2)oc2cccc(-c4nc5c(ccc6ccccc65)s4)c23)cc1 ; c1ccc(N(c2cccc(-c3cccc4ccccc34)c2)c2ccc3c(c2)oc2cccc(-c4nc5c(ccc6ccccc65)s4)c23)cc1 ; c1ccc(N(c2cccc(-c3ccc4ccccc4c3)c2)c2ccc3c(c2)oc2cccc(-c4nc5c(ccc6ccccc65)s4)c23)cc1 ; c1ccc2cc(-c3ccc(N(c4ccc5ccccc5c4)c4ccc5c(c4)oc4cccc(-c6nc7c(ccc8ccccc87)s6)c45)cc3)ccc2c1] 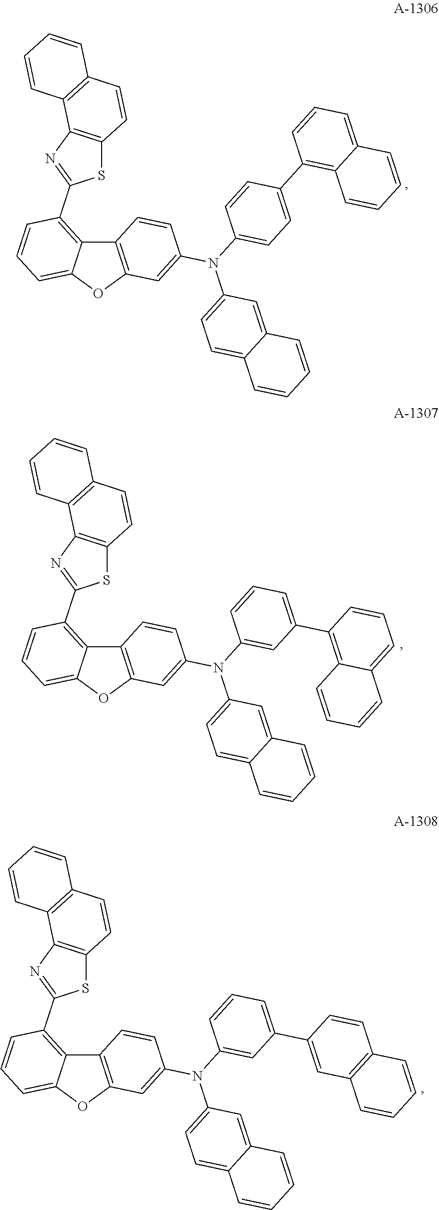 [SMILES: c1ccc2cc(N(c3ccc(-c4cccc5ccccc45)cc3)c3ccc4c(c3)oc3cccc(-c5nc6c(ccc7ccccc76)s5)c34)ccc2c1 ; c1cc(-c2cccc3ccccc23)cc(N(c2ccc3ccccc3c2)c2ccc3c(c2)oc2cccc(-c4nc5c(ccc6ccccc65)s4)c23)c1 ; c1cc(-c2ccc3ccccc3c2)cc(N(c2ccc3ccccc3c2)c2ccc3c(c2)oc2cccc(-c4nc5c(ccc6ccccc65)s4)c23)c1] 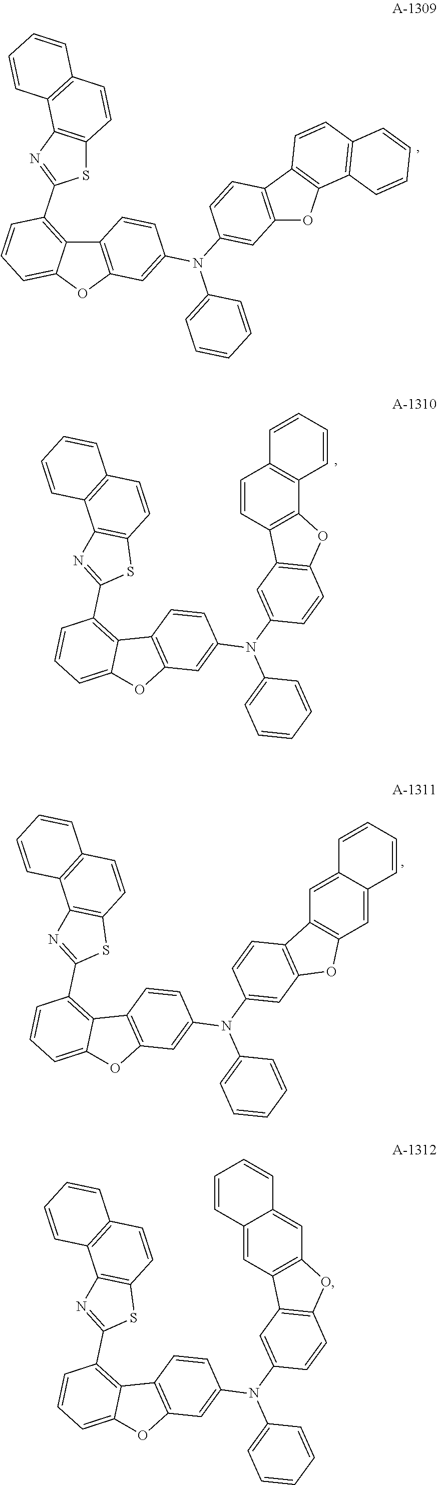 [SMILES: c1ccc(N(c2ccc3c(c2)oc2c4ccccc4ccc32)c2ccc3c(c2)oc2cccc(-c4nc5c(ccc6ccccc65)s4)c23)cc1 ; c1ccc(N(c2ccc3c(c2)oc2cccc(-c4nc5c(ccc6ccccc65)s4)c23)c2ccc3oc4c5ccccc5ccc4c3c2)cc1 ; c1ccc(N(c2ccc3c(c2)oc2cc4ccccc4cc23)c2ccc3c(c2)oc2cccc(-c4nc5c(ccc6ccccc65)s4)c23)cc1 ; c1ccc(N(c2ccc3c(c2)oc2cccc(-c4nc5c(ccc6ccccc65)s4)c23)c2ccc3oc4cc5ccccc5cc4c3c2)cc1] 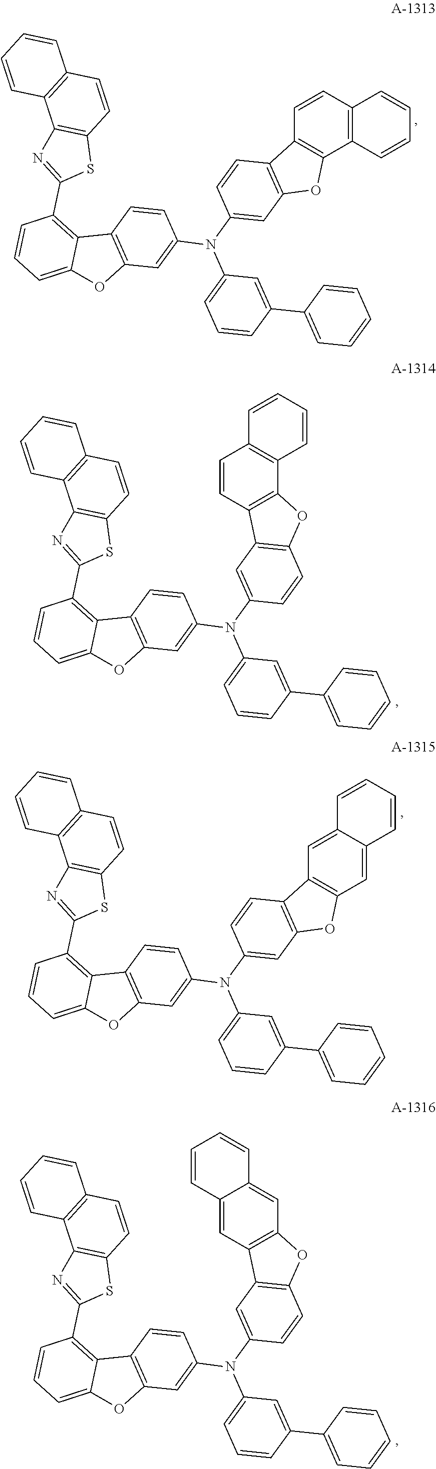 [SMILES: c1ccc(-c2cccc(N(c3ccc4c(c3)oc3c5ccccc5ccc43)c3ccc4c(c3)oc3cccc(-c5nc6c(ccc7ccccc76)s5)c34)c2)cc1 ; c1ccc(-c2cccc(N(c3ccc4c(c3)oc3cccc(-c5nc6c(ccc7ccccc76)s5)c34)c3ccc4oc5c6ccccc6ccc5c4c3)c2)cc1 ; c1ccc(-c2cccc(N(c3ccc4c(c3)oc3cc5ccccc5cc34)c3ccc4c(c3)oc3cccc(-c5nc6c(ccc7ccccc76)s5)c34)c2)cc1 ; c1ccc(-c2cccc(N(c3ccc4c(c3)oc3cccc(-c5nc6c(ccc7ccccc76)s5)c34)c3ccc4oc5cc6ccccc6cc5c4c3)c2)cc1] 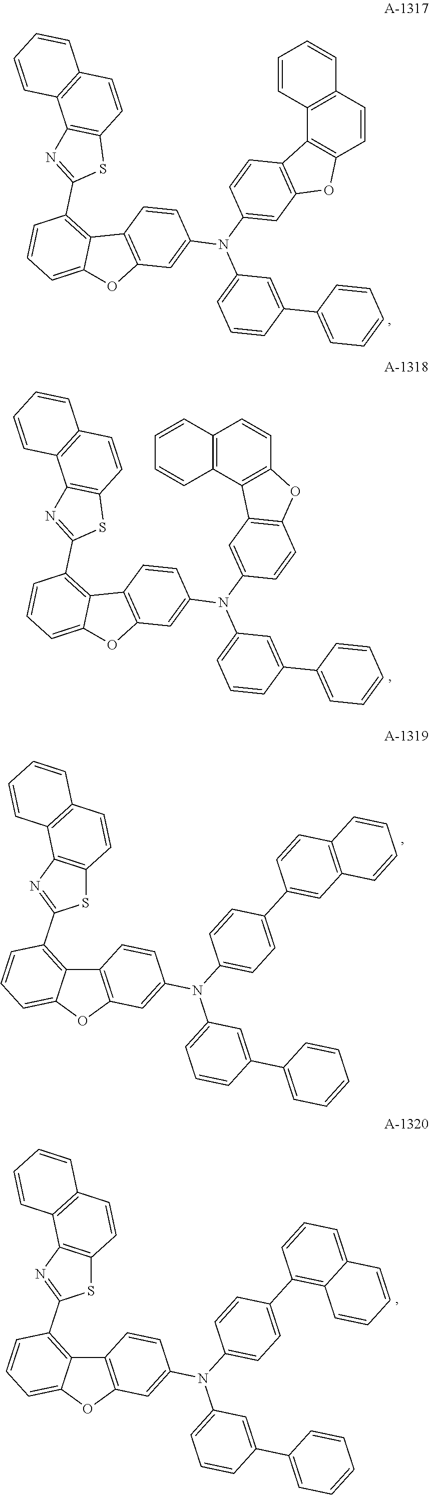 [SMILES: c1ccc(-c2cccc(N(c3ccc4c(c3)oc3cccc(-c5nc6c(ccc7ccccc76)s5)c34)c3ccc4c(c3)oc3ccc5ccccc5c34)c2)cc1 ; c1ccc(-c2cccc(N(c3ccc4c(c3)oc3cccc(-c5nc6c(ccc7ccccc76)s5)c34)c3ccc4oc5ccc6ccccc6c5c4c3)c2)cc1 ; c1ccc(-c2cccc(N(c3ccc(-c4ccc5ccccc5c4)cc3)c3ccc4c(c3)oc3cccc(-c5nc6c(ccc7ccccc76)s5)c34)c2)cc1 ; c1ccc(-c2cccc(N(c3ccc(-c4cccc5ccccc45)cc3)c3ccc4c(c3)oc3cccc(-c5nc6c(ccc7ccccc76)s5)c34)c2)cc1] 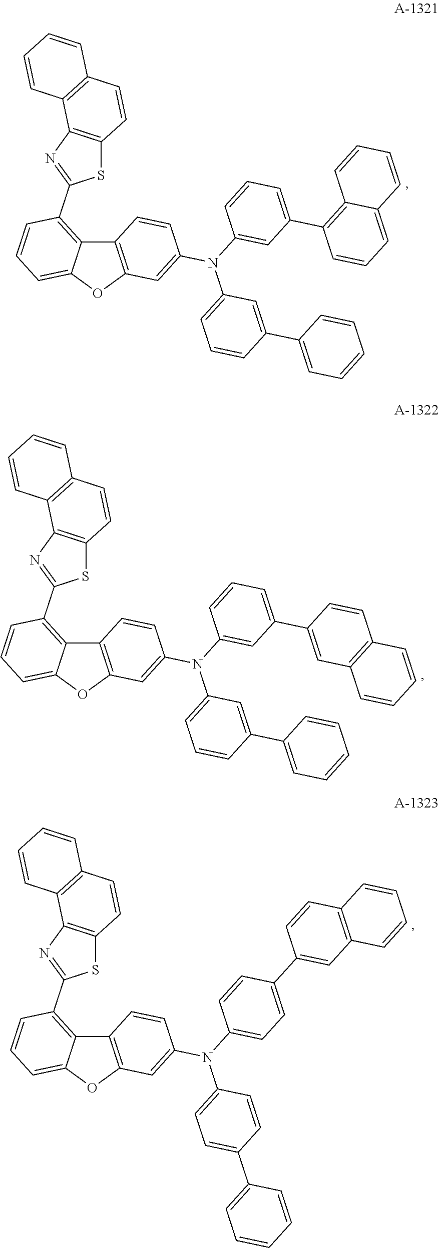 [SMILES: c1ccc(-c2cccc(N(c3cccc(-c4cccc5ccccc45)c3)c3ccc4c(c3)oc3cccc(-c5nc6c(ccc7ccccc76)s5)c34)c2)cc1 ; c1ccc(-c2cccc(N(c3cccc(-c4ccc5ccccc5c4)c3)c3ccc4c(c3)oc3cccc(-c5nc6c(ccc7ccccc76)s5)c34)c2)cc1 ; c1ccc(-c2ccc(N(c3ccc(-c4ccc5ccccc5c4)cc3)c3ccc4c(c3)oc3cccc(-c5nc6c(ccc7ccccc76)s5)c34)cc2)cc1] 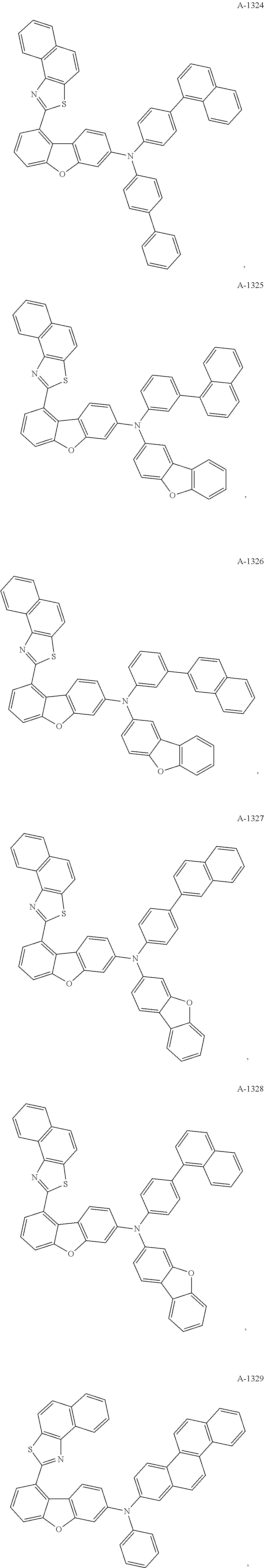 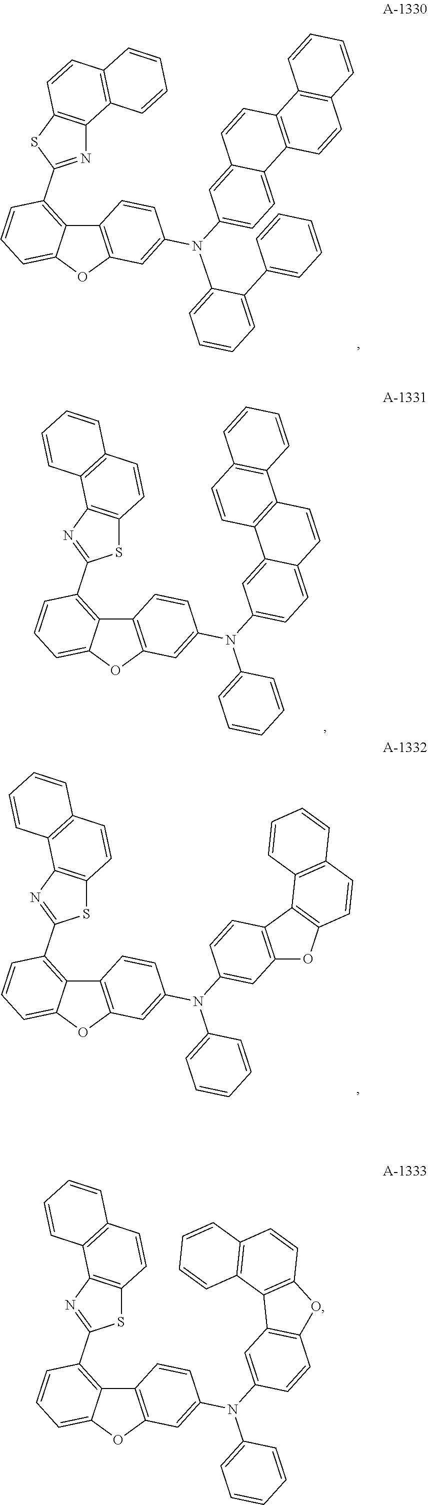 [SMILES: c1ccc(-c2ccccc2N(c2ccc3c(ccc4c5ccccc5ccc34)c2)c2ccc3c(c2)oc2cccc(-c4nc5c(ccc6ccccc65)s4)c23)cc1 ; c1ccc(N(c2ccc3c(c2)oc2cccc(-c4nc5c(ccc6ccccc65)s4)c23)c2ccc3ccc4c5ccccc5ccc4c3c2)cc1 ; c1ccc(N(c2ccc3c(c2)oc2cccc(-c4nc5c(ccc6ccccc65)s4)c23)c2ccc3c(c2)oc2ccc4ccccc4c23)cc1 ; c1ccc(N(c2ccc3c(c2)oc2cccc(-c4nc5c(ccc6ccccc65)s4)c23)c2ccc3oc4ccc5ccccc5c4c3c2)cc1] 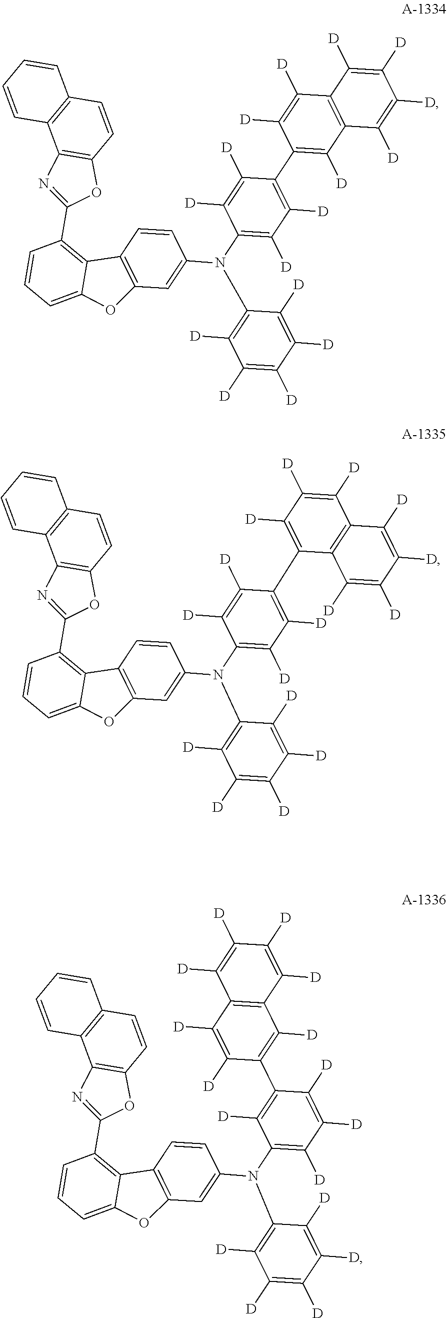 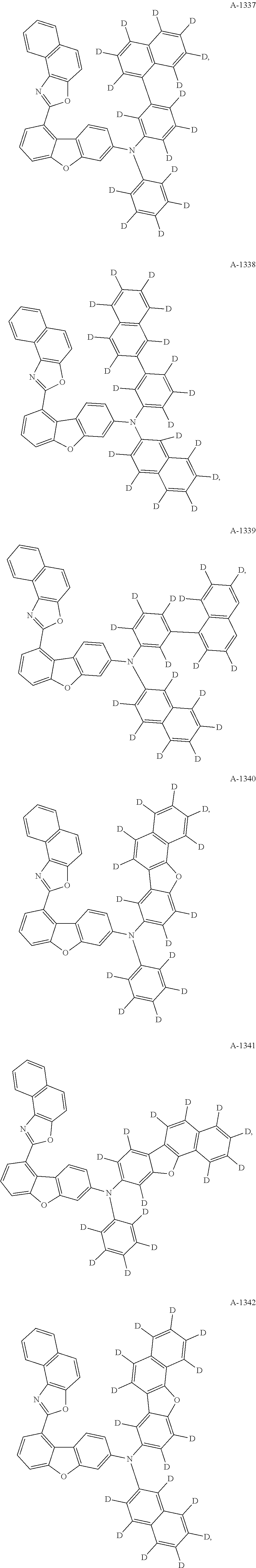 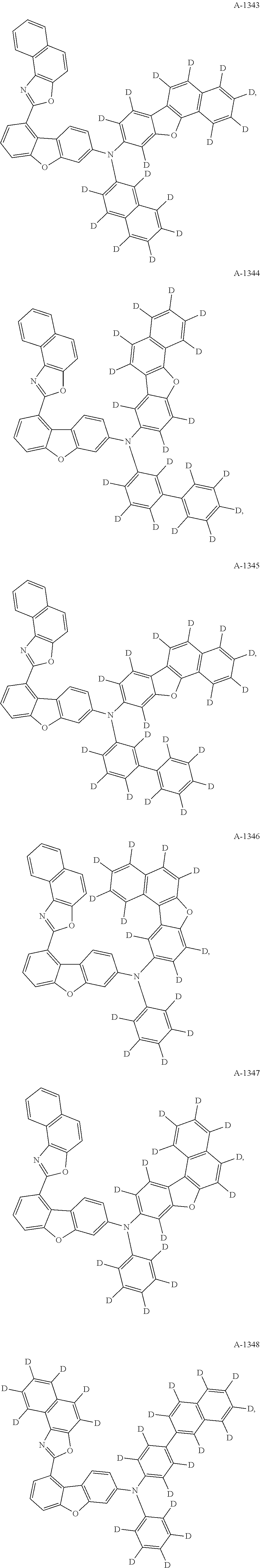 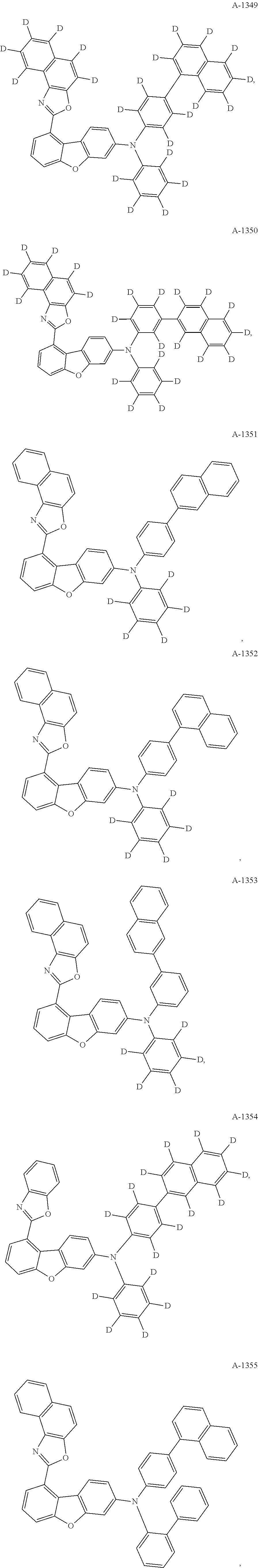 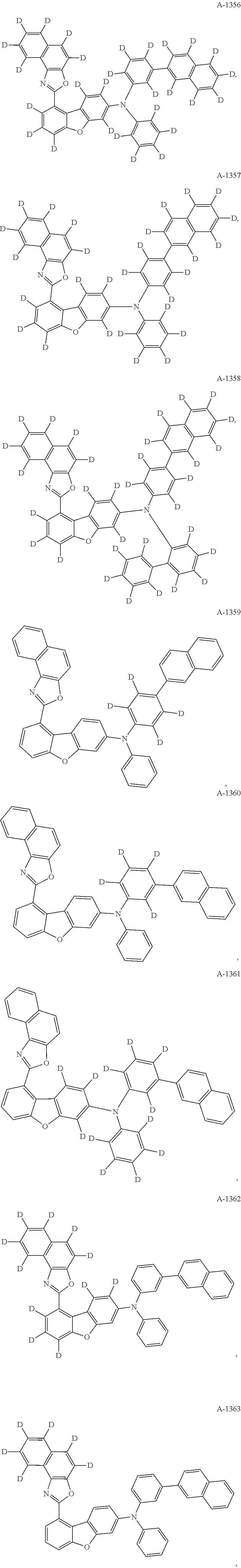 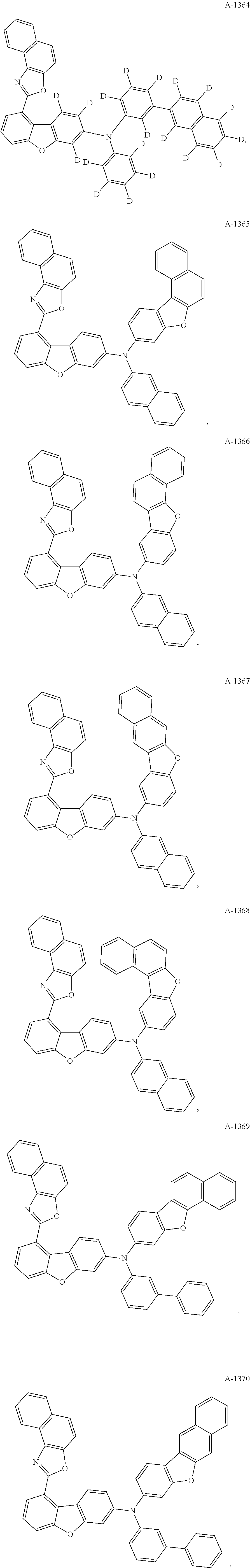 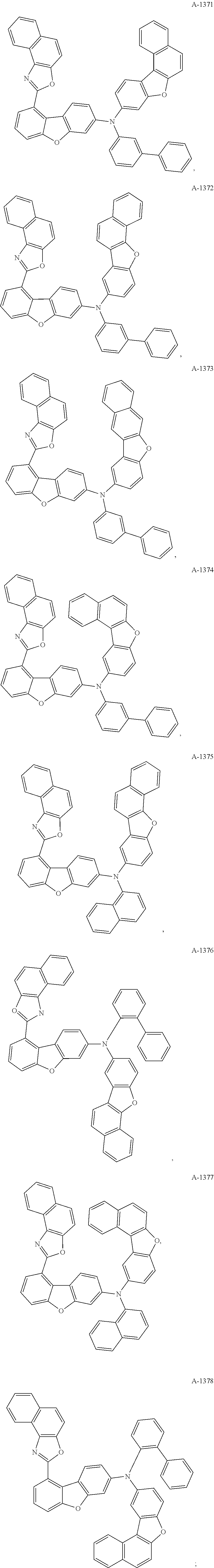
wherein hydrogens in the structures of Compound A-1 to Compound A-1378 can be partially or fully substituted with deuterium.

14. The mixture according to claim 8, wherein the second compound has a structure represented by Formula 2: 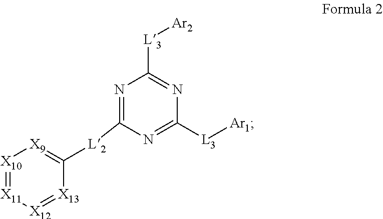
wherein
X₉ to X₁₃ are, at each occurrence identically or differently, selected from CRₓ or N;
L′₂, L₃ and L′₃ are selected from a single bond, substituted or unsubstituted arylene having 6 to 30 carbon atoms, substituted or unsubstituted heteroarylene having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
Ar₁ and Ar₂ are selected from substituted or unsubstituted aryl having 6 to 30 carbon atoms, substituted or unsubstituted heteroaryl having 3 to 30 carbon atoms or a combination thereof;
preferably, at least one of Ar₁ or Ar₂ is selected from the group consisting of: substituted or unsubstituted dibenzofuryl, substituted or unsubstituted dibenzothienyl, substituted or unsubstituted carbazolyl, substituted or unsubstituted silafluorenyl, substituted or unsubstituted fluorenyl, substituted or unsubstituted naphthyl, substituted or unsubstituted chrysenyl and combinations thereof; and
adjacent substituents Rₓ can be optionally joined to form a ring.

15. The mixture according to claim 1, wherein the second compound has a structure represented by Formula 2′: 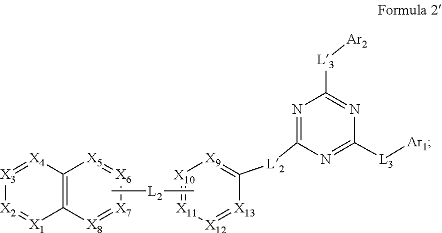
wherein
X₁ to X₄ are, at each occurrence identically or differently, selected from CRₓ or N;
X₅ to X₁₃ are, at each occurrence identically or differently, selected from C, CRₓ or N, at least one of X₅ to X₈ is selected from C and joined to L₂, and at least one of X₉ to X₁₃ is selected from C and joined to L₂;
L₂, L′₂, L₃ and L′₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or a combination thereof;
Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents Rₓ can be optionally joined to form a ring.

16. The mixture according to claim 15, wherein L₂, L′₂, L₃ and L′₃ are, at each occurrence identically or differently, selected from a single bond, substituted or unsubstituted arylene having 6 to 20 carbon atoms, substituted or unsubstituted heteroarylene having 3 to 20 carbon atoms or a combination thereof;
preferably, L₂, L′₂, L₃ and L′₃ are, at each occurrence identically or differently, selected from a single bond, substituted or unsubstituted arylene having 6 to 20 carbon atoms or a combination thereof;
more preferably, L₂, L′₂, L₃ and L′₃ are, at each occurrence identically or differently, selected from a single bond, substituted or unsubstituted phenylene, substituted or unsubstituted naphthylene, substituted or unsubstituted biphenylene, substituted or unsubstituted phenanthrylene, substituted or unsubstituted triphenylenylene, substituted or unsubstituted 9,9-dimethylfluorenylene, substituted or unsubstituted terphenylene, substituted or unsubstituted chrysenylene or a combination thereof.

17. The mixture according to claim 15, wherein X₁ to X₄ are, at each occurrence identically or differently, selected from CRₓ; and X₅ to X₁₃ are, at each occurrence identically or differently, selected from C or CRₓ, X₆ or X₇ is selected from C and joined to L₂, and X₁₁ is selected from C and joined to L₂;
preferably, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms and combinations thereof;
more preferably, Rₓ is, at each occurrence identically or differently, selected from the group consisting of: hydrogen, deuterium, halogen, phenyl, pyridyl, vinyl, adamantyl, methyl, ethyl, isopropyl, cyclopropanyl, naphthyl, biphenyl, phenanthryl, triphenylenyl, t-butyl, trifluoromethyl, 9,9-dimethylfluorenyl, terphenyl, dibenzothienyl, dibenzofuryl, benzothiazolyl, benzoxazolyl, phenanthroxazolyl, phenanthrothiazolyl, chrysenyl and combinations thereof.

18. The mixture according to claim 14, wherein Ar₁ and Ar₂ have, at each occurrence identically or differently, a structure represented by any one or a combination of Formula Ar-1 to Formula Ar-6: 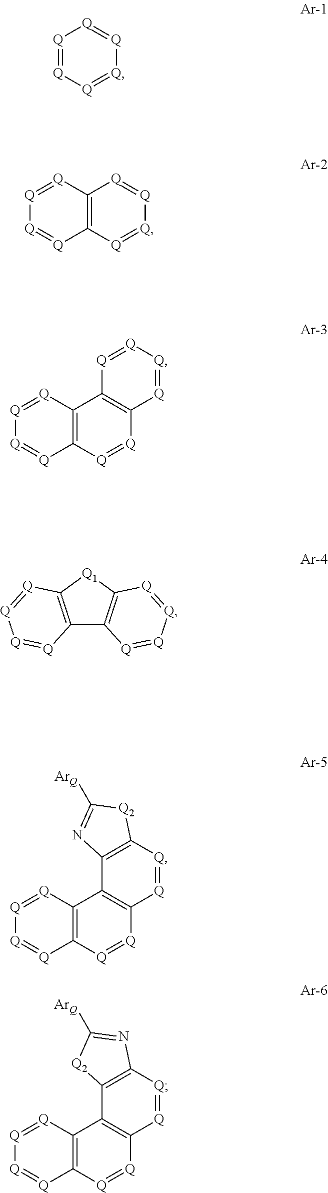
wherein
Ar_{Q} is, at each occurrence identically or differently, selected from substituted or unsubstituted aryl having 6 to 30 carbon atoms, substituted or unsubstituted heteroaryl having 3 to 30 carbon atoms or a combination thereof;
Q is, at each occurrence identically or differently, selected from C, CR_{Q} or N, and at least one Q is selected from C and joined to L₃ or L′₃;
Q₁ is selected from O, S, Se, NR_{Q} or CR_{Q}R_{Q};
Q₂ is selected from O, S or Se;
R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{Q} can be optionally joined to form a ring;
preferably, Ar₁ and Ar₂, have, at each occurrence identically or differently, a structure represented by any one of Formula Ar-1, Formula Ar-2 or Formula Ar-4.

19. The mixture according to claim 18, wherein in Formula Ar-1 to Formula Ar-6, Q is, at each occurrence identically or differently, selected from C or CR_{Q}; Q₁ is selected from O, S or CR_{Q}R_{Q}; and Q₂ is selected from O or S;
preferably, R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms and combinations thereof;
more preferably, R_{Q} is, at each occurrence identically or differently, selected from the group consisting of: hydrogen, deuterium, halogen, phenyl, pyridyl, vinyl, adamantyl, methyl, ethyl, isopropyl, cyclopropanyl, naphthyl, biphenyl, phenanthryl, triphenylenyl, t-butyl, trifluoromethyl, 9,9-dimethylfluorenyl, terphenyl, dibenzothienyl, dibenzofuryl, benzothiazolyl, benzoxazolyl, phenanthroxazolyl, phenanthrothiazolyl, chrysenyl and combinations thereof.

20. The mixture according to claim 1, wherein the second compound is selected from the group consisting of Compound B-1 to Compound B-223, wherein specific structures of Compound B-1 to Compound B-223 are as follows: 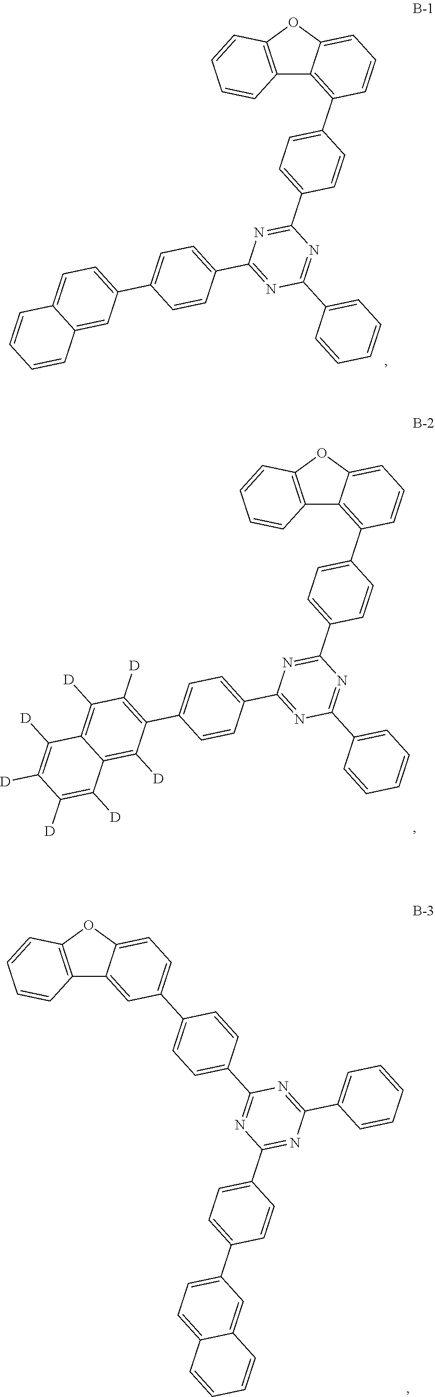 [SMILES: c1ccc(-c2nc(-c3ccc(-c4ccc5ccccc5c4)cc3)nc(-c3ccc(-c4cccc5oc6ccccc6c45)cc3)n2)cc1 ; [2H]c1c([2H])c([2H])c2c([2H])c(-c3ccc(-c4nc(-c5ccccc5)nc(-c5ccc(-c6cccc7oc8ccccc8c67)cc5)n4)cc3)c([2H])c([2H])c2c1[2H] ; c1ccc(-c2nc(-c3ccc(-c4ccc5ccccc5c4)cc3)nc(-c3ccc(-c4ccc5oc6ccccc6c5c4)cc3)n2)cc1] 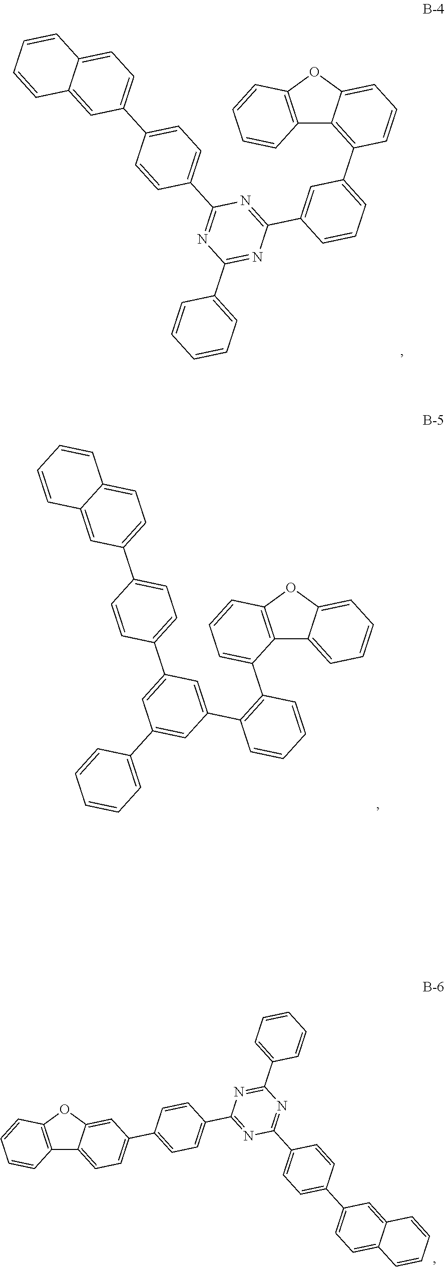 [SMILES: c1ccc(-c2nc(-c3ccc(-c4ccc5ccccc5c4)cc3)nc(-c3cccc(-c4cccc5oc6ccccc6c45)c3)n2)cc1 ; c1ccc(-c2cc(-c3ccc(-c4ccc5ccccc5c4)cc3)cc(-c3ccccc3-c3cccc4oc5ccccc5c34)c2)cc1 ; c1ccc(-c2nc(-c3ccc(-c4ccc5ccccc5c4)cc3)nc(-c3ccc(-c4ccc5c(c4)oc4ccccc45)cc3)n2)cc1] 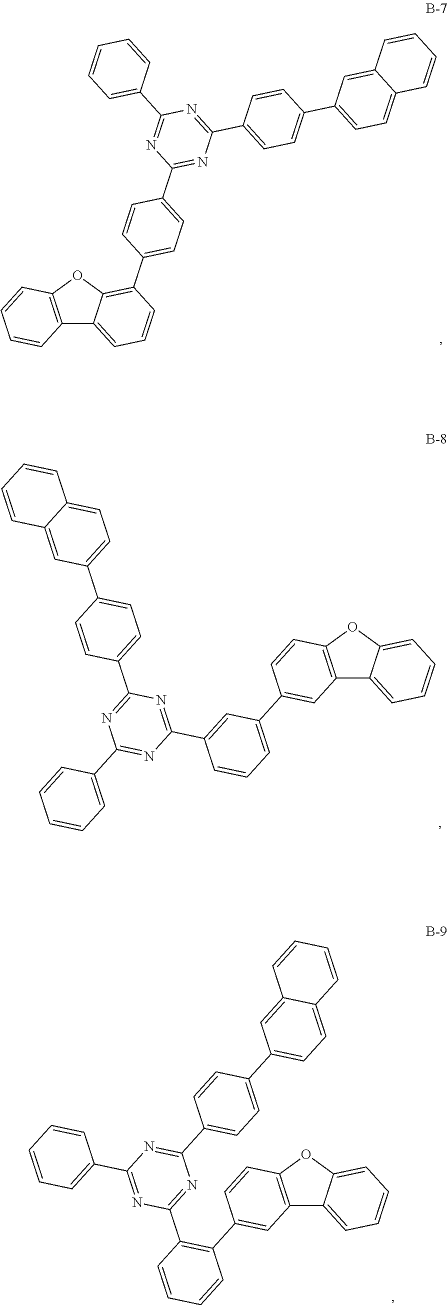 [SMILES: c1ccc(-c2nc(-c3ccc(-c4ccc5ccccc5c4)cc3)nc(-c3ccc(-c4cccc5c4oc4ccccc45)cc3)n2)cc1 ; c1ccc(-c2nc(-c3ccc(-c4ccc5ccccc5c4)cc3)nc(-c3cccc(-c4ccc5oc6ccccc6c5c4)c3)n2)cc1 ; c1ccc(-c2nc(-c3ccc(-c4ccc5ccccc5c4)cc3)nc(-c3ccccc3-c3ccc4oc5ccccc5c4c3)n2)cc1] 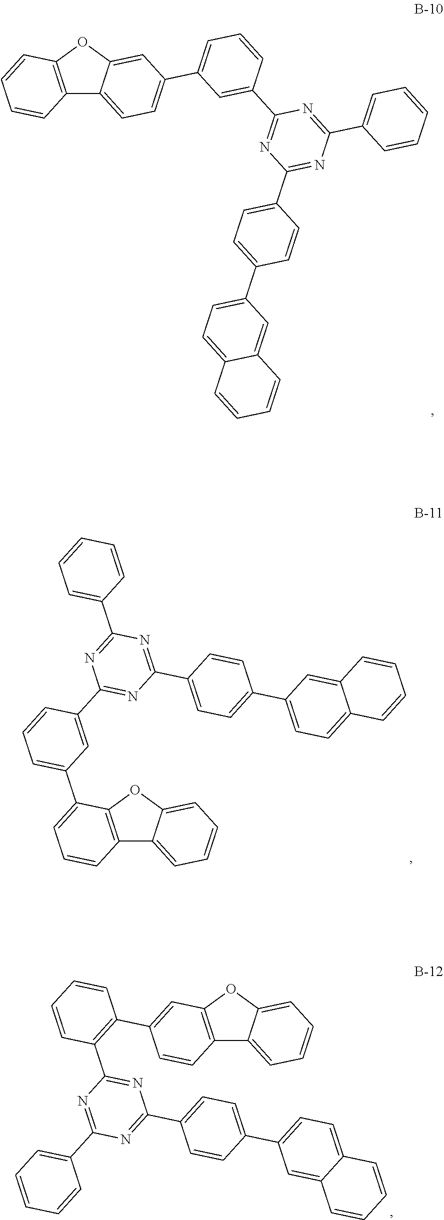 [SMILES: c1ccc(-c2nc(-c3ccc(-c4ccc5ccccc5c4)cc3)nc(-c3cccc(-c4ccc5c(c4)oc4ccccc45)c3)n2)cc1 ; c1ccc(-c2nc(-c3ccc(-c4ccc5ccccc5c4)cc3)nc(-c3cccc(-c4cccc5c4oc4ccccc45)c3)n2)cc1 ; c1ccc(-c2nc(-c3ccc(-c4ccc5ccccc5c4)cc3)nc(-c3ccccc3-c3ccc4c(c3)oc3ccccc34)n2)cc1] 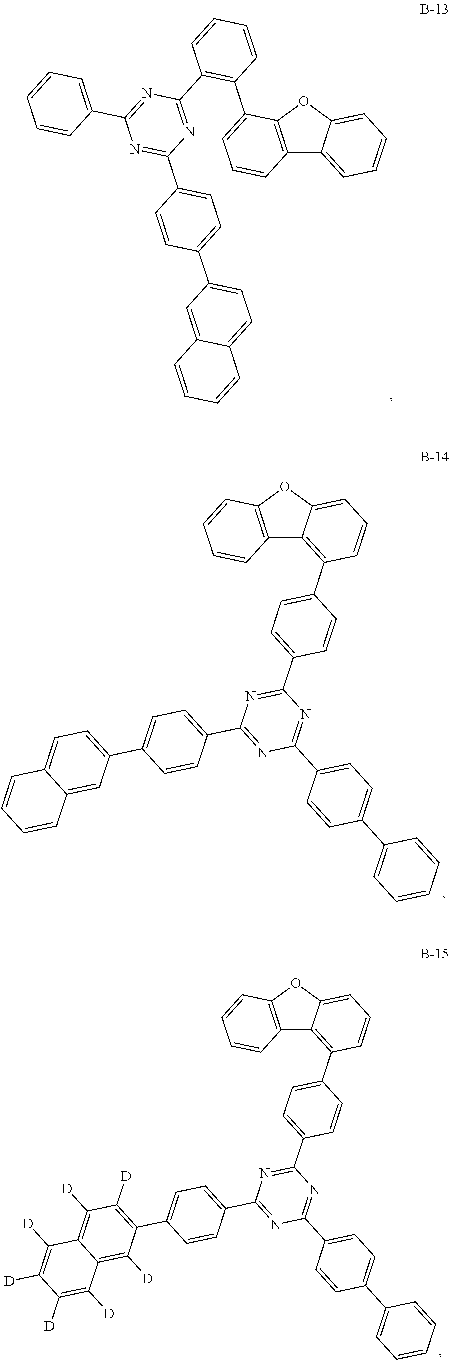 [SMILES: c1ccc(-c2nc(-c3ccc(-c4ccc5ccccc5c4)cc3)nc(-c3ccccc3-c3cccc4c3oc3ccccc34)n2)cc1 ; c1ccc(-c2ccc(-c3nc(-c4ccc(-c5ccc6ccccc6c5)cc4)nc(-c4ccc(-c5cccc6oc7ccccc7c56)cc4)n3)cc2)cc1 ; [2H]c1c([2H])c([2H])c2c([2H])c(-c3ccc(-c4nc(-c5ccc(-c6ccccc6)cc5)nc(-c5ccc(-c6cccc7oc8ccccc8c67)cc5)n4)cc3)c([2H])c([2H])c2c1[2H]] 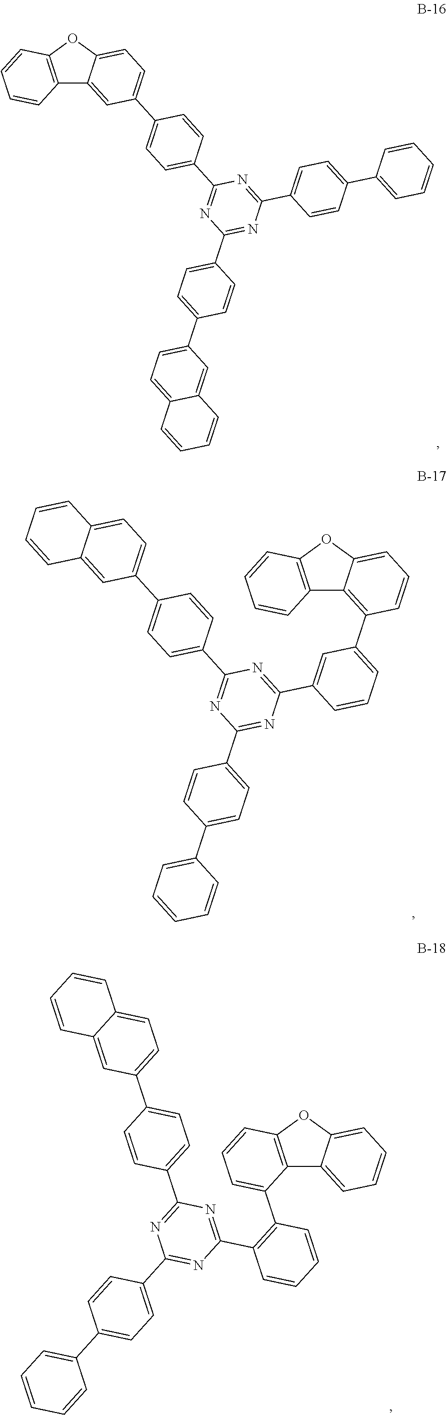 [SMILES: c1ccc(-c2ccc(-c3nc(-c4ccc(-c5ccc6ccccc6c5)cc4)nc(-c4ccc(-c5ccc6oc7ccccc7c6c5)cc4)n3)cc2)cc1 ; c1ccc(-c2ccc(-c3nc(-c4ccc(-c5ccc6ccccc6c5)cc4)nc(-c4cccc(-c5cccc6oc7ccccc7c56)c4)n3)cc2)cc1 ; c1ccc(-c2ccc(-c3nc(-c4ccc(-c5ccc6ccccc6c5)cc4)nc(-c4ccccc4-c4cccc5oc6ccccc6c45)n3)cc2)cc1] 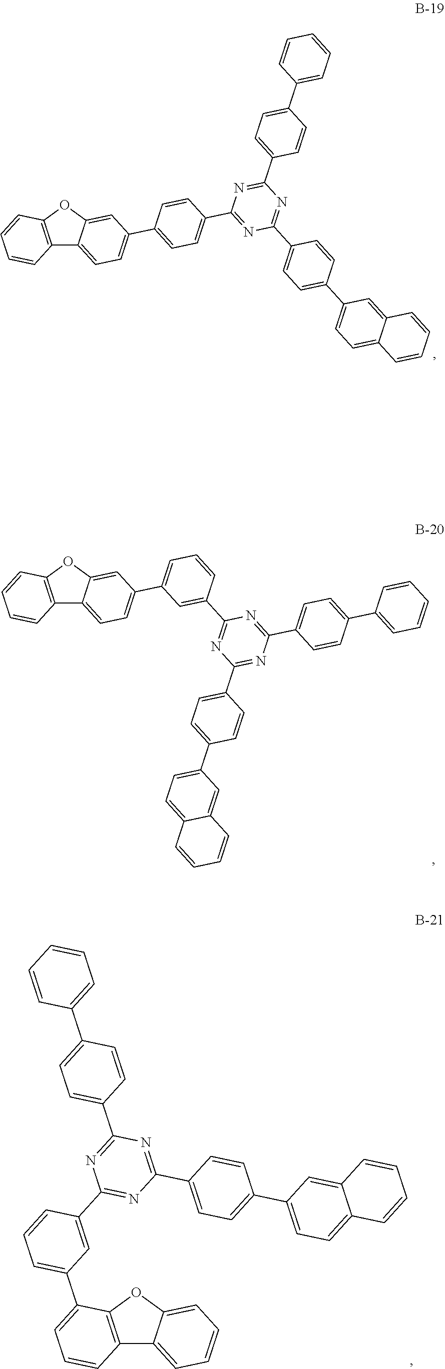 [SMILES: c1ccc(-c2ccc(-c3nc(-c4ccc(-c5ccc6ccccc6c5)cc4)nc(-c4ccc(-c5ccc6c(c5)oc5ccccc56)cc4)n3)cc2)cc1 ; c1ccc(-c2ccc(-c3nc(-c4ccc(-c5ccc6ccccc6c5)cc4)nc(-c4cccc(-c5ccc6c(c5)oc5ccccc56)c4)n3)cc2)cc1 ; c1ccc(-c2ccc(-c3nc(-c4ccc(-c5ccc6ccccc6c5)cc4)nc(-c4cccc(-c5cccc6c5oc5ccccc56)c4)n3)cc2)cc1] 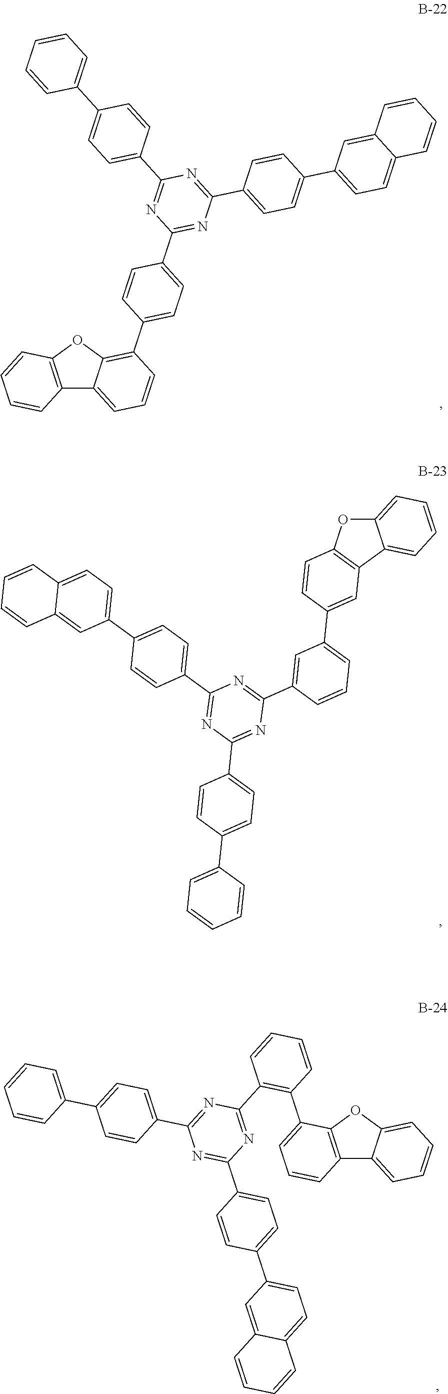 [SMILES: c1ccc(-c2ccc(-c3nc(-c4ccc(-c5ccc6ccccc6c5)cc4)nc(-c4ccc(-c5cccc6c5oc5ccccc56)cc4)n3)cc2)cc1 ; c1ccc(-c2ccc(-c3nc(-c4ccc(-c5ccc6ccccc6c5)cc4)nc(-c4cccc(-c5ccc6oc7ccccc7c6c5)c4)n3)cc2)cc1 ; c1ccc(-c2ccc(-c3nc(-c4ccc(-c5ccc6ccccc6c5)cc4)nc(-c4ccccc4-c4cccc5c4oc4ccccc45)n3)cc2)cc1] 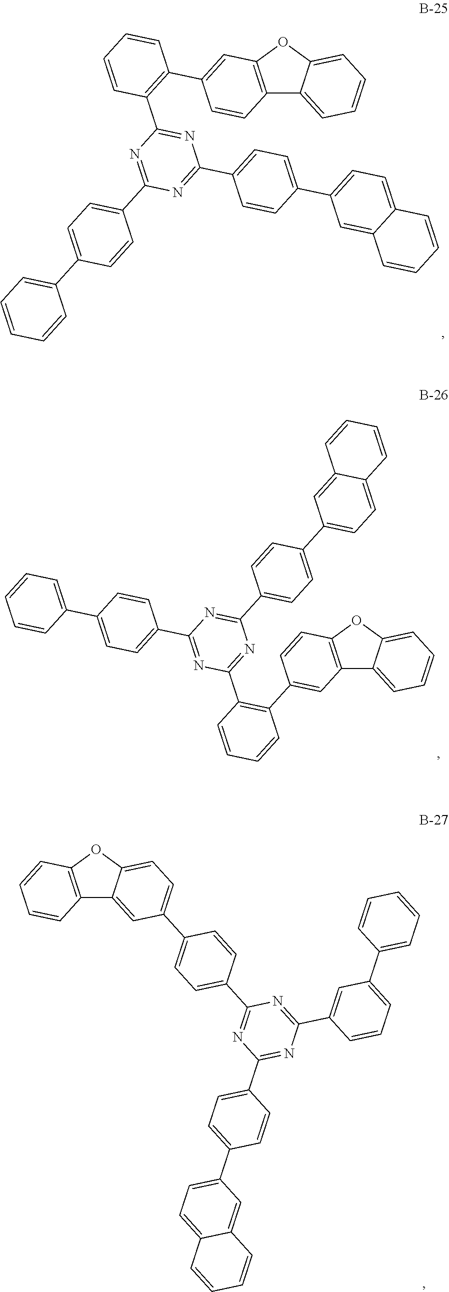 [SMILES: c1ccc(-c2ccc(-c3nc(-c4ccc(-c5ccc6ccccc6c5)cc4)nc(-c4ccccc4-c4ccc5c(c4)oc4ccccc45)n3)cc2)cc1 ; c1ccc(-c2ccc(-c3nc(-c4ccc(-c5ccc6ccccc6c5)cc4)nc(-c4ccccc4-c4ccc5oc6ccccc6c5c4)n3)cc2)cc1 ; c1ccc(-c2cccc(-c3nc(-c4ccc(-c5ccc6ccccc6c5)cc4)nc(-c4ccc(-c5ccc6oc7ccccc7c6c5)cc4)n3)c2)cc1] 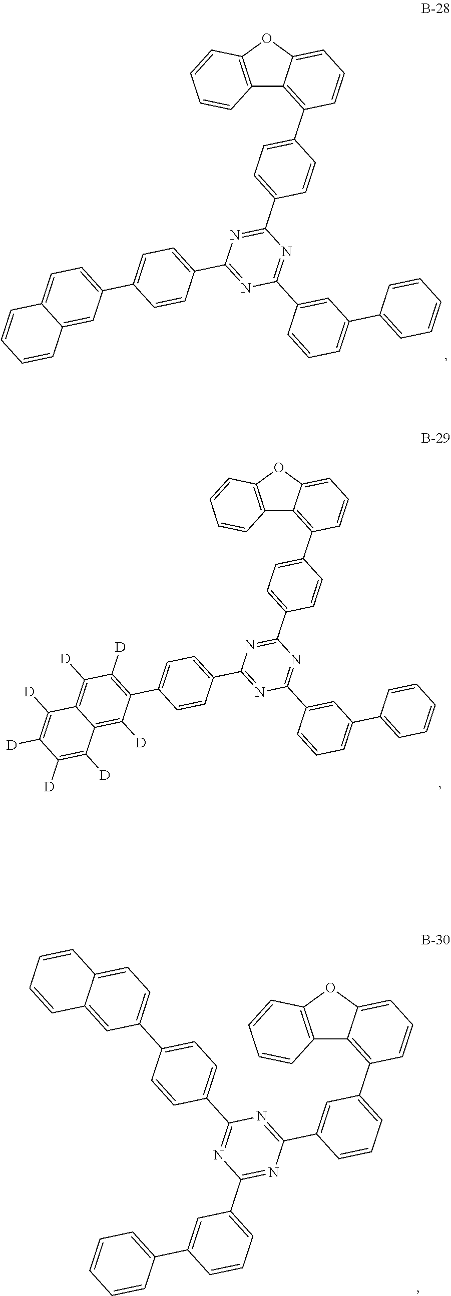 [SMILES: c1ccc(-c2cccc(-c3nc(-c4ccc(-c5ccc6ccccc6c5)cc4)nc(-c4ccc(-c5cccc6oc7ccccc7c56)cc4)n3)c2)cc1 ; [2H]c1c([2H])c([2H])c2c([2H])c(-c3ccc(-c4nc(-c5ccc(-c6cccc7oc8ccccc8c67)cc5)nc(-c5cccc(-c6ccccc6)c5)n4)cc3)c([2H])c([2H])c2c1[2H] ; c1ccc(-c2cccc(-c3nc(-c4ccc(-c5ccc6ccccc6c5)cc4)nc(-c4cccc(-c5cccc6oc7ccccc7c56)c4)n3)c2)cc1] 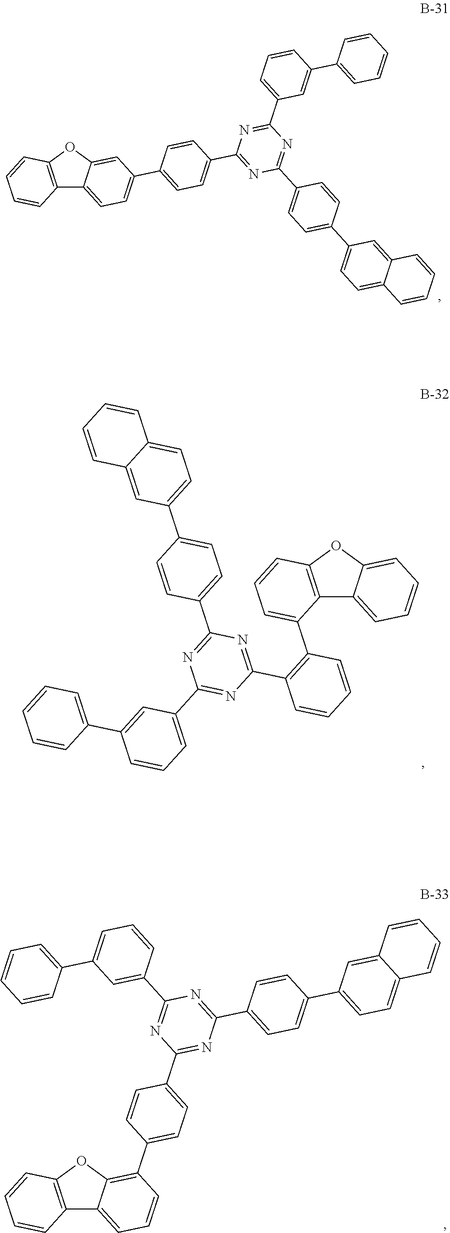 [SMILES: c1ccc(-c2cccc(-c3nc(-c4ccc(-c5ccc6ccccc6c5)cc4)nc(-c4ccc(-c5ccc6c(c5)oc5ccccc56)cc4)n3)c2)cc1 ; c1ccc(-c2cccc(-c3nc(-c4ccc(-c5ccc6ccccc6c5)cc4)nc(-c4ccccc4-c4cccc5oc6ccccc6c45)n3)c2)cc1 ; c1ccc(-c2cccc(-c3nc(-c4ccc(-c5ccc6ccccc6c5)cc4)nc(-c4ccc(-c5cccc6c5oc5ccccc56)cc4)n3)c2)cc1] 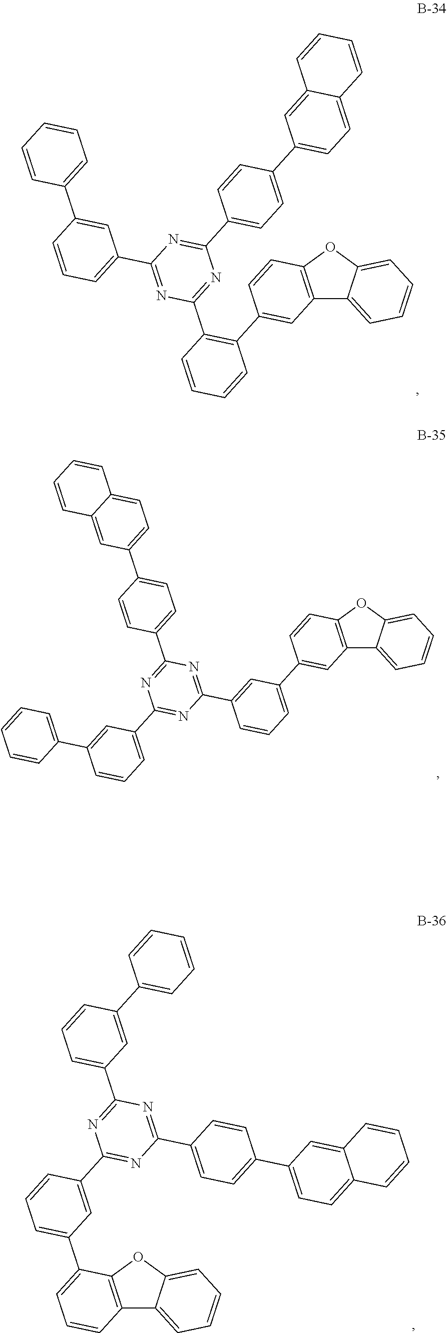 [SMILES: c1ccc(-c2cccc(-c3nc(-c4ccc(-c5ccc6ccccc6c5)cc4)nc(-c4ccccc4-c4ccc5oc6ccccc6c5c4)n3)c2)cc1 ; c1ccc(-c2cccc(-c3nc(-c4ccc(-c5ccc6ccccc6c5)cc4)nc(-c4cccc(-c5ccc6oc7ccccc7c6c5)c4)n3)c2)cc1 ; c1ccc(-c2cccc(-c3nc(-c4ccc(-c5ccc6ccccc6c5)cc4)nc(-c4cccc(-c5cccc6c5oc5ccccc56)c4)n3)c2)cc1] 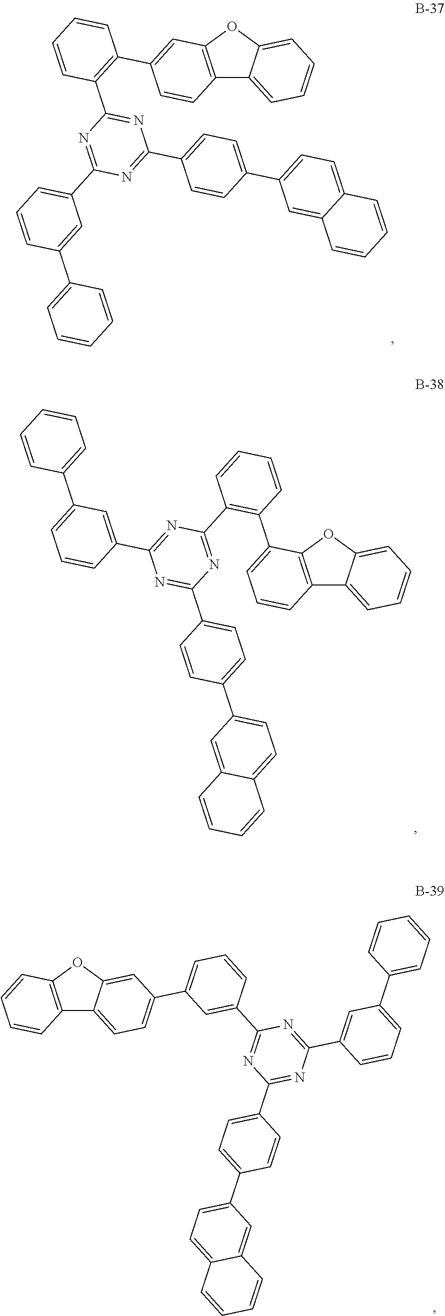 [SMILES: c1ccc(-c2cccc(-c3nc(-c4ccc(-c5ccc6ccccc6c5)cc4)nc(-c4ccccc4-c4ccc5c(c4)oc4ccccc45)n3)c2)cc1 ; c1ccc(-c2cccc(-c3nc(-c4ccc(-c5ccc6ccccc6c5)cc4)nc(-c4ccccc4-c4cccc5c4oc4ccccc45)n3)c2)cc1 ; c1ccc(-c2cccc(-c3nc(-c4ccc(-c5ccc6ccccc6c5)cc4)nc(-c4cccc(-c5ccc6c(c5)oc5ccccc56)c4)n3)c2)cc1] 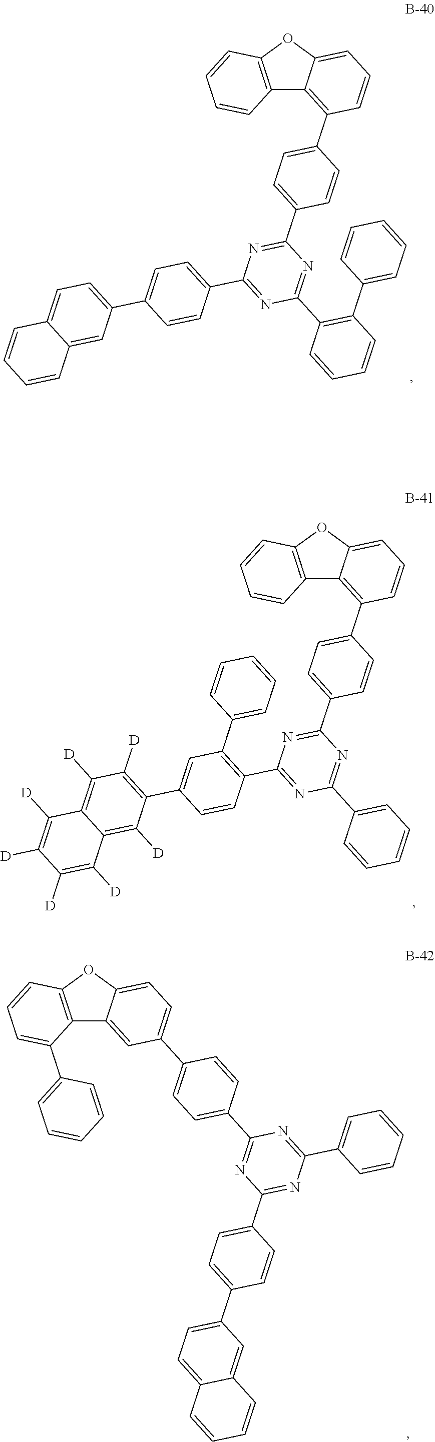 [SMILES: c1ccc(-c2ccccc2-c2nc(-c3ccc(-c4ccc5ccccc5c4)cc3)nc(-c3ccc(-c4cccc5oc6ccccc6c45)cc3)n2)cc1 ; [2H]c1c([2H])c([2H])c2c([2H])c(-c3ccc(-c4nc(-c5ccccc5)nc(-c5ccc(-c6cccc7oc8ccccc8c67)cc5)n4)c(-c4ccccc4)c3)c([2H])c([2H])c2c1[2H] ; c1ccc(-c2nc(-c3ccc(-c4ccc5ccccc5c4)cc3)nc(-c3ccc(-c4ccc5oc6cccc(-c7ccccc7)c6c5c4)cc3)n2)cc1] 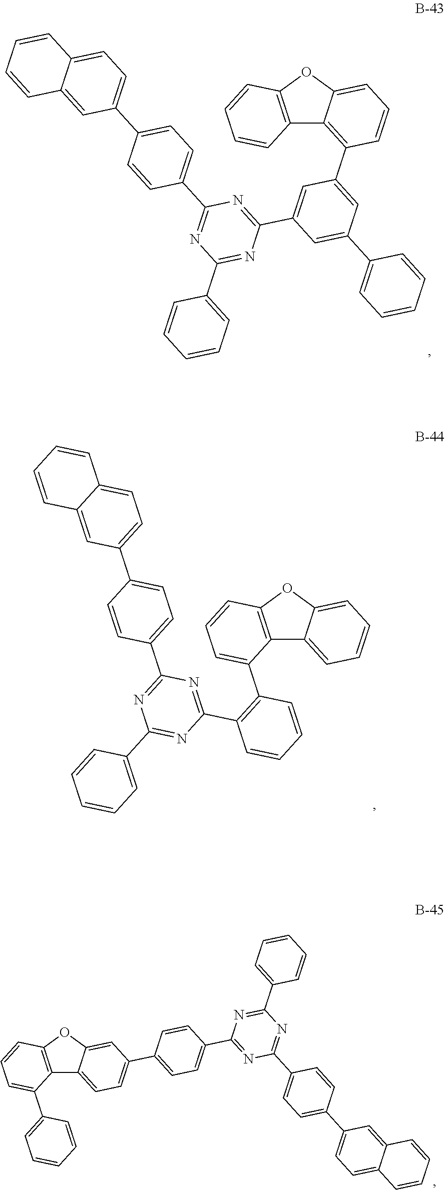 [SMILES: c1ccc(-c2cc(-c3nc(-c4ccccc4)nc(-c4ccc(-c5ccc6ccccc6c5)cc4)n3)cc(-c3cccc4oc5ccccc5c34)c2)cc1 ; c1ccc(-c2nc(-c3ccc(-c4ccc5ccccc5c4)cc3)nc(-c3ccccc3-c3cccc4oc5ccccc5c34)n2)cc1 ; c1ccc(-c2nc(-c3ccc(-c4ccc5ccccc5c4)cc3)nc(-c3ccc(-c4ccc5c(c4)oc4cccc(-c6ccccc6)c45)cc3)n2)cc1] 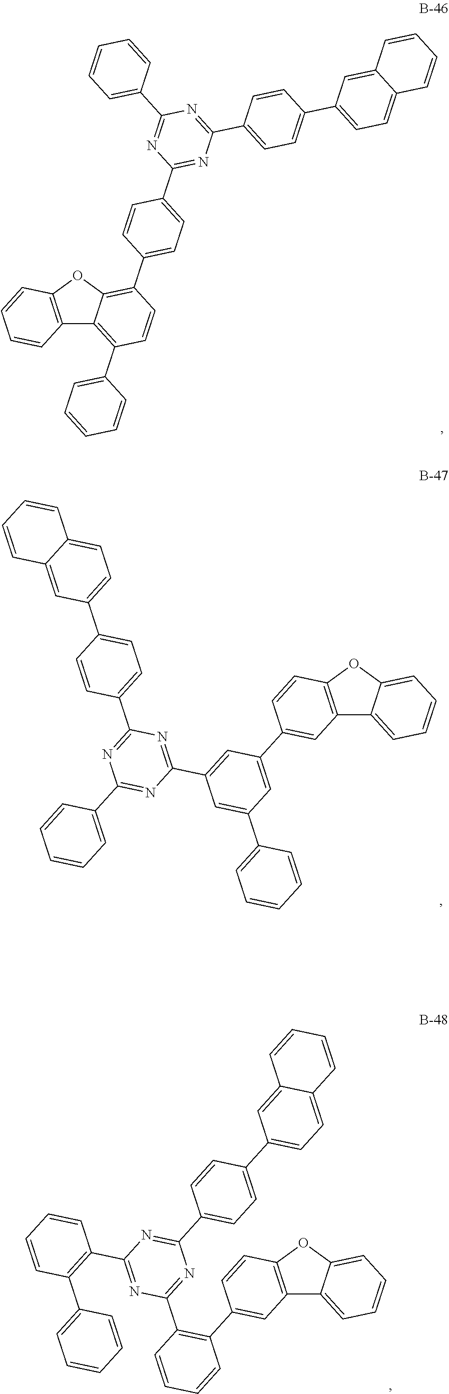 [SMILES: c1ccc(-c2nc(-c3ccc(-c4ccc5ccccc5c4)cc3)nc(-c3ccc(-c4ccc(-c5ccccc5)c5c4oc4ccccc45)cc3)n2)cc1 ; c1ccc(-c2cc(-c3ccc4oc5ccccc5c4c3)cc(-c3nc(-c4ccccc4)nc(-c4ccc(-c5ccc6ccccc6c5)cc4)n3)c2)cc1 ; c1ccc(-c2ccccc2-c2nc(-c3ccc(-c4ccc5ccccc5c4)cc3)nc(-c3ccccc3-c3ccc4oc5ccccc5c4c3)n2)cc1] 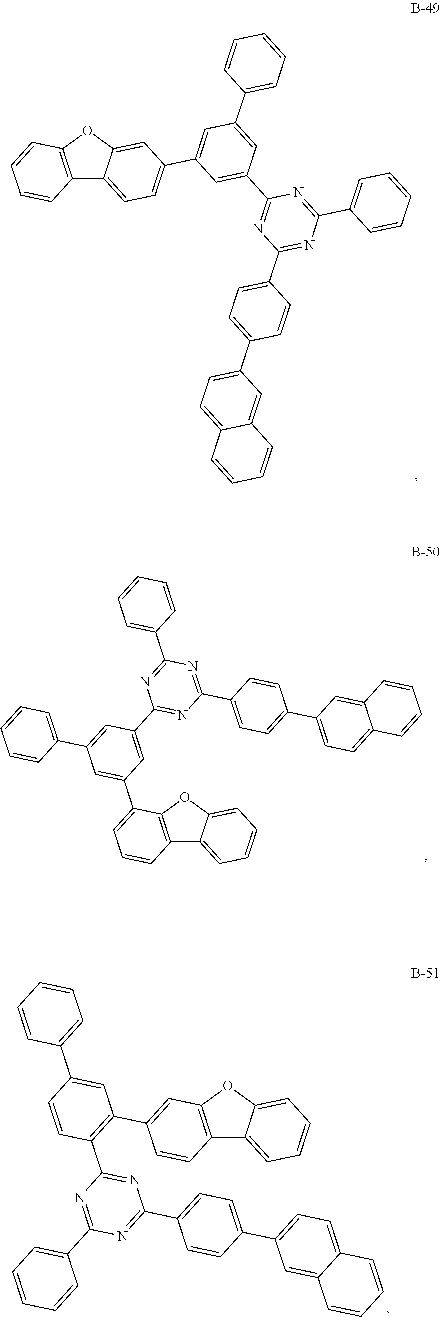 [SMILES: c1ccc(-c2cc(-c3ccc4c(c3)oc3ccccc34)cc(-c3nc(-c4ccccc4)nc(-c4ccc(-c5ccc6ccccc6c5)cc4)n3)c2)cc1 ; c1ccc(-c2cc(-c3nc(-c4ccccc4)nc(-c4ccc(-c5ccc6ccccc6c5)cc4)n3)cc(-c3cccc4c3oc3ccccc34)c2)cc1 ; c1ccc(-c2ccc(-c3nc(-c4ccccc4)nc(-c4ccc(-c5ccc6ccccc6c5)cc4)n3)c(-c3ccc4c(c3)oc3ccccc34)c2)cc1] 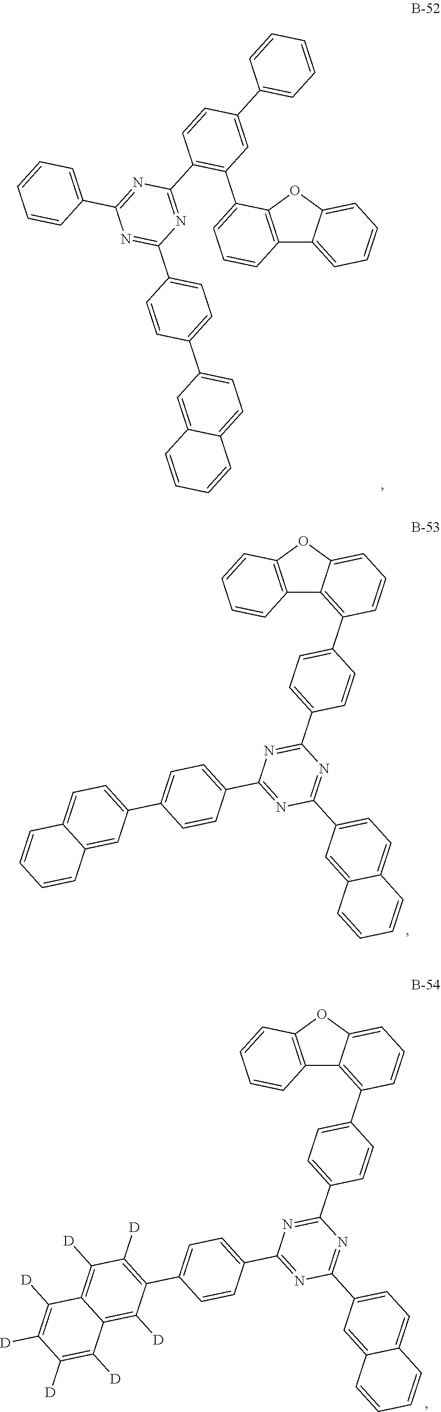 [SMILES: c1ccc(-c2ccc(-c3nc(-c4ccccc4)nc(-c4ccc(-c5ccc6ccccc6c5)cc4)n3)c(-c3cccc4c3oc3ccccc34)c2)cc1 ; c1ccc2cc(-c3ccc(-c4nc(-c5ccc(-c6cccc7oc8ccccc8c67)cc5)nc(-c5ccc6ccccc6c5)n4)cc3)ccc2c1 ; [2H]c1c([2H])c([2H])c2c([2H])c(-c3ccc(-c4nc(-c5ccc(-c6cccc7oc8ccccc8c67)cc5)nc(-c5ccc6ccccc6c5)n4)cc3)c([2H])c([2H])c2c1[2H]] 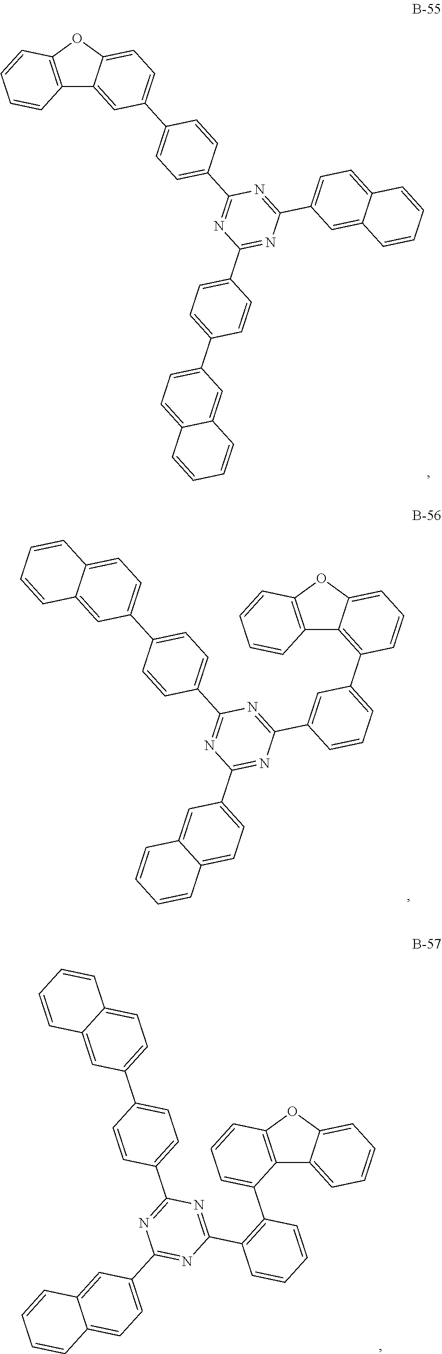 [SMILES: c1ccc2cc(-c3ccc(-c4nc(-c5ccc(-c6ccc7oc8ccccc8c7c6)cc5)nc(-c5ccc6ccccc6c5)n4)cc3)ccc2c1 ; c1cc(-c2nc(-c3ccc(-c4ccc5ccccc5c4)cc3)nc(-c3ccc4ccccc4c3)n2)cc(-c2cccc3oc4ccccc4c23)c1 ; c1ccc(-c2cccc3oc4ccccc4c23)c(-c2nc(-c3ccc(-c4ccc5ccccc5c4)cc3)nc(-c3ccc4ccccc4c3)n2)c1] 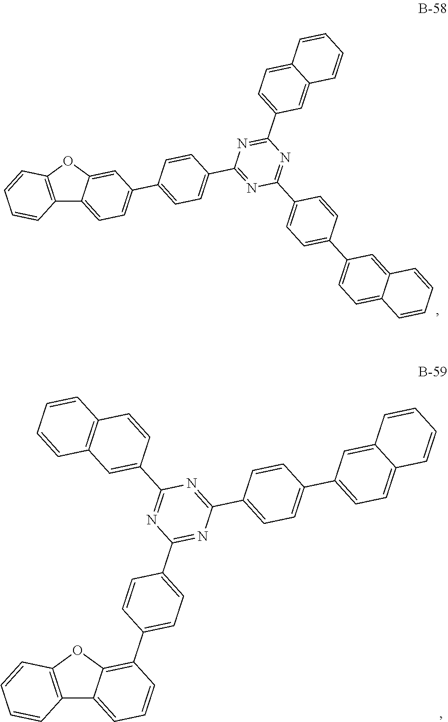 [SMILES: c1ccc2cc(-c3ccc(-c4nc(-c5ccc(-c6ccc7c(c6)oc6ccccc67)cc5)nc(-c5ccc6ccccc6c5)n4)cc3)ccc2c1 ; c1ccc2cc(-c3ccc(-c4nc(-c5ccc(-c6cccc7c6oc6ccccc67)cc5)nc(-c5ccc6ccccc6c5)n4)cc3)ccc2c1] 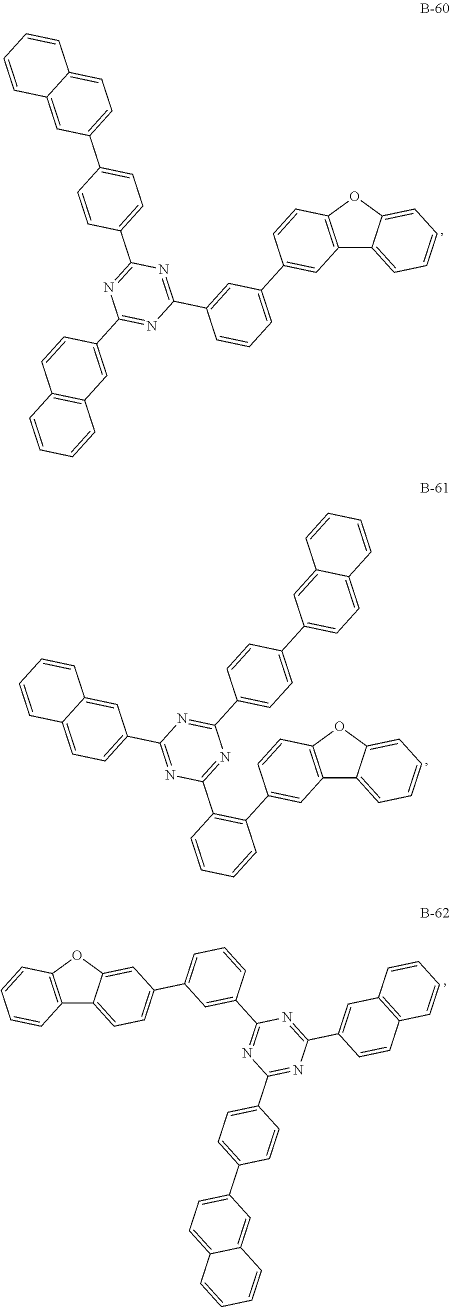 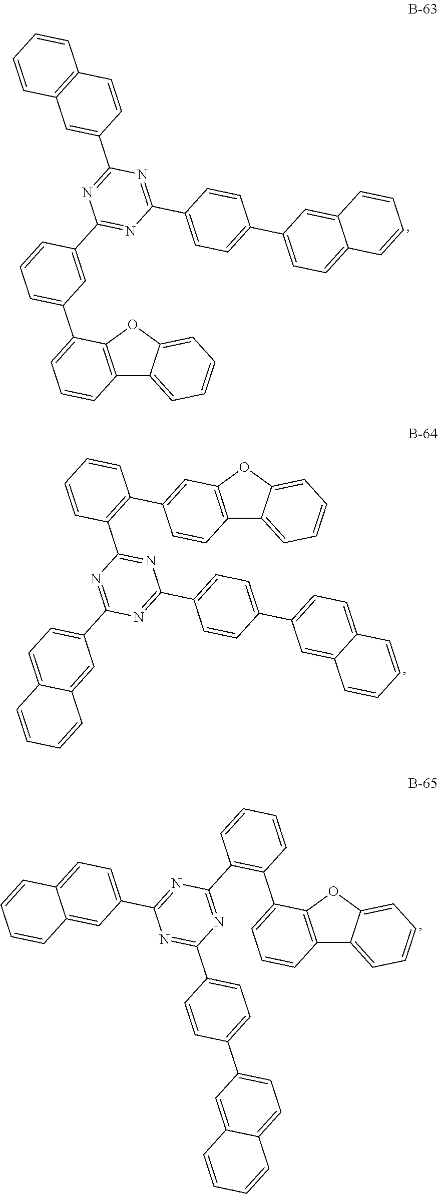 [SMILES: c1cc(-c2nc(-c3ccc(-c4ccc5ccccc5c4)cc3)nc(-c3ccc4ccccc4c3)n2)cc(-c2cccc3c2oc2ccccc23)c1 ; c1ccc(-c2nc(-c3ccc(-c4ccc5ccccc5c4)cc3)nc(-c3ccc4ccccc4c3)n2)c(-c2ccc3c(c2)oc2ccccc23)c1 ; c1ccc(-c2cccc3c2oc2ccccc23)c(-c2nc(-c3ccc(-c4ccc5ccccc5c4)cc3)nc(-c3ccc4ccccc4c3)n2)c1] 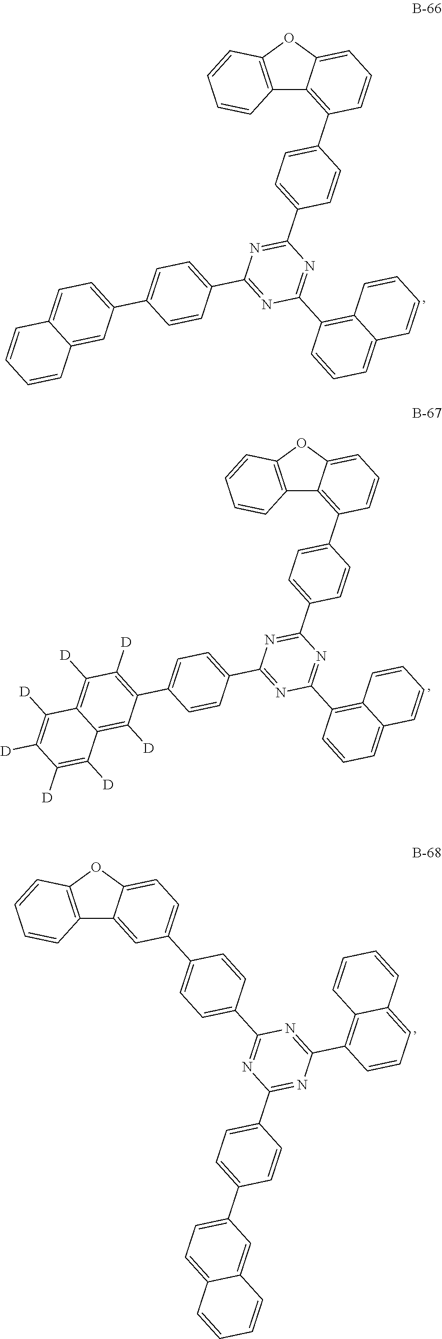 [SMILES: c1ccc2cc(-c3ccc(-c4nc(-c5ccc(-c6cccc7oc8ccccc8c67)cc5)nc(-c5cccc6ccccc56)n4)cc3)ccc2c1 ; [2H]c1c([2H])c([2H])c2c([2H])c(-c3ccc(-c4nc(-c5ccc(-c6cccc7oc8ccccc8c67)cc5)nc(-c5cccc6ccccc56)n4)cc3)c([2H])c([2H])c2c1[2H] ; c1ccc2cc(-c3ccc(-c4nc(-c5ccc(-c6ccc7oc8ccccc8c7c6)cc5)nc(-c5cccc6ccccc56)n4)cc3)ccc2c1] 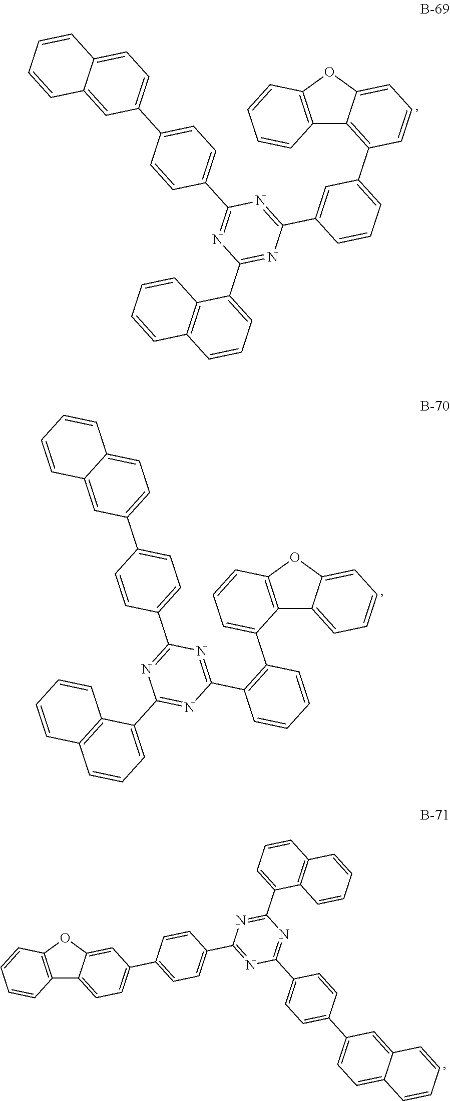 [SMILES: c1cc(-c2nc(-c3ccc(-c4ccc5ccccc5c4)cc3)nc(-c3cccc4ccccc34)n2)cc(-c2cccc3oc4ccccc4c23)c1 ; c1ccc(-c2cccc3oc4ccccc4c23)c(-c2nc(-c3ccc(-c4ccc5ccccc5c4)cc3)nc(-c3cccc4ccccc34)n2)c1 ; c1ccc2cc(-c3ccc(-c4nc(-c5ccc(-c6ccc7c(c6)oc6ccccc67)cc5)nc(-c5cccc6ccccc56)n4)cc3)ccc2c1] 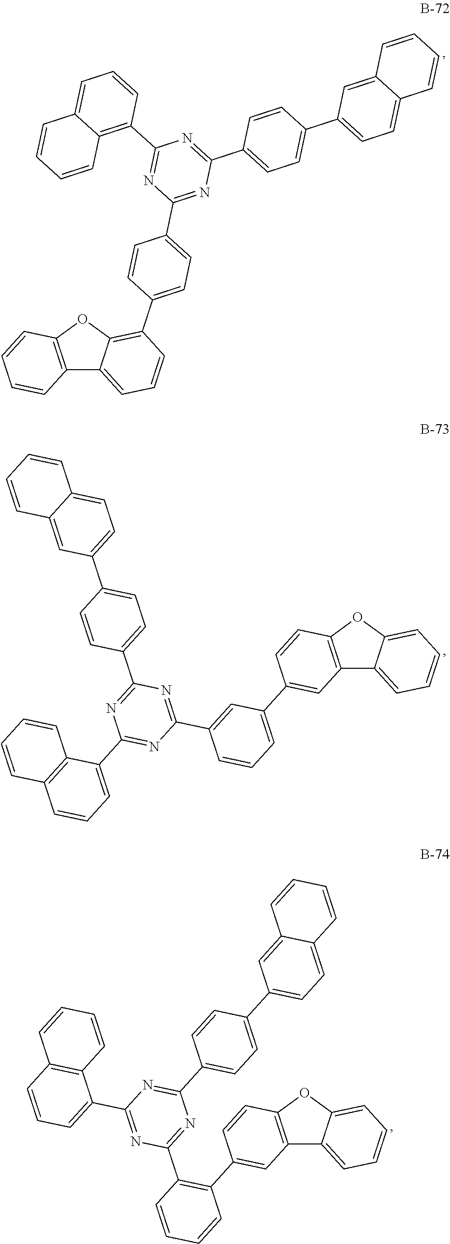 [SMILES: c1ccc2cc(-c3ccc(-c4nc(-c5ccc(-c6cccc7c6oc6ccccc67)cc5)nc(-c5cccc6ccccc56)n4)cc3)ccc2c1 ; c1cc(-c2ccc3oc4ccccc4c3c2)cc(-c2nc(-c3ccc(-c4ccc5ccccc5c4)cc3)nc(-c3cccc4ccccc34)n2)c1 ; c1ccc(-c2nc(-c3ccc(-c4ccc5ccccc5c4)cc3)nc(-c3cccc4ccccc34)n2)c(-c2ccc3oc4ccccc4c3c2)c1] 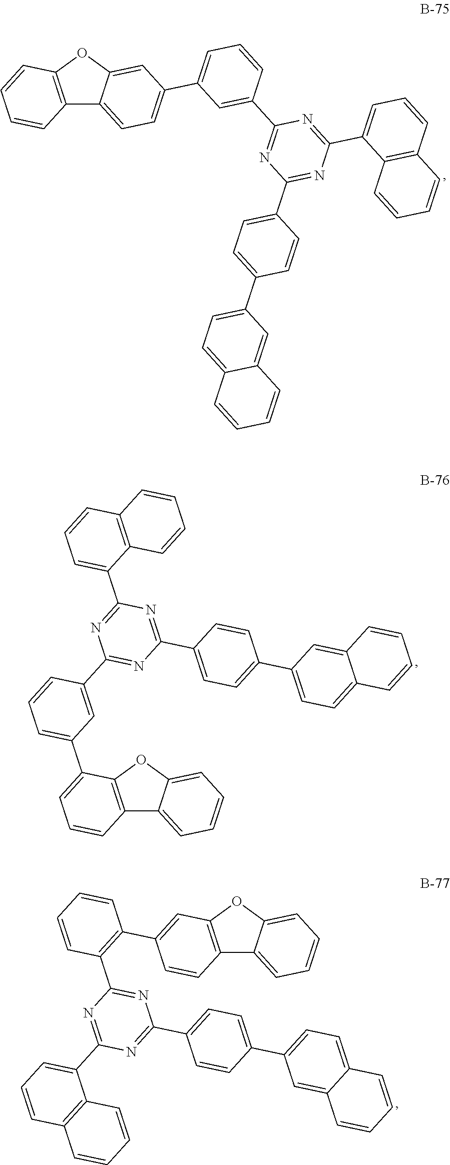 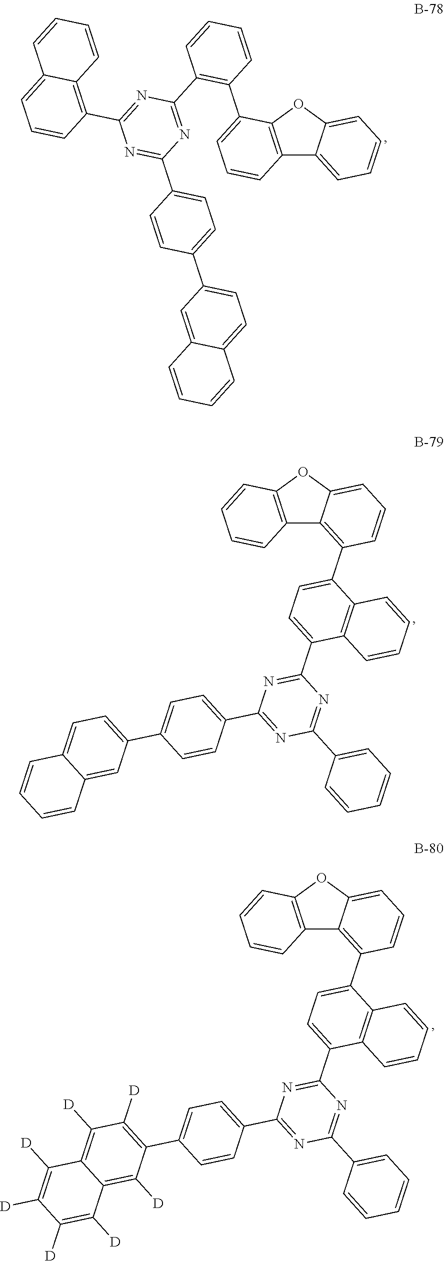 [SMILES: c1ccc(-c2cccc3c2oc2ccccc23)c(-c2nc(-c3ccc(-c4ccc5ccccc5c4)cc3)nc(-c3cccc4ccccc34)n2)c1 ; c1ccc(-c2nc(-c3ccc(-c4ccc5ccccc5c4)cc3)nc(-c3ccc(-c4cccc5oc6ccccc6c45)c4ccccc34)n2)cc1 ; [2H]c1c([2H])c([2H])c2c([2H])c(-c3ccc(-c4nc(-c5ccccc5)nc(-c5ccc(-c6cccc7oc8ccccc8c67)c6ccccc56)n4)cc3)c([2H])c([2H])c2c1[2H]] 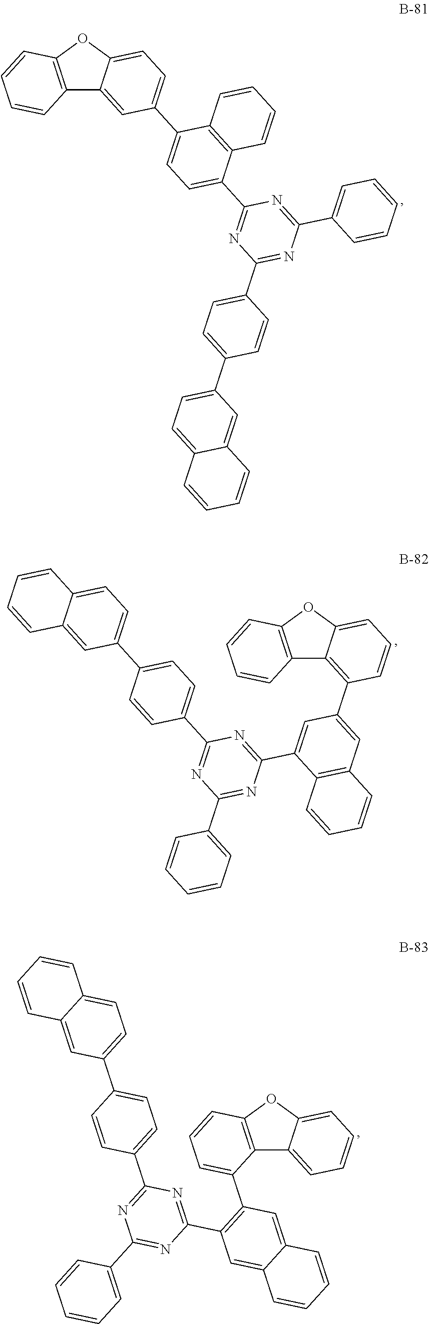 [SMILES: c1ccc(-c2nc(-c3ccc(-c4ccc5ccccc5c4)cc3)nc(-c3ccc(-c4ccc5oc6ccccc6c5c4)c4ccccc34)n2)cc1 ; c1ccc(-c2nc(-c3ccc(-c4ccc5ccccc5c4)cc3)nc(-c3cc(-c4cccc5oc6ccccc6c45)cc4ccccc34)n2)cc1 ; c1ccc(-c2nc(-c3ccc(-c4ccc5ccccc5c4)cc3)nc(-c3cc4ccccc4cc3-c3cccc4oc5ccccc5c34)n2)cc1] 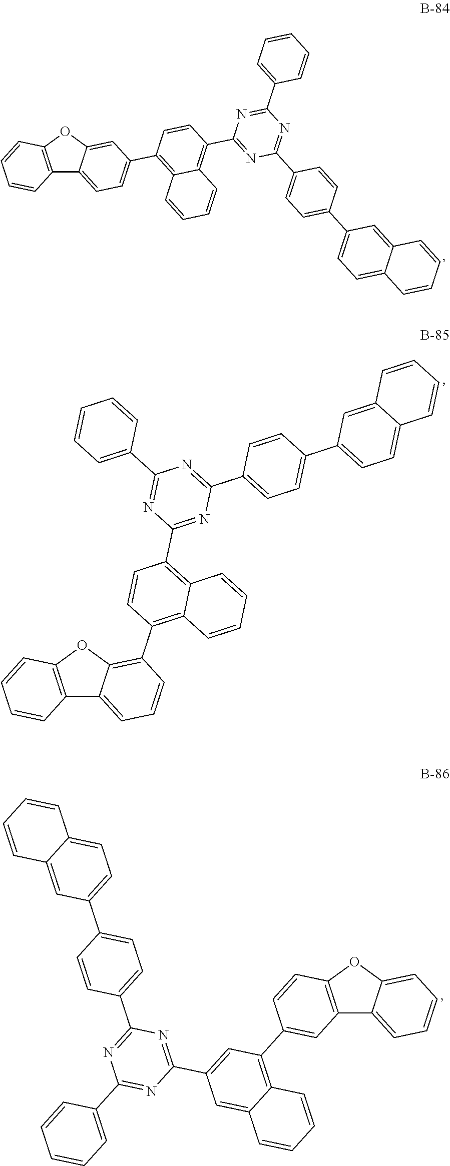 [SMILES: c1ccc(-c2nc(-c3ccc(-c4ccc5ccccc5c4)cc3)nc(-c3ccc(-c4ccc5c(c4)oc4ccccc45)c4ccccc34)n2)cc1 ; c1ccc(-c2nc(-c3ccc(-c4ccc5ccccc5c4)cc3)nc(-c3ccc(-c4cccc5c4oc4ccccc45)c4ccccc34)n2)cc1 ; c1ccc(-c2nc(-c3ccc(-c4ccc5ccccc5c4)cc3)nc(-c3cc(-c4ccc5oc6ccccc6c5c4)c4ccccc4c3)n2)cc1] 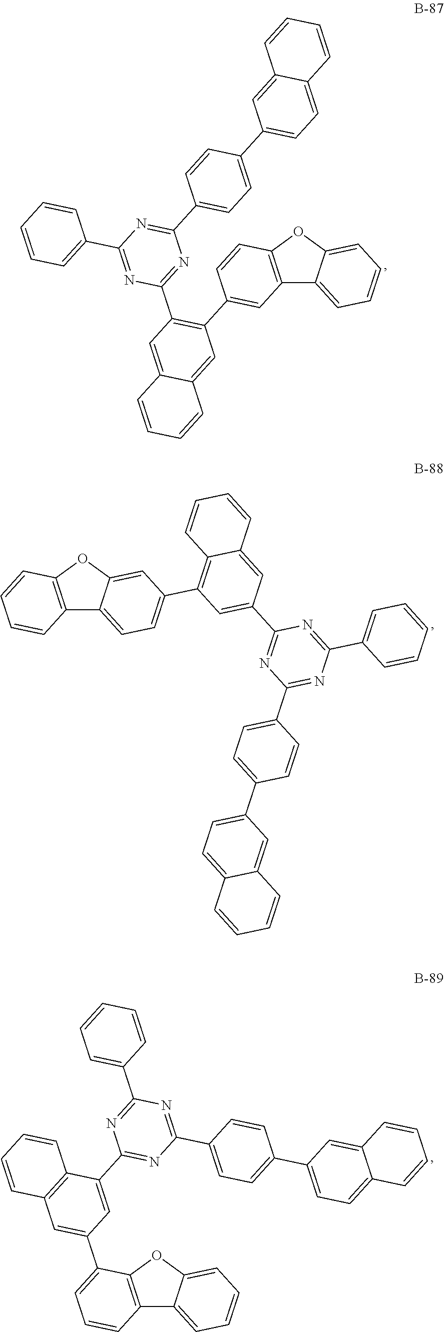 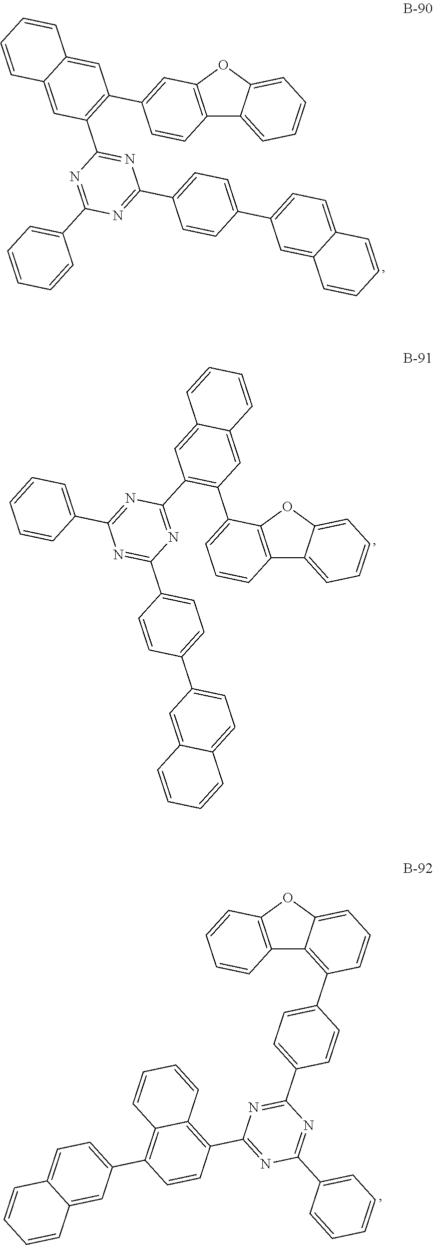 [SMILES: c1ccc(-c2nc(-c3ccc(-c4ccc5ccccc5c4)cc3)nc(-c3cc4ccccc4cc3-c3ccc4c(c3)oc3ccccc34)n2)cc1 ; c1ccc(-c2nc(-c3ccc(-c4ccc5ccccc5c4)cc3)nc(-c3cc4ccccc4cc3-c3cccc4c3oc3ccccc34)n2)cc1 ; c1ccc(-c2nc(-c3ccc(-c4cccc5oc6ccccc6c45)cc3)nc(-c3ccc(-c4ccc5ccccc5c4)c4ccccc34)n2)cc1] 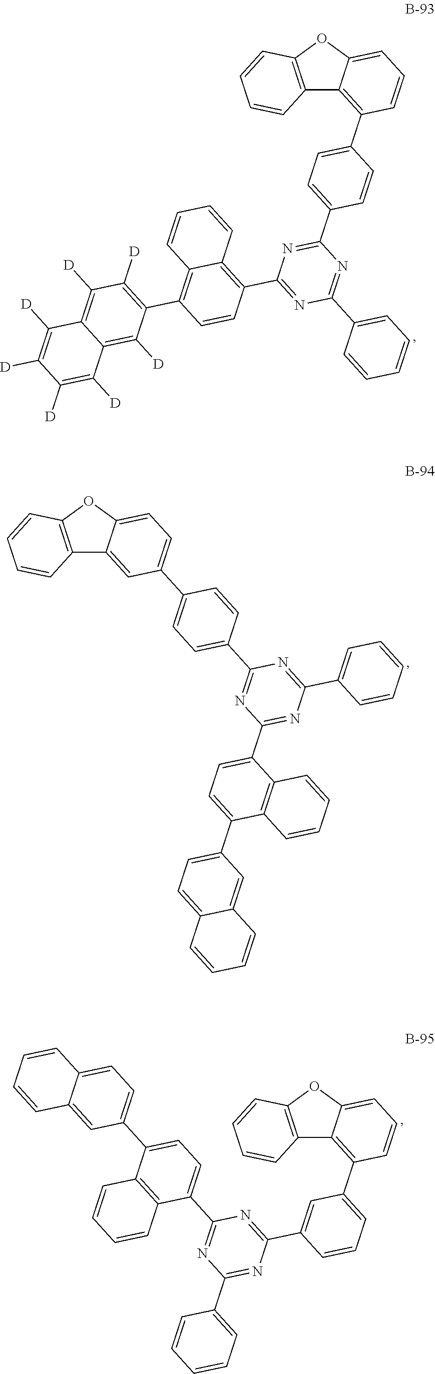 [SMILES: [2H]c1c([2H])c([2H])c2c([2H])c(-c3ccc(-c4nc(-c5ccccc5)nc(-c5ccc(-c6cccc7oc8ccccc8c67)cc5)n4)c4ccccc34)c([2H])c([2H])c2c1[2H] ; c1ccc(-c2nc(-c3ccc(-c4ccc5oc6ccccc6c5c4)cc3)nc(-c3ccc(-c4ccc5ccccc5c4)c4ccccc34)n2)cc1 ; c1ccc(-c2nc(-c3cccc(-c4cccc5oc6ccccc6c45)c3)nc(-c3ccc(-c4ccc5ccccc5c4)c4ccccc34)n2)cc1] 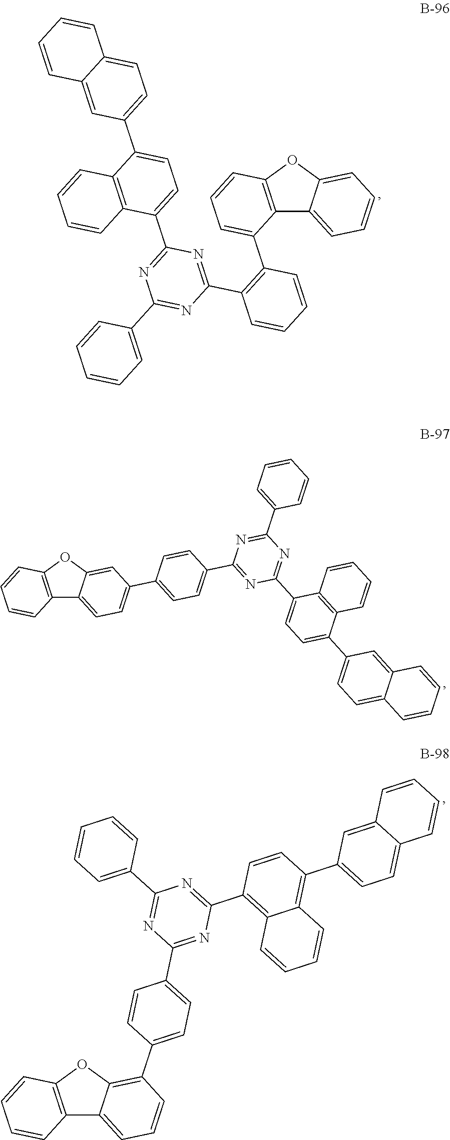 [SMILES: c1ccc(-c2nc(-c3ccccc3-c3cccc4oc5ccccc5c34)nc(-c3ccc(-c4ccc5ccccc5c4)c4ccccc34)n2)cc1 ; c1ccc(-c2nc(-c3ccc(-c4ccc5c(c4)oc4ccccc45)cc3)nc(-c3ccc(-c4ccc5ccccc5c4)c4ccccc34)n2)cc1 ; c1ccc(-c2nc(-c3ccc(-c4cccc5c4oc4ccccc45)cc3)nc(-c3ccc(-c4ccc5ccccc5c4)c4ccccc34)n2)cc1] 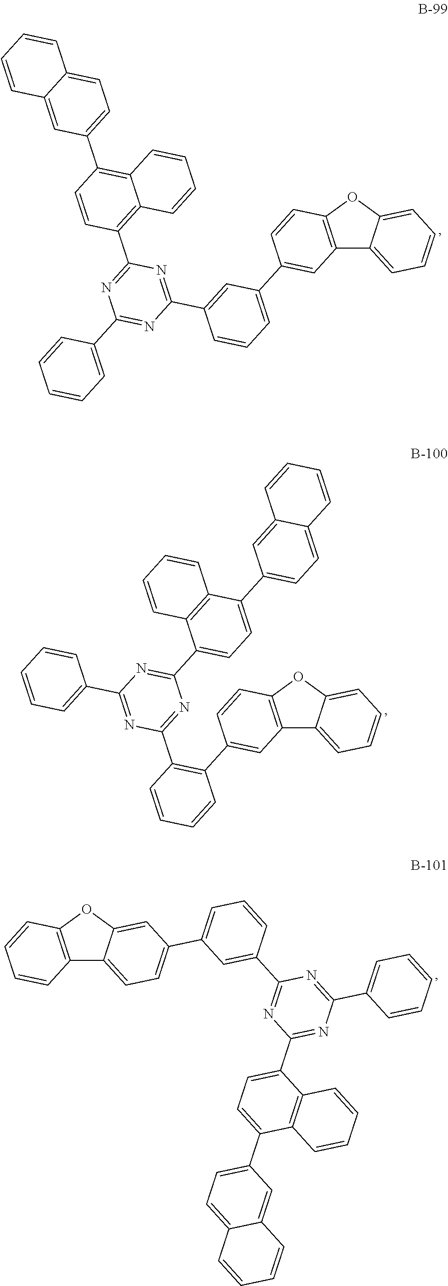 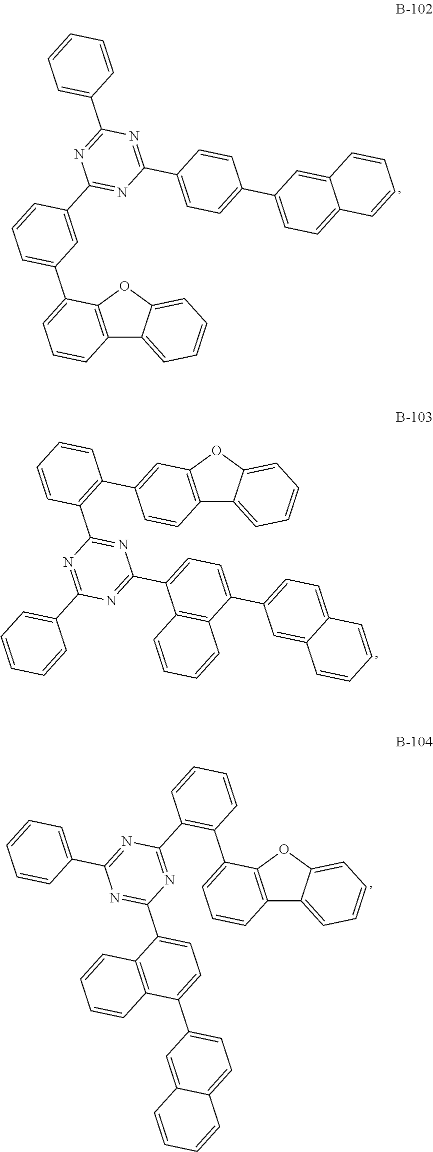 [SMILES: c1ccc(-c2nc(-c3ccc(-c4ccc5ccccc5c4)cc3)nc(-c3cccc(-c4cccc5c4oc4ccccc45)c3)n2)cc1 ; c1ccc(-c2nc(-c3ccccc3-c3ccc4c(c3)oc3ccccc34)nc(-c3ccc(-c4ccc5ccccc5c4)c4ccccc34)n2)cc1 ; c1ccc(-c2nc(-c3ccccc3-c3cccc4c3oc3ccccc34)nc(-c3ccc(-c4ccc5ccccc5c4)c4ccccc34)n2)cc1] 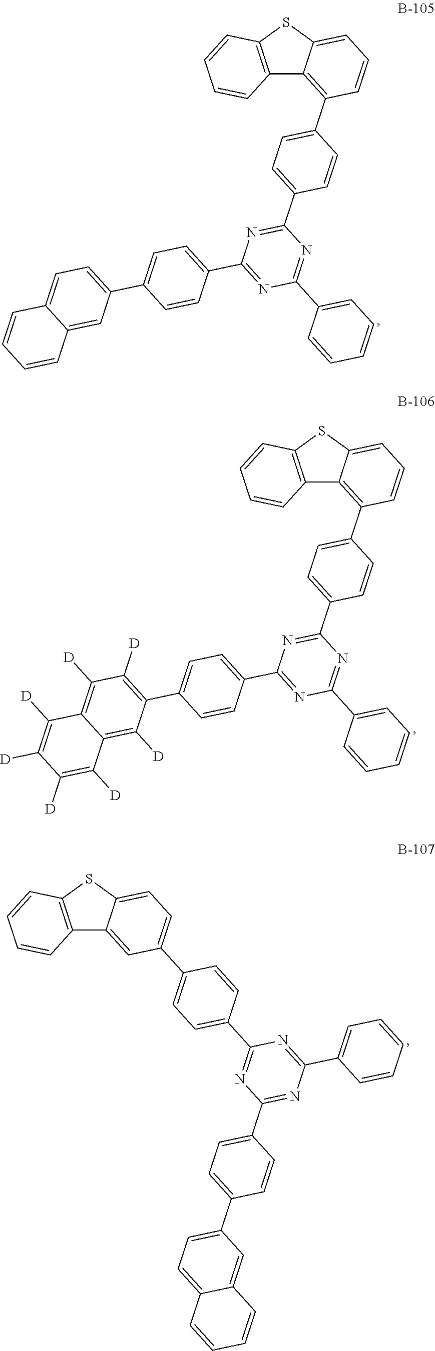 [SMILES: c1ccc(-c2nc(-c3ccc(-c4ccc5ccccc5c4)cc3)nc(-c3ccc(-c4cccc5sc6ccccc6c45)cc3)n2)cc1 ; [2H]c1c([2H])c([2H])c2c([2H])c(-c3ccc(-c4nc(-c5ccccc5)nc(-c5ccc(-c6cccc7sc8ccccc8c67)cc5)n4)cc3)c([2H])c([2H])c2c1[2H] ; c1ccc(-c2nc(-c3ccc(-c4ccc5ccccc5c4)cc3)nc(-c3ccc(-c4ccc5sc6ccccc6c5c4)cc3)n2)cc1] 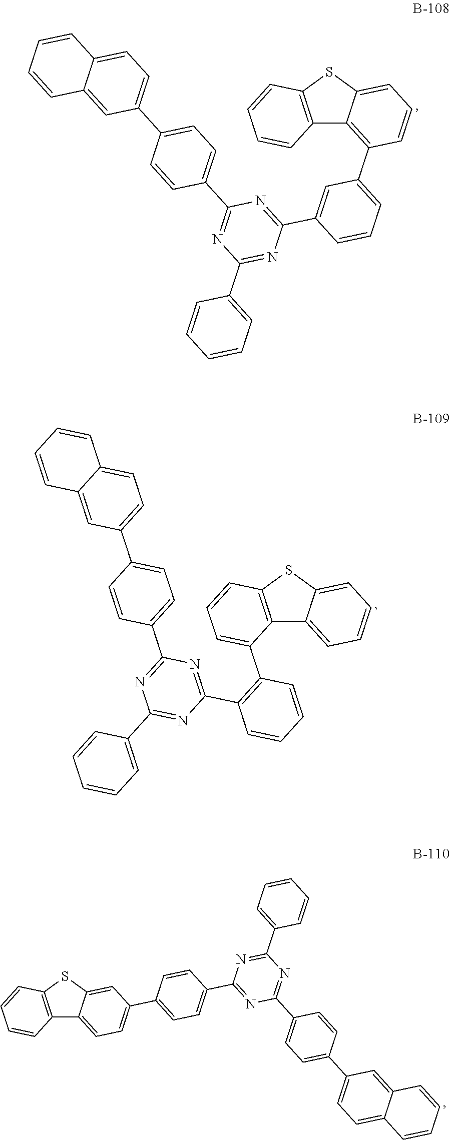 [SMILES: c1ccc(-c2nc(-c3ccc(-c4ccc5ccccc5c4)cc3)nc(-c3cccc(-c4cccc5sc6ccccc6c45)c3)n2)cc1 ; c1ccc(-c2nc(-c3ccc(-c4ccc5ccccc5c4)cc3)nc(-c3ccccc3-c3cccc4sc5ccccc5c34)n2)cc1 ; c1ccc(-c2nc(-c3ccc(-c4ccc5ccccc5c4)cc3)nc(-c3ccc(-c4ccc5c(c4)sc4ccccc45)cc3)n2)cc1] 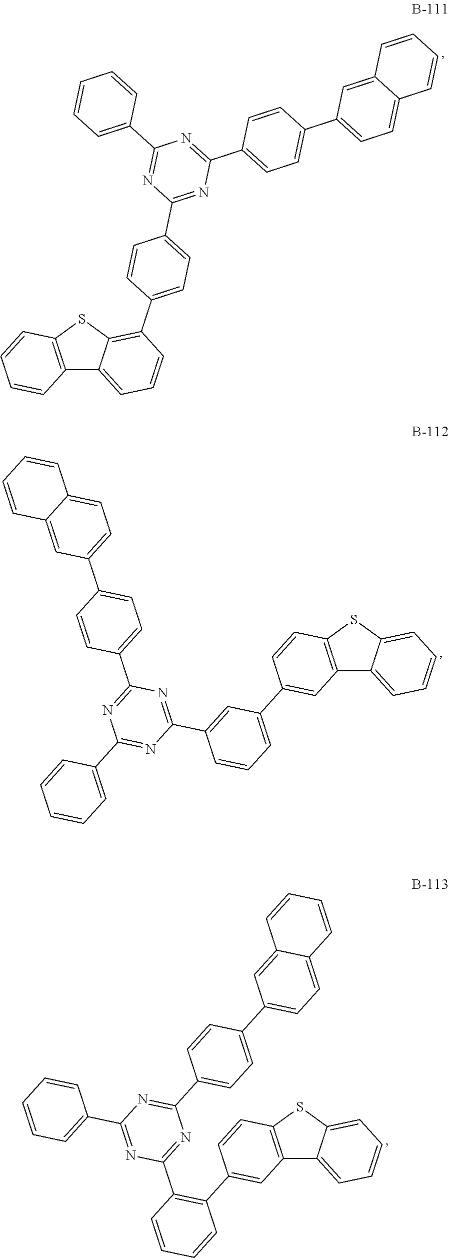 [SMILES: c1ccc(-c2nc(-c3ccc(-c4ccc5ccccc5c4)cc3)nc(-c3ccc(-c4cccc5c4sc4ccccc45)cc3)n2)cc1 ; c1ccc(-c2nc(-c3ccc(-c4ccc5ccccc5c4)cc3)nc(-c3cccc(-c4ccc5sc6ccccc6c5c4)c3)n2)cc1 ; c1ccc(-c2nc(-c3ccc(-c4ccc5ccccc5c4)cc3)nc(-c3ccccc3-c3ccc4sc5ccccc5c4c3)n2)cc1] 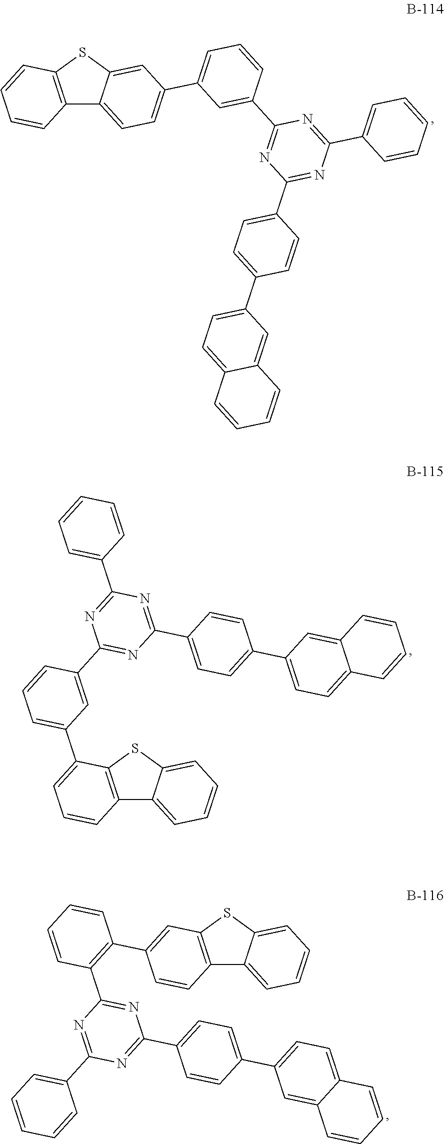 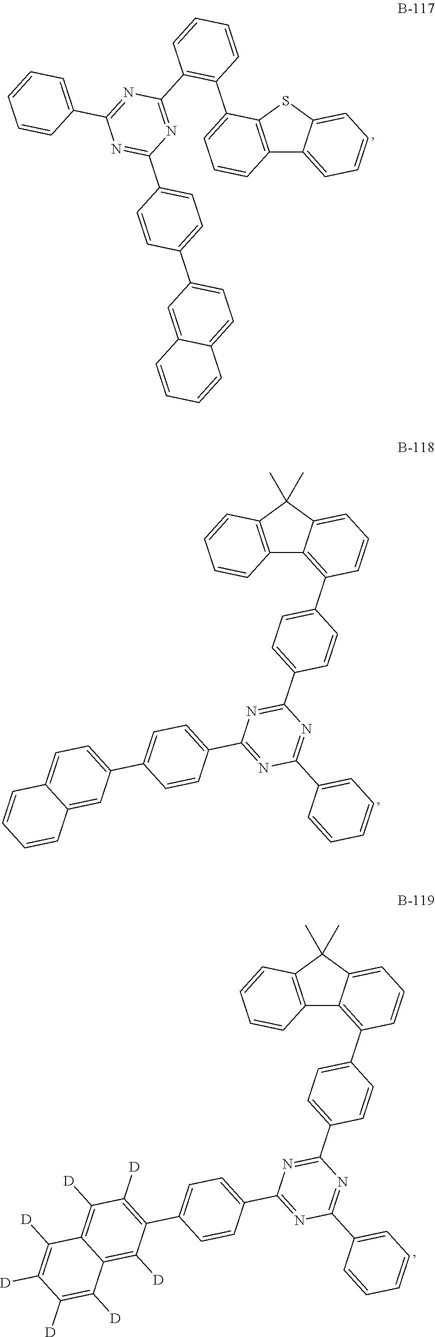 [SMILES: c1ccc(-c2nc(-c3ccc(-c4ccc5ccccc5c4)cc3)nc(-c3ccccc3-c3cccc4c3sc3ccccc34)n2)cc1 ; CC1(C)c2ccccc2-c2c(-c3ccc(-c4nc(-c5ccccc5)nc(-c5ccc(-c6ccc7ccccc7c6)cc5)n4)cc3)cccc21 ; [2H]c1c([2H])c([2H])c2c([2H])c(-c3ccc(-c4nc(-c5ccccc5)nc(-c5ccc(-c6cccc7c6-c6ccccc6C7(C)C)cc5)n4)cc3)c([2H])c([2H])c2c1[2H]] 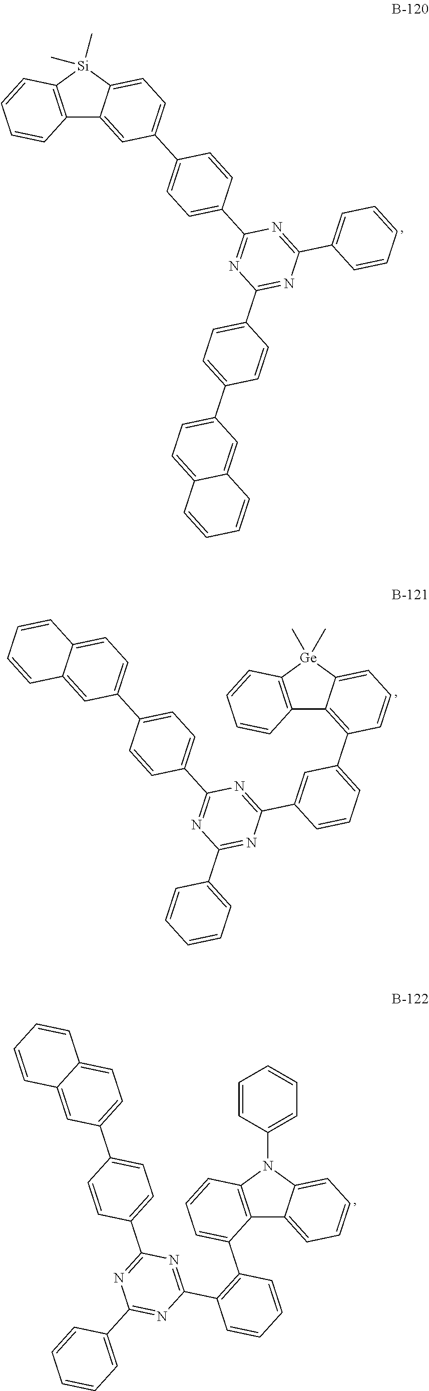 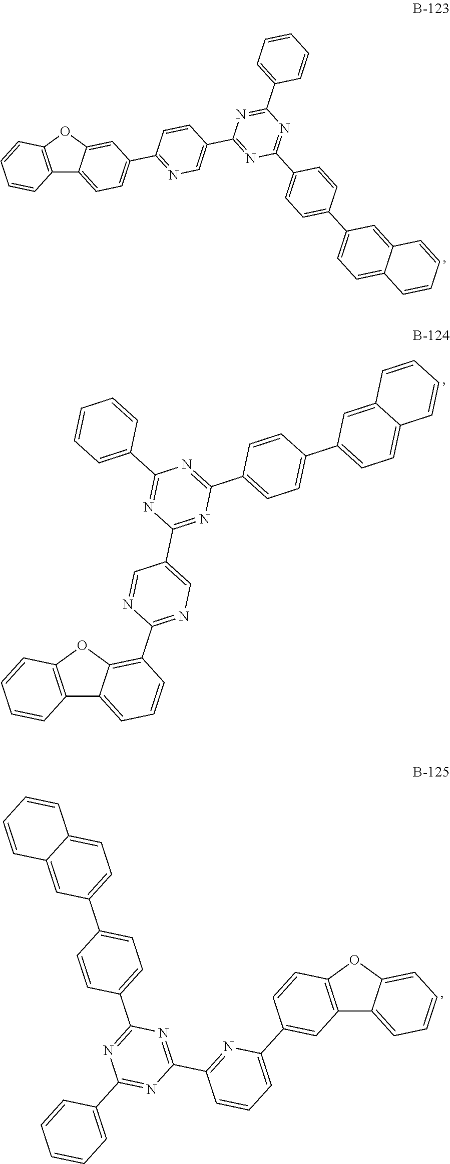 [SMILES: c1ccc(-c2nc(-c3ccc(-c4ccc5ccccc5c4)cc3)nc(-c3ccc(-c4ccc5c(c4)oc4ccccc45)nc3)n2)cc1 ; c1ccc(-c2nc(-c3ccc(-c4ccc5ccccc5c4)cc3)nc(-c3cnc(-c4cccc5c4oc4ccccc45)nc3)n2)cc1 ; c1ccc(-c2nc(-c3ccc(-c4ccc5ccccc5c4)cc3)nc(-c3cccc(-c4ccc5oc6ccccc6c5c4)n3)n2)cc1] 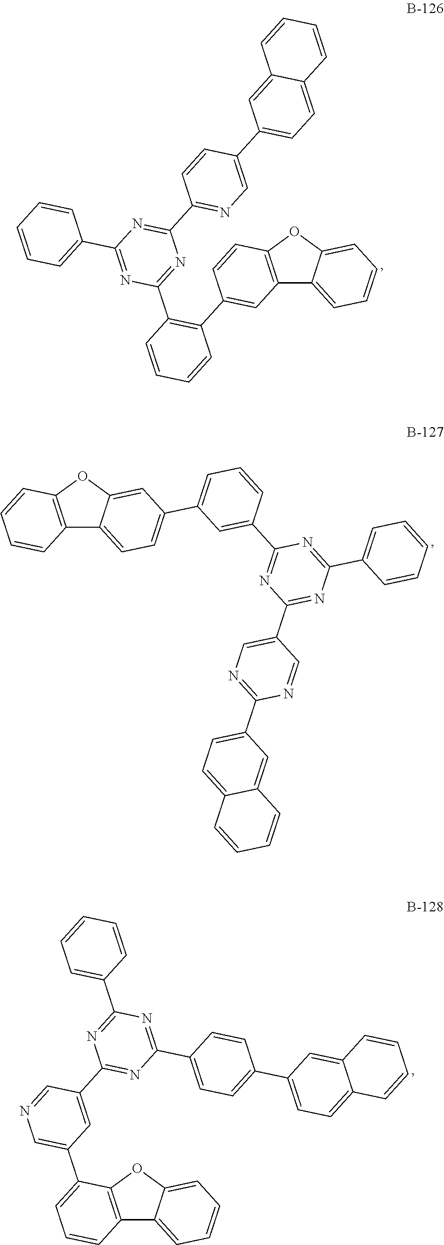 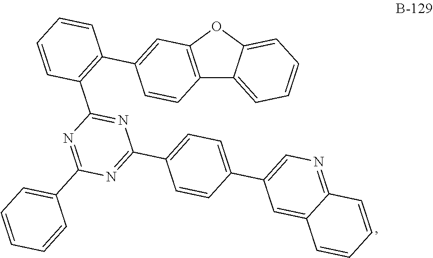 [SMILES: c1ccc(-c2nc(-c3ccc(-c4cnc5ccccc5c4)cc3)nc(-c3ccccc3-c3ccc4c(c3)oc3ccccc34)n2)cc1] 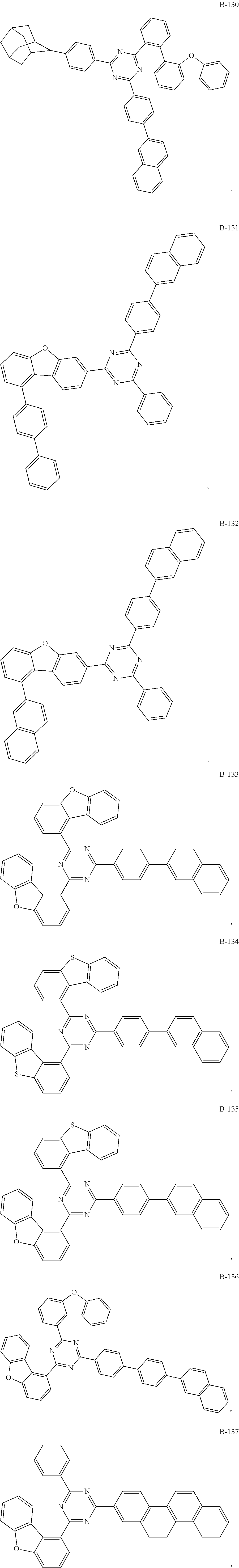 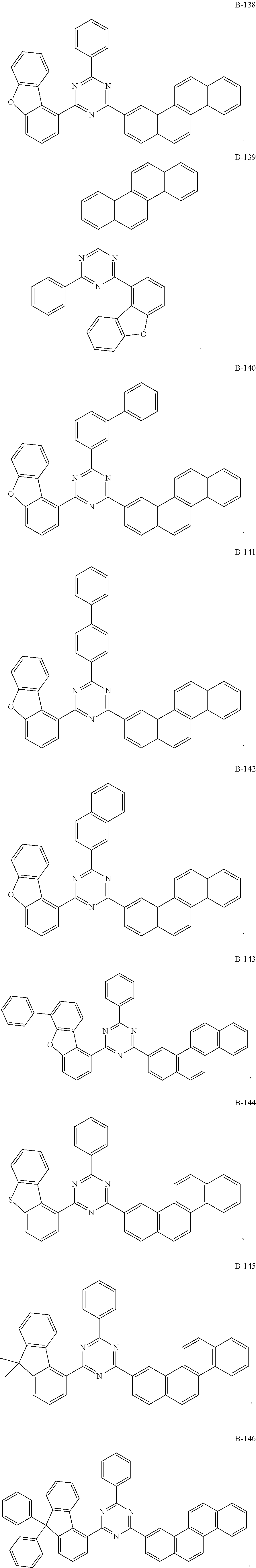 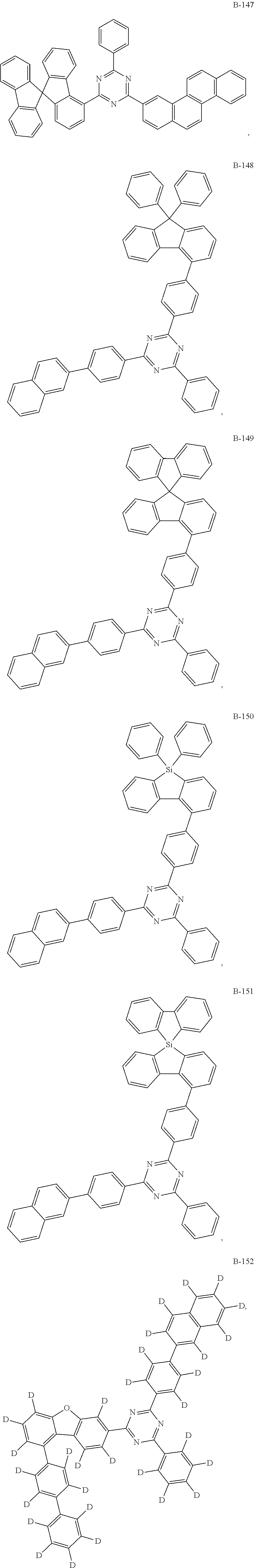 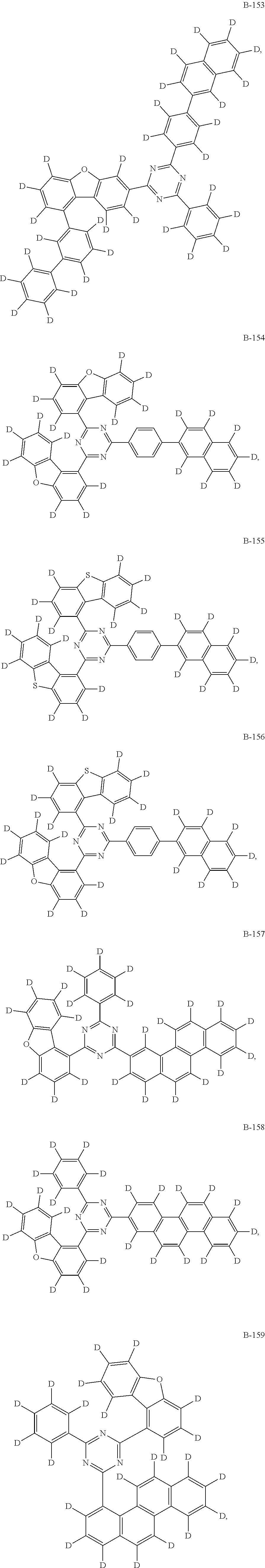 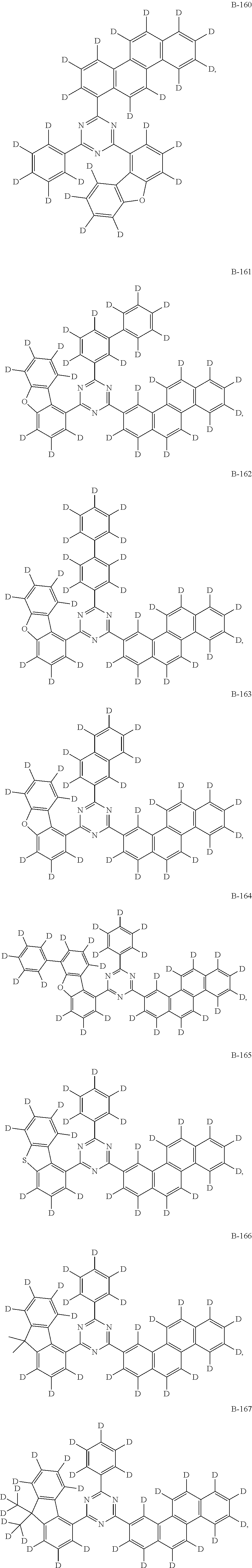 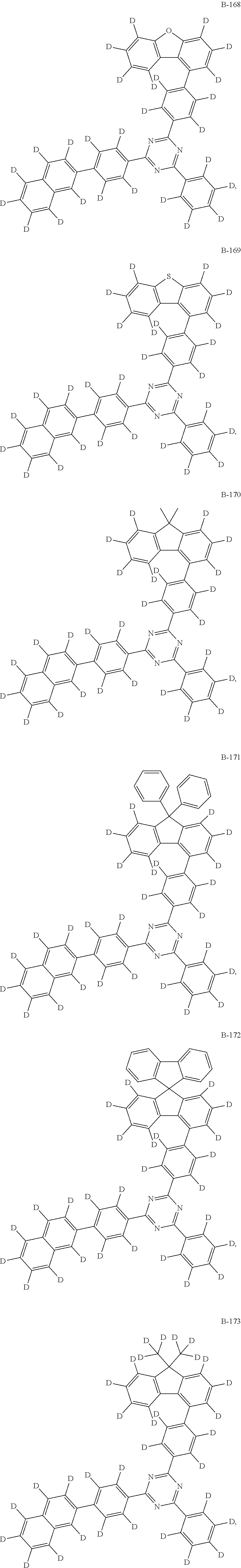 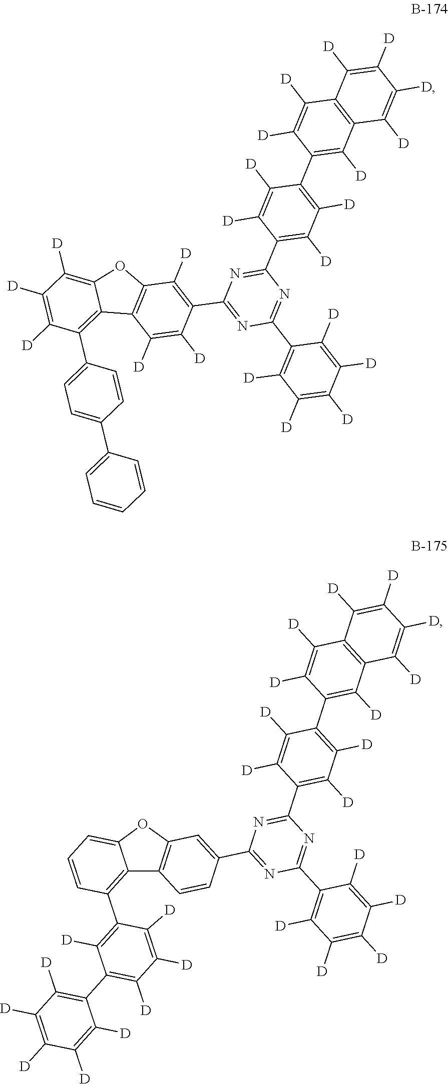 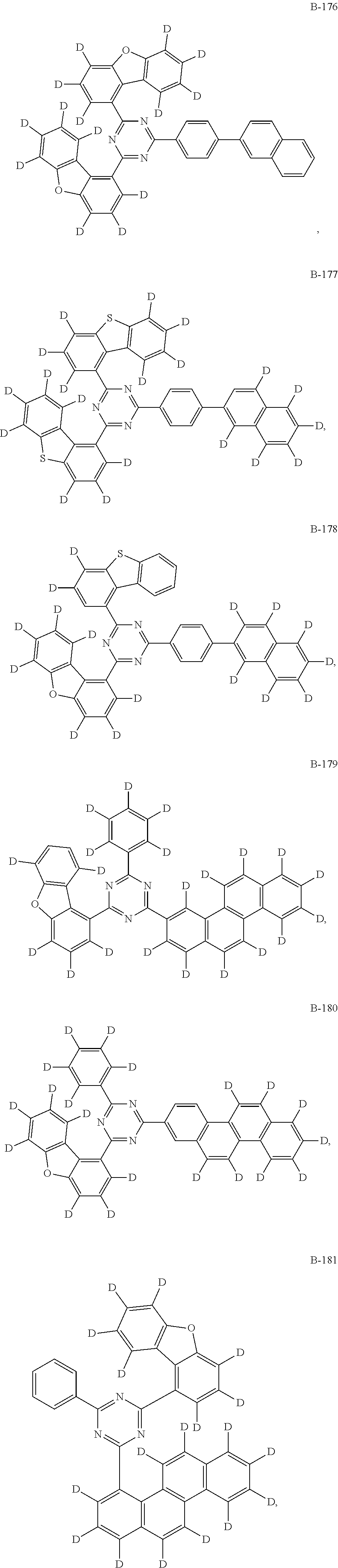 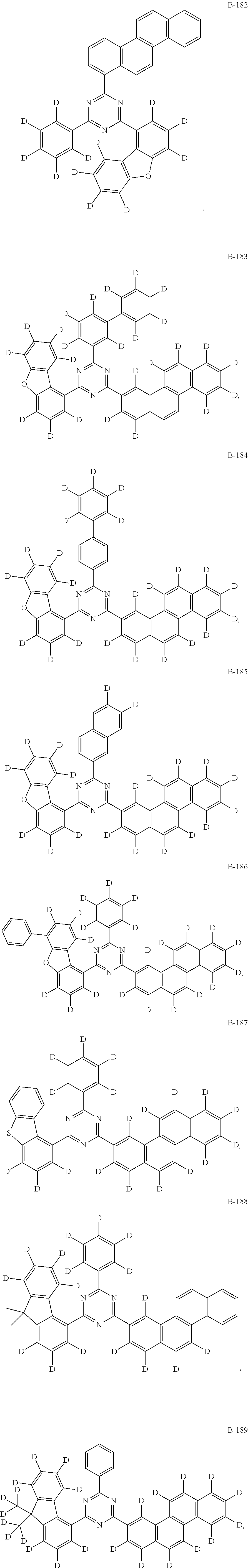 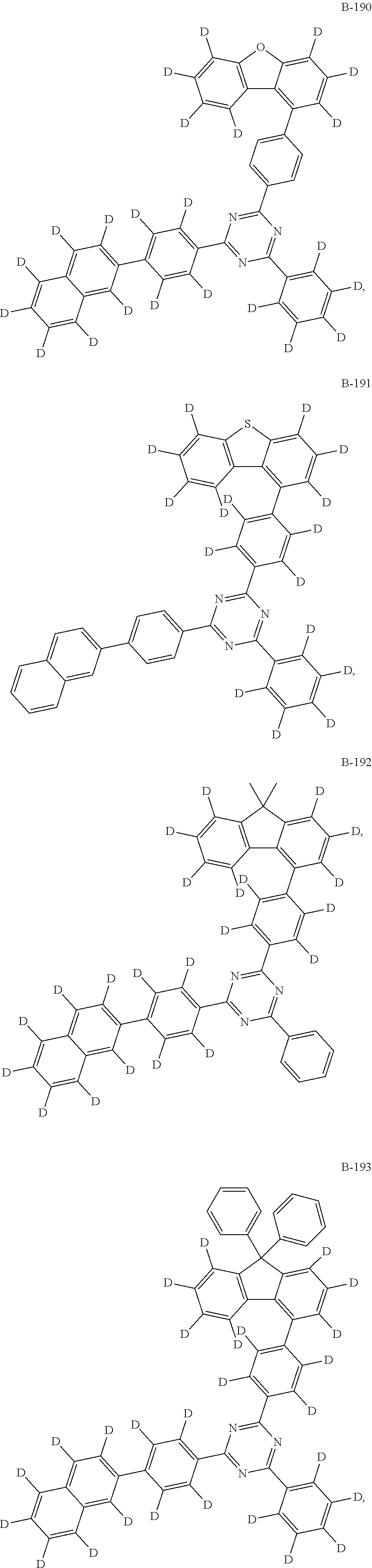 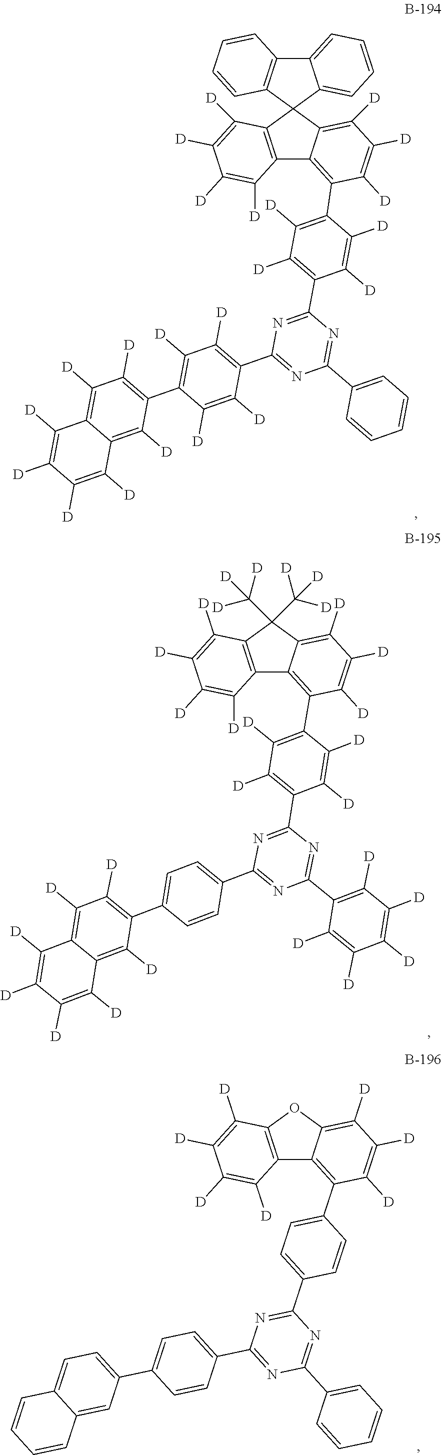 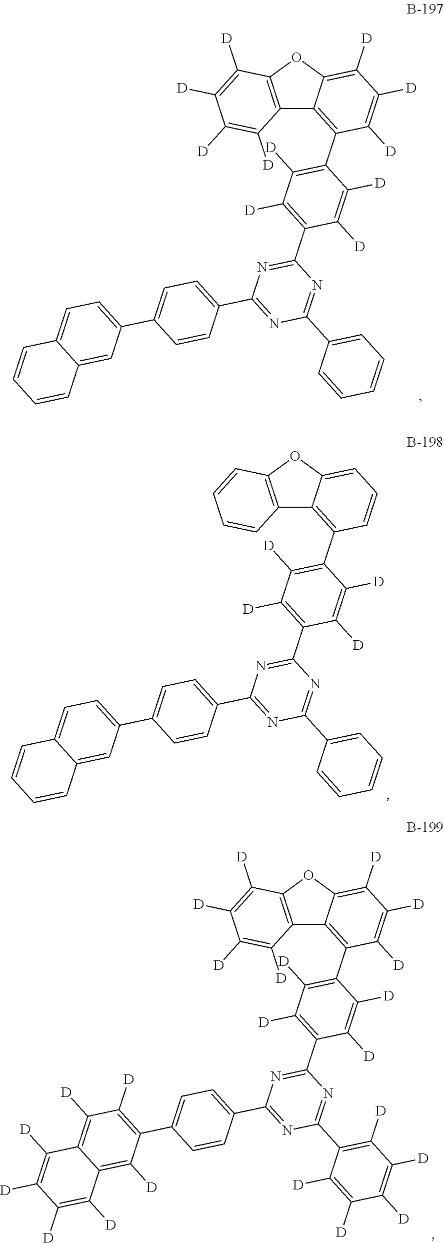 [SMILES: [2H]c1c([2H])c(-c2c([2H])c([2H])c([2H])c3oc4c([2H])c([2H])c([2H])c([2H])c4c23)c([2H])c([2H])c1-c1nc(-c2ccccc2)nc(-c2ccc(-c3ccc4ccccc4c3)cc2)n1 ; [2H]c1c([2H])c(-c2cccc3oc4ccccc4c23)c([2H])c([2H])c1-c1nc(-c2ccccc2)nc(-c2ccc(-c3ccc4ccccc4c3)cc2)n1 ; [2H]c1c([2H])c([2H])c(-c2nc(-c3ccc(-c4c([2H])c([2H])c5c([2H])c([2H])c([2H])c([2H])c5c4[2H])cc3)nc(-c3c([2H])c([2H])c(-c4c([2H])c([2H])c([2H])c5oc6c([2H])c([2H])c([2H])c([2H])c6c45)c([2H])c3[2H])n2)c([2H])c1[2H]] 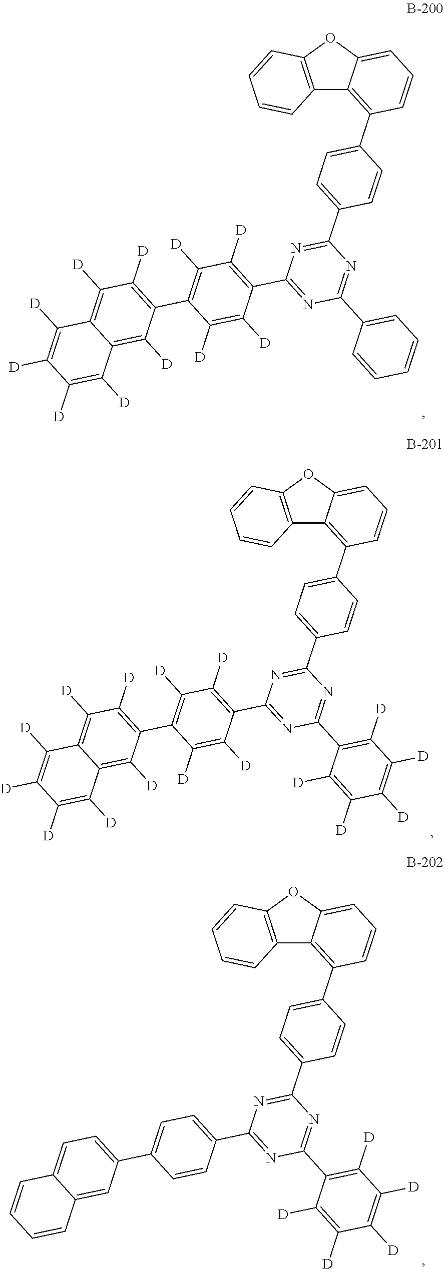 [SMILES: [2H]c1c([2H])c(-c2c([2H])c([2H])c3c([2H])c([2H])c([2H])c([2H])c3c2[2H])c([2H])c([2H])c1-c1nc(-c2ccccc2)nc(-c2ccc(-c3cccc4oc5ccccc5c34)cc2)n1 ; [2H]c1c([2H])c([2H])c(-c2nc(-c3ccc(-c4cccc5oc6ccccc6c45)cc3)nc(-c3c([2H])c([2H])c(-c4c([2H])c([2H])c5c([2H])c([2H])c([2H])c([2H])c5c4[2H])c([2H])c3[2H])n2)c([2H])c1[2H] ; [2H]c1c([2H])c([2H])c(-c2nc(-c3ccc(-c4ccc5ccccc5c4)cc3)nc(-c3ccc(-c4cccc5oc6ccccc6c45)cc3)n2)c([2H])c1[2H]] 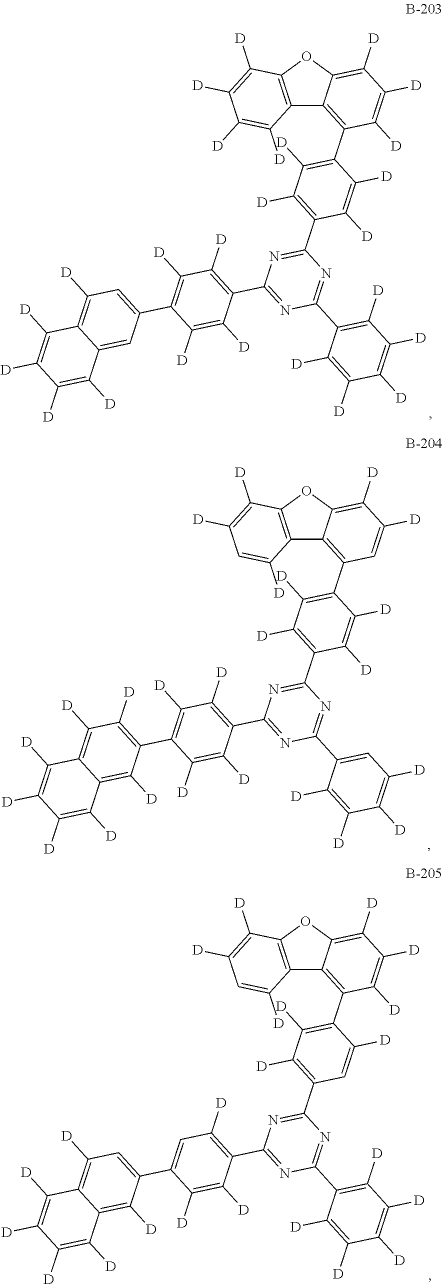 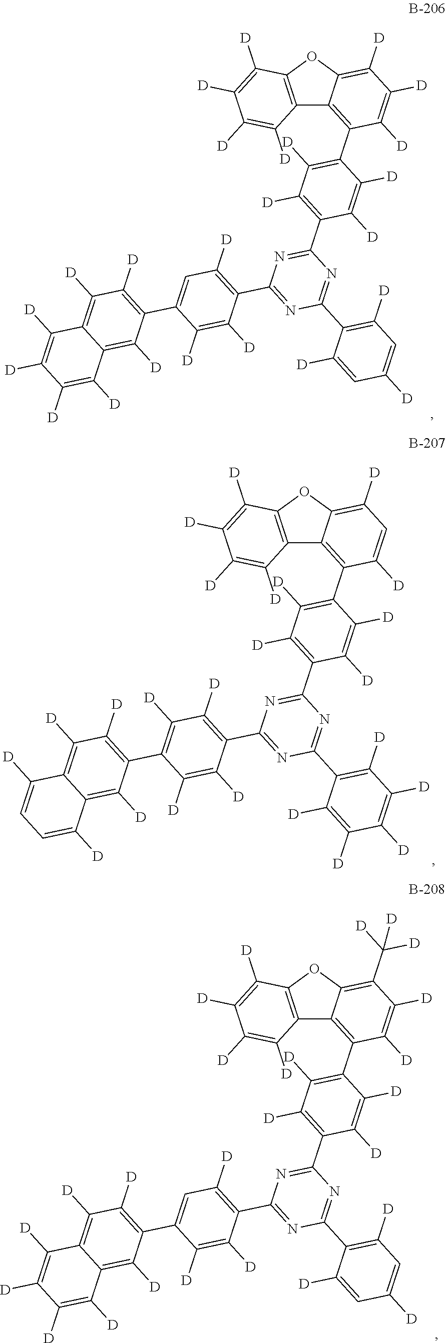 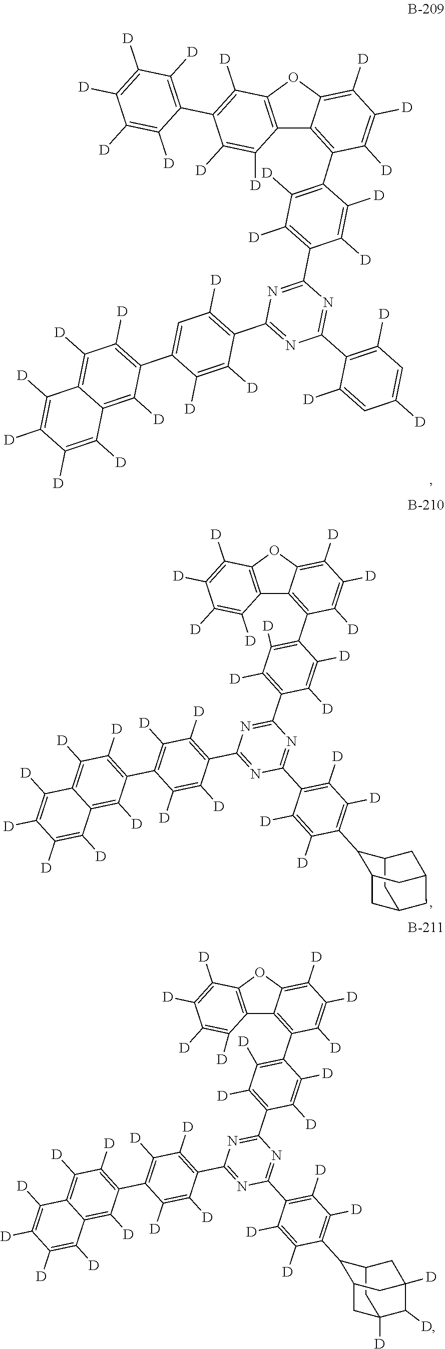 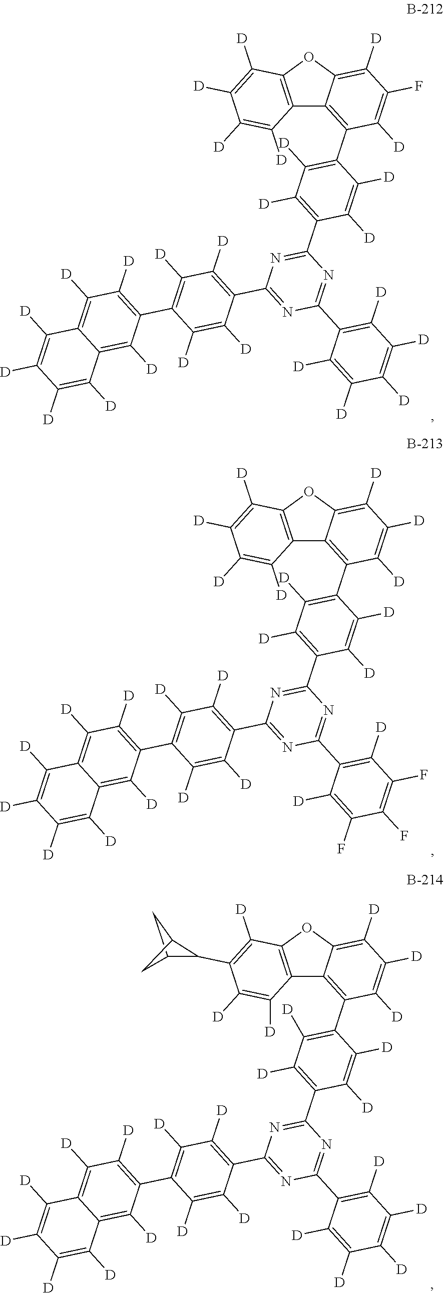 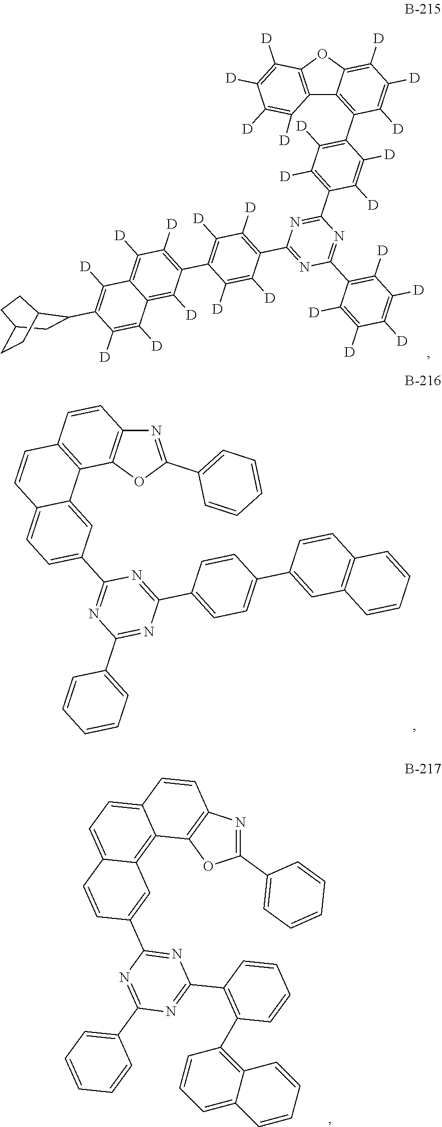 [SMILES: [2H]c1c([2H])c([2H])c(-c2nc(-c3c([2H])c([2H])c(-c4c([2H])c([2H])c5c([2H])c(C6CC7CCC6CC7)c([2H])c([2H])c5c4[2H])c([2H])c3[2H])nc(-c3c([2H])c([2H])c(-c4c([2H])c([2H])c([2H])c5oc6c([2H])c([2H])c([2H])c([2H])c6c45)c([2H])c3[2H])n2)c([2H])c1[2H] ; c1ccc(-c2nc(-c3ccc(-c4ccc5ccccc5c4)cc3)nc(-c3ccc4ccc5ccc6nc(-c7ccccc7)oc6c5c4c3)n2)cc1 ; c1ccc(-c2nc(-c3ccc4ccc5ccc6nc(-c7ccccc7)oc6c5c4c3)nc(-c3ccccc3-c3cccc4ccccc34)n2)cc1] 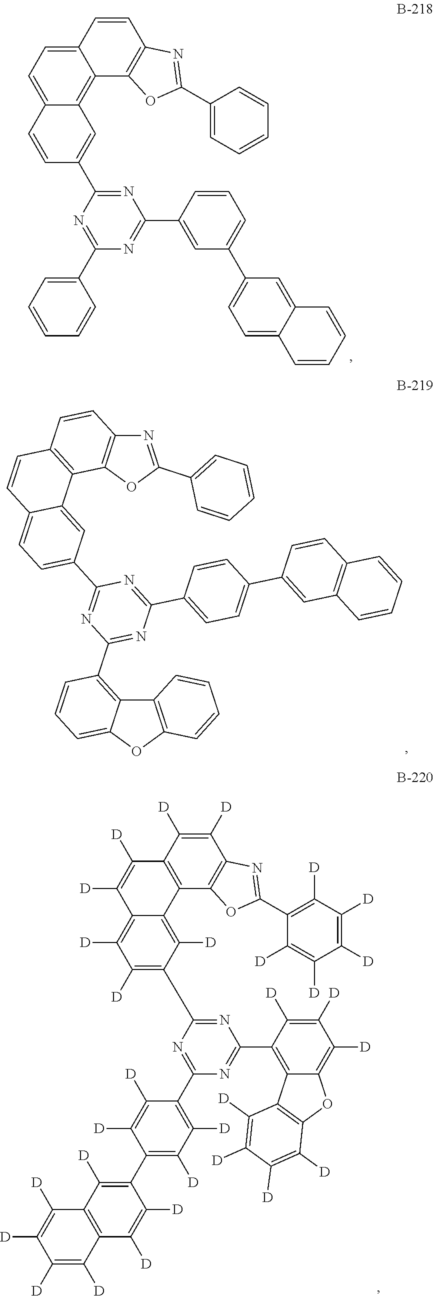 [SMILES: c1ccc(-c2nc(-c3cccc(-c4ccc5ccccc5c4)c3)nc(-c3ccc4ccc5ccc6nc(-c7ccccc7)oc6c5c4c3)n2)cc1 ; c1ccc(-c2nc3ccc4ccc5ccc(-c6nc(-c7ccc(-c8ccc9ccccc9c8)cc7)nc(-c7cccc8oc9ccccc9c78)n6)cc5c4c3o2)cc1 ; [2H]c1c([2H])c([2H])c(-c2nc3c([2H])c([2H])c4c([2H])c([2H])c5c([2H])c([2H])c(-c6nc(-c7c([2H])c([2H])c(-c8c([2H])c([2H])c9c([2H])c([2H])c([2H])c([2H])c9c8[2H])c([2H])c7[2H])nc(-c7c([2H])c([2H])c([2H])c8oc9c([2H])c([2H])c([2H])c([2H])c9c78)n6)c([2H])c5c4c3o2)c([2H])c1[2H]] 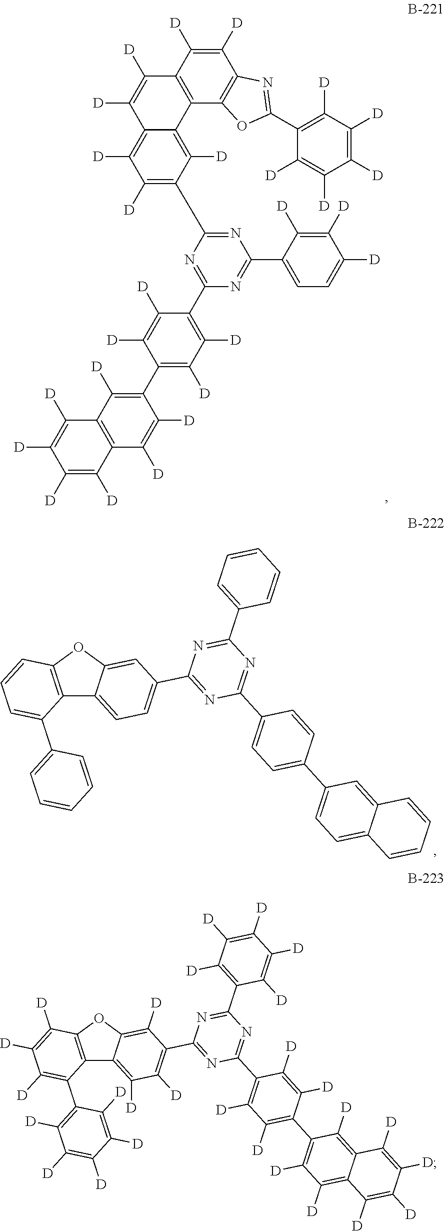
wherein hydrogens in the structures of Compound B-1 to Compound B-223 can be partially or fully substituted with deuterium.

21. The mixture according to claim 14, wherein the third compound has a structure represented by Formula 1 or Formula 2;
preferably, at least two of the first compound, the second compound and the third compound are isomers of each other or isotopologues of each other;
more preferably, the third compound has a structure represented by Formula 1, and the third compound and the first compound are isomers or isotopologues of each other; or the third compound has a structure represented by Formula 2, and the third compound and the second compound are isomers of each other or isotopologues of each other.

22. The mixture according to claim 1, wherein a deuteration rate of at least one of the first compound, the second compound or the third compound is 5% to 100%; preferably, the deuteration rate is 30% to 100%; more preferably, the deuteration rate is 50% to 100%.

23. An electroluminescent device, comprising a first electrode, a second electrode and an organic layer disposed between the first electrode and the second electrode, wherein the organic layer comprises at least the mixture according to claim 1.

24. The electroluminescent device according to claim 23, wherein the organic layer is a emissive layer, and the mixture is a host material.

25. The electroluminescent device according to claim 24, wherein the organic layer is the emissive layer, and the emissive layer further comprises at least one phosphorescent material; preferably, a maximum emission wavelength of the phosphorescent material is greater than or equal to 580 nm.

26. The electroluminescent device according to claim 25, wherein the phosphorescent material is a metal complex having a general formula of M(Lₐ)ᵤ(L_{b})ᵥ(L_{c})_{q};
M is selected from a metal with a relative atomic mass greater than 40;
Lₐ, L_{b} and L_{c} are a first ligand, a second ligand and a third ligand coordinated to M, respectively; Lₐ, L_{b}, and L_{c} can be optionally joined to form a multidentate ligand;
Lₐ, L_{b} and L_{c} may be identical or different; u is 1, 2 or 3, v is 0, 1 or 2, q is 0, 1 or 2, and u+v+q equals the oxidation state of M; when u is greater than or equal to 2, multiple Lₐ may be identical or different; when v is 2, two L_{b} may be identical or different; when q is 2, two L_{c} may be identical or different;
Lₐ has a structure represented by Formula 3: 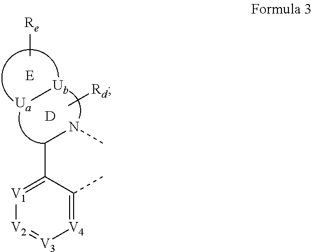
wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and Rₑ represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ and Rᵥ can be optionally joined to form a ring;
L_{b} and L_{c} are, at each occurrence identically or differently, selected from any one of the following structures: 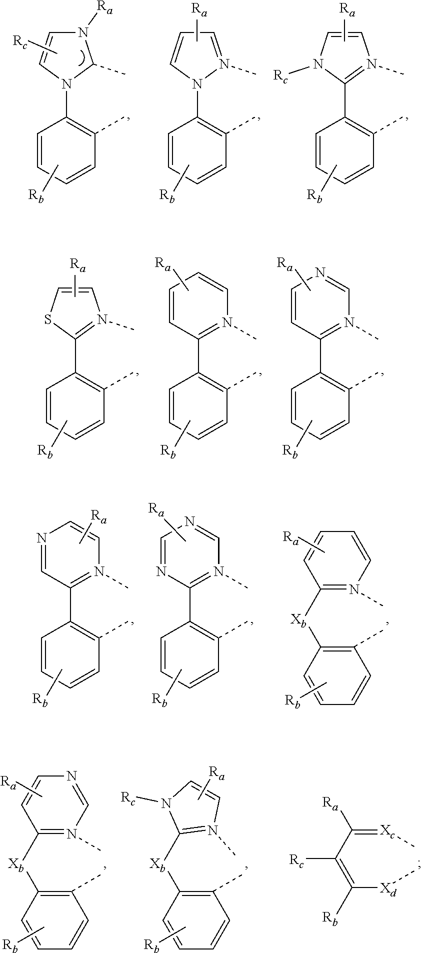
wherein
Rₐ, R_{b} and R_{c} represent, at each occurrence identically or differently, mono-substitution, multiple substitutions or non-substitution;
X_{b} is, at each occurrence identically or differently, selected from the group consisting of: O, S, Se, NR_{N1} and CR_{C1}R_{C2};
X_{c} and X_{d} are, at each occurrence identically or differently, selected from the group consisting of: O, S, Se and NR_{N2};
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
in the structures of the ligands L_{b} and L_{c}, adjacent substituents Rₐ, R_{b}, R_{c}, R_{N1}, R_{N2}, R_{C1} and R_{C2} can be optionally joined to form a ring.

27. The electroluminescent device according to claim 25, wherein the phosphorescent material is a metal complex having a general formula of M(Lₐ)ᵤ(L_{b})ᵥ;
M is selected from a metal with a relative atomic mass greater than 40;
Lₐ and L_{b} are a first ligand and a second ligand coordinated to M, respectively; Lₐ and L_{b} can be optionally joined to form a multidentate ligand;
u is 1, 2 or 3, v is 0, 1 or 2, and u+v equals the oxidation state of M; when u is greater than or equal to 2, multiple Lₐ may be identical or different; when v is 2, two L_{b} may be identical or different;
Lₐ has a structure represented by Formula 3: 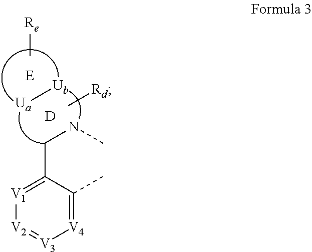
wherein
the ring D is selected from a five-membered heteroaromatic ring or a six-membered heteroaromatic ring;
the ring E is selected from a five-membered unsaturated carbocyclic ring, a benzene ring, a five-membered heteroaromatic ring or a six-membered heteroaromatic ring;
the ring D and the ring E are fused via Uₐ and U_{b};
Uₐ and U_{b} are, at each occurrence identically or differently, selected from C or N;
R_{d} and R_{c} represent, at each occurrence identically or differently, mono-substitution, multiple substitutions or non-substitution;
V₁ to V₄ are, at each occurrence identically or differently, selected from CRᵥ or N;
R_{d}, Rₑ and Rᵥ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R_{d}, Rₑ and Rᵥ can be optionally joined to form a ring;
the ligand L_{b} has the following structure: 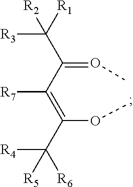
wherein R₁ to R₇ are each independently selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
preferably, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or a combination thereof;
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or a combination thereof.

28. An electronic device, comprising the electroluminescent device according to claim 23.

29. A compound composition, comprising a first compound represented by Formula 1, a second compound represented by Formula 2 and a third compound represented by Formula 1 or Formula 2, wherein the first compound, the second compound and the third compound have structures different from each other; 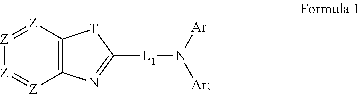
wherein
Ar is, at each occurrence identically or differently, selected from substituted or unsubstituted aryl having 6 to 30 carbon atoms, substituted or unsubstituted heteroaryl having 3 to 30 carbon atoms or a combination thereof;
L₁ is selected from a single bond, substituted or unsubstituted arylene having 6 to 30 carbon atoms, substituted or unsubstituted heteroarylene having 3 to 30 carbon atoms or a combination thereof;
Z is, at each occurrence identically or differently, selected from N or CR_{z}; and
T is selected from O, S or Se; 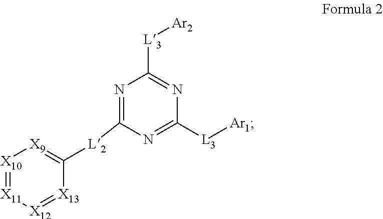
wherein
X₉ to X₁₃ are, at each occurrence identically or differently, selected from CRₓ or N;
L′₂, L₃ and L′₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
Ar₁ and Ar₂ are selected from substituted or unsubstituted aryl having 6 to 30 carbon atoms, substituted or unsubstituted heteroaryl having 3 to 30 carbon atoms or a combination thereof;
R_{z} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R_{z} can be optionally joined to form a ring; and
adjacent substituents Rₓ can be optionally joined to form a ring.
